(19) United States
(12) Patent Application Publication
(10) Pub. No.: US 2025/0255091 A1
(43) Pub. Date: Aug. 7, 2025

(54) ORGANIC LIGHT-EMITTING DIODE AND DISPLAY APPARATUS

(71) Applicants: KunShan Go-Visionox Opto-Electronics Co., Ltd, Kunshan (CN); TSINGHUA UNIVERSITY, Beijing (CN)

(72) Inventors: Guomeng LI, Kunshan (CN); Lian DUAN, Kunshan (CN); Baoyu LI, Kunshan (CN); Minghan CAI, Kunshan (CN); Bin LIU, Kunshan (CN); Mengzhen LI, Kunshan (CN); Hongyu WANG, Kunshan (CN)

(73) Assignees: KunShan Go-Visionox Opto-Electronics Co., Ltd, Kunshan (CN); TSINGHUA UNIVERSITY, Beijing (CN)

(21) Appl. No.: 19/185,216

(22) Filed: Apr. 21, 2025

Related U.S. Application Data
(63) Continuation of application No. PCT/CN2023/077259, filed on Feb. 20, 2023.

(30) Foreign Application Priority Data
Nov. 14, 2022 (CN) 202211421993.0

(51) Int. Cl. H10K 50/115; H10K 85/60; H10K 101/00; H10K 101/10; H10K 101/25; H10K 101/30

(52) U.S. Cl. CPC H10K 50/115; H10K 85/622; H10K 85/636; H10K 85/654; H10K 85/6572; H10K 85/6574; H10K 85/6576; H10K 85/658; H10K 2101/10; H10K 2101/25; H10K 2101/30; H10K 2101/90

(57) ABSTRACT

Provided in the present application are an organic light-emitting diode and a display apparatus. The organic light-emitting diode includes at least one light-emitting layer, which includes at least one phosphorescence sensitized light-emitting layer, wherein the phosphorescence sensitized light-emitting layer includes a host material, a phosphorescent sensitizer and a narrow-spectrum fluorescent material, and the full width at half maximum of the narrow-spectrum fluorescent material is less than 50 nm. The present application can improve the performance, such as the efficiency, of an organic light-emitting diode.

### CROSS-REFERENCE TO RELATED APPLICATIONS

The present application a continuation of International Application No. PCT/CN 2023/077259 filed on Feb. 20, 2023, which claims priority to Chinese Patent Application No. 202211421993.0, filed on Nov. 14, 2022. All of the aforementioned patent applications are hereby incorporated by reference in their entireties.

### FIELD

The present application relates to an organic light-emitting diode and a display apparatus, which belong to the field of organic electroluminescence.

### BACKGROUND

An organic light-emitting diode (OLED) is a device driven by electric current to achieve luminescence, the main characteristic of which is derived from the light-emitting layer therein. When an appropriate voltage is applied, electrons and holes will be combined in the light-emitting layer to generate excitons, and light of various wavelengths is emitted depending on the properties of the light-emitting layer. Currently, the light-emitting layer materials generally lead to defects such as low efficiency of devices, especially for stacked-layer devices, which usually include a plurality of light-emitting layers. The light-emitting layer essentially includes a host material and a phosphorescent material, and the phosphorescent material is prone to cause problems such as low efficiency of devices with the limitations of the structural properties thereof (such as long-wavelength ³M LCT absorption and long self-transient service life).

### SUMMARY

The present application provides an organic light-emitting diode and a display apparatus, which can improve the performance such as efficiency of the device and effectively overcome the defects in the prior art.

One embodiment of the present application provides an organic light-emitting diode, including at least one light-emitting layer, which includes at least one phosphorescence sensitized light-emitting layer, wherein the phosphorescence sensitized light-emitting layer includes a host material, a phosphorescent sensitizer and a narrow-spectrum fluorescent material, and the full width at half maximum of the narrow-spectrum fluorescent material is less than 50 nm.

Another embodiment of the present application provides a display apparatus, which includes the organic light-emitting diode described above.

In the present application, the organic light-emitting diode has at least one light-emitting layer that is a phosphorescence sensitized light-emitting layer (that is, the organic light-emitting diode at least includes one phosphorescence sensitized light-emitting layer). The phosphorescence sensitized light-emitting layer has a composition system including a host material, a phosphorescent sensitizer, and a narrow-spectrum fluorescent material, wherein the full width at half maximum (FWHM) of the introduced narrow-spectrum fluorescent material is less than 50 nm. With such a composition system, the phosphorescent material is used to sensitize the narrow-spectrum fluorescent material for luminescence, and problems such as a broader full width at half maximum of the phosphorescent material itself can be mitigated, thereby improving the performance such as efficiency of the device.

### BRIEF DESCRIPTION OF THE DRAWINGS

FIG. 1 shows a structural schematic diagram of an organic light-emitting diode according to an example of the present application; and

FIG. 2 shows a structural schematic diagram of an organic light-emitting diode according to another example of the present application.

### DETAILED DESCRIPTION OF THE EMBODIMENTS

With the limitation of factors such as the structure and properties of light-emitting materials, light-emitting devices generally have defects such as low efficiency. For example, the green light-emitting layer of devices (e.g., a green light-emitting device) essentially has a composition system of a host material and a green phosphorescent dye. With such a composition system, the phosphorescent material always has problems such as a broader width of emission peak and the resulting low efficiency of devices due to the limitation of the structural properties thereof (such as long-wavelength ³M LCT absorption and long transient service life themselves). In particular, stacked-layer devices typically have at least two light-emitting layers that are stacked. In a green stacked device, each light-emitting layer includes a host material and a phosphorescent material. The phosphorescent material generally has problems such as a broader emission peak width and the resulting low efficiency of devices.

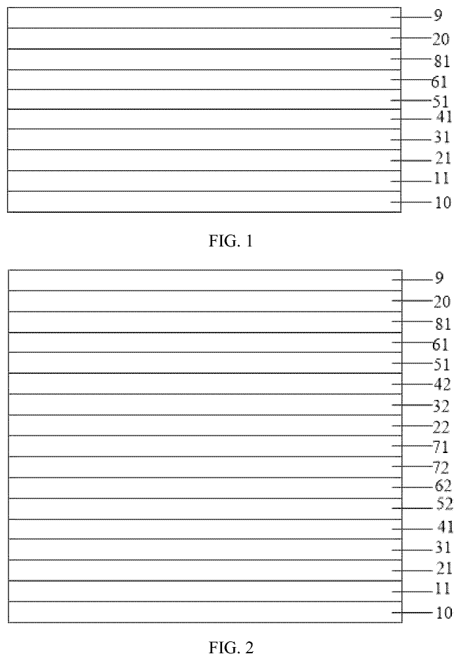

In view of this, an example of the present application provides an organic light-emitting diode. As shown in FIGS. 1 and 2, the organic light-emitting diode includes at least one light-emitting layer, and at least one of the light-emitting layers is a phosphorescence sensitized light-emitting layer (that is, at least one light-emitting layer includes at least one phosphorescence sensitized light-emitting layer). The phosphorescence sensitized light-emitting layer includes a host material, a phosphorescent sensitizer, and a narrow-spectrum fluorescent material, wherein the full width at half maximum of the narrow-spectrum fluorescent material is less than 50 nm.

The organic light-emitting diodes described above at least include one phosphorescence sensitized light-emitting layer, which has a composition system including a host material, a phosphorescent sensitizer, and a narrow-spectrum fluorescent material, wherein the full width at half maximum (FWHM) of the introduced narrow-spectrum fluorescent material is less than 50 nm. In such a composition system, the phosphorescent material is used to sensitize the narrow-spectrum fluorescent material for luminescence, and problems such as a broader full width at half maximum of the phosphorescent material itself can be mitigated, thereby improving the efficiency, service life and other performance of devices and realizing high-efficiency and high-stability luminescence of devices.

Specifically, the luminescence peak of the narrow-spectrum fluorescent material may be 480 nm-580 nm, such as 480 nm, 500 nm, 510 nm, 520 nm, 530 nm, 540 nm, 550 nm, and 580 nm.

In some examples, the narrow-spectrum fluorescent material may have a luminescence peak of 500 nm-550 nm and a luminescence spectrum of green light, and the light-emitting layer described above is a green light-emitting layer, which enables the organic light-emitting diodes in these examples of the present application to generate green light. Furthermore, in the green light-emitting device, the light-emitting layer is formed by a three-doped system of a host material, a phosphorescent sensitizer, and a narrow-spectrum fluorescent material with an FWHM less than 50 nm, which are introduced simultaneously, so that the efficiency, service life and other performance of the green light-emitting device can be improved.

Specifically, the narrow-spectrum fluorescent material described above may include a boron-containing compound and may be selected from boron-containing resonance fluorescent materials with an FWHM<50 nm. For example, in some examples, the narrow-spectrum fluorescent material includes one or more of compounds having structures represented by Formula 3-1, Formula 3-2, Formula 3-3, Formula 3-4, Formula 3-5, Formula 3-6, and Formula 3-7 as follows:

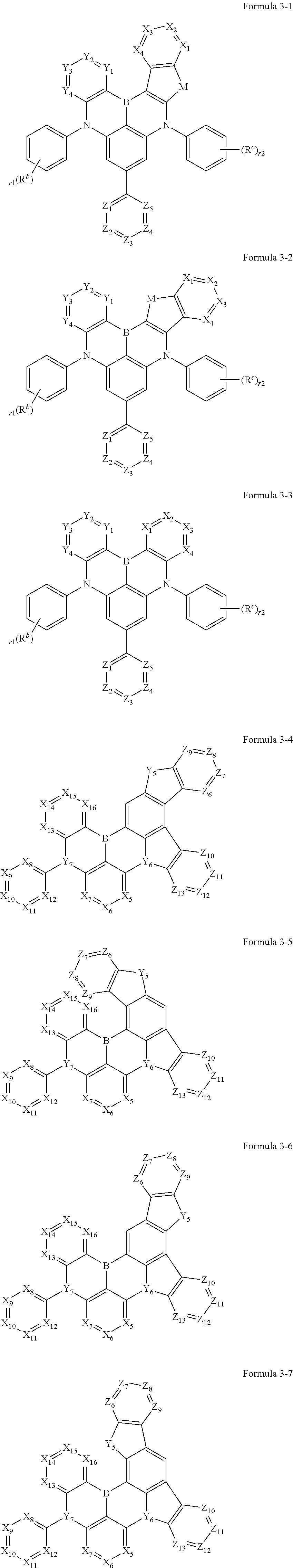

wherein M is NR², O, S or Se; r1 and r2 are each independently an integer from 0 to 5; X₁ to X₁₆, Y₁ to Y₄, and Z₁ to Z₅ are each independently CR₁ or N, and at least one of Z¹ to Z⁵ is N; Y₅, Y₆ and Y₇ are each independently O, S, CR₂ or N; R^{b}, R^{c}, R₁ and R₂ are each independently selected from at least one of hydrogen, halogen, cyano, nitro, hydroxyl, amino, substituted or unsubstituted C1-C20 linear or branched alkyl, substituted or unsubstituted C3-C20 cycloalkyl, substituted or unsubstituted C2-C20 linear or branched or cyclic alkenyl, substituted or unsubstituted C2-C20 linear or branched or cyclic alkynyl, substituted or unsubstituted C1-C20 alkoxy, substituted or unsubstituted C1-C20 silanyl, substituted or unsubstituted C6-C30 aryloxy, substituted or unsubstituted C6-C60 aryl, substituted or unsubstituted C3-C60 heteroaryl, a substituted or unsubstituted C6-C60 aryl ether group, a substituted or unsubstituted C3-C60 heteroaryl ether group, substituted or unsubstituted C6-C60 arylthio, substituted or unsubstituted C3-C60 heteroarylthio, substituted or unsubstituted C6-C60 arylamino, and substituted or unsubstituted C3-C60 heteroarylamino; and R¹ is linked or not linked to an adjacent group.

In one embodiment, the “substituted” in the expression “substituted or unsubstituted” above refers to being substituted with at least one selected from halogen, C1-C30 linear or branched alkyl, C3-C30 cycloalkyl, C3-C20 heterocycloalkyl, C1-C10 alkoxy, carboxyl, nitro, cyano, amino, hydroxyl, mercapto, C1-C20 alkylsilyl, C1-C20 alkylamino, C6-C30 arylamino, C3-C30 heteroarylamino, C6-C60 aryloxy, C3-C30 heteroaryloxy, C6-C60 aryl, or C3-C60 heteroaryl.

In one embodiment, X₁ to X₄ are all CR₁, and R₁ is selected from at least one of hydrogen, C1-C20 linear or branched alkyl, C3-C20 cycloalkyl, C6-C60 aryl, and C3-C60 heteroaryl; preferably hydrogen, C1-C6 linear or branched alkyl and phenyl; more preferably hydrogen, isopropyl, tert-butyl and phenyl; and further preferably, at least one of the plurality of R₁ is not hydrogen.

In one embodiment, Y₁ to Y₄ are all CR₁, and R₁ is selected from at least one of hydrogen, C1-C20 linear or branched alkyl, C3-C20 cycloalkyl, C6-C60 aryl, and C3-C60 heteroaryl, preferably hydrogen, C1-C6 linear or branched alkyl and phenyl, more preferably hydrogen, isopropyl, tert-butyl, and phenyl; and at least one of the plurality of R₁ is not hydrogen.

In one embodiment, R^{b} is hydrogen, C1-C6 linear or branched alkyl, and phenyl, preferably hydrogen, isopropyl, tert-butyl, and phenyl; and at least one of the plurality of R^{b} is not hydrogen. R^{c} is hydrogen, C1-C6 linear or branched alkyl, and phenyl, preferably hydrogen, isopropyl, tert-butyl and phenyl, and at least one of the plurality of R^{c} is not hydrogen.

In one embodiment, Z₁ to Z₅ are not all N, and at least one R₁ is substituted or unsubstituted C6-C60 aryl, or substituted or unsubstituted C3-C60; and preferably, Z₁ to Z₅ are not all N, and at least one R₁ is substituted or unsubstituted C6-C12 aryl, or substituted or unsubstituted C3-C12 heteroaryl.

The aforementioned compounds having a structure represented by Formula 3-1, Formula 3-2, Formula 3-3, Formula 3-4, Formula 3-5, Formula 3-6, and Formula 3-7 have an emission spectrum of green light, a strong rigid structure, small Stokes shift, narrow-spectrum characteristics, and an FWHM<50 nm, which can effectively adjust the color of light, thereby improving the performance such as light color, color purity, luminous efficiency, and service life of the devices.

In the present application, unless otherwise stated, the expression related to chemical elements includes the concept of isotopes with the same chemical properties. For example, hydrogen (H) includes ¹H (protium), ²H (deuterium, D), ³H (tritium, T), and the like, and carbon (C) includes ¹²C, ¹³C, and the like.

In the present application, unless otherwise specified, the heteroatom of heteroaryl is an atom or atomic group selected from the group including N, O, S, P, B, Si, and Se, preferably N, O, and S.

In the present application, the halogens may be fluorine, chlorine, bromine, and iodine.

In the present application, the “substituted or unsubstituted” group mentioned above may be substituted with one or a plurality of substituents. When there is a plurality of (at least 2) substituents, the substituents may be identical or different.

In the present application, the expression Ca-Cb denotes that the number of carbon atoms in the group is a-b, and this number of carbon atoms does not include the number of carbon atoms in the substituent unless otherwise stated. As an example, C1-C20 mentioned above may be, for example, C1, C2, C3, C4, C5, C6, C7, C8, C9, C10, C11, C12, C13, C14, C15, C16, C17, C18, or C20; C3-C20 may be, for example, C3, C4, C5, C6, C7, C8, C9, C10, C11, C12, C13, C14, C15, C16, C17, C18, C19, or C20; C3-C60 may be, for example, C3, C4, C5, C6, C9, C10, C12, C14, C16, C18, C20, C22, C24, C26, C28, C30, C32, C34, C36, C38, C40, C42, C44, C46, C48, C50, C52, C54, C56, or C58; and C6-C60 may be, for example, C6, C9, C10, C12, C14, C16, C18, C20, C22, C24, C26, C28, C30, C32, C34, C36, C38, C40, C42, C44, C46, C48, C50, C52, C54, C56, or C58.

As an example, the C1-C30 alkyl may include at least one of C1-C30 linear or branched alkyl and C1-C30 cycloalkyl.

As an example, the C1-C20 linear or branched alkyl and C1-C30 linear or branched alkyl may be a linear or branched alkyl, which is, for example, selected from methyl, ethyl, n-propyl, isopropyl, n-butyl, isobutyl, tert-butyl, 2-methylbutyl, n-pentyl, isopentyl, neopentyl, n-hexyl, neohexyl, 2-ethylhexyl, n-octyl, n-heptyl, n-nonyl, and n-decyl, but is not limited thereto.

As an example, the C3-C20 cycloalkyl may include monocycloalkyl or polycycloalkyl, wherein the monocycloalkyl refers to an alkyl group containing a single cyclic structure, and the polycycloalkyl refers to a structure formed by two or more cycloalkyl groups sharing one or more carbon atoms on the rings. As an example, the C3-C20 cycloalkyl is selected from, but is not limited to, cyclopropyl, cyclobutyl, cyclopentyl, cyclohexyl, adamantyl, etc.

As an example, the aryl mentioned above may include monocyclic aryl and polycyclic aryl, wherein the monocyclic aryl refers to a single phenyl group or a biphenyl group (i.e. the group contains at least one phenyl group, and when at least two phenyl groups are contained, the phenyl groups are linked via single bonds), including, for example, phenyl, biphenyl, and terphenyl; and the polycyclic aryl refers to a group containing at least two aromatic rings which are fused together via two adjacent carbon atoms in common, including, for example, naphthyl, anthryl, phenanthryl, indenyl, fluorenyl and derivatives thereof (such as 9,9-dimethylfluorenyl, 9,9-diethylfluorenyl, 9,9-dipropylfluorenyl, 9,9-dibutylfluorenyl, 9,9-dipentylfluorenyl, 9,9-dihexylfluorenyl, 9,9-diphenylfluorenyl, 9,9-dinaphthylfluorenyl, spirobifluorenyl, and benzofluorenyl), fluoranthryl, triphenylylene, pyrenyl, perylenyl, chrysenyl, or tetracenyl.

As an example, the heteroaryl mentioned above may include monocyclic heteroaryl or polycyclic heteroaryl. The monocyclic heteroaryl refers to a single heteroaryl group (aromatic heterocycle) or a biaryl group formed by a single heteroaryl group linked to another aromatic group (aryl or heteroaryl) via a single bond, that is, the monocyclic heteroaryl contains at least one heteroaryl group, and when a molecule contains a heteroaryl group and an additional aromatic group, the heteroaryl group is linked to the additional aromatic group via a single bond. The monocyclic heteroaryl includes, for example, pyridinyl, pyrimidinyl, pyrazinyl, pyridazinyl, triazinyl, furanyl, thienyl, and pyrrolyl. The polycyclic heteroaryl refers to a molecule containing at least one heteroaryl group and at least one aromatic group (heteroaryl or aryl), which are fused together via two adjacent atoms in common, including, for example, quinolinyl, isoquinolinyl, quinoxalinyl, quinazolinyl, benzofuranyl, benzothienyl, isobenzofuranyl, isobenzothienyl, indolyl, dibenzofuranyl, dibenzothienyl, carbazolyl and derivatives thereof, acridinyl, phenothiazinyl, phenoxazinyl, and hydroacridinyl.

In the present application, “each independently” denotes that when there is a plurality of subjects, the subjects may be the same or different from each other.

Specifically, the narrow-spectrum fluorescent material includes one or more of the following compounds M1 to M474:

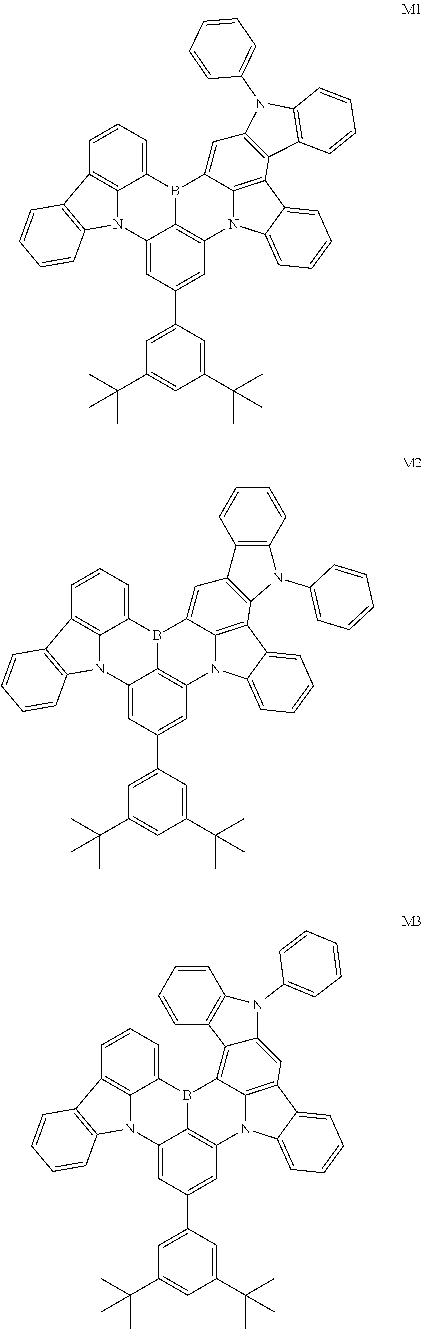 [SMILES: CC(C)(C)c1cc(-c2cc3c4c(c2)-n2c5ccccc5c5c6c7ccccc7n(-c7ccccc7)c6cc(c52)B4c2cccc4c5ccccc5n-3c24)cc(C(C)(C)C)c1 ; CC(C)(C)c1cc(-c2cc3c4c(c2)-n2c5ccccc5c5c2c(cc2c6ccccc6n(-c6ccccc6)c25)B4c2cccc4c5ccccc5n-3c24)cc(C(C)(C)C)c1 ; CC(C)(C)c1cc(-c2cc3c4c(c2)-n2c5ccccc5c5cc6c(c(c52)B4c2cccc4c5ccccc5n-3c24)c2ccccc2n6-c2ccccc2)cc(C(C)(C)C)c1]

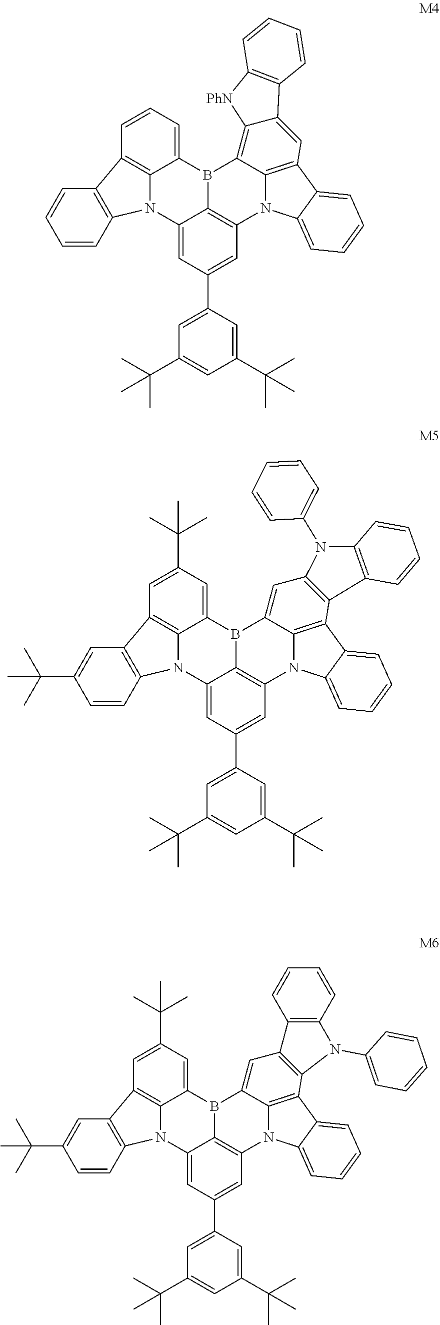

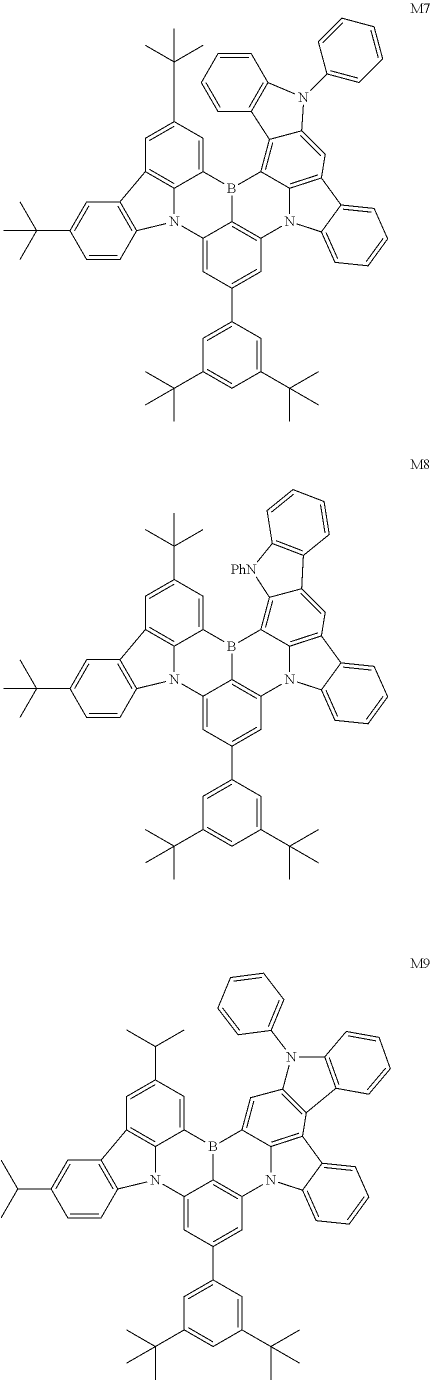

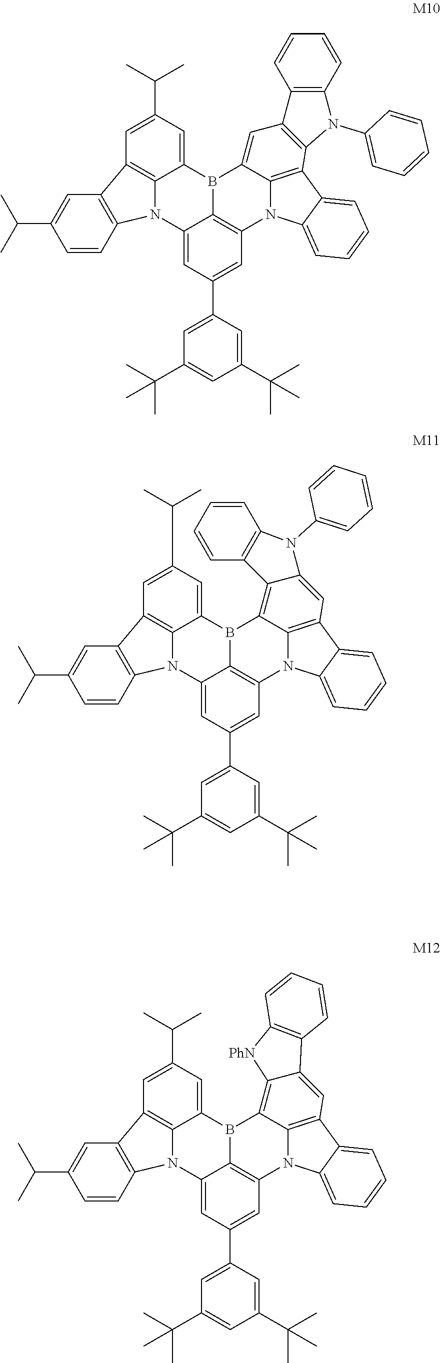

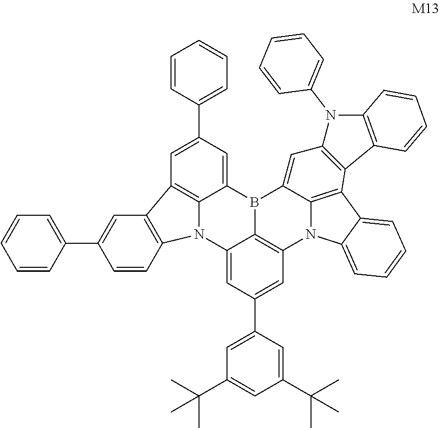 [SMILES: CC(C)(C)c1cc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc(C(C)(C)C)c1]

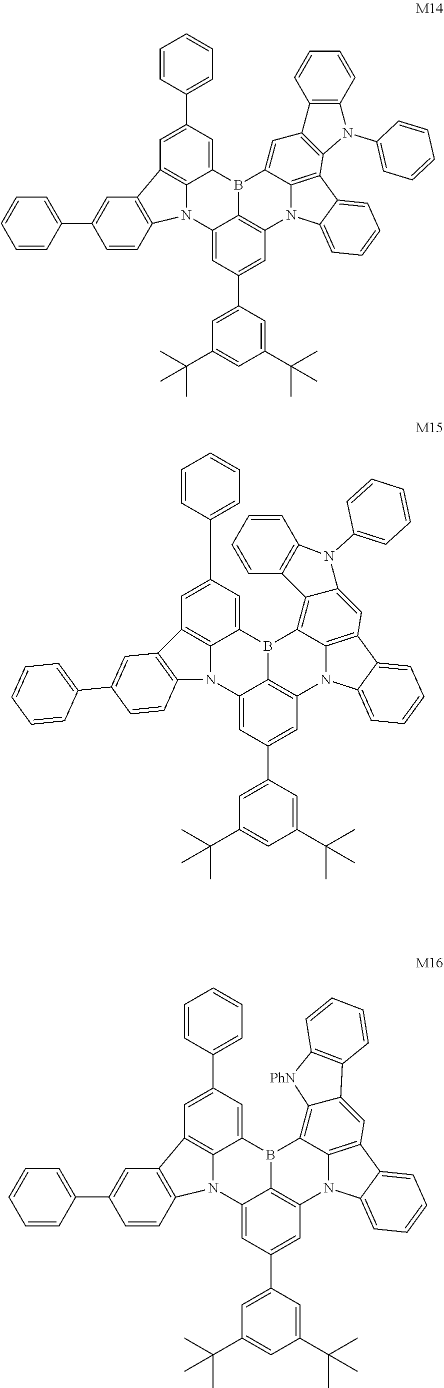

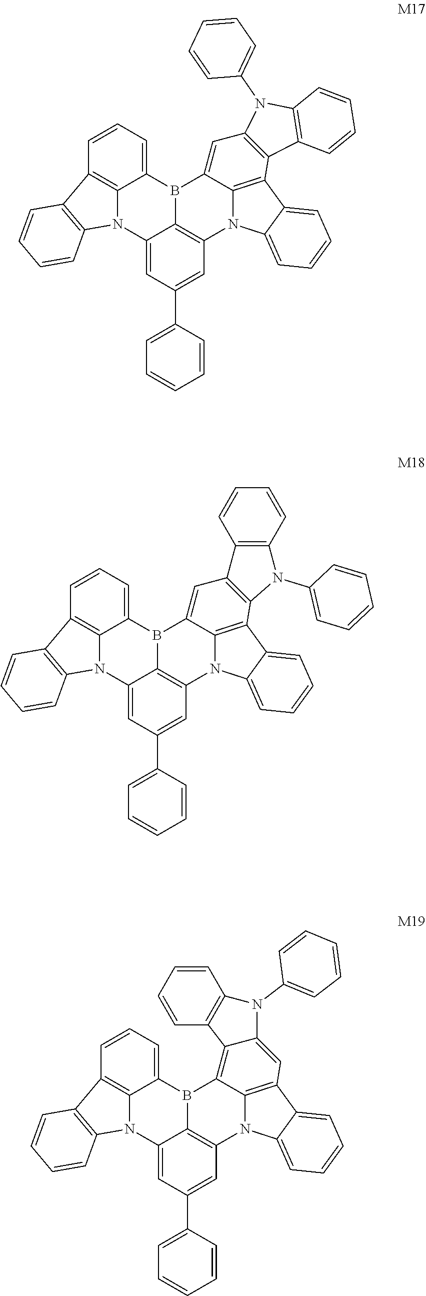 [SMILES: c1ccc(-c2cc3c4c(c2)-n2c5ccccc5c5c6c7ccccc7n(-c7ccccc7)c6cc(c52)B4c2cccc4c5ccccc5n-3c24)cc1 ; c1ccc(-c2cc3c4c(c2)-n2c5ccccc5c5c2c(cc2c6ccccc6n(-c6ccccc6)c25)B4c2cccc4c5ccccc5n-3c24)cc1 ; c1ccc(-c2cc3c4c(c2)-n2c5ccccc5c5cc6c(c(c52)B4c2cccc4c5ccccc5n-3c24)c2ccccc2n6-c2ccccc2)cc1]

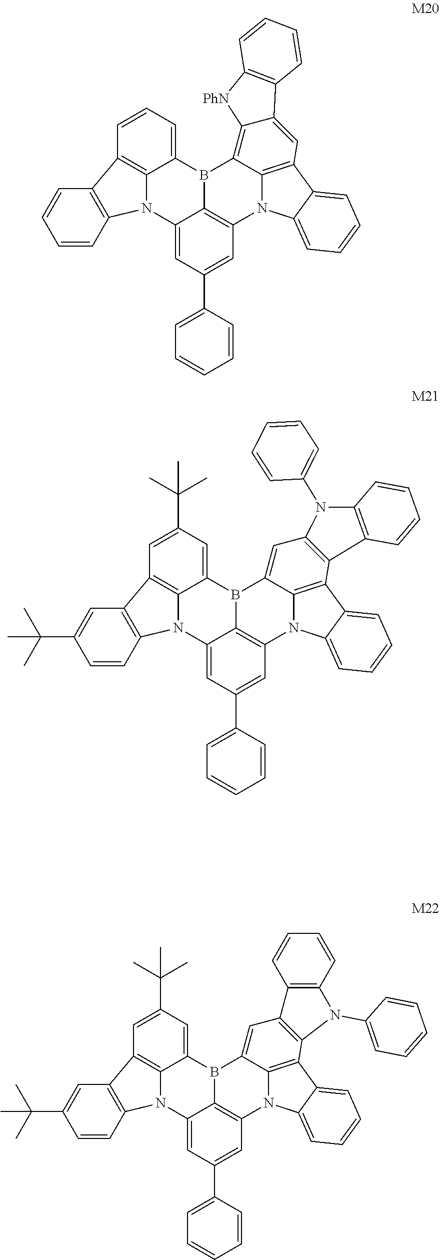

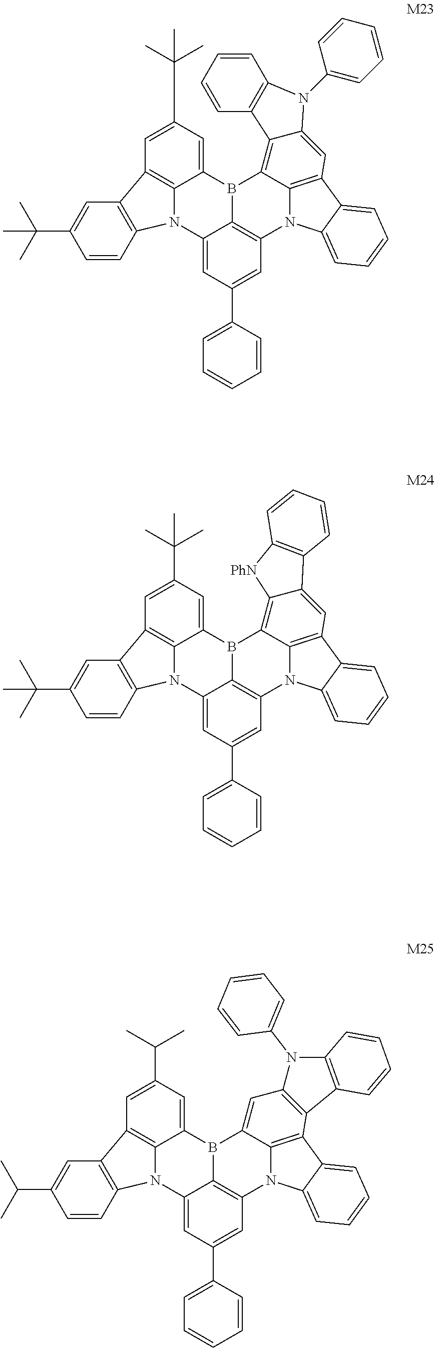

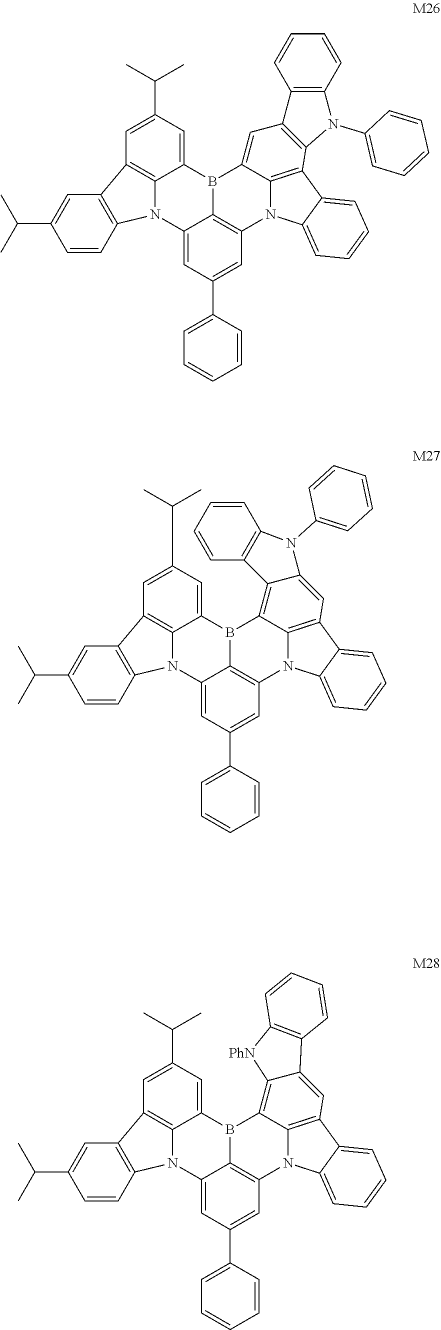

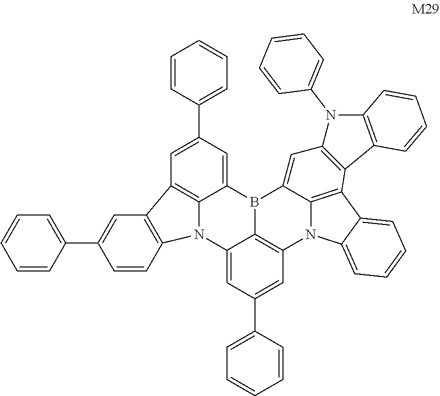 [SMILES: c1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc1]

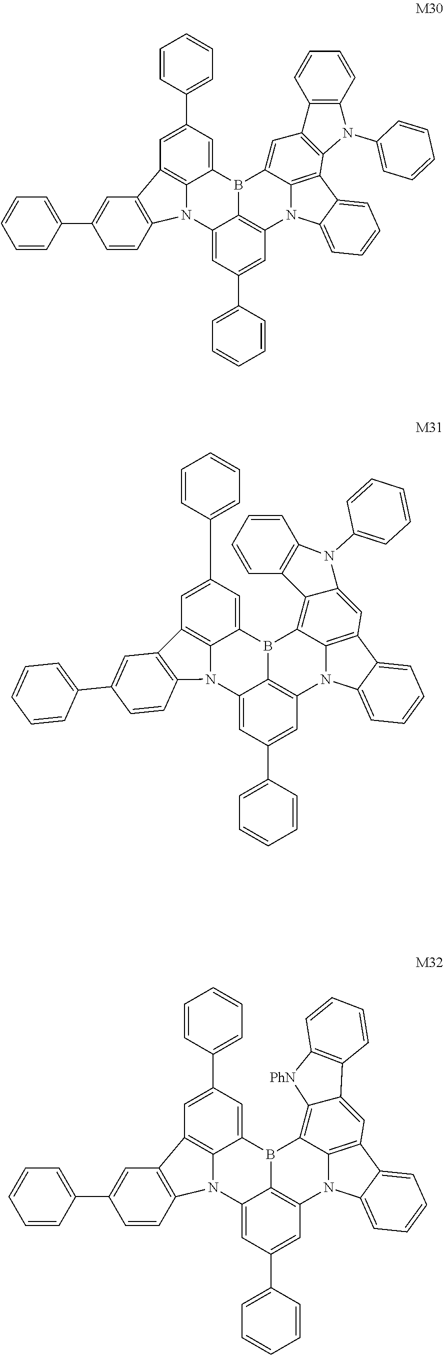

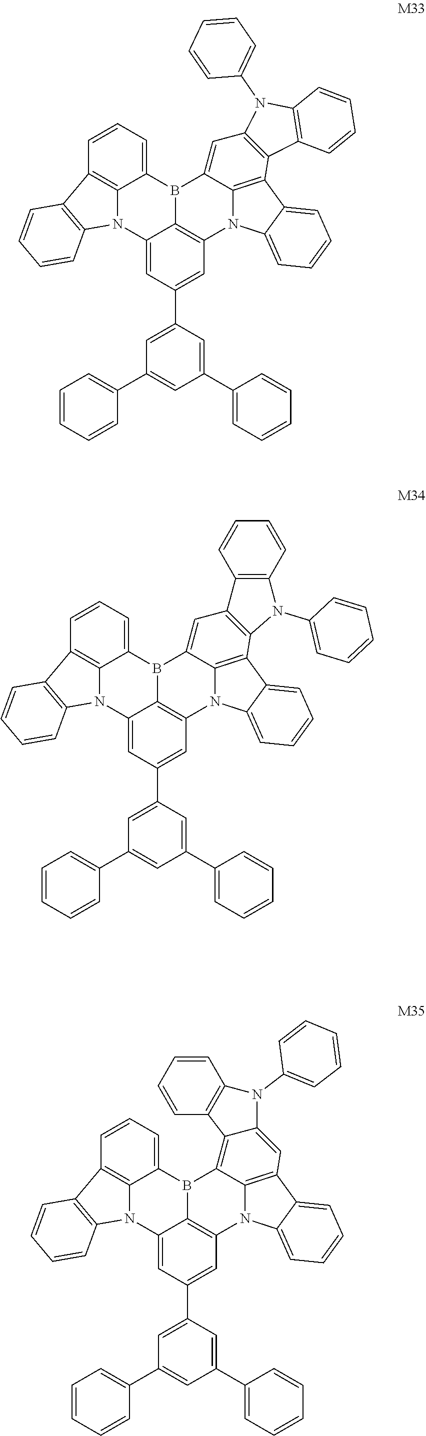 [SMILES: c1ccc(-c2cc(-c3ccccc3)cc(-c3cc4c5c(c3)-n3c6ccccc6c6c7c8ccccc8n(-c8ccccc8)c7cc(c63)B5c3cccc5c6ccccc6n-4c35)c2)cc1 ; c1ccc(-c2cc(-c3ccccc3)cc(-c3cc4c5c(c3)-n3c6ccccc6c6c3c(cc3c7ccccc7n(-c7ccccc7)c36)B5c3cccc5c6ccccc6n-4c35)c2)cc1 ; c1ccc(-c2cc(-c3ccccc3)cc(-c3cc4c5c(c3)-n3c6ccccc6c6cc7c(c(c63)B5c3cccc5c6ccccc6n-4c35)c3ccccc3n7-c3ccccc3)c2)cc1]

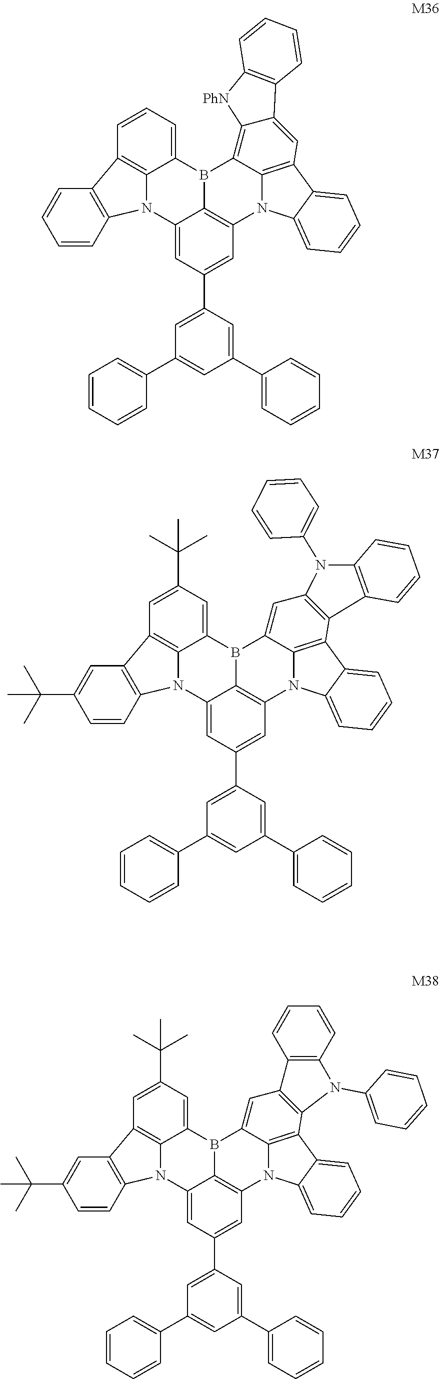

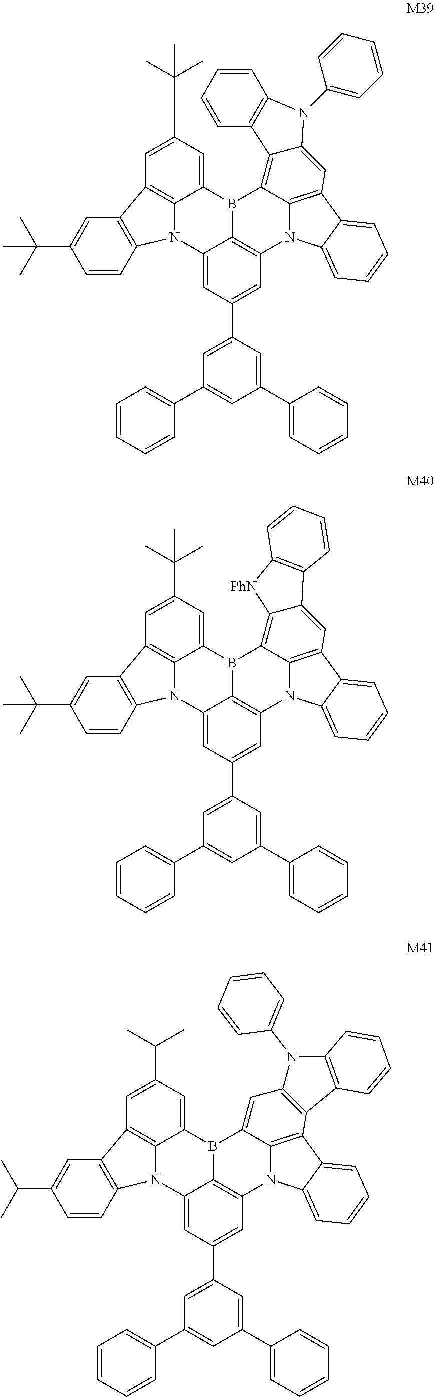

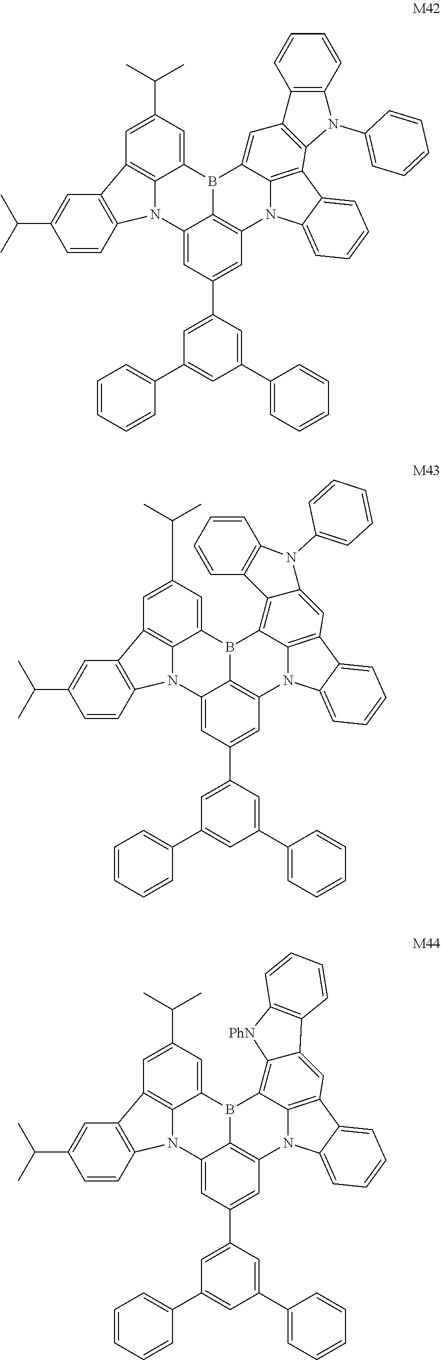

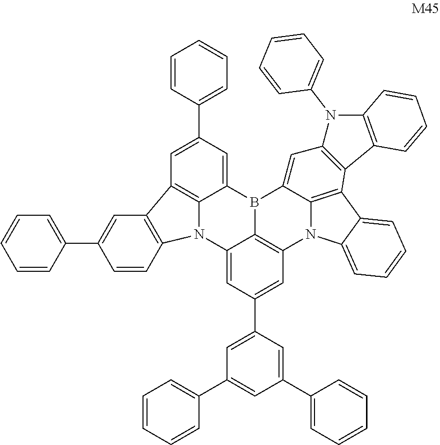 [SMILES: c1ccc(-c2cc(-c3ccccc3)cc(-c3cc4c5c(c3)-n3c6ccccc6c6c7c8ccccc8n(-c8ccccc8)c7cc(c63)B5c3cc(-c5ccccc5)cc5c6cc(-c7ccccc7)ccc6n-4c35)c2)cc1]

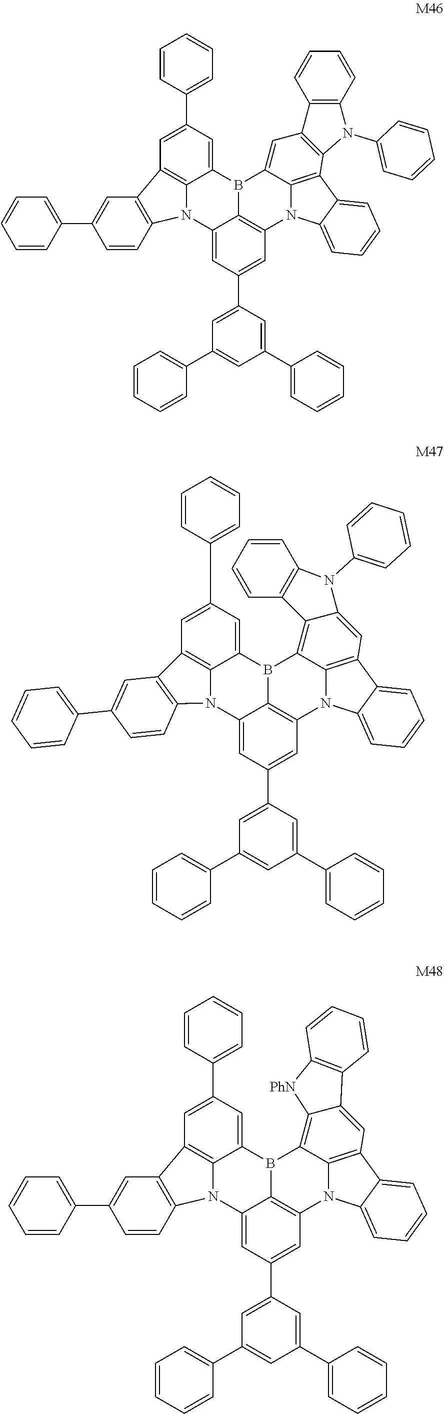

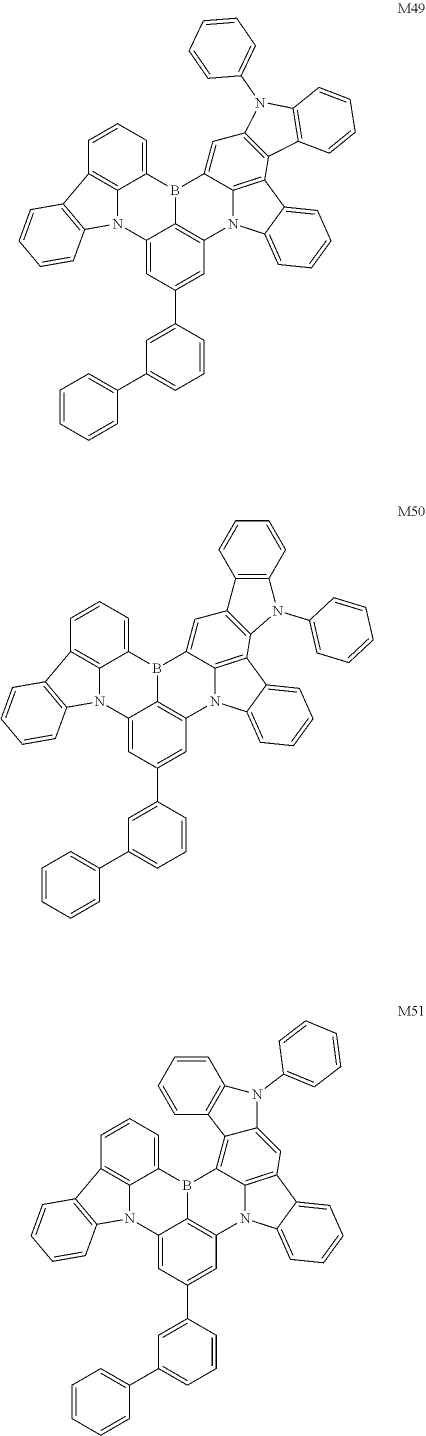 [SMILES: c1ccc(-c2cccc(-c3cc4c5c(c3)-n3c6ccccc6c6c7c8ccccc8n(-c8ccccc8)c7cc(c63)B5c3cccc5c6ccccc6n-4c35)c2)cc1 ; c1ccc(-c2cccc(-c3cc4c5c(c3)-n3c6ccccc6c6c3c(cc3c7ccccc7n(-c7ccccc7)c36)B5c3cccc5c6ccccc6n-4c35)c2)cc1 ; c1ccc(-c2cccc(-c3cc4c5c(c3)-n3c6ccccc6c6cc7c(c(c63)B5c3cccc5c6ccccc6n-4c35)c3ccccc3n7-c3ccccc3)c2)cc1]

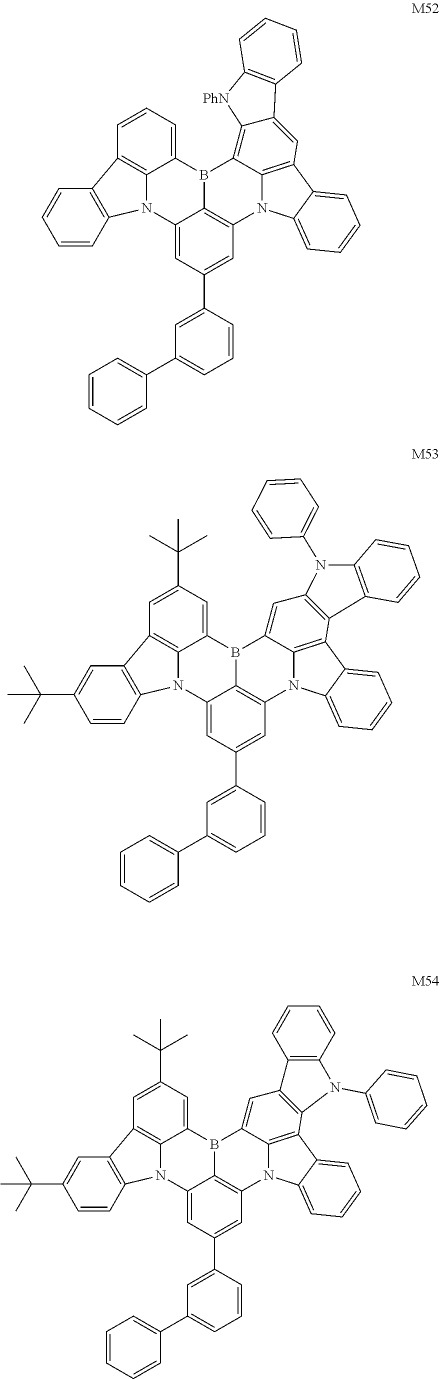

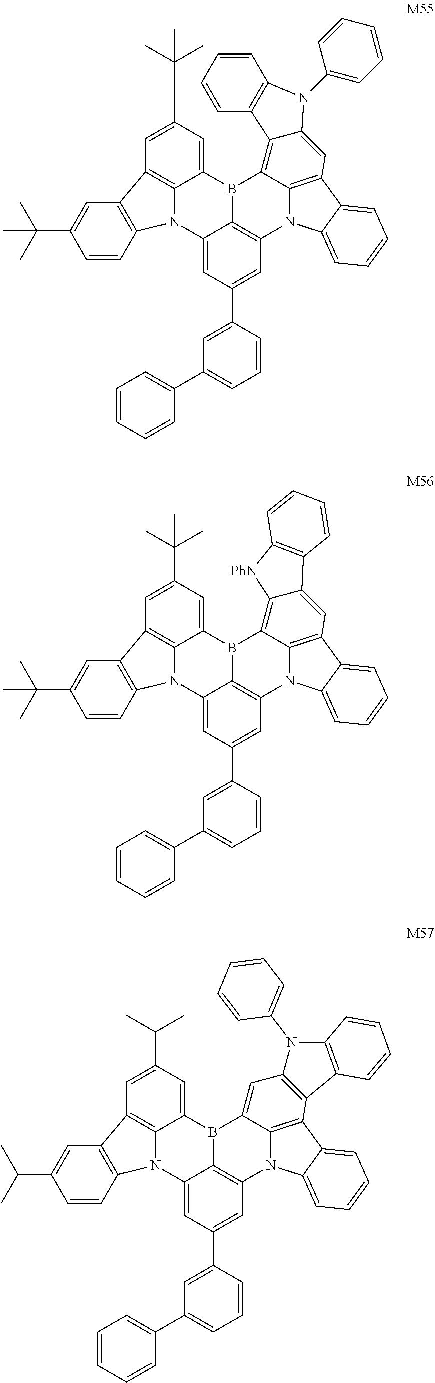

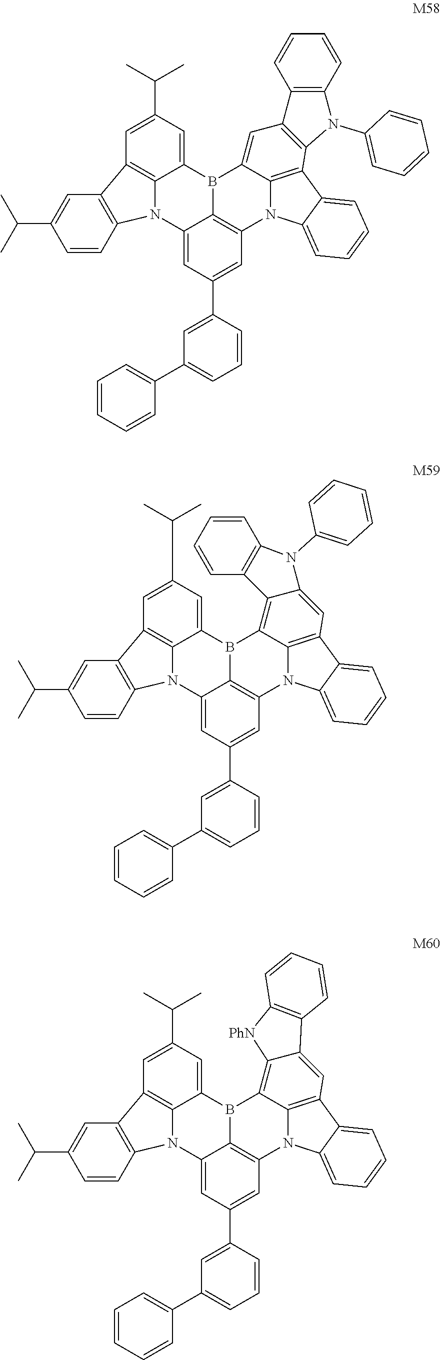

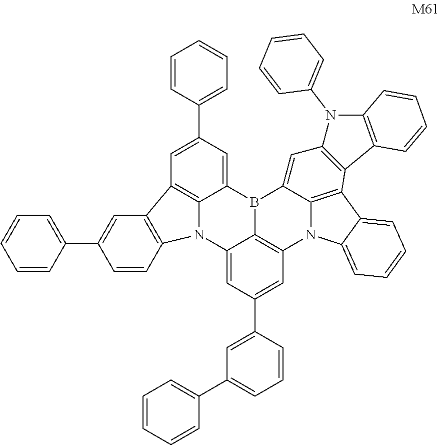 [SMILES: c1ccc(-c2cccc(-c3cc4c5c(c3)-n3c6ccccc6c6c7c8ccccc8n(-c8ccccc8)c7cc(c63)B5c3cc(-c5ccccc5)cc5c6cc(-c7ccccc7)ccc6n-4c35)c2)cc1]

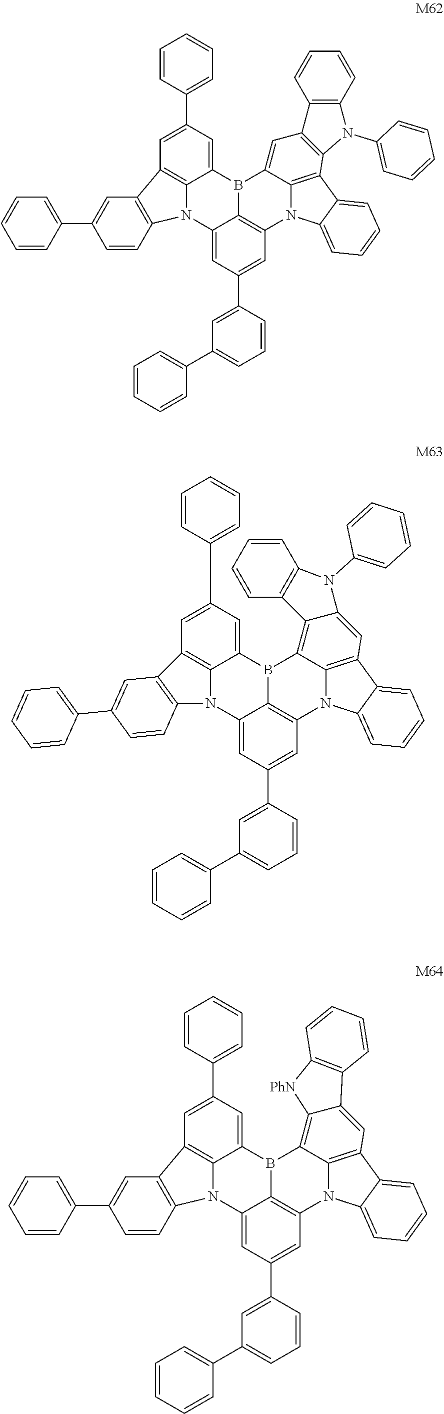

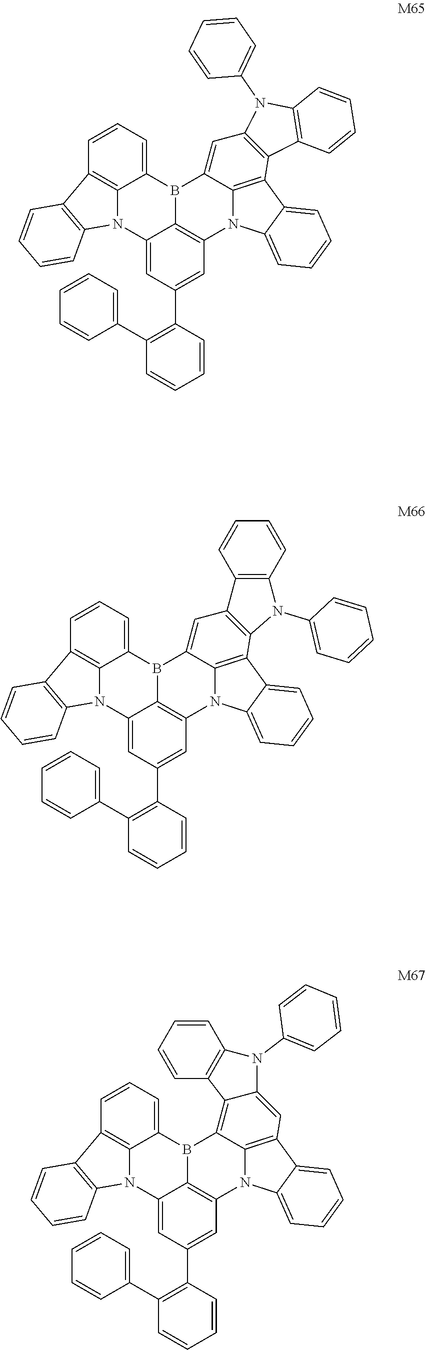 [SMILES: c1ccc(-c2ccccc2-c2cc3c4c(c2)-n2c5ccccc5c5c6c7ccccc7n(-c7ccccc7)c6cc(c52)B4c2cccc4c5ccccc5n-3c24)cc1 ; c1ccc(-c2ccccc2-c2cc3c4c(c2)-n2c5ccccc5c5c2c(cc2c6ccccc6n(-c6ccccc6)c25)B4c2cccc4c5ccccc5n-3c24)cc1 ; c1ccc(-c2ccccc2-c2cc3c4c(c2)-n2c5ccccc5c5cc6c(c(c52)B4c2cccc4c5ccccc5n-3c24)c2ccccc2n6-c2ccccc2)cc1]

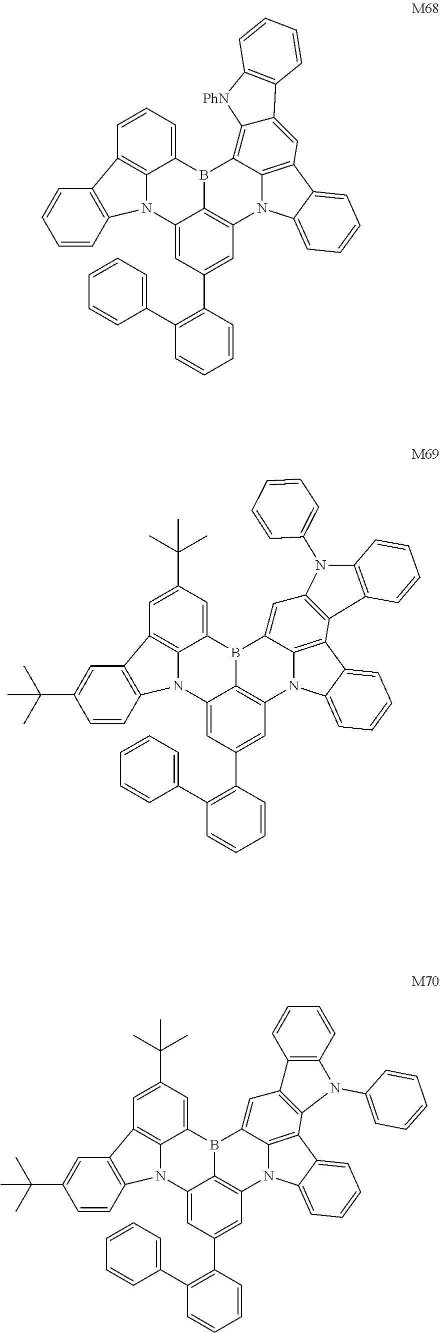

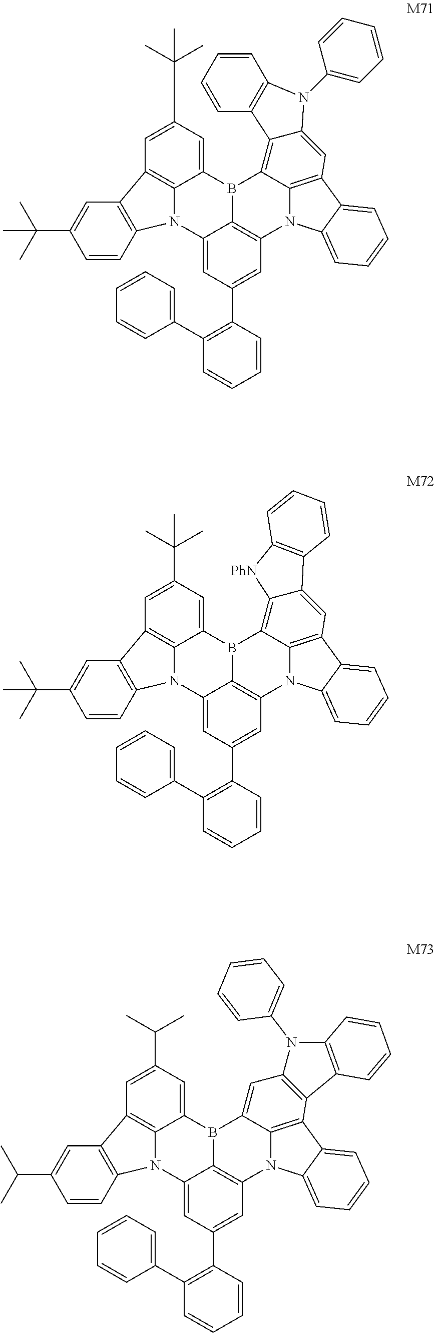

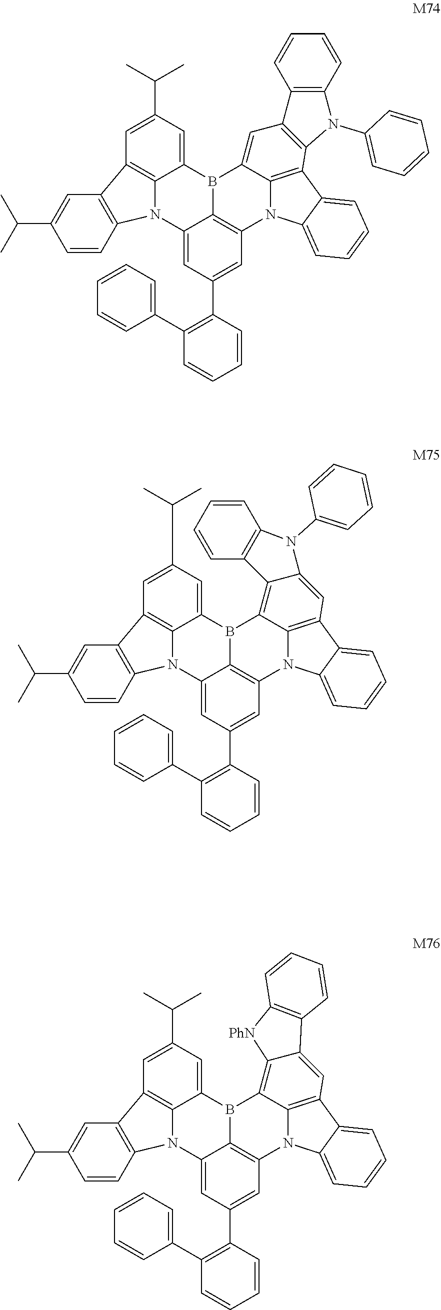

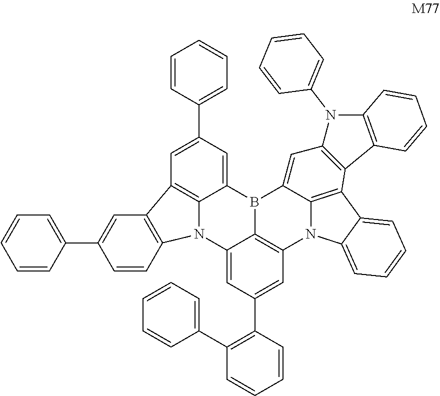 [SMILES: c1ccc(-c2ccc3c(c2)c2cc(-c4ccccc4)cc4c2n3-c2cc(-c3ccccc3-c3ccccc3)cc3c2B4c2cc4c(c5ccccc5n4-c4ccccc4)c4c5ccccc5n-3c24)cc1]

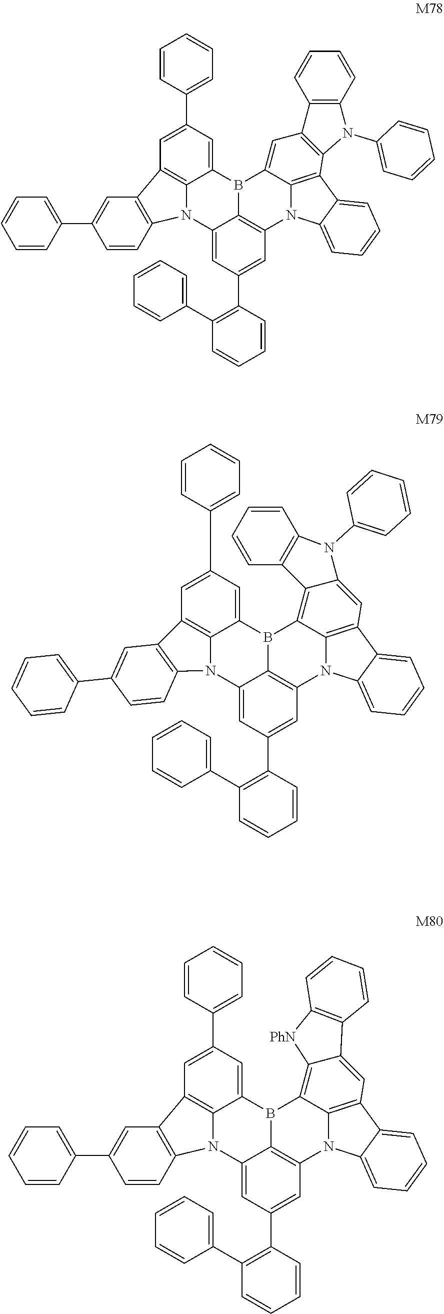

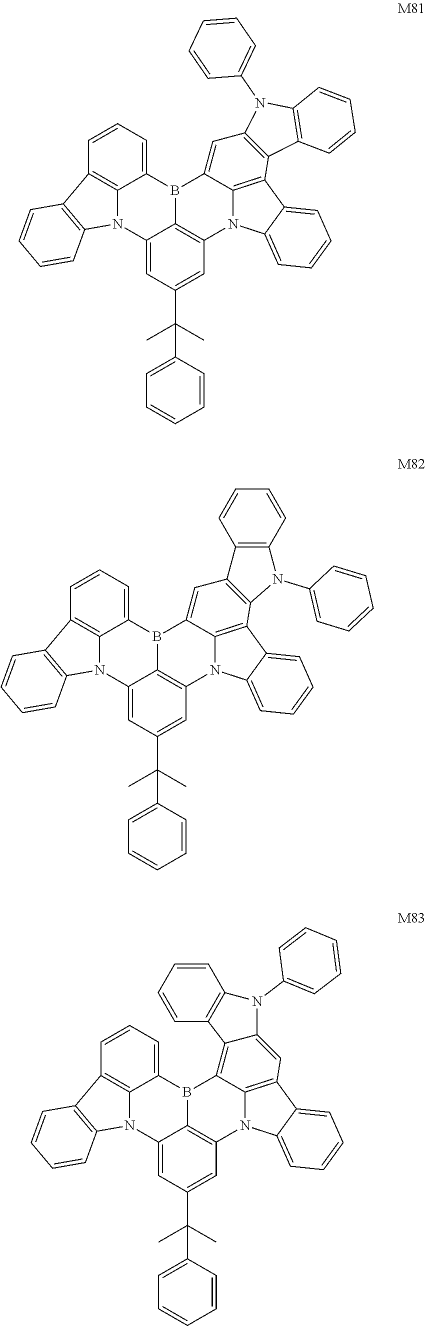 [SMILES: CC(C)(c1ccccc1)c1cc2c3c(c1)-n1c4ccccc4c4c5c6ccccc6n(-c6ccccc6)c5cc(c41)B3c1cccc3c4ccccc4n-2c13 ; CC(C)(c1ccccc1)c1cc2c3c(c1)-n1c4ccccc4c4c1c(cc1c5ccccc5n(-c5ccccc5)c14)B3c1cccc3c4ccccc4n-2c13 ; CC(C)(c1ccccc1)c1cc2c3c(c1)-n1c4ccccc4c4cc5c(c(c41)B3c1cccc3c4ccccc4n-2c13)c1ccccc1n5-c1ccccc1]

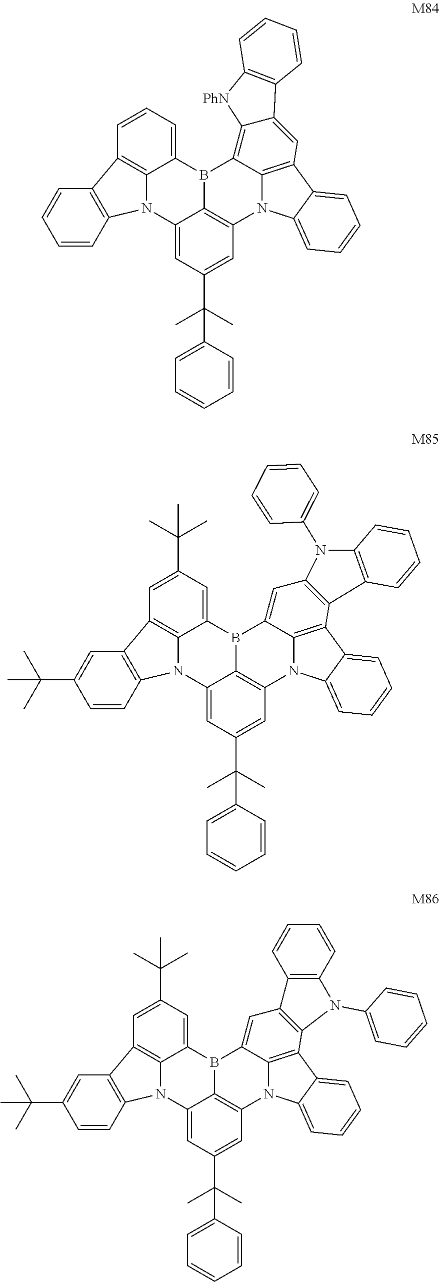

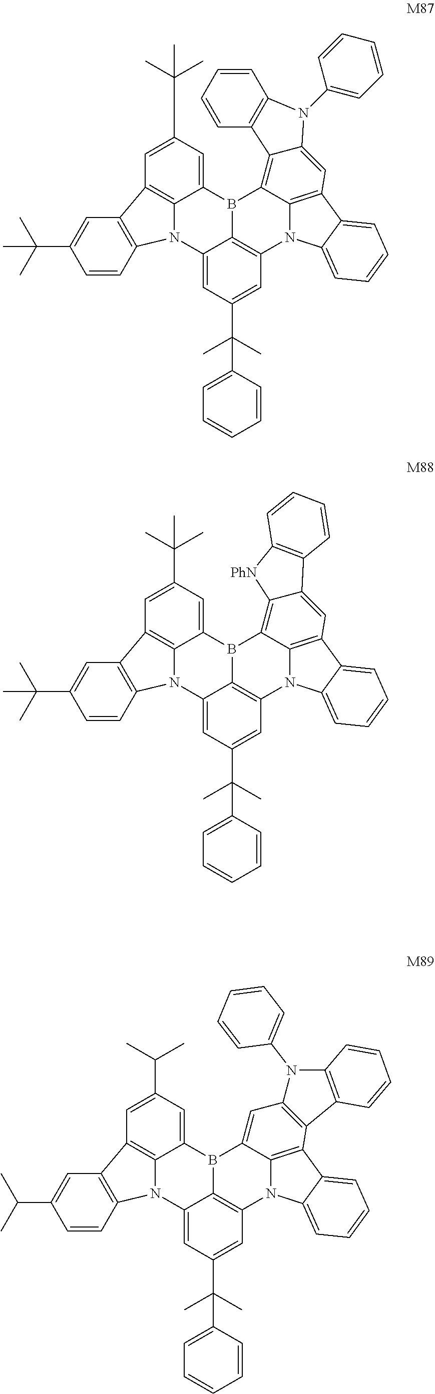

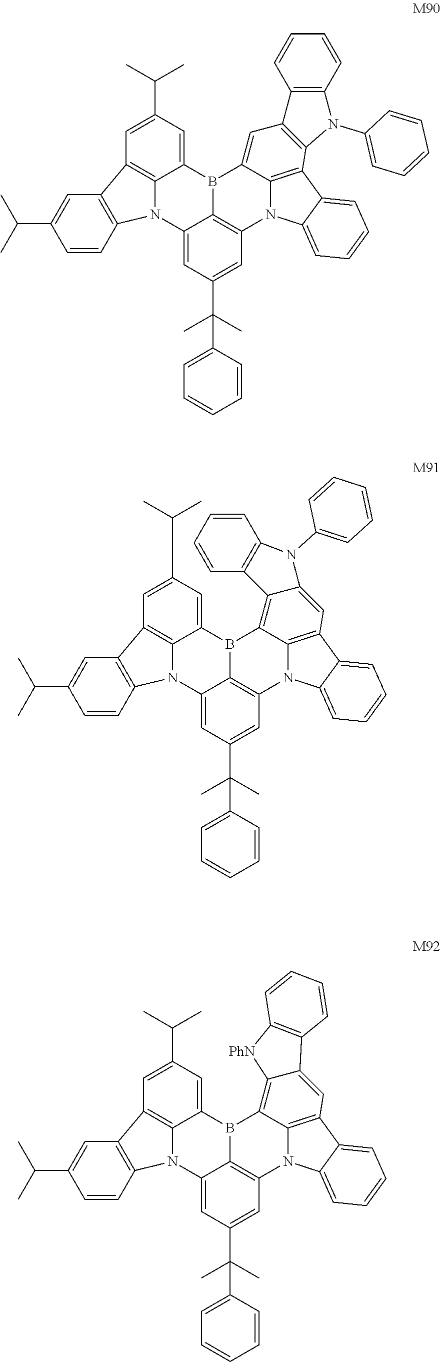

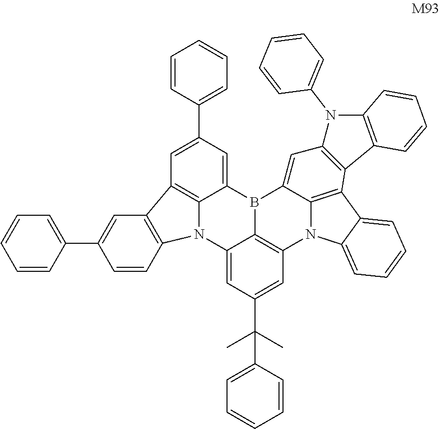 [SMILES: CC(C)(c1ccccc1)c1cc2c3c(c1)-n1c4ccccc4c4c5c6ccccc6n(-c6ccccc6)c5cc(c41)B3c1cc(-c3ccccc3)cc3c4cc(-c5ccccc5)ccc4n-2c13]

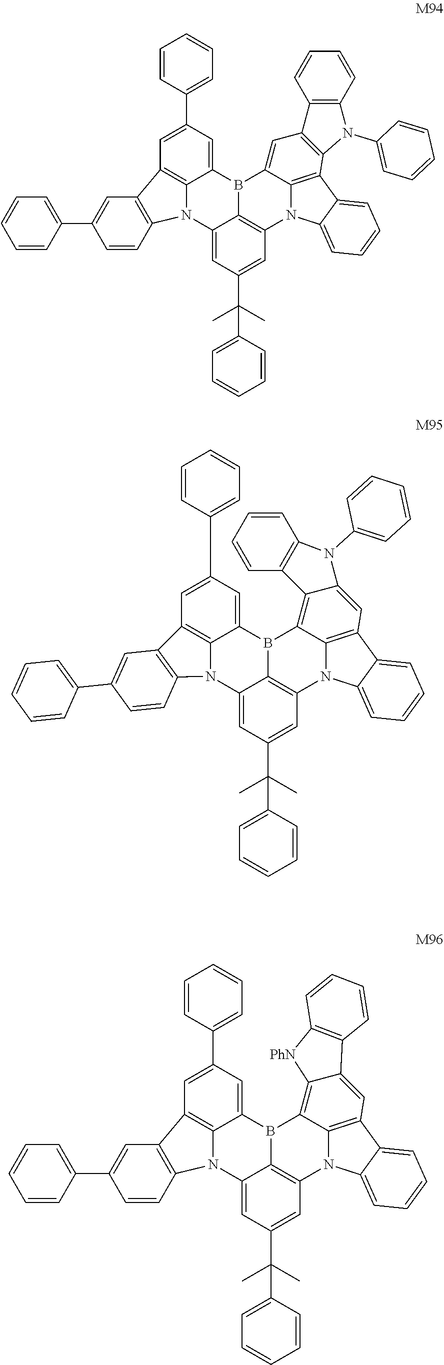

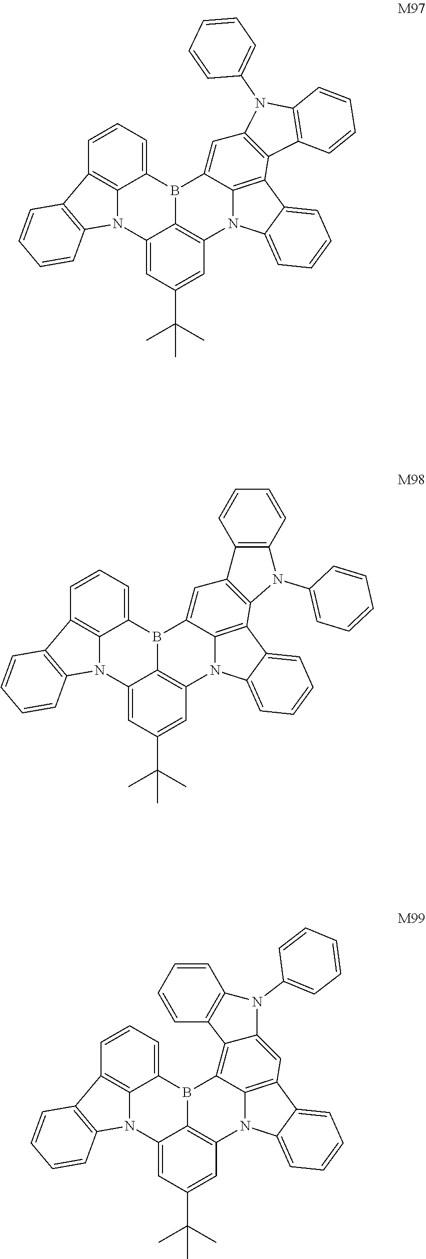 [SMILES: CC(C)(C)c1cc2c3c(c1)-n1c4ccccc4c4c5c6ccccc6n(-c6ccccc6)c5cc(c41)B3c1cccc3c4ccccc4n-2c13 ; CC(C)(C)c1cc2c3c(c1)-n1c4ccccc4c4c1c(cc1c5ccccc5n(-c5ccccc5)c14)B3c1cccc3c4ccccc4n-2c13 ; CC(C)(C)c1cc2c3c(c1)-n1c4ccccc4c4cc5c(c(c41)B3c1cccc3c4ccccc4n-2c13)c1ccccc1n5-c1ccccc1]

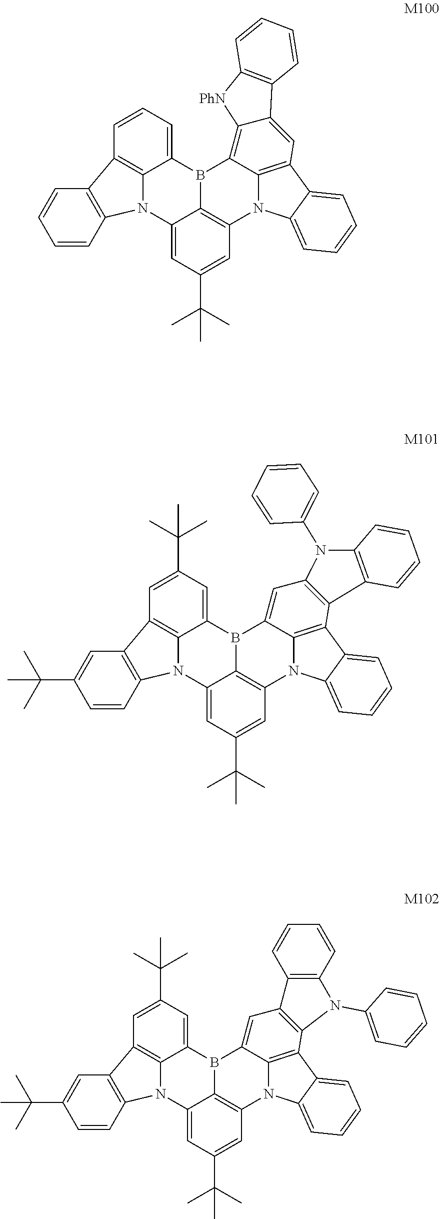

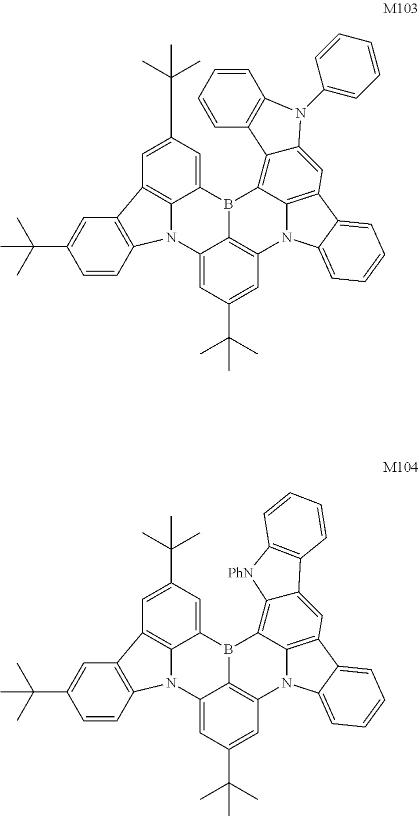

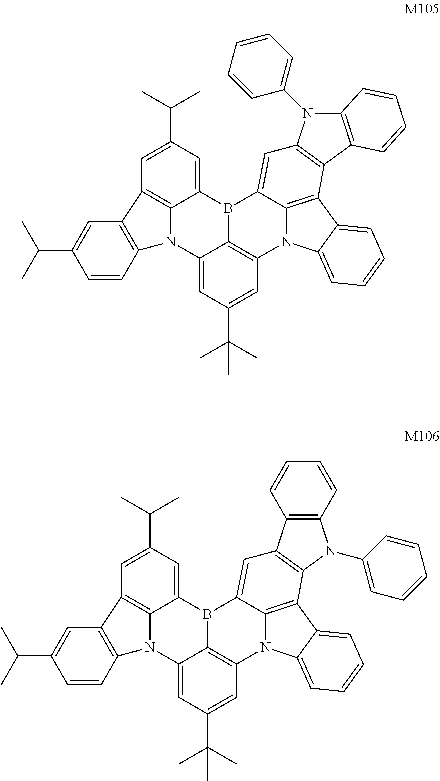 [SMILES: CC(C)c1ccc2c(c1)c1cc(C(C)C)cc3c1n2-c1cc(C(C)(C)C)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(C(C)(C)C)cc2c1B3c1cc3c4ccccc4n(-c4ccccc4)c3c3c4ccccc4n-2c13]

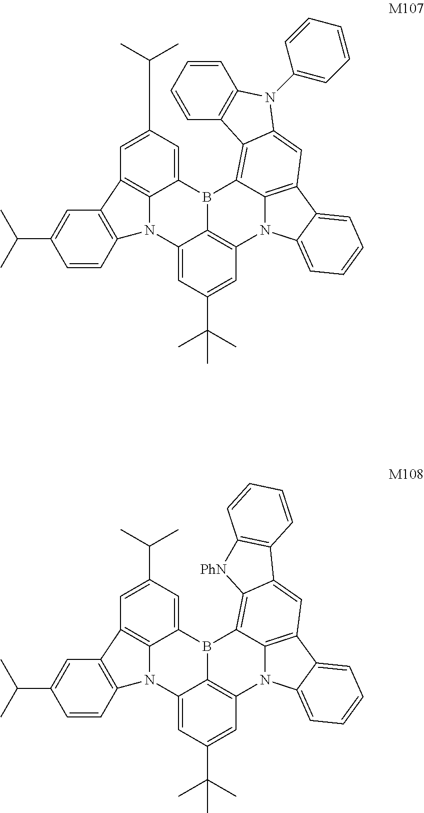

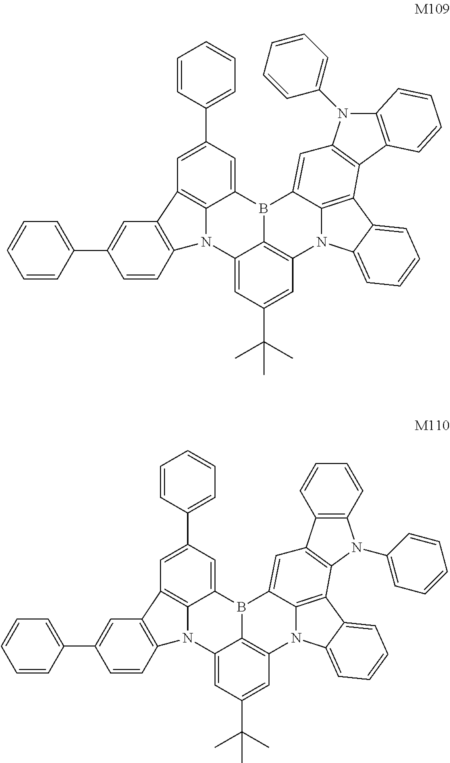 [SMILES: CC(C)(C)c1cc2c3c(c1)-n1c4ccccc4c4c5c6ccccc6n(-c6ccccc6)c5cc(c41)B3c1cc(-c3ccccc3)cc3c4cc(-c5ccccc5)ccc4n-2c13 ; CC(C)(C)c1cc2c3c(c1)-n1c4ccccc4c4c1c(cc1c5ccccc5n(-c5ccccc5)c14)B3c1cc(-c3ccccc3)cc3c4cc(-c5ccccc5)ccc4n-2c13]

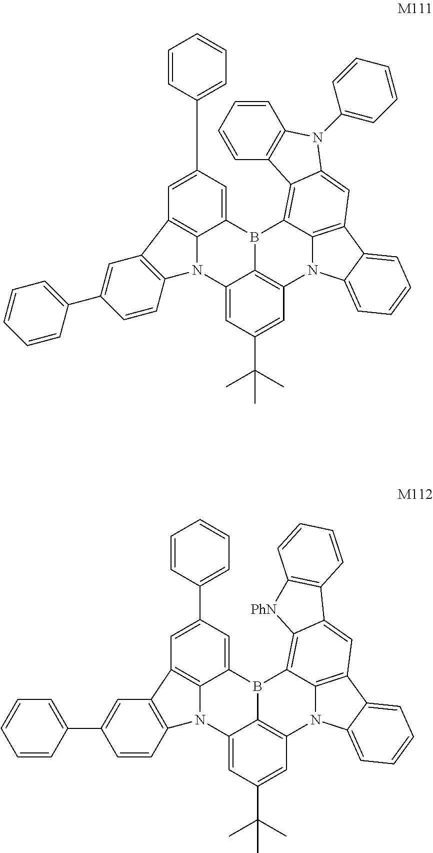

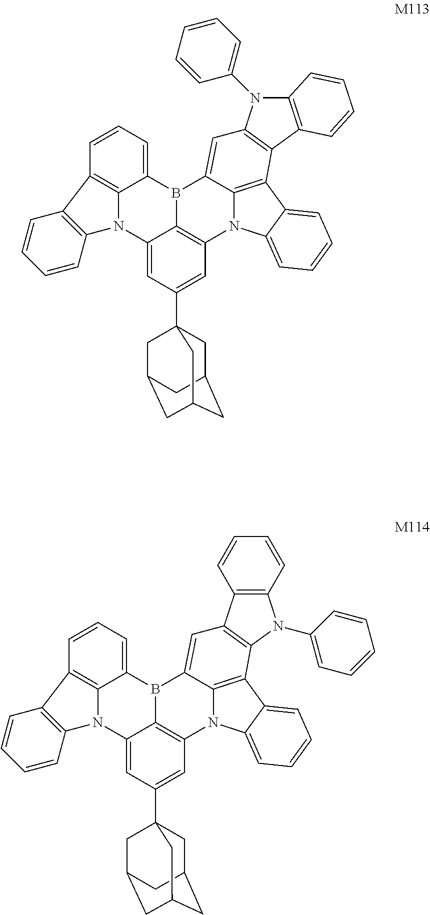 [SMILES: c1ccc(-n2c3ccccc3c3c4c5ccccc5n5c4c(cc32)B2c3c(cc(C46CC7CC(CC(C7)C4)C6)cc3-5)-n3c4ccccc4c4cccc2c43)cc1 ; c1ccc(-n2c3ccccc3c3cc4c5c(c6ccccc6n5-c5cc(C67CC8CC(CC(C8)C6)C7)cc6c5B4c4cccc5c7ccccc7n-6c45)c32)cc1]

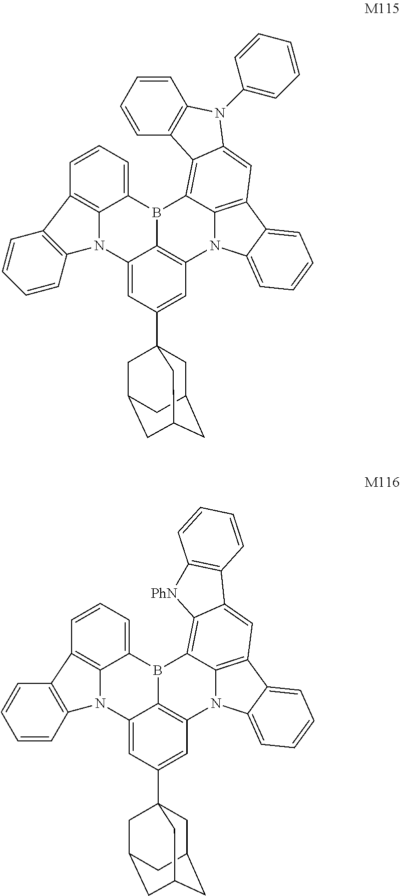

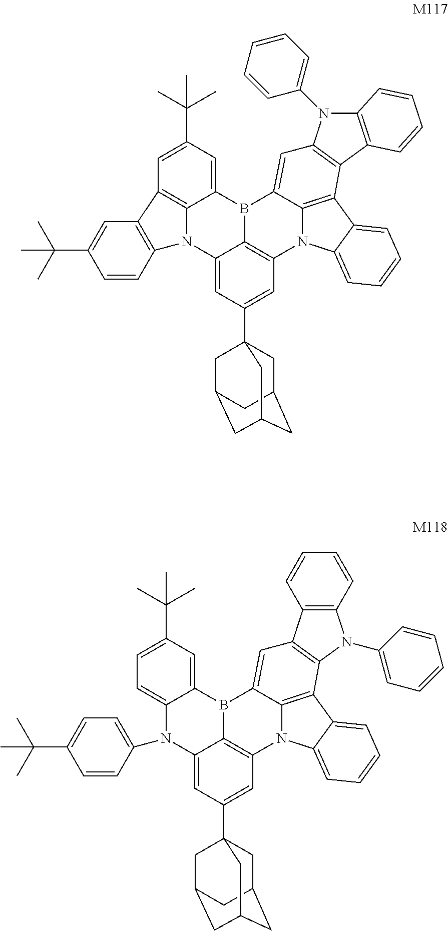 [SMILES: CC(C)(C)c1ccc2c(c1)c1cc(C(C)(C)C)cc3c1n2-c1cc(C24CC5CC(CC(C5)C2)C4)cc2c1B3c1cc3c(c4ccccc4n3-c3ccccc3)c3c4ccccc4n-2c13 ; CC(C)(C)c1ccc(N2c3ccc(C(C)(C)C)cc3B3c4c2cc(C25CC6CC(CC(C6)C2)C5)cc4-n2c4ccccc4c4c2c3cc2c3ccccc3n(-c3ccccc3)c24)cc1]

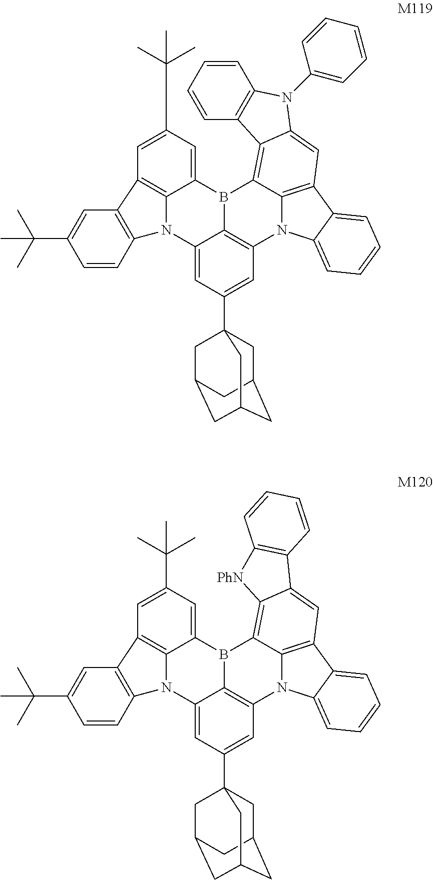

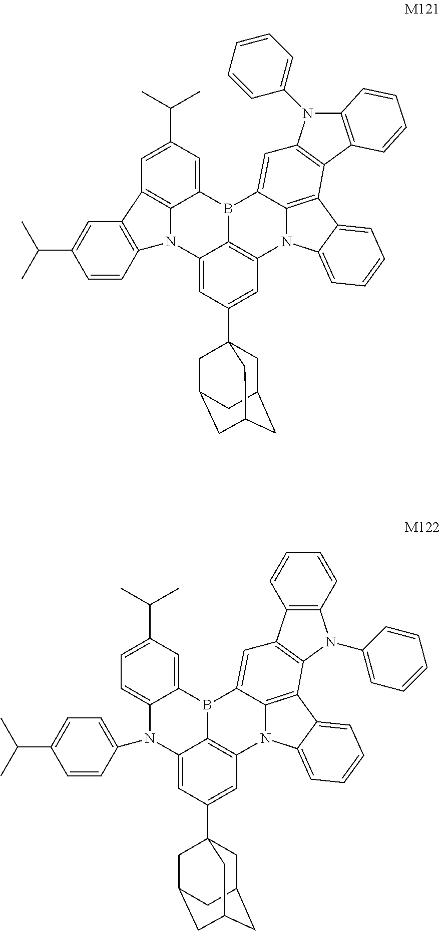 [SMILES: CC(C)c1ccc2c(c1)c1cc(C(C)C)cc3c1n2-c1cc(C24CC5CC(CC(C5)C2)C4)cc2c1B3c1cc3c(c4ccccc4n3-c3ccccc3)c3c4ccccc4n-2c13 ; CC(C)c1ccc(N2c3ccc(C(C)C)cc3B3c4c2cc(C25CC6CC(CC(C6)C2)C5)cc4-n2c4ccccc4c4c2c3cc2c3ccccc3n(-c3ccccc3)c24)cc1]

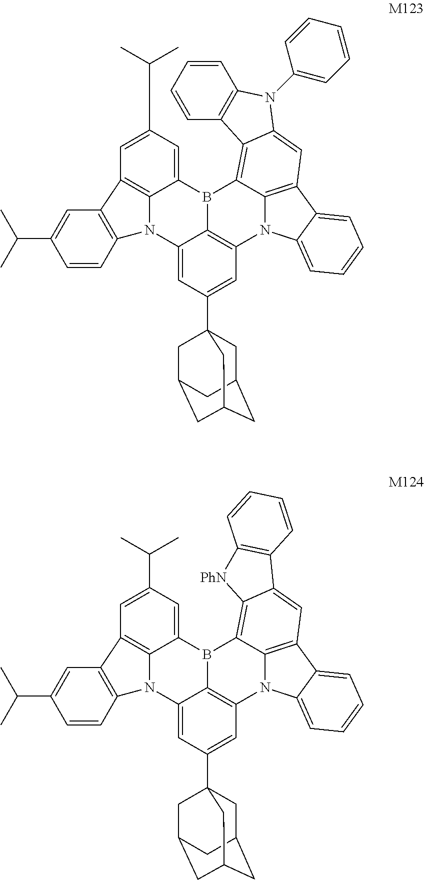

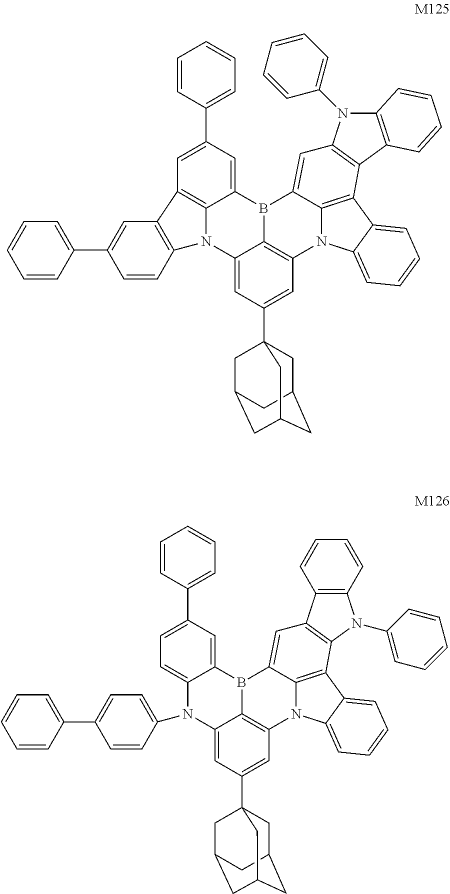 [SMILES: c1ccc(-c2ccc3c(c2)c2cc(-c4ccccc4)cc4c2n3-c2cc(C35CC6CC(CC(C6)C3)C5)cc3c2B4c2cc4c(c5ccccc5n4-c4ccccc4)c4c5ccccc5n-3c24)cc1 ; c1ccc(-c2ccc(N3c4ccc(-c5ccccc5)cc4B4c5c3cc(C36CC7CC(CC(C7)C3)C6)cc5-n3c5ccccc5c5c3c4cc3c4ccccc4n(-c4ccccc4)c35)cc2)cc1]

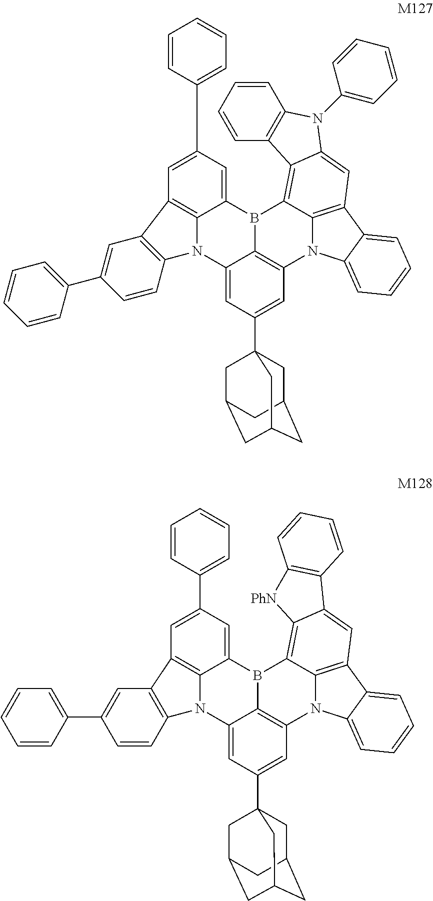

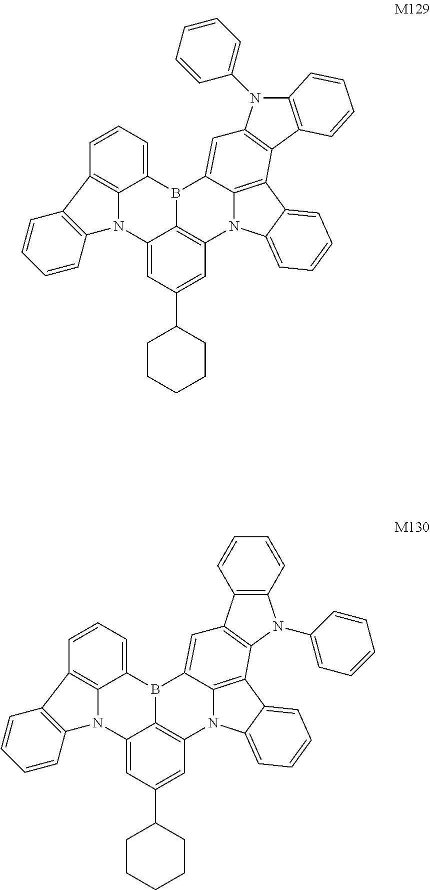 [SMILES: c1ccc(-n2c3ccccc3c3c4c5ccccc5n5c4c(cc32)B2c3c(cc(C4CCCCC4)cc3-5)-n3c4ccccc4c4cccc2c43)cc1 ; c1ccc(-n2c3ccccc3c3cc4c5c(c6ccccc6n5-c5cc(C6CCCCC6)cc6c5B4c4cccc5c7ccccc7n-6c45)c32)cc1]

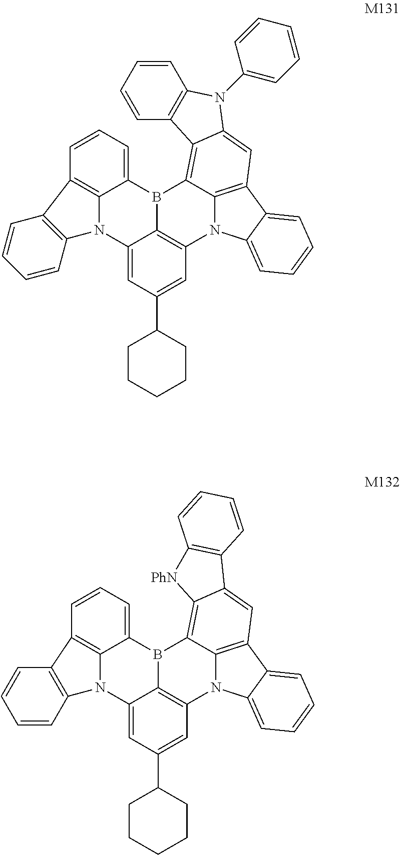

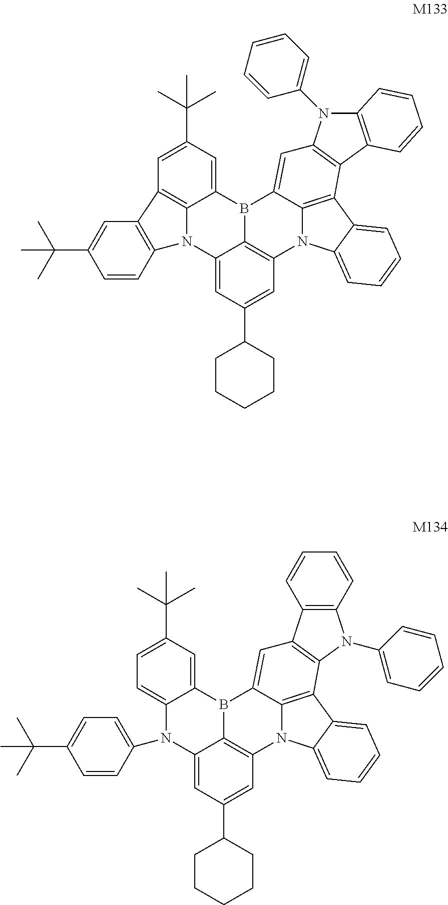 [SMILES: CC(C)(C)c1ccc2c(c1)c1cc(C(C)(C)C)cc3c1n2-c1cc(C2CCCCC2)cc2c1B3c1cc3c(c4ccccc4n3-c3ccccc3)c3c4ccccc4n-2c13 ; CC(C)(C)c1ccc(N2c3ccc(C(C)(C)C)cc3B3c4c2cc(C2CCCCC2)cc4-n2c4ccccc4c4c2c3cc2c3ccccc3n(-c3ccccc3)c24)cc1]

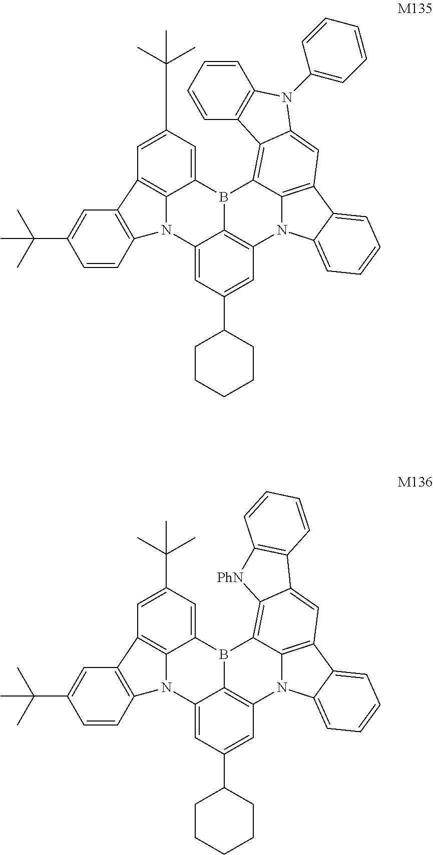

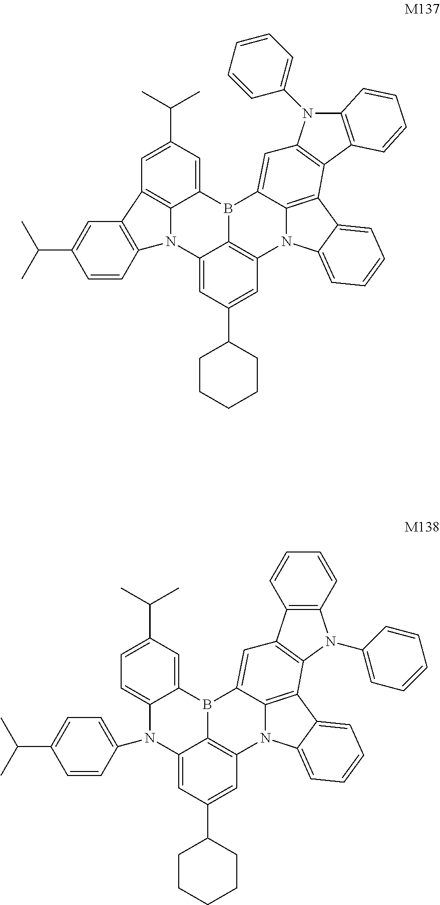 [SMILES: CC(C)c1ccc2c(c1)c1cc(C(C)C)cc3c1n2-c1cc(C2CCCCC2)cc2c1B3c1cc3c(c4ccccc4n3-c3ccccc3)c3c4ccccc4n-2c13 ; CC(C)c1ccc(N2c3ccc(C(C)C)cc3B3c4c2cc(C2CCCCC2)cc4-n2c4ccccc4c4c2c3cc2c3ccccc3n(-c3ccccc3)c24)cc1]

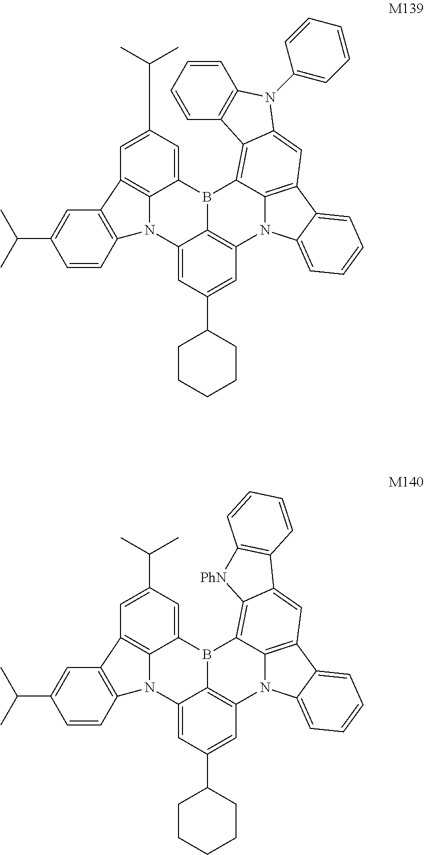

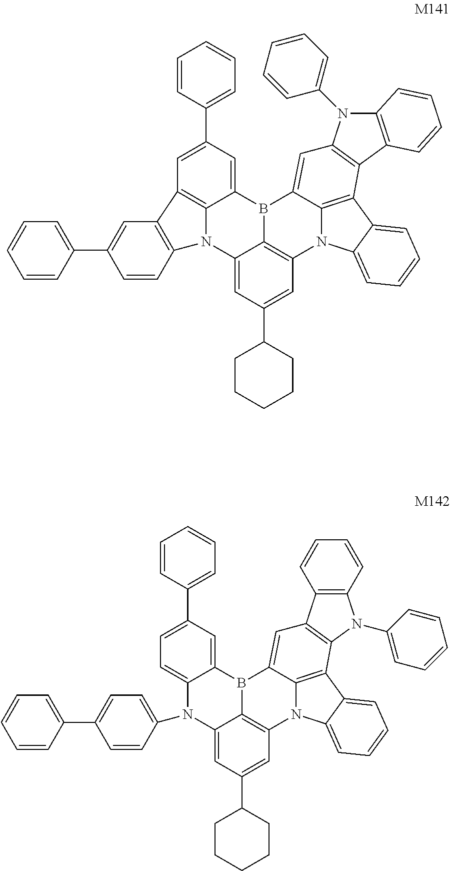 [SMILES: c1ccc(-c2ccc3c(c2)c2cc(-c4ccccc4)cc4c2n3-c2cc(C3CCCCC3)cc3c2B4c2cc4c(c5ccccc5n4-c4ccccc4)c4c5ccccc5n-3c24)cc1 ; c1ccc(-c2ccc(N3c4ccc(-c5ccccc5)cc4B4c5c3cc(C3CCCCC3)cc5-n3c5ccccc5c5c3c4cc3c4ccccc4n(-c4ccccc4)c35)cc2)cc1]

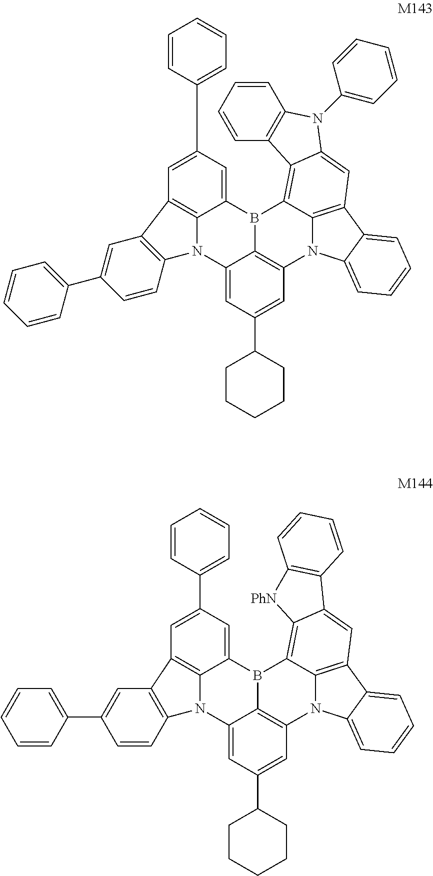

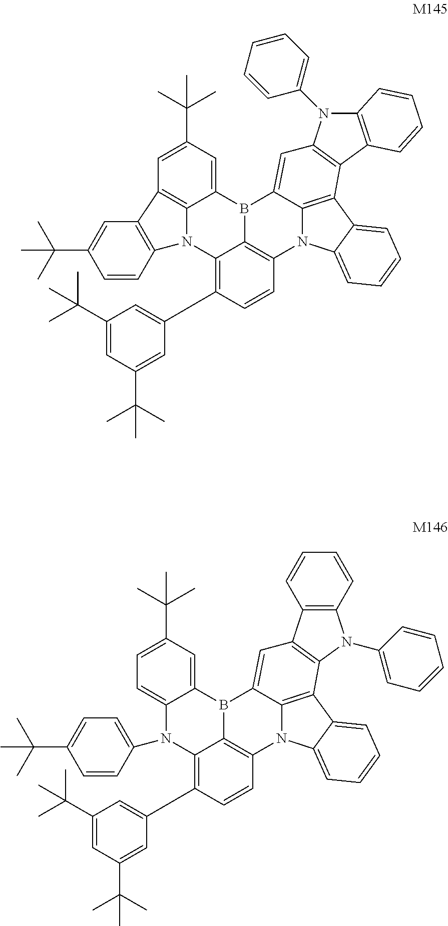 [SMILES: CC(C)(C)c1cc(-c2ccc3c4c2-n2c5ccc(C(C)(C)C)cc5c5cc(C(C)(C)C)cc(c52)B4c2cc4c(c5ccccc5n4-c4ccccc4)c4c5ccccc5n-3c24)cc(C(C)(C)C)c1 ; CC(C)(C)c1ccc(N2c3ccc(C(C)(C)C)cc3B3c4c(ccc(-c5cc(C(C)(C)C)cc(C(C)(C)C)c5)c42)-n2c4ccccc4c4c2c3cc2c3ccccc3n(-c3ccccc3)c24)cc1]

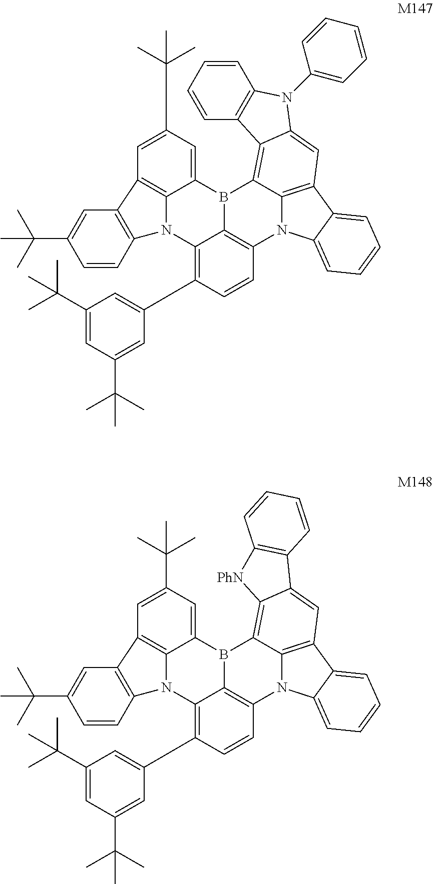

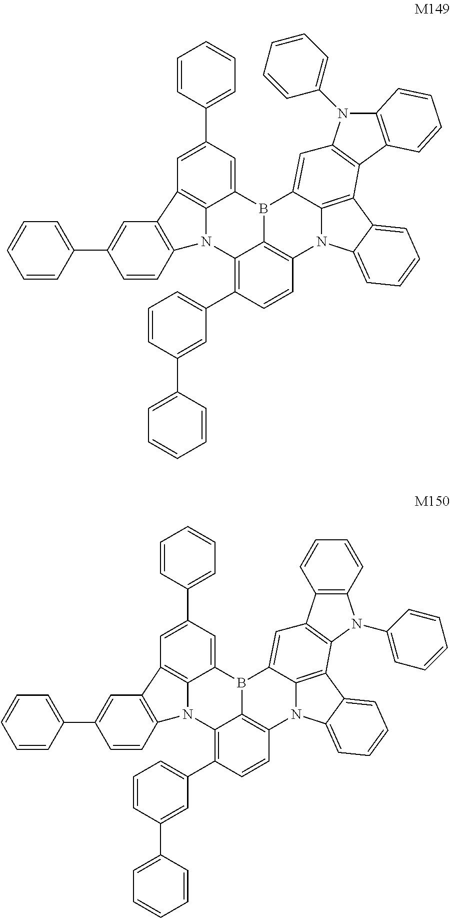 [SMILES: c1ccc(-c2cccc(-c3ccc4c5c3-n3c6ccc(-c7ccccc7)cc6c6cc(-c7ccccc7)cc(c63)B5c3cc5c(c6ccccc6n5-c5ccccc5)c5c6ccccc6n-4c35)c2)cc1 ; c1ccc(-c2cccc(-c3ccc4c5c3-n3c6ccc(-c7ccccc7)cc6c6cc(-c7ccccc7)cc(c63)B5c3cc5c6ccccc6n(-c6ccccc6)c5c5c6ccccc6n-4c35)c2)cc1]

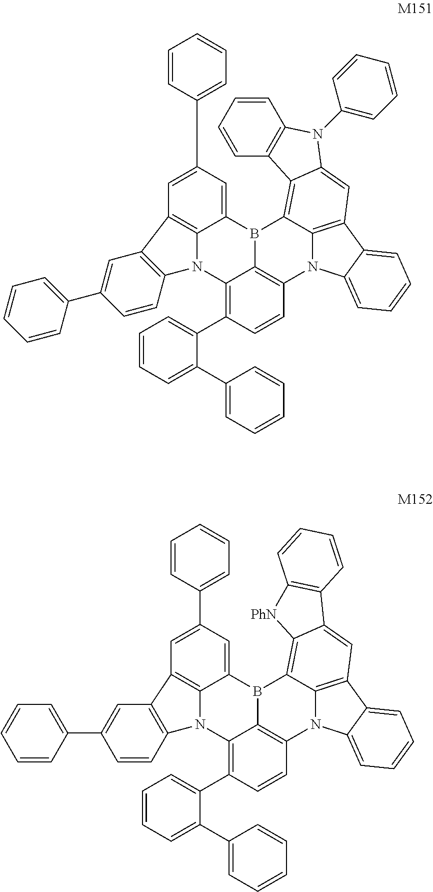

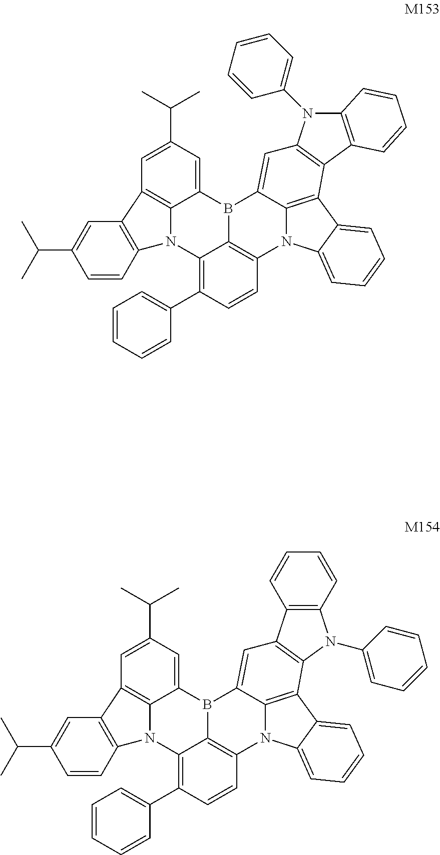 [SMILES: CC(C)c1ccc2c(c1)c1cc(C(C)C)cc3c1n2-c1c(-c2ccccc2)ccc2c1B3c1cc3c(c4ccccc4n3-c3ccccc3)c3c4ccccc4n-2c13 ; CC(C)c1ccc2c(c1)c1cc(C(C)C)cc3c1n2-c1c(-c2ccccc2)ccc2c1B3c1cc3c4ccccc4n(-c4ccccc4)c3c3c4ccccc4n-2c13]

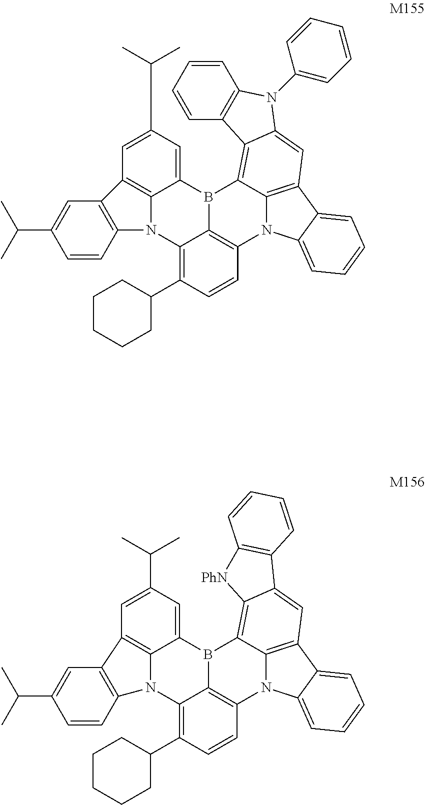

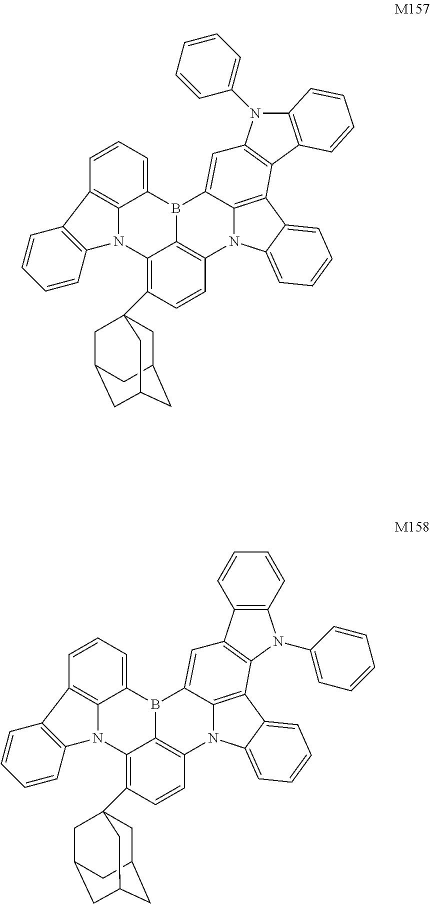 [SMILES: c1ccc(-n2c3ccccc3c3c4c5ccccc5n5c4c(cc32)B2c3c-5ccc(C45CC6CC(CC(C6)C4)C5)c3-n3c4ccccc4c4cccc2c43)cc1 ; c1ccc(-n2c3ccccc3c3cc4c5c(c6ccccc6n5-c5ccc(C67CC8CC(CC(C8)C6)C7)c6c5B4c4cccc5c7ccccc7n-6c45)c32)cc1]

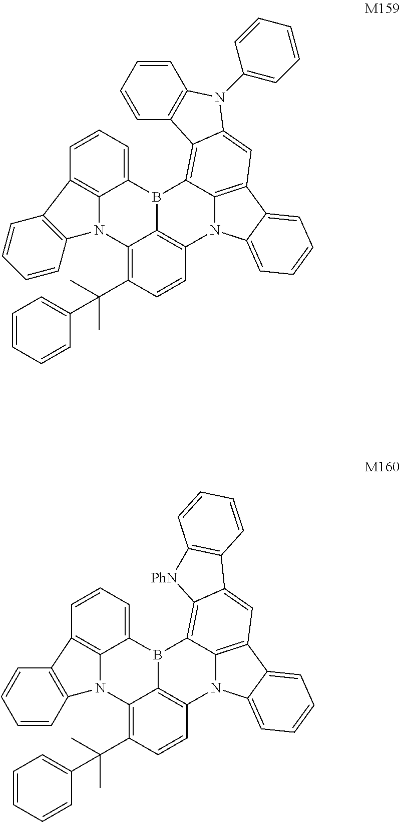

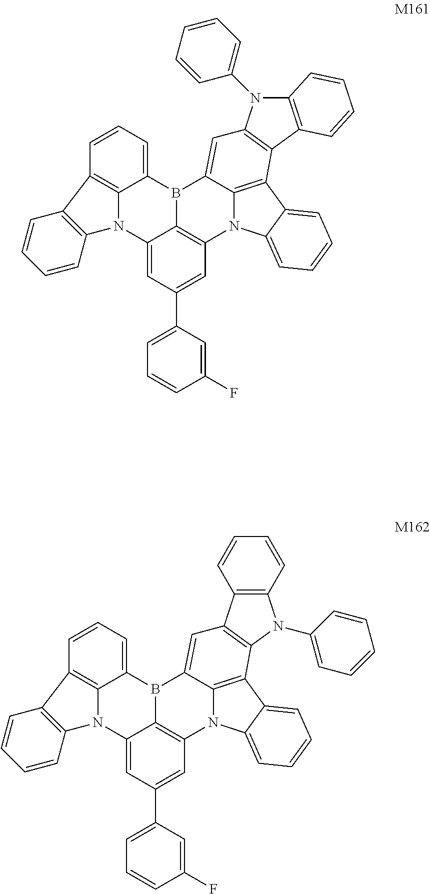 [SMILES: Fc1cccc(-c2cc3c4c(c2)-n2c5ccccc5c5c6c7ccccc7n(-c7ccccc7)c6cc(c52)B4c2cccc4c5ccccc5n-3c24)c1 ; Fc1cccc(-c2cc3c4c(c2)-n2c5ccccc5c5c2c(cc2c6ccccc6n(-c6ccccc6)c25)B4c2cccc4c5ccccc5n-3c24)c1]

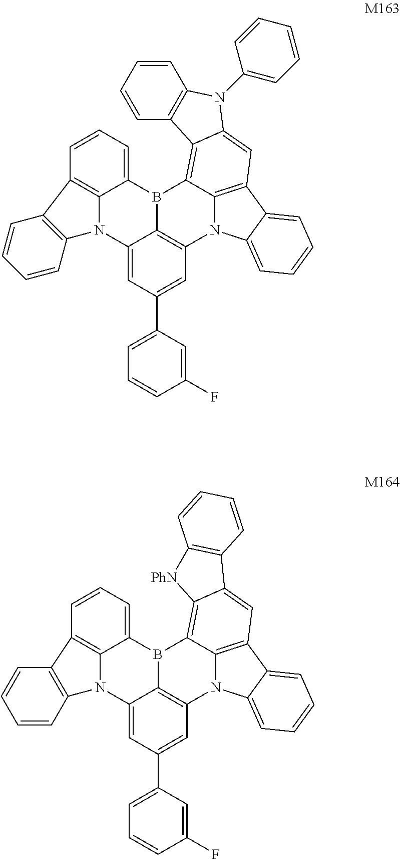

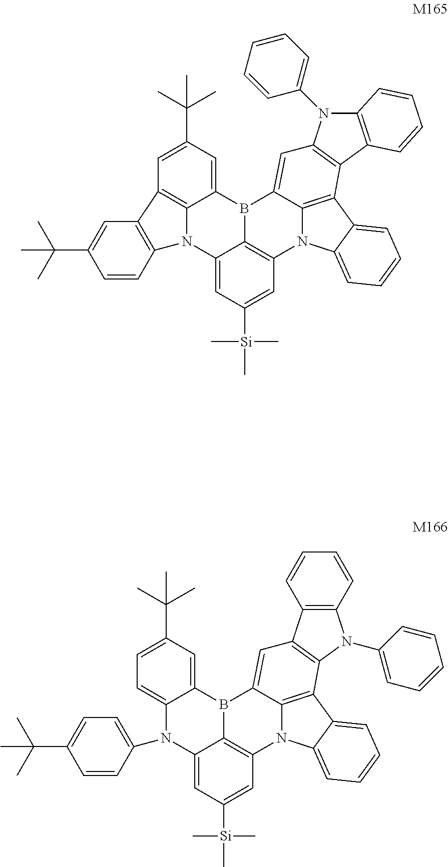 [SMILES: CC(C)(C)c1ccc2c(c1)c1cc(C(C)(C)C)cc3c1n2-c1cc([Si](C)(C)C)cc2c1B3c1cc3c(c4ccccc4n3-c3ccccc3)c3c4ccccc4n-2c13 ; CC(C)(C)c1ccc(N2c3ccc(C(C)(C)C)cc3B3c4c2cc([Si](C)(C)C)cc4-n2c4ccccc4c4c2c3cc2c3ccccc3n(-c3ccccc3)c24)cc1]

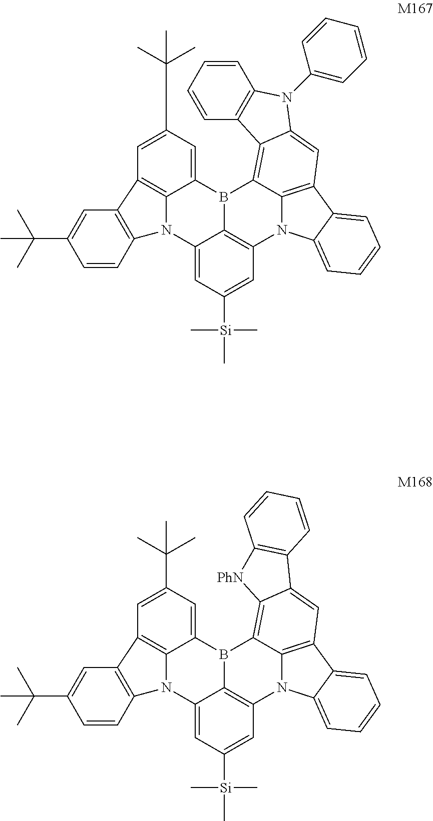

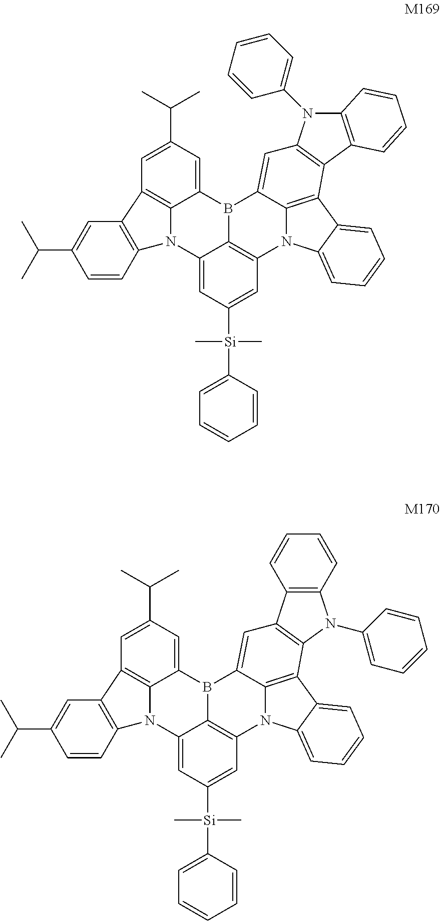 [SMILES: CC(C)c1ccc2c(c1)c1cc(C(C)C)cc3c1n2-c1cc([Si](C)(C)c2ccccc2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc([Si](C)(C)c2ccccc2)cc2c1B3c1cc3c4ccccc4n(-c4ccccc4)c3c3c4ccccc4n-2c13]

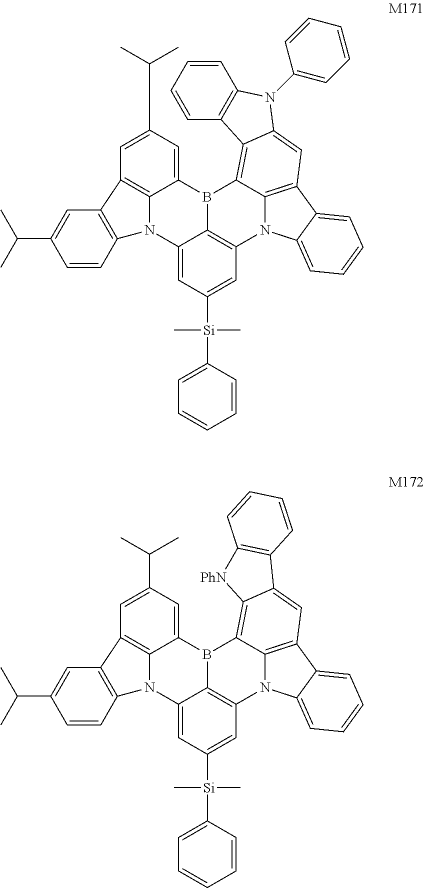

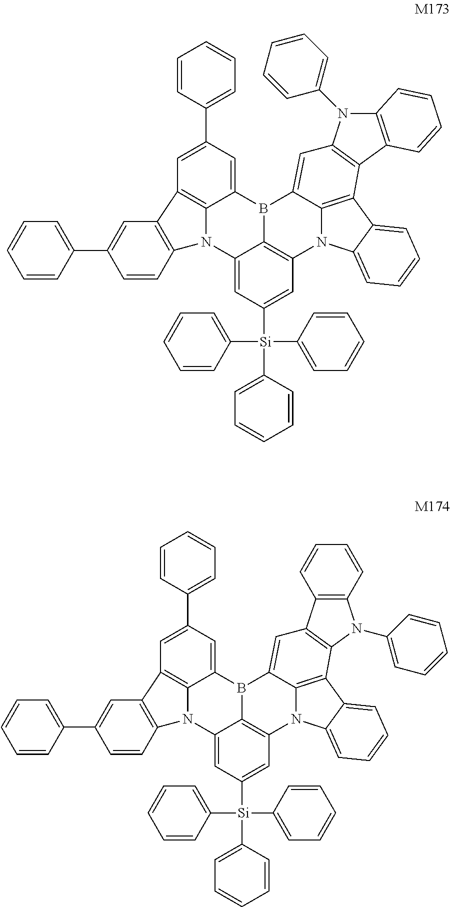 [SMILES: c1ccc(-c2ccc3c(c2)c2cc(-c4ccccc4)cc4c2n3-c2cc([Si](c3ccccc3)(c3ccccc3)c3ccccc3)cc3c2B4c2cc4c(c5ccccc5n4-c4ccccc4)c4c5ccccc5n-3c24)cc1 ; c1ccc(-c2ccc3c(c2)c2cc(-c4ccccc4)cc4c2n3-c2cc([Si](c3ccccc3)(c3ccccc3)c3ccccc3)cc3c2B4c2cc4c5ccccc5n(-c5ccccc5)c4c4c5ccccc5n-3c24)cc1]

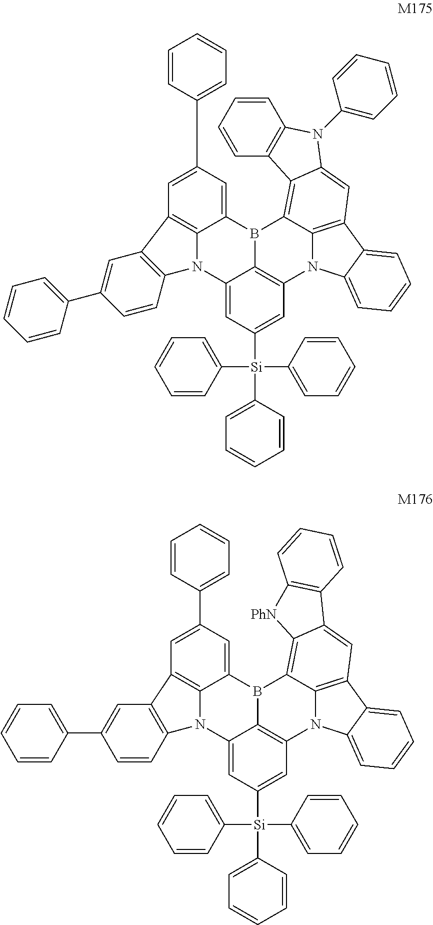

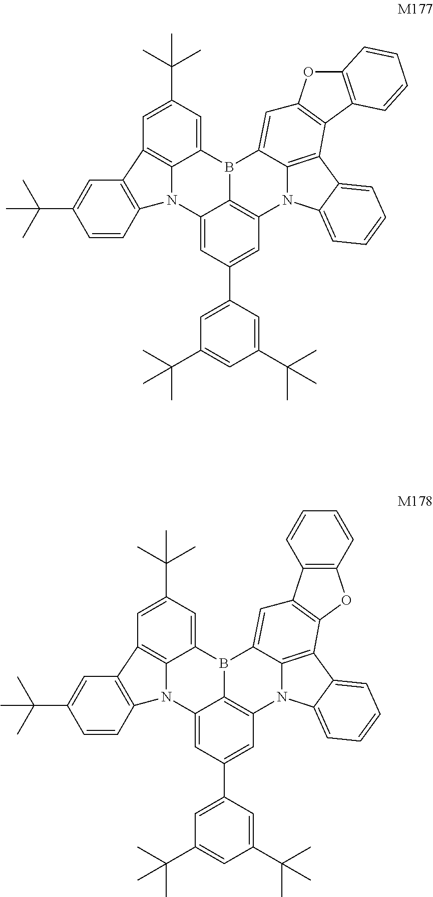 [SMILES: CC(C)(C)c1cc(-c2cc3c4c(c2)-n2c5ccccc5c5c6c(cc(c52)B4c2cc(C(C)(C)C)cc4c5cc(C(C)(C)C)ccc5n-3c24)oc2ccccc26)cc(C(C)(C)C)c1 ; CC(C)(C)c1cc(-c2cc3c4c(c2)-n2c5ccccc5c5c6oc7ccccc7c6cc(c52)B4c2cc(C(C)(C)C)cc4c5cc(C(C)(C)C)ccc5n-3c24)cc(C(C)(C)C)c1]

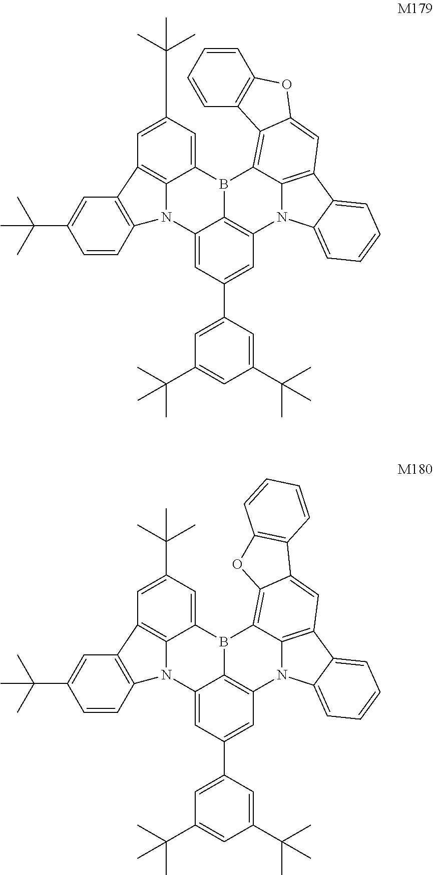 [SMILES: CC(C)(C)c1cc(-c2cc3c4c(c2)-n2c5ccccc5c5cc6oc7ccccc7c6c(c52)B4c2cc(C(C)(C)C)cc4c5cc(C(C)(C)C)ccc5n-3c24)cc(C(C)(C)C)c1 ; CC(C)(C)c1cc(-c2cc3c4c(c2)-n2c5ccccc5c5cc6c(oc7ccccc76)c(c52)B4c2cc(C(C)(C)C)cc4c5cc(C(C)(C)C)ccc5n-3c24)cc(C(C)(C)C)c1]

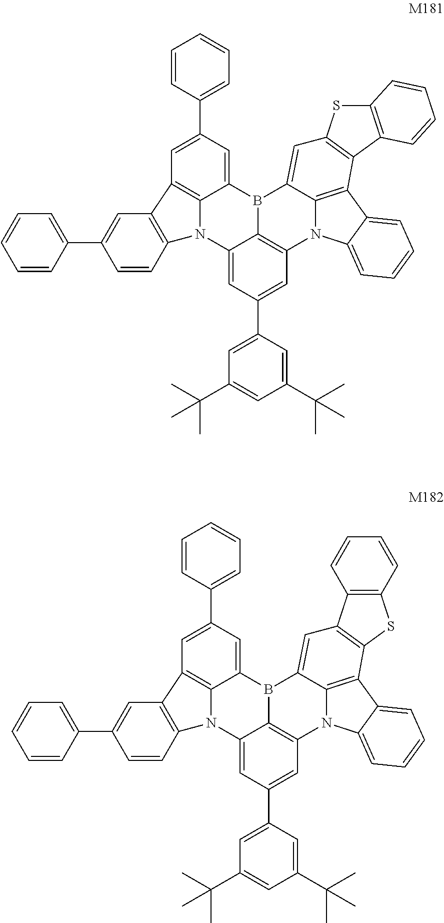 [SMILES: CC(C)(C)c1cc(-c2cc3c4c(c2)-n2c5ccccc5c5c6c(cc(c52)B4c2cc(-c4ccccc4)cc4c5cc(-c7ccccc7)ccc5n-3c24)sc2ccccc26)cc(C(C)(C)C)c1 ; CC(C)(C)c1cc(-c2cc3c4c(c2)-n2c5ccccc5c5c6sc7ccccc7c6cc(c52)B4c2cc(-c4ccccc4)cc4c5cc(-c6ccccc6)ccc5n-3c24)cc(C(C)(C)C)c1]

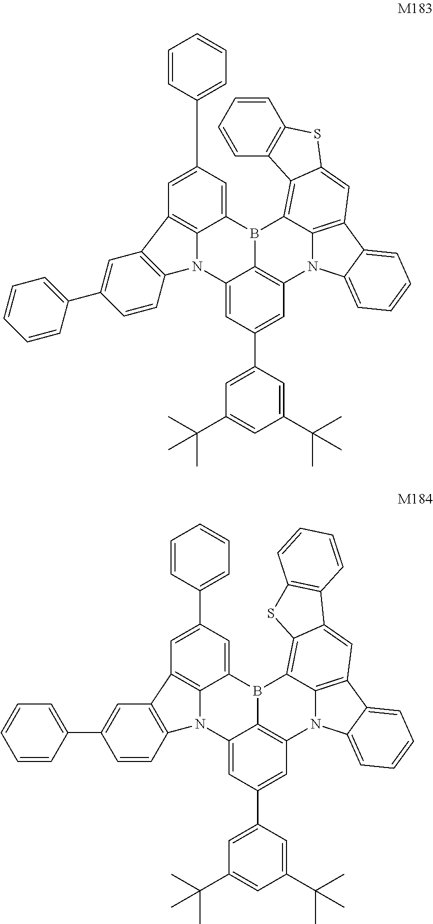 [SMILES: CC(C)(C)c1cc(-c2cc3c4c(c2)-n2c5ccccc5c5cc6sc7ccccc7c6c(c52)B4c2cc(-c4ccccc4)cc4c5cc(-c6ccccc6)ccc5n-3c24)cc(C(C)(C)C)c1 ; CC(C)(C)c1cc(-c2cc3c4c(c2)-n2c5ccccc5c5cc6c(sc7ccccc76)c(c52)B4c2cc(-c4ccccc4)cc4c5cc(-c6ccccc6)ccc5n-3c24)cc(C(C)(C)C)c1]

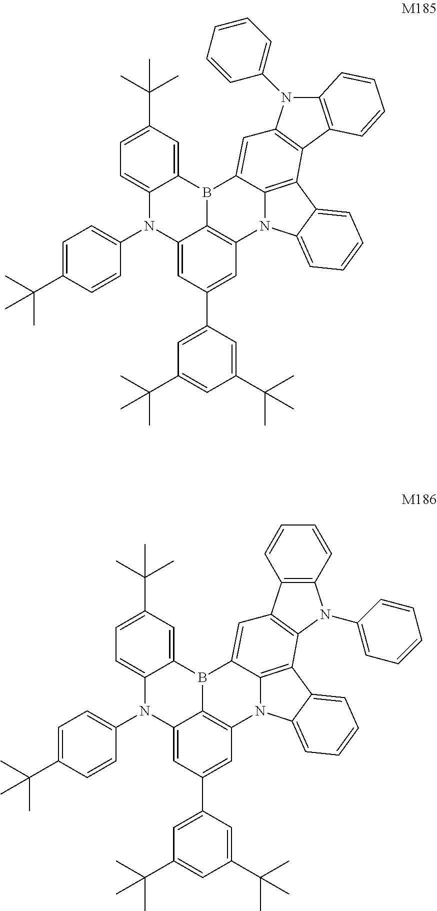 [SMILES: CC(C)(C)c1ccc(N2c3ccc(C(C)(C)C)cc3B3c4c2cc(-c2cc(C(C)(C)C)cc(C(C)(C)C)c2)cc4-n2c4ccccc4c4c5c6ccccc6n(-c6ccccc6)c5cc3c42)cc1 ; CC(C)(C)c1ccc(N2c3ccc(C(C)(C)C)cc3B3c4c2cc(-c2cc(C(C)(C)C)cc(C(C)(C)C)c2)cc4-n2c4ccccc4c4c2c3cc2c3ccccc3n(-c3ccccc3)c24)cc1]

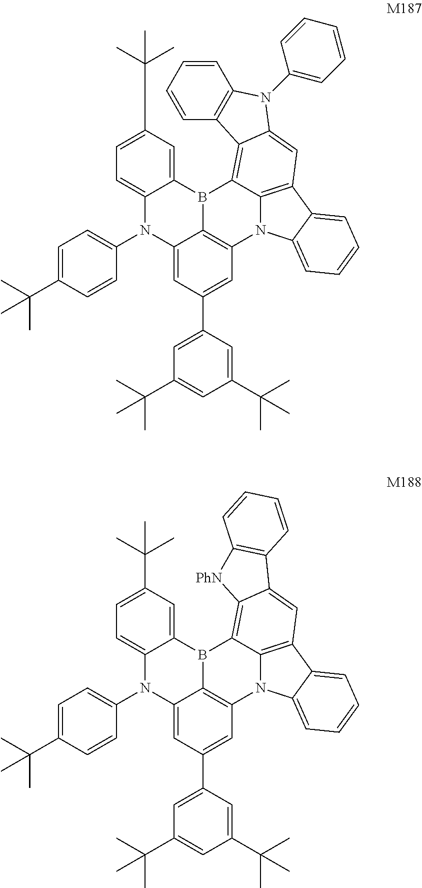

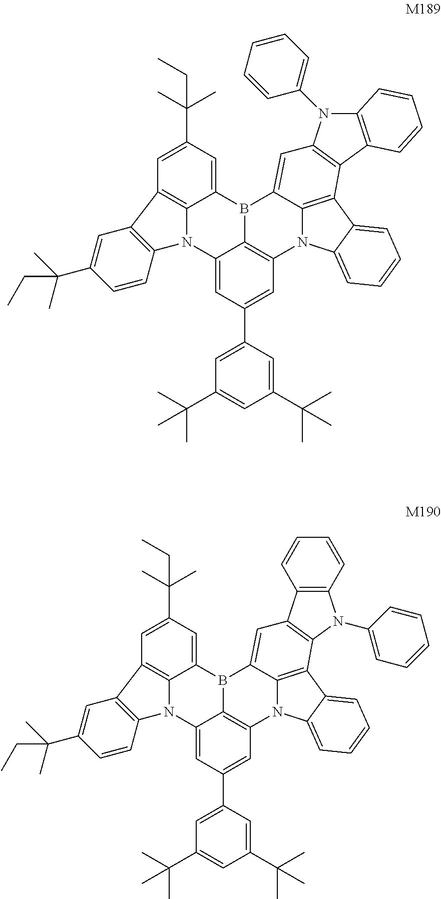 [SMILES: CCC(C)(C)c1ccc2c(c1)c1cc(C(C)(C)CC)cc3c1n2-c1cc(-c2cc(C(C)(C)C)cc(C(C)(C)C)c2)cc2c1B3c1cc3c(c4ccccc4n3-c3ccccc3)c3c4ccccc4n-2c13 ; CCC(C)(C)c1ccc2c(c1)c1cc(C(C)(C)CC)cc3c1n2-c1cc(-c2cc(C(C)(C)C)cc(C(C)(C)C)c2)cc2c1B3c1cc3c4ccccc4n(-c4ccccc4)c3c3c4ccccc4n-2c13]

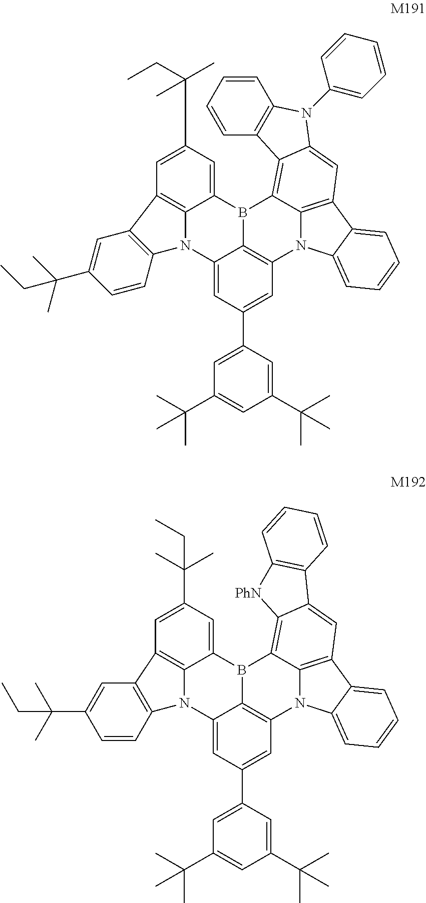

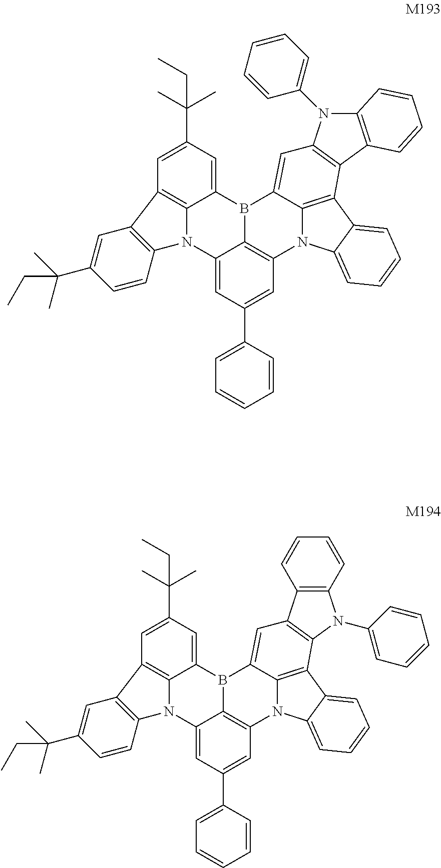 [SMILES: CCC(C)(C)c1ccc2c(c1)c1cc(C(C)(C)CC)cc3c1n2-c1cc(-c2ccccc2)cc2c1B3c1cc3c(c4ccccc4n3-c3ccccc3)c3c4ccccc4n-2c13 ; CCC(C)(C)c1ccc2c(c1)c1cc(C(C)(C)CC)cc3c1n2-c1cc(-c2ccccc2)cc2c1B3c1cc3c4ccccc4n(-c4ccccc4)c3c3c4ccccc4n-2c13]

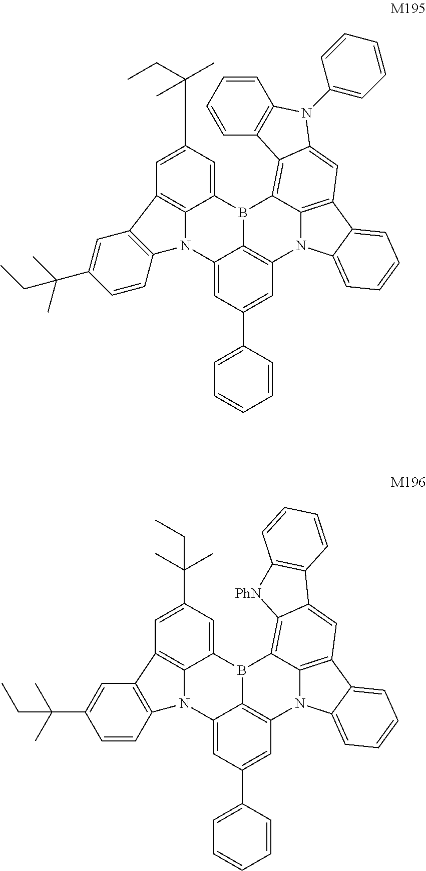

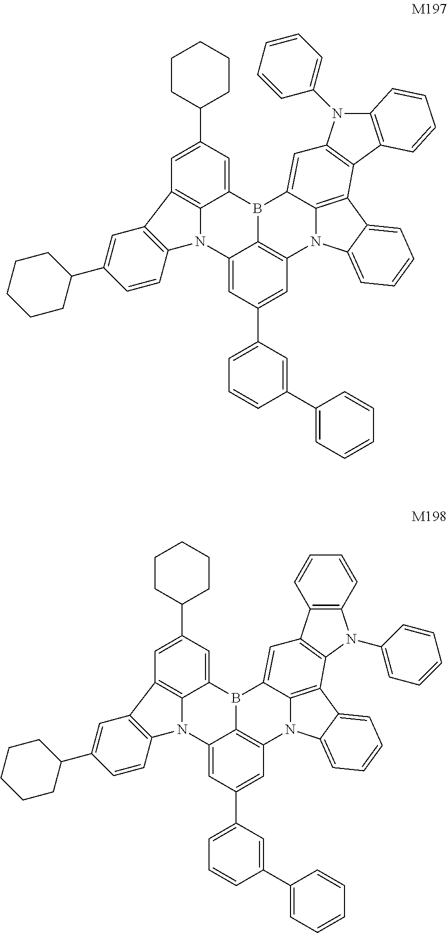 [SMILES: c1ccc(-c2cccc(-c3cc4c5c(c3)-n3c6ccccc6c6c7c8ccccc8n(-c8ccccc8)c7cc(c63)B5c3cc(C5CCCCC5)cc5c6cc(C7CCCCC7)ccc6n-4c35)c2)cc1 ; c1ccc(-c2cccc(-c3cc4c5c(c3)-n3c6ccccc6c6c3c(cc3c7ccccc7n(-c7ccccc7)c36)B5c3cc(C5CCCCC5)cc5c6cc(C7CCCCC7)ccc6n-4c35)c2)cc1]

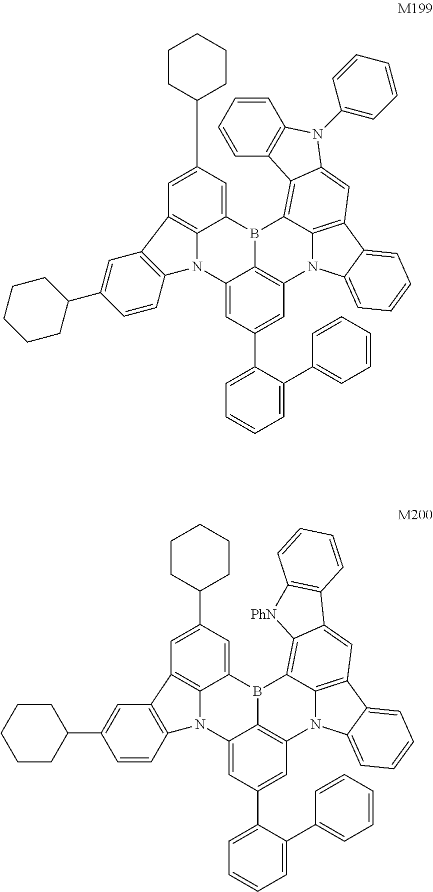

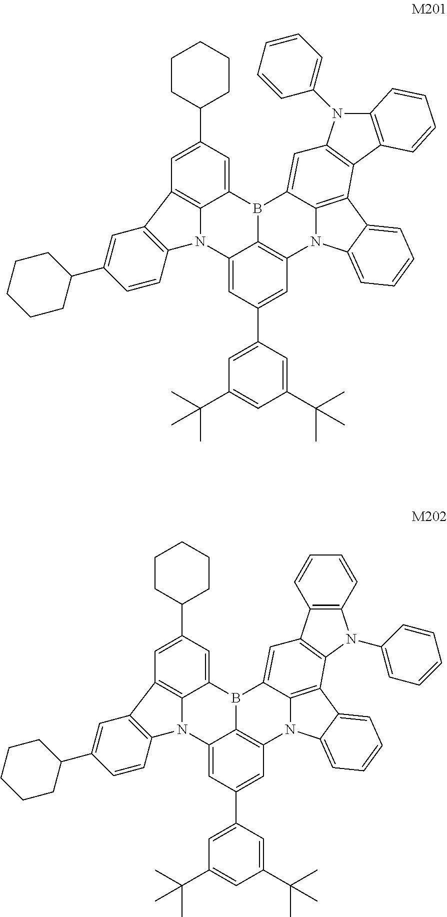 [SMILES: CC(C)(C)c1cc(-c2cc3c4c(c2)-n2c5ccccc5c5c6c7ccccc7n(-c7ccccc7)c6cc(c52)B4c2cc(C4CCCCC4)cc4c5cc(C6CCCCC6)ccc5n-3c24)cc(C(C)(C)C)c1 ; CC(C)(C)c1cc(-c2cc3c4c(c2)-n2c5ccccc5c5c2c(cc2c6ccccc6n(-c6ccccc6)c25)B4c2cc(C4CCCCC4)cc4c5cc(C6CCCCC6)ccc5n-3c24)cc(C(C)(C)C)c1]

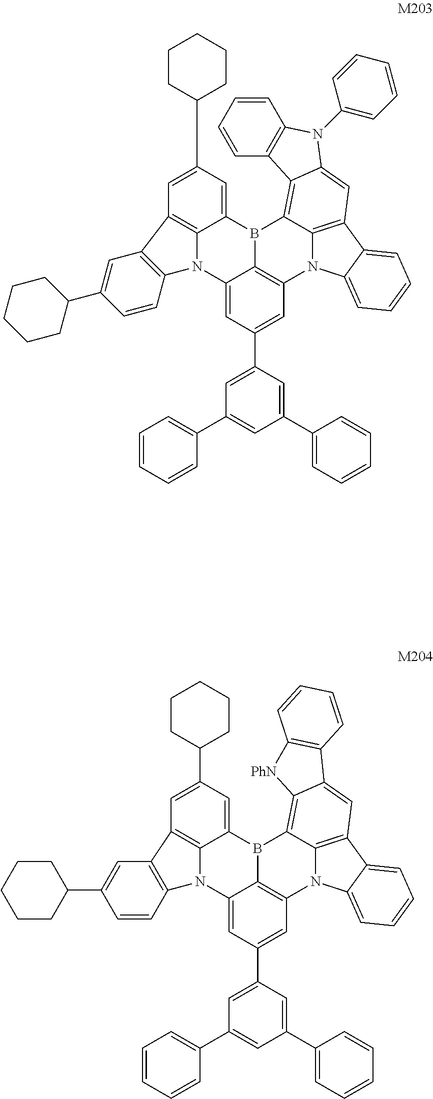

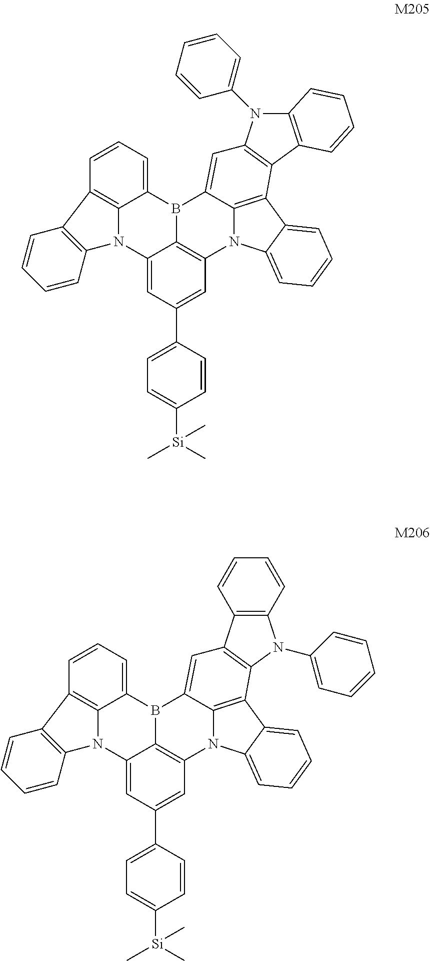 [SMILES: C[Si](C)(C)c1ccc(-c2cc3c4c(c2)-n2c5ccccc5c5c6c7ccccc7n(-c7ccccc7)c6cc(c52)B4c2cccc4c5ccccc5n-3c24)cc1 ; C[Si](C)(C)c1ccc(-c2cc3c4c(c2)-n2c5ccccc5c5c2c(cc2c6ccccc6n(-c6ccccc6)c25)B4c2cccc4c5ccccc5n-3c24)cc1]

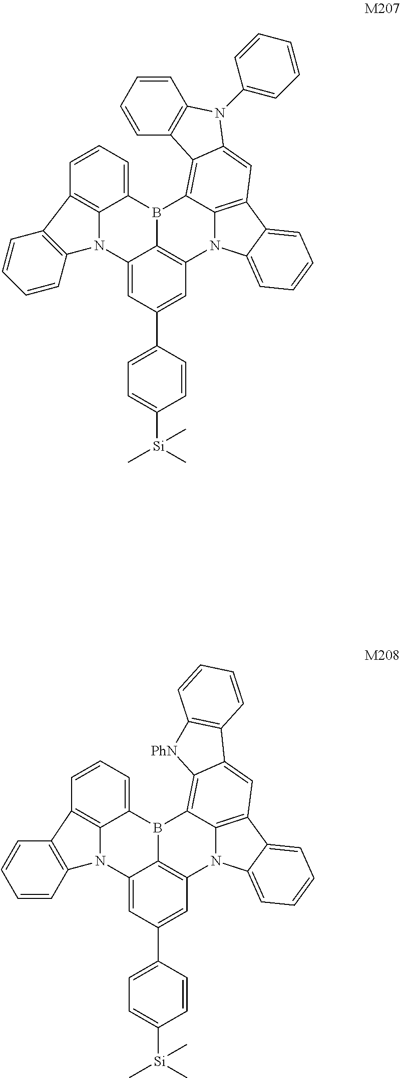

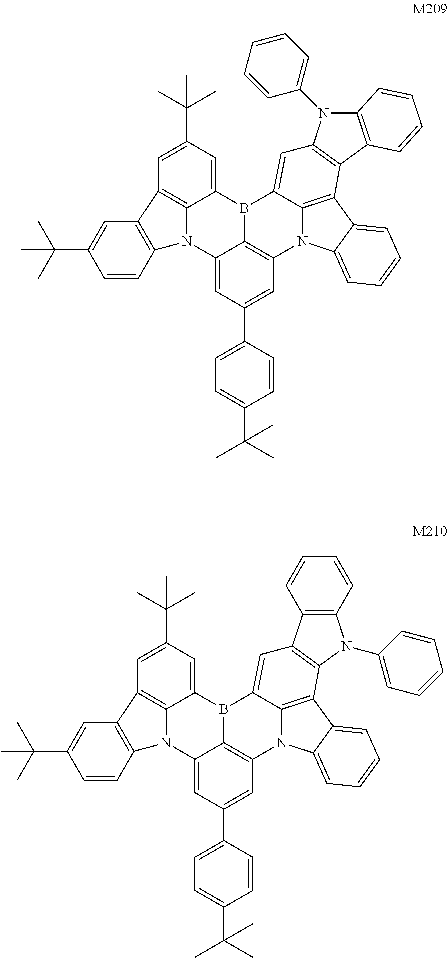 [SMILES: CC(C)(C)c1ccc(-c2cc3c4c(c2)-n2c5ccccc5c5c6c7ccccc7n(-c7ccccc7)c6cc(c52)B4c2cc(C(C)(C)C)cc4c5cc(C(C)(C)C)ccc5n-3c24)cc1 ; CC(C)(C)c1ccc(-c2cc3c4c(c2)-n2c5ccccc5c5c2c(cc2c6ccccc6n(-c6ccccc6)c25)B4c2cc(C(C)(C)C)cc4c5cc(C(C)(C)C)ccc5n-3c24)cc1]

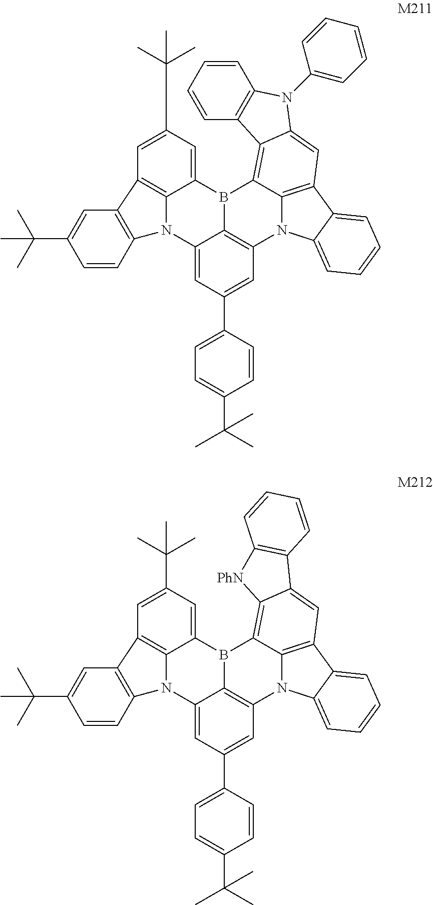

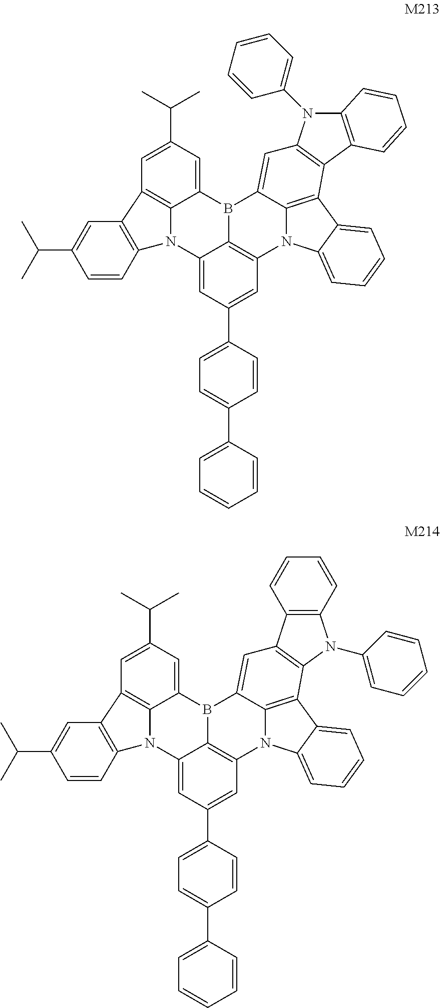 [SMILES: CC(C)c1ccc2c(c1)c1cc(C(C)C)cc3c1n2-c1cc(-c2ccc(-c4ccccc4)cc2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2ccc(-c4ccccc4)cc2)cc2c1B3c1cc3c4ccccc4n(-c4ccccc4)c3c3c4ccccc4n-2c13]

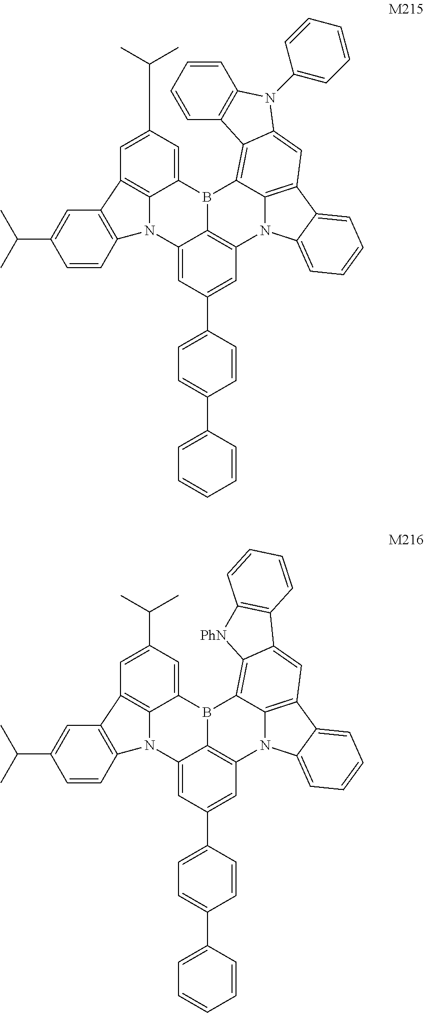

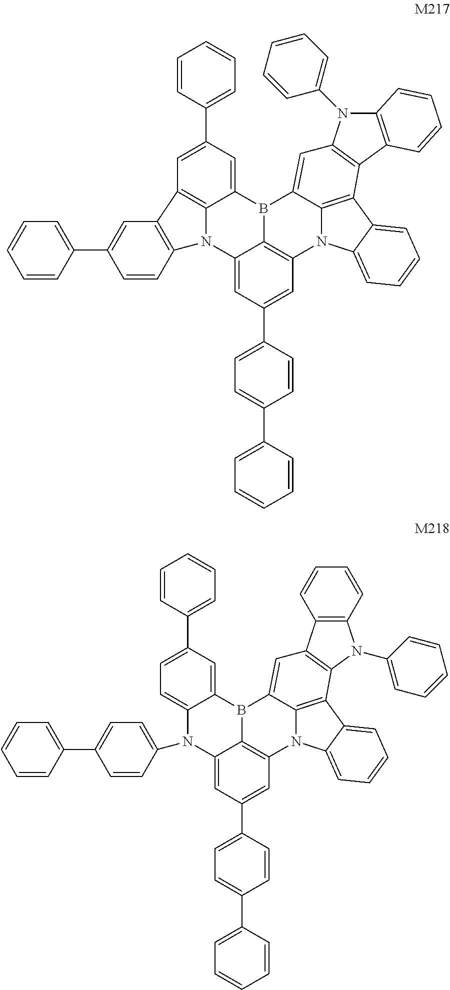 [SMILES: c1ccc(-c2ccc(-c3cc4c5c(c3)-n3c6ccccc6c6c7c8ccccc8n(-c8ccccc8)c7cc(c63)B5c3cc(-c5ccccc5)cc5c6cc(-c7ccccc7)ccc6n-4c35)cc2)cc1 ; c1ccc(-c2ccc(-c3cc4c5c(c3)-n3c6ccccc6c6c3c(cc3c7ccccc7n(-c7ccccc7)c36)B5c3cc(-c5ccccc5)ccc3N4c3ccc(-c4ccccc4)cc3)cc2)cc1]

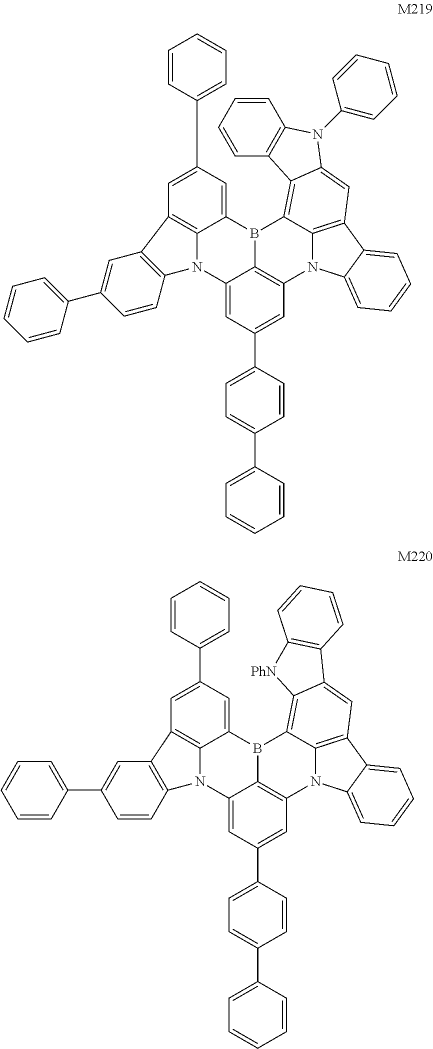

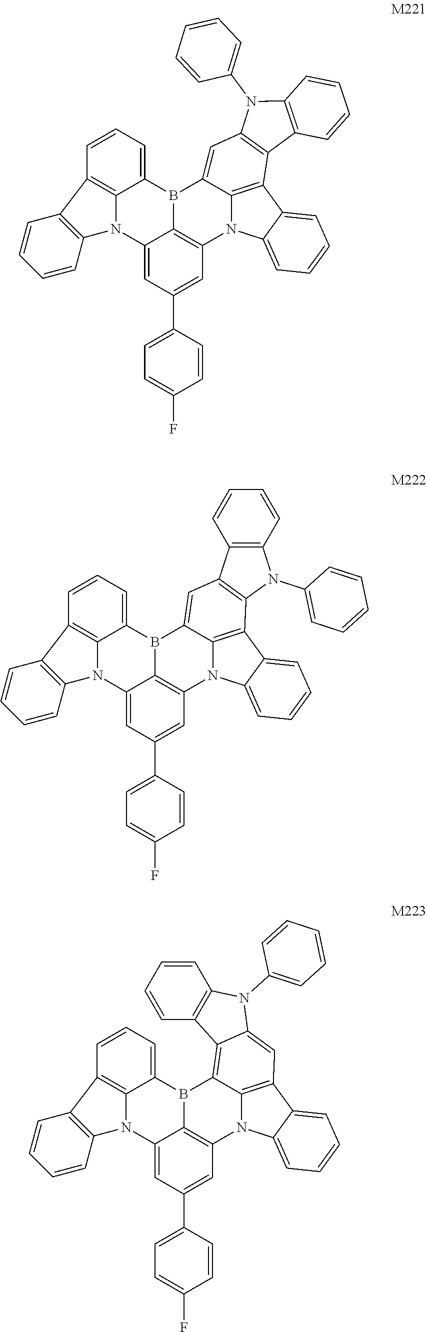 [SMILES: Fc1ccc(-c2cc3c4c(c2)-n2c5ccccc5c5c6c7ccccc7n(-c7ccccc7)c6cc(c52)B4c2cccc4c5ccccc5n-3c24)cc1 ; Fc1ccc(-c2cc3c4c(c2)-n2c5ccccc5c5c2c(cc2c6ccccc6n(-c6ccccc6)c25)B4c2cccc4c5ccccc5n-3c24)cc1 ; Fc1ccc(-c2cc3c4c(c2)-n2c5ccccc5c5cc6c(c(c52)B4c2cccc4c5ccccc5n-3c24)c2ccccc2n6-c2ccccc2)cc1]

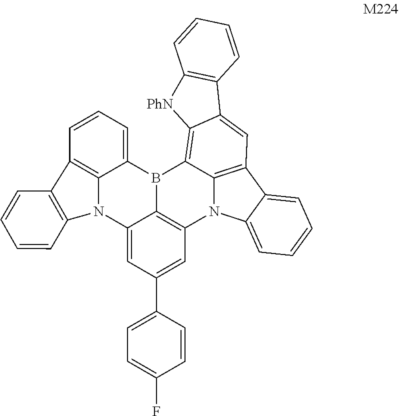

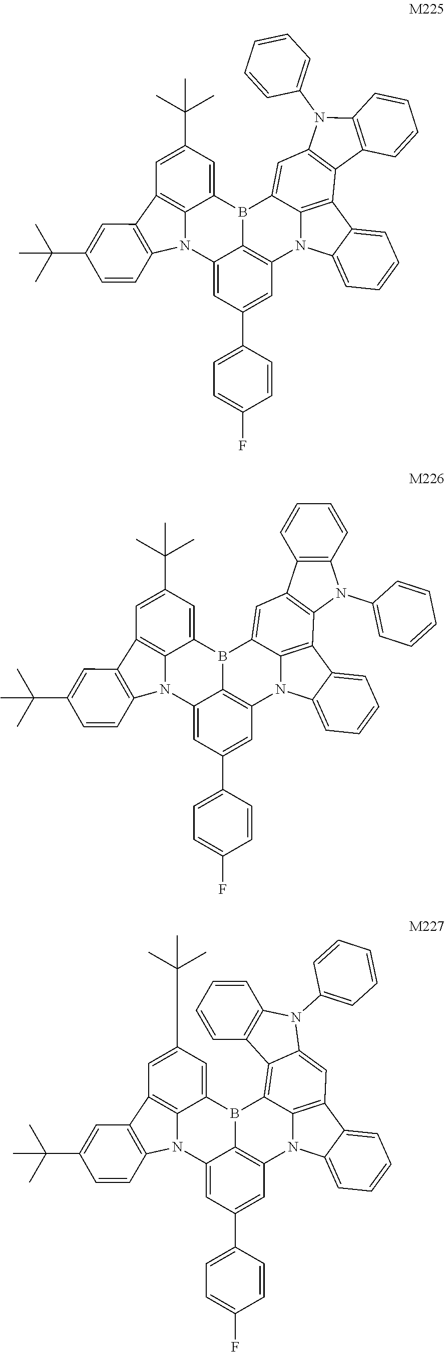 [SMILES: CC(C)(C)c1ccc2c(c1)c1cc(C(C)(C)C)cc3c1n2-c1cc(-c2ccc(F)cc2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2ccc(F)cc2)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2ccc(F)cc2)cc2c1B3c1c3c4ccccc4n(-c4ccccc4)c3cc3c4ccccc4n-2c13]

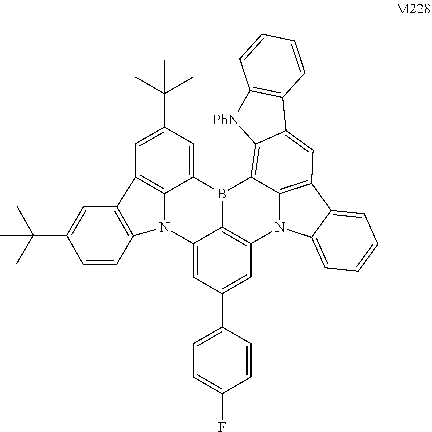

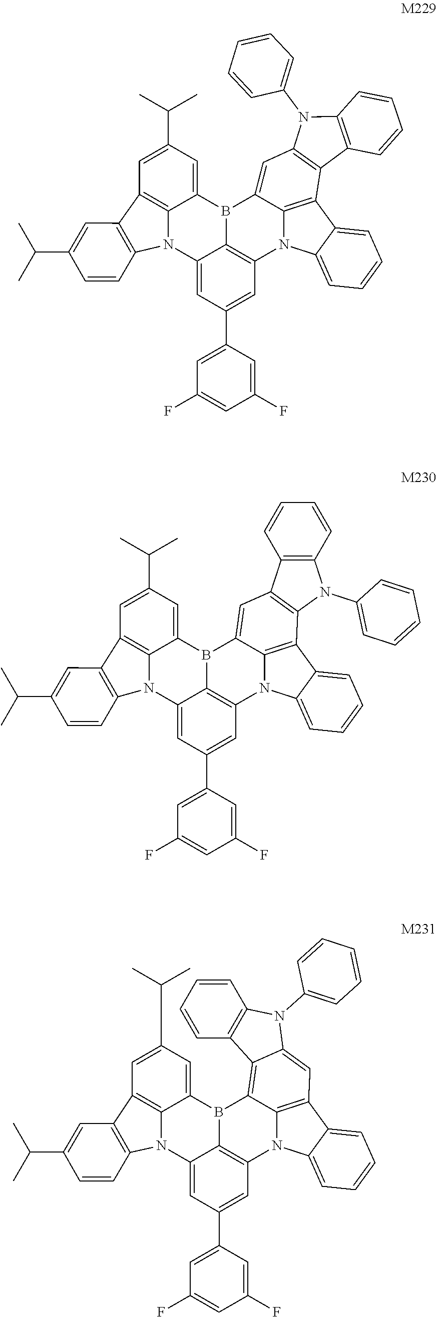 [SMILES: CC(C)c1ccc2c(c1)c1cc(C(C)C)cc3c1n2-c1cc(-c2cc(F)cc(F)c2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2cc(F)cc(F)c2)cc2c1B3c1cc3c4ccccc4n(-c4ccccc4)c3c3c4ccccc4n-2c13 ; CC(C)c1ccc2c(c1)c1cc(C(C)C)cc3c1n2-c1cc(-c2cc(F)cc(F)c2)cc2c1B3c1c3c4ccccc4n(-c4ccccc4)c3cc3c4ccccc4n-2c13]

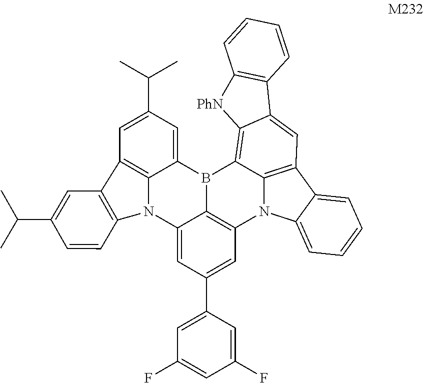

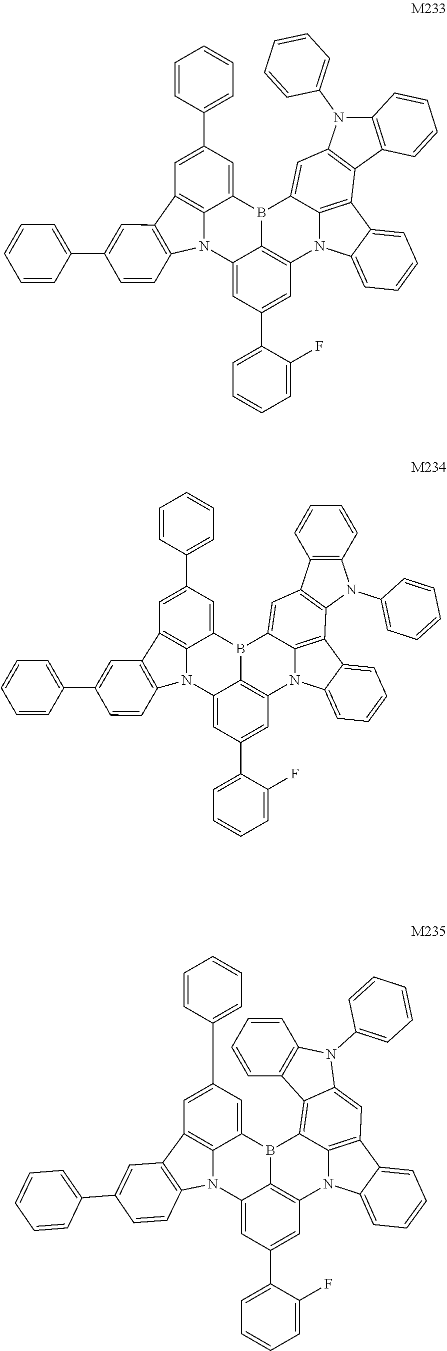 [SMILES: Fc1ccccc1-c1cc2c3c(c1)-n1c4ccccc4c4c5c6ccccc6n(-c6ccccc6)c5cc(c41)B3c1cc(-c3ccccc3)cc3c4cc(-c5ccccc5)ccc4n-2c13 ; Fc1ccccc1-c1cc2c3c(c1)-n1c4ccccc4c4c1c(cc1c5ccccc5n(-c5ccccc5)c14)B3c1cc(-c3ccccc3)cc3c4cc(-c5ccccc5)ccc4n-2c13 ; Fc1ccccc1-c1cc2c3c(c1)-n1c4ccccc4c4cc5c(c(c41)B3c1cc(-c3ccccc3)cc3c4cc(-c6ccccc6)ccc4n-2c13)c1ccccc1n5-c1ccccc1]

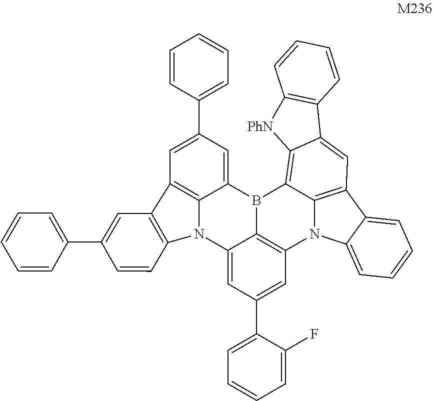

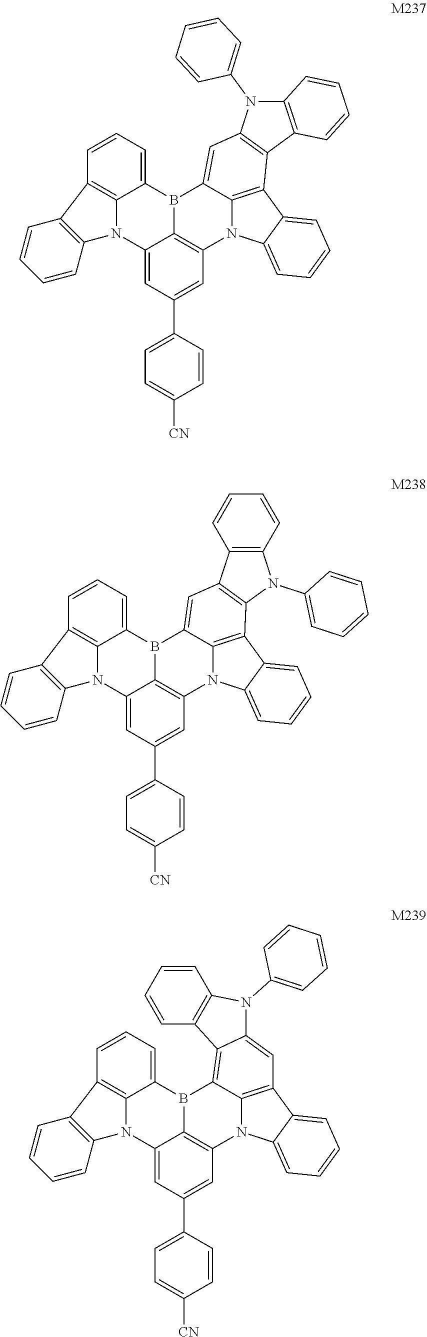 [SMILES: N#Cc1ccc(-c2cc3c4c(c2)-n2c5ccccc5c5c6c7ccccc7n(-c7ccccc7)c6cc(c52)B4c2cccc4c5ccccc5n-3c24)cc1 ; N#Cc1ccc(-c2cc3c4c(c2)-n2c5ccccc5c5c2c(cc2c6ccccc6n(-c6ccccc6)c25)B4c2cccc4c5ccccc5n-3c24)cc1 ; N#Cc1ccc(-c2cc3c4c(c2)-n2c5ccccc5c5cc6c(c(c52)B4c2cccc4c5ccccc5n-3c24)c2ccccc2n6-c2ccccc2)cc1]

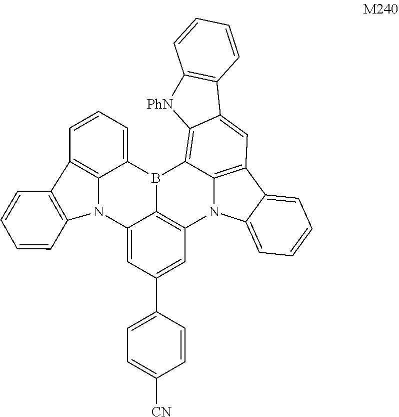

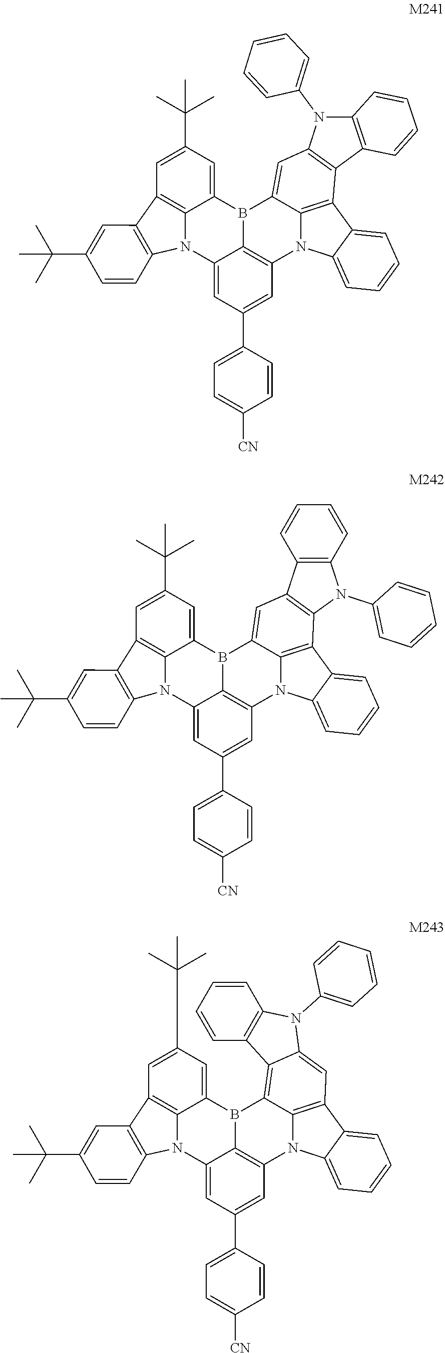 [SMILES: CC(C)(C)c1ccc2c(c1)c1cc(C(C)(C)C)cc3c1n2-c1cc(-c2ccc(C#N)cc2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2ccc(C#N)cc2)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2ccc(C#N)cc2)cc2c1B3c1c3c4ccccc4n(-c4ccccc4)c3cc3c4ccccc4n-2c13]

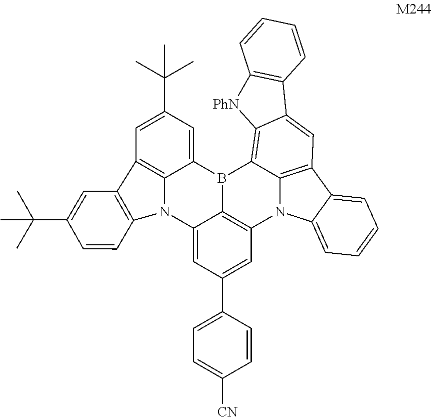

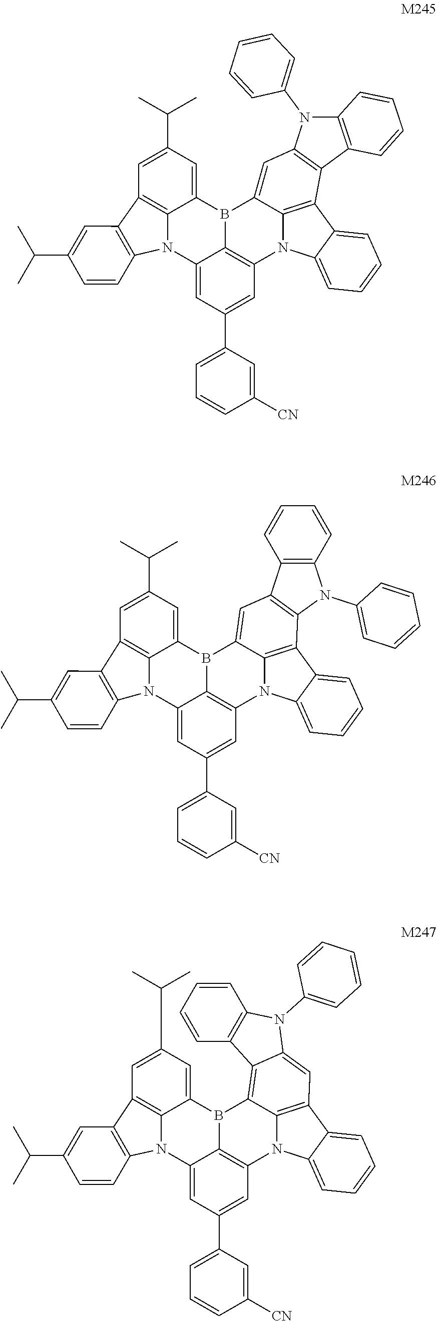 [SMILES: CC(C)c1ccc2c(c1)c1cc(C(C)C)cc3c1n2-c1cc(-c2cccc(C#N)c2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2cccc(C#N)c2)cc2c1B3c1cc3c4ccccc4n(-c4ccccc4)c3c3c4ccccc4n-2c13 ; CC(C)c1ccc2c(c1)c1cc(C(C)C)cc3c1n2-c1cc(-c2cccc(C#N)c2)cc2c1B3c1c3c4ccccc4n(-c4ccccc4)c3cc3c4ccccc4n-2c13]

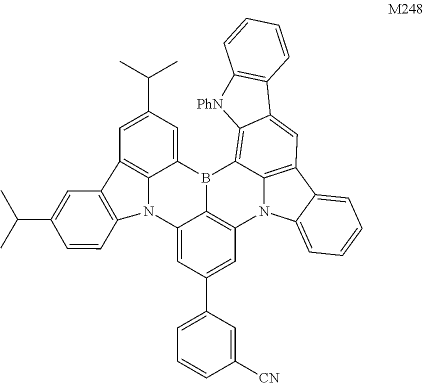

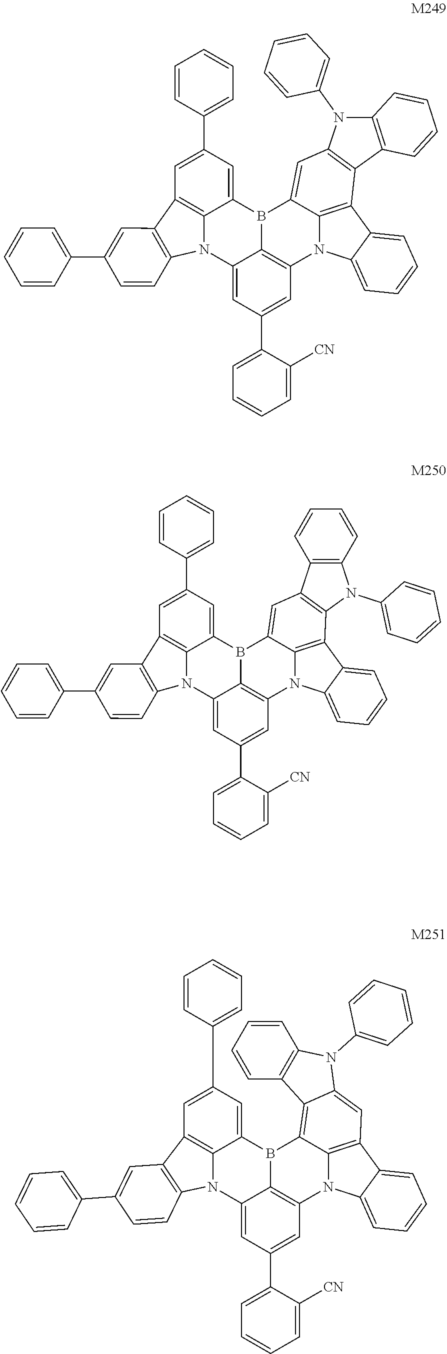 [SMILES: N#Cc1ccccc1-c1cc2c3c(c1)-n1c4ccccc4c4c5c6ccccc6n(-c6ccccc6)c5cc(c41)B3c1cc(-c3ccccc3)cc3c4cc(-c5ccccc5)ccc4n-2c13 ; N#Cc1ccccc1-c1cc2c3c(c1)-n1c4ccccc4c4c1c(cc1c5ccccc5n(-c5ccccc5)c14)B3c1cc(-c3ccccc3)cc3c4cc(-c5ccccc5)ccc4n-2c13 ; N#Cc1ccccc1-c1cc2c3c(c1)-n1c4ccccc4c4cc5c(c(c41)B3c1cc(-c3ccccc3)cc3c4cc(-c6ccccc6)ccc4n-2c13)c1ccccc1n5-c1ccccc1]

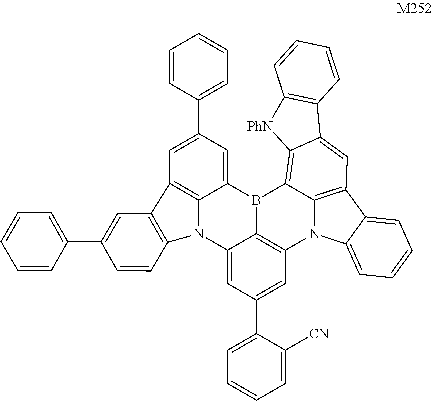

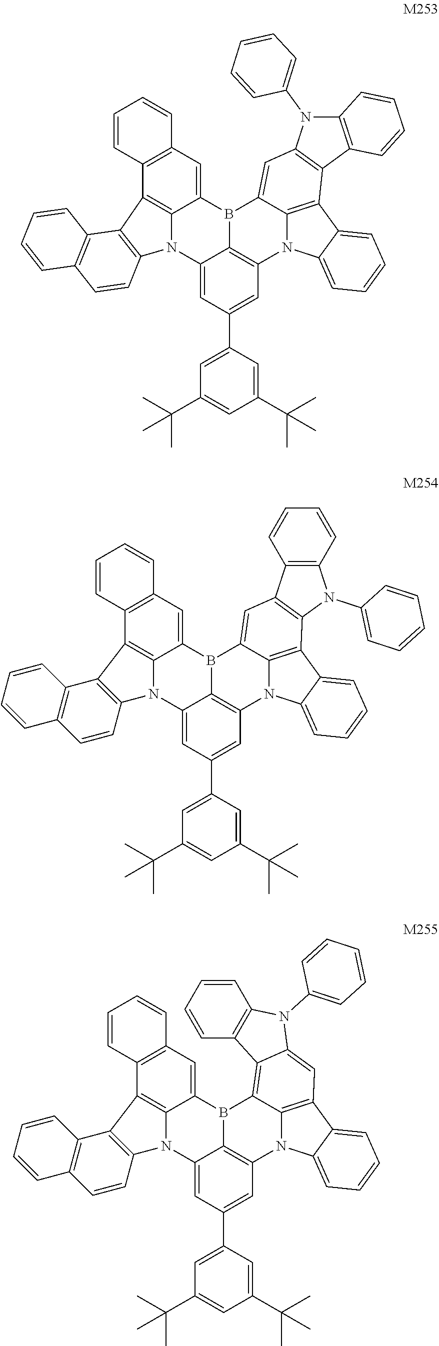 [SMILES: CC(C)(C)c1cc(-c2cc3c4c(c2)-n2c5ccc6ccccc6c5c5c6ccccc6cc(c52)B4c2cc4c(c5ccccc5n4-c4ccccc4)c4c5ccccc5n-3c24)cc(C(C)(C)C)c1 ; CC(C)(C)c1cc(-c2cc3c4c(c2)-n2c5ccc6ccccc6c5c5c6ccccc6cc(c52)B4c2cc4c5ccccc5n(-c5ccccc5)c4c4c5ccccc5n-3c24)cc(C(C)(C)C)c1 ; CC(C)(C)c1cc(-c2cc3c4c(c2)-n2c5ccc6ccccc6c5c5c6ccccc6cc(c52)B4c2c4c5ccccc5n(-c5ccccc5)c4cc4c5ccccc5n-3c24)cc(C(C)(C)C)c1]

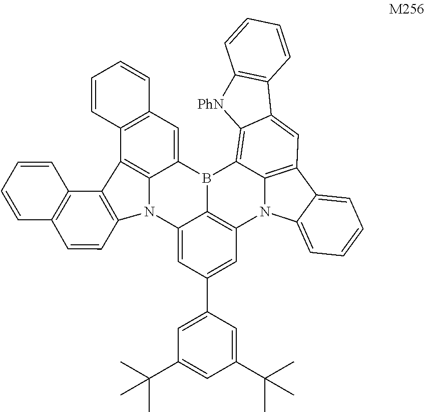

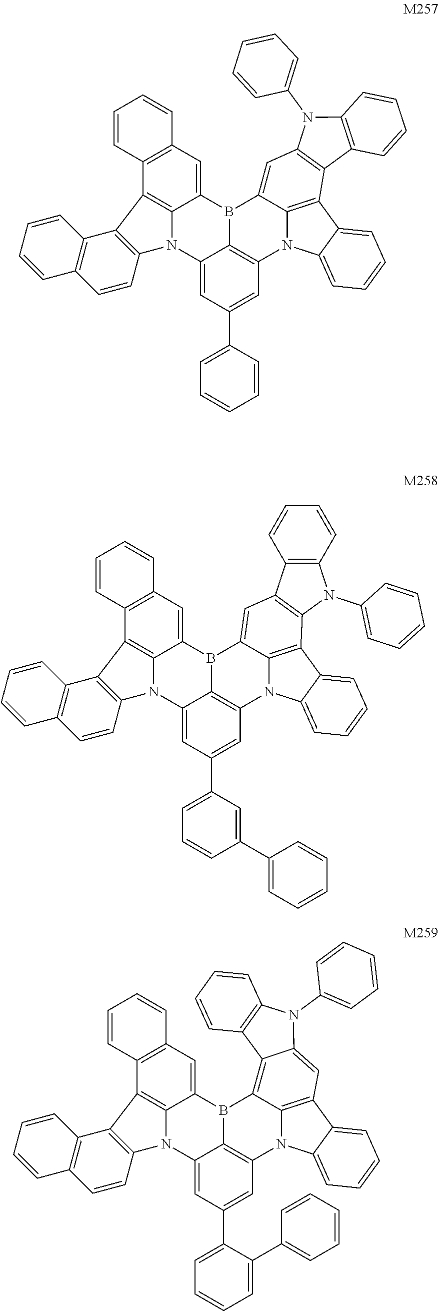 [SMILES: c1ccc(-c2cc3c4c(c2)-n2c5ccc6ccccc6c5c5c6ccccc6cc(c52)B4c2cc4c(c5ccccc5n4-c4ccccc4)c4c5ccccc5n-3c24)cc1 ; c1ccc(-c2cccc(-c3cc4c5c(c3)-n3c6ccc7ccccc7c6c6c7ccccc7cc(c63)B5c3cc5c6ccccc6n(-c6ccccc6)c5c5c6ccccc6n-4c35)c2)cc1 ; c1ccc(-c2ccccc2-c2cc3c4c(c2)-n2c5ccc6ccccc6c5c5c6ccccc6cc(c52)B4c2c4c5ccccc5n(-c5ccccc5)c4cc4c5ccccc5n-3c24)cc1]

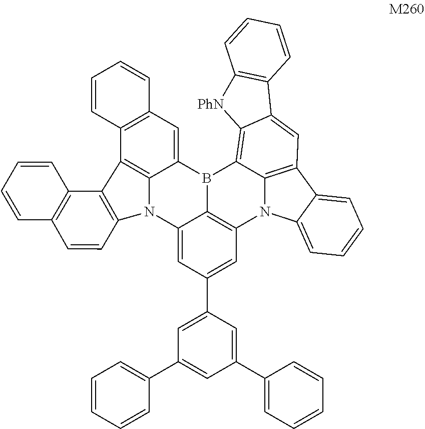

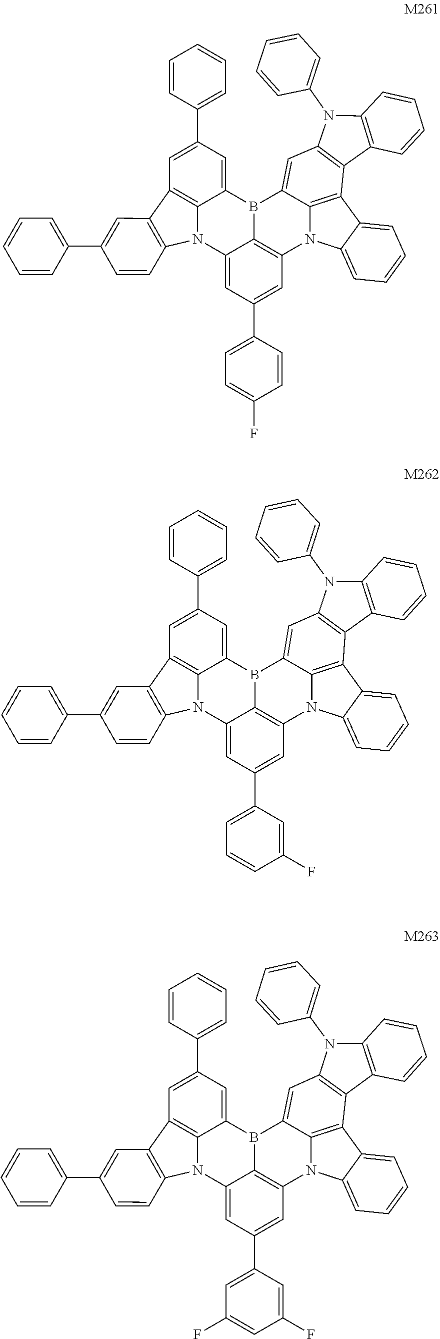 [SMILES: Fc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc1 ; Fc1cccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1 ; Fc1cc(F)cc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1]

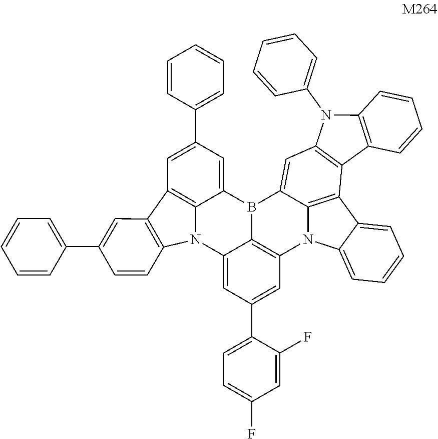 [SMILES: Fc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c(F)c1]

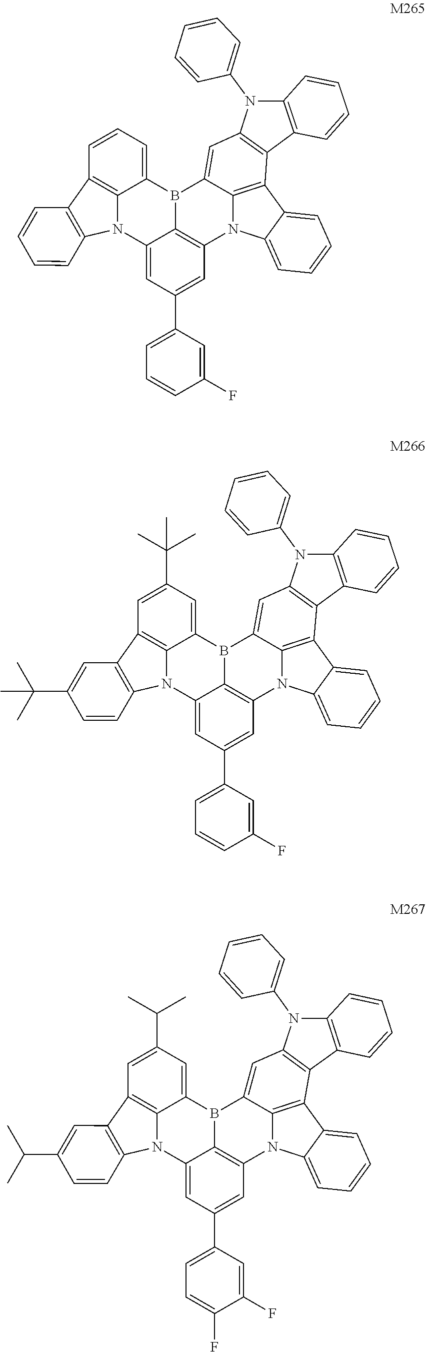 [SMILES: Fc1cccc(-c2cc3c4c(c2)-n2c5ccccc5c5c6c7ccccc7n(-c7ccccc7)c6cc(c52)B4c2cccc4c5ccccc5n-3c24)c1 ; CC(C)(C)c1ccc2c(c1)c1cc(C(C)(C)C)cc3c1n2-c1cc(-c2cccc(F)c2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2ccc(F)c(F)c2)cc2c1B3c1cc3c(c4ccccc4n3-c3ccccc3)c3c4ccccc4n-2c13]

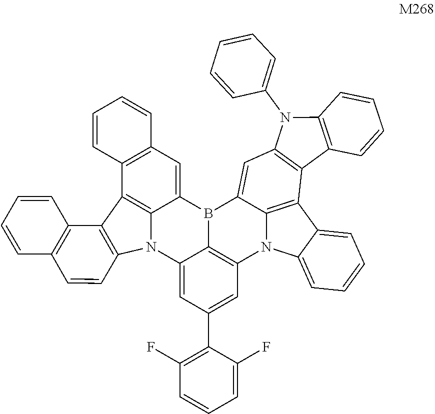 [SMILES: Fc1cccc(F)c1-c1cc2c3c(c1)-n1c4ccc5ccccc5c4c4c5ccccc5cc(c41)B3c1cc3c(c4ccccc4n3-c3ccccc3)c3c4ccccc4n-2c13]

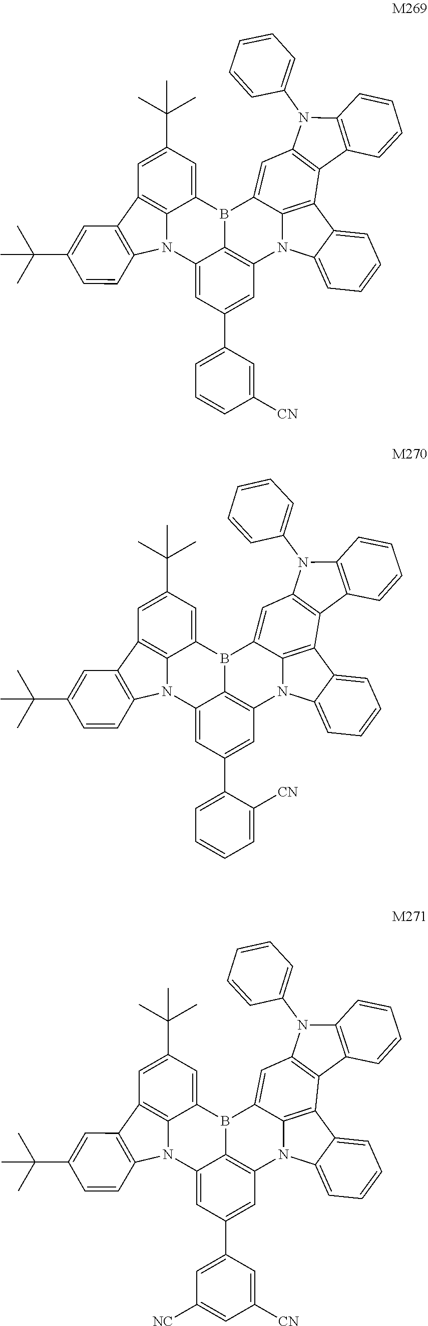 [SMILES: CC(C)(C)c1ccc2c(c1)c1cc(C(C)(C)C)cc3c1n2-c1cc(-c2cccc(C#N)c2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2ccccc2C#N)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2cc(C#N)cc(C#N)c2)cc2c1B3c1cc3c(c4ccccc4n3-c3ccccc3)c3c4ccccc4n-2c13]

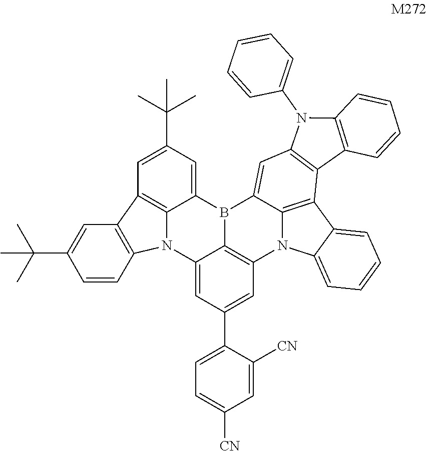 [SMILES: CC(C)(C)c1ccc2c(c1)c1cc(C(C)(C)C)cc3c1n2-c1cc(-c2ccc(C#N)cc2C#N)cc2c1B3c1cc3c(c4ccccc4n3-c3ccccc3)c3c4ccccc4n-2c13]

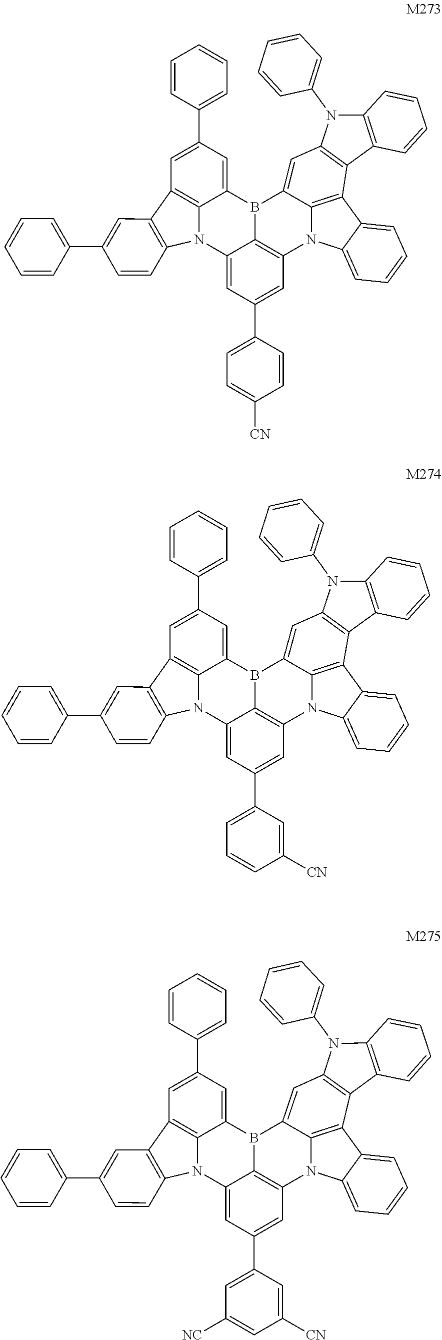 [SMILES: N#Cc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc1 ; N#Cc1cccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1 ; N#Cc1cc(C#N)cc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1]

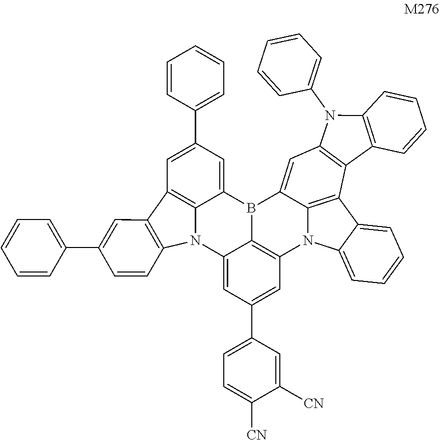 [SMILES: N#Cc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc1C#N]

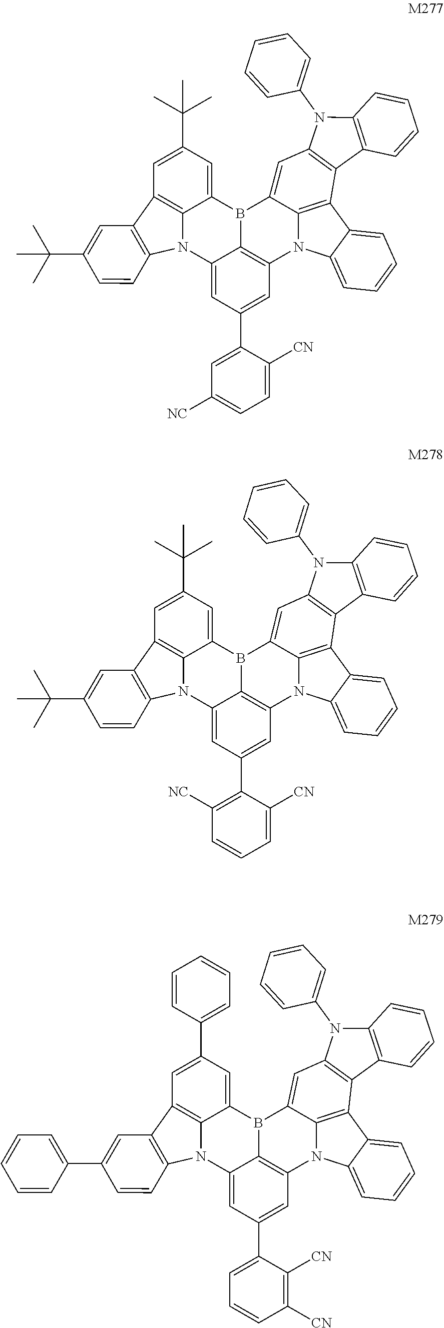 [SMILES: CC(C)(C)c1ccc2c(c1)c1cc(C(C)(C)C)cc3c1n2-c1cc(-c2cc(C#N)ccc2C#N)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2c(C#N)cccc2C#N)cc2c1B3c1cc3c(c4ccccc4n3-c3ccccc3)c3c4ccccc4n-2c13 ; N#Cc1cccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1C#N]

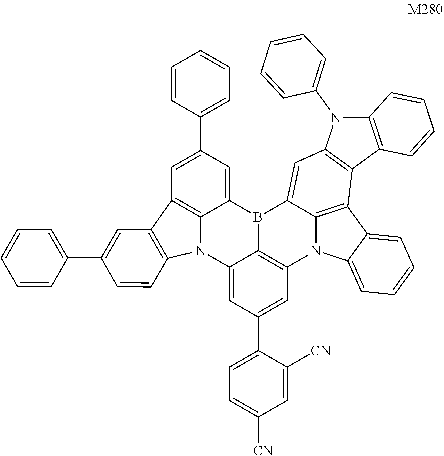 [SMILES: N#Cc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c(C#N)c1]

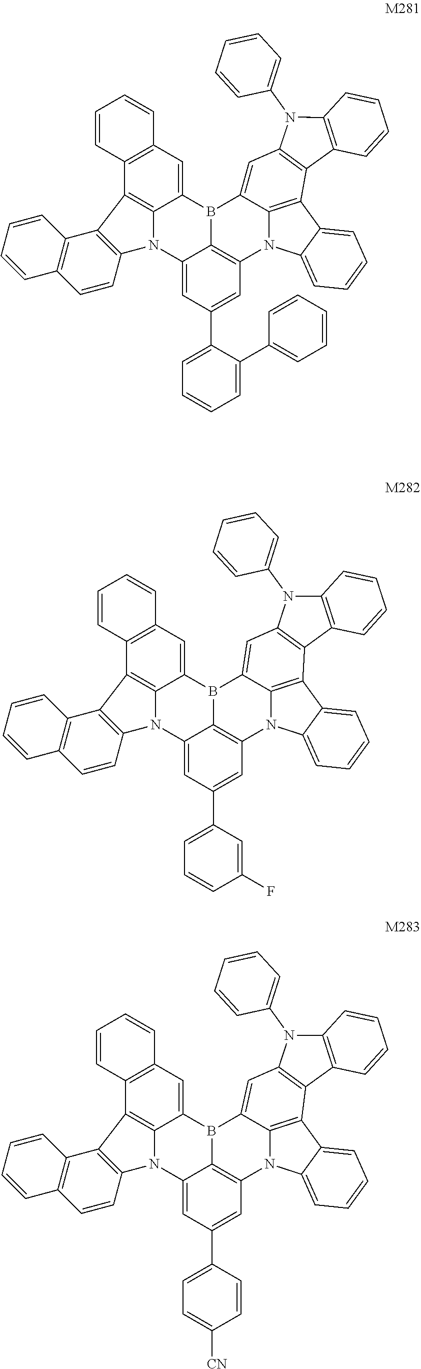 [SMILES: c1ccc(-c2ccccc2-c2cc3c4c(c2)-n2c5ccc6ccccc6c5c5c6ccccc6cc(c52)B4c2cc4c(c5ccccc5n4-c4ccccc4)c4c5ccccc5n-3c24)cc1 ; Fc1cccc(-c2cc3c4c(c2)-n2c5ccc6ccccc6c5c5c6ccccc6cc(c52)B4c2cc4c(c5ccccc5n4-c4ccccc4)c4c5ccccc5n-3c24)c1 ; N#Cc1ccc(-c2cc3c4c(c2)-n2c5ccc6ccccc6c5c5c6ccccc6cc(c52)B4c2cc4c(c5ccccc5n4-c4ccccc4)c4c5ccccc5n-3c24)cc1]

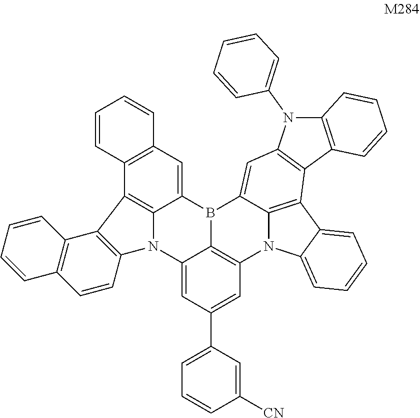 [SMILES: N#Cc1cccc(-c2cc3c4c(c2)-n2c5ccc6ccccc6c5c5c6ccccc6cc(c52)B4c2cc4c(c5ccccc5n4-c4ccccc4)c4c5ccccc5n-3c24)c1]

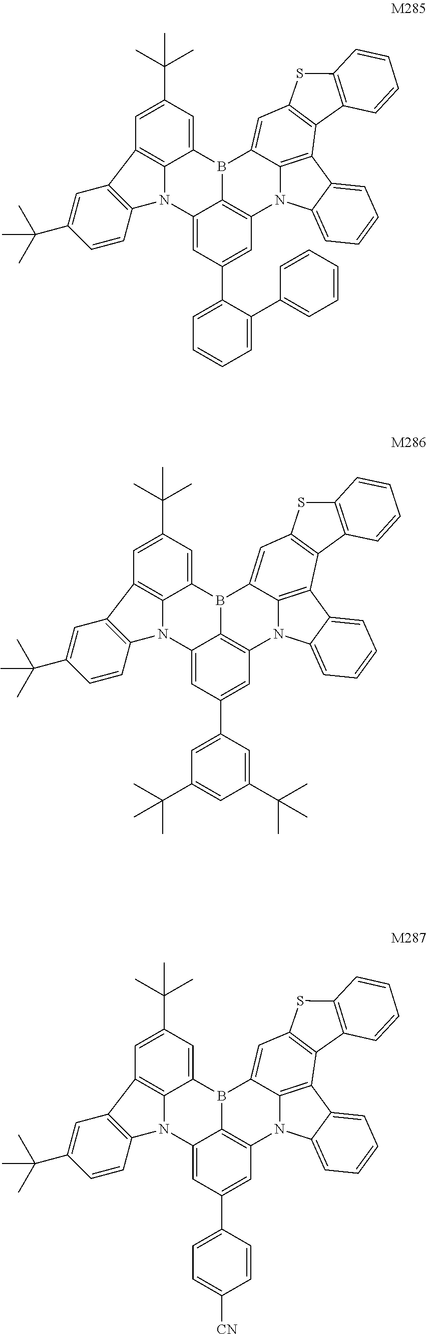 [SMILES: CC(C)(C)c1ccc2c(c1)c1cc(C(C)(C)C)cc3c1n2-c1cc(-c2ccccc2-c2ccccc2)cc2c1B3c1cc3sc4ccccc4c3c3c4ccccc4n-2c13 ; CC(C)(C)c1cc(-c2cc3c4c(c2)-n2c5ccccc5c5c6c(cc(c52)B4c2cc(C(C)(C)C)cc4c5cc(C(C)(C)C)ccc5n-3c24)sc2ccccc26)cc(C(C)(C)C)c1 ; CC(C)(C)c1ccc2c(c1)c1cc(C(C)(C)C)cc3c1n2-c1cc(-c2ccc(C#N)cc2)cc2c1B3c1cc3sc4ccccc4c3c3c4ccccc4n-2c13]

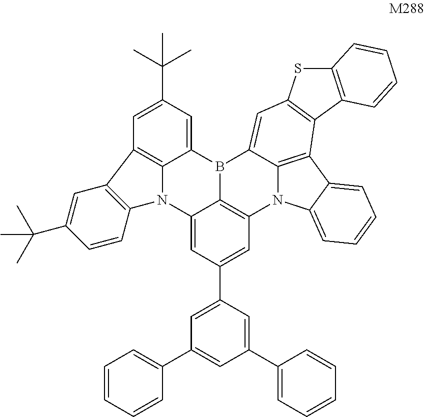 [SMILES: CC(C)(C)c1ccc2c(c1)c1cc(C(C)(C)C)cc3c1n2-c1cc(-c2cc(-c4ccccc4)cc(-c4ccccc4)c2)cc2c1B3c1cc3sc4ccccc4c3c3c4ccccc4n-2c13]

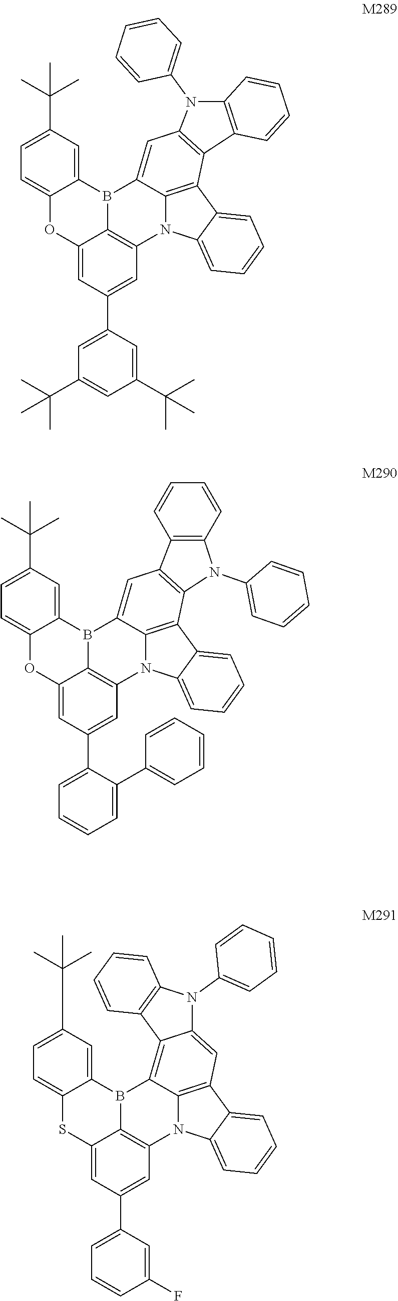 [SMILES: CC(C)(C)c1cc(-c2cc3c4c(c2)-n2c5ccccc5c5c6c7ccccc7n(-c7ccccc7)c6cc(c52)B4c2cc(C(C)(C)C)ccc2O3)cc(C(C)(C)C)c1 ; CC(C)(C)c1ccc2c(c1)B1c3c(cc(-c4ccccc4-c4ccccc4)cc3-n3c4ccccc4c4c3c1cc1c3ccccc3n(-c3ccccc3)c14)O2 ; CC(C)(C)c1ccc2c(c1)B1c3c(cc(-c4cccc(F)c4)cc3-n3c4ccccc4c4cc5c(c1c43)c1ccccc1n5-c1ccccc1)S2]

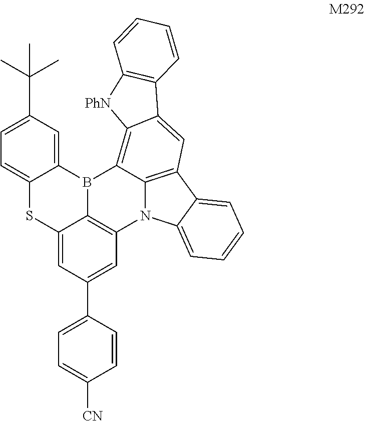

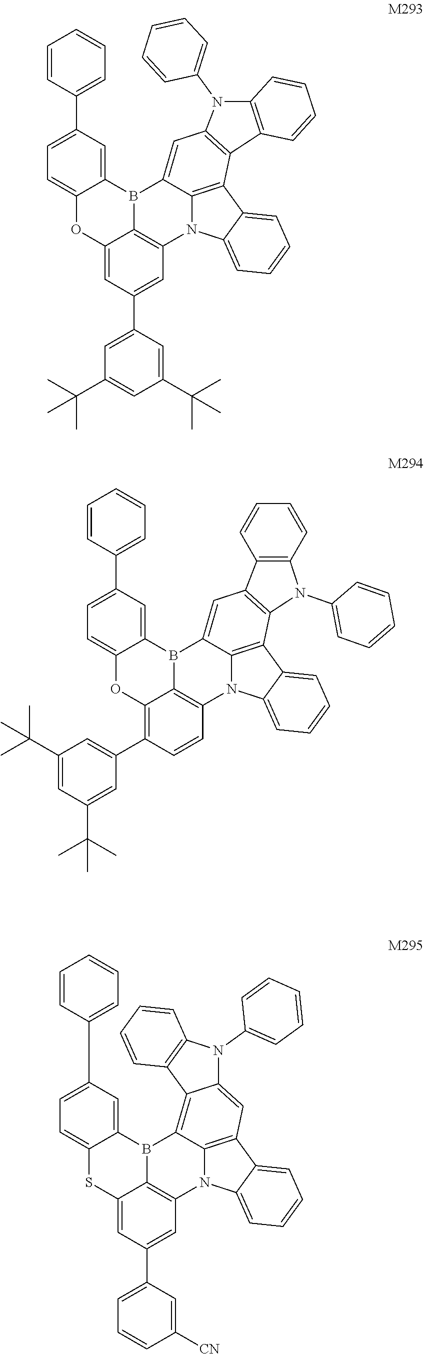 [SMILES: CC(C)(C)c1cc(-c2cc3c4c(c2)-n2c5ccccc5c5c6c7ccccc7n(-c7ccccc7)c6cc(c52)B4c2cc(-c4ccccc4)ccc2O3)cc(C(C)(C)C)c1 ; CC(C)(C)c1cc(-c2ccc3c4c2Oc2ccc(-c5ccccc5)cc2B4c2cc4c5ccccc5n(-c5ccccc5)c4c4c5ccccc5n-3c24)cc(C(C)(C)C)c1 ; N#Cc1cccc(-c2cc3c4c(c2)-n2c5ccccc5c5cc6c(c(c52)B4c2cc(-c4ccccc4)ccc2S3)c2ccccc2n6-c2ccccc2)c1]

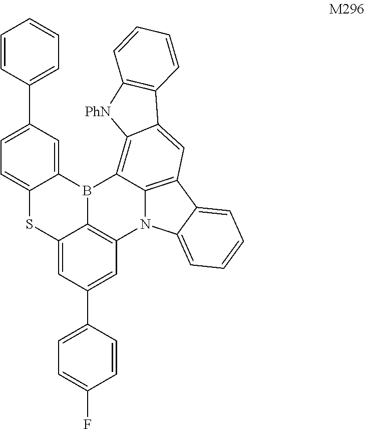

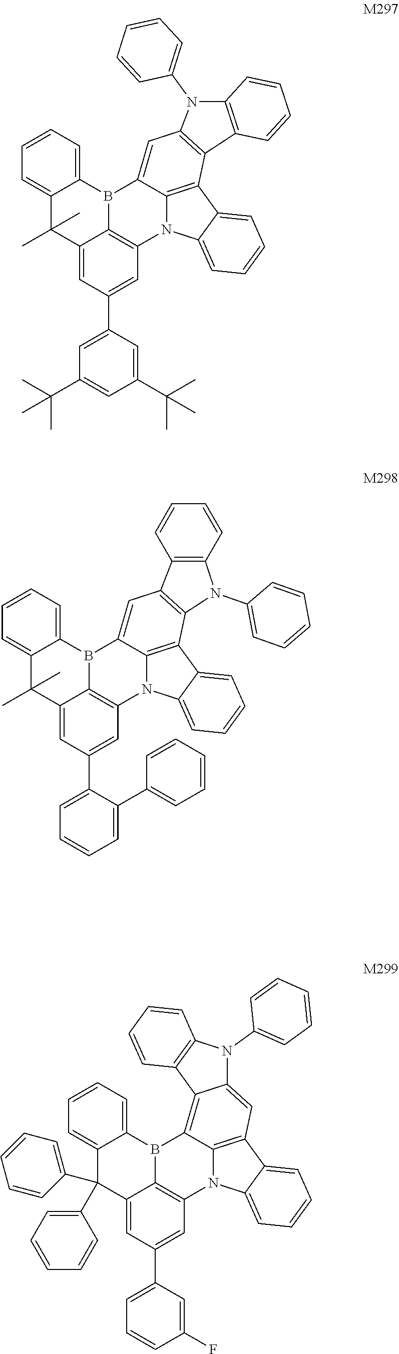

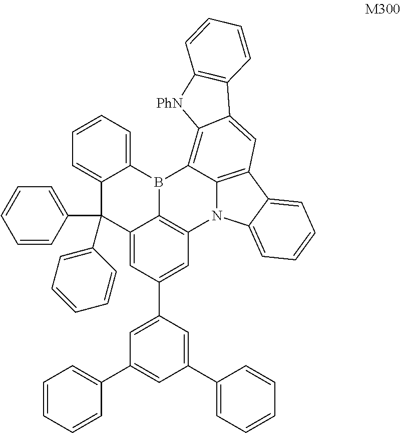

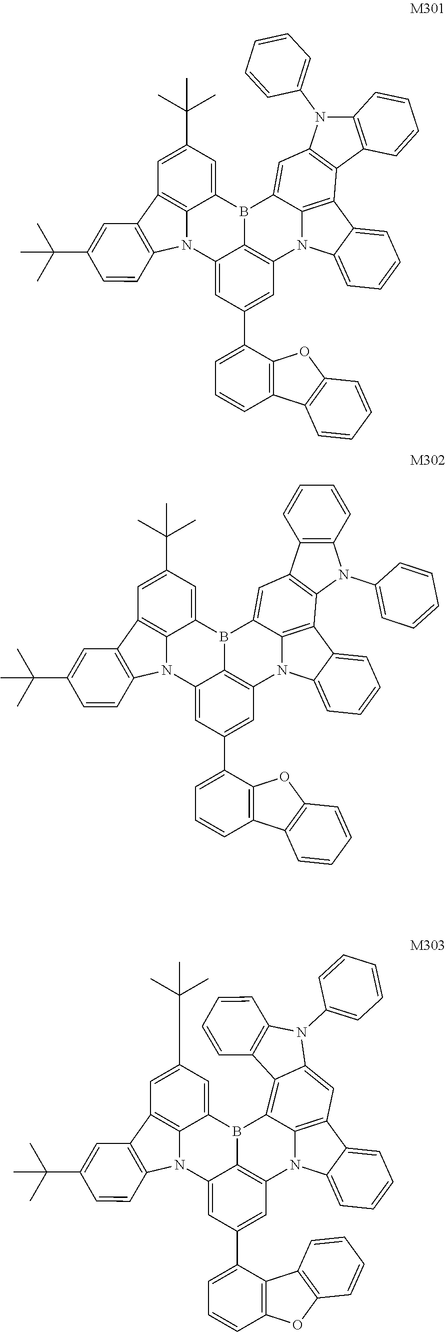 [SMILES: CC(C)(C)c1ccc2c(c1)c1cc(C(C)(C)C)cc3c1n2-c1cc(-c2cccc4c2oc2ccccc24)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2cccc4c2oc2ccccc24)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2cccc4oc5ccccc5c24)cc2c1B3c1c3c4ccccc4n(-c4ccccc4)c3cc3c4ccccc4n-2c13]

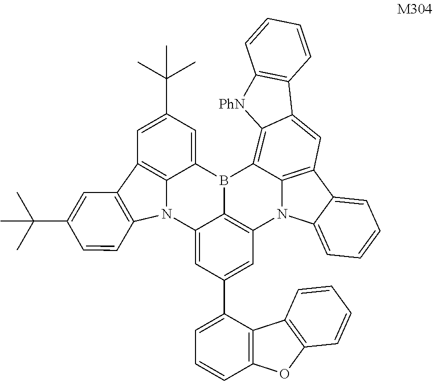

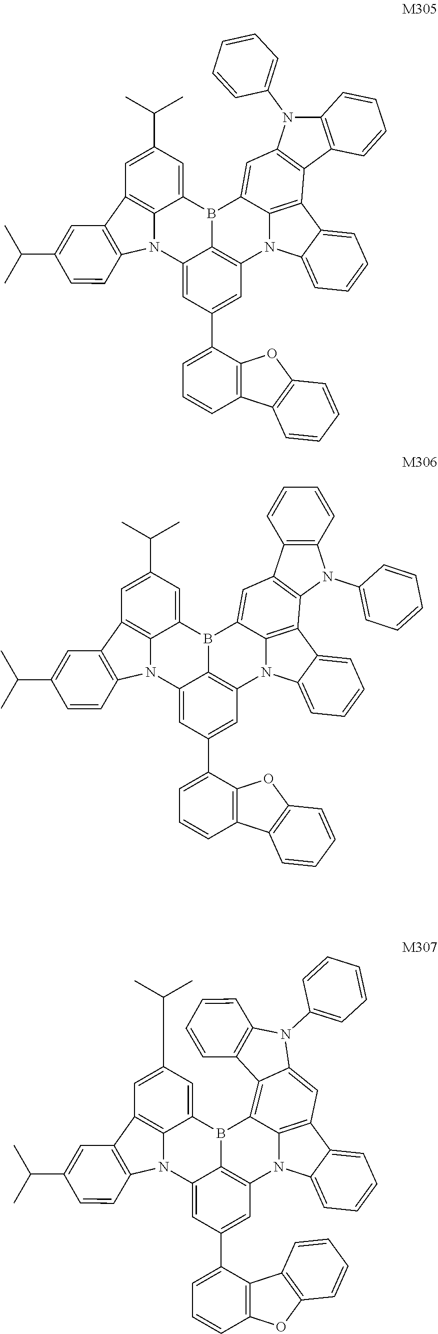

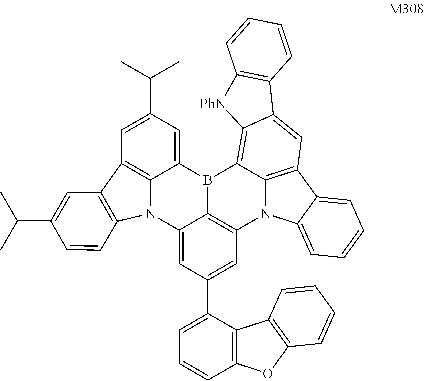

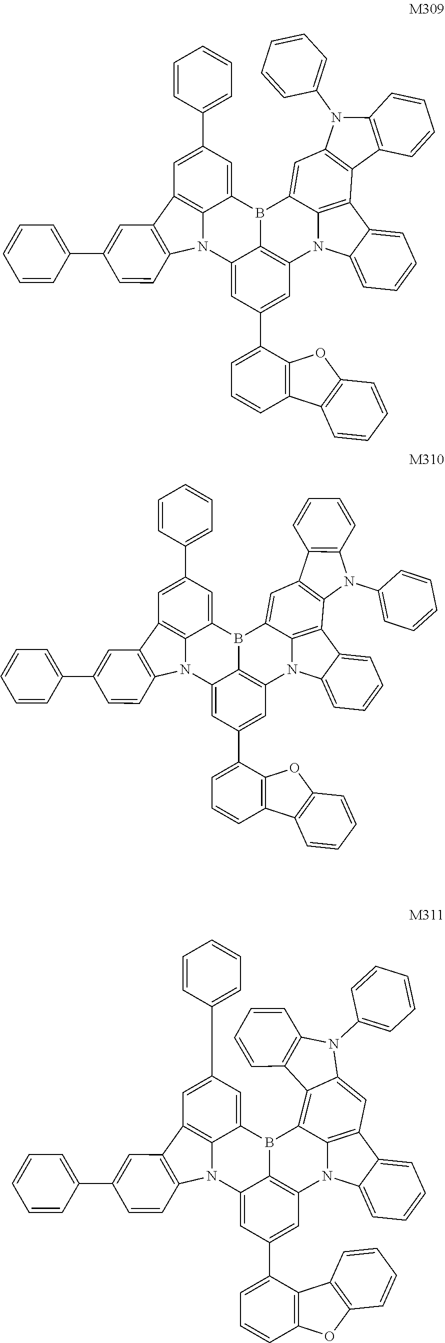 [SMILES: c1ccc(-c2ccc3c(c2)c2cc(-c4ccccc4)cc4c2n3-c2cc(-c3cccc5c3oc3ccccc35)cc3c2B4c2cc4c(c5ccccc5n4-c4ccccc4)c4c5ccccc5n-3c24)cc1 ; c1ccc(-c2ccc3c(c2)c2cc(-c4ccccc4)cc4c2n3-c2cc(-c3cccc5c3oc3ccccc35)cc3c2B4c2cc4c5ccccc5n(-c5ccccc5)c4c4c5ccccc5n-3c24)cc1 ; c1ccc(-c2ccc3c(c2)c2cc(-c4ccccc4)cc4c2n3-c2cc(-c3cccc5oc6ccccc6c35)cc3c2B4c2c4c5ccccc5n(-c5ccccc5)c4cc4c5ccccc5n-3c24)cc1]

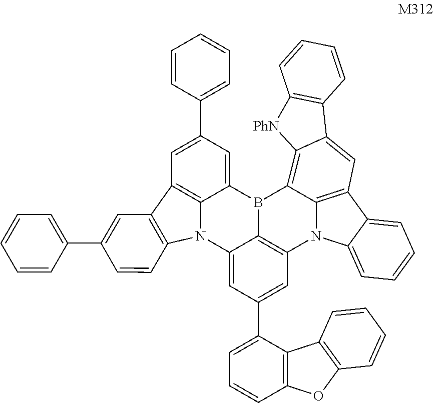

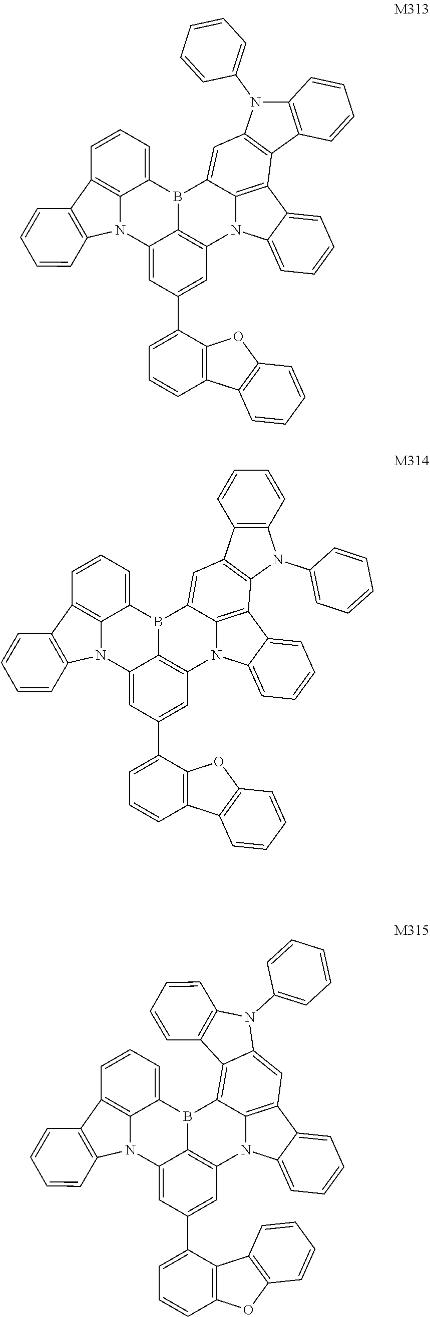 [SMILES: c1ccc(-n2c3ccccc3c3c4c5ccccc5n5c4c(cc32)B2c3c(cc(-c4cccc6c4oc4ccccc46)cc3-5)-n3c4ccccc4c4cccc2c43)cc1 ; c1ccc(-n2c3ccccc3c3cc4c5c(c6ccccc6n5-c5cc(-c6cccc7c6oc6ccccc67)cc6c5B4c4cccc5c7ccccc7n-6c45)c32)cc1 ; c1ccc(-n2c3ccccc3c3c4c5c(cc32)c2ccccc2n5-c2cc(-c3cccc5oc6ccccc6c35)cc3c2B4c2cccc4c5ccccc5n-3c24)cc1]

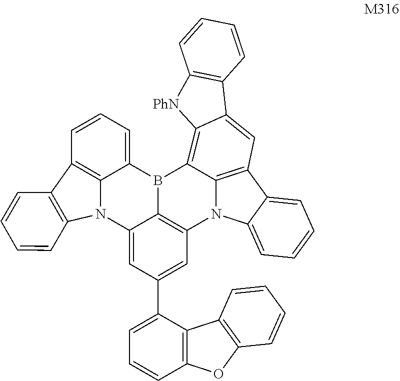

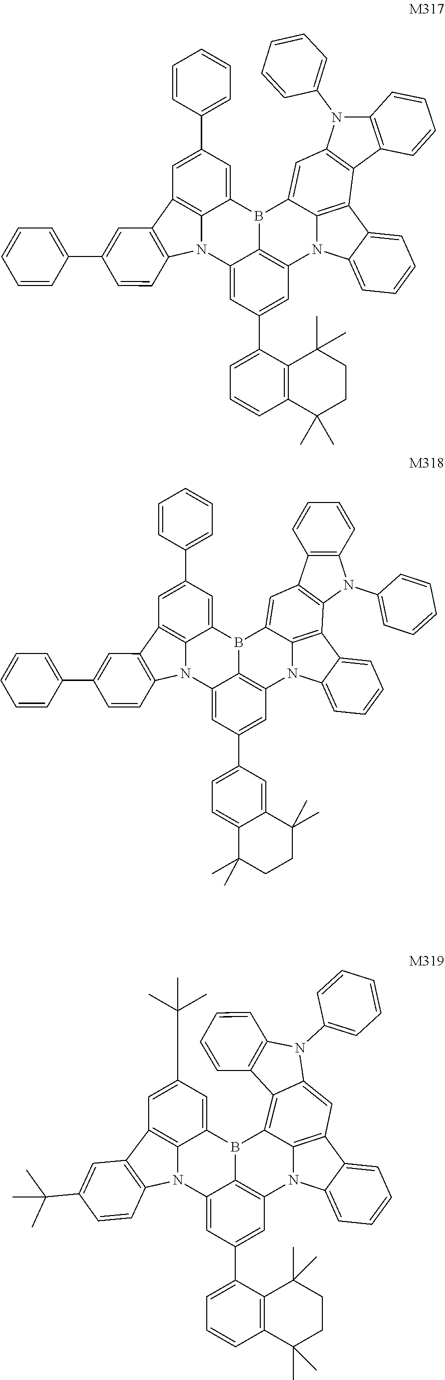 [SMILES: CC1(C)CCC(C)(C)c2c(-c3cc4c5c(c3)-n3c6ccccc6c6c7c8ccccc8n(-c8ccccc8)c7cc(c63)B5c3cc(-c5ccccc5)cc5c6cc(-c7ccccc7)ccc6n-4c35)cccc21 ; CC1(C)CCC(C)(C)c2cc(-c3cc4c5c(c3)-n3c6ccccc6c6c3c(cc3c7ccccc7n(-c7ccccc7)c36)B5c3cc(-c5ccccc5)cc5c6cc(-c7ccccc7)ccc6n-4c35)ccc21 ; CC(C)(C)c1ccc2c(c1)c1cc(C(C)(C)C)cc3c1n2-c1cc(-c2cccc4c2C(C)(C)CCC4(C)C)cc2c1B3c1c3c4ccccc4n(-c4ccccc4)c3cc3c4ccccc4n-2c13]

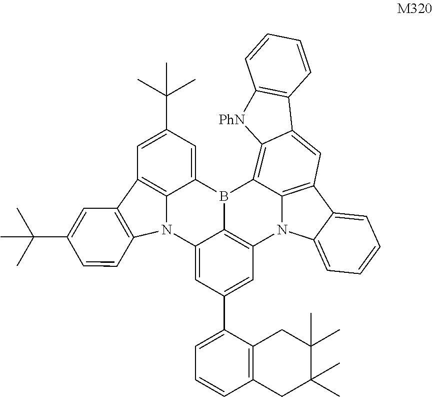

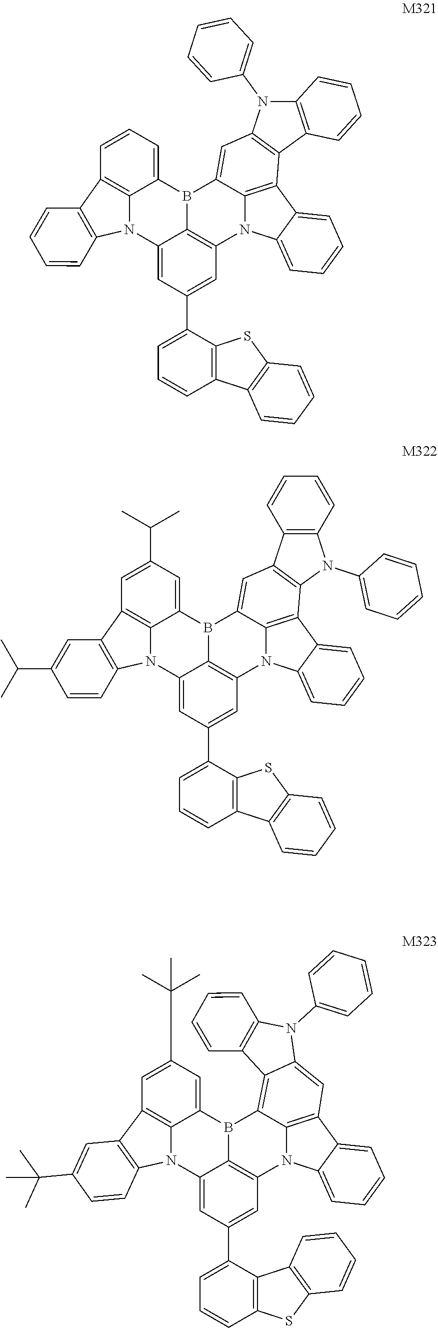 [SMILES: c1ccc(-n2c3ccccc3c3c4c5ccccc5n5c4c(cc32)B2c3c(cc(-c4cccc6c4sc4ccccc46)cc3-5)-n3c4ccccc4c4cccc2c43)cc1 ; CC(C)c1ccc2c(c1)c1cc(C(C)C)cc3c1n2-c1cc(-c2cccc4c2sc2ccccc24)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2cccc4sc5ccccc5c24)cc2c1B3c1c3c4ccccc4n(-c4ccccc4)c3cc3c4ccccc4n-2c13]

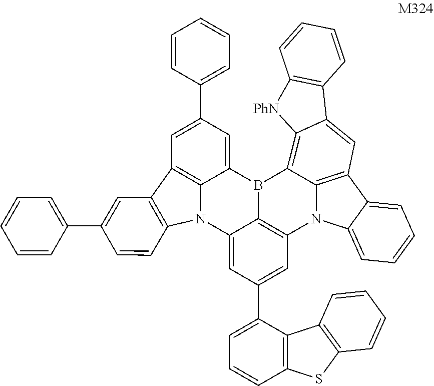

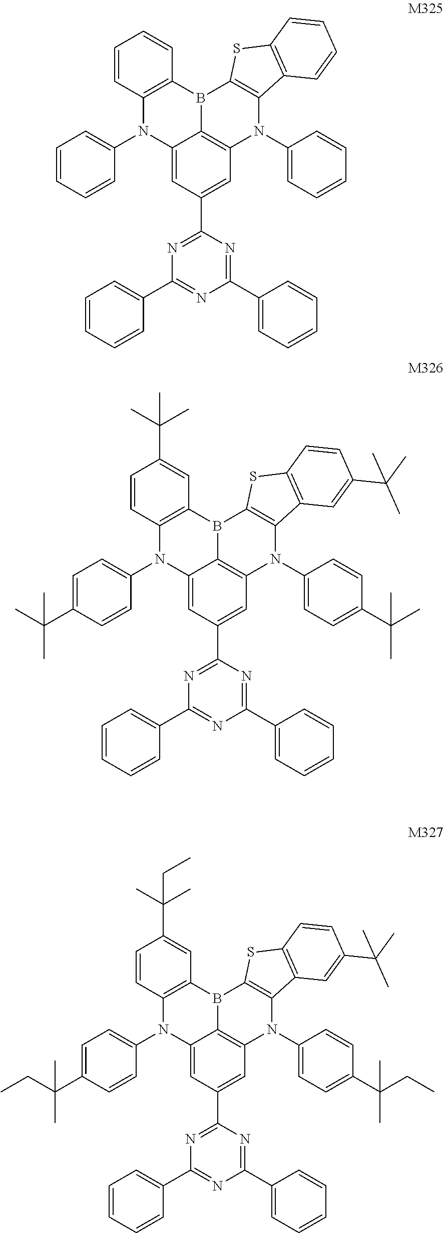

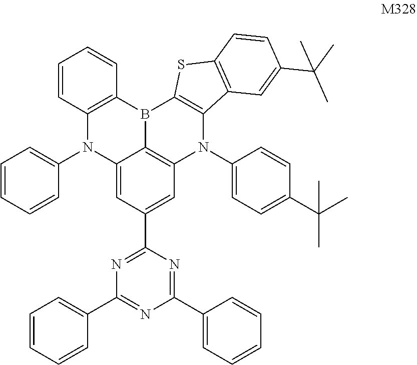 [SMILES: CC(C)(C)c1ccc(N2c3cc(-c4nc(-c5ccccc5)nc(-c5ccccc5)n4)cc4c3B(c3ccccc3N4c3ccccc3)c3sc4ccc(C(C)(C)C)cc4c32)cc1]

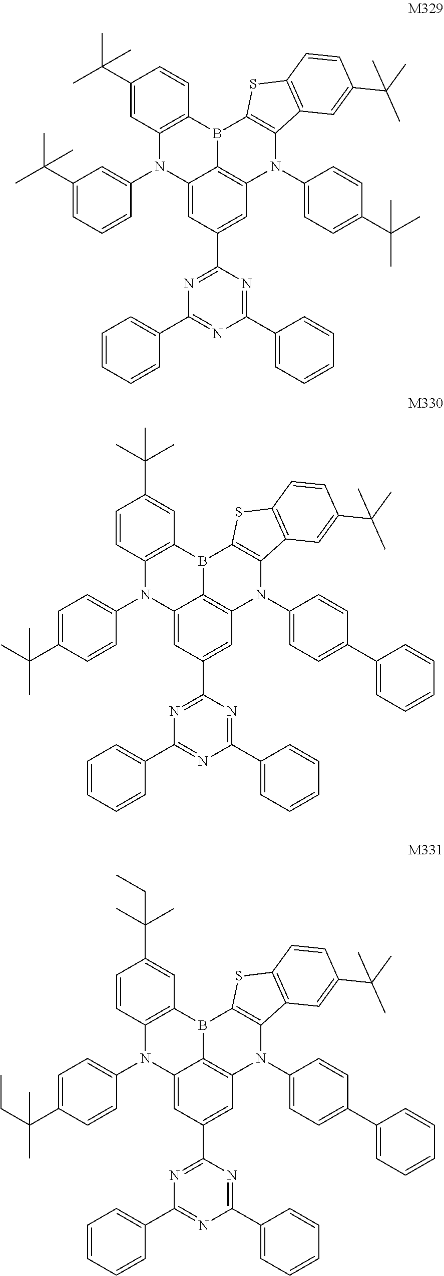

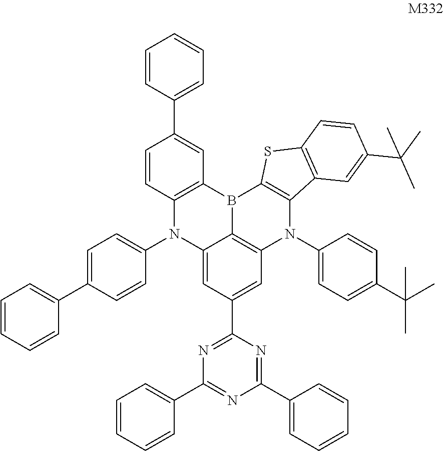 [SMILES: CC(C)(C)c1ccc(N2c3cc(-c4nc(-c5ccccc5)nc(-c5ccccc5)n4)cc4c3B(c3cc(-c5ccccc5)ccc3N4c3ccc(-c4ccccc4)cc3)c3sc4ccc(C(C)(C)C)cc4c32)cc1]

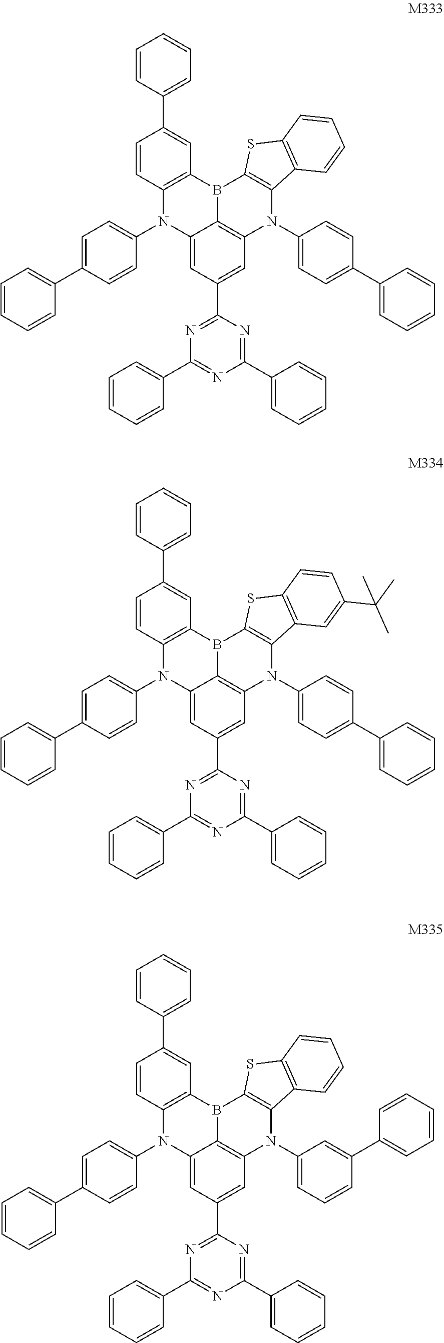 [SMILES: c1ccc(-c2ccc(N3c4ccc(-c5ccccc5)cc4B4c5sc6ccccc6c5N(c5ccc(-c6ccccc6)cc5)c5cc(-c6nc(-c7ccccc7)nc(-c7ccccc7)n6)cc3c54)cc2)cc1 ; CC(C)(C)c1ccc2sc3c(c2c1)N(c1ccc(-c2ccccc2)cc1)c1cc(-c2nc(-c4ccccc4)nc(-c4ccccc4)n2)cc2c1B3c1cc(-c3ccccc3)ccc1N2c1ccc(-c2ccccc2)cc1 ; c1ccc(-c2ccc(N3c4ccc(-c5ccccc5)cc4B4c5sc6ccccc6c5N(c5cccc(-c6ccccc6)c5)c5cc(-c6nc(-c7ccccc7)nc(-c7ccccc7)n6)cc3c54)cc2)cc1]

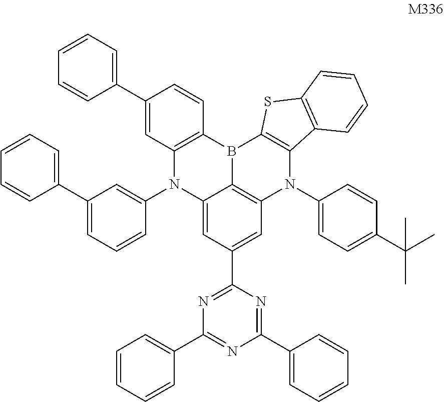 [SMILES: CC(C)(C)c1ccc(N2c3cc(-c4nc(-c5ccccc5)nc(-c5ccccc5)n4)cc4c3B(c3ccc(-c5ccccc5)cc3N4c3cccc(-c4ccccc4)c3)c3sc4ccccc4c32)cc1]

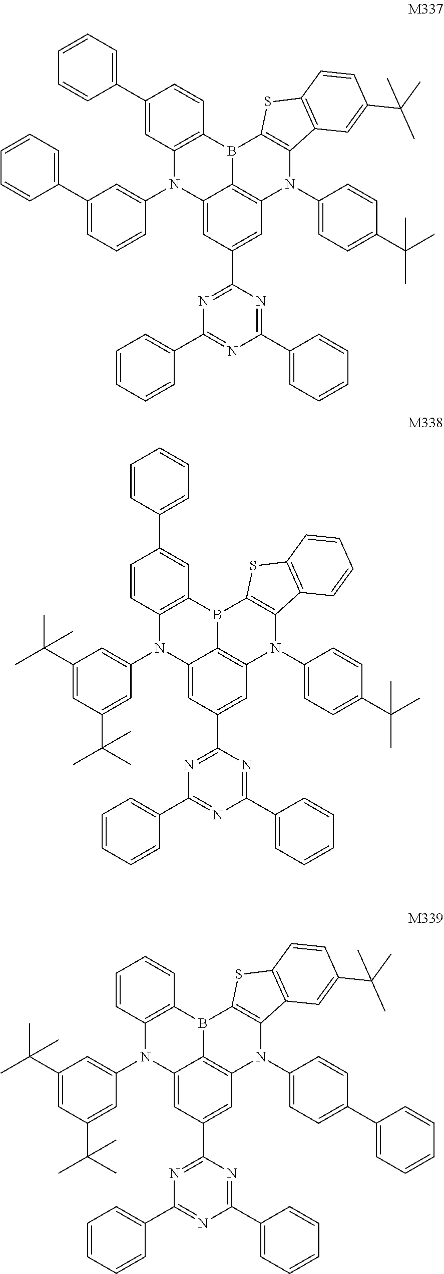

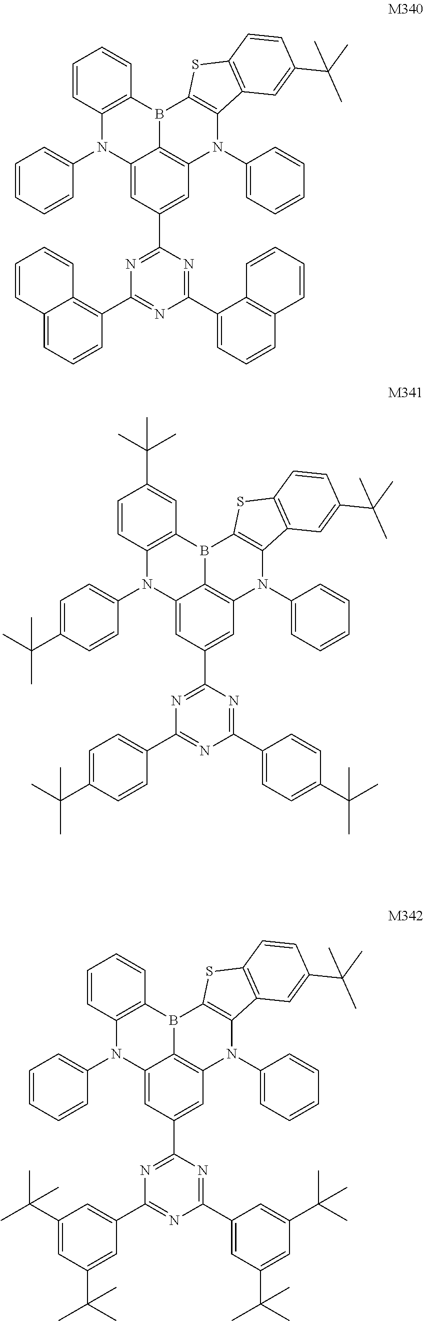

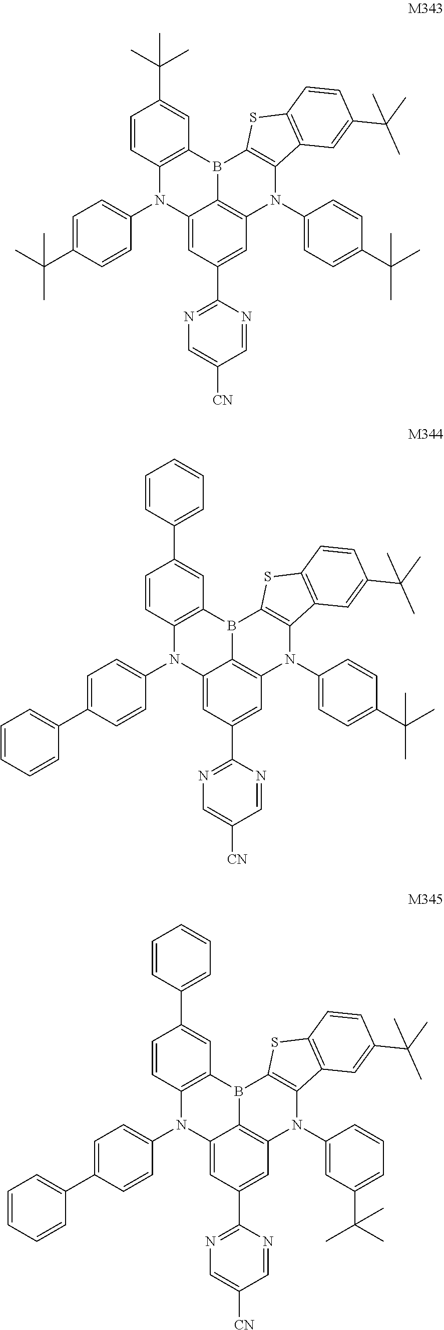 [SMILES: CC(C)(C)c1ccc(N2c3ccc(C(C)(C)C)cc3B3c4sc5ccc(C(C)(C)C)cc5c4N(c4ccc(C(C)(C)C)cc4)c4cc(-c5ncc(C#N)cn5)cc2c43)cc1 ; CC(C)(C)c1ccc(N2c3cc(-c4ncc(C#N)cn4)cc4c3B(c3cc(-c5ccccc5)ccc3N4c3ccc(-c4ccccc4)cc3)c3sc4ccc(C(C)(C)C)cc4c32)cc1 ; CC(C)(C)c1cccc(N2c3cc(-c4ncc(C#N)cn4)cc4c3B(c3cc(-c5ccccc5)ccc3N4c3ccc(-c4ccccc4)cc3)c3sc4ccc(C(C)(C)C)cc4c32)c1]

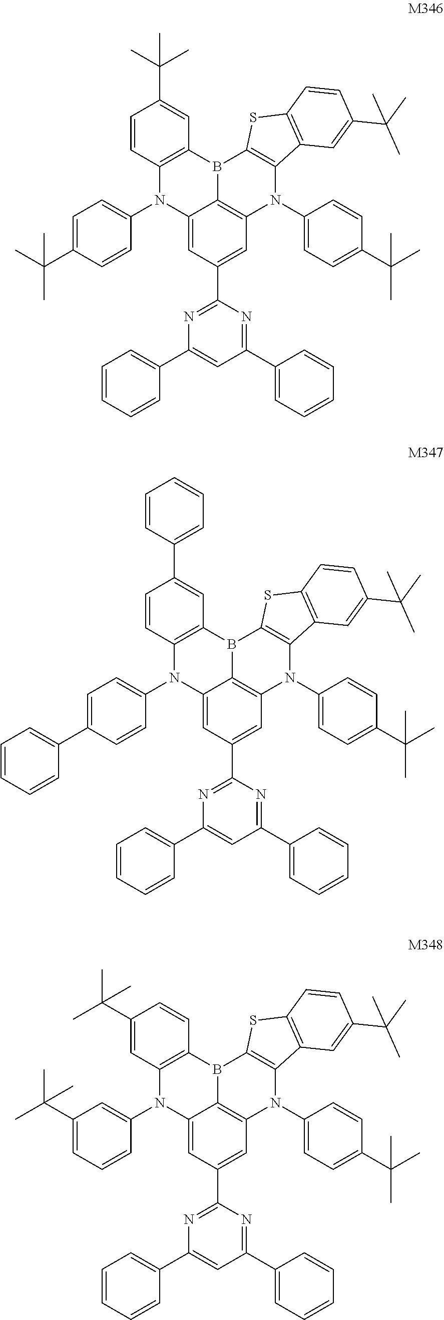

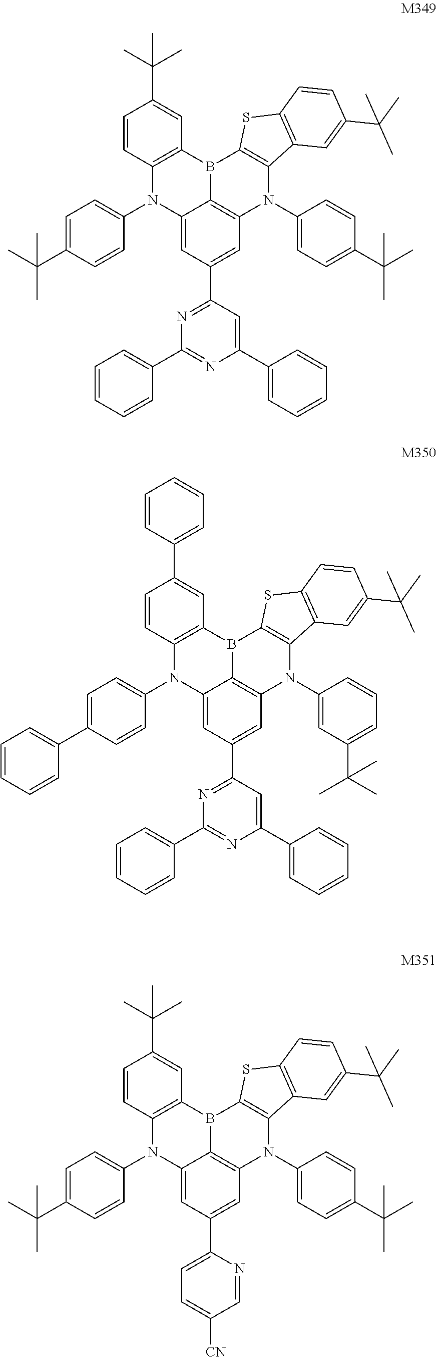

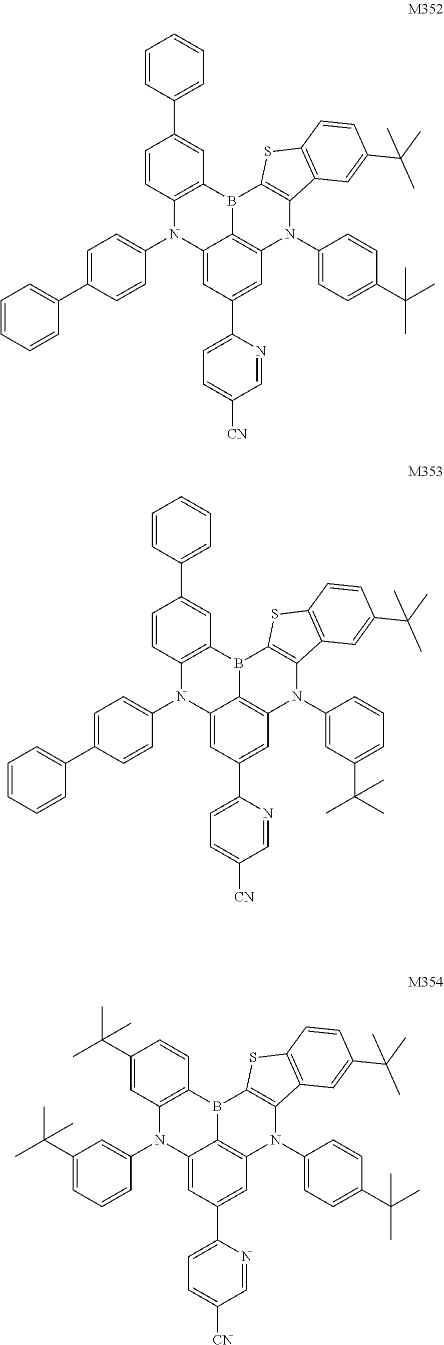

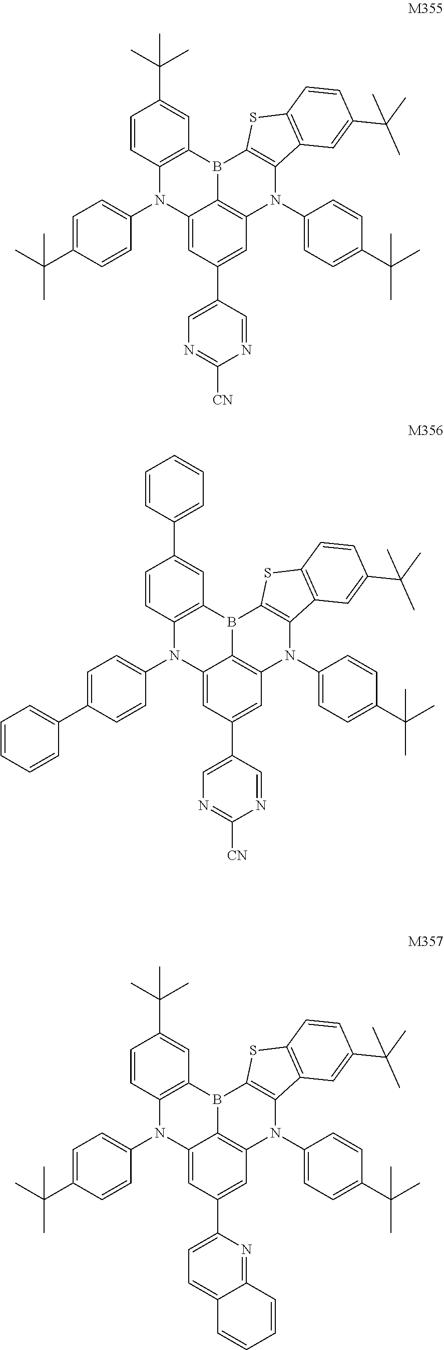

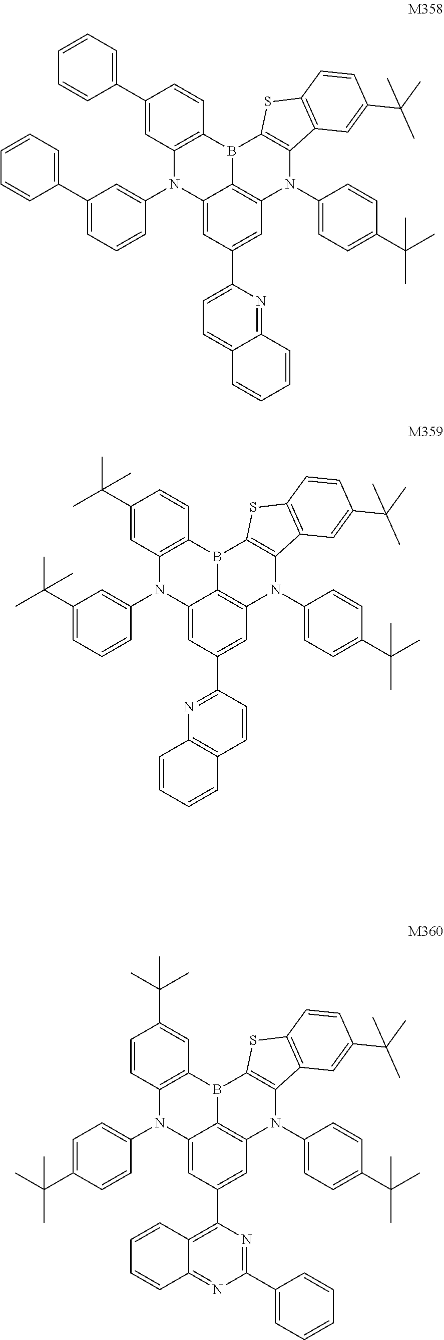

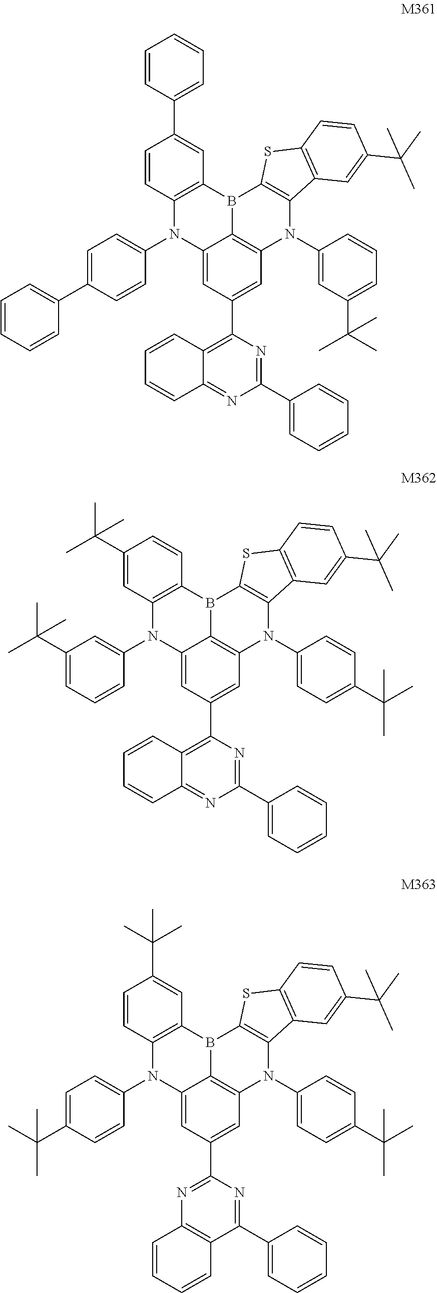

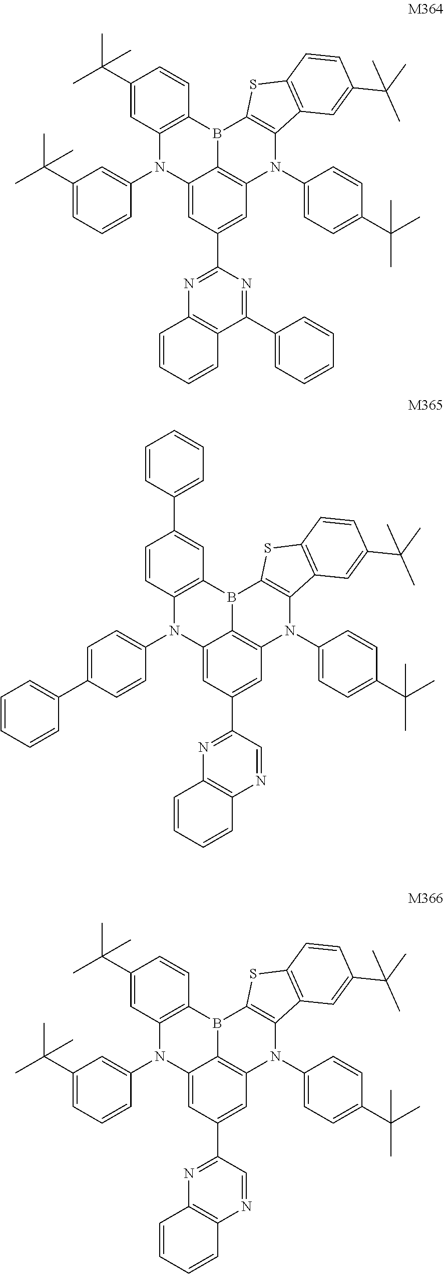

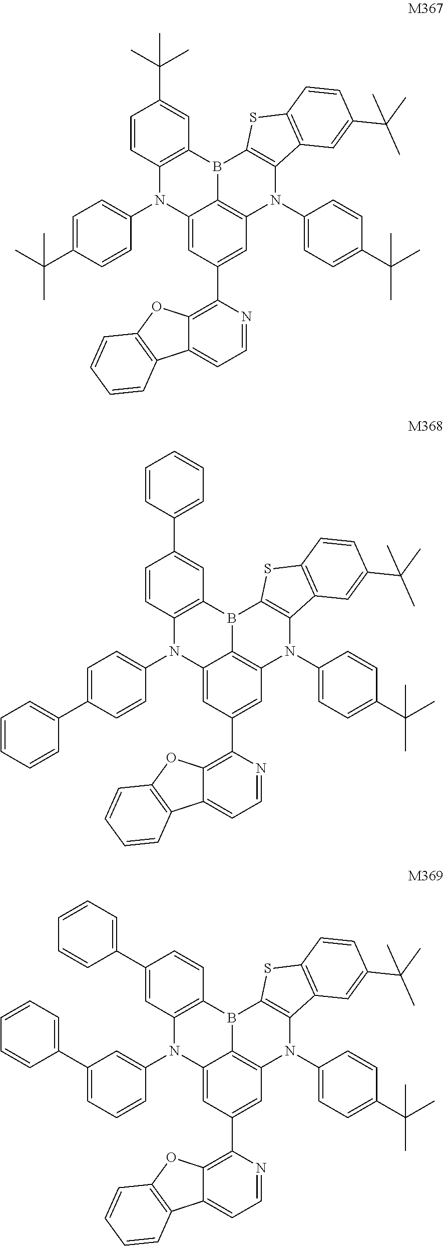 [SMILES: CC(C)(C)c1ccc(N2c3ccc(C(C)(C)C)cc3B3c4sc5ccc(C(C)(C)C)cc5c4N(c4ccc(C(C)(C)C)cc4)c4cc(-c5nccc6c5oc5ccccc56)cc2c43)cc1 ; CC(C)(C)c1ccc(N2c3cc(-c4nccc5c4oc4ccccc45)cc4c3B(c3cc(-c5ccccc5)ccc3N4c3ccc(-c4ccccc4)cc3)c3sc4ccc(C(C)(C)C)cc4c32)cc1 ; CC(C)(C)c1ccc(N2c3cc(-c4nccc5c4oc4ccccc45)cc4c3B(c3ccc(-c5ccccc5)cc3N4c3cccc(-c4ccccc4)c3)c3sc4ccc(C(C)(C)C)cc4c32)cc1]

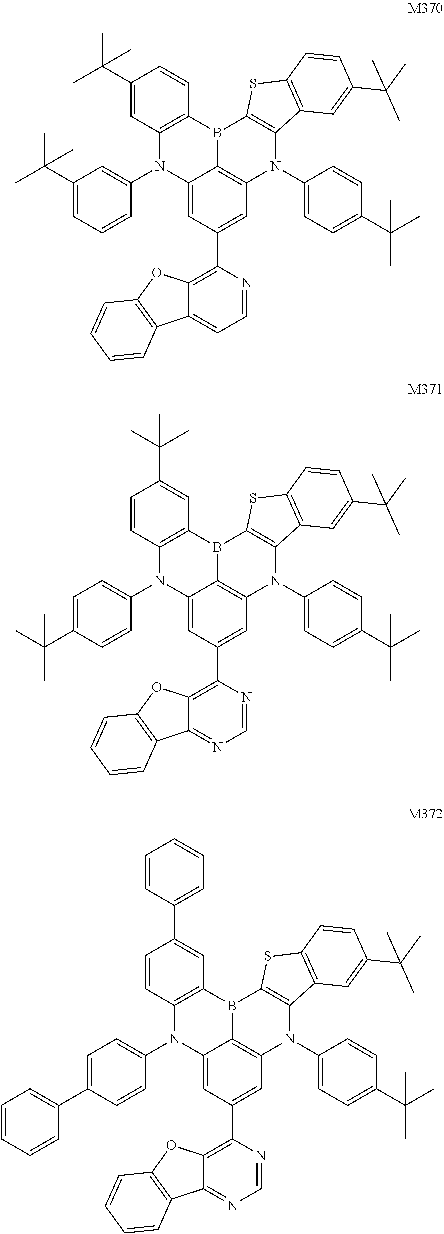

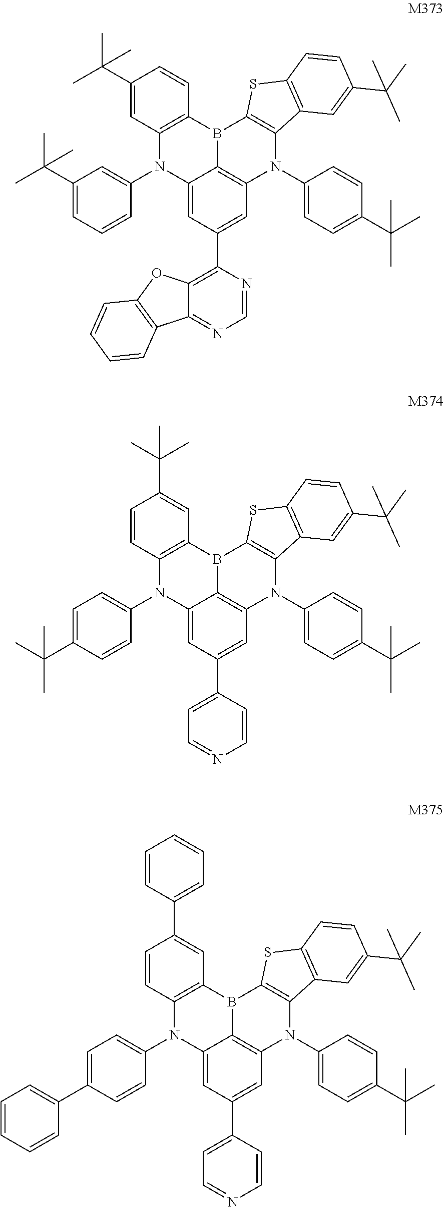

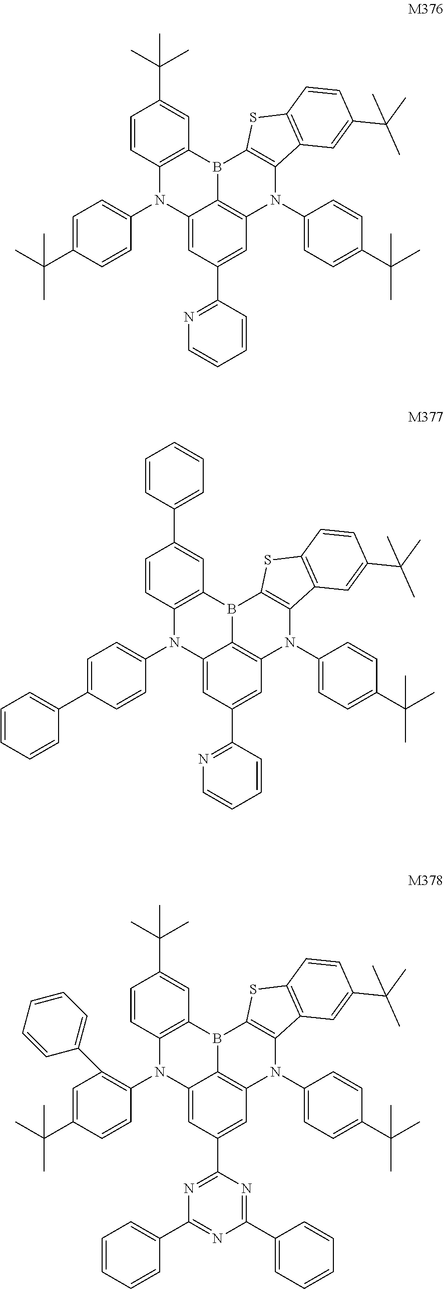

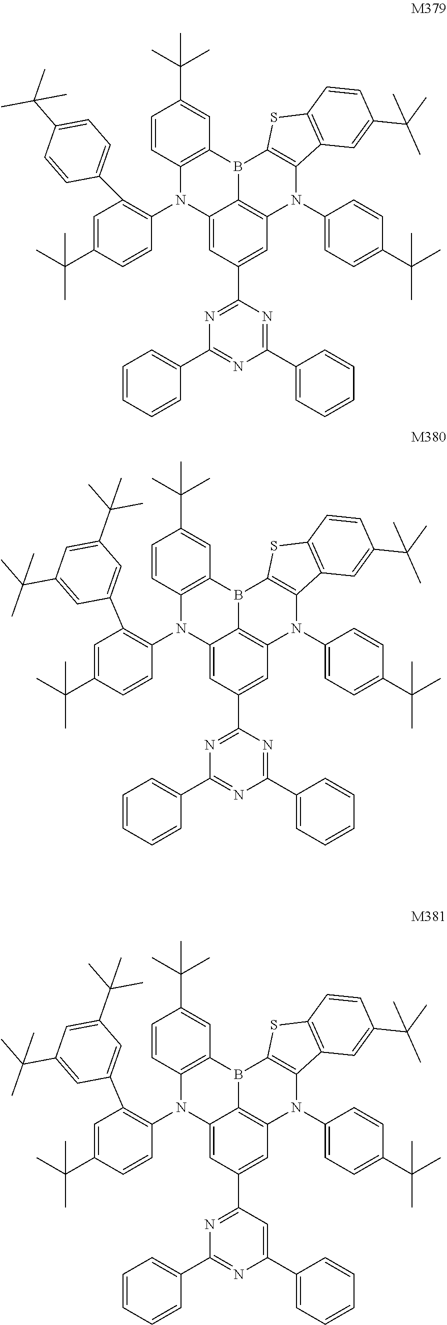

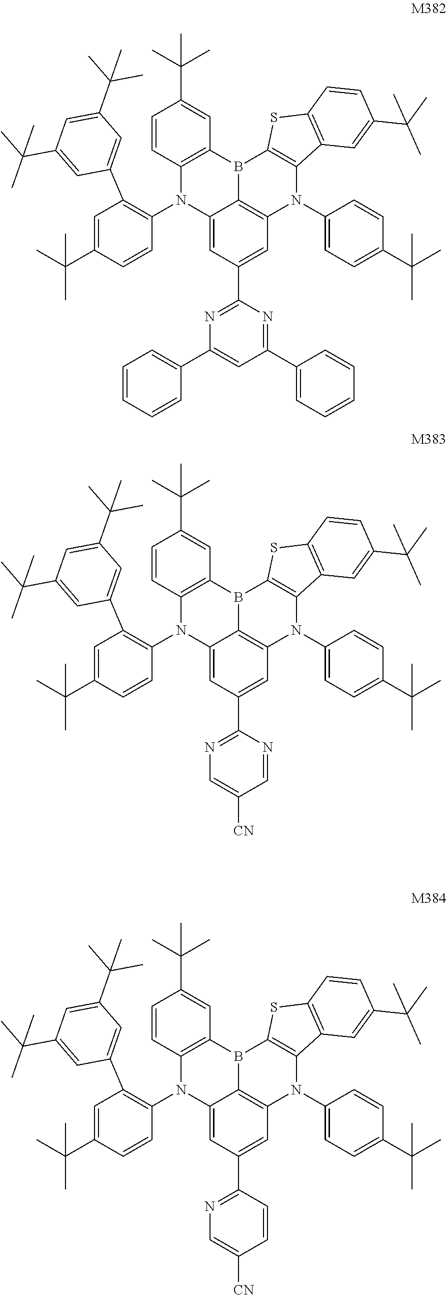

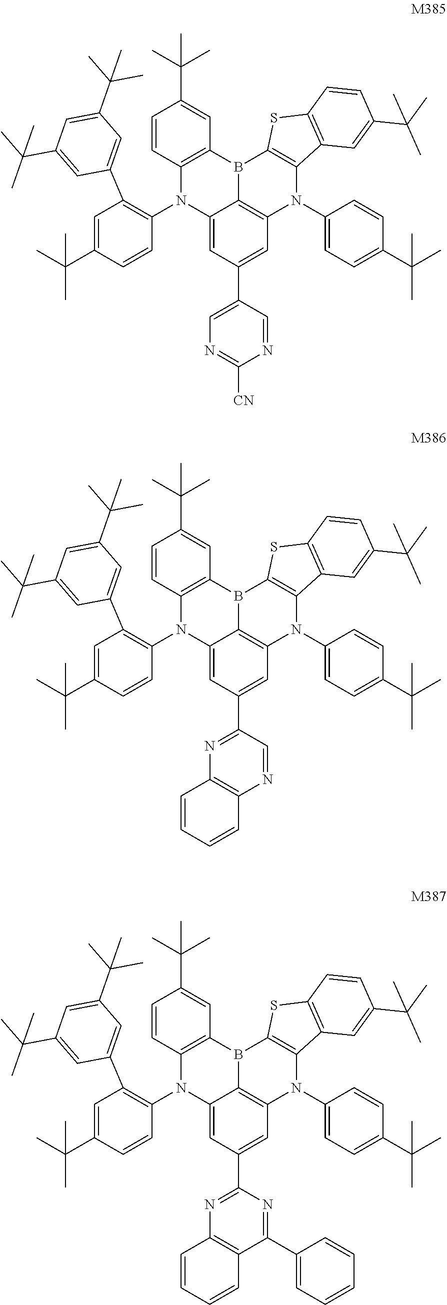

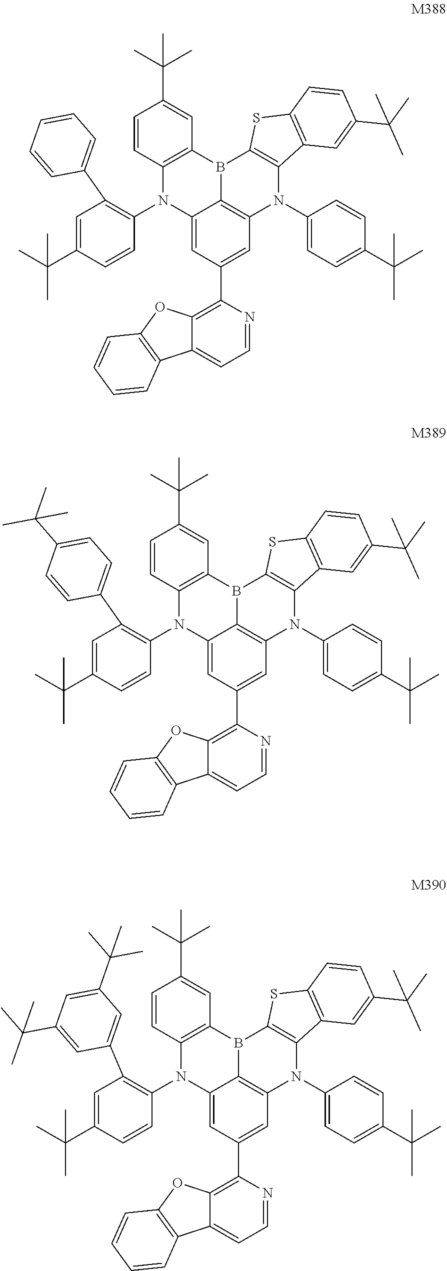

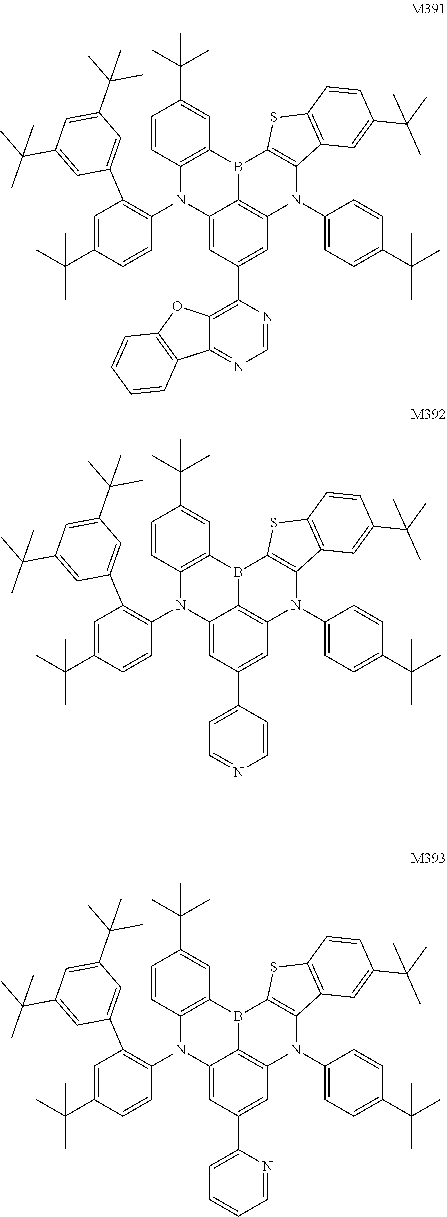

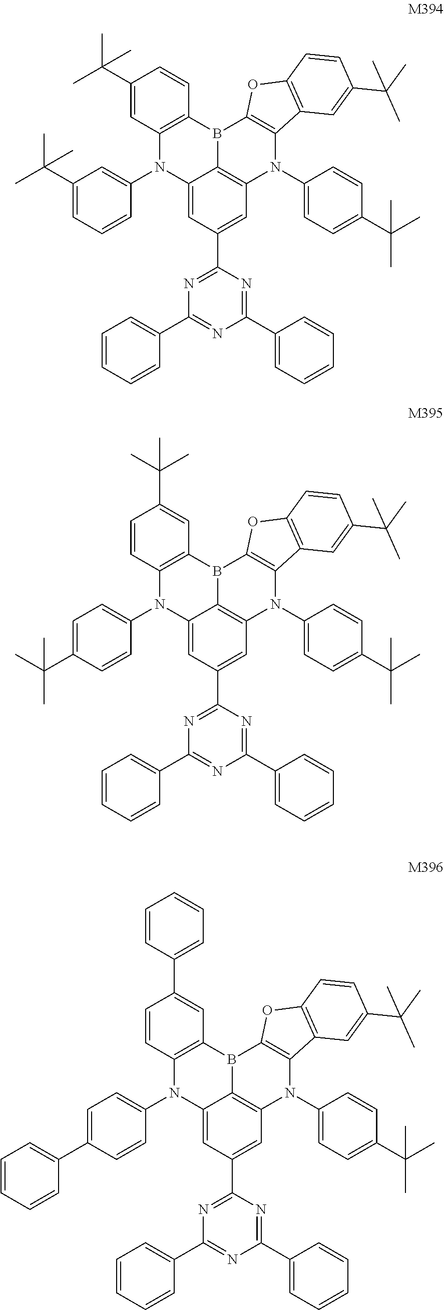

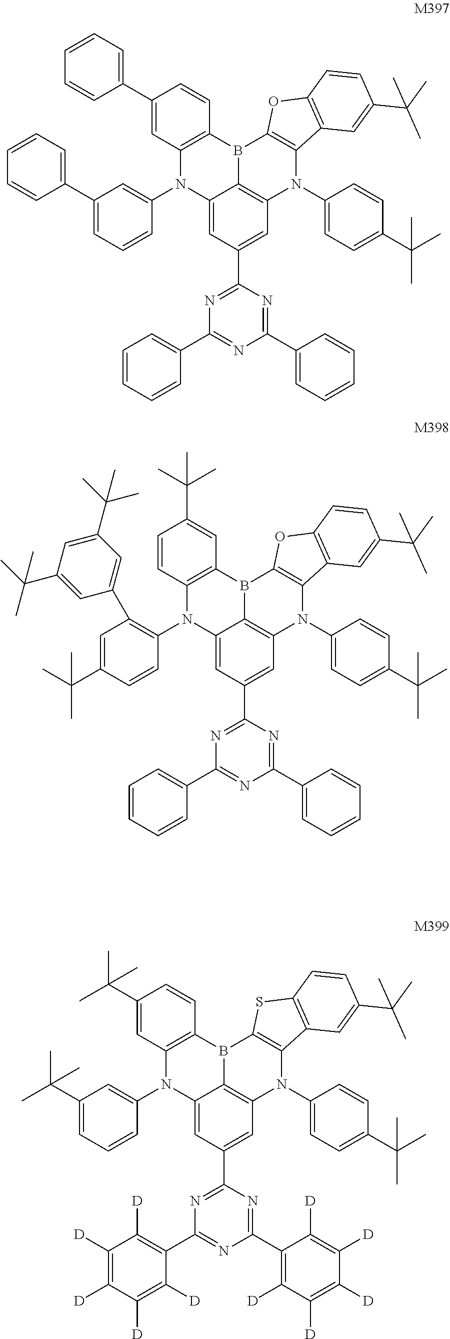

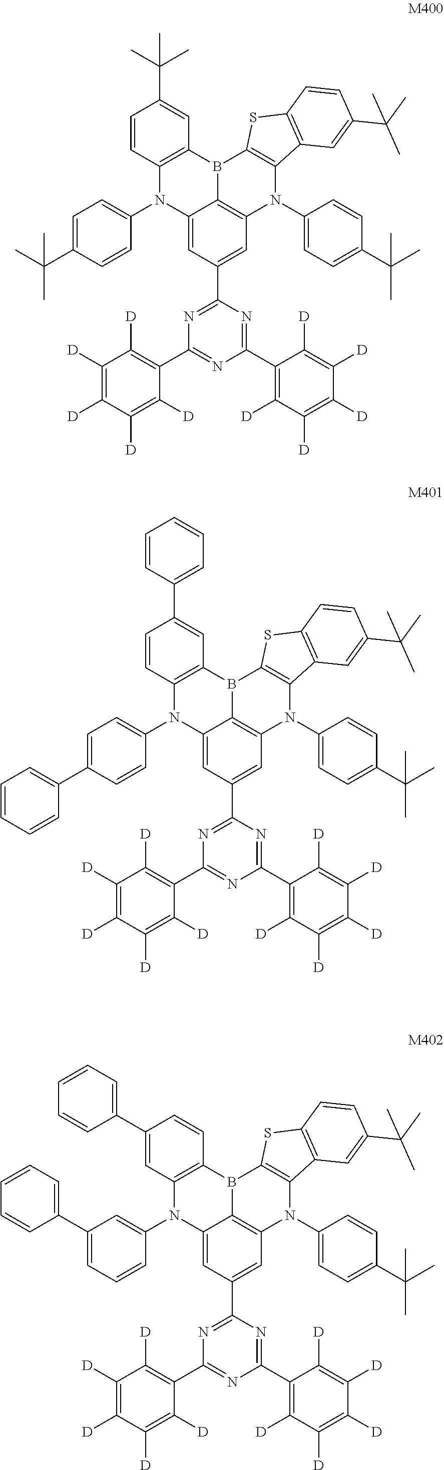

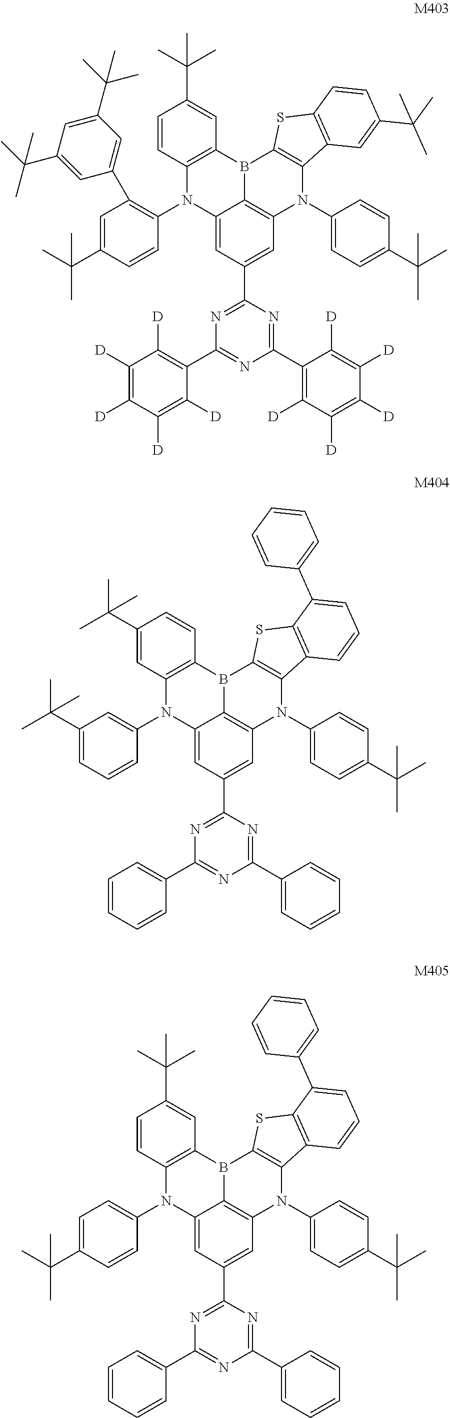

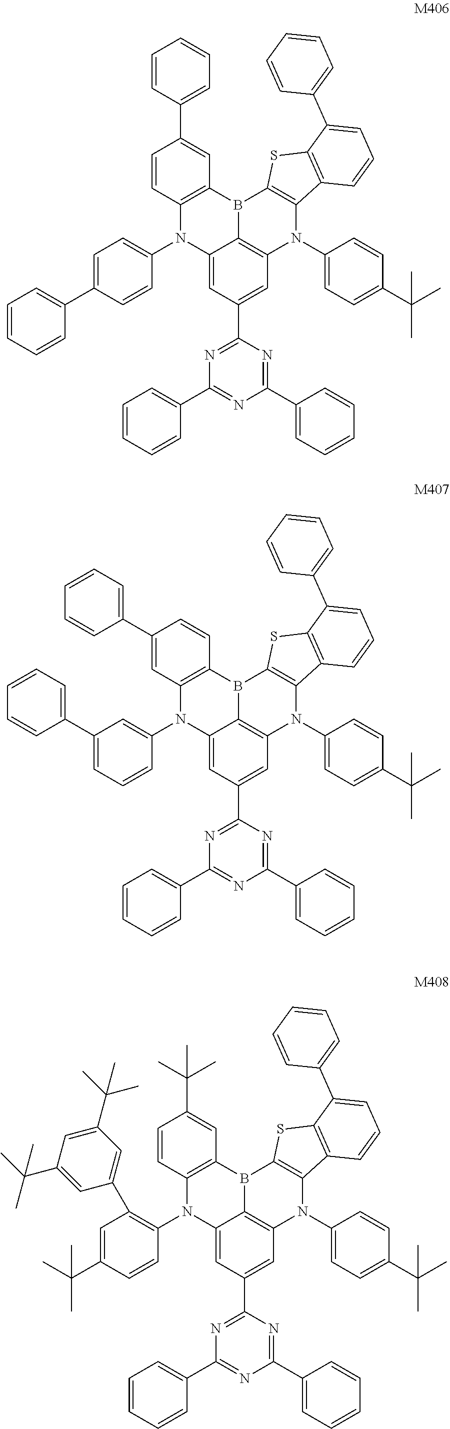

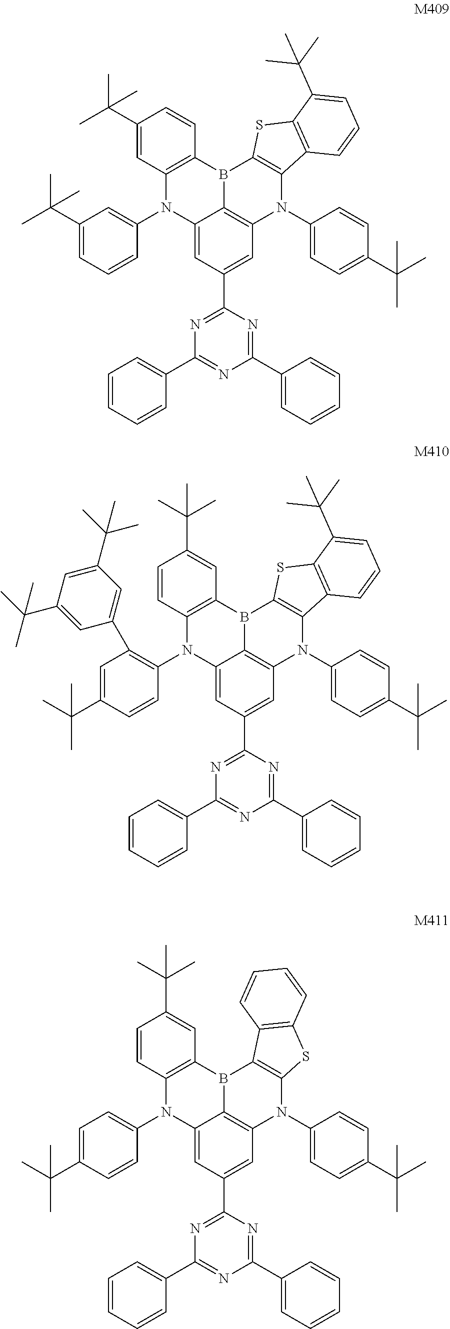

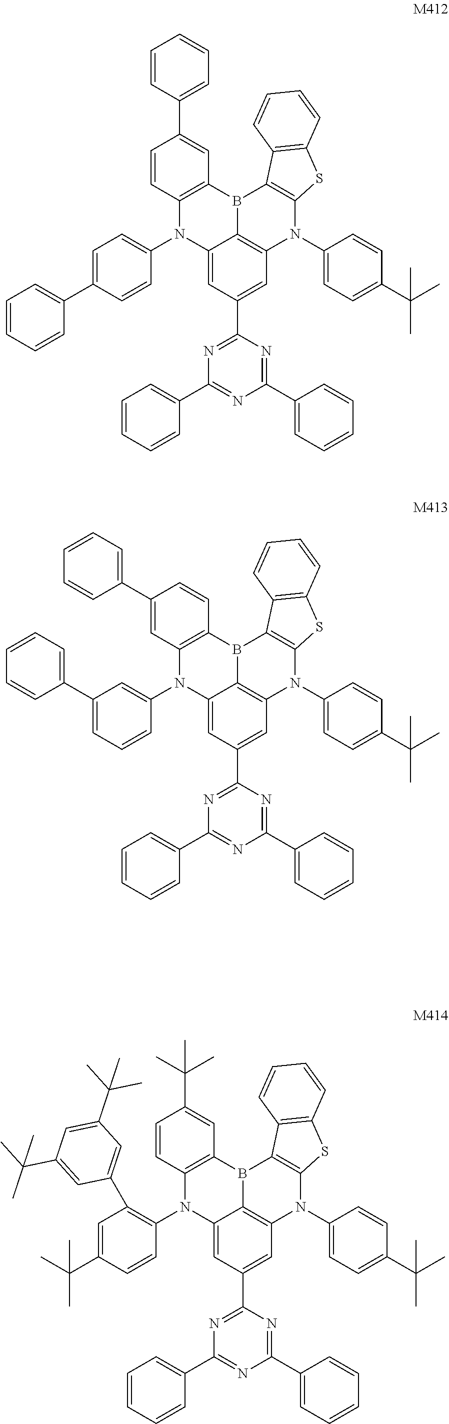

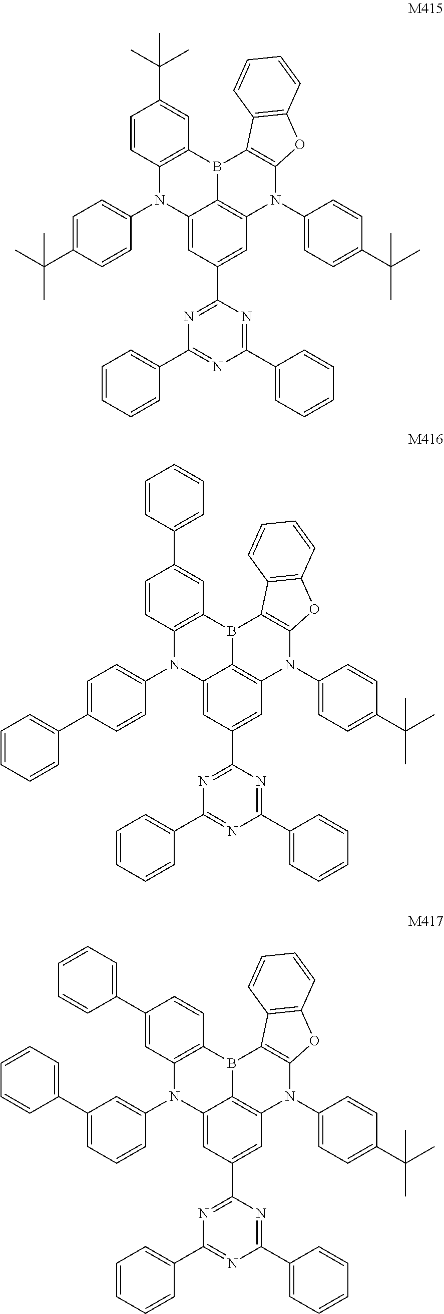 [SMILES: CC(C)(C)c1ccc(N2c3ccc(C(C)(C)C)cc3B3c4c2cc(-c2nc(-c5ccccc5)nc(-c5ccccc5)n2)cc4N(c2ccc(C(C)(C)C)cc2)c2oc4ccccc4c23)cc1 ; CC(C)(C)c1ccc(N2c3cc(-c4nc(-c5ccccc5)nc(-c5ccccc5)n4)cc4c3B(c3cc(-c5ccccc5)ccc3N4c3ccc(-c4ccccc4)cc3)c3c2oc2ccccc32)cc1 ; CC(C)(C)c1ccc(N2c3cc(-c4nc(-c5ccccc5)nc(-c5ccccc5)n4)cc4c3B(c3ccc(-c5ccccc5)cc3N4c3cccc(-c4ccccc4)c3)c3c2oc2ccccc32)cc1]

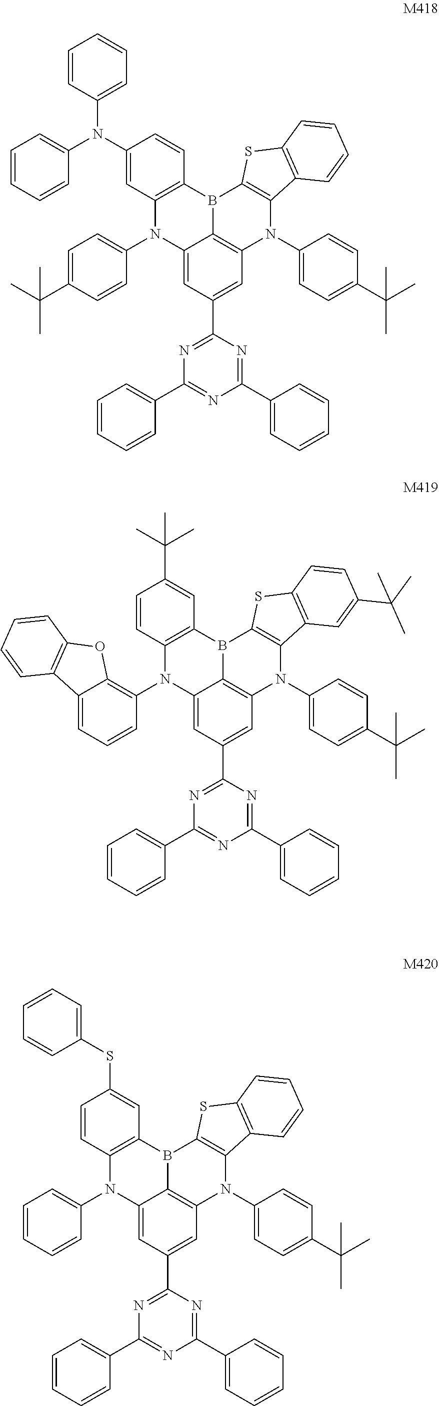 [SMILES: CC(C)(C)c1ccc(N2c3cc(N(c4ccccc4)c4ccccc4)ccc3B3c4sc5ccccc5c4N(c4ccc(C(C)(C)C)cc4)c4cc(-c5nc(-c6ccccc6)nc(-c6ccccc6)n5)cc2c43)cc1 ; CC(C)(C)c1ccc(N2c3cc(-c4nc(-c5ccccc5)nc(-c5ccccc5)n4)cc4c3B(c3cc(C(C)(C)C)ccc3N4c3cccc4c3oc3ccccc34)c3sc4ccc(C(C)(C)C)cc4c32)cc1 ; CC(C)(C)c1ccc(N2c3cc(-c4nc(-c5ccccc5)nc(-c5ccccc5)n4)cc4c3B(c3cc(Sc5ccccc5)ccc3N4c3ccccc3)c3sc4ccccc4c32)cc1]

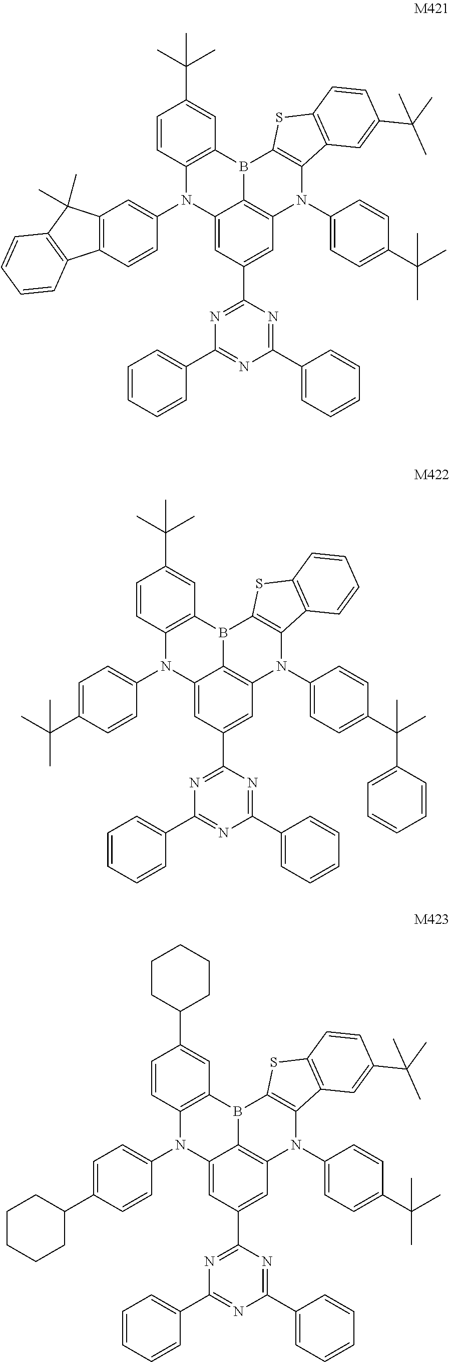

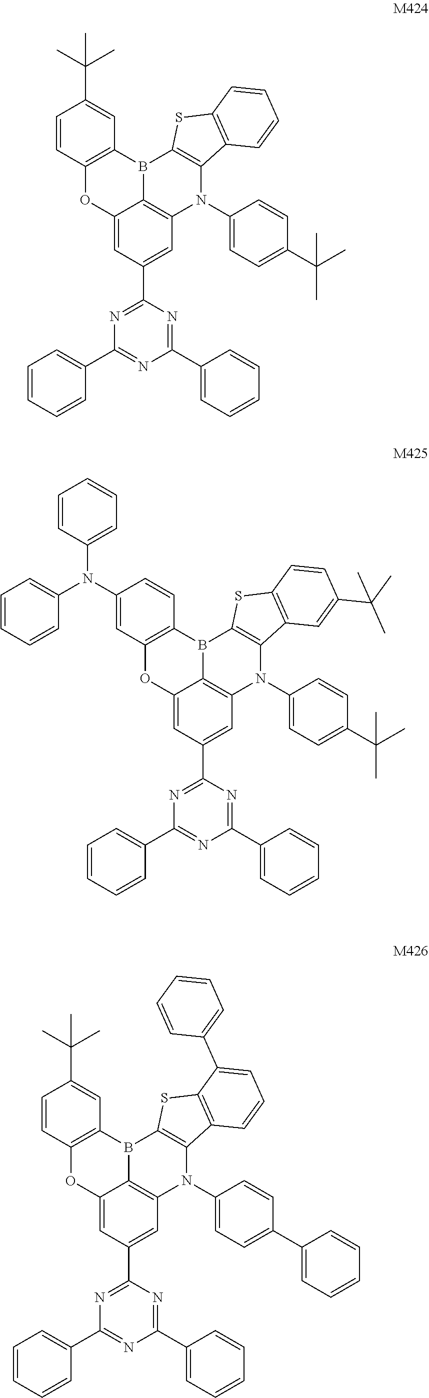 [SMILES: CC(C)(C)c1ccc(N2c3cc(-c4nc(-c5ccccc5)nc(-c5ccccc5)n4)cc4c3B(c3cc(C(C)(C)C)ccc3O4)c3sc4ccccc4c32)cc1 ; CC(C)(C)c1ccc(N2c3cc(-c4nc(-c5ccccc5)nc(-c5ccccc5)n4)cc4c3B(c3ccc(N(c5ccccc5)c5ccccc5)cc3O4)c3sc4ccc(C(C)(C)C)cc4c32)cc1 ; CC(C)(C)c1ccc2c(c1)B1c3sc4c(-c5ccccc5)cccc4c3N(c3ccc(-c4ccccc4)cc3)c3cc(-c4nc(-c5ccccc5)nc(-c5ccccc5)n4)cc(c31)O2]

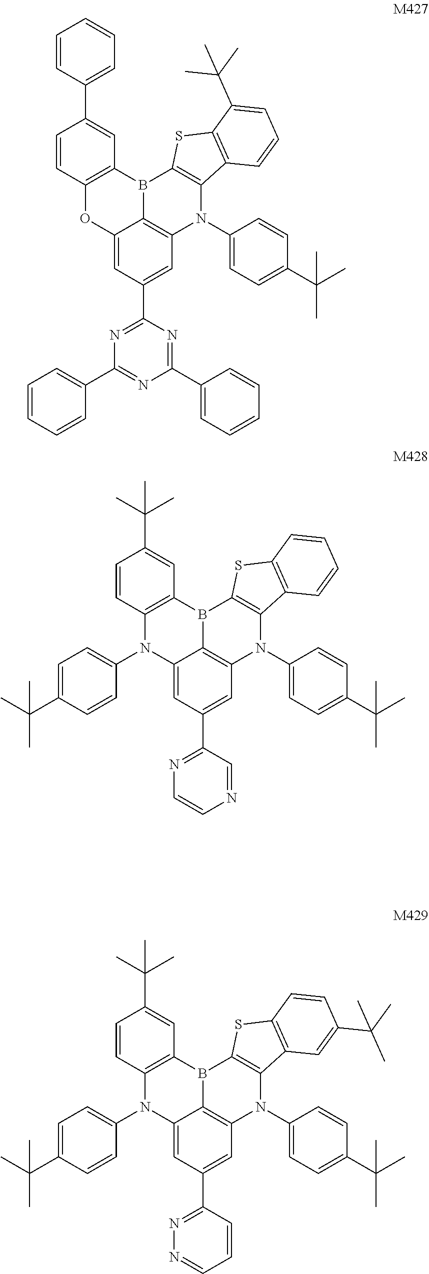

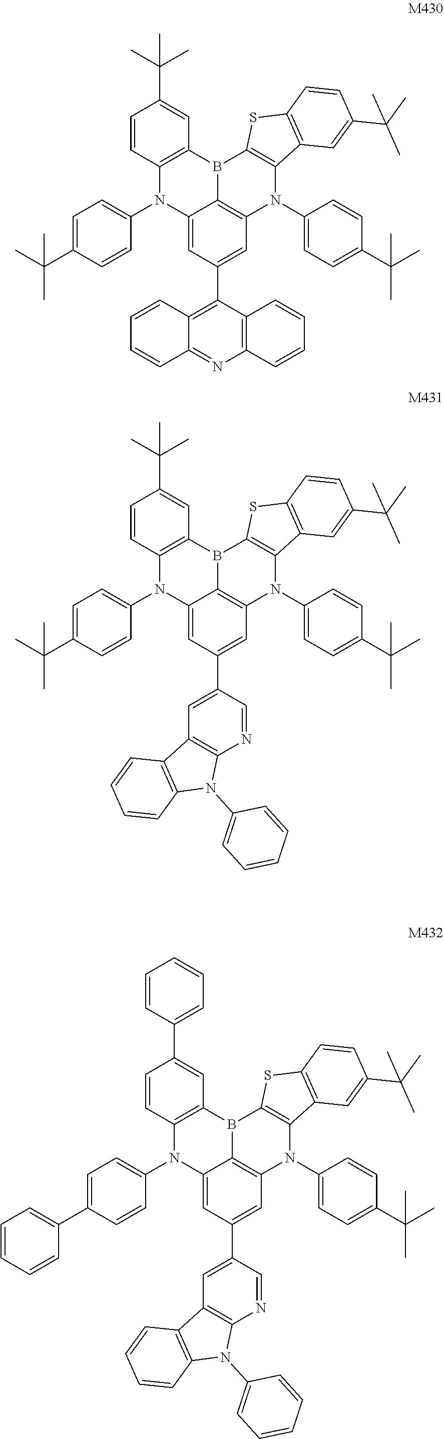

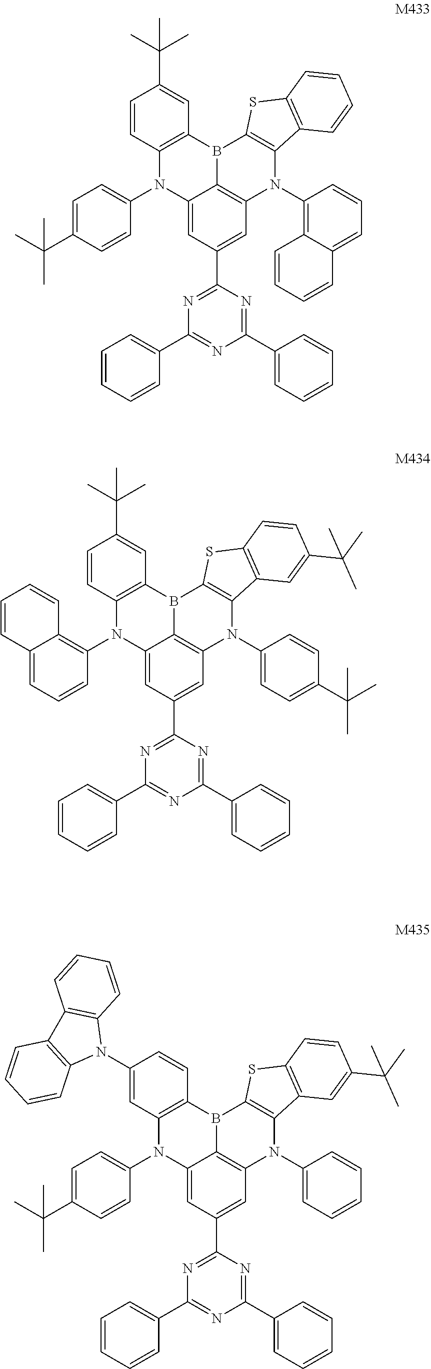 [SMILES: CC(C)(C)c1ccc(N2c3ccc(C(C)(C)C)cc3B3c4sc5ccccc5c4N(c4cccc5ccccc45)c4cc(-c5nc(-c6ccccc6)nc(-c6ccccc6)n5)cc2c43)cc1 ; CC(C)(C)c1ccc(N2c3cc(-c4nc(-c5ccccc5)nc(-c5ccccc5)n4)cc4c3B(c3cc(C(C)(C)C)ccc3N4c3cccc4ccccc34)c3sc4ccc(C(C)(C)C)cc4c32)cc1 ; CC(C)(C)c1ccc(N2c3cc(-n4c5ccccc5c5ccccc54)ccc3B3c4sc5ccc(C(C)(C)C)cc5c4N(c4ccccc4)c4cc(-c5nc(-c6ccccc6)nc(-c6ccccc6)n5)cc2c43)cc1]

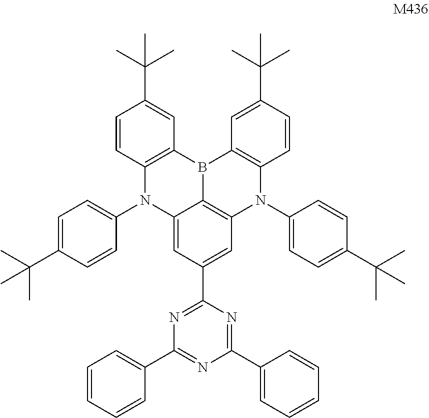 [SMILES: CC(C)(C)c1ccc(N2c3ccc(C(C)(C)C)cc3B3c4cc(C(C)(C)C)ccc4N(c4ccc(C(C)(C)C)cc4)c4cc(-c5nc(-c6ccccc6)nc(-c6ccccc6)n5)cc2c43)cc1]

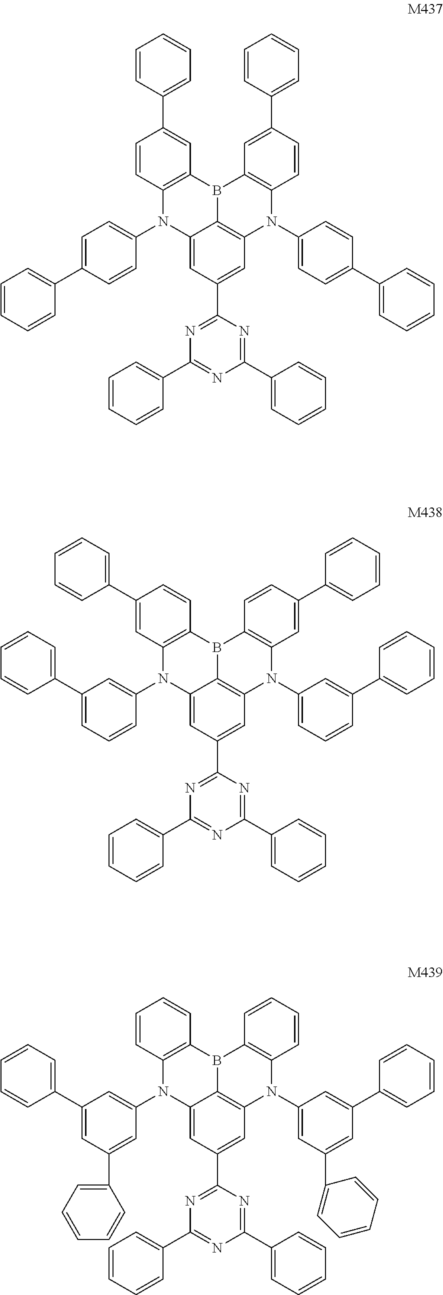 [SMILES: c1ccc(-c2ccc(N3c4ccc(-c5ccccc5)cc4B4c5cc(-c6ccccc6)ccc5N(c5ccc(-c6ccccc6)cc5)c5cc(-c6nc(-c7ccccc7)nc(-c7ccccc7)n6)cc3c54)cc2)cc1 ; c1ccc(-c2cccc(N3c4cc(-c5ccccc5)ccc4B4c5ccc(-c6ccccc6)cc5N(c5cccc(-c6ccccc6)c5)c5cc(-c6nc(-c7ccccc7)nc(-c7ccccc7)n6)cc3c54)c2)cc1 ; c1ccc(-c2cc(-c3ccccc3)cc(N3c4ccccc4B4c5ccccc5N(c5cc(-c6ccccc6)cc(-c6ccccc6)c5)c5cc(-c6nc(-c7ccccc7)nc(-c7ccccc7)n6)cc3c54)c2)cc1]

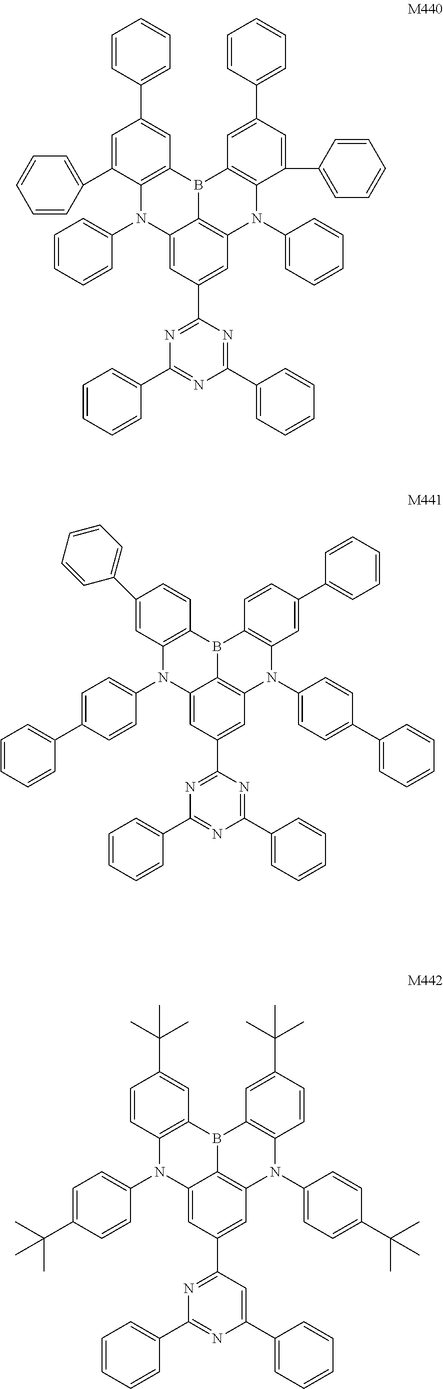 [SMILES: c1ccc(-c2cc3c(c(-c4ccccc4)c2)N(c2ccccc2)c2cc(-c4nc(-c5ccccc5)nc(-c5ccccc5)n4)cc4c2B3c2cc(-c3ccccc3)cc(-c3ccccc3)c2N4c2ccccc2)cc1 ; c1ccc(-c2ccc(N3c4cc(-c5ccccc5)ccc4B4c5ccc(-c6ccccc6)cc5N(c5ccc(-c6ccccc6)cc5)c5cc(-c6nc(-c7ccccc7)nc(-c7ccccc7)n6)cc3c54)cc2)cc1 ; CC(C)(C)c1ccc(N2c3ccc(C(C)(C)C)cc3B3c4cc(C(C)(C)C)ccc4N(c4ccc(C(C)(C)C)cc4)c4cc(-c5cc(-c6ccccc6)nc(-c6ccccc6)n5)cc2c43)cc1]

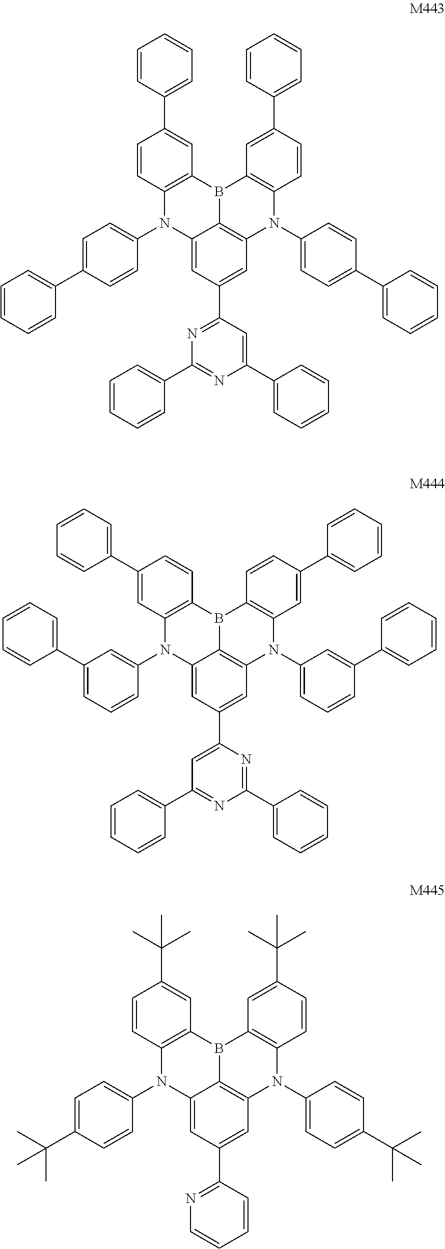 [SMILES: c1ccc(-c2ccc(N3c4ccc(-c5ccccc5)cc4B4c5cc(-c6ccccc6)ccc5N(c5ccc(-c6ccccc6)cc5)c5cc(-c6cc(-c7ccccc7)nc(-c7ccccc7)n6)cc3c54)cc2)cc1 ; c1ccc(-c2cccc(N3c4cc(-c5ccccc5)ccc4B4c5ccc(-c6ccccc6)cc5N(c5cccc(-c6ccccc6)c5)c5cc(-c6cc(-c7ccccc7)nc(-c7ccccc7)n6)cc3c54)c2)cc1 ; CC(C)(C)c1ccc(N2c3ccc(C(C)(C)C)cc3B3c4cc(C(C)(C)C)ccc4N(c4ccc(C(C)(C)C)cc4)c4cc(-c5ccccn5)cc2c43)cc1]

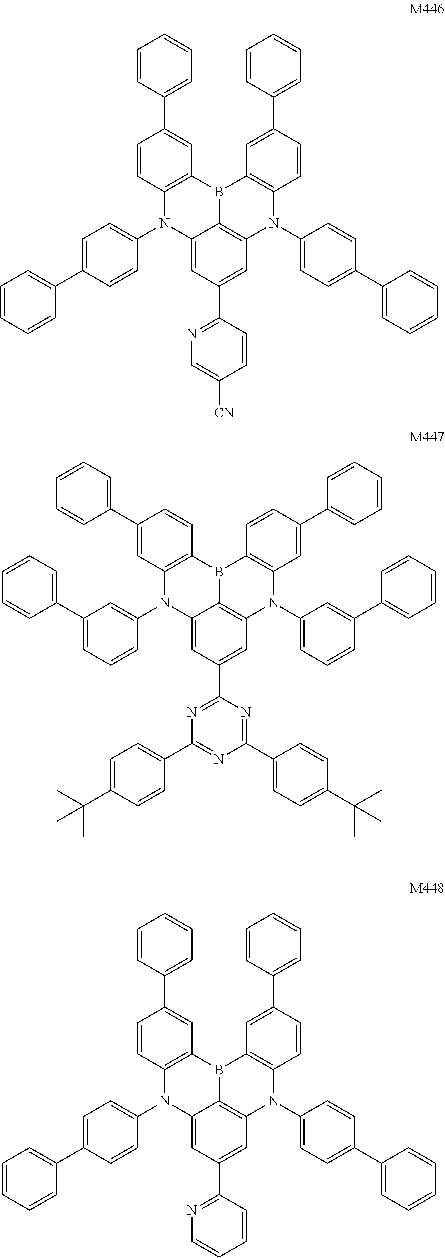 [SMILES: N#Cc1ccc(-c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)nc1 ; CC(C)(C)c1ccc(-c2nc(-c3ccc(C(C)(C)C)cc3)nc(-c3cc4c5c(c3)N(c3cccc(-c6ccccc6)c3)c3cc(-c6ccccc6)ccc3B5c3ccc(-c5ccccc5)cc3N4c3cccc(-c4ccccc4)c3)n2)cc1 ; c1ccc(-c2ccc(N3c4ccc(-c5ccccc5)cc4B4c5cc(-c6ccccc6)ccc5N(c5ccc(-c6ccccc6)cc5)c5cc(-c6ccccn6)cc3c54)cc2)cc1]

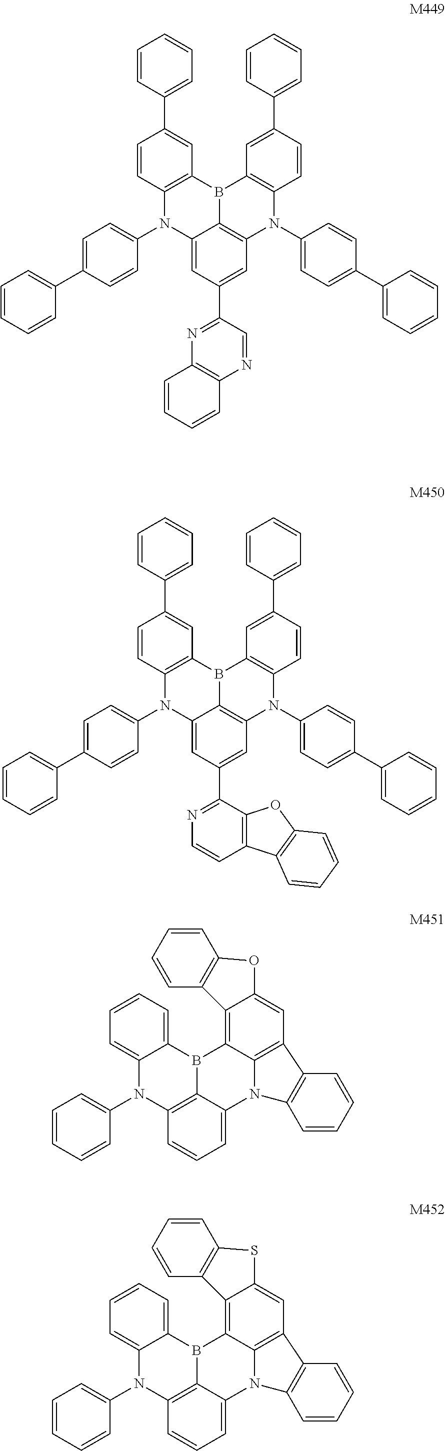 [SMILES: c1ccc(-c2ccc(N3c4ccc(-c5ccccc5)cc4B4c5cc(-c6ccccc6)ccc5N(c5ccc(-c6ccccc6)cc5)c5cc(-c6cnc7ccccc7n6)cc3c54)cc2)cc1 ; c1ccc(-c2ccc(N3c4ccc(-c5ccccc5)cc4B4c5cc(-c6ccccc6)ccc5N(c5ccc(-c6ccccc6)cc5)c5cc(-c6nccc7c6oc6ccccc67)cc3c54)cc2)cc1 ; c1ccc(N2c3ccccc3B3c4c2cccc4-n2c4ccccc4c4cc5oc6ccccc6c5c3c42)cc1 ; c1ccc(N2c3ccccc3B3c4c2cccc4-n2c4ccccc4c4cc5sc6ccccc6c5c3c42)cc1]

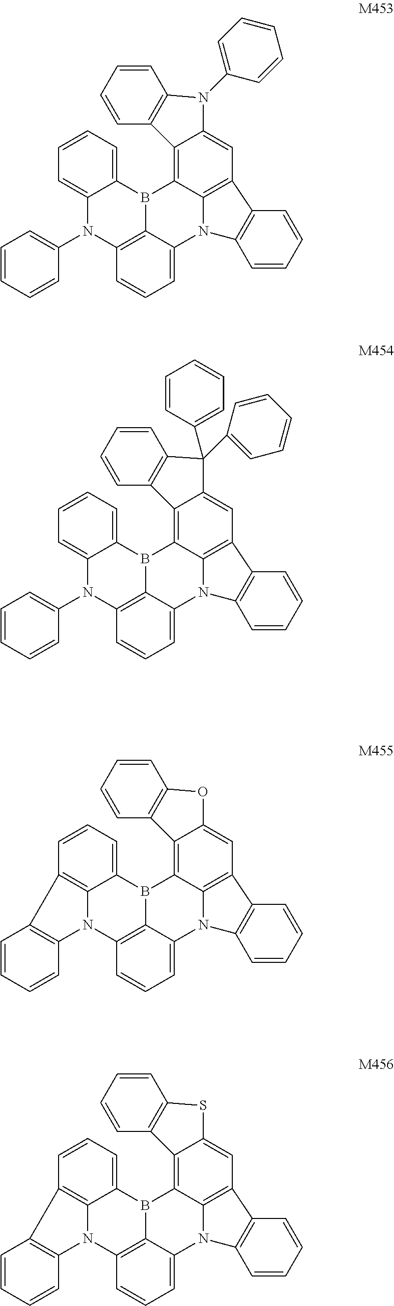 [SMILES: c1ccc(N2c3ccccc3B3c4c2cccc4-n2c4ccccc4c4cc5c(c3c42)c2ccccc2n5-c2ccccc2)cc1 ; c1ccc(N2c3ccccc3B3c4c2cccc4-n2c4ccccc4c4cc5c(c3c42)-c2ccccc2C5(c2ccccc2)c2ccccc2)cc1 ; c1cc2c3c(c1)-n1c4ccccc4c4cc5oc6ccccc6c5c(c41)B3c1cccc3c4ccccc4n-2c13 ; c1cc2c3c(c1)-n1c4ccccc4c4cc5sc6ccccc6c5c(c41)B3c1cccc3c4ccccc4n-2c13]

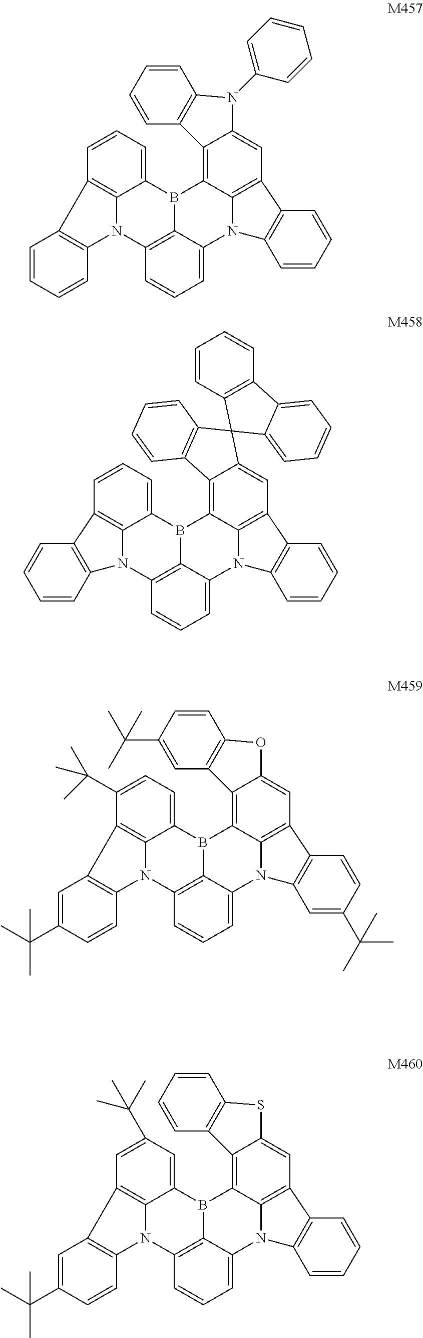

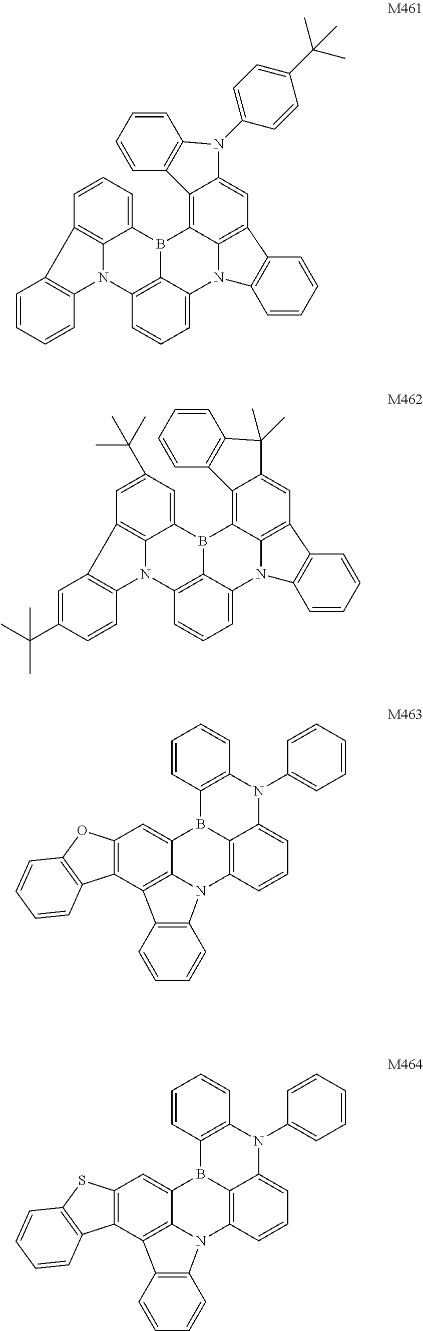

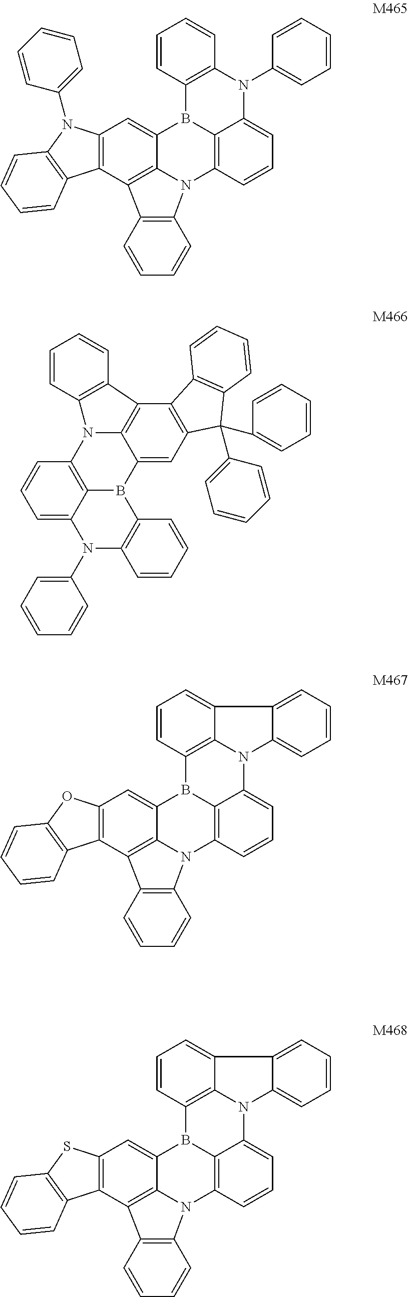 [SMILES: c1ccc(N2c3ccccc3B3c4c2cccc4-n2c4ccccc4c4c5c6ccccc6n(-c6ccccc6)c5cc3c42)cc1 ; c1ccc(N2c3ccccc3B3c4c2cccc4-n2c4ccccc4c4c5c(cc3c42)C(c2ccccc2)(c2ccccc2)c2ccccc2-5)cc1 ; c1cc2c3c(c1)-n1c4ccccc4c4c5c(cc(c41)B3c1cccc3c4ccccc4n-2c13)oc1ccccc15 ; c1cc2c3c(c1)-n1c4ccccc4c4c5c(cc(c41)B3c1cccc3c4ccccc4n-2c13)sc1ccccc15]

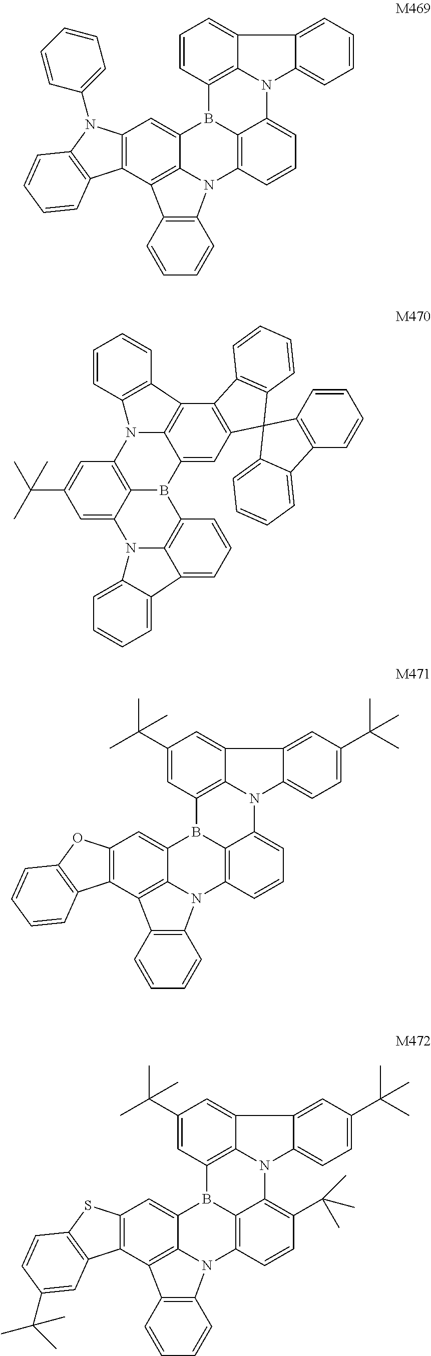

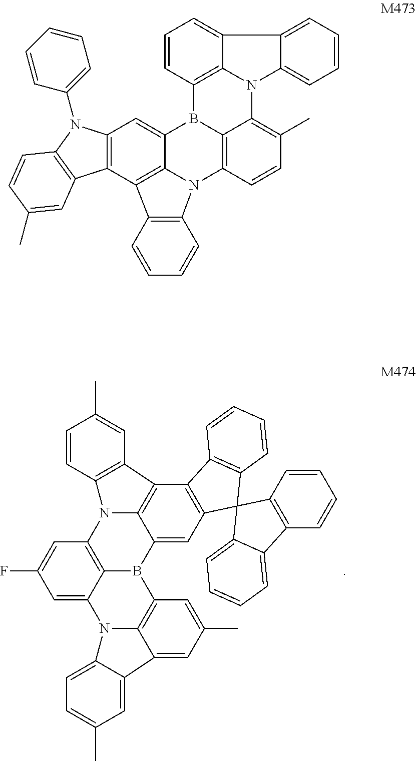 [SMILES: Cc1ccc2c(c1)c1c3c4ccccc4n4c3c(cc1n2-c1ccccc1)B1c2c-4ccc(C)c2-n2c3ccccc3c3cccc1c32 ; Cc1ccc2c(c1)c1cc(C)cc3c1n2-c1cc(F)cc2c1B3c1cc3c(c4c5cc(C)ccc5n-2c14)-c1ccccc1C31c2ccccc2-c2ccccc21]

In addition, the phosphorescence sensitized light-emitting layer may contain one or more (at least two) host materials, and when there is a plurality of host materials, at least two of the host materials may or may not form an exciplex.

When there is a plurality of host materials, the mass percentage of each of the plurality of host materials is not less than 10%, for example, equal to or greater than 10%, based on the total mass of the plurality of host materials.

In some examples, the host material includes two host materials, i.e., a first host material and a second host material, respectively, and the two host materials form an exciplex. That is, the phosphorescence sensitized light-emitting layer includes an exciplex formed by the two host materials, which is beneficial to further improving the performance such as efficiency of the device.

Typically, the phosphorescent sensitizer has a singlet energy level S₁^{Phos} and a triplet energy level T₁^{Phos}, and the narrow-spectrum fluorescent material has a singlet energy level S₁^{F} and a triplet energy level T₁^{F}. The triplet energy level T₁^{Phos} of the phosphorescent sensitizer is higher than the singlet energy level S₁^{F} and the triplet energy level T₁^{F} of the narrow-spectrum fluorescent material, i.e., T₁^{Phos}>S₁^{F}, and T₁^{Phos}>T₁^{F}.

In addition, both the singlet energy level and the triplet energy level of the host material are higher than the triplet energy level T₁^{Phos} of the phosphorescent sensitizer. When there is a plurality of host materials, the singlet energy level and the triplet energy level of each host material are higher than the triplet energy level T₁^{Phos} of the phosphorescent sensitizer, that is, the singlet energy level and the triplet energy level of both the first host material and the second host material mentioned above are higher than T₁^{Phos}, respectively.

Furthermore, when the first host material and the second host material form an exciplex, both the singlet energy level (singlet excited state energy) S₁^{EX} and the triplet energy level (triplet excited state energy) T₁^{EX} of the exciplex are higher than the triplet energy level T₁^{Phos} of the phosphorescent sensitizer, i.e., S₁^{EX}>T₁^{Phos}, and T₁^{EX}>T₁^{Phos}.

In addition, both the singlet energy level SEX and the triplet energy level T₁^{EX} of the exciplex are higher than the triplet energy level T₁^{F} of the narrow-spectrum fluorescent material, i.e., S₁^{EX}>T₁^{F}, and T₁^{EX}>T₁^{F}.

In addition, the singlet energy level SEX and the triplet energy level T₁^{EX} of the exciplex satisfy the following relationship: S₁^{EX}−T₁^{EX}≤0.3 eV, and S₁^{EX}>T₁^{EX}, i.e., 0<S₁^{EX}−T₁^{EX}≤0.3 eV.

Typically, the exciplex has delayed fluorescence properties in the time-resolved photoluminescence spectra of the thin film.

Specifically, the first host material is a hole transport host material, and the second host material is an electron transport host material. The first host material has a singlet energy level S₁^{P} and a triplet energy level T₁^{P}, the second host material has a singlet energy level S₁^{N} and a triplet energy level T₁^{N}, and S₁^{P}, S₁^{N}, and the singlet energy level S₁^{EX} of the exciplex formed by the two host materials satisfy: S₁^{P}>S₁^{N}>S₁^{EX}.

In addition, the first host material (the hole transport host material) has a highest occupied molecular orbital and a lowest unoccupied molecular orbital, with the highest occupied molecular orbital energy level (HOMO energy level) being E_{HOMO}^{P}, and the lowest unoccupied molecular orbital energy level (LUMO energy level) being E_{LUMO}^{P}; the second host material (the electron transport host material) has a highest occupied molecular orbital and a lowest unoccupied molecular orbital, with the highest occupied molecular orbital energy level (HOMO energy level) being E_{HOMO}^{N}, and the lowest unoccupied molecular orbital energy level (LUMO energy level) being E_{LUMO}^{N}. The following relationship is satisfied: E_{HOMO}^{P}>E_{HOMO}^{N}, and E_{LUMO}^{P}>E_{LUMO}^{N}.

In some specific examples, E_{HOMO}^{P}−E_{HOMO}^{N}>0.1 eV, and E_{LUMO}^{P}−E_{LUMO}^{N}>0.3 eV.

It should be noted that E_{HOMO}^{P}, E_{LUMO}^{P}, E_{HOMO}^{N} and E_{LUMO}^{N} are all negative value. When E_{HOMO}^{P}>E_{HOMO}^{N}, the absolute value of E_{HOMO}^{P} is less than that of E_{HOMO}^{N}; and if E_{LUMO}^{P}>E_{LUMO}^{N}, the absolute value of E_{LUMO}^{P} is less than that of E_{LUMO}^{N}.

In an example of the present application, the singlet energy levels and the triplet energy levels of the materials can be measured using conventional methods in the art. For example, S₁^{P}, T₁^{P}, S₁^{N}, T₁^{N}, S₁^{EX} and T₁^{EX} can be respectively calculated from the emission peak onset value (Onset) of the fluorescence and phosphorescence emission spectra at a low temperature (77 K), S₁^{Phos} can be calculated from the Onset value of end absorption in the longest wavelength direction in ultraviolet-visible absorption spectra, and T₁^{Phos} is calculated from the Onset value of the phosphorescence emission spectrum at 77 K.

Specifically, the first host material may include a compound represented by Formula 1:

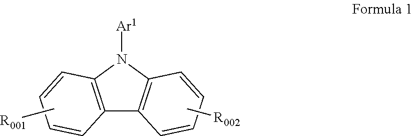

in Formula 1, Ar¹ is selected from one of substituted or unsubstituted C6-C60 aryl, and substituted or unsubstituted C3-C60 heteroaryl; and
R₀₀₁ and R₀₀₂ represent zero to the maximum permissible substituents on the benzene rings, and R₀₀₁ and R₀₀₂ are each independently selected from one of deuterium, cyano, substituted or unsubstituted C1-C20 alkyl, substituted or unsubstituted C3-C20 cycloalkyl, substituted or unsubstituted C1-C20 silanyl, substituted or unsubstituted C6-C30 arylamino, substituted or unsubstituted C7-C30 aralkyl, substituted or unsubstituted C3-C30 heteroarylamino, substituted or unsubstituted C6-C60 aryl, and substituted or unsubstituted C3-C60 heteroaryl.

In one embodiment, the first host material has a structure represented by Formula 1-1 or Formula 1-2:

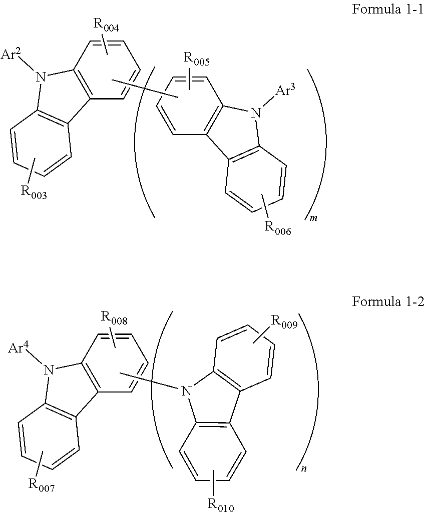

wherein m and n are each independently an integer from 1 to 4;
Ar², Ar³ and A r4 are each independently selected from one of substituted or unsubstituted C6-C60 aryl, and substituted or unsubstituted C3-C60 heteroaryl; and R₀₀₃ to R₀₁₀ represent zero to the maximum permissible substituents on the benzene rings and are each independently selected from one of hydrogen, deuterium, cyano, substituted or unsubstituted C1-C20 alkyl, substituted or unsubstituted C3-C20 cycloalkyl, substituted or unsubstituted C1-C20 silanyl, substituted or unsubstituted C6-C30 arylamino, substituted or unsubstituted C7-C30 aralkyl, substituted or unsubstituted C3-C30 heteroarylamino, substituted or unsubstituted C6-C60 aryl, and substituted or unsubstituted C3-C60 heteroaryl.

In one embodiment, Ar², Ar³ and Ar⁴ are each independently selected from one or a combination of more of substituted or unsubstituted benzene, substituted or unsubstituted biphenyl, substituted or unsubstituted terphenyl, substituted or unsubstituted triphenylene, substituted or unsubstituted dibenzofuran, substituted or unsubstituted dibenzothiophene, substituted or unsubstituted indole, substituted or unsubstituted indolocarbazole, substituted or unsubstituted carbazole, and substituted or unsubstituted fluorene.

In some specific embodiments, the first host material includes one or more of the following compounds D-1 to D-85:

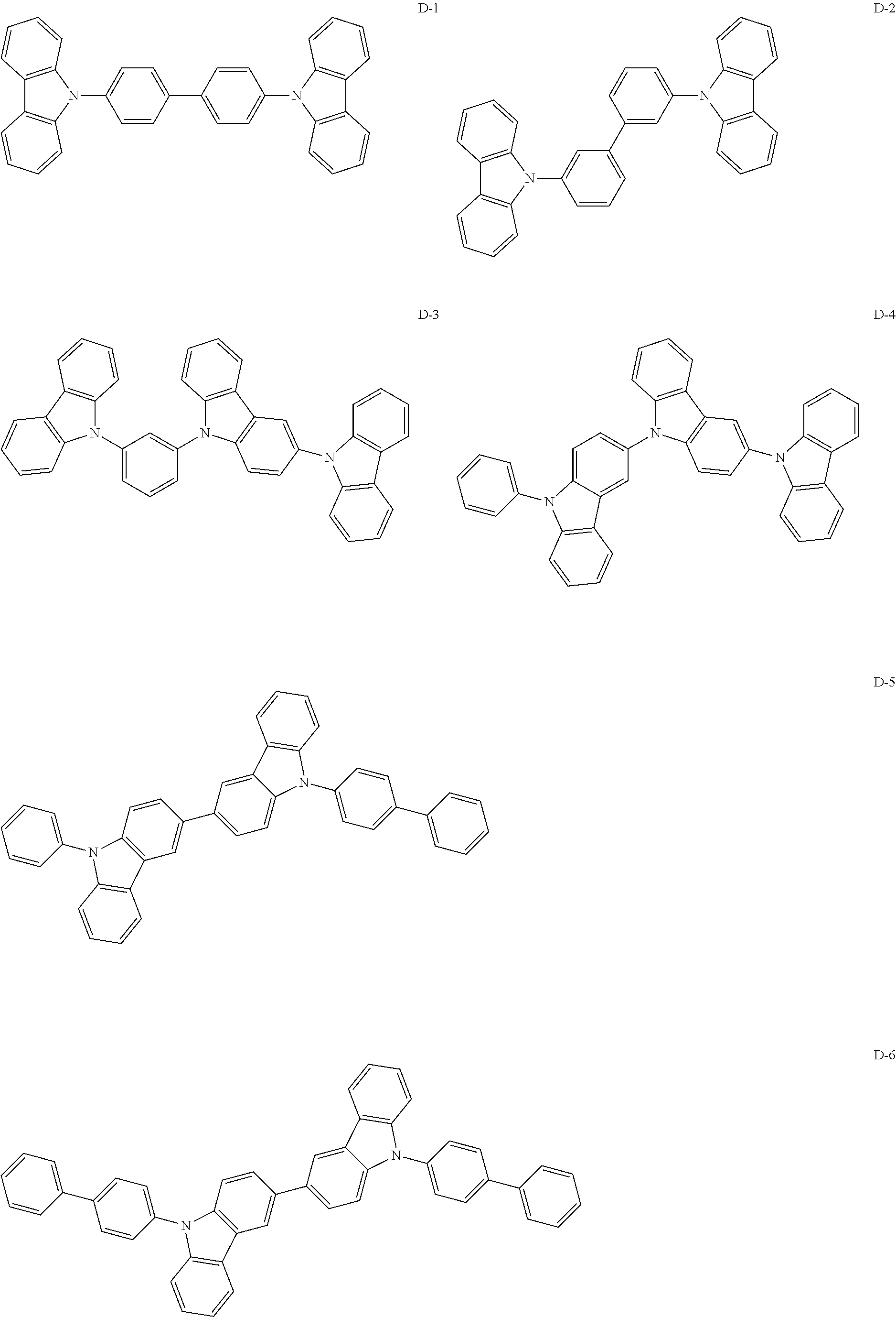 [SMILES: c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1 ; c1cc(-n2c3ccccc3c3ccccc32)cc(-n2c3ccccc3c3cc(-n4c5ccccc5c5ccccc54)ccc32)c1 ; c1ccc(-n2c3ccccc3c3cc(-n4c5ccccc5c5cc(-n6c7ccccc7c7ccccc76)ccc54)ccc32)cc1 ; c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

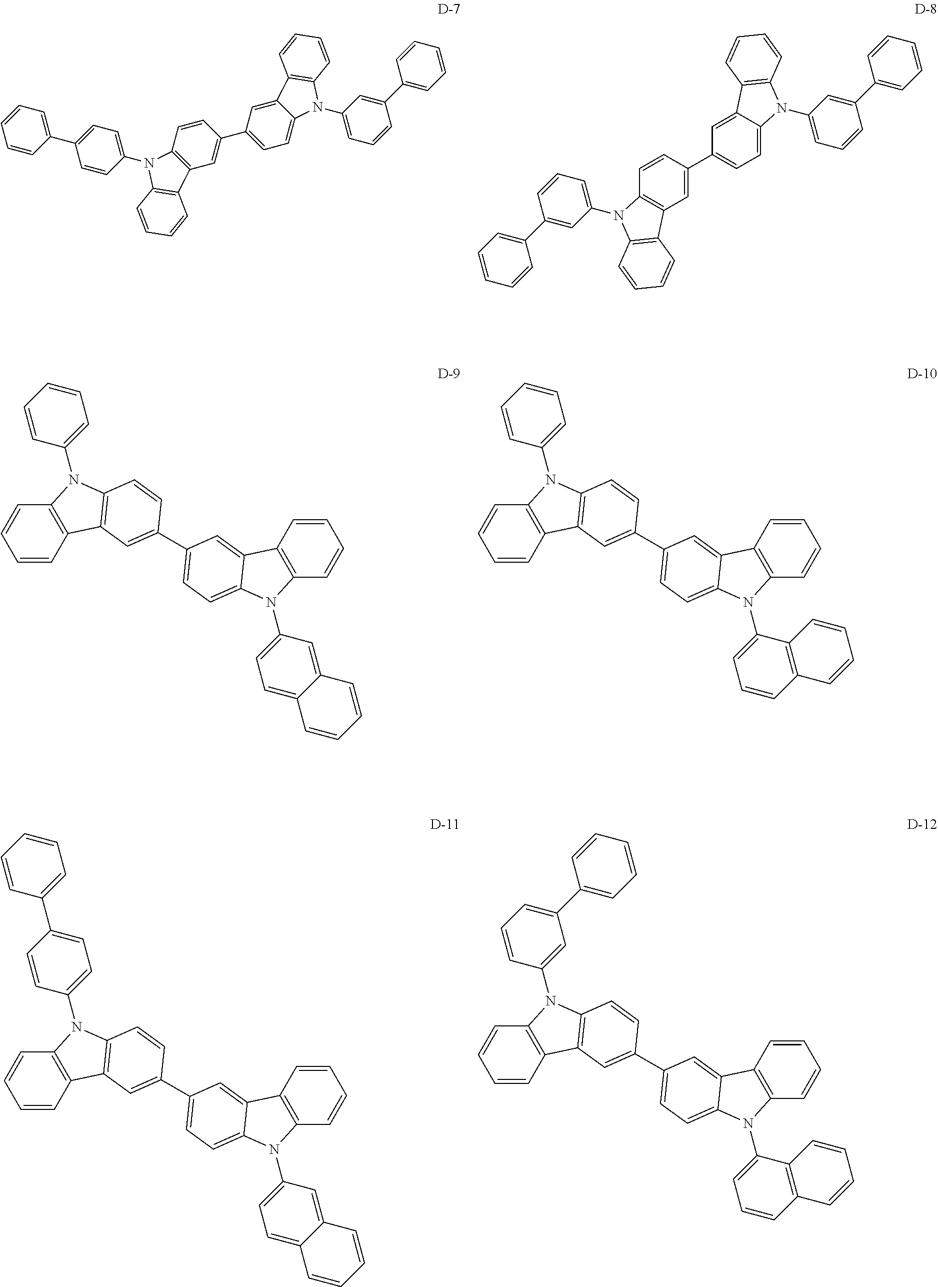 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc6ccccc56)ccc43)c2)cc1]

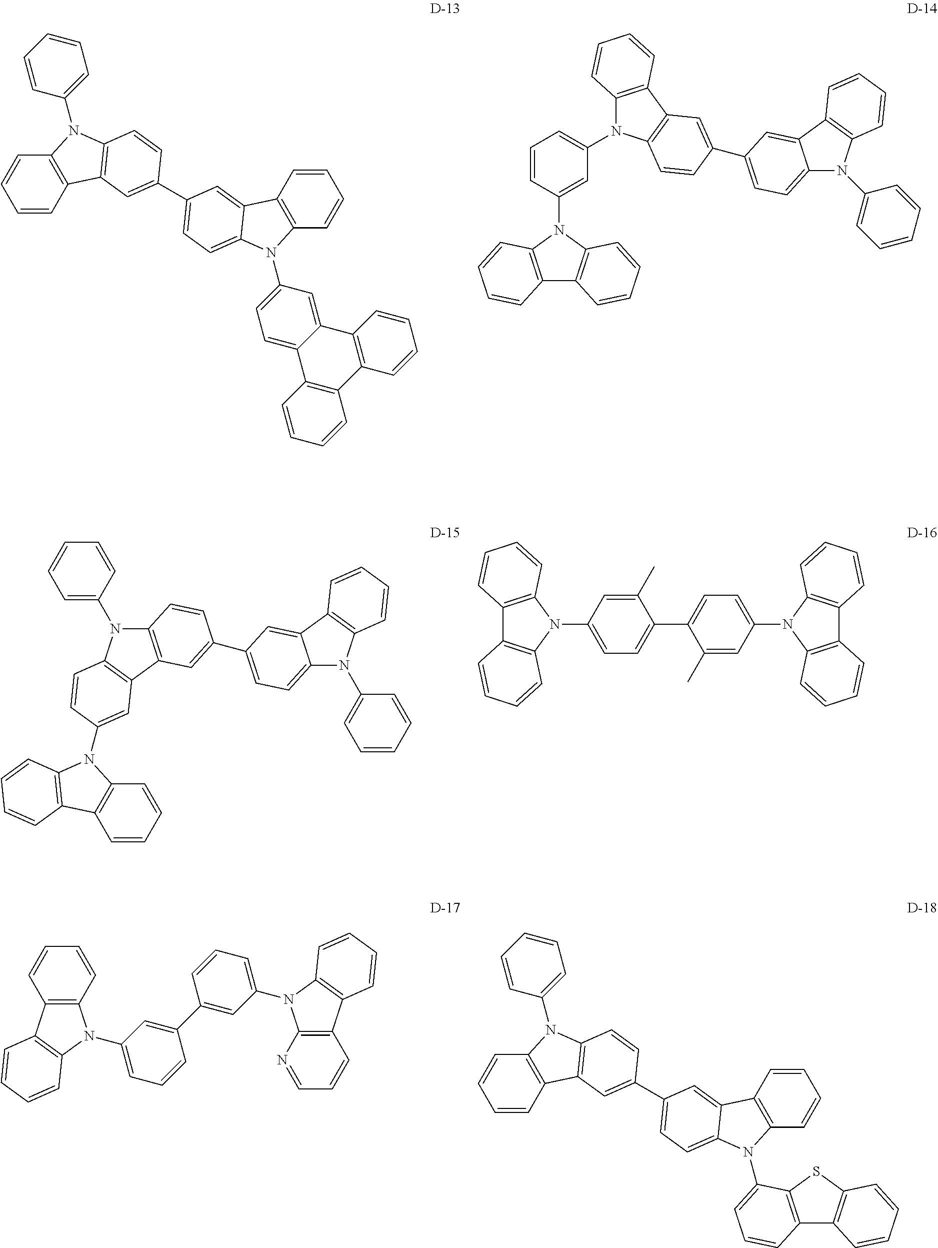 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4ccccc4n5-c4cccc(-n5c6ccccc6c6ccccc65)c4)ccc32)cc1 ; c1ccc(-n2c3ccccc3c3cc(-c4ccc5c(c4)c4cc(-n6c7ccccc7c7ccccc76)ccc4n5-c4ccccc4)ccc32)cc1 ; Cc1cc(-n2c3ccccc3c3ccccc32)ccc1-c1ccc(-n2c3ccccc3c3ccccc32)cc1C ; c1cc(-c2cccc(-n3c4ccccc4c4cccnc43)c2)cc(-n2c3ccccc3c3ccccc32)c1 ; c1ccc(-n2c3ccccc3c3cc(-c4ccc5c(c4)c4ccccc4n5-c4cccc5c4sc4ccccc45)ccc32)cc1]

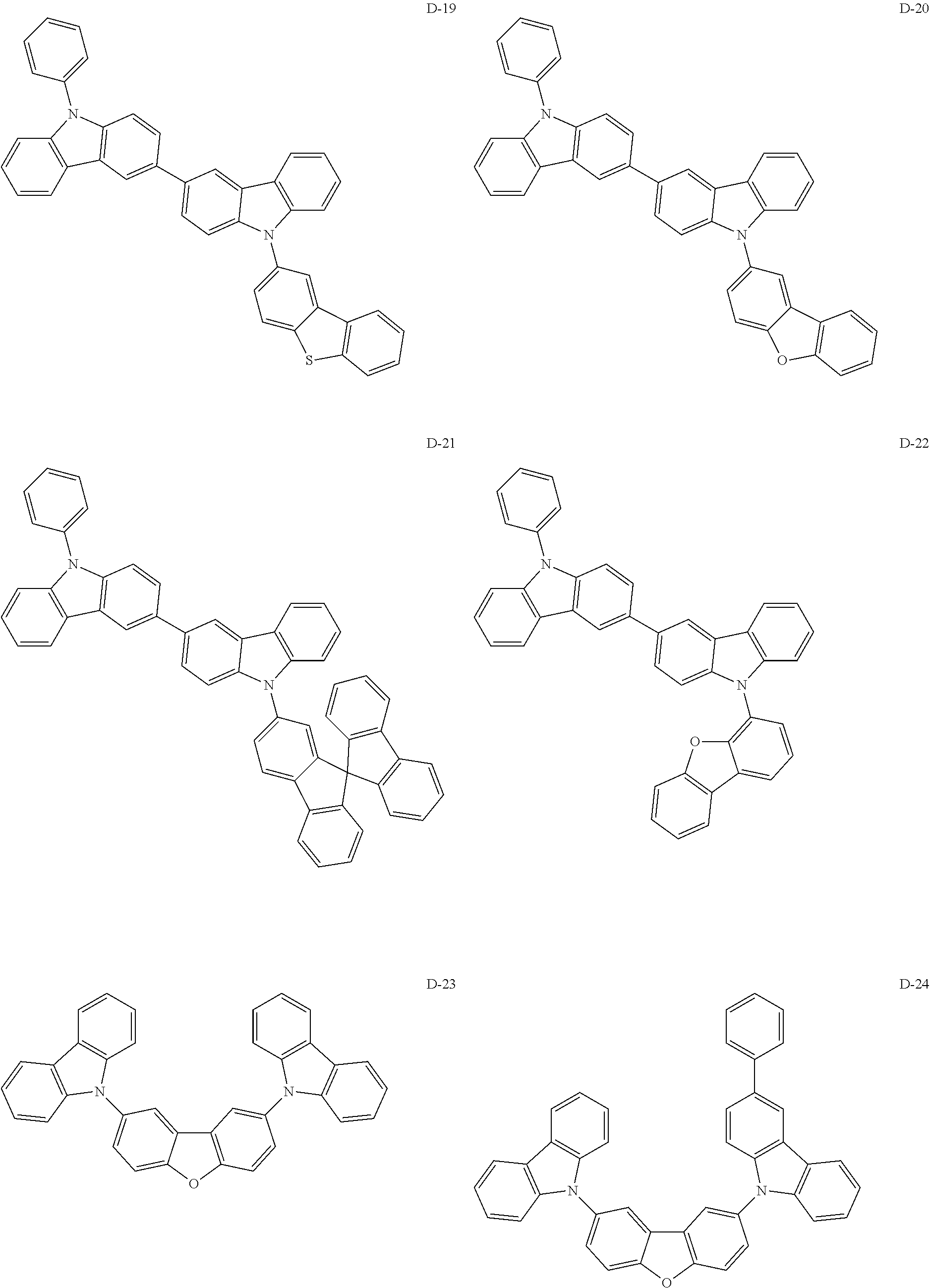 [SMILES: c1ccc(-n2c3ccccc3c3cc(-c4ccc5c(c4)c4ccccc4n5-c4ccc5sc6ccccc6c5c4)ccc32)cc1 ; c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; c1ccc(-n2c3ccccc3c3cc(-c4ccc5c(c4)c4ccccc4n5-c4cccc5c4oc4ccccc45)ccc32)cc1 ; c1ccc2c(c1)c1ccccc1n2-c1ccc2oc3ccc(-n4c5ccccc5c5ccccc54)cc3c2c1 ; c1ccc(-c2ccc3c(c2)c2ccccc2n3-c2ccc3oc4ccc(-n5c6ccccc6c6ccccc65)cc4c3c2)cc1]

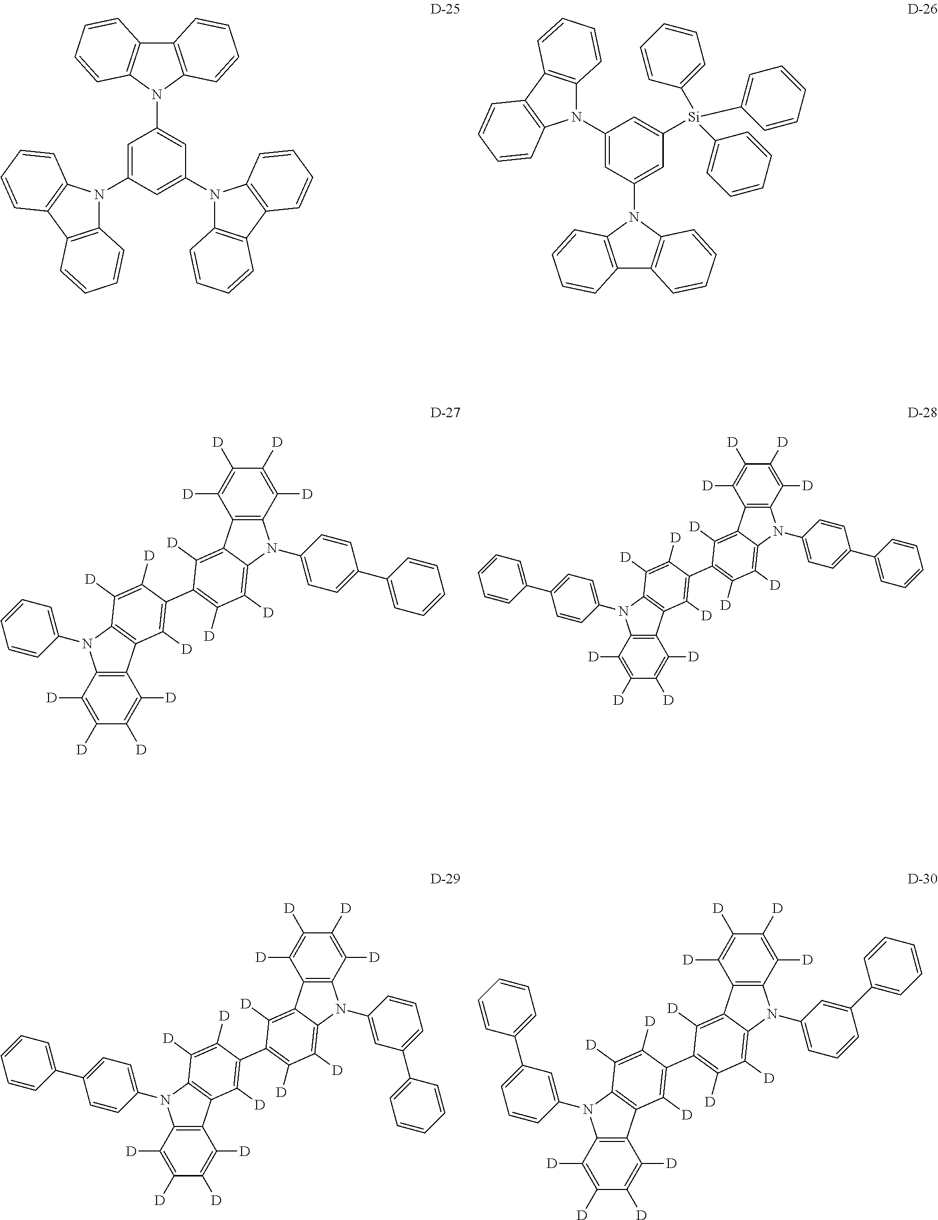

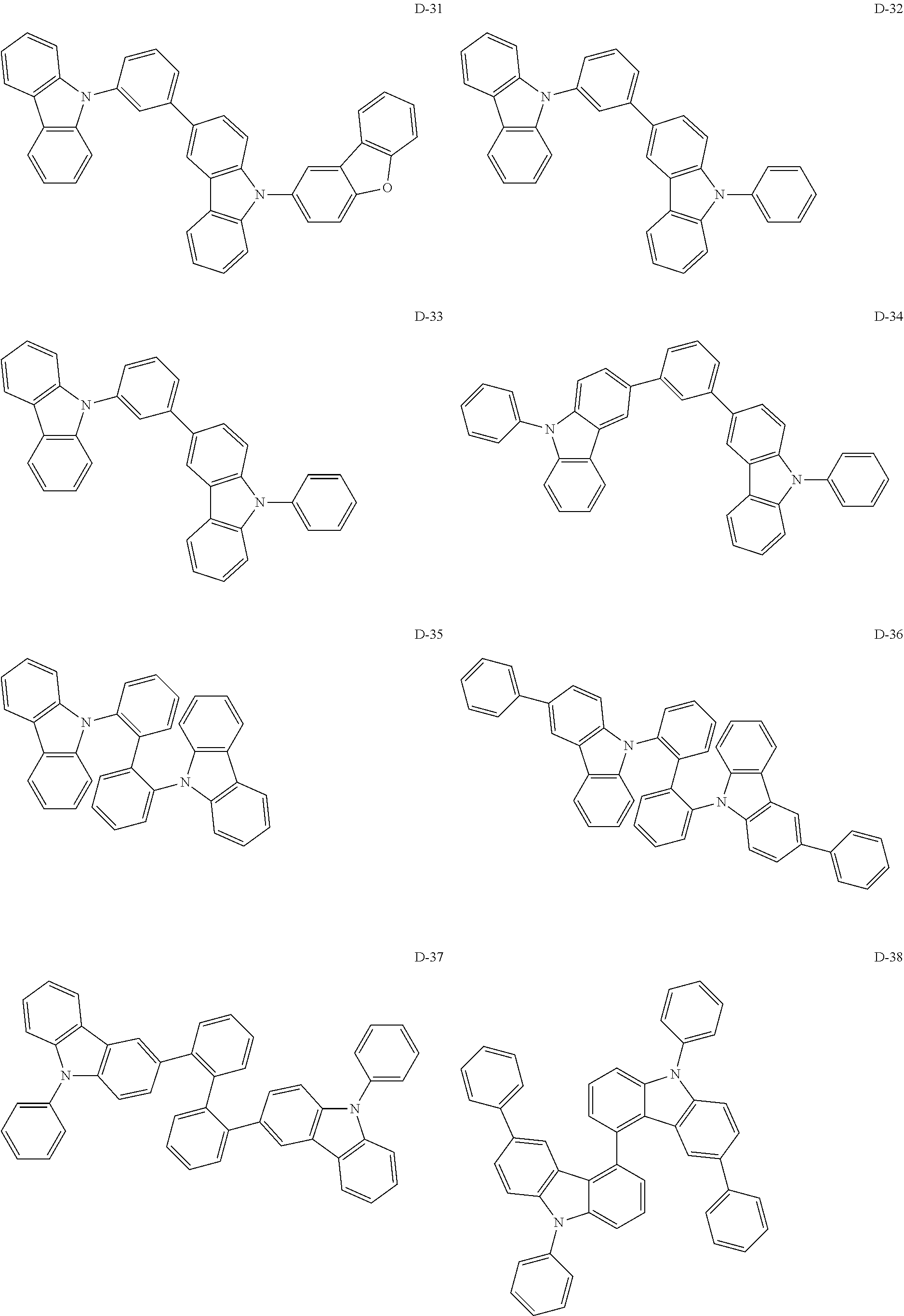

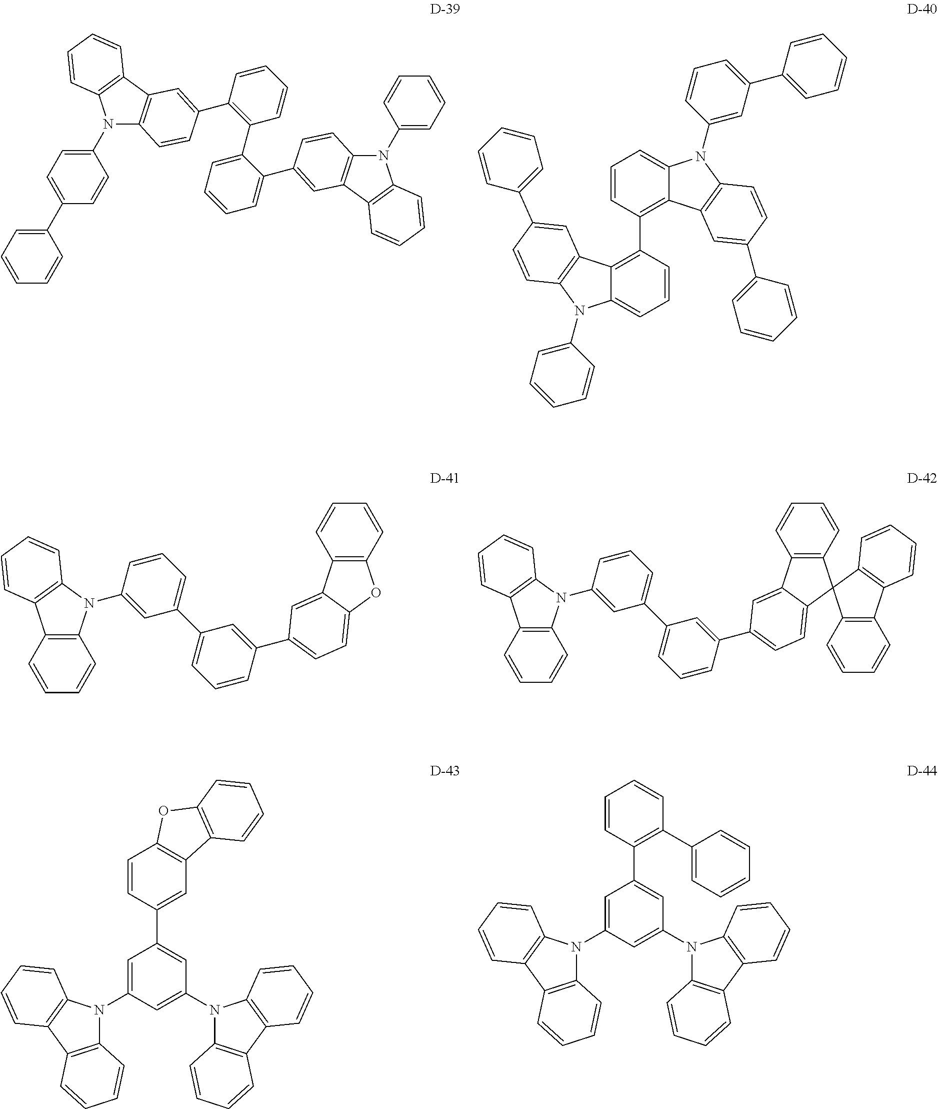 [SMILES: c1ccc(-c2ccc(-n3c4ccccc4c4cc(-c5ccccc5-c5ccccc5-c5ccc6c(c5)c5ccccc5n6-c5ccccc5)ccc43)cc2)cc1 ; c1ccc(-c2cccc(-n3c4ccc(-c5ccccc5)cc4c4c(-c5cccc6c5c5cc(-c7ccccc7)ccc5n6-c5ccccc5)cccc43)c2)cc1 ; c1cc(-c2cccc(-n3c4ccccc4c4ccccc43)c2)cc(-c2ccc3oc4ccccc4c3c2)c1 ; c1cc(-c2cccc(-n3c4ccccc4c4ccccc43)c2)cc(-c2ccc3c(c2)-c2ccccc2C32c3ccccc3-c3ccccc32)c1 ; c1ccc2c(c1)oc1ccc(-c3cc(-n4c5ccccc5c5ccccc54)cc(-n4c5ccccc5c5ccccc54)c3)cc12 ; c1ccc(-c2ccccc2-c2cc(-n3c4ccccc4c4ccccc43)cc(-n3c4ccccc4c4ccccc43)c2)cc1]

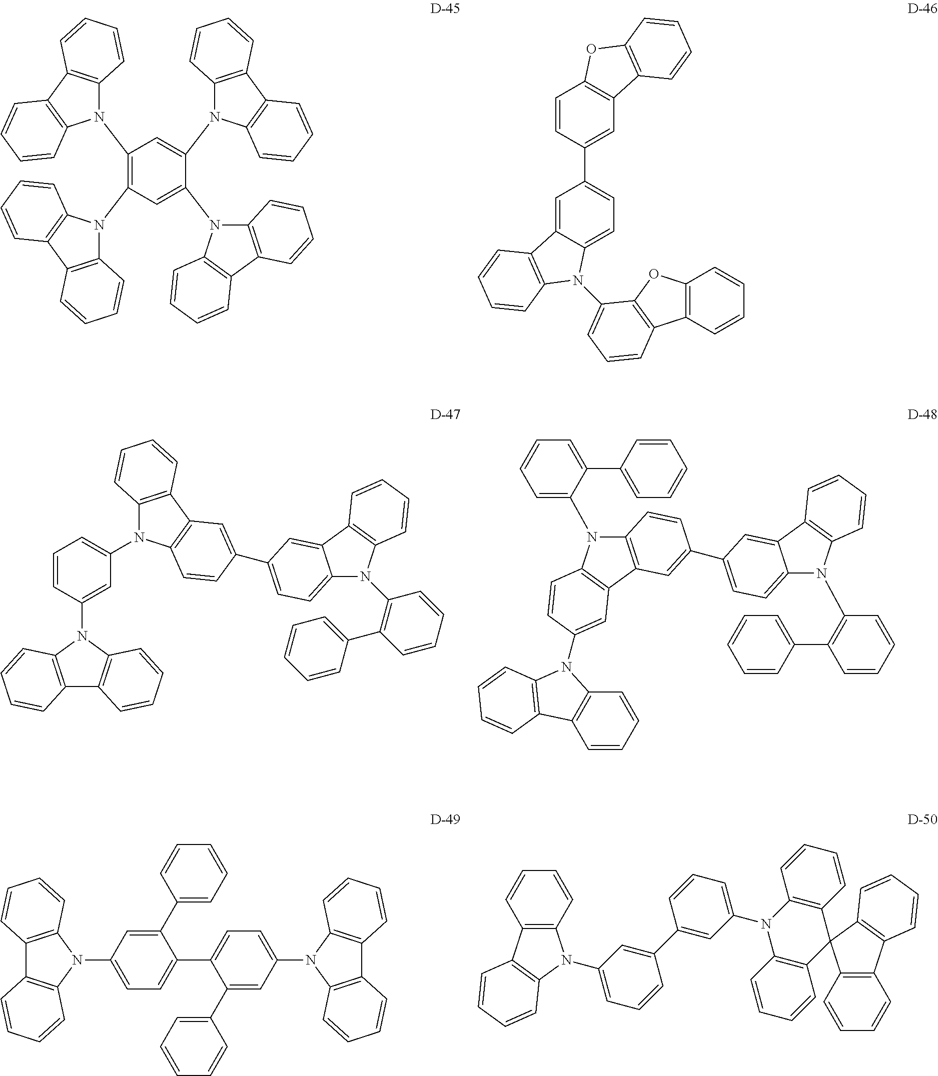

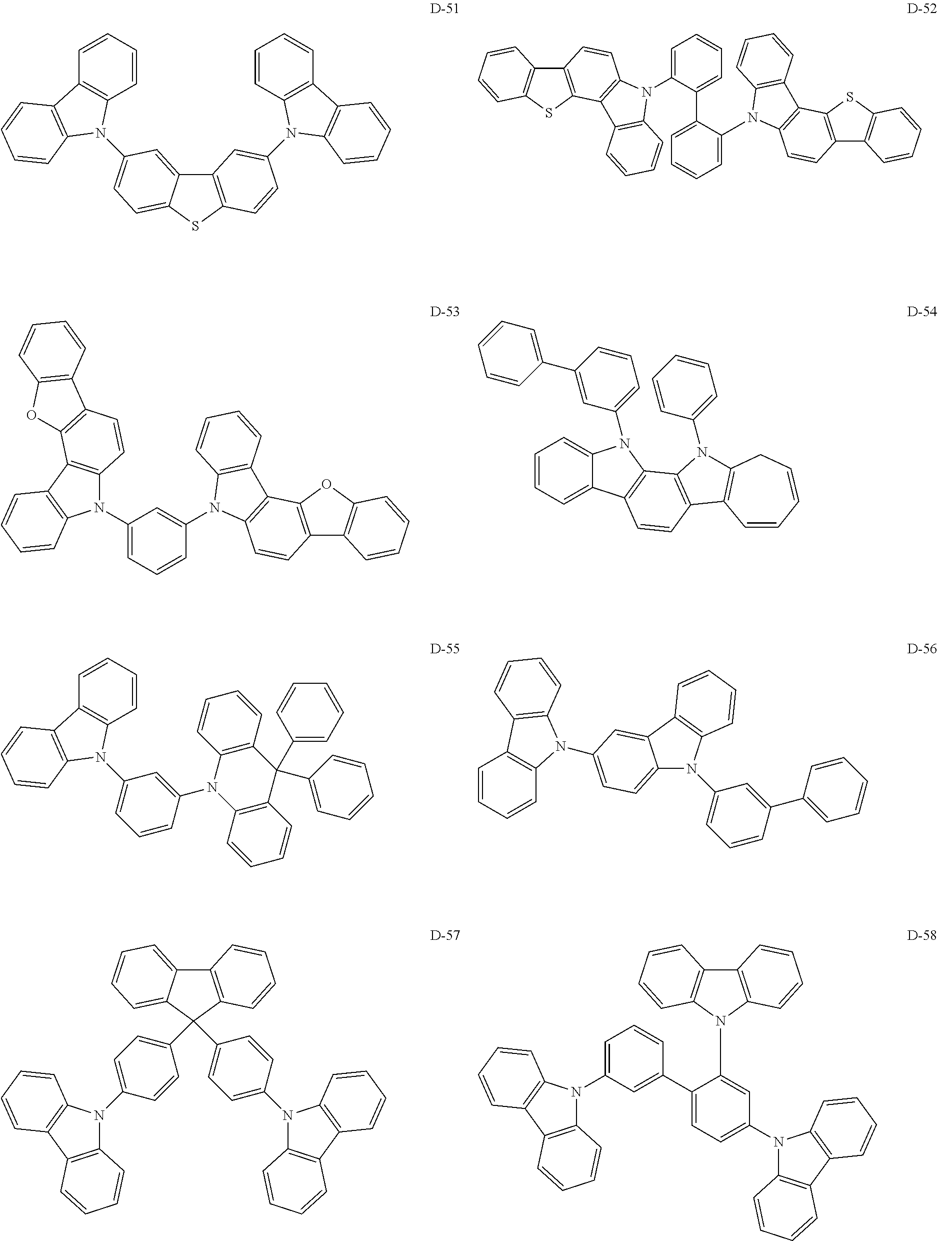

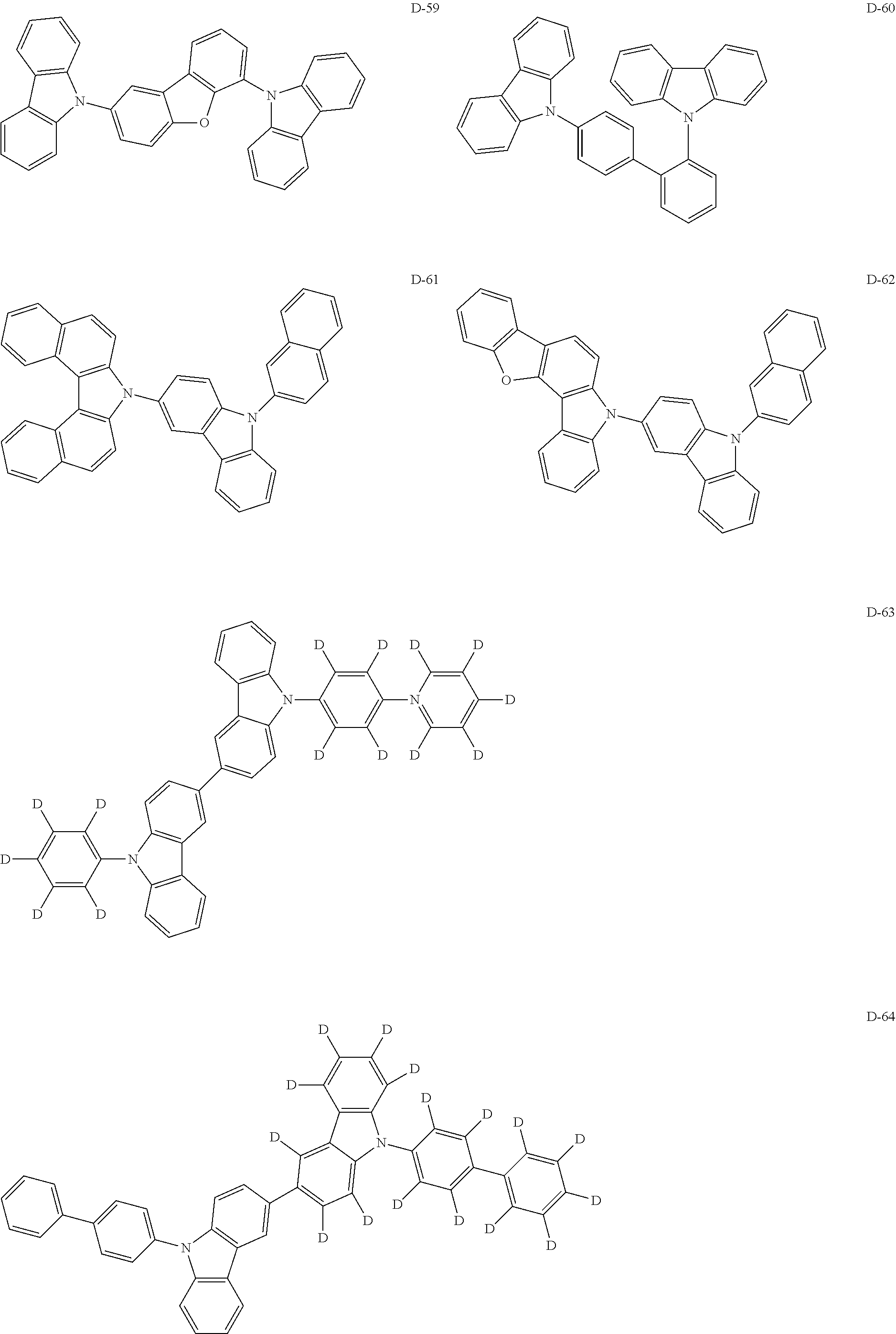

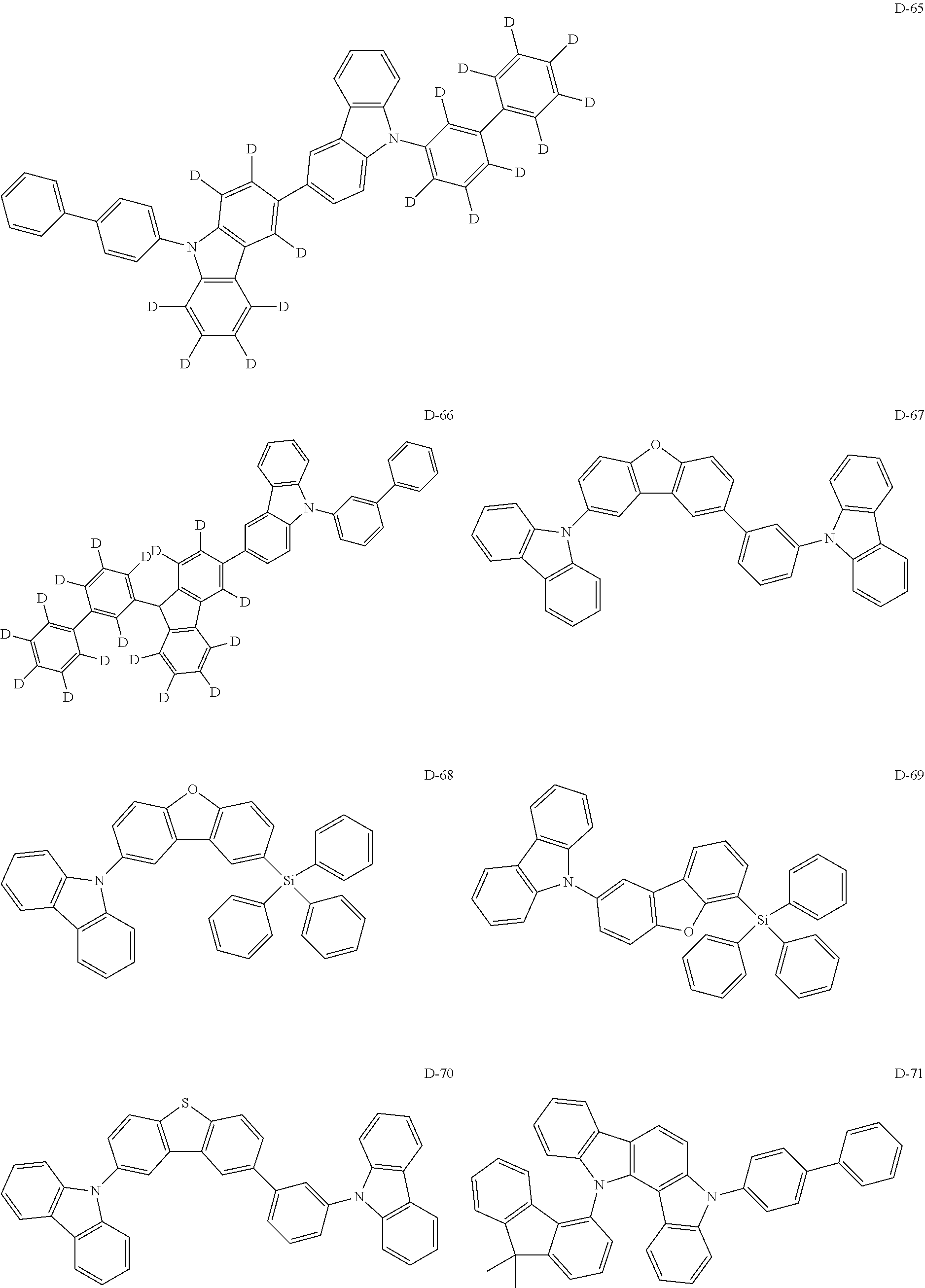

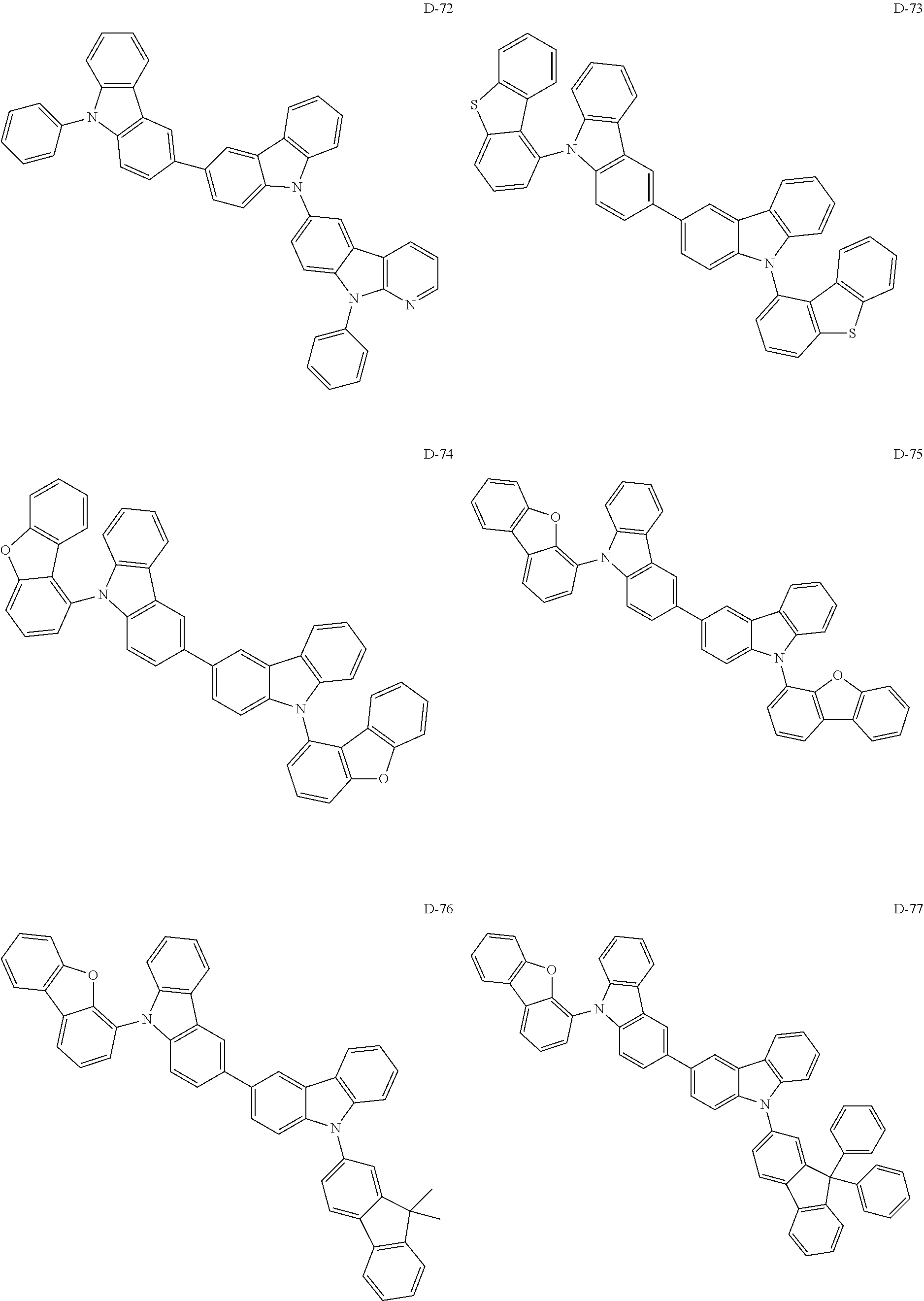

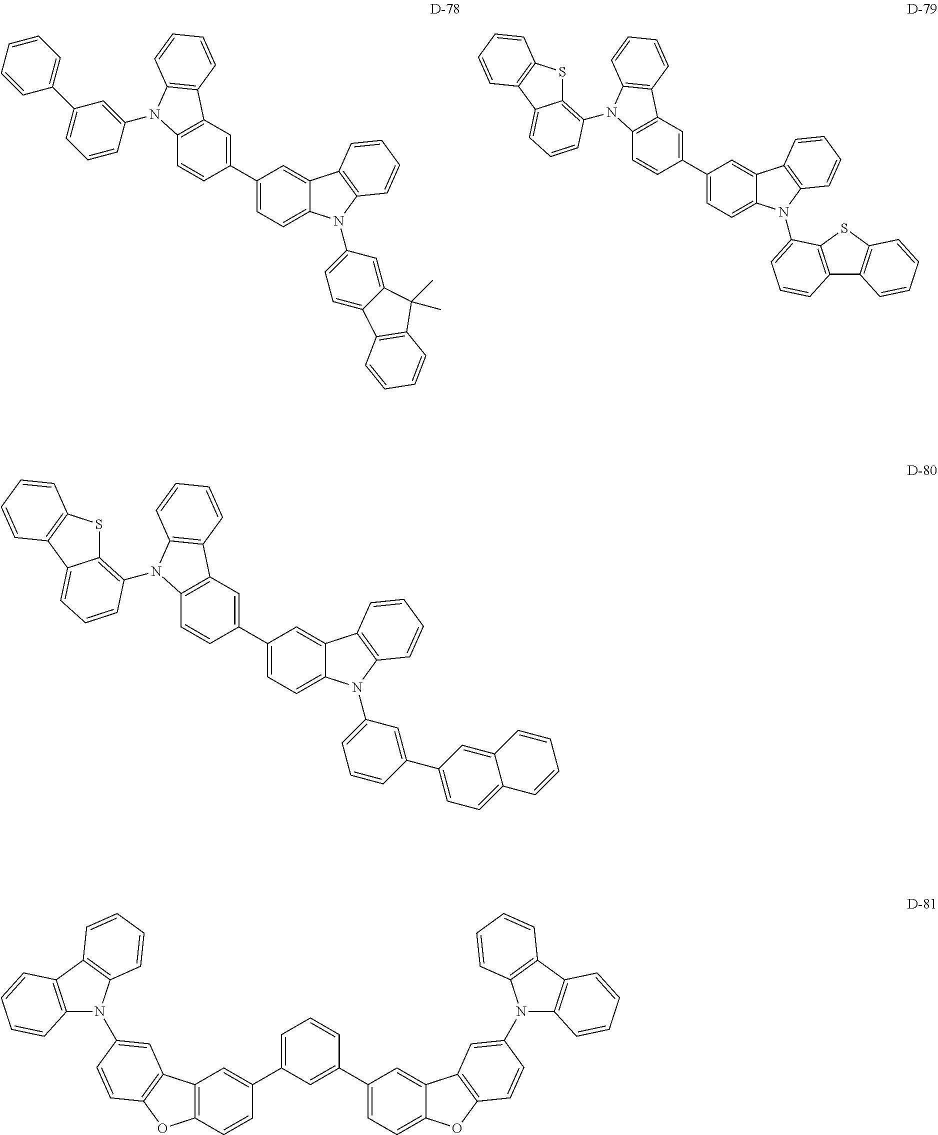 [SMILES: CC1(C)c2ccccc2-c2ccc(-n3c4ccccc4c4cc(-c5ccc6c(c5)c5ccccc5n6-c5cccc(-c6ccccc6)c5)ccc43)cc21 ; c1ccc2c(c1)sc1c(-n3c4ccccc4c4cc(-c5ccc6c(c5)c5ccccc5n6-c5cccc6c5sc5ccccc56)ccc43)cccc12 ; c1cc(-c2ccc3ccccc3c2)cc(-n2c3ccccc3c3cc(-c4ccc5c(c4)c4ccccc4n5-c4cccc5c4sc4ccccc45)ccc32)c1 ; c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1]

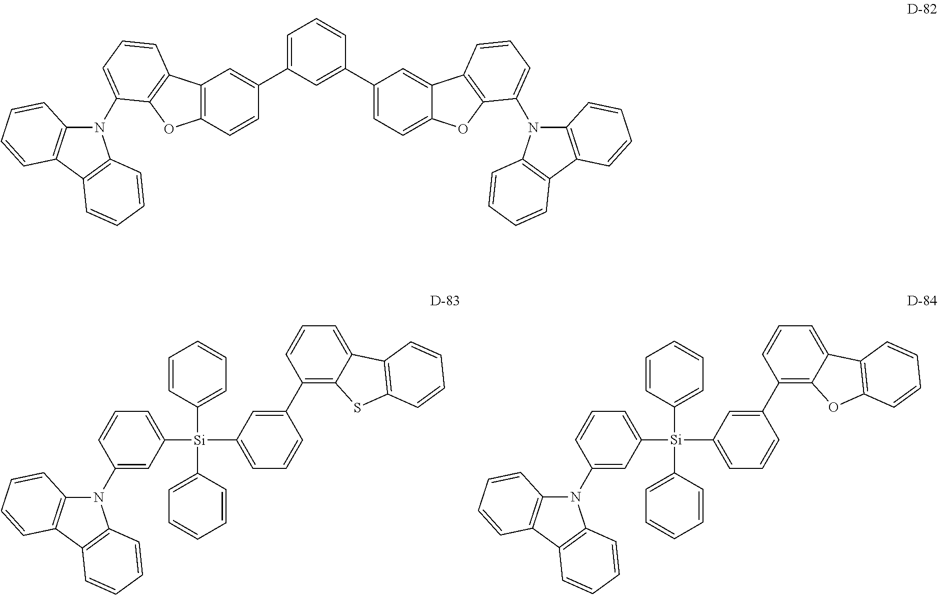 [SMILES: c1cc(-c2ccc3oc4c(-n5c6ccccc6c6ccccc65)cccc4c3c2)cc(-c2ccc3oc4c(-n5c6ccccc6c6ccccc65)cccc4c3c2)c1 ; c1ccc([Si](c2ccccc2)(c2cccc(-c3cccc4c3sc3ccccc34)c2)c2cccc(-n3c4ccccc4c4ccccc43)c2)cc1 ; c1ccc([Si](c2ccccc2)(c2cccc(-c3cccc4c3oc3ccccc34)c2)c2cccc(-n3c4ccccc4c4ccccc43)c2)cc1]

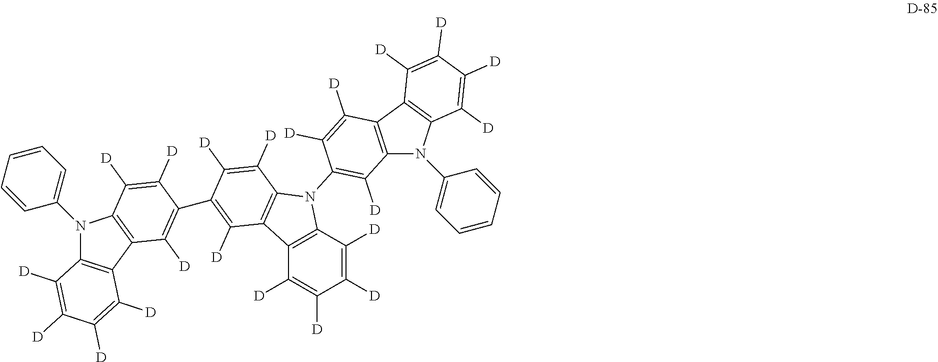 [SMILES: [2H]c1c([2H])c([2H])c2c(c1[2H])c1c([2H])c(-c3c([2H])c([2H])c4c(c3[2H])c3c([2H])c([2H])c([2H])c([2H])c3n4-c3c([2H])c([2H])c4c5c([2H])c([2H])c([2H])c([2H])c5n(-c5ccccc5)c4c3[2H])c([2H])c([2H])c1n2-c1ccccc1]

The second host material includes a nitrogen-containing aromatic heterocyclic compound, and specifically, the second host material contains a structural unit represented by Formula 2:

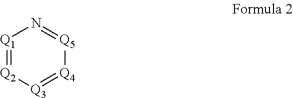

wherein Q1 to Q5 are each independently selected from nitrogen or C—R₀₁₁, and R₀₁₁ is independently selected from one of deuterium, substituted or unsubstituted C1-C20 alkyl, substituted or unsubstituted C3-C20 cycloalkyl, substituted or unsubstituted C2-C20 alkenyl, substituted or unsubstituted C1-C20 silanyl, substituted or unsubstituted C6-C60 arylsilyl, substituted or unsubstituted C6-C30 arylamino, substituted or unsubstituted C7-C30 aralkyl, substituted or unsubstituted C3-C30 heteroarylamino, substituted or unsubstituted C6-C60 aryl, and substituted or unsubstituted C3-C60 heteroaryl; and adjacent R₀₁₁ groups are linked or not linked, and specifically may be fused or not fused to form a ring.

In some specific embodiments, the second host material may include one or more of the following compounds A1 to A86:

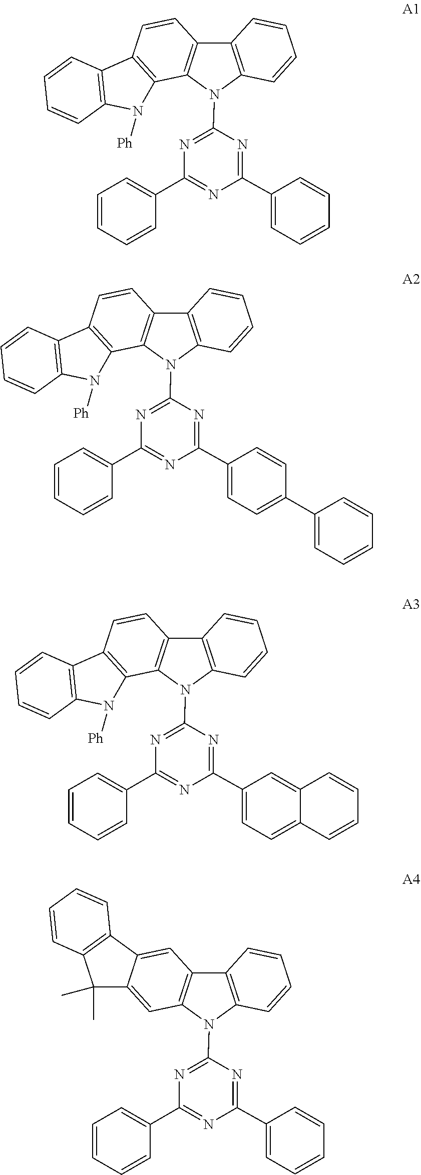

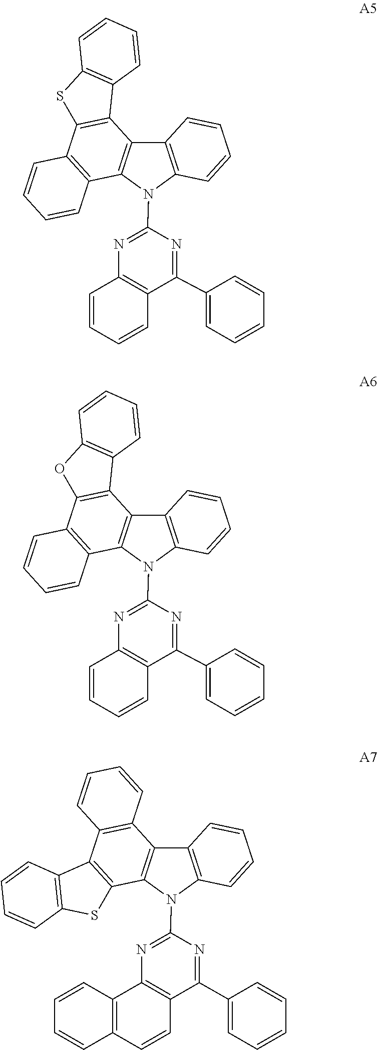 [SMILES: c1ccc(-c2nc(-n3c4ccccc4c4c5c6ccccc6sc5c5ccccc5c43)nc3ccccc23)cc1 ; c1ccc(-c2nc(-n3c4ccccc4c4c5c6ccccc6oc5c5ccccc5c43)nc3ccccc23)cc1 ; c1ccc(-c2nc(-n3c4ccccc4c4c5ccccc5c5c6ccccc6sc5c43)nc3c2ccc2ccccc23)cc1]

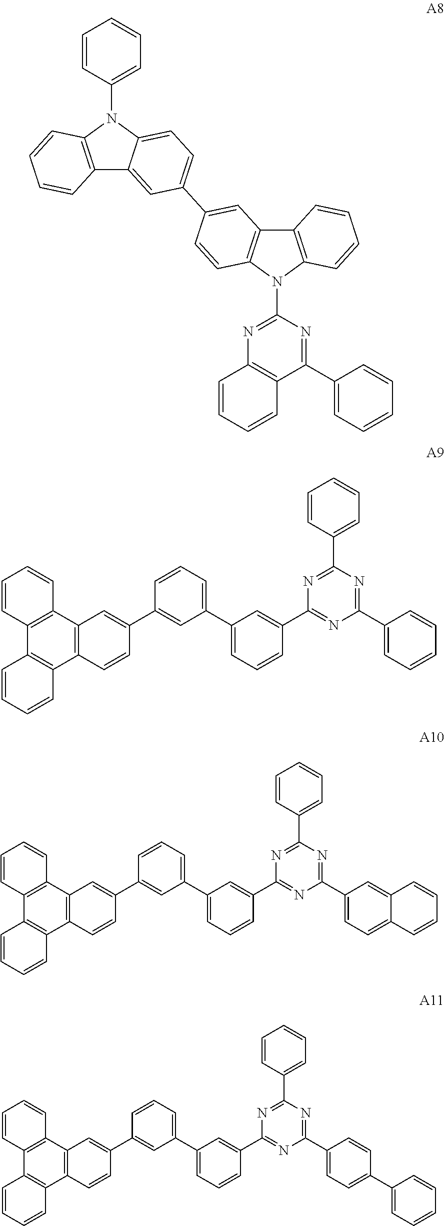 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3cccc(-c4cccc(-c5ccc6c7ccccc7c7ccccc7c6c5)c4)c3)nc(-c3ccc4ccccc4c3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1]

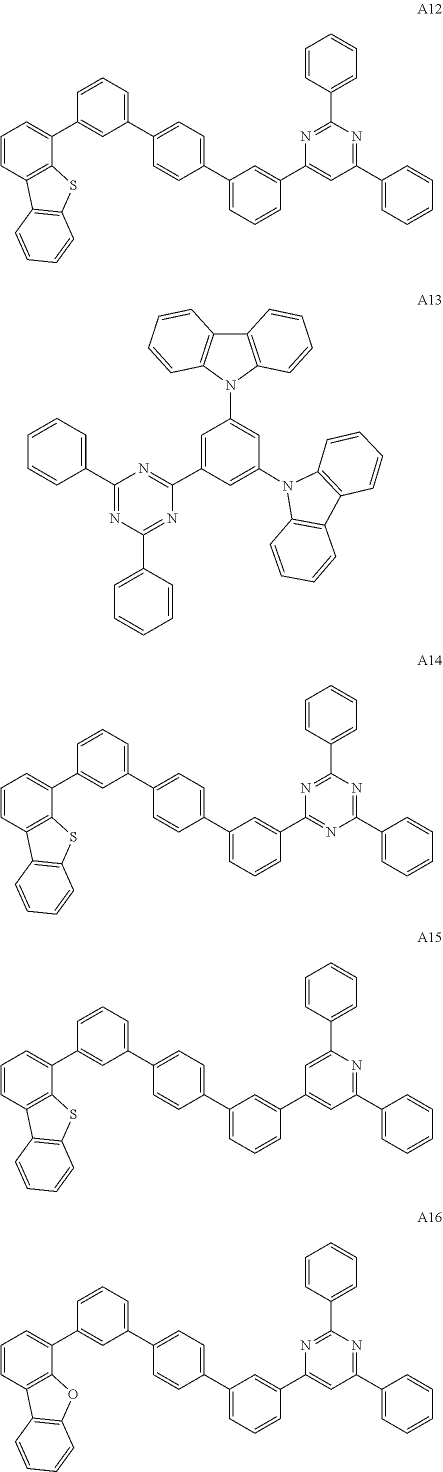 [SMILES: c1ccc(-c2cc(-c3cccc(-c4ccc(-c5cccc(-c6cccc7c6sc6ccccc67)c5)cc4)c3)nc(-c3ccccc3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1ccc(-c2nc(-c3ccccc3)nc(-c3cccc(-c4ccc(-c5cccc(-c6cccc7c6sc6ccccc67)c5)cc4)c3)n2)cc1 ; c1ccc(-c2cc(-c3cccc(-c4ccc(-c5cccc(-c6cccc7c6sc6ccccc67)c5)cc4)c3)cc(-c3ccccc3)n2)cc1 ; c1ccc(-c2cc(-c3cccc(-c4ccc(-c5cccc(-c6cccc7c6oc6ccccc67)c5)cc4)c3)nc(-c3ccccc3)n2)cc1]

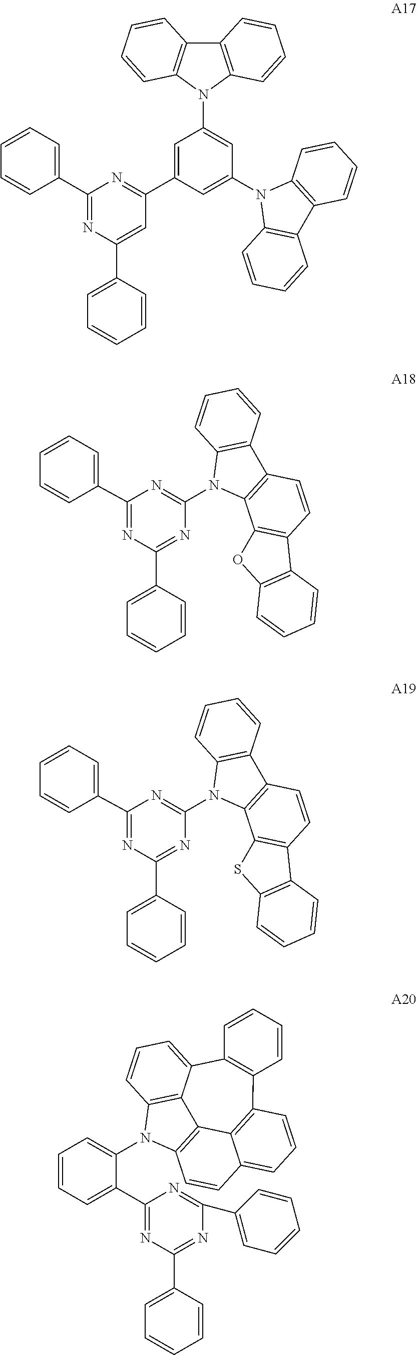 [SMILES: c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2nc(-c3ccccc3)nc(-n3c4ccccc4c4ccc5c6ccccc6oc5c43)n2)cc1 ; c1ccc(-c2nc(-c3ccccc3)nc(-n3c4ccccc4c4ccc5c6ccccc6sc5c43)n2)cc1 ; c1ccc(-c2nc(-c3ccccc3)nc(-c3ccccc3-n3c4cccc5c4c4c6c(cccc6ccc43)-c3ccccc3-5)n2)cc1]

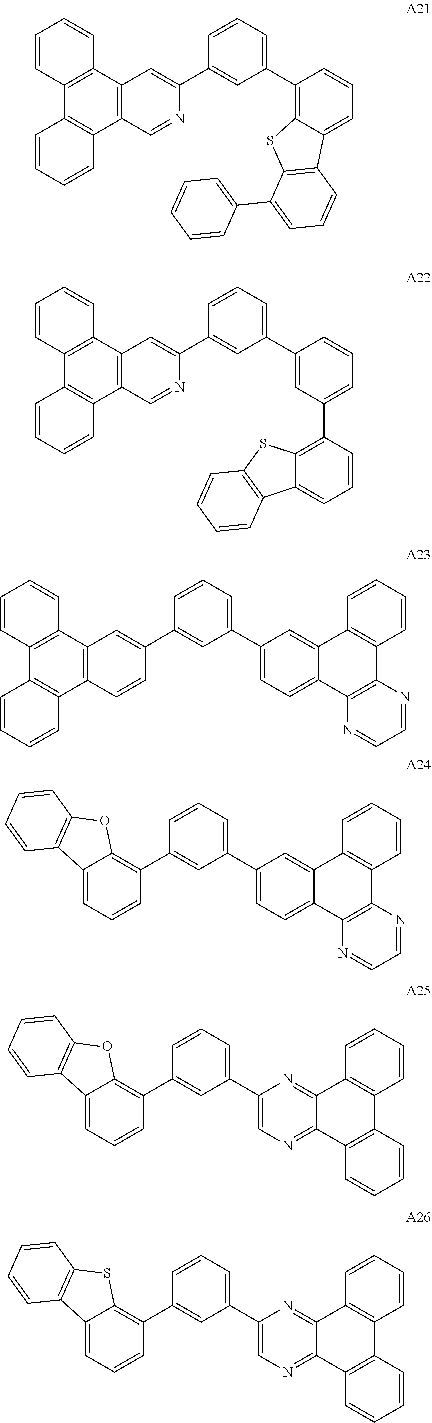 [SMILES: c1ccc(-c2cccc3c2sc2c(-c4cccc(-c5cc6c7ccccc7c7ccccc7c6cn5)c4)cccc23)cc1 ; c1cc(-c2cccc(-c3cccc4c3sc3ccccc34)c2)cc(-c2cc3c4ccccc4c4ccccc4c3cn2)c1 ; c1cc(-c2ccc3c4ccccc4c4ccccc4c3c2)cc(-c2ccc3c(c2)c2ccccc2c2nccnc32)c1 ; c1cc(-c2ccc3c(c2)c2ccccc2c2nccnc32)cc(-c2cccc3c2oc2ccccc23)c1 ; c1cc(-c2cnc3c4ccccc4c4ccccc4c3n2)cc(-c2cccc3c2oc2ccccc23)c1 ; c1cc(-c2cnc3c4ccccc4c4ccccc4c3n2)cc(-c2cccc3c2sc2ccccc23)c1]

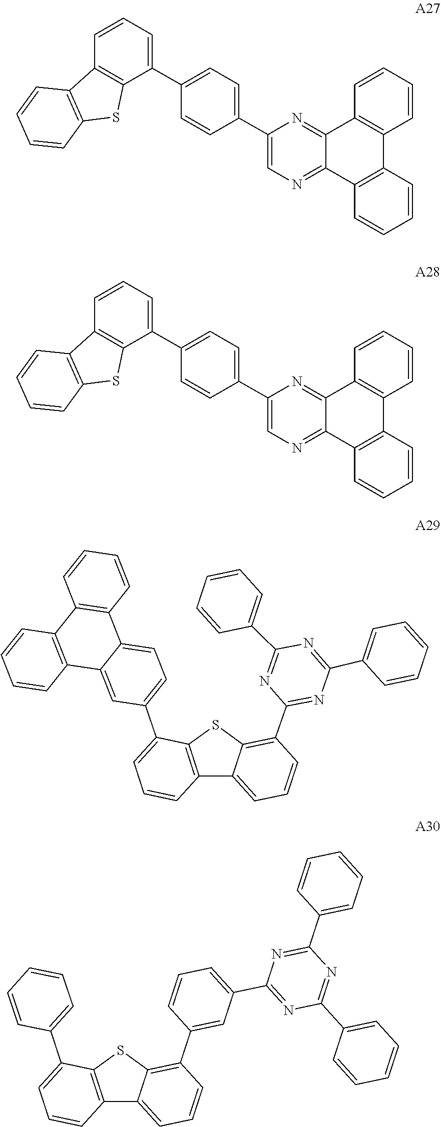 [SMILES: c1ccc2c(c1)sc1c(-c3ccc(-c4cnc5c6ccccc6c6ccccc6c5n4)cc3)cccc12 ; c1ccc2c(c1)sc1c(-c3ccc(-c4cnc5c6ccccc6c6ccccc6c5n4)cc3)cccc12 ; c1ccc(-c2nc(-c3ccccc3)nc(-c3cccc4c3sc3c(-c5ccc6c7ccccc7c7ccccc7c6c5)cccc34)n2)cc1 ; c1ccc(-c2nc(-c3ccccc3)nc(-c3cccc(-c4cccc5c4sc4c(-c6ccccc6)cccc45)c3)n2)cc1]

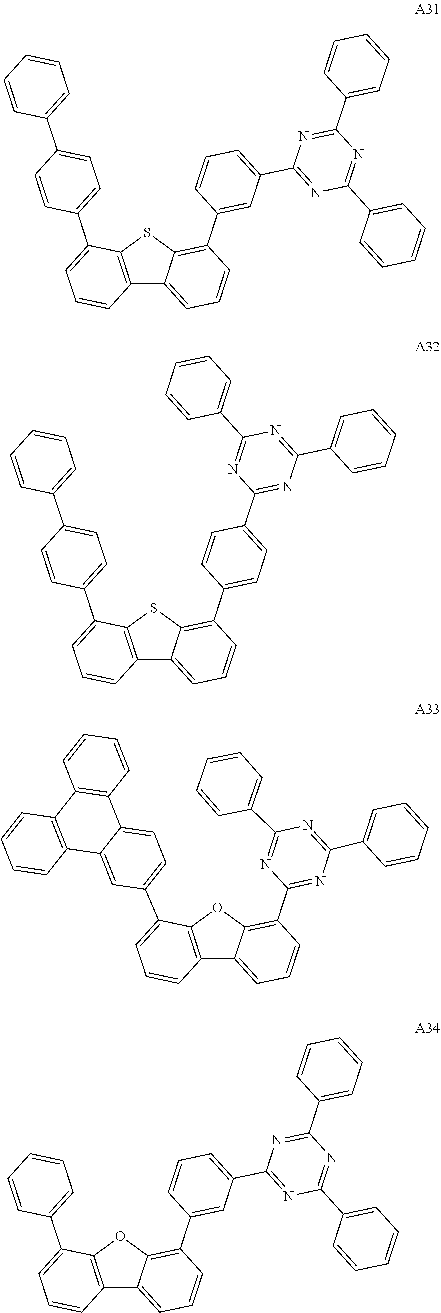 [SMILES: c1ccc(-c2ccc(-c3cccc4c3sc3c(-c5cccc(-c6nc(-c7ccccc7)nc(-c7ccccc7)n6)c5)cccc34)cc2)cc1 ; c1ccc(-c2ccc(-c3cccc4c3sc3c(-c5ccc(-c6nc(-c7ccccc7)nc(-c7ccccc7)n6)cc5)cccc34)cc2)cc1 ; c1ccc(-c2nc(-c3ccccc3)nc(-c3cccc4c3oc3c(-c5ccc6c7ccccc7c7ccccc7c6c5)cccc34)n2)cc1 ; c1ccc(-c2nc(-c3ccccc3)nc(-c3cccc(-c4cccc5c4oc4c(-c6ccccc6)cccc45)c3)n2)cc1]

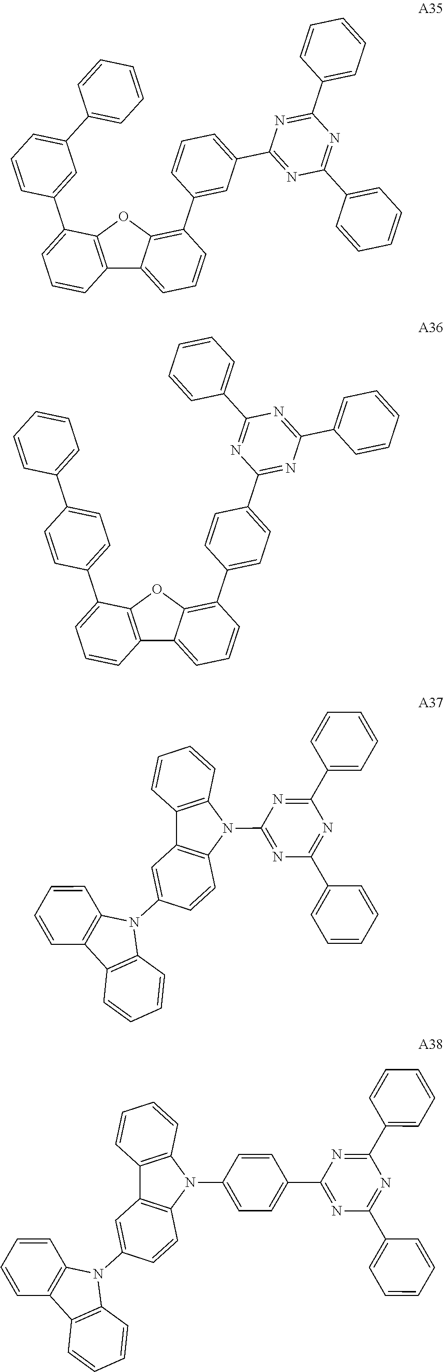 [SMILES: c1ccc(-c2cccc(-c3cccc4c3oc3c(-c5cccc(-c6nc(-c7ccccc7)nc(-c7ccccc7)n6)c5)cccc34)c2)cc1 ; c1ccc(-c2ccc(-c3cccc4c3oc3c(-c5ccc(-c6nc(-c7ccccc7)nc(-c7ccccc7)n6)cc5)cccc34)cc2)cc1 ; c1ccc(-c2nc(-c3ccccc3)nc(-n3c4ccccc4c4cc(-n5c6ccccc6c6ccccc65)ccc43)n2)cc1 ; c1ccc(-c2nc(-c3ccccc3)nc(-c3ccc(-n4c5ccccc5c5cc(-n6c7ccccc7c7ccccc76)ccc54)cc3)n2)cc1]

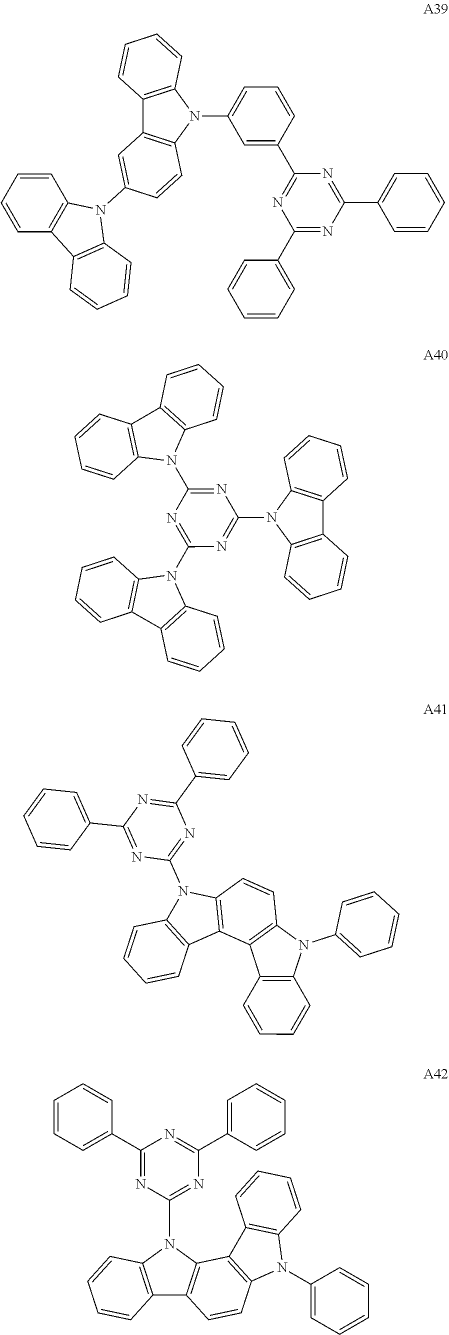 [SMILES: c1ccc(-c2nc(-c3ccccc3)nc(-c3cccc(-n4c5ccccc5c5cc(-n6c7ccccc7c7ccccc76)ccc54)c3)n2)cc1 ; c1ccc2c(c1)c1ccccc1n2-c1nc(-n2c3ccccc3c3ccccc32)nc(-n2c3ccccc3c3ccccc32)n1 ; c1ccc(-c2nc(-c3ccccc3)nc(-n3c4ccccc4c4c5c6ccccc6n(-c6ccccc6)c5ccc43)n2)cc1 ; c1ccc(-c2nc(-c3ccccc3)nc(-n3c4ccccc4c4ccc5c(c6ccccc6n5-c5ccccc5)c43)n2)cc1]

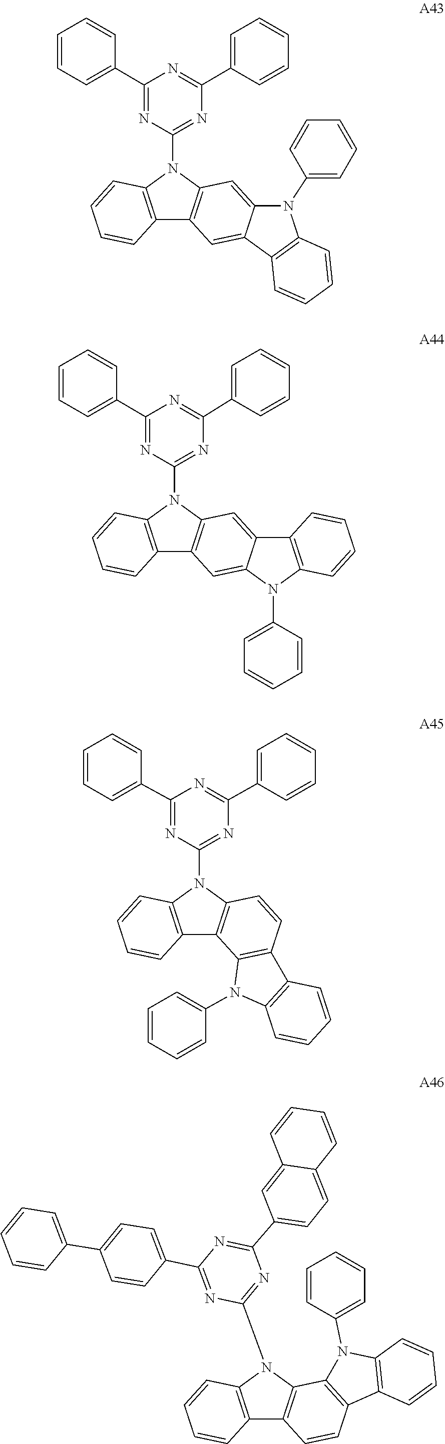

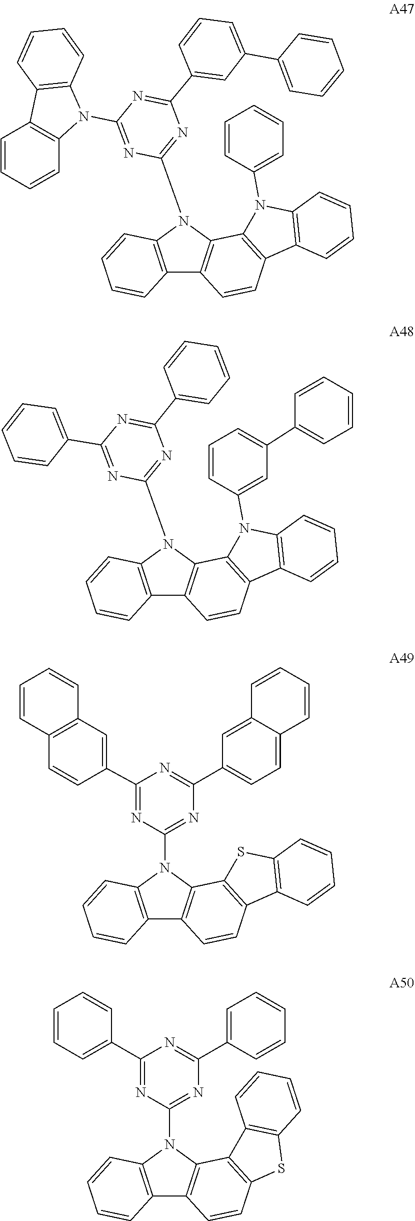 [SMILES: c1ccc(-c2cccc(-c3nc(-n4c5ccccc5c5ccccc54)nc(-n4c5ccccc5c5ccc6c7ccccc7n(-c7ccccc7)c6c54)n3)c2)cc1 ; c1ccc(-c2cccc(-n3c4ccccc4c4ccc5c6ccccc6n(-c6nc(-c7ccccc7)nc(-c7ccccc7)n6)c5c43)c2)cc1 ; c1ccc2cc(-c3nc(-c4ccc5ccccc5c4)nc(-n4c5ccccc5c5ccc6c7ccccc7sc6c54)n3)ccc2c1 ; c1ccc(-c2nc(-c3ccccc3)nc(-n3c4ccccc4c4ccc5sc6ccccc6c5c43)n2)cc1]

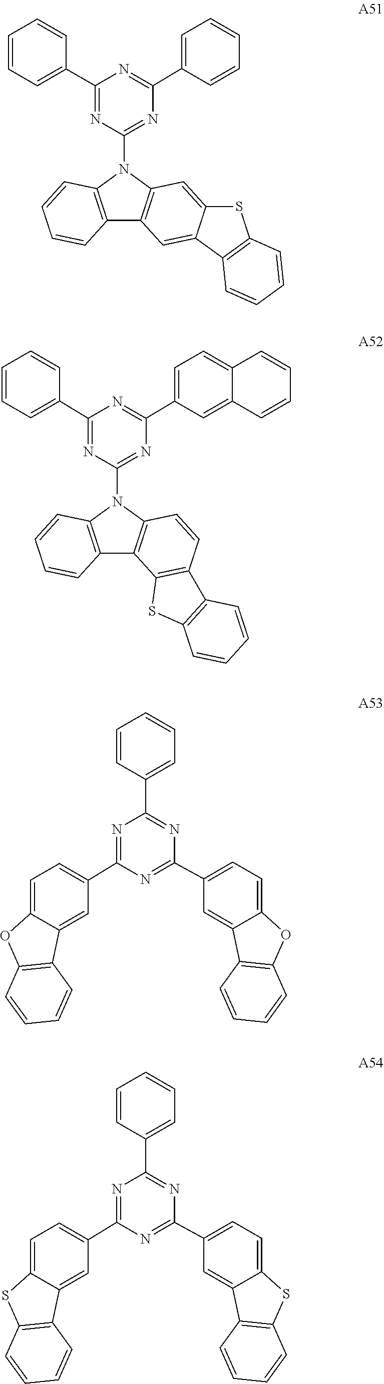 [SMILES: c1ccc(-c2nc(-c3ccccc3)nc(-n3c4ccccc4c4cc5c(cc43)sc3ccccc35)n2)cc1 ; c1ccc(-c2nc(-c3ccc4ccccc4c3)nc(-n3c4ccccc4c4c5sc6ccccc6c5ccc43)n2)cc1 ; c1ccc(-c2nc(-c3ccc4oc5ccccc5c4c3)nc(-c3ccc4oc5ccccc5c4c3)n2)cc1 ; c1ccc(-c2nc(-c3ccc4sc5ccccc5c4c3)nc(-c3ccc4sc5ccccc5c4c3)n2)cc1]

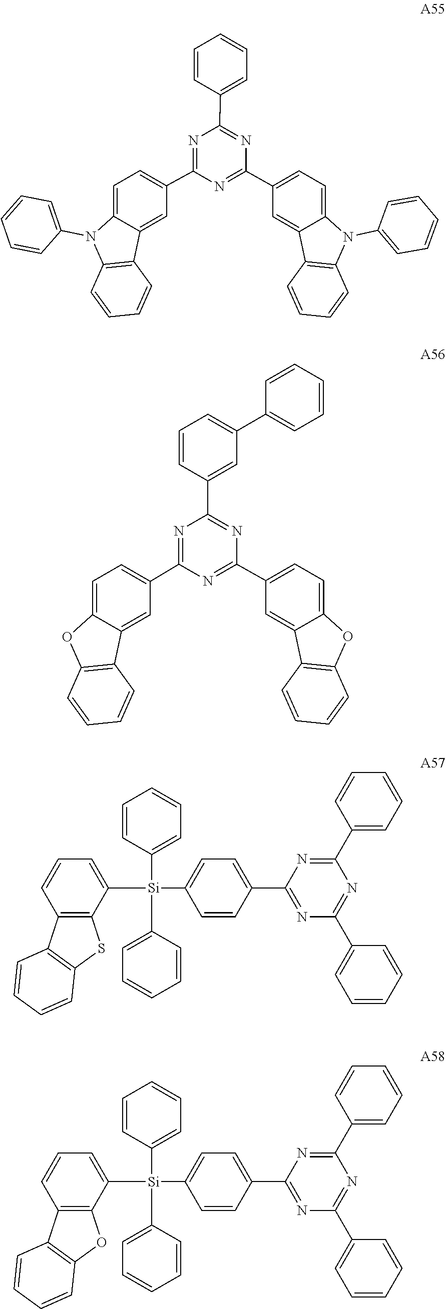 [SMILES: c1ccc(-c2nc(-c3ccc4c(c3)c3ccccc3n4-c3ccccc3)nc(-c3ccc4c(c3)c3ccccc3n4-c3ccccc3)n2)cc1 ; c1ccc(-c2cccc(-c3nc(-c4ccc5oc6ccccc6c5c4)nc(-c4ccc5oc6ccccc6c5c4)n3)c2)cc1 ; c1ccc(-c2nc(-c3ccccc3)nc(-c3ccc([Si](c4ccccc4)(c4ccccc4)c4cccc5c4sc4ccccc45)cc3)n2)cc1 ; c1ccc(-c2nc(-c3ccccc3)nc(-c3ccc([Si](c4ccccc4)(c4ccccc4)c4cccc5c4oc4ccccc45)cc3)n2)cc1]

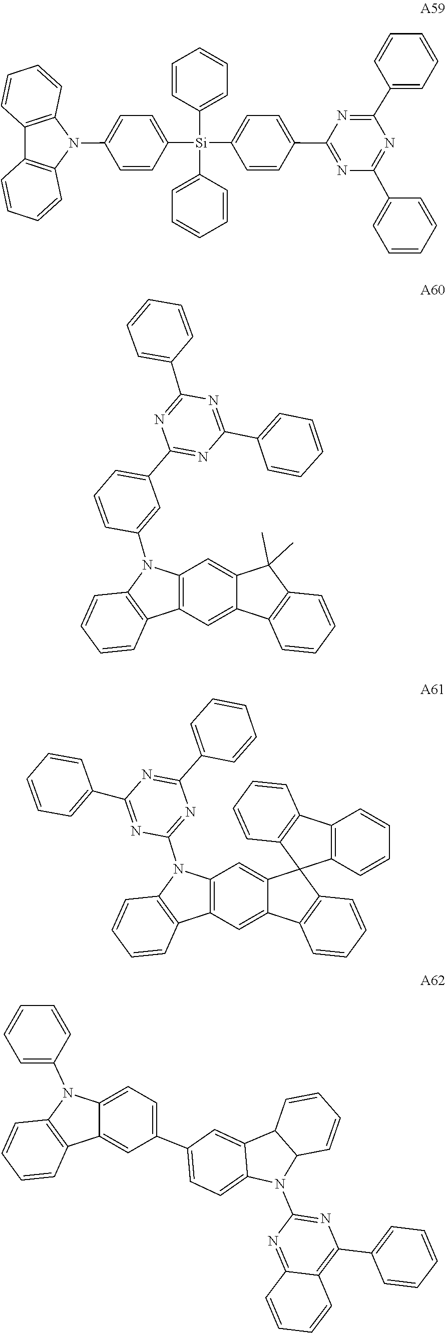 [SMILES: c1ccc(-c2nc(-c3ccccc3)nc(-c3ccc([Si](c4ccccc4)(c4ccccc4)c4ccc(-n5c6ccccc6c6ccccc65)cc4)cc3)n2)cc1 ; CC1(C)c2ccccc2-c2cc3c4ccccc4n(-c4cccc(-c5nc(-c6ccccc6)nc(-c6ccccc6)n5)c4)c3cc21 ; c1ccc(-c2nc(-c3ccccc3)nc(-n3c4ccccc4c4cc5c(cc43)C3(c4ccccc4-c4ccccc43)c3ccccc3-5)n2)cc1 ; C1=CC2c3cc(-c4ccc5c(c4)c4ccccc4n5-c4ccccc4)ccc3N(c3nc(-c4ccccc4)c4ccccc4n3)C2C=C1]

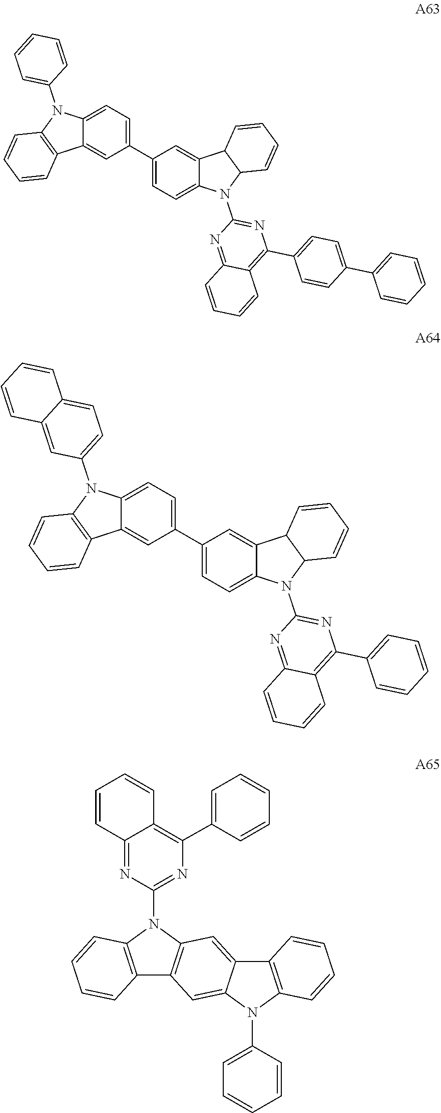 [SMILES: C1=CC2c3cc(-c4ccc5c(c4)c4ccccc4n5-c4ccccc4)ccc3N(c3nc(-c4ccc(-c5ccccc5)cc4)c4ccccc4n3)C2C=C1 ; C1=CC2c3cc(-c4ccc5c(c4)c4ccccc4n5-c4ccc5ccccc5c4)ccc3N(c3nc(-c4ccccc4)c4ccccc4n3)C2C=C1 ; c1ccc(-c2nc(-n3c4ccccc4c4cc5c(cc43)c3ccccc3n5-c3ccccc3)nc3ccccc23)cc1]

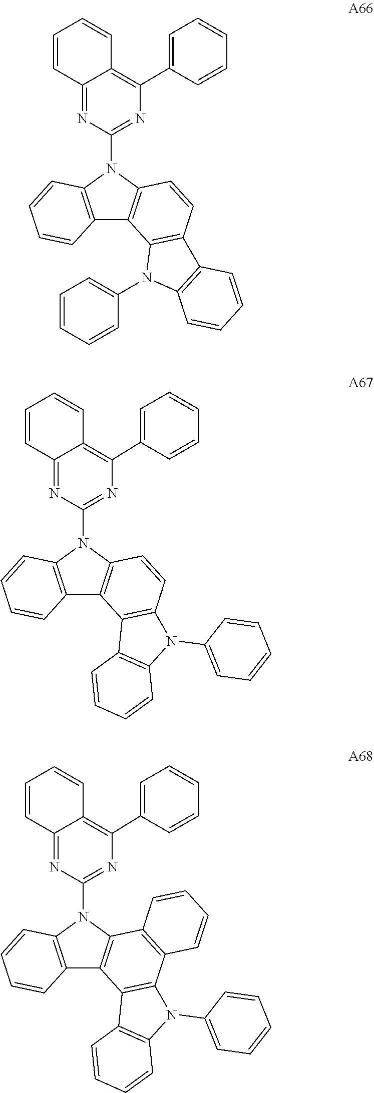 [SMILES: c1ccc(-c2nc(-n3c4ccccc4c4c3ccc3c5ccccc5n(-c5ccccc5)c34)nc3ccccc23)cc1 ; c1ccc(-c2nc(-n3c4ccccc4c4c5c6ccccc6n(-c6ccccc6)c5ccc43)nc3ccccc23)cc1 ; c1ccc(-c2nc(-n3c4ccccc4c4c5c6ccccc6n(-c6ccccc6)c5c5ccccc5c43)nc3ccccc23)cc1]

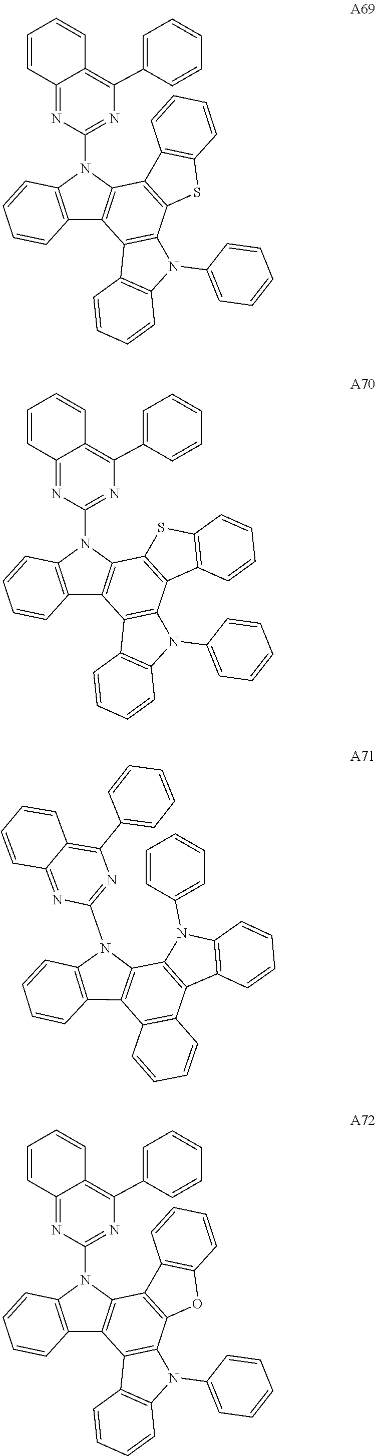

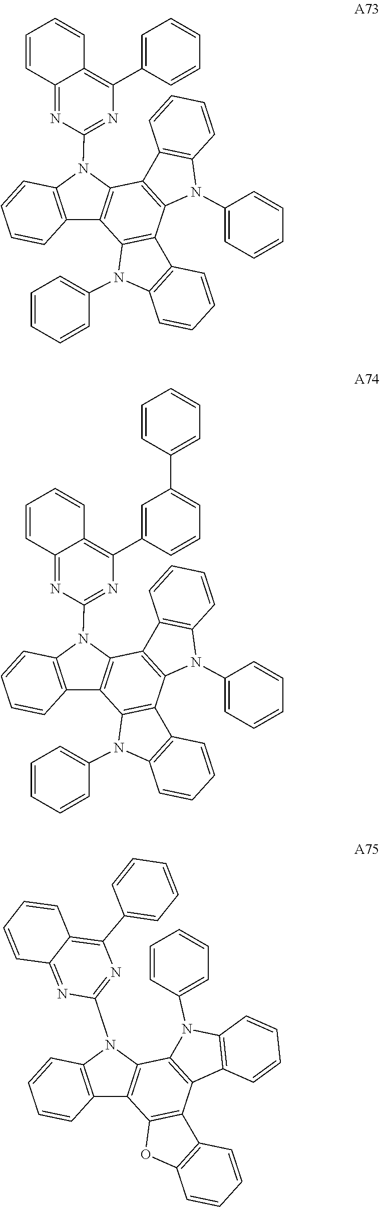 [SMILES: c1ccc(-c2nc(-n3c4ccccc4c4c5c(c6ccccc6n5-c5ccccc5)c5c(c6ccccc6n5-c5ccccc5)c43)nc3ccccc23)cc1 ; c1ccc(-c2cccc(-c3nc(-n4c5ccccc5c5c6c(c7ccccc7n6-c6ccccc6)c6c(c7ccccc7n6-c6ccccc6)c54)nc4ccccc34)c2)cc1 ; c1ccc(-c2nc(-n3c4ccccc4c4c5oc6ccccc6c5c5c6ccccc6n(-c6ccccc6)c5c43)nc3ccccc23)cc1]

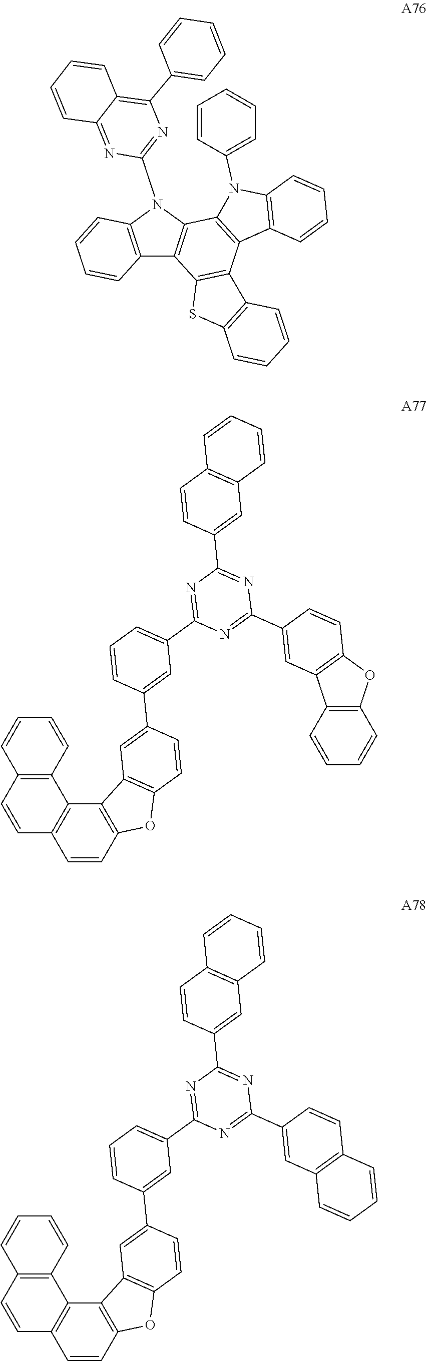 [SMILES: c1ccc(-c2nc(-n3c4ccccc4c4c5sc6ccccc6c5c5c6ccccc6n(-c6ccccc6)c5c43)nc3ccccc23)cc1 ; c1cc(-c2ccc3oc4ccc5ccc6ccccc6c5c4c3c2)cc(-c2nc(-c3ccc4ccccc4c3)nc(-c3ccc4oc5ccccc5c4c3)n2)c1 ; c1cc(-c2ccc3oc4ccc5ccc6ccccc6c5c4c3c2)cc(-c2nc(-c3ccc4ccccc4c3)nc(-c3ccc4ccccc4c3)n2)c1]

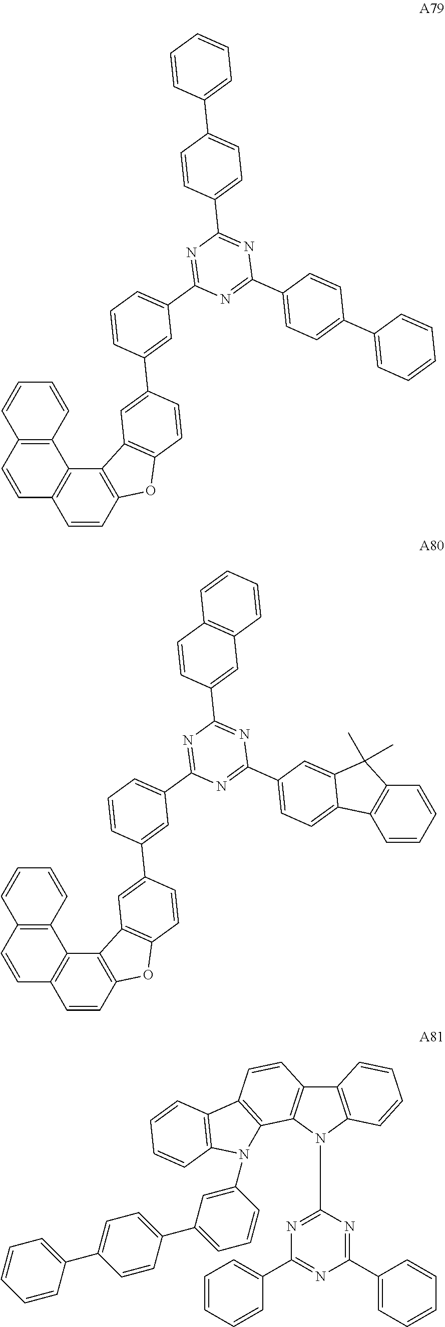 [SMILES: c1ccc(-c2ccc(-c3nc(-c4ccc(-c5ccccc5)cc4)nc(-c4cccc(-c5ccc6oc7ccc8ccc9ccccc9c8c7c6c5)c4)n3)cc2)cc1 ; CC1(C)c2ccccc2-c2ccc(-c3nc(-c4cccc(-c5ccc6oc7ccc8ccc9ccccc9c8c7c6c5)c4)nc(-c4ccc5ccccc5c4)n3)cc21 ; c1ccc(-c2ccc(-c3cccc(-n4c5ccccc5c5ccc6c7ccccc7n(-c7nc(-c8ccccc8)nc(-c8ccccc8)n7)c6c54)c3)cc2)cc1]

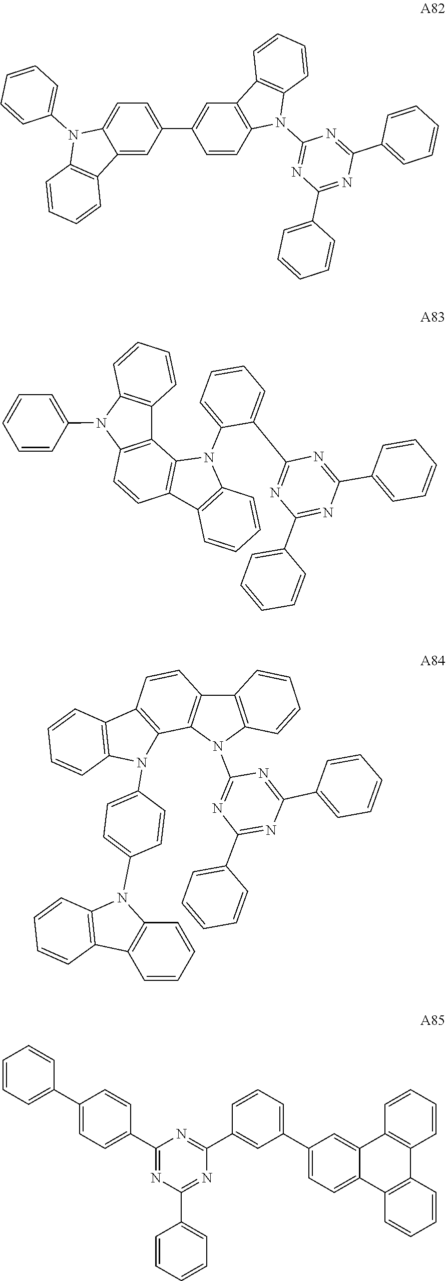 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccccc3-n3c4ccccc4c4ccc5c(c6ccccc6n5-c5ccccc5)c43)n2)cc1 ; c1ccc(-c2nc(-c3ccccc3)nc(-n3c4ccccc4c4ccc5c6ccccc6n(-c6ccc(-n7c8ccccc8c8ccccc87)cc6)c5c43)n2)cc1 ; c1ccc(-c2ccc(-c3nc(-c4ccccc4)nc(-c4cccc(-c5ccc6c7ccccc7c7ccccc7c6c5)c4)n3)cc2)cc1]

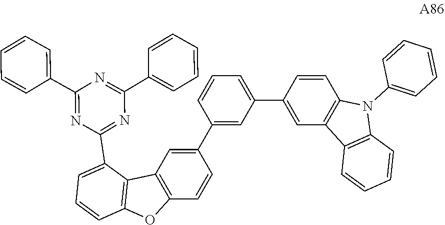 [SMILES: c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1]

In addition, the phosphorescent sensitizer includes, but is not limited to, one or more of the following compounds GPD-1 to GPD-47:

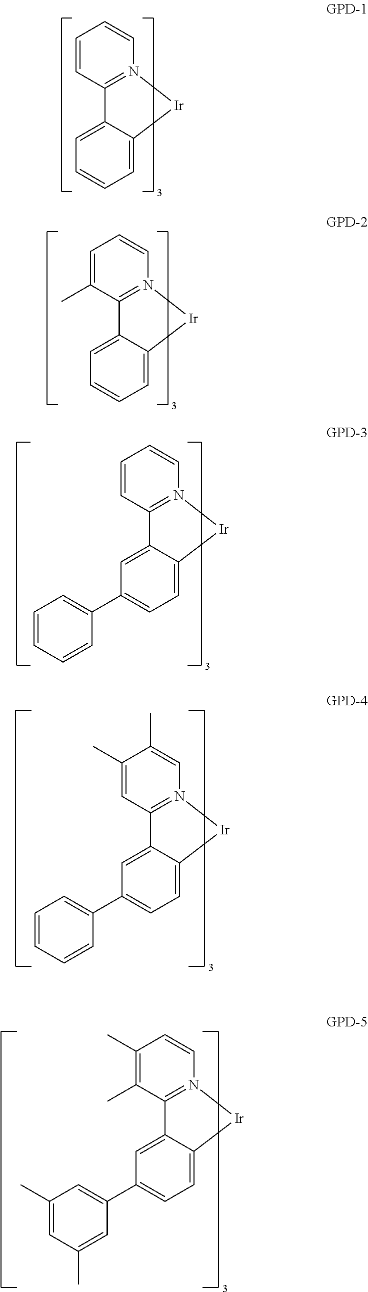

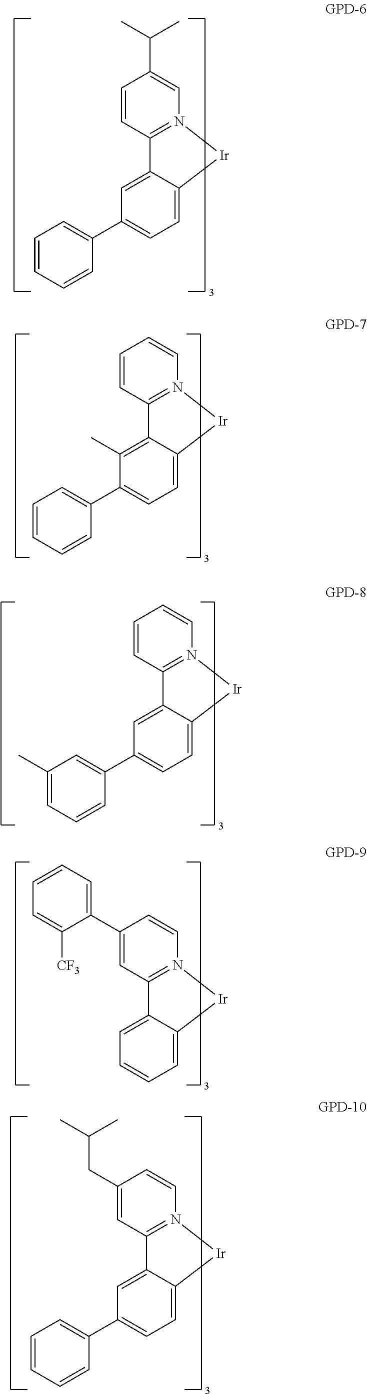

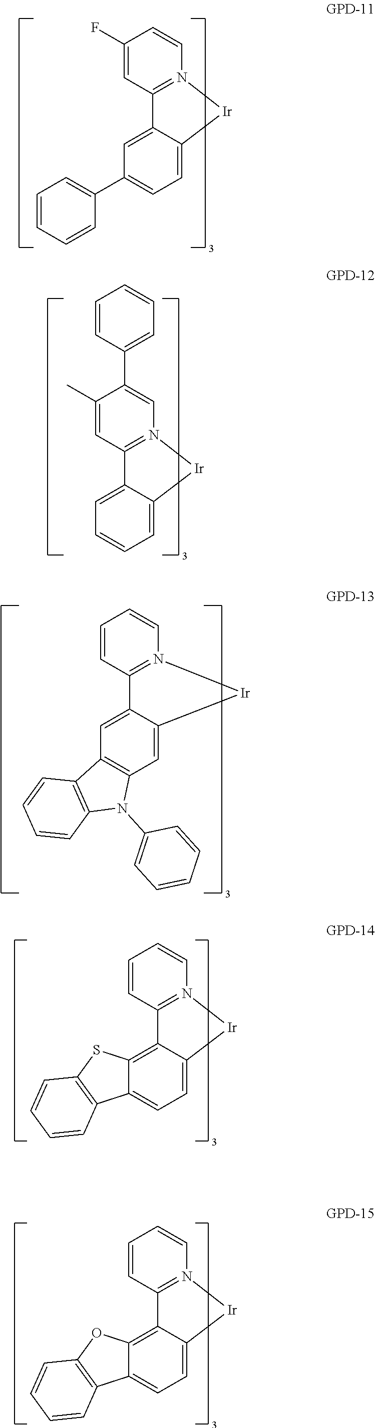

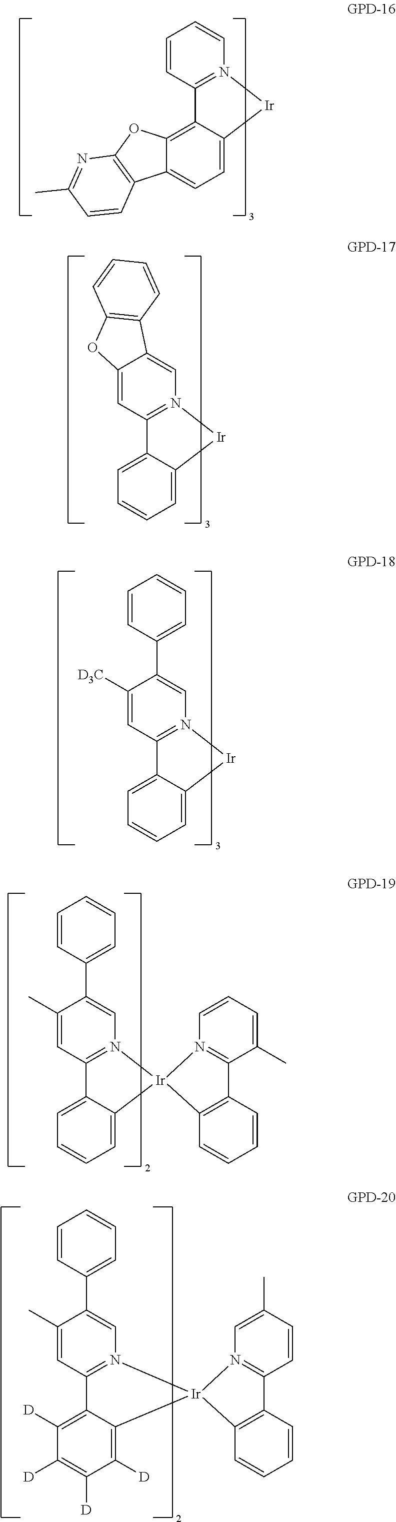

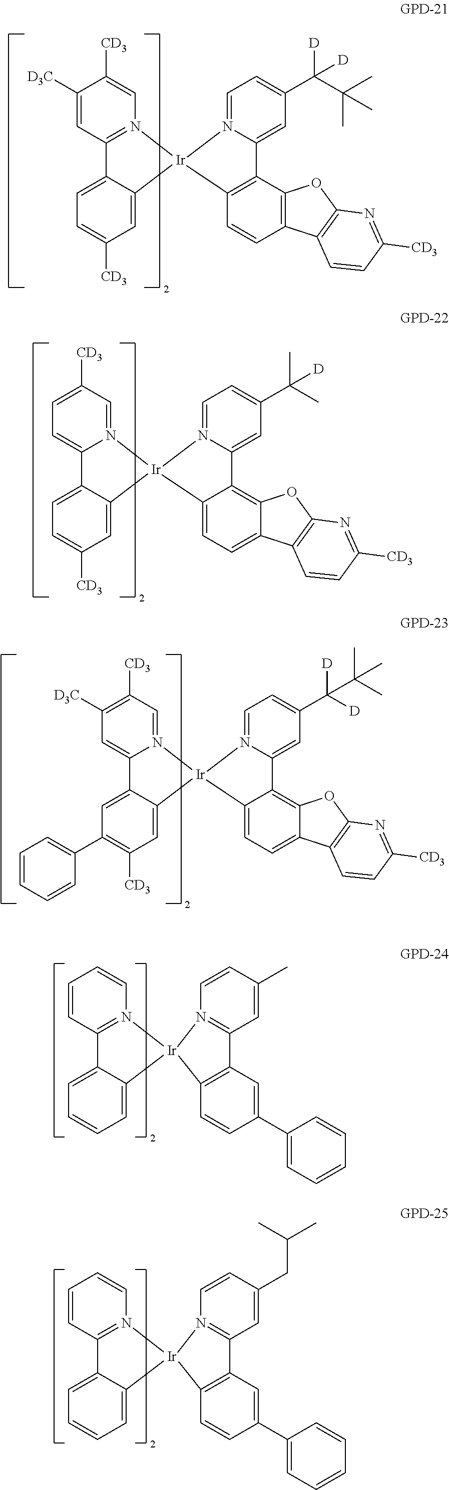

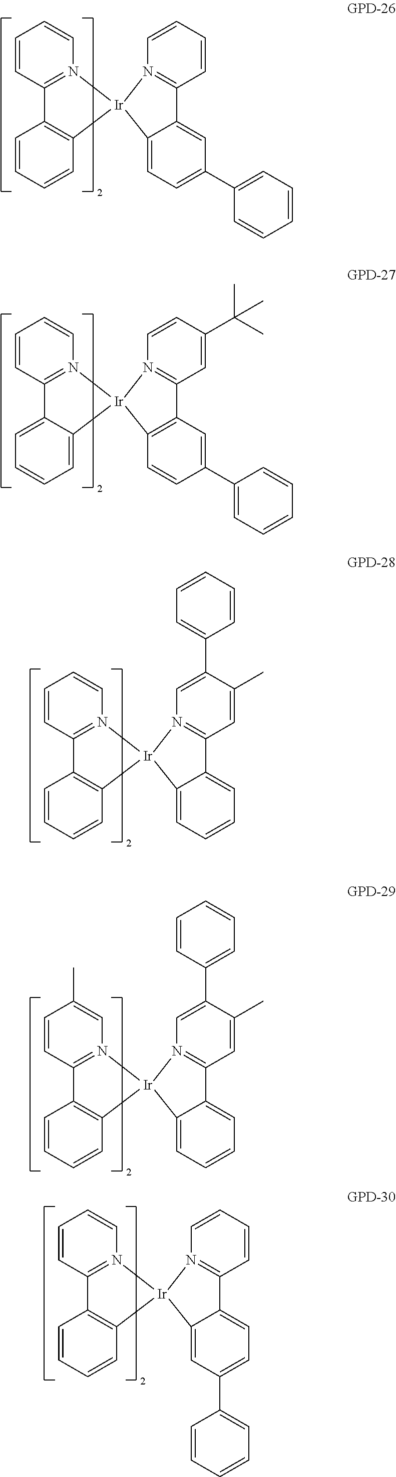

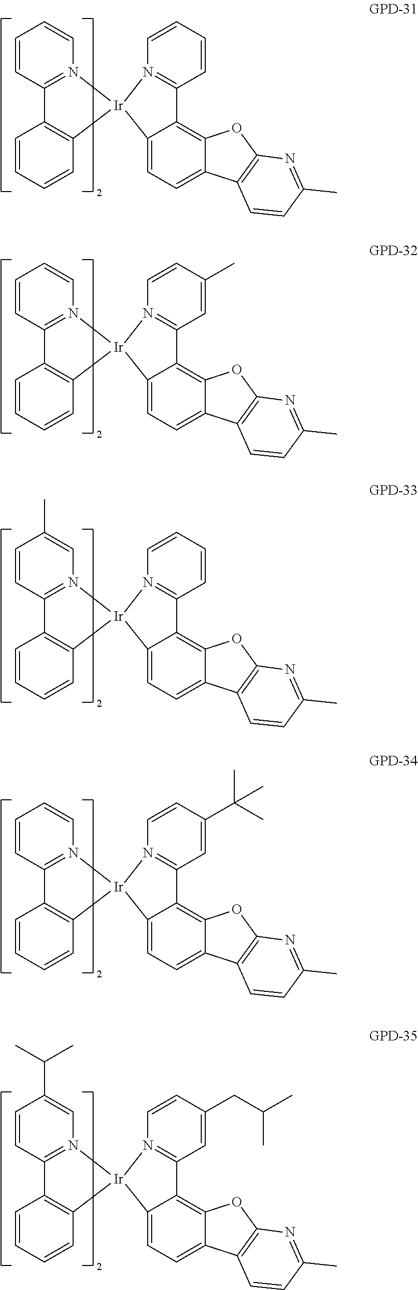

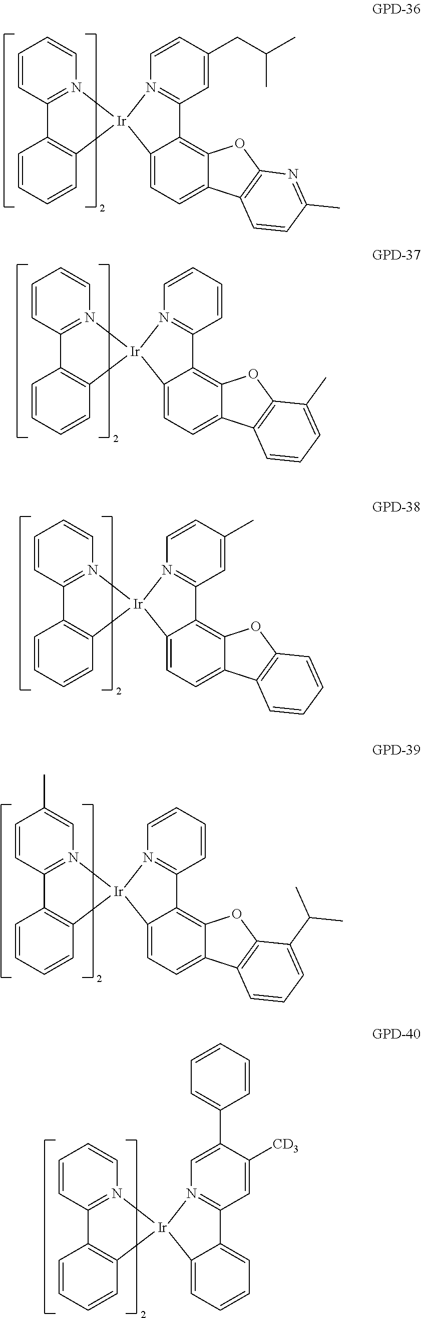

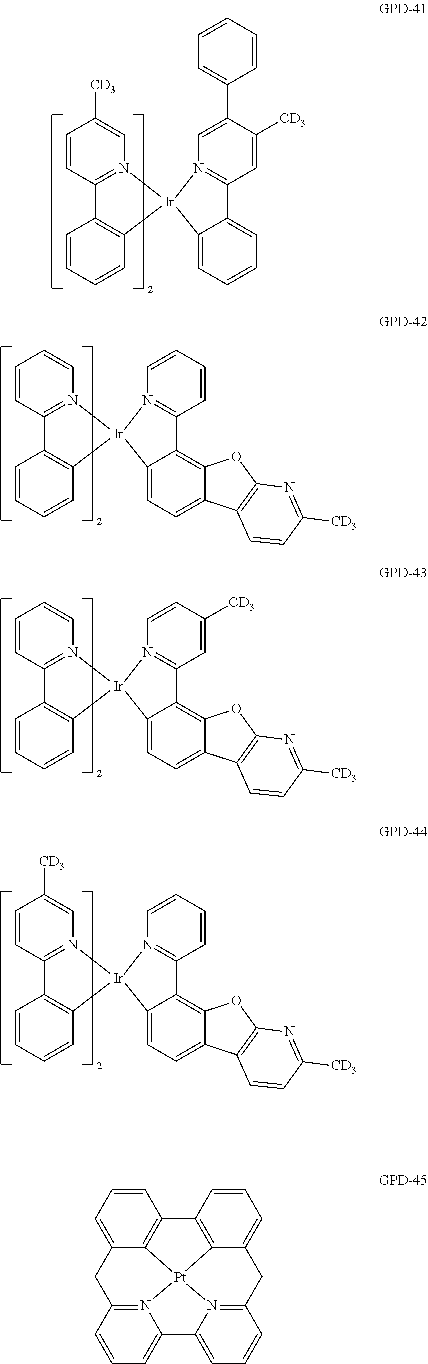

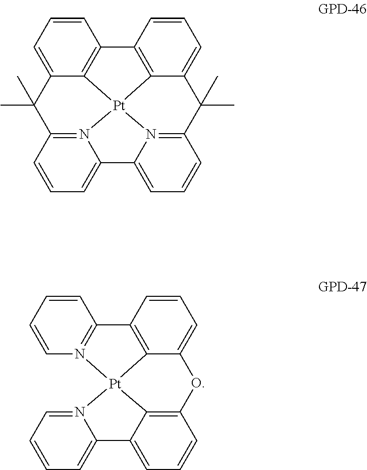

Studies show that comparatively, using one or more of GPD-1 to GPD-47 above as a phosphorescent sensitizer is more conducive to the cooperation of the host material with the narrow-spectrum fluorescent material, thereby further improving the performance such as the efficiency and service life of the device.

Typically, in the phosphorescence sensitized light-emitting layer, the mass content of the phosphorescent sensitizer is 0.1-50%, for example, 0.1%, 3%, 5%, 8%, 10%, 12%, 15%, 18%, 20%, 25%, 30%, 35%, 40%, 45%, and 50%; the mass content of the narrow-spectrum fluorescent material is 0.1-30%, for example 0.1%, 0.3%, 0.5%, 0.8%, 1%, 1.5%, 2%, 2.5%, 3%, 4%, 5%, 6%, 7%, 8%, 9%, 10%, 12%, 15%, 18%, 20%, 25%, and 30%; and the rest is the host material.

In one embodiment, in the phosphorescence sensitized light-emitting layer, the mass content of the phosphorescent sensitizer is 0.1-15%, more preferably not more than 10%, for example, 1-10% or 3-8%, which is conducive to further improving the performance such as the efficiency of the organic light-emitting diode.

In one embodiment, in the phosphorescence sensitized light-emitting layer, the mass content of the narrow-spectrum fluorescent material is 0.1-5%, more preferably 0.5-2% or 0.5-1.5%, which is conducive to further improving the performance such as efficiency of the organic light-emitting diode.

The organic light-emitting diode further includes an anode, a hole transport zone, an electron transport zone, and a cathode, and the light-emitting layer, the hole transport zone and the electron transport zone are placed between the anode and the cathode.

Specifically, as shown in FIG. 1, the organic light-emitting diode may be a single-layer device (or referred to as a single-light-emitting-layer device), that is, the device has one light-emitting layer, and the anode, hole transport zone, light-emitting layer, electron transport zone, and cathode are stacked sequentially.

In one embodiment, as shown in FIG. 2, the organic light-emitting diode is a stacked-layer device, which further includes a charge generation layer (CGL) provided between the anode and the cathode and has at least two light-emitting layers. The at least two light-emitting layers are stacked (or referred to as “piled”), specifically sequentially stacked in the direction from the anode to the cathode, and the charge generation layer is provided between two adjacent light-emitting layers (that is, a charge generation layer is provided between every two adjacent light-emitting layers).

Herein, at least one light-emitting layer is a phosphorescence sensitized light-emitting layer containing a host material, a phosphorescent sensitizer and a narrow-spectrum fluorescent material described above, and the remaining light-emitting layers may also be the phosphorescence sensitized light-emitting layers above, or phosphorescence layers including a host material and a phosphorescent material except for a narrow-spectrum fluorescent material described above.

When the organic light-emitting diode contains both a phosphorescence sensitized light-emitting layer and a phosphorescence layer, the host material in the phosphorescence layer may be the same or different from that in the phosphorescence sensitized light-emitting layer, and the phosphorescent material in the phosphorescence layer may be the same or different from the phosphorescent sensitizer in the phosphorescence sensitized light-emitting layer. When the light-emitting layers of the organic light-emitting diode are all phosphorescence sensitized light-emitting layers, the host materials, the phosphorescent sensitizers, and the narrow-spectrum fluorescent materials in different light-emitting layers may be the same or different.

Specifically, the host material in the phosphorescence layer may include, but is not limited to, one or more of the compounds PH-1 to PH-85, and the phosphorescent material in the phosphorescence layer may include, but is not limited to, one or more of the compounds RPD-1 to RPD-29. In addition, in the phosphorescence layer, the mass content of the phosphorescent material is 0.1-20%, for example, 0.1%, 0.5%, 1%, 3%, 5%, 8%, 10%, 12%, 15%, 18%, and 20%, and the rest is the host material.

In some examples, the organic light-emitting diode may be a green stacked-layer light-emitting device. That is, the light-emitting layers are green light-emitting layers; in other words, a plurality of (at least two) green light-emitting layers are stacked between the anode and the cathode, and at least one of the green light-emitting layers is the phosphorescence sensitized light-emitting layer, which is specifically a green phosphorescence sensitized light-emitting layer for emitting green light.

In the stacked-layer device, the hole transport zone includes a first hole transport zone provided between the anode and the light-emitting layer closest to the anode (e.g., the first light-emitting layer described below), and a first electron transport zone provided between the cathode and the light-emitting layer closest to the cathode (e.g., the second light-emitting layer described below).

In addition, the charge generation layer includes an n-type charge generation layer (n-CGL) and a p-type charge generation layer (p-CGL). When an n-type charge generation layer and a p-type charge generation layer are adjacent to each other, the n-type charge generation layer is provided on one side of the p-type charge generation layer that is away from the cathode, and the p-type charge generation layer is provided on one side of the n-type charge generation layer that is away from the anode. The hole transport zone further includes a second hole transport zone, and the electron transport zone further includes a second electron transport zone. When charge generation layers are provided between two adjacent light-emitting layers, the second electron transport zone is provided between an n-type charge generation layer and a light-emitting layer, and the second hole transport zone is provided between a p-type charge generation layer and another light-emitting layer.

Specifically, the hole transport zones (the first hole transport zone and the second hole transport zone) may include at least one of a hole injection layer (HIL), a hole transport layer (HTL), and an electron blocking layer (EBL). For example, the hole transport zone may be a hole transport layer of a single-layer structure (including a single-layer hole transport layer containing only one compound, or a single-layer hole transport layer containing a plurality of compounds), or a multi-layer structure including at least one of a hole injection layer (HIL), a hole transport layer (HTL), and an electron blocking layer (EBL).

For example, the first hole transport zone includes a hole injection layer, a hole transport layer, and an electron blocking layer, and an anode, the hole injection layer, the hole transport layer, the electron blocking layer, and a light-emitting layer closest to the anode are stacked sequentially.

For example, the second hole transport zone includes a hole transport layer and an electron blocking layer, and a p-type charge generation layer, the hole transport layer, the electron blocking layer, and a light-emitting layer are stacked sequentially.

Specifically, the electron transport zones (the first electron transport zone and the second electron transport zone) may include at least one of an electron injection layer (EIL), an electron transport layer (ETL), and a hole blocking layer (HBL). For example, the electron transport zone may be an electron transport layer of a single-layer structure (including a single-layer electron transport layer containing only one compound, or a single-layer electron transport layer containing a plurality of compounds), or a multi-layer structure including at least one of an electron injection layer (EIL), an electron transport layer (ETL), and a hole blocking layer (HBL).

For example, the first electron transport zone includes an electron injection layer, an electron transport layer, and a hole blocking layer, and a light-emitting layer closest to the cathode, the hole blocking layer, the electron transport layer, the electron injection layer, and a cathode are stacked sequentially.

For example, the second electron transport zone includes an electron transport layer and a hole blocking layer, and a light-emitting layer, the hole blocking layer, the electron transport layer, and an n-type charge generation layer are stacked sequentially.

In some specific examples, as shown in FIG. 1, the organic light-emitting diode is a single-layer device including an anode 10, a first hole injection layer 11, a first hole transport layer 21, a first electron blocking layer 31, a first light-emitting layer 41, a first hole blocking layer 51, a first electron transport layer 61, a first electron injection layer 81 and a cathode 20, which are stacked sequentially.

In other specific examples, as shown in FIG. 2, the organic light-emitting diode is a stacked-layer device including two light-emitting layers, which are a first light-emitting layer 41 and a second light-emitting layer 42, respectively, and an anode 10, the first light-emitting layer 41, the second light-emitting layer 42, and a cathode 20 are sequentially stacked, wherein the first light-emitting layer 41 is a phosphorescence sensitized light-emitting layer, and the second light-emitting layer 42 is a phosphorescence layer; in some embodiments, the second light-emitting layer 42 is a phosphorescence sensitized light-emitting layer, and the first light-emitting layer 41 is a phosphorescence layer; in some embodiments, both the first light-emitting layer 41 and the second light-emitting layer 42 are phosphorescence sensitized light-emitting layers.

Herein, a first hole transport zone provided between the anode 10 and the first light-emitting layer 41 includes a first hole injection layer 11, a first hole transport layer 21, and a first electron blocking layer 31; a second electron transport zone provided between the first light-emitting layer 41 and an n-type charge generation layer 72 includes a second hole blocking layer 52 and a second electron transport layer 62; a second hole transport zone provided between a p-type charge generation layer 71 and the second light-emitting layer 42 includes a second hole transport layer 22 and a second electron blocking layer 32; a first electron transport zone provided between the second light-emitting layer 42 and the cathode 20 includes a first hole blocking layer 51, a first electron transport layer 61, and a first electron injection layer 81; the anode 10, the first hole injection layer 11, the first hole transport layer 21, the first electron blocking layer 31, the first light-emitting layer 41, the second hole blocking layer 52, the second electron transport layer 62, the n-type charge generation layer 72, the p-type charge generation layer 71, the second hole transport layer 22, the second electron blocking layer 32, the second light-emitting layer 42, the first hole blocking layer 51, the first electron transport layer 61, the first electron injection layer 81, and the cathode 20 are sequentially stacked.

Typically, the material of the n-type charge generation layer may include an organic matrix material or a mixture of an organic matrix material and a doping material. The organic matrix material includes, for example, an o-phenanthroline compound, which includes, but is not limited to, one or more of the following compounds CGL-1 to CGL-12. The doping material may include a metal and/or a metal compound such as a metal salt, which includes, but is not limited to, one or more of Liq, LiF, NaCl, CsF, Li₂O, Cs₂CO₃, BaO, Na, Li, Ca, Mg, Ag, and Y b.

In some specific examples, in the n-type charge generation layer, the mass content of the doping material may be 0.1-20%, for example, 0.1%, 0.5%, 1%, 3%, 5%, 8%, 10%, 12%, 15%, 18%, and 20%, and the rest is the organic matrix material.

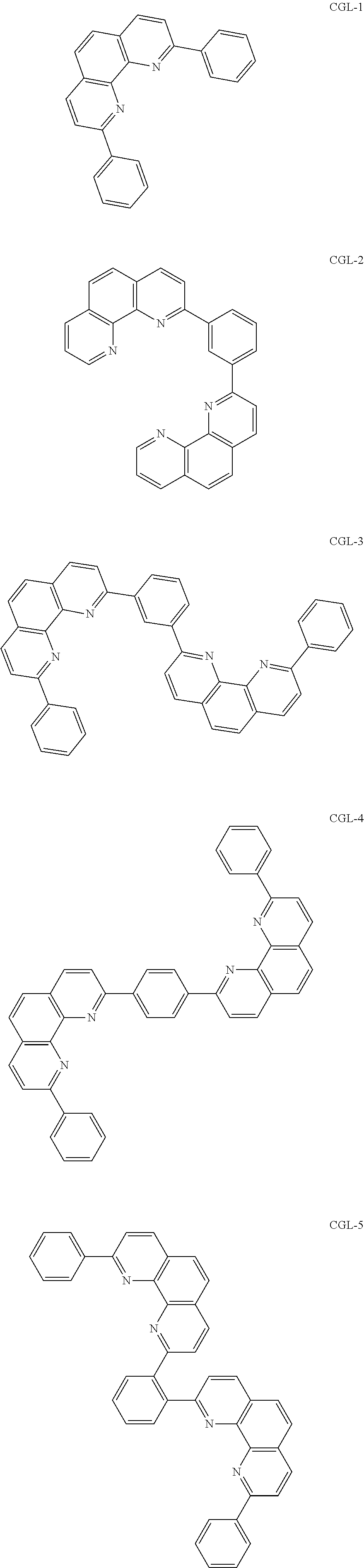 [SMILES: c1ccc(-c2ccc3ccc4ccc(-c5ccccc5)nc4c3n2)cc1 ; c1cc(-c2ccc3ccc4cccnc4c3n2)cc(-c2ccc3ccc4cccnc4c3n2)c1 ; c1ccc(-c2ccc3ccc4ccc(-c5cccc(-c6ccc7ccc8ccc(-c9ccccc9)nc8c7n6)c5)nc4c3n2)cc1 ; c1ccc(-c2ccc3ccc4ccc(-c5ccc(-c6ccc7ccc8ccc(-c9ccccc9)nc8c7n6)cc5)nc4c3n2)cc1 ; c1ccc(-c2ccc3ccc4ccc(-c5ccccc5-c5ccc6ccc7ccc(-c8ccccc8)nc7c6n5)nc4c3n2)cc1]

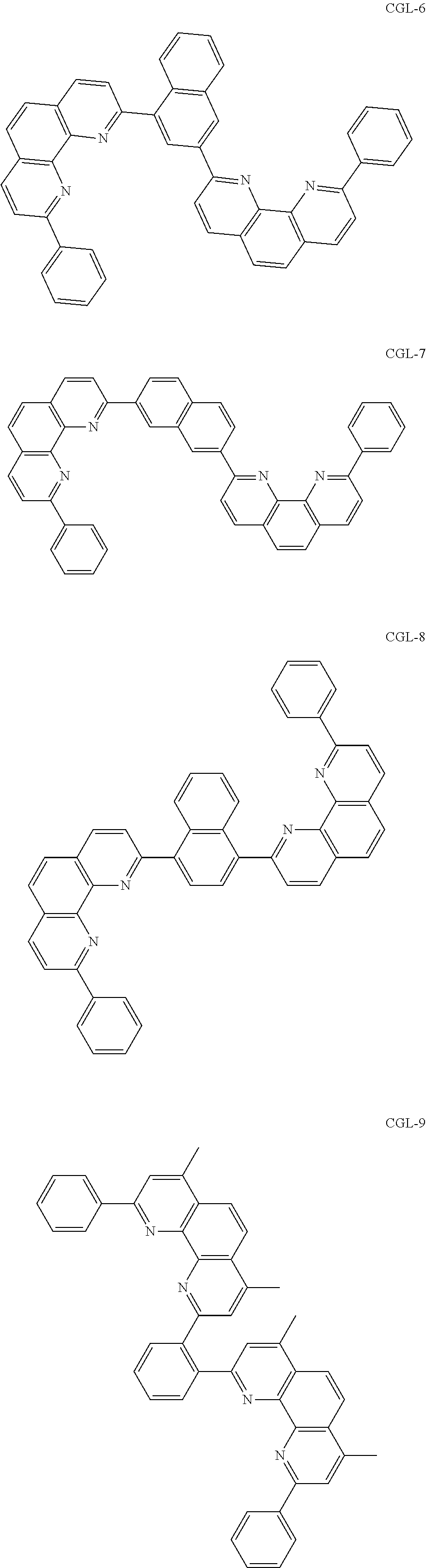 [SMILES: c1ccc(-c2ccc3ccc4ccc(-c5cc(-c6ccc7ccc8ccc(-c9ccccc9)nc8c7n6)c6ccccc6c5)nc4c3n2)cc1 ; c1ccc(-c2ccc3ccc4ccc(-c5ccc6ccc(-c7ccc8ccc9ccc(-c%10ccccc%10)nc9c8n7)cc6c5)nc4c3n2)cc1 ; c1ccc(-c2ccc3ccc4ccc(-c5ccc(-c6ccc7ccc8ccc(-c9ccccc9)nc8c7n6)c6ccccc56)nc4c3n2)cc1 ; Cc1cc(-c2ccccc2)nc2c1ccc1c(C)cc(-c3ccccc3-c3cc(C)c4ccc5c(C)cc(-c6ccccc6)nc5c4n3)nc12]

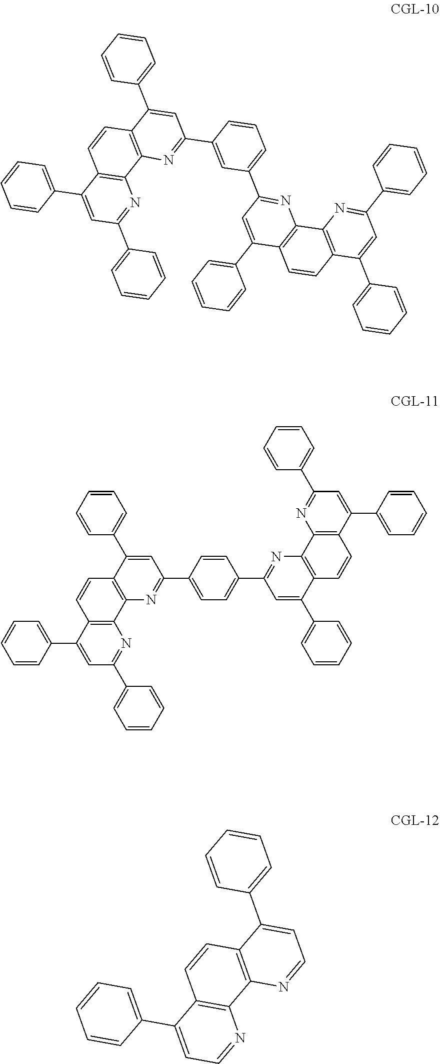 [SMILES: c1ccc(-c2cc(-c3ccccc3)c3ccc4c(-c5ccccc5)cc(-c5cccc(-c6cc(-c7ccccc7)c7ccc8c(-c9ccccc9)cc(-c9ccccc9)nc8c7n6)c5)nc4c3n2)cc1 ; c1ccc(-c2cc(-c3ccccc3)c3ccc4c(-c5ccccc5)cc(-c5ccc(-c6cc(-c7ccccc7)c7ccc8c(-c9ccccc9)cc(-c9ccccc9)nc8c7n6)cc5)nc4c3n2)cc1 ; c1ccc(-c2ccnc3c2ccc2c(-c4ccccc4)ccnc23)cc1]

In addition, the material of the p-type charge generation layer may include, but is not limited to, one or more of the following compounds HT-1 to HT-51 and HI-1 to HI-3. For example, it may be a mixture of a first type of compound (one or more of HT-1 to HT-51) and a second type of compound (one or more of HI-1 to HI-3).

In some specific examples, in the p-type charge generation layer, the mass content of the second type of compound is 0.1-30%, for example, 0.1%, 0.5%, 1%, 3%, 5%, 8%, 10%, 12%, 15%, 18%, 20%, 22%, 25%, 28%, and 30%, and the rest is the first type of compound.

In addition, the thickness of the light-emitting layer (a phosphorescence sensitized light-emitting layer or a phosphorescence layer) may be 200 Å-500 Å, for example, 200 Å, 220 Å, 250 Å, 280 Å, 300 Å, 350 Å, 380 Å, 400 Å, 450 Å, 480 Å, and 500 Å, and 300-400 Å is generally preferred.

In addition, the organic light-emitting diode further includes a substrate, on which an anode can be formed by sputtering or depositing an anode material, and the remaining layers can be formed through vacuum thermal evaporation, spin coating, printing and other conventional methods in the art. This will not be explained in detail. Herein, the substrate may be a glass or polymer material with excellent mechanical strength, thermal stability, water resistance and transparency. Additionally, a substrate used as a display may also be provided with a thin film transistor (TFT).

For example, the anode includes indium tin oxide (ITO), indium zinc oxide (IZO), tin dioxide (SnO₂), zinc oxide (ZnO) and other transparent conductive oxide materials and combinations thereof. The cathode material may be magnesium (Mg), silver (Ag), aluminum (Al), aluminum-lithium (Al—Li), calcium (Ca), magnesium-indium (Mg—In), magnesium-silver (M g-A g) and other metals or alloys and any combination thereof.

In some examples, the organic light-emitting diode may be a top light-emitting device (or referred to as a top-emitting device), and a substrate structure with an anode may be a top-emitting substrate structure conventionally used in the art for a top-emitting device. For example, a substrate structure with an anode includes an ITO layer, a silver layer and an ITO layer, which are stacked sequentially and have a thickness of 100 Å, 1,000 Å and 100 Å, respectively.

In addition, the side of the cathode that is away from the anode may further be provided with a capping layer (CPL) 9, which is used to adjust the top-emission microcavity to adjust the light color and efficiency of the top-emitting device.

Herein, the thickness of the capping layer 9 may be a conventional thickness of such layers in the art, for example 500-800 Å, such as 500 Å, 550 Å, 600 Å, 650 Å, 700 Å, 750 Å and 800 Å.

In addition, the material of the capping layer 9 may be a conventional material for such layers in the art, including, for example, one or more of the following compounds CPL-1 to CPL-3:

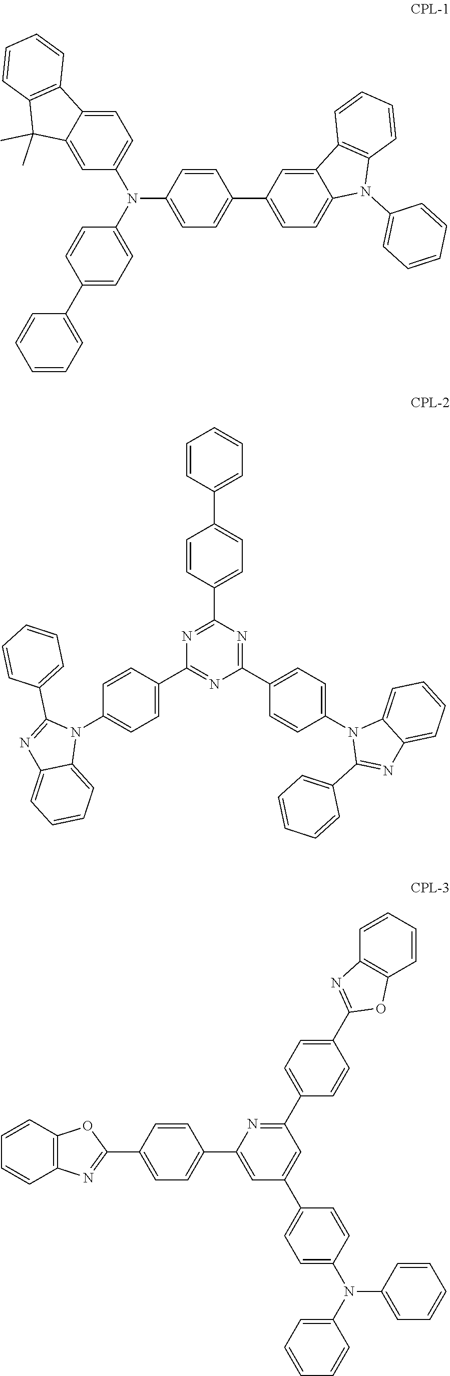 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3nc(-c4ccc(-n5c(-c6ccccc6)nc6ccccc65)cc4)nc(-c4ccc(-n5c(-c6ccccc6)nc6ccccc65)cc4)n3)cc2)cc1 ; c1ccc(N(c2ccccc2)c2ccc(-c3cc(-c4ccc(-c5nc6ccccc6o5)cc4)nc(-c4ccc(-c5nc6ccccc6o5)cc4)c3)cc2)cc1]

In addition, the material of the hole transport zone includes, but is not limited to, one or more of the following compounds: a phthalocyanine derivative (such as CuPc), a conductive polymer or a conductive-dopant-containing polymer (such as poly(phenylene vinylene), polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), and polyaniline/poly(4-styrenesulfonate) (Pani/PSS)), and an aromatic amine derivative, wherein the aromatic amine derivative includes one or more of the following compounds HT-1 to HT-51:

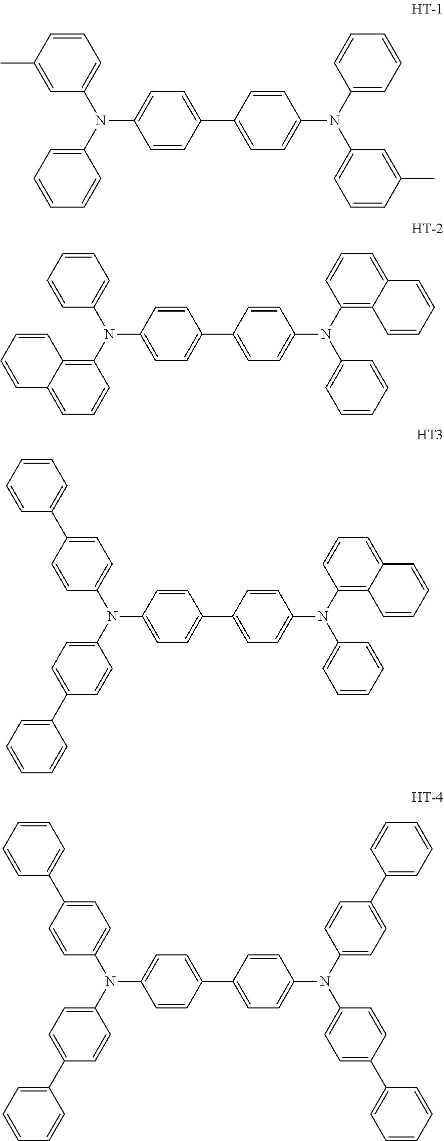

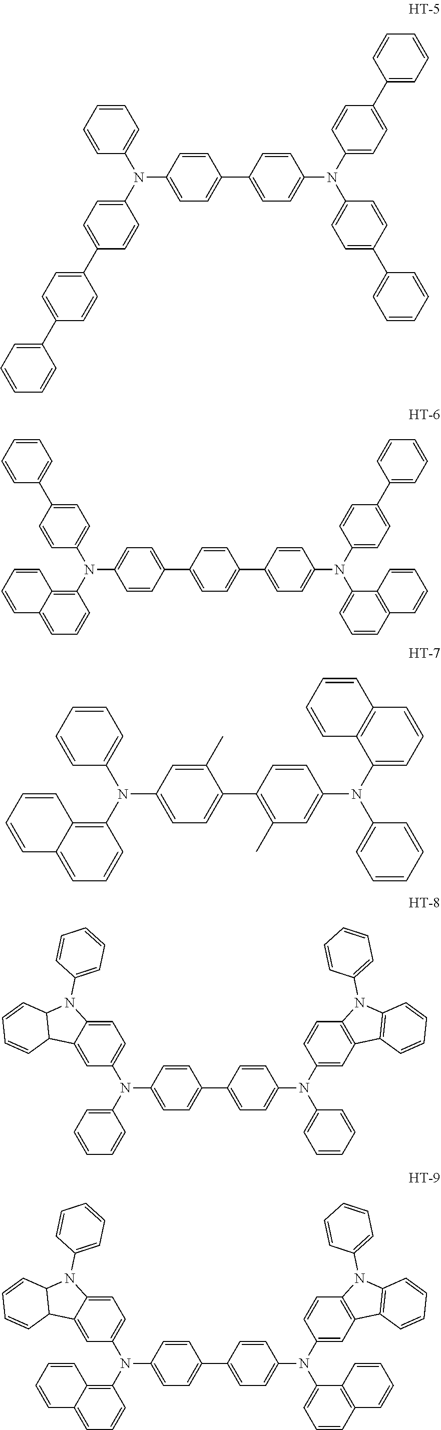

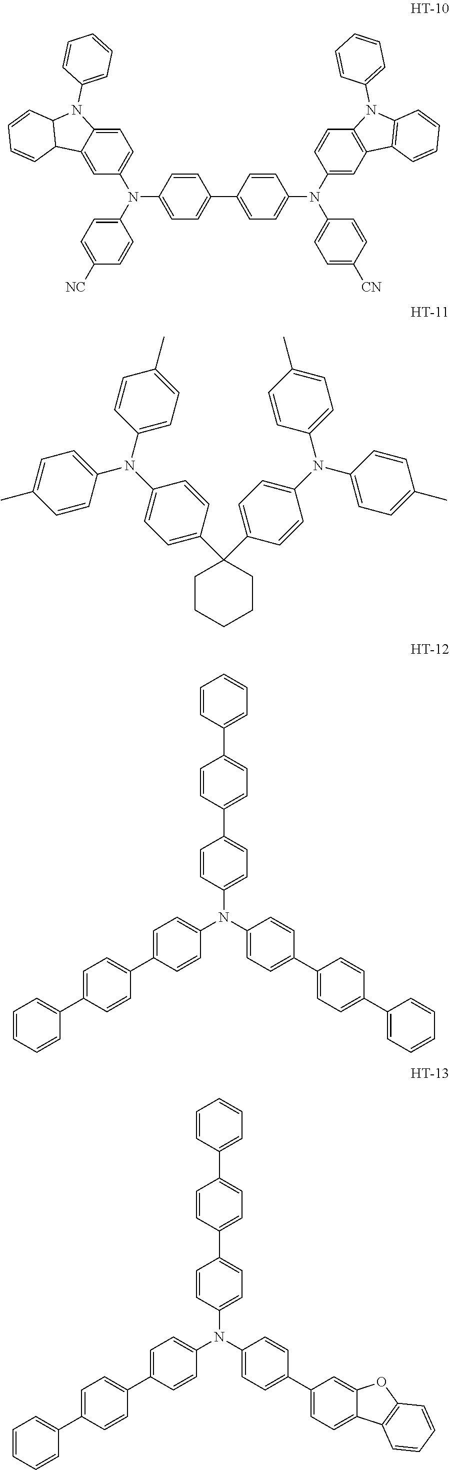

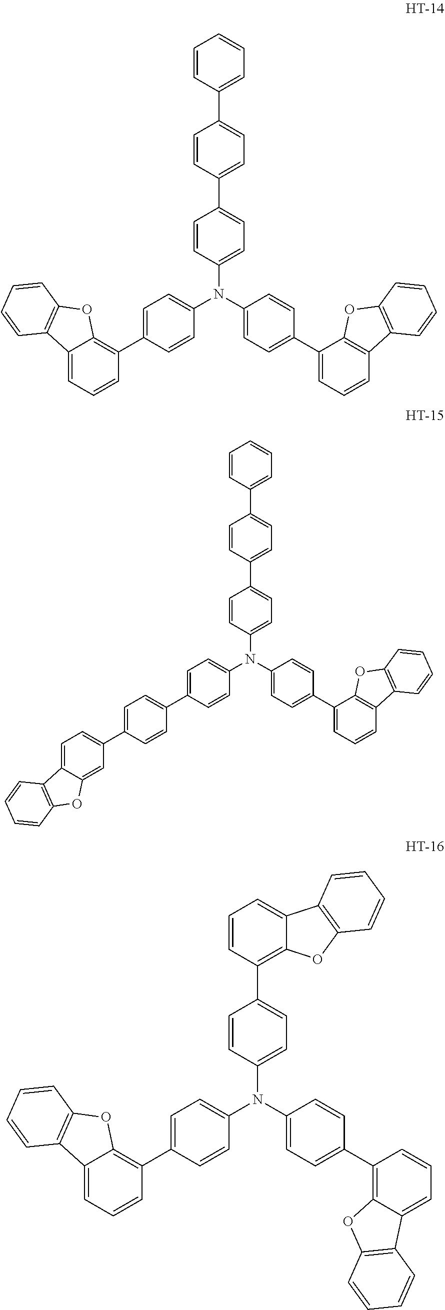 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(-c3ccc(N(c4ccc(-c5ccc(-c6ccc7c(c6)oc6ccccc67)cc5)cc4)c4ccc(-c5cccc6c5oc5ccccc56)cc4)cc3)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12]

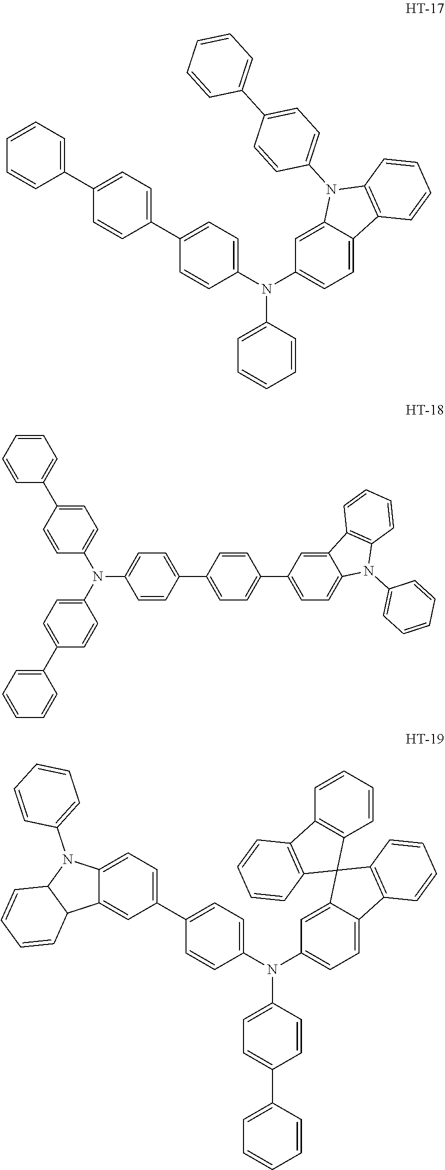 [SMILES: c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; C1=CC2c3cc(-c4ccc(N(c5ccc(-c6ccccc6)cc5)c5ccc6c(c5)C5(c7ccccc7-c7ccccc75)c5ccccc5-6)cc4)ccc3N(c3ccccc3)C2C=C1]

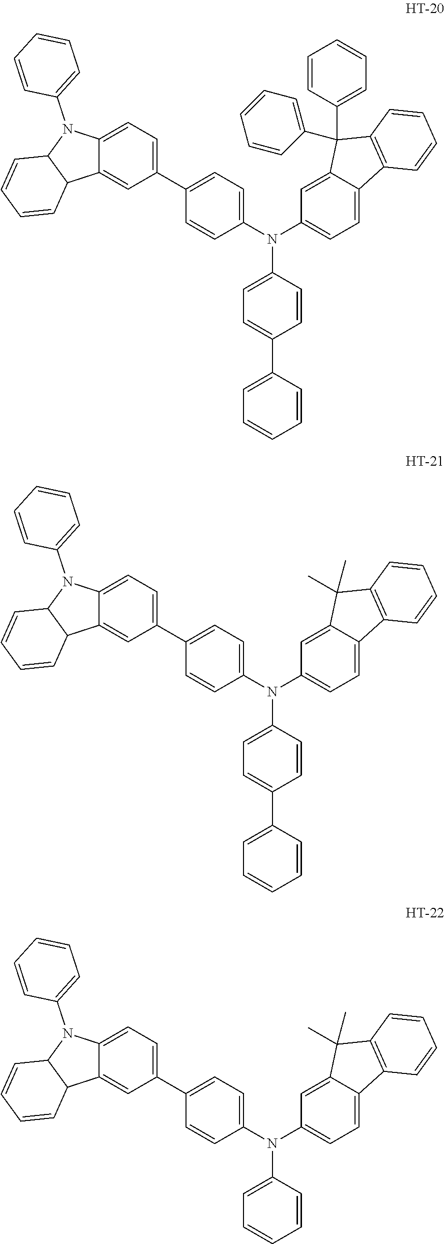 [SMILES: C1=CC2c3cc(-c4ccc(N(c5ccc(-c6ccccc6)cc5)c5ccc6c(c5)C(c5ccccc5)(c5ccccc5)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)C4C=CC=CC4N5c4ccccc4)cc3)cc21 ; CC1(C)c2ccccc2-c2ccc(N(c3ccccc3)c3ccc(-c4ccc5c(c4)C4C=CC=CC4N5c4ccccc4)cc3)cc21]

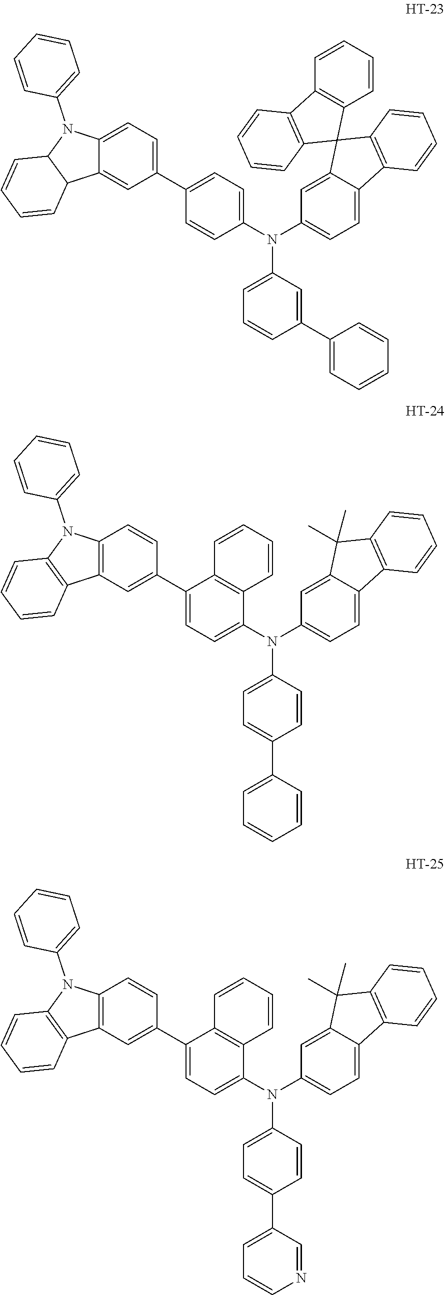 [SMILES: C1=CC2c3cc(-c4ccc(N(c5cccc(-c6ccccc6)c5)c5ccc6c(c5)C5(c7ccccc7-c7ccccc75)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)c4ccccc4n5-c4ccccc4)c4ccccc34)cc21 ; CC1(C)c2ccccc2-c2ccc(N(c3ccc(-c4cccnc4)cc3)c3ccc(-c4ccc5c(c4)c4ccccc4n5-c4ccccc4)c4ccccc34)cc21]

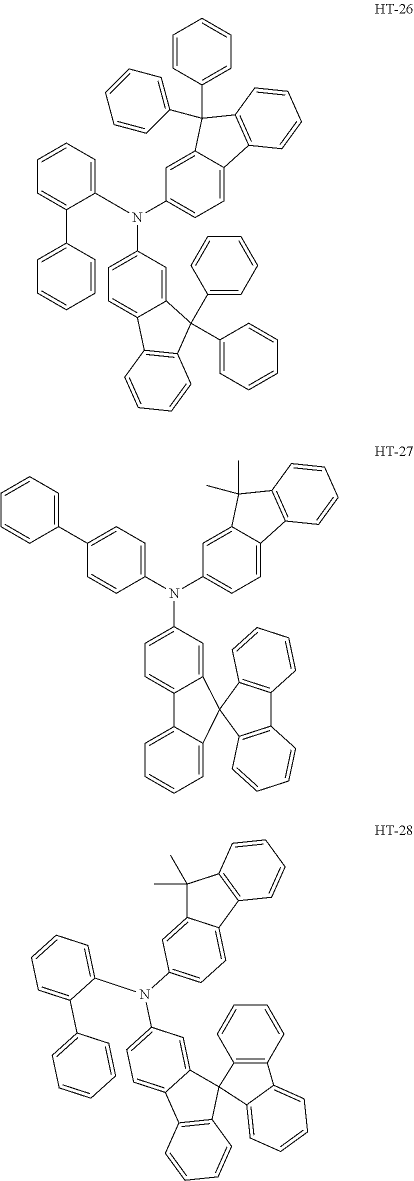 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21]

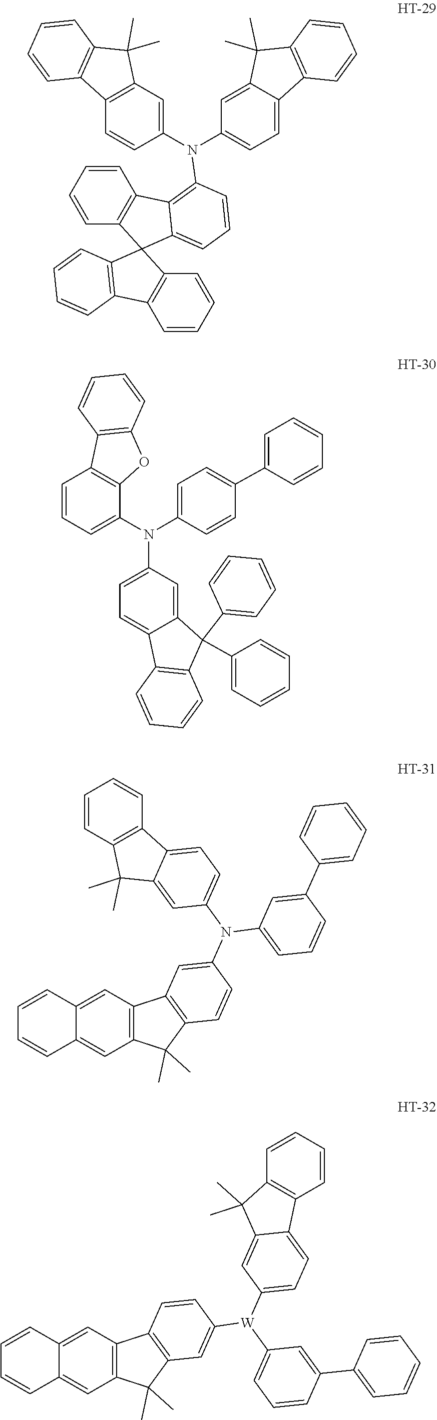

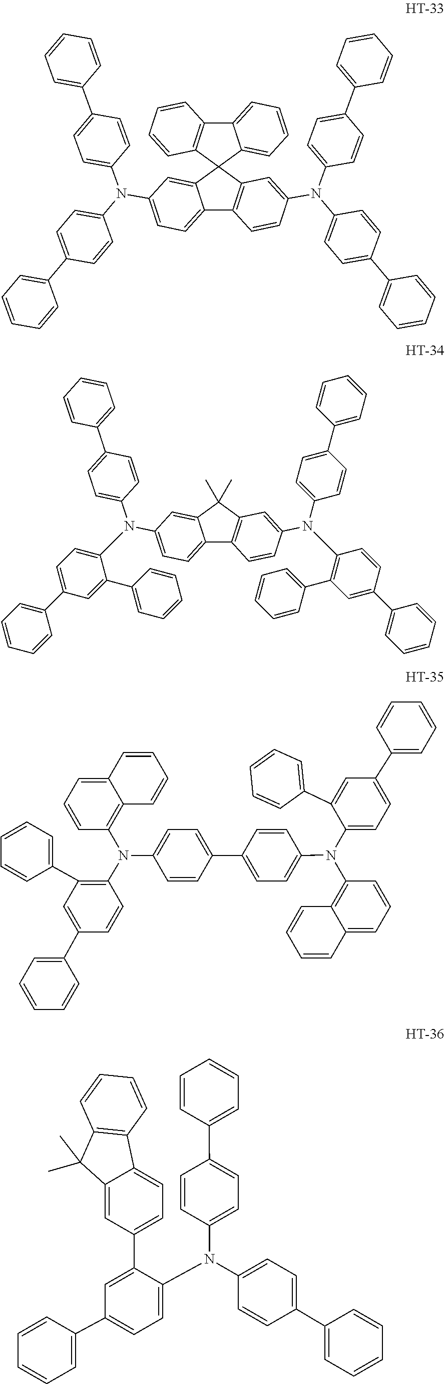 [SMILES: c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; CC1(C)c2cc(N(c3ccc(-c4ccccc4)cc3)c3ccc(-c4ccccc4)cc3-c3ccccc3)ccc2-c2ccc(N(c3ccc(-c4ccccc4)cc3)c3ccc(-c4ccccc4)cc3-c3ccccc3)cc21 ; c1ccc(-c2ccc(N(c3ccc(-c4ccc(N(c5ccc(-c6ccccc6)cc5-c5ccccc5)c5cccc6ccccc56)cc4)cc3)c3cccc4ccccc34)c(-c3ccccc3)c2)cc1 ; CC1(C)c2ccccc2-c2ccc(-c3cc(-c4ccccc4)ccc3N(c3ccc(-c4ccccc4)cc3)c3ccc(-c4ccccc4)cc3)cc21]

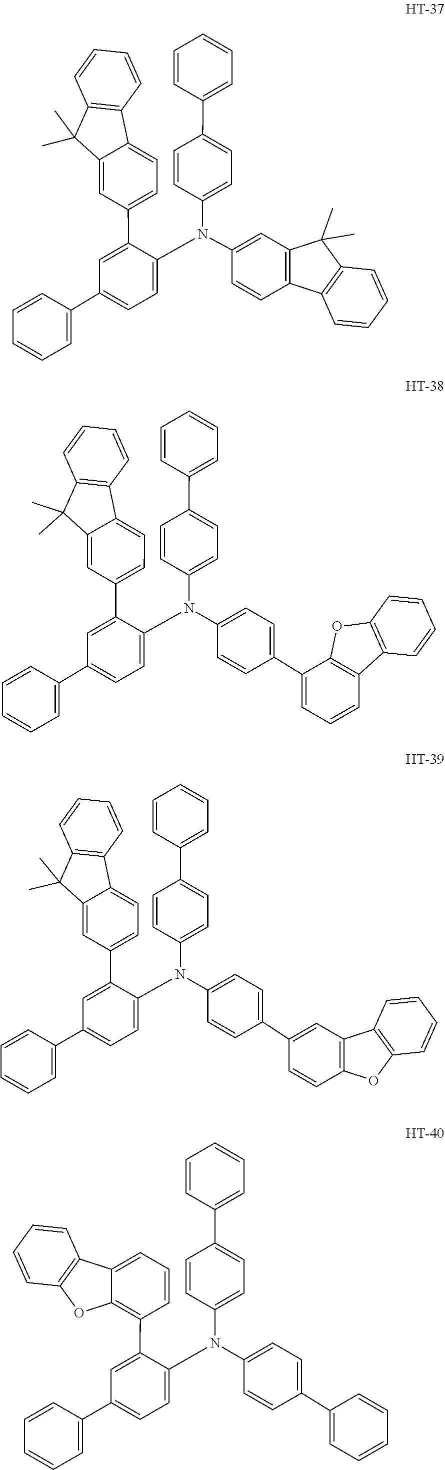 [SMILES: CC1(C)c2ccccc2-c2ccc(-c3cc(-c4ccccc4)ccc3N(c3ccc(-c4ccccc4)cc3)c3ccc4c(c3)C(C)(C)c3ccccc3-4)cc21 ; CC1(C)c2ccccc2-c2ccc(-c3cc(-c4ccccc4)ccc3N(c3ccc(-c4ccccc4)cc3)c3ccc(-c4cccc5c4oc4ccccc45)cc3)cc21 ; CC1(C)c2ccccc2-c2ccc(-c3cc(-c4ccccc4)ccc3N(c3ccc(-c4ccccc4)cc3)c3ccc(-c4ccc5oc6ccccc6c5c4)cc3)cc21 ; c1ccc(-c2ccc(N(c3ccc(-c4ccccc4)cc3)c3ccc(-c4ccccc4)cc3-c3cccc4c3oc3ccccc34)cc2)cc1]

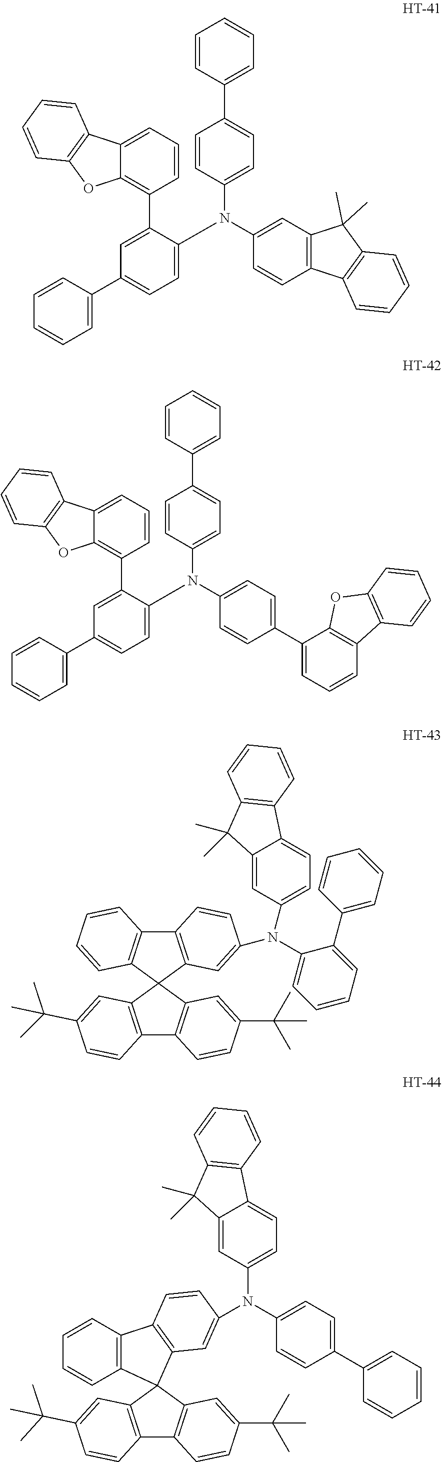 [SMILES: CC1(C)c2ccccc2-c2ccc(N(c3ccc(-c4ccccc4)cc3)c3ccc(-c4ccccc4)cc3-c3cccc4c3oc3ccccc34)cc21 ; c1ccc(-c2ccc(N(c3ccc(-c4cccc5c4oc4ccccc45)cc3)c3ccc(-c4ccccc4)cc3-c3cccc4c3oc3ccccc34)cc2)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2]

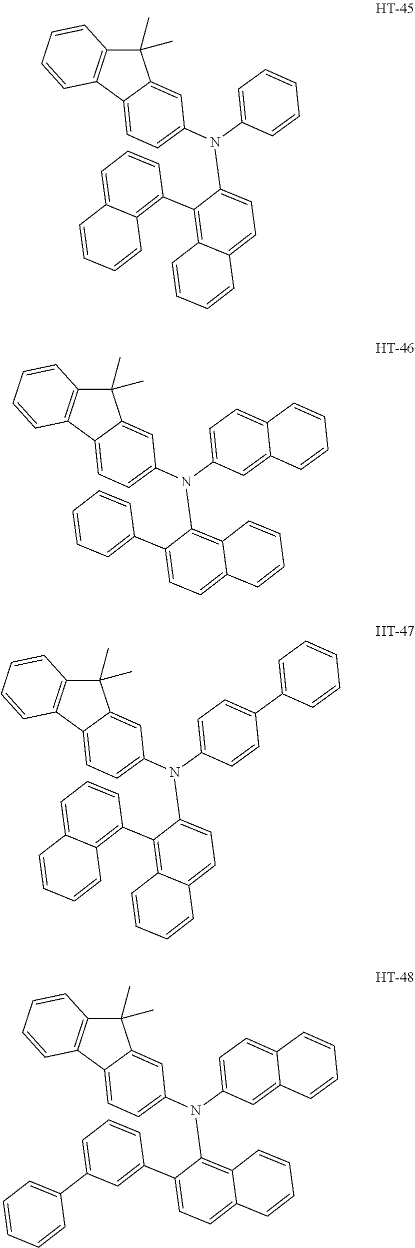 [SMILES: CC1(C)c2ccccc2-c2ccc(N(c3ccccc3)c3ccc4ccccc4c3-c3cccc4ccccc34)cc21 ; CC1(C)c2ccccc2-c2ccc(N(c3ccc4ccccc4c3)c3c(-c4ccccc4)ccc4ccccc34)cc21 ; CC1(C)c2ccccc2-c2ccc(N(c3ccc(-c4ccccc4)cc3)c3ccc4ccccc4c3-c3cccc4ccccc34)cc21 ; CC1(C)c2ccccc2-c2ccc(N(c3ccc4ccccc4c3)c3c(-c4cccc(-c5ccccc5)c4)ccc4ccccc34)cc21]

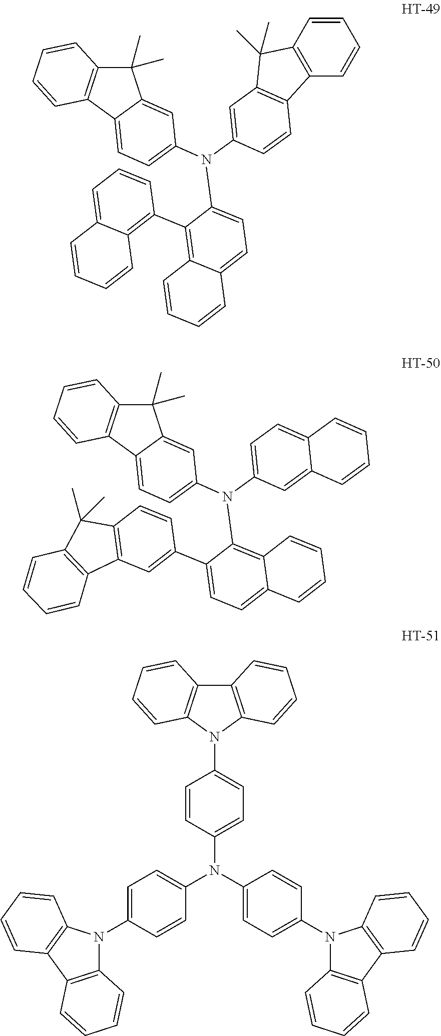 [SMILES: CC1(C)c2ccccc2-c2ccc(N(c3ccc4c(c3)C(C)(C)c3ccccc3-4)c3ccc4ccccc4c3-c3cccc4ccccc34)cc21 ; CC1(C)c2ccccc2-c2cc(-c3ccc4ccccc4c3N(c3ccc4c(c3)C(C)(C)c3ccccc3-4)c3ccc4ccccc4c3)ccc21 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

In addition, the material of the hole injection layer may include, but is not limited to, one or more of the HT-1 to HT-51 above and the HI-1 to HI-3 below:

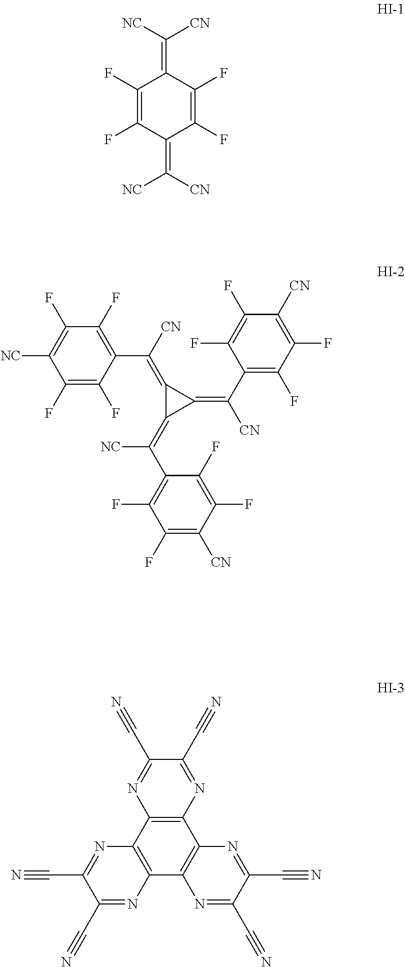 [SMILES: N#CC(C#N)=c1c(F)c(F)c(=C(C#N)C#N)c(F)c1F ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#Cc1nc2c3nc(C#N)c(C#N)nc3c3nc(C#N)c(C#N)nc3c2nc1C#N]

In addition, the material of the electron blocking layer may include, but is not limited to, one or more of the HT-1 to HT-51 above and the PH-47 to PH-77 below:

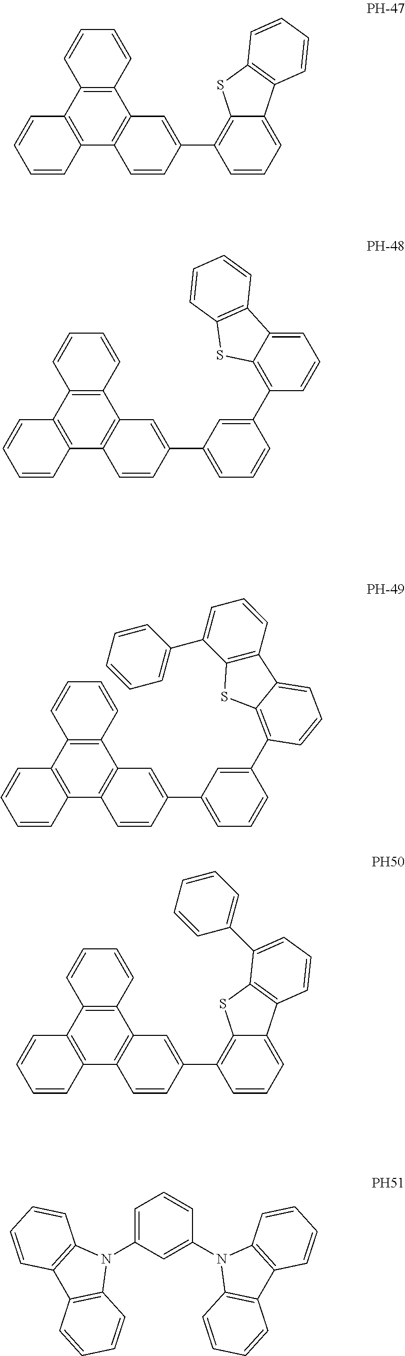

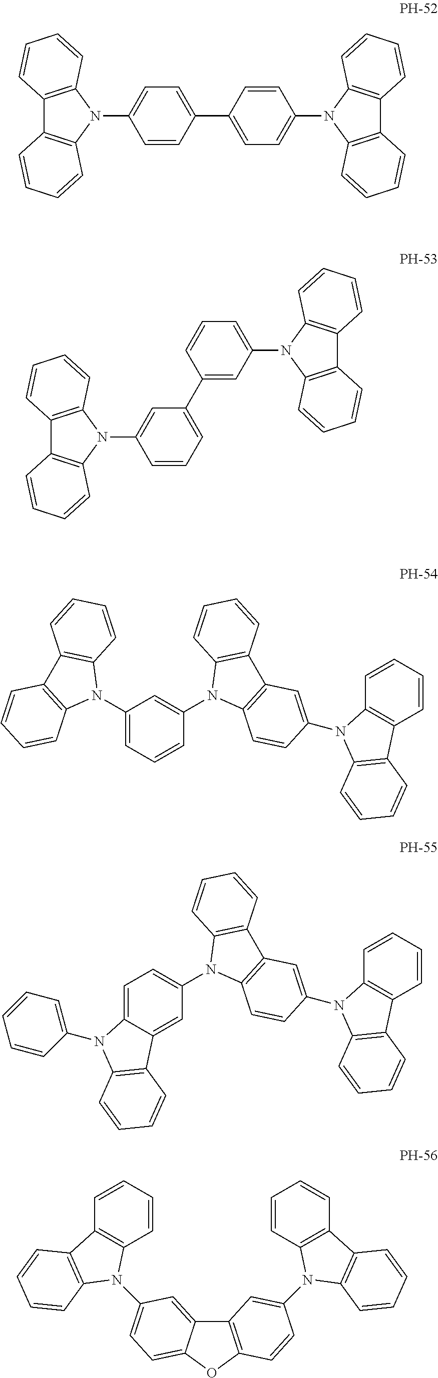 [SMILES: c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1 ; c1cc(-n2c3ccccc3c3ccccc32)cc(-n2c3ccccc3c3cc(-n4c5ccccc5c5ccccc54)ccc32)c1 ; c1ccc(-n2c3ccccc3c3cc(-n4c5ccccc5c5cc(-n6c7ccccc7c7ccccc76)ccc54)ccc32)cc1 ; c1ccc2c(c1)c1ccccc1n2-c1ccc2oc3ccc(-n4c5ccccc5c5ccccc54)cc3c2c1]

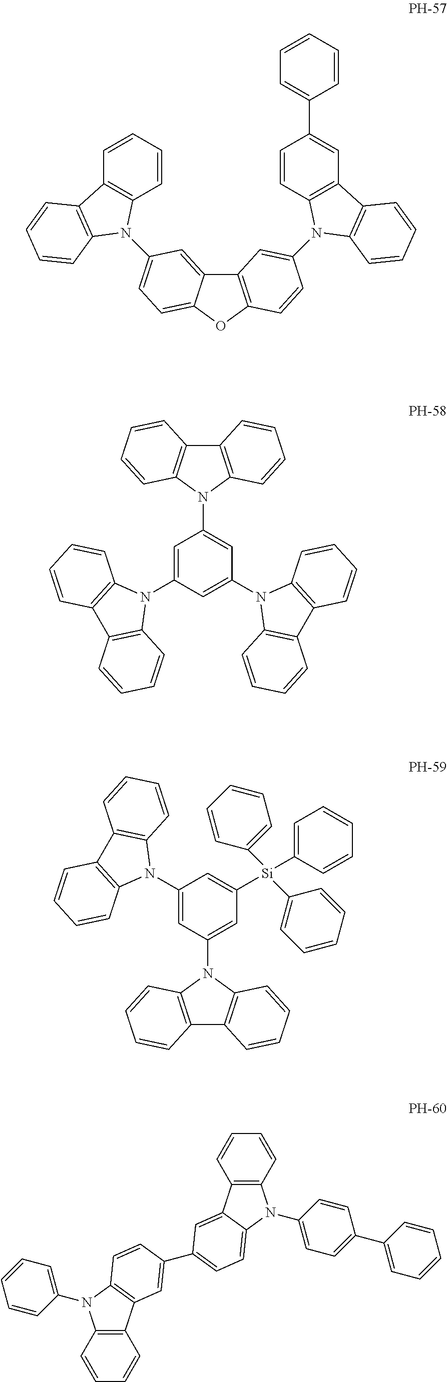 [SMILES: c1ccc(-c2ccc3c(c2)c2ccccc2n3-c2ccc3oc4ccc(-n5c6ccccc6c6ccccc65)cc4c3c2)cc1 ; c1ccc2c(c1)c1ccccc1n2-c1cc(-n2c3ccccc3c3ccccc32)cc(-n2c3ccccc3c3ccccc32)c1 ; c1ccc([Si](c2ccccc2)(c2ccccc2)c2cc(-n3c4ccccc4c4ccccc43)cc(-n3c4ccccc4c4ccccc43)c2)cc1 ; c1ccc(-c2ccc(-n3c4ccccc4c4cc(-c5ccc6c(c5)c5ccccc5n6-c5ccccc5)ccc43)cc2)cc1]

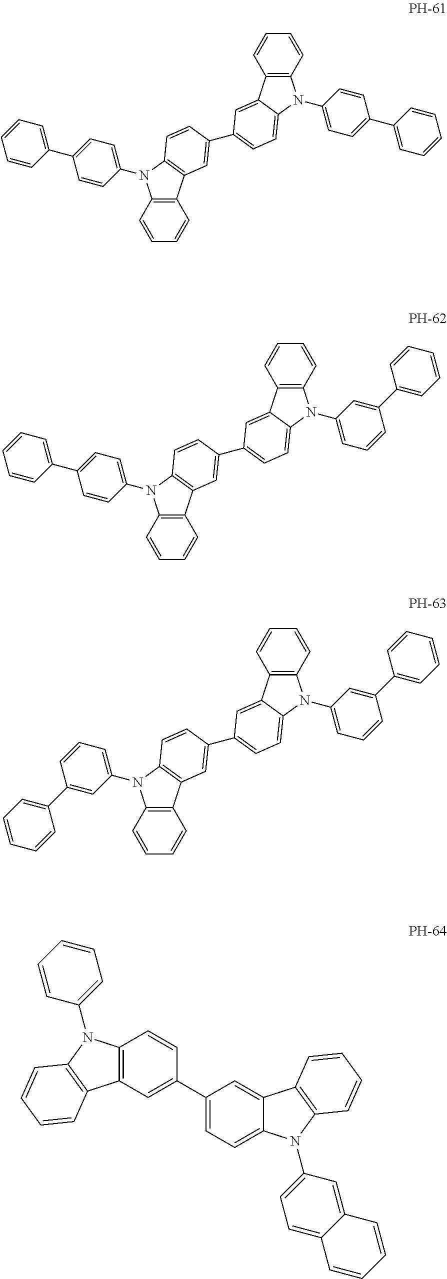 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-n2c3ccccc3c3cc(-c4ccc5c(c4)c4ccccc4n5-c4ccc5ccccc5c4)ccc32)cc1]

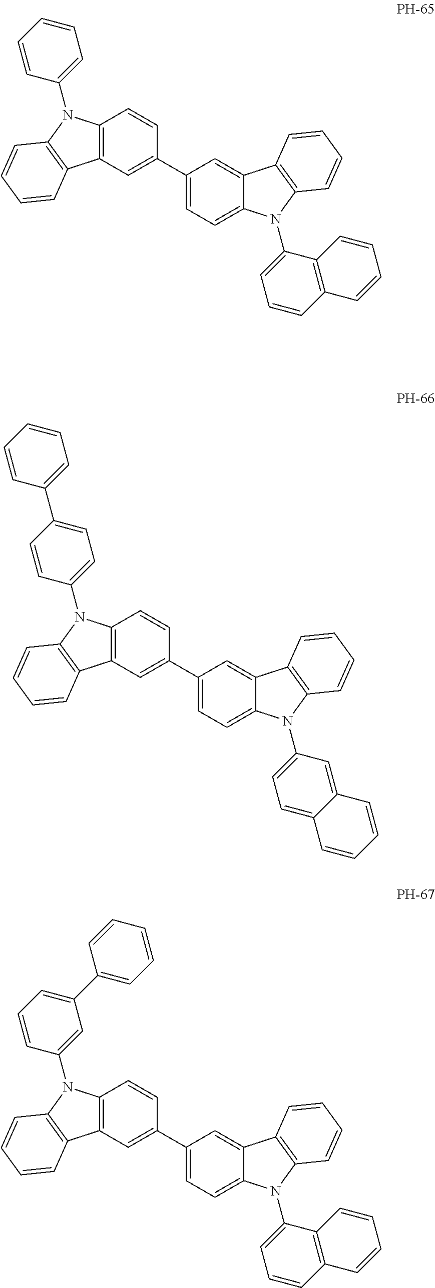 [SMILES: c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc6ccccc56)ccc43)c2)cc1]

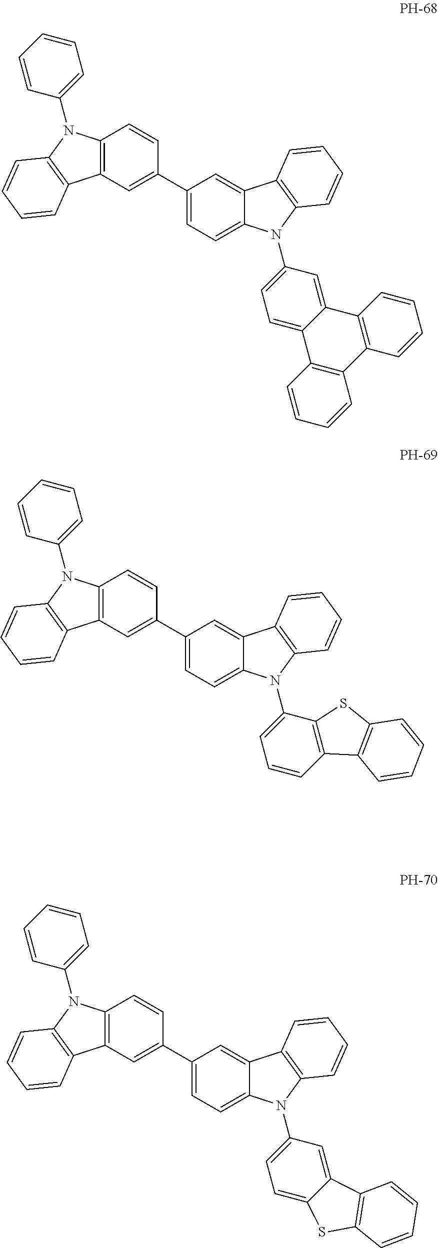 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1]

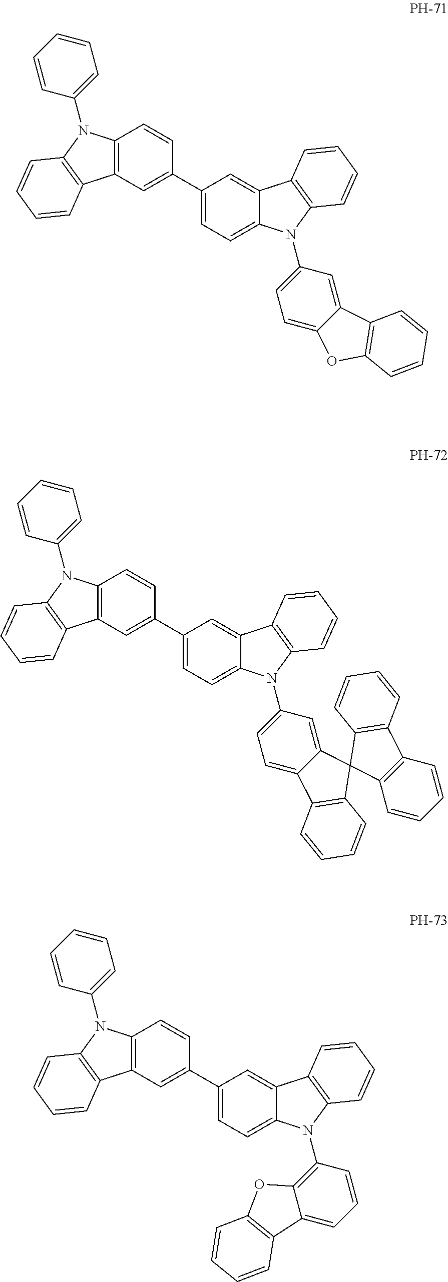 [SMILES: c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; c1ccc(-n2c3ccccc3c3cc(-c4ccc5c(c4)c4ccccc4n5-c4cccc5c4oc4ccccc45)ccc32)cc1]

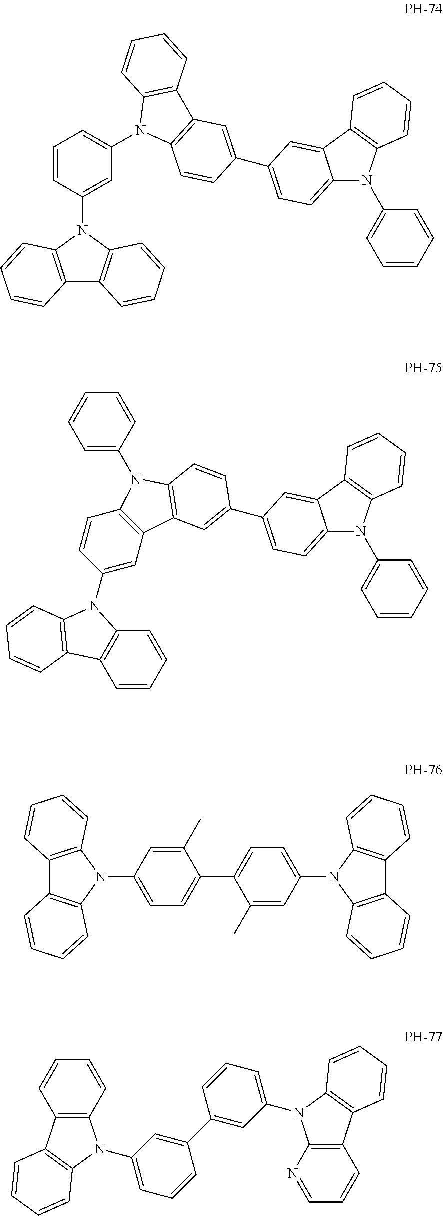 [SMILES: c1ccc(-n2c3ccccc3c3cc(-c4ccc5c(c4)c4ccccc4n5-c4cccc(-n5c6ccccc6c6ccccc65)c4)ccc32)cc1 ; c1ccc(-n2c3ccccc3c3cc(-c4ccc5c(c4)c4cc(-n6c7ccccc7c7ccccc76)ccc4n5-c4ccccc4)ccc32)cc1 ; Cc1cc(-n2c3ccccc3c3ccccc32)ccc1-c1ccc(-n2c3ccccc3c3ccccc32)cc1C ; c1cc(-c2cccc(-n3c4ccccc4c4cccnc43)c2)cc(-n2c3ccccc3c3ccccc32)c1]

In addition, the material of the electron transport layer may include, but is not limited to, one or more of the ET-1 to ET-73 below:

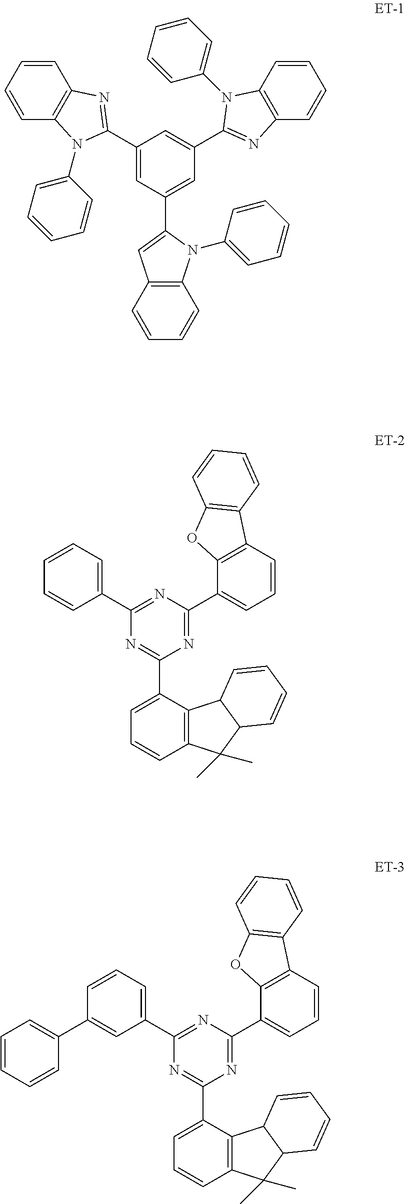 [SMILES: c1ccc(-n2c(-c3cc(-c4nc5ccccc5n4-c4ccccc4)cc(-c4nc5ccccc5n4-c4ccccc4)c3)cc3ccccc32)cc1 ; CC1(C)c2cccc(-c3nc(-c4ccccc4)nc(-c4cccc5c4oc4ccccc45)n3)c2C2C=CC=CC21 ; CC1(C)c2cccc(-c3nc(-c4cccc(-c5ccccc5)c4)nc(-c4cccc5c4oc4ccccc45)n3)c2C2C=CC=CC21]

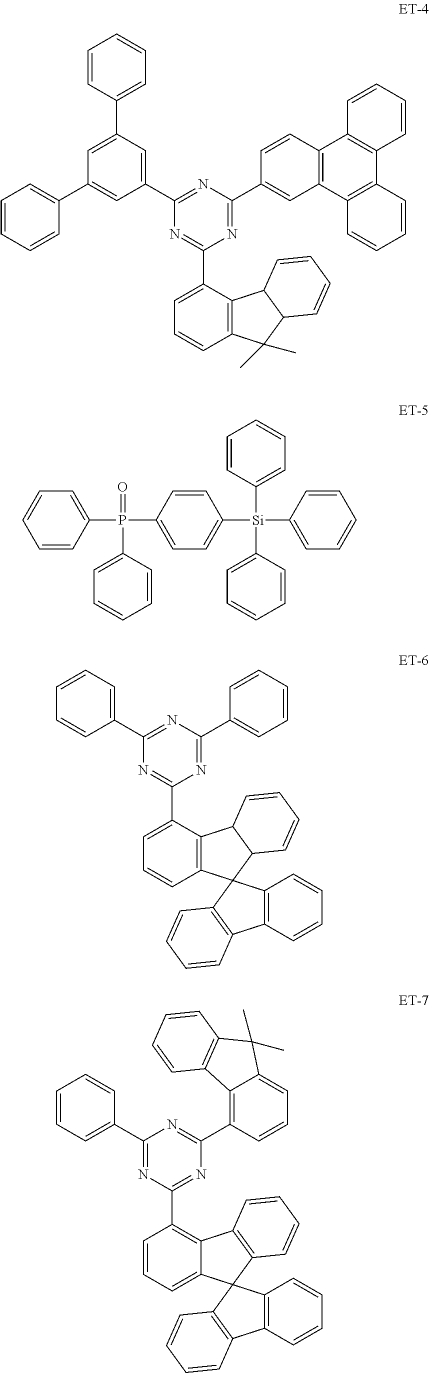

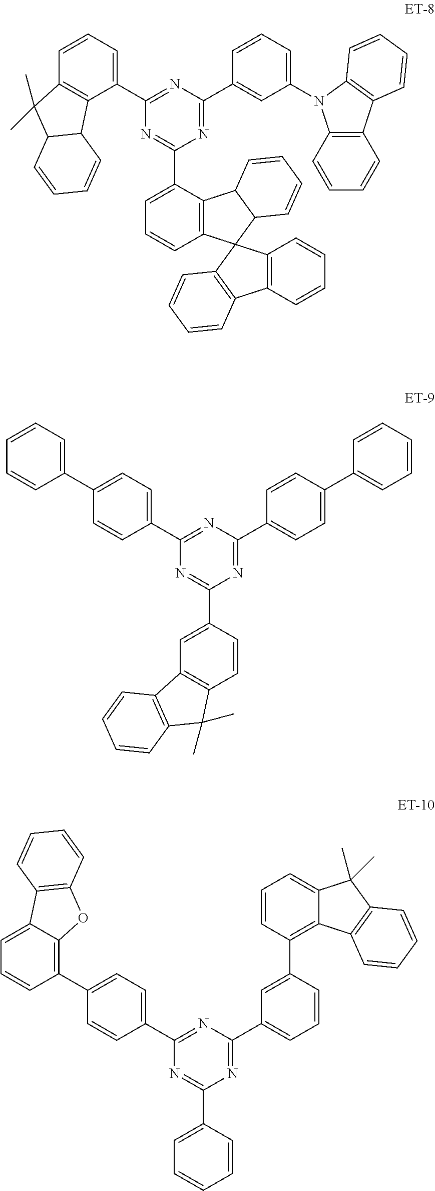 [SMILES: CC1(C)c2cccc(-c3nc(-c4cccc(-n5c6ccccc6c6ccccc65)c4)nc(-c4cccc5c4C4C=CC=CC4C54c5ccccc5-c5ccccc54)n3)c2C2C=CC=CC21 ; CC1(C)c2ccccc2-c2cc(-c3nc(-c4ccc(-c5ccccc5)cc4)nc(-c4ccc(-c5ccccc5)cc4)n3)ccc21 ; CC1(C)c2ccccc2-c2c(-c3cccc(-c4nc(-c5ccccc5)nc(-c5ccc(-c6cccc7c6oc6ccccc67)cc5)n4)c3)cccc21]

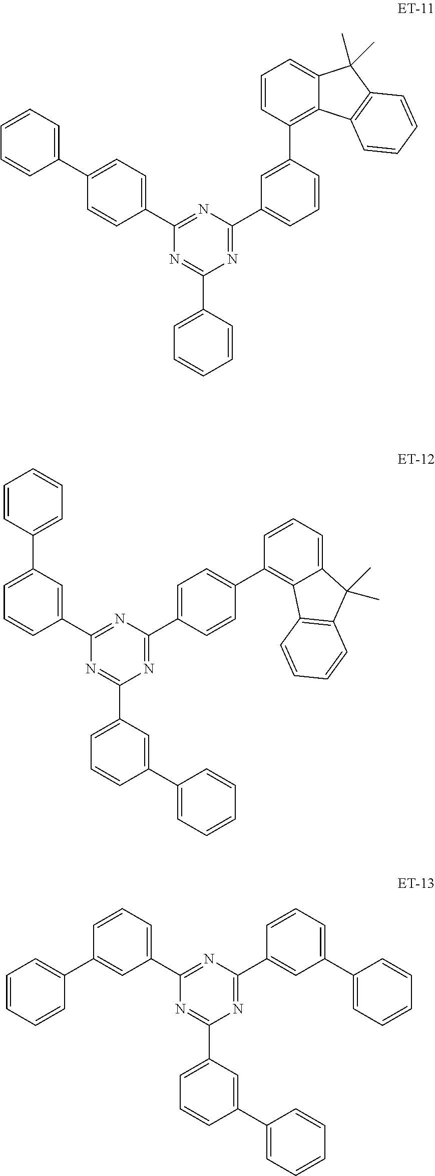 [SMILES: CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21 ; c1ccc(-c2cccc(-c3nc(-c4cccc(-c5ccccc5)c4)nc(-c4cccc(-c5ccccc5)c4)n3)c2)cc1]

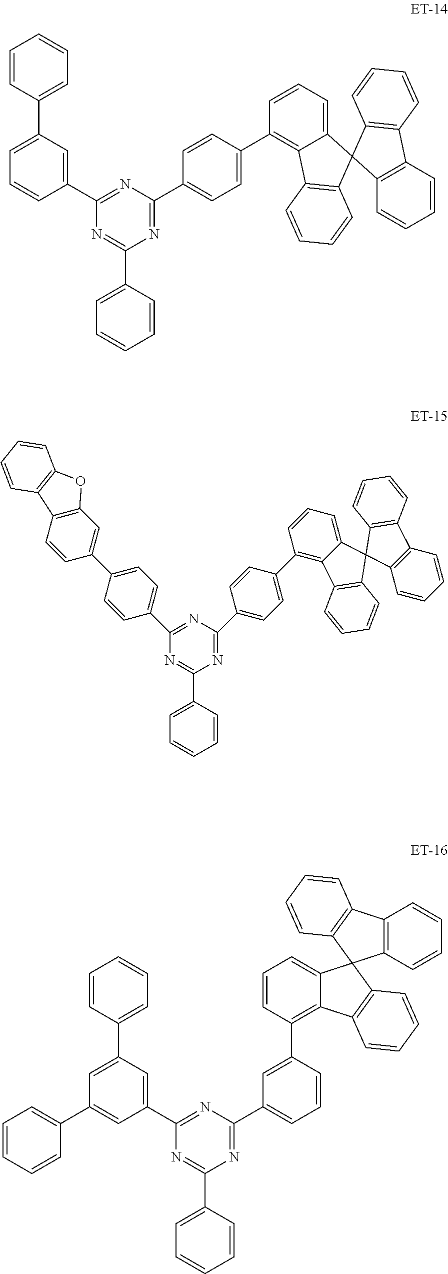 [SMILES: c1ccc(-c2cccc(-c3nc(-c4ccccc4)nc(-c4ccc(-c5cccc6c5-c5ccccc5C65c6ccccc6-c6ccccc65)cc4)n3)c2)cc1 ; c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1 ; c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1]

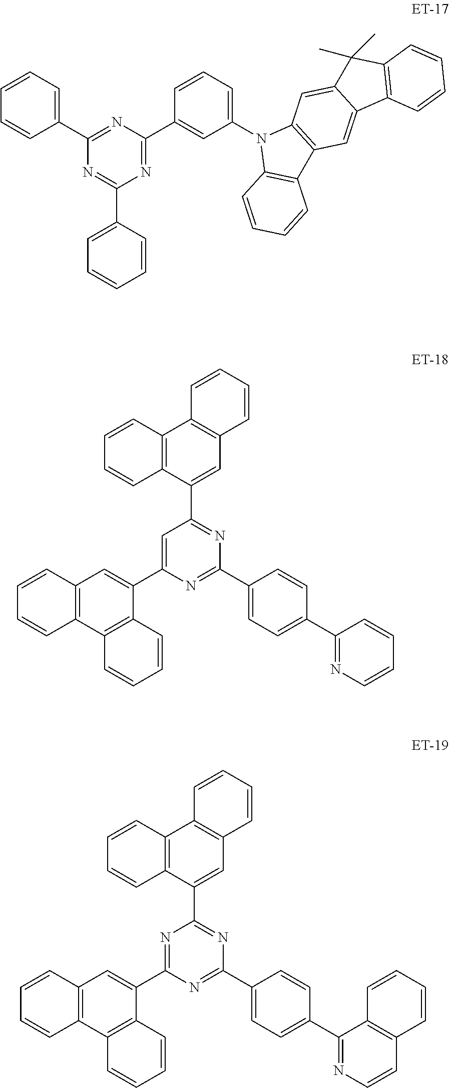 [SMILES: CC1(C)c2ccccc2-c2cc3c4ccccc4n(-c4cccc(-c5nc(-c6ccccc6)nc(-c6ccccc6)n5)c4)c3cc21 ; c1ccc(-c2ccc(-c3nc(-c4cc5ccccc5c5ccccc45)cc(-c4cc5ccccc5c5ccccc45)n3)cc2)nc1 ; c1ccc2c(-c3ccc(-c4nc(-c5cc6ccccc6c6ccccc56)nc(-c5cc6ccccc6c6ccccc56)n4)cc3)nccc2c1]

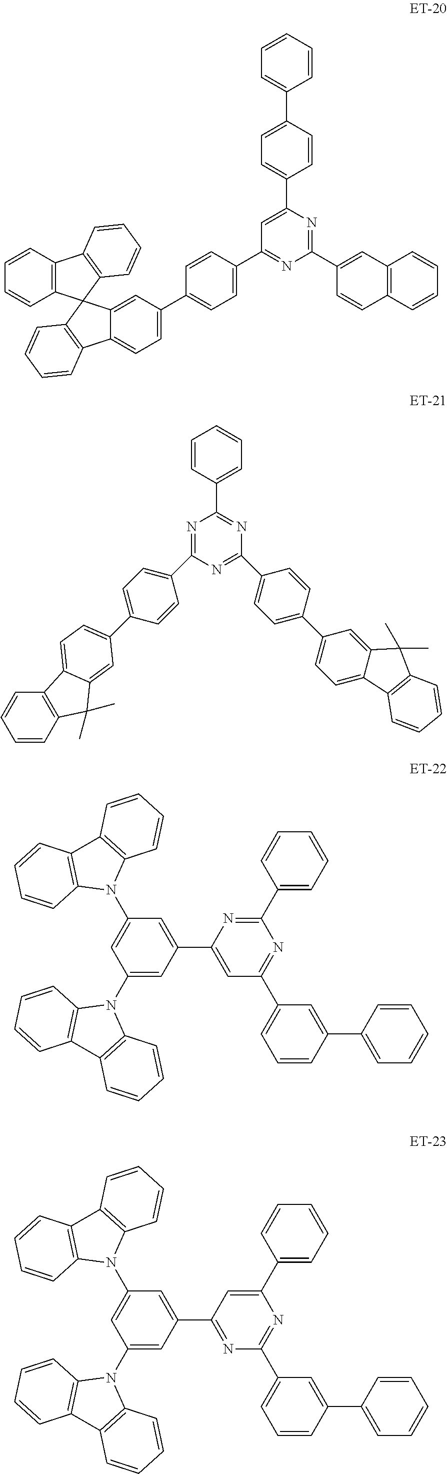 [SMILES: c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cccc(-c3nc(-c4ccccc4)cc(-c4cc(-n5c6ccccc6c6ccccc65)cc(-n5c6ccccc6c6ccccc65)c4)n3)c2)cc1]

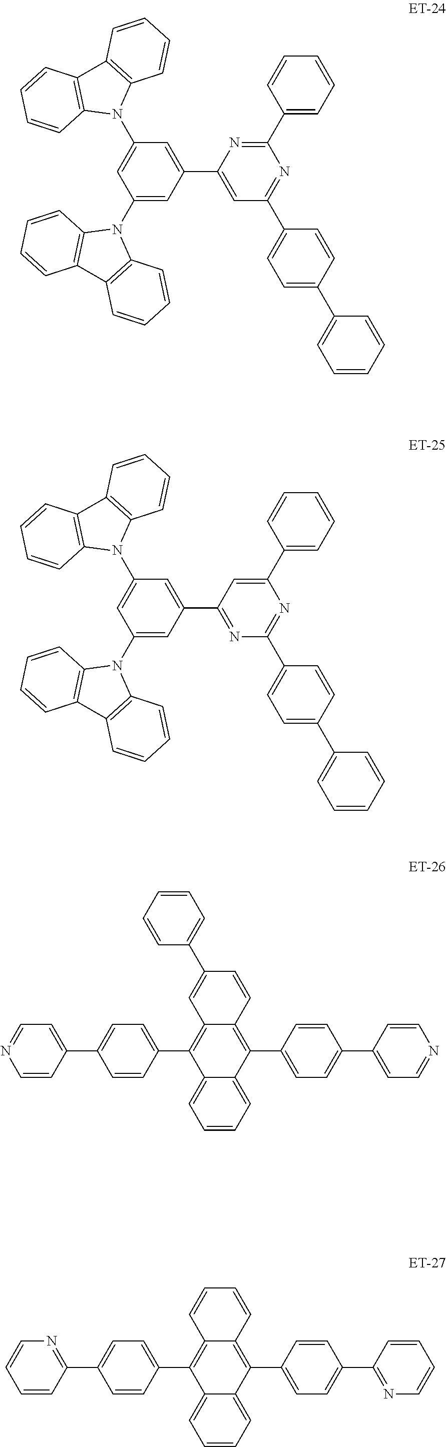 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1]

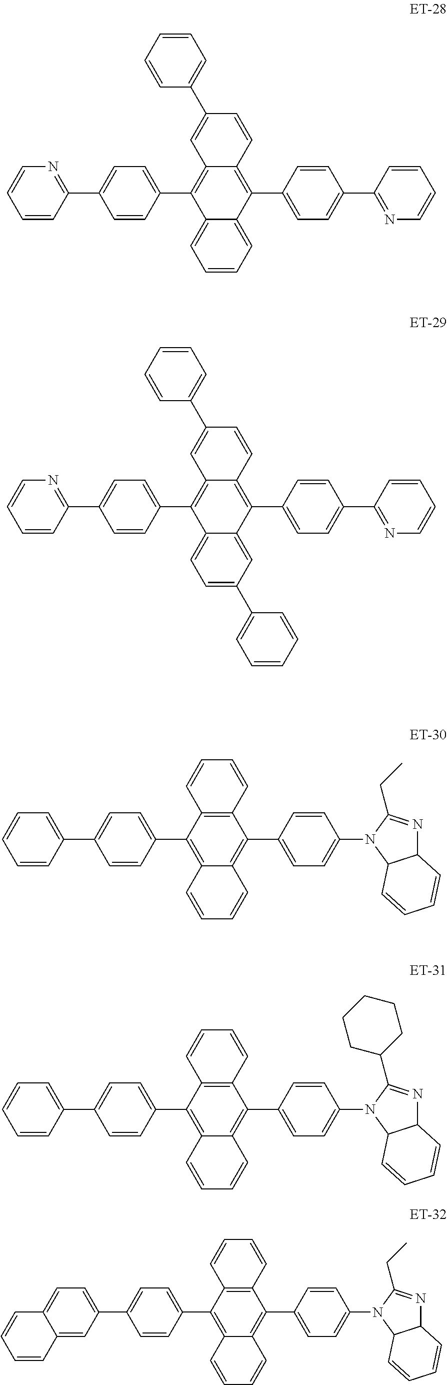 [SMILES: c1ccc(-c2ccc3c(-c4ccc(-c5ccccn5)cc4)c4ccccc4c(-c4ccc(-c5ccccn5)cc4)c3c2)cc1 ; c1ccc(-c2ccc3c(-c4ccc(-c5ccccn5)cc4)c4cc(-c5ccccc5)ccc4c(-c4ccc(-c5ccccn5)cc4)c3c2)cc1 ; CCC1=NC2C=CC=CC2N1c1ccc(-c2c3ccccc3c(-c3ccc(-c4ccccc4)cc3)c3ccccc23)cc1 ; C1=CC2N=C(C3CCCCC3)N(c3ccc(-c4c5ccccc5c(-c5ccc(-c6ccccc6)cc5)c5ccccc45)cc3)C2C=C1 ; CCC1=NC2C=CC=CC2N1c1ccc(-c2c3ccccc3c(-c3ccc(-c4ccc5ccccc5c4)cc3)c3ccccc23)cc1]

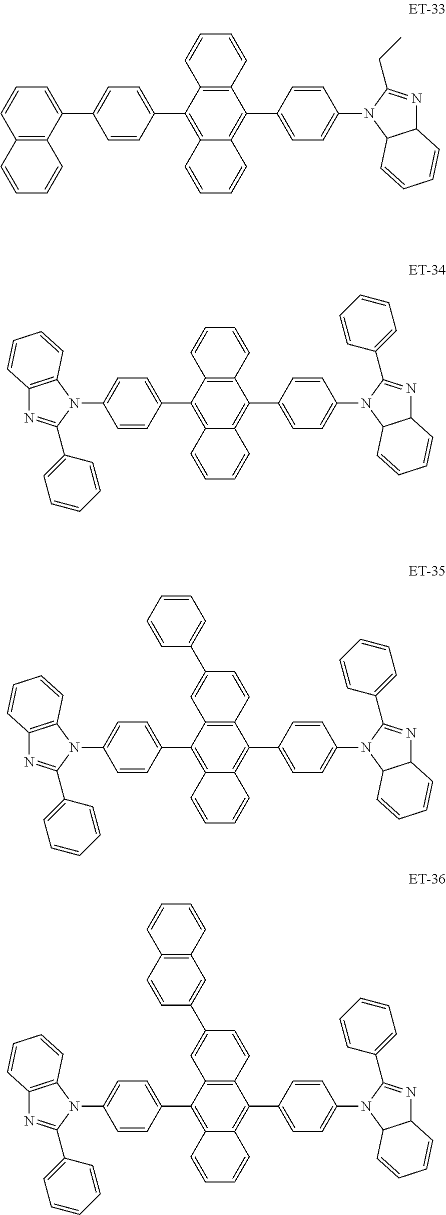 [SMILES: CCC1=NC2C=CC=CC2N1c1ccc(-c2c3ccccc3c(-c3ccc(-c4cccc5ccccc45)cc3)c3ccccc23)cc1 ; C1=CC2N=C(c3ccccc3)N(c3ccc(-c4c5ccccc5c(-c5ccc(-n6c(-c7ccccc7)nc7ccccc76)cc5)c5ccccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccccc6)ccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1]

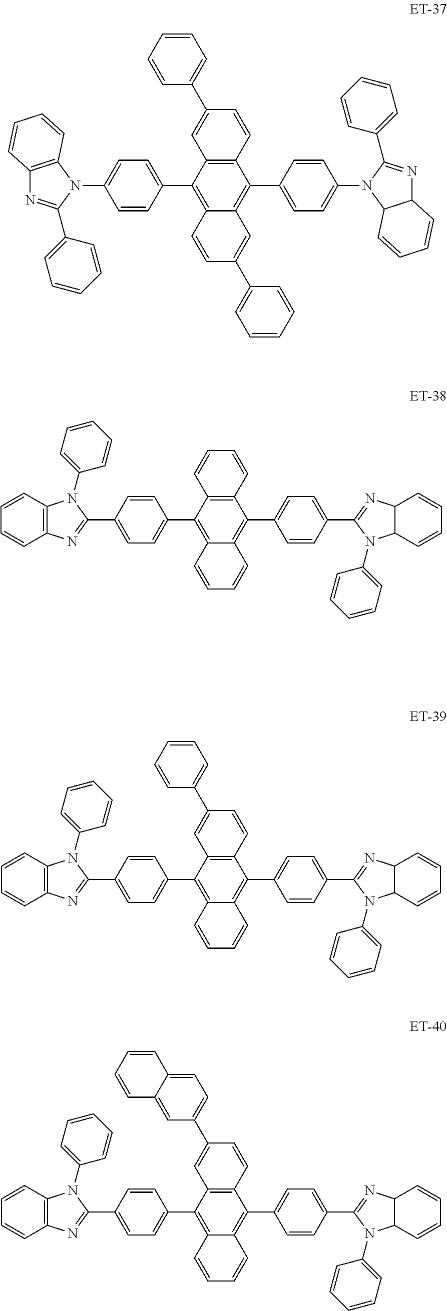 [SMILES: C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1 ; C1=CC2N=C(c3ccc(-c4c5ccccc5c(-c5ccc(-c6nc7ccccc7n6-c6ccccc6)cc5)c5ccccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccccc6)ccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccc7ccccc7c6)ccc45)cc3)N(c3ccccc3)C2C=C1]

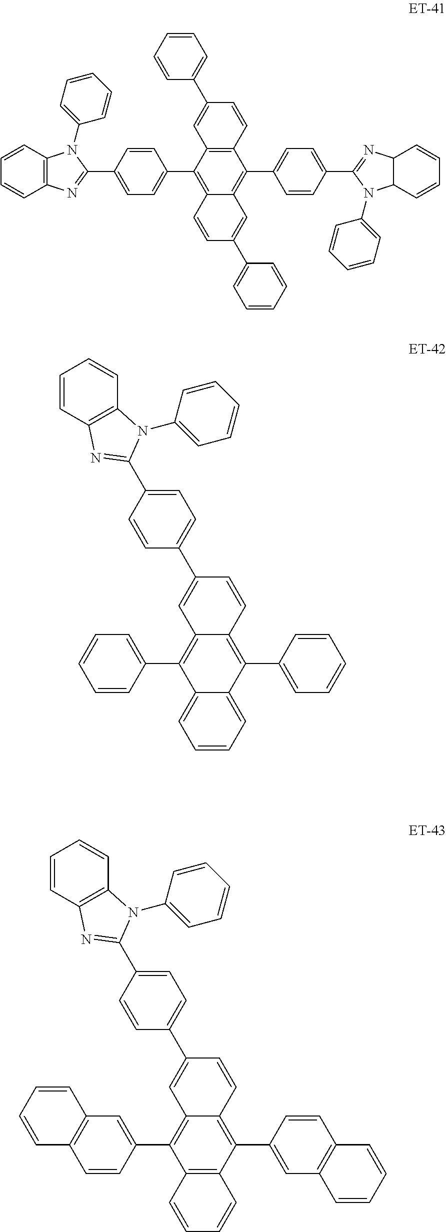 [SMILES: C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1 ; c1ccc(-c2c3ccccc3c(-c3ccccc3)c3cc(-c4ccc(-c5nc6ccccc6n5-c5ccccc5)cc4)ccc23)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

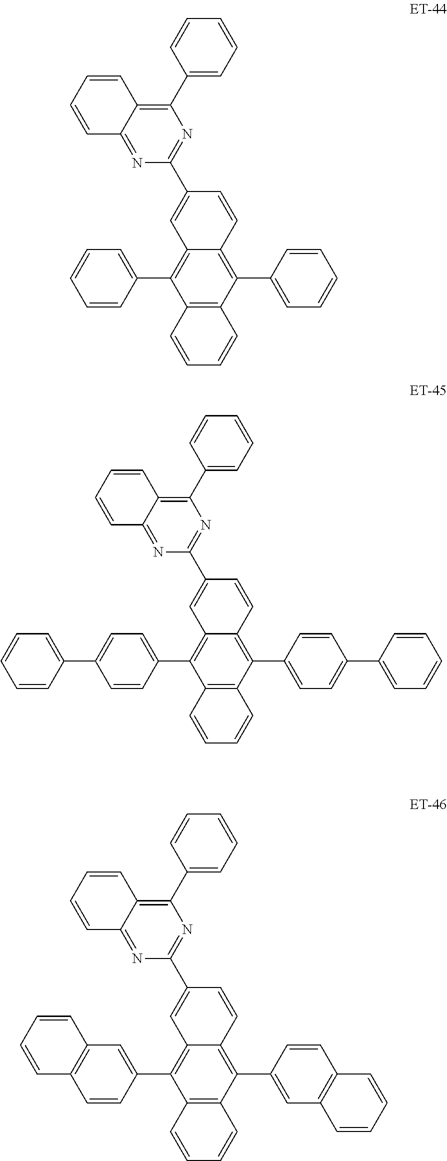 [SMILES: c1ccc(-c2nc(-c3ccc4c(-c5ccccc5)c5ccccc5c(-c5ccccc5)c4c3)nc3ccccc23)cc1 ; c1ccc(-c2ccc(-c3c4ccccc4c(-c4ccc(-c5ccccc5)cc4)c4cc(-c5nc(-c6ccccc6)c6ccccc6n5)ccc34)cc2)cc1 ; c1ccc(-c2nc(-c3ccc4c(-c5ccc6ccccc6c5)c5ccccc5c(-c5ccc6ccccc6c5)c4c3)nc3ccccc23)cc1]

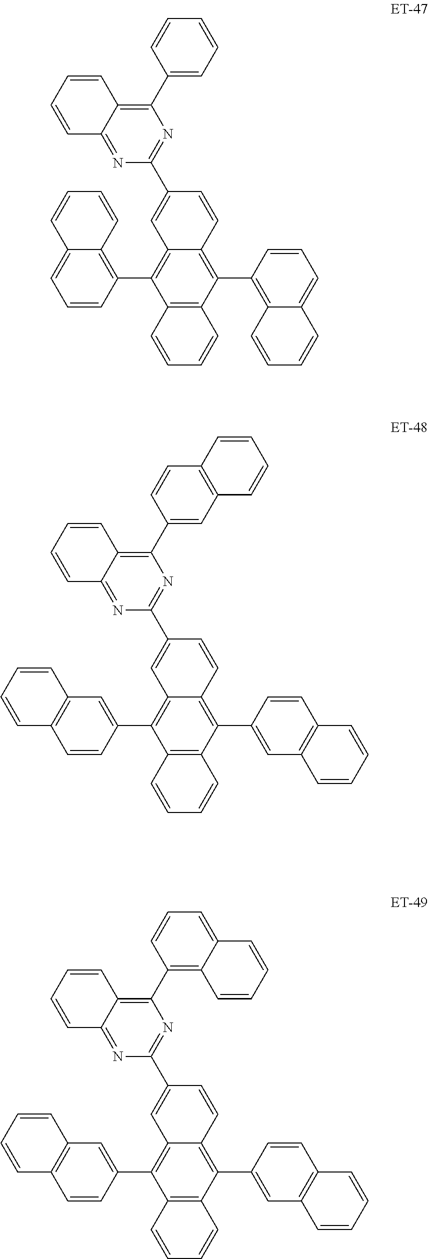 [SMILES: c1ccc(-c2nc(-c3ccc4c(-c5cccc6ccccc56)c5ccccc5c(-c5cccc6ccccc56)c4c3)nc3ccccc23)cc1 ; c1ccc2cc(-c3nc(-c4ccc5c(-c6ccc7ccccc7c6)c6ccccc6c(-c6ccc7ccccc7c6)c5c4)nc4ccccc34)ccc2c1 ; c1ccc2cc(-c3c4ccccc4c(-c4ccc5ccccc5c4)c4cc(-c5nc(-c6cccc7ccccc67)c6ccccc6n5)ccc34)ccc2c1]

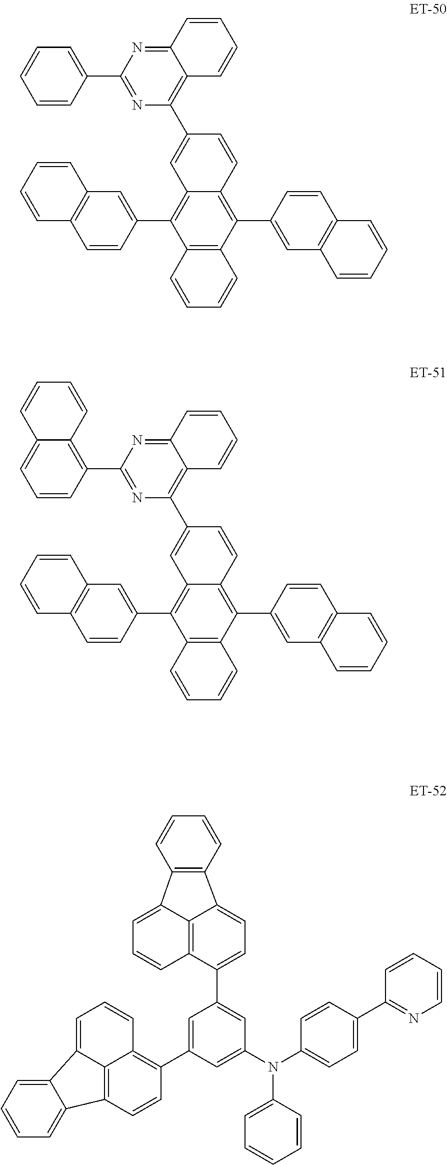 [SMILES: c1ccc(-c2nc(-c3ccc4c(-c5ccc6ccccc6c5)c5ccccc5c(-c5ccc6ccccc6c5)c4c3)c3ccccc3n2)cc1 ; c1ccc2cc(-c3c4ccccc4c(-c4ccc5ccccc5c4)c4cc(-c5nc(-c6cccc7ccccc67)nc6ccccc56)ccc34)ccc2c1 ; c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1]

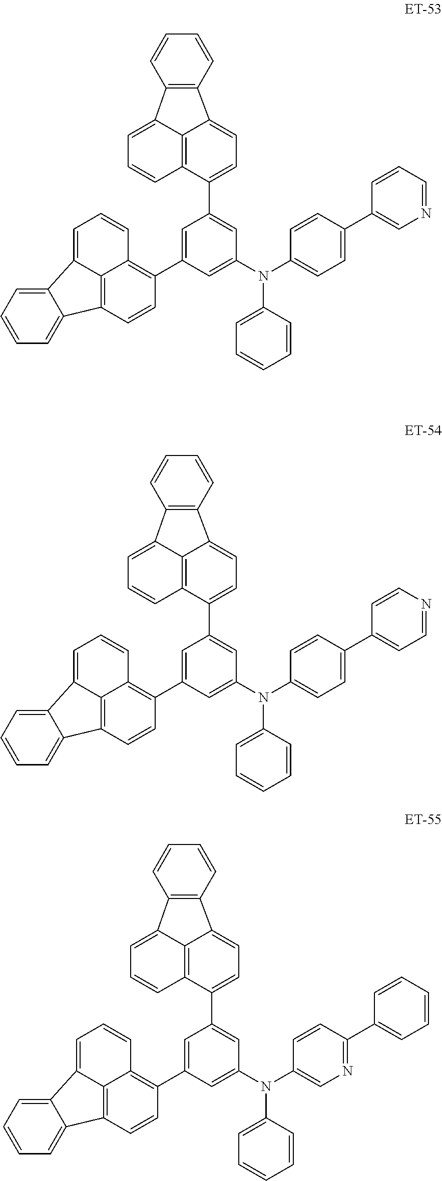 [SMILES: c1ccc(N(c2ccc(-c3cccnc3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3ccncc3)cc2)c2cc(-c3ccc4c5c(cccc35)-c3ccccc3-4)cc(-c3ccc4c5c(cccc35)-c3ccccc3-4)c2)cc1 ; c1ccc(-c2ccc(N(c3ccccc3)c3cc(-c4ccc5c6c(cccc46)-c4ccccc4-5)cc(-c4ccc5c6c(cccc46)-c4ccccc4-5)c3)cn2)cc1]

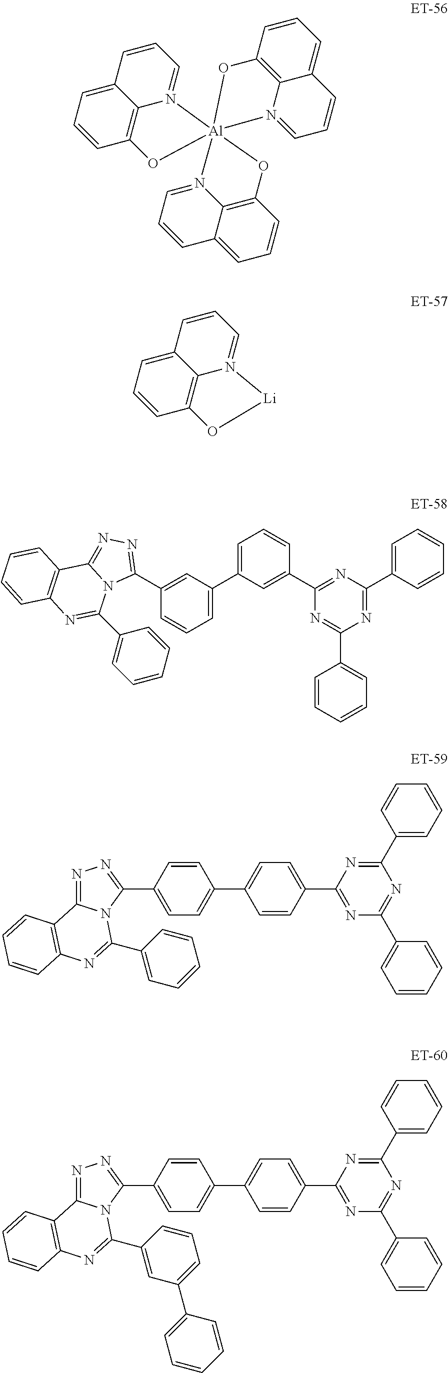

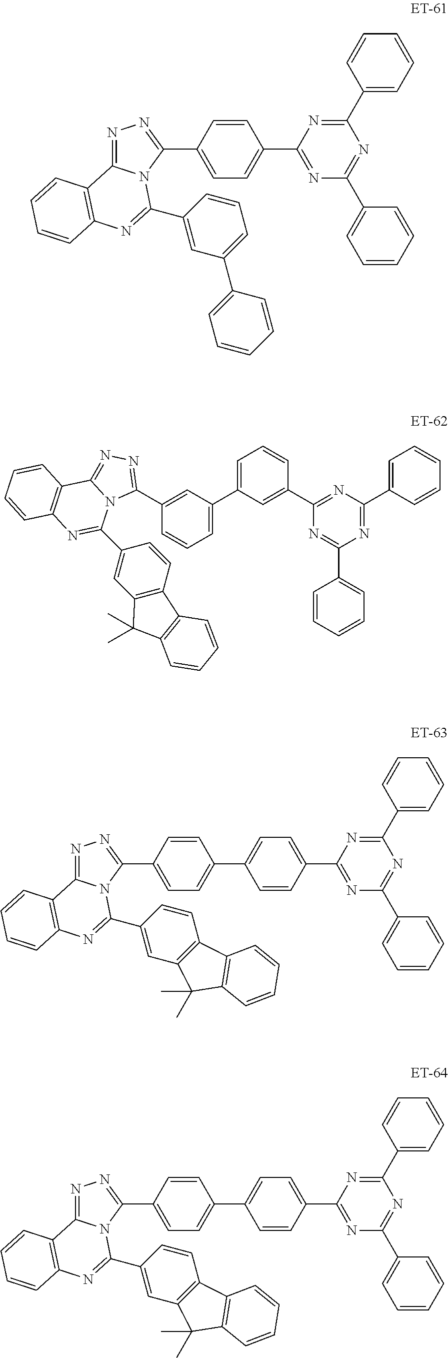 [SMILES: c1ccc(-c2cccc(-c3nc4ccccc4c4nnc(-c5ccc(-c6nc(-c7ccccc7)nc(-c7ccccc7)n6)cc5)n34)c2)cc1 ; CC1(C)c2ccccc2-c2ccc(-c3nc4ccccc4c4nnc(-c5cccc(-c6cccc(-c7nc(-c8ccccc8)nc(-c8ccccc8)n7)c6)c5)n34)cc21 ; CC1(C)c2ccccc2-c2ccc(-c3nc4ccccc4c4nnc(-c5ccc(-c6ccc(-c7nc(-c8ccccc8)nc(-c8ccccc8)n7)cc6)cc5)n34)cc21 ; CC1(C)c2ccccc2-c2ccc(-c3nc4ccccc4c4nnc(-c5ccc(-c6ccc(-c7nc(-c8ccccc8)nc(-c8ccccc8)n7)cc6)cc5)n34)cc21]

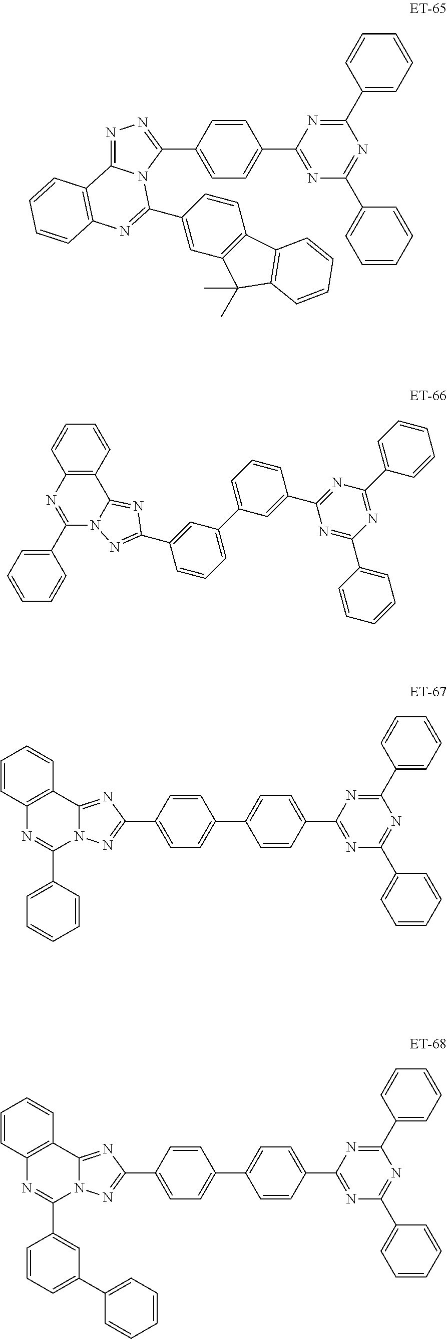 [SMILES: CC1(C)c2ccccc2-c2ccc(-c3nc4ccccc4c4nnc(-c5ccc(-c6nc(-c7ccccc7)nc(-c7ccccc7)n6)cc5)n34)cc21 ; c1ccc(-c2nc(-c3ccccc3)nc(-c3cccc(-c4cccc(-c5nc6c7ccccc7nc(-c7ccccc7)n6n5)c4)c3)n2)cc1 ; c1ccc(-c2nc(-c3ccccc3)nc(-c3ccc(-c4ccc(-c5nc6c7ccccc7nc(-c7ccccc7)n6n5)cc4)cc3)n2)cc1 ; c1ccc(-c2cccc(-c3nc4ccccc4c4nc(-c5ccc(-c6ccc(-c7nc(-c8ccccc8)nc(-c8ccccc8)n7)cc6)cc5)nn34)c2)cc1]

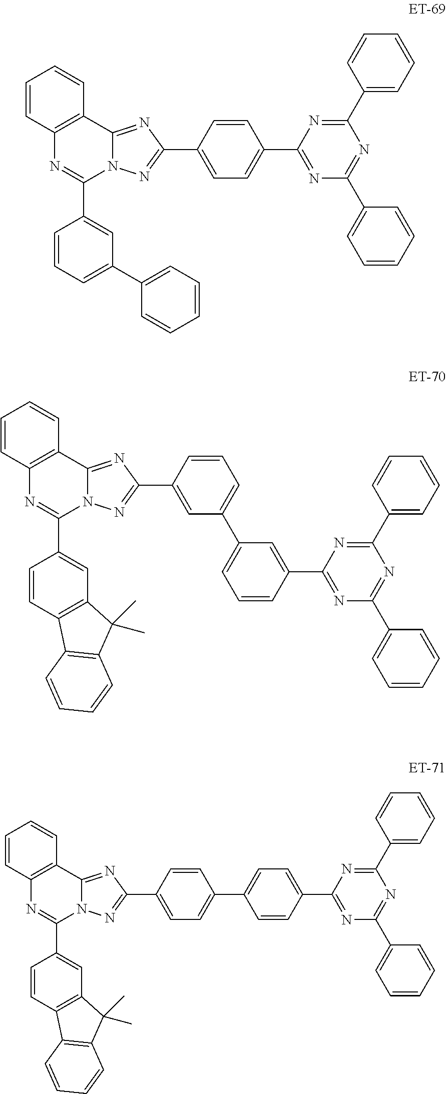 [SMILES: c1ccc(-c2cccc(-c3nc4ccccc4c4nc(-c5ccc(-c6nc(-c7ccccc7)nc(-c7ccccc7)n6)cc5)nn34)c2)cc1 ; CC1(C)c2ccccc2-c2ccc(-c3nc4ccccc4c4nc(-c5cccc(-c6cccc(-c7nc(-c8ccccc8)nc(-c8ccccc8)n7)c6)c5)nn34)cc21 ; CC1(C)c2ccccc2-c2ccc(-c3nc4ccccc4c4nc(-c5ccc(-c6ccc(-c7nc(-c8ccccc8)nc(-c8ccccc8)n7)cc6)cc5)nn34)cc21]

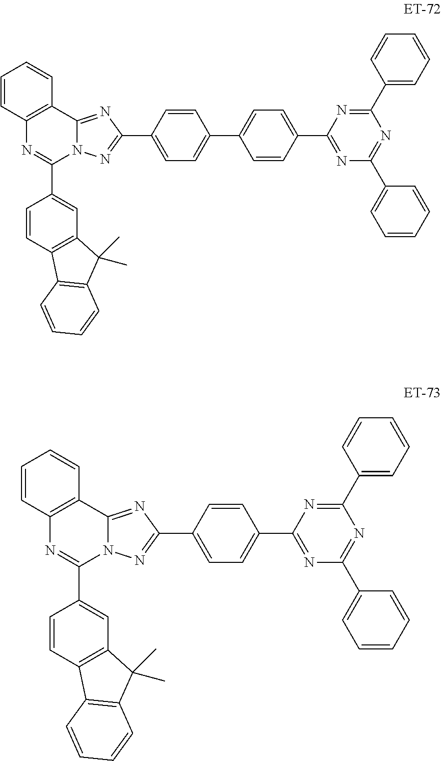 [SMILES: CC1(C)c2ccccc2-c2ccc(-c3nc4ccccc4c4nc(-c5ccc(-c6ccc(-c7nc(-c8ccccc8)nc(-c8ccccc8)n7)cc6)cc5)nn34)cc21 ; CC1(C)c2ccccc2-c2ccc(-c3nc4ccccc4c4nc(-c5ccc(-c6nc(-c7ccccc7)nc(-c7ccccc7)n6)cc5)nn34)cc21]

In addition, the material of the hole blocking layer may include, but is not limited to, one or more of the ET-1 to ET-73 above and the PH-1 to PH-46 below:

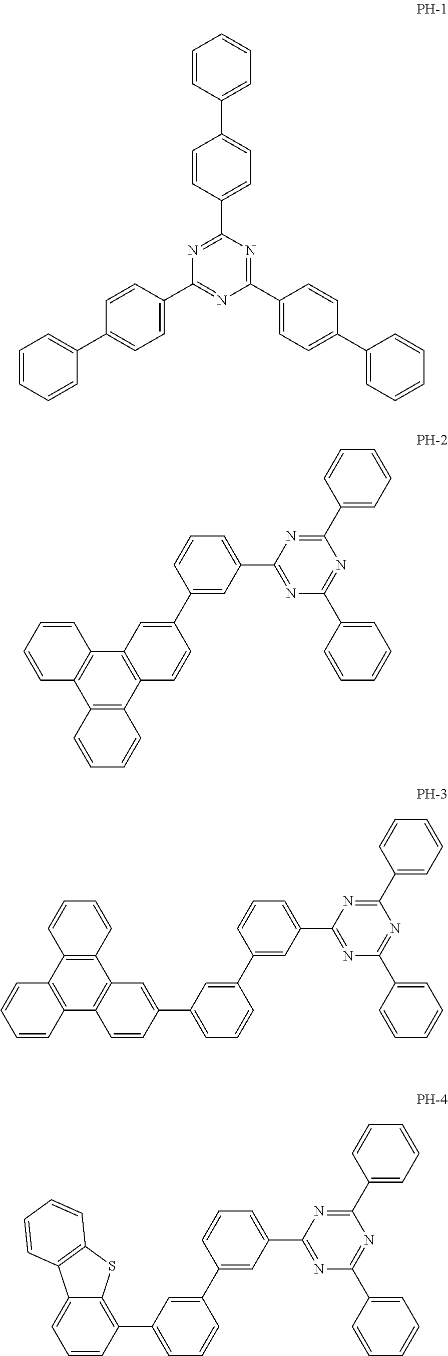 [SMILES: c1ccc(-c2ccc(-c3nc(-c4ccc(-c5ccccc5)cc4)nc(-c4ccc(-c5ccccc5)cc4)n3)cc2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4cccc(-c5cccc6c5sc5ccccc56)c4)c3)n2)cc1]

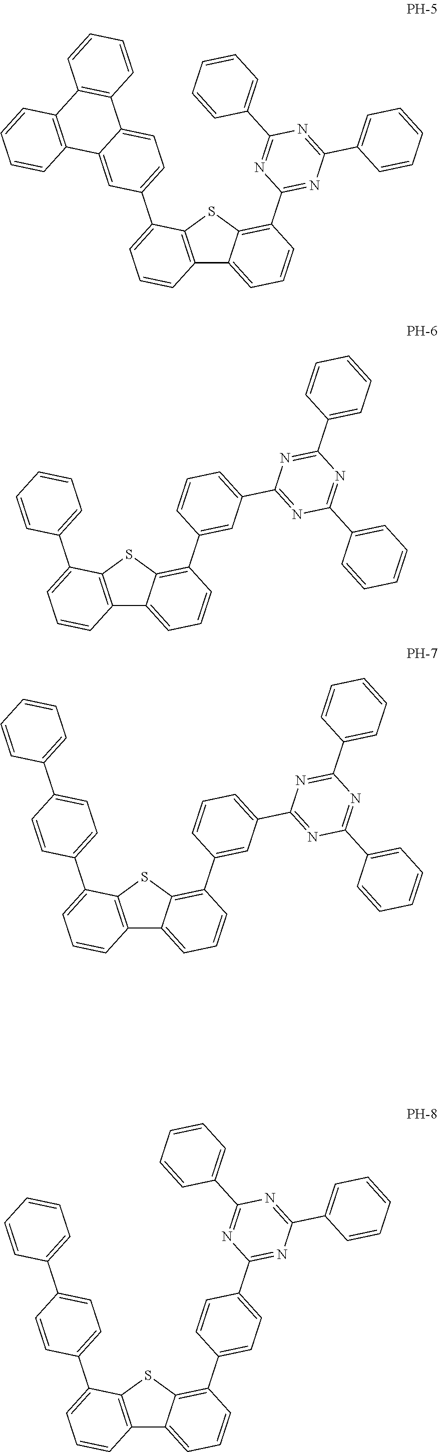 [SMILES: c1ccc(-c2nc(-c3ccccc3)nc(-c3cccc4c3sc3c(-c5ccc6c7ccccc7c7ccccc7c6c5)cccc34)n2)cc1 ; c1ccc(-c2nc(-c3ccccc3)nc(-c3cccc(-c4cccc5c4sc4c(-c6ccccc6)cccc45)c3)n2)cc1 ; c1ccc(-c2ccc(-c3cccc4c3sc3c(-c5cccc(-c6nc(-c7ccccc7)nc(-c7ccccc7)n6)c5)cccc34)cc2)cc1 ; c1ccc(-c2ccc(-c3cccc4c3sc3c(-c5ccc(-c6nc(-c7ccccc7)nc(-c7ccccc7)n6)cc5)cccc34)cc2)cc1]

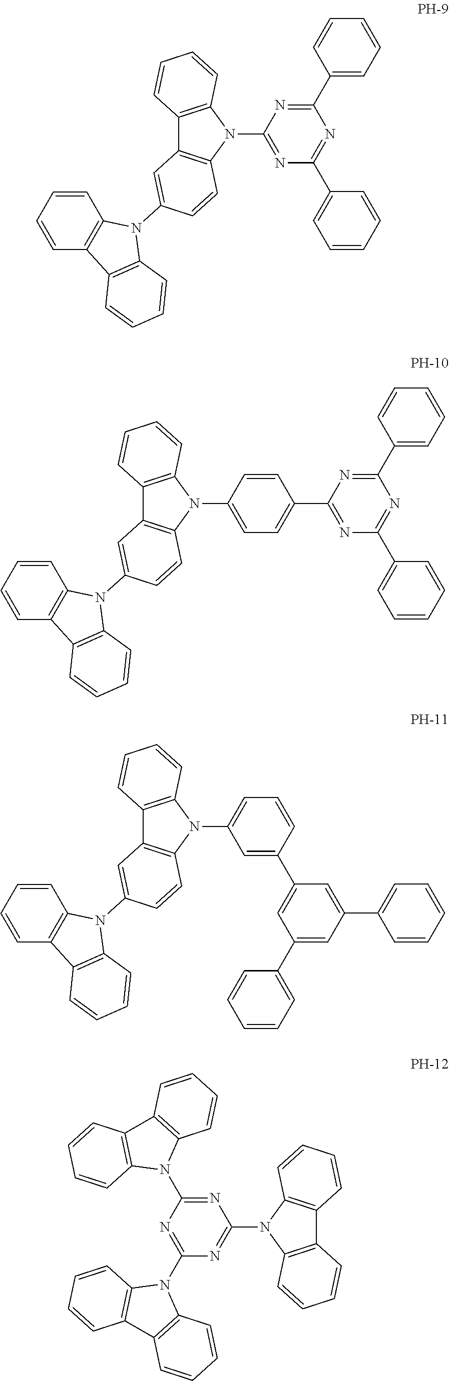 [SMILES: c1ccc(-c2nc(-c3ccccc3)nc(-n3c4ccccc4c4cc(-n5c6ccccc6c6ccccc65)ccc43)n2)cc1 ; c1ccc(-c2nc(-c3ccccc3)nc(-c3ccc(-n4c5ccccc5c5cc(-n6c7ccccc7c7ccccc76)ccc54)cc3)n2)cc1 ; c1ccc(-c2cc(-c3ccccc3)cc(-c3cccc(-n4c5ccccc5c5cc(-n6c7ccccc7c7ccccc76)ccc54)c3)c2)cc1 ; c1ccc2c(c1)c1ccccc1n2-c1nc(-n2c3ccccc3c3ccccc32)nc(-n2c3ccccc3c3ccccc32)n1]

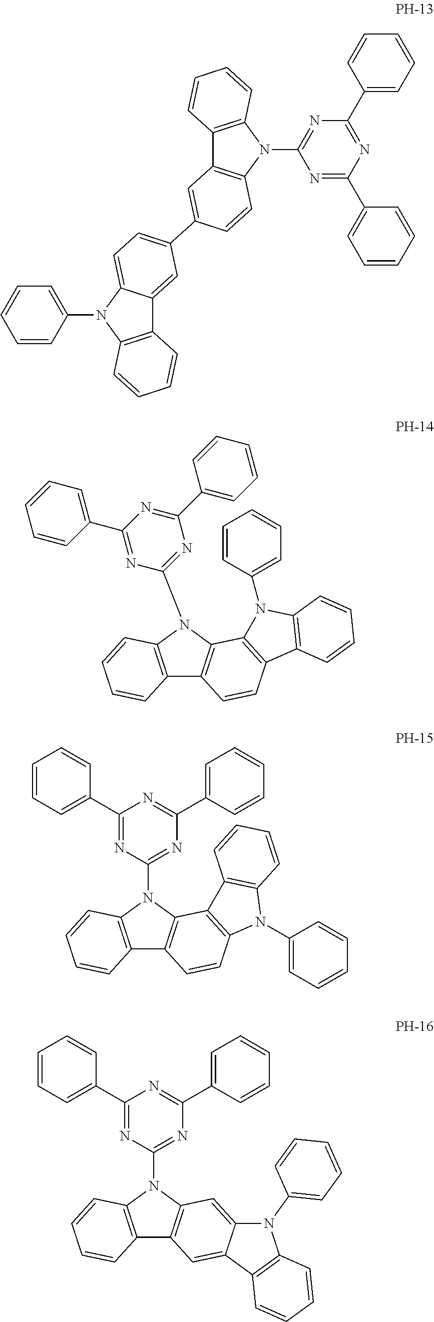 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-n3c4ccccc4c4cc5c6ccccc6n(-c6ccccc6)c5cc43)n2)cc1]

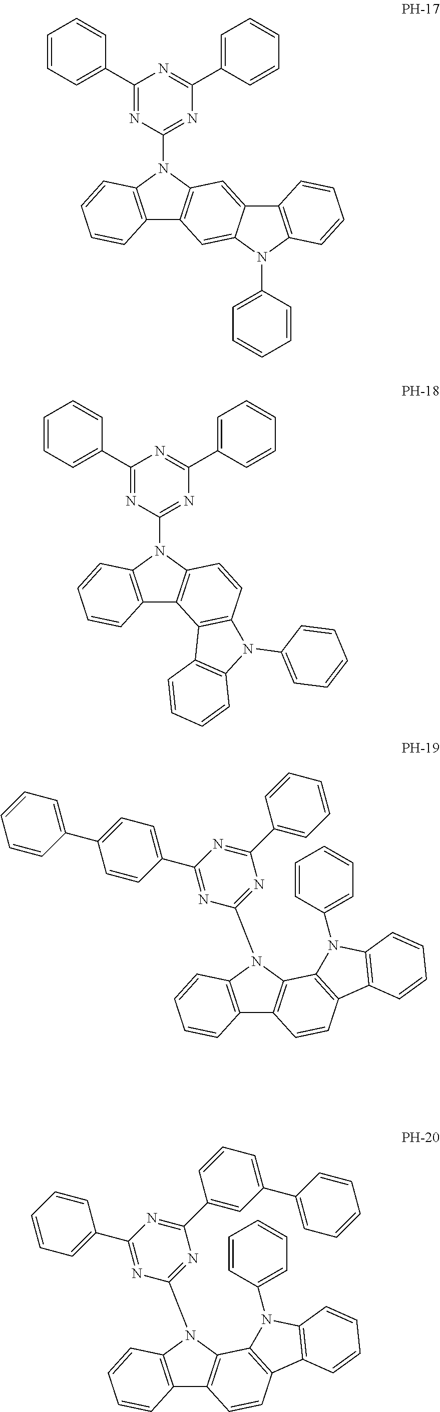

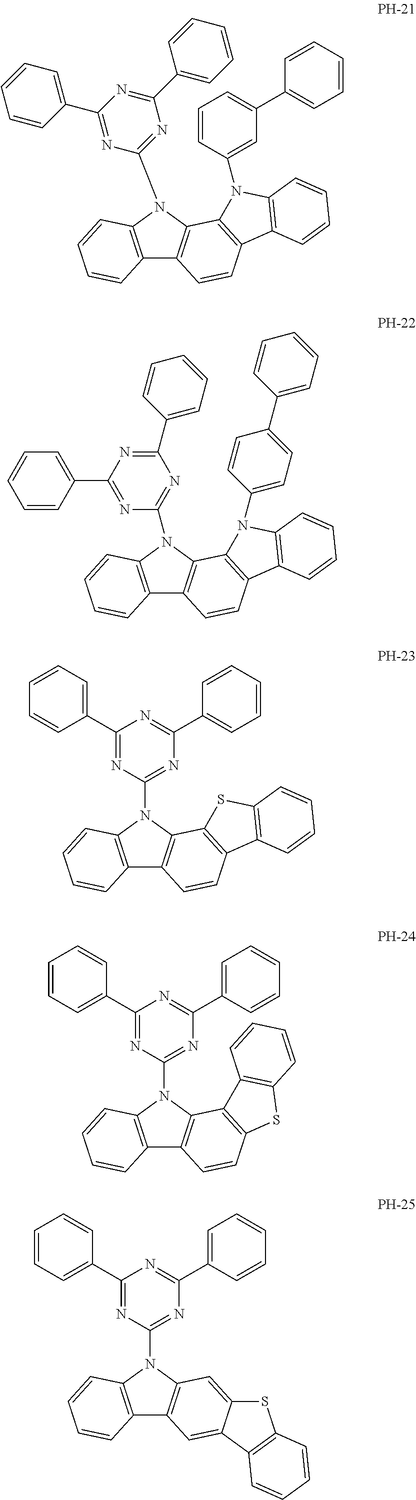 [SMILES: c1ccc(-c2cccc(-n3c4ccccc4c4ccc5c6ccccc6n(-c6nc(-c7ccccc7)nc(-c7ccccc7)n6)c5c43)c2)cc1 ; c1ccc(-c2ccc(-n3c4ccccc4c4ccc5c6ccccc6n(-c6nc(-c7ccccc7)nc(-c7ccccc7)n6)c5c43)cc2)cc1 ; c1ccc(-c2nc(-c3ccccc3)nc(-n3c4ccccc4c4ccc5c6ccccc6sc5c43)n2)cc1 ; c1ccc(-c2nc(-c3ccccc3)nc(-n3c4ccccc4c4ccc5sc6ccccc6c5c43)n2)cc1 ; c1ccc(-c2nc(-c3ccccc3)nc(-n3c4ccccc4c4cc5c(cc43)sc3ccccc35)n2)cc1]

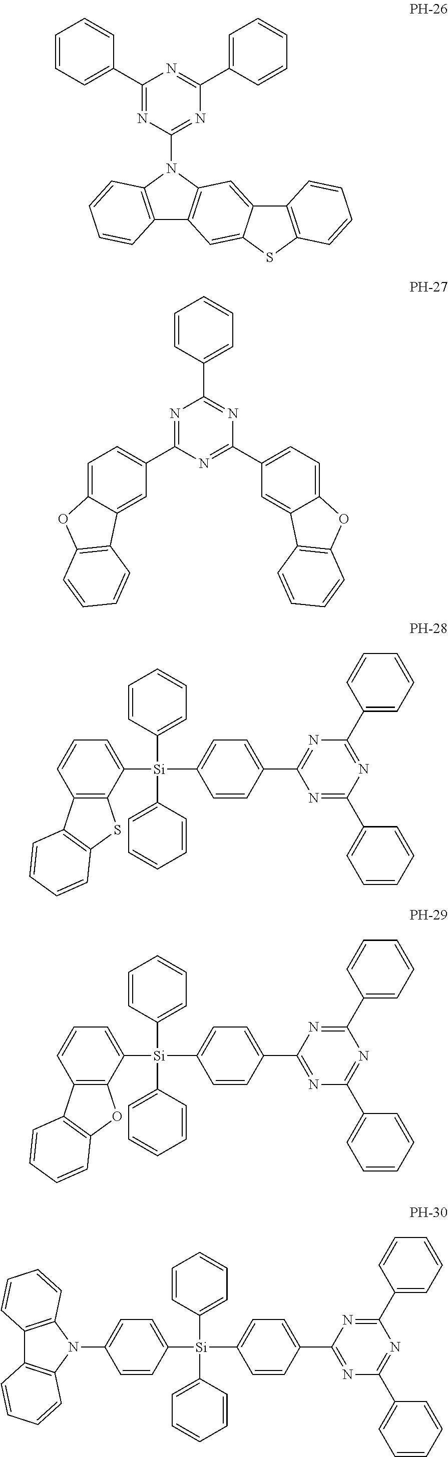 [SMILES: c1ccc(-c2nc(-c3ccccc3)nc(-n3c4ccccc4c4cc5sc6ccccc6c5cc43)n2)cc1 ; c1ccc(-c2nc(-c3ccc4oc5ccccc5c4c3)nc(-c3ccc4oc5ccccc5c4c3)n2)cc1 ; c1ccc(-c2nc(-c3ccccc3)nc(-c3ccc([Si](c4ccccc4)(c4ccccc4)c4cccc5c4sc4ccccc45)cc3)n2)cc1 ; c1ccc(-c2nc(-c3ccccc3)nc(-c3ccc([Si](c4ccccc4)(c4ccccc4)c4cccc5c4oc4ccccc45)cc3)n2)cc1 ; c1ccc(-c2nc(-c3ccccc3)nc(-c3ccc([Si](c4ccccc4)(c4ccccc4)c4ccc(-n5c6ccccc6c6ccccc65)cc4)cc3)n2)cc1]

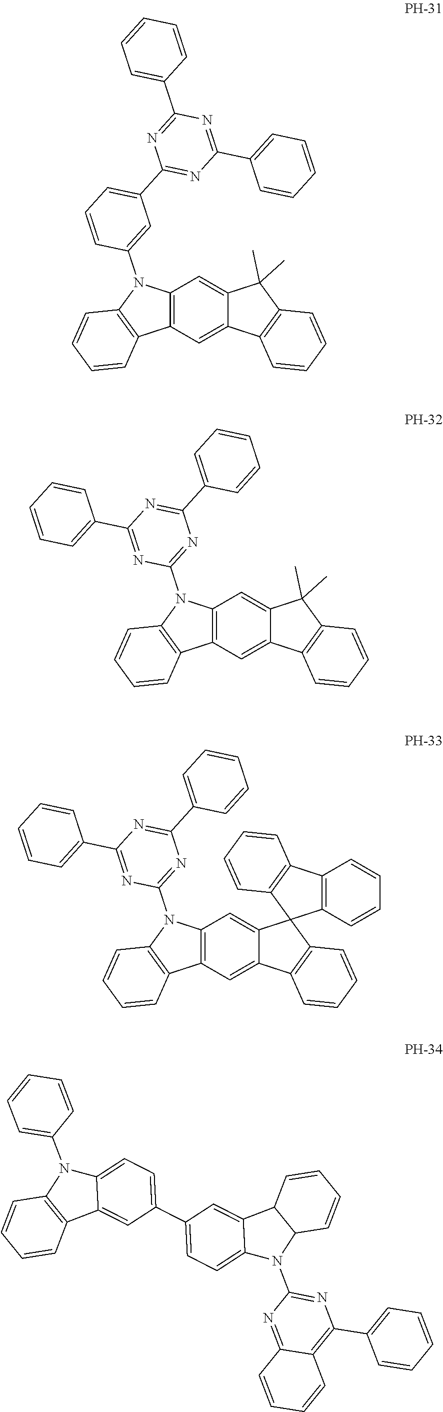 [SMILES: CC1(C)c2ccccc2-c2cc3c4ccccc4n(-c4cccc(-c5nc(-c6ccccc6)nc(-c6ccccc6)n5)c4)c3cc21 ; CC1(C)c2ccccc2-c2cc3c4ccccc4n(-c4nc(-c5ccccc5)nc(-c5ccccc5)n4)c3cc21 ; c1ccc(-c2nc(-c3ccccc3)nc(-n3c4ccccc4c4cc5c(cc43)C3(c4ccccc4-c4ccccc43)c3ccccc3-5)n2)cc1 ; C1=CC2c3cc(-c4ccc5c(c4)c4ccccc4n5-c4ccccc4)ccc3N(c3nc(-c4ccccc4)c4ccccc4n3)C2C=C1]

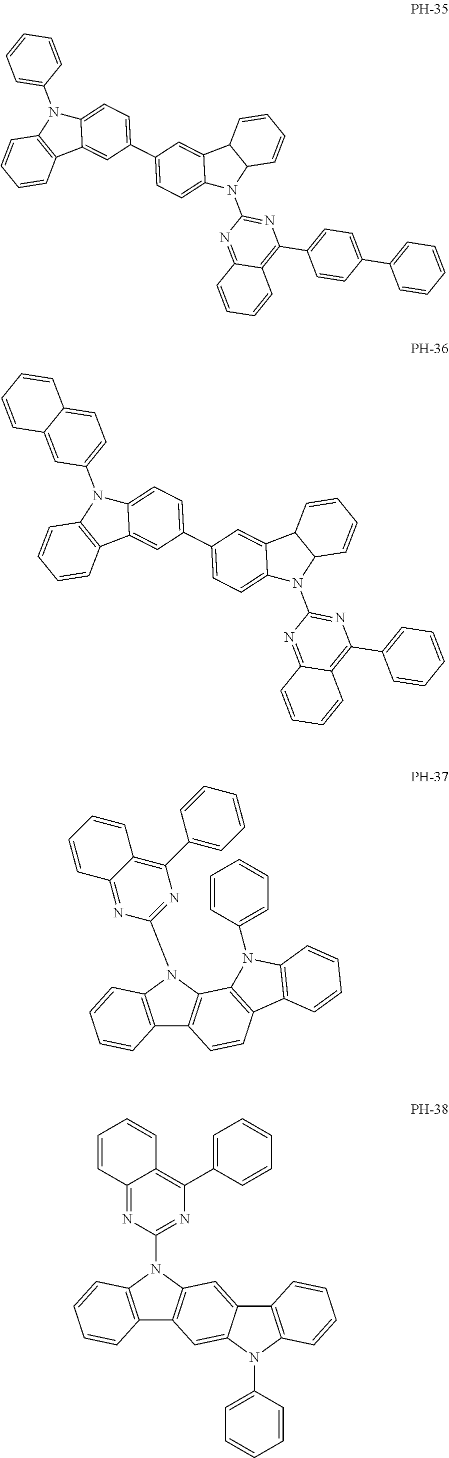 [SMILES: C1=CC2c3cc(-c4ccc5c(c4)c4ccccc4n5-c4ccccc4)ccc3N(c3nc(-c4ccc(-c5ccccc5)cc4)c4ccccc4n3)C2C=C1 ; C1=CC2c3cc(-c4ccc5c(c4)c4ccccc4n5-c4ccc5ccccc5c4)ccc3N(c3nc(-c4ccccc4)c4ccccc4n3)C2C=C1 ; c1ccc(-c2nc(-n3c4ccccc4c4ccc5c6ccccc6n(-c6ccccc6)c5c43)nc3ccccc23)cc1 ; c1ccc(-c2nc(-n3c4ccccc4c4cc5c(cc43)c3ccccc3n5-c3ccccc3)nc3ccccc23)cc1]

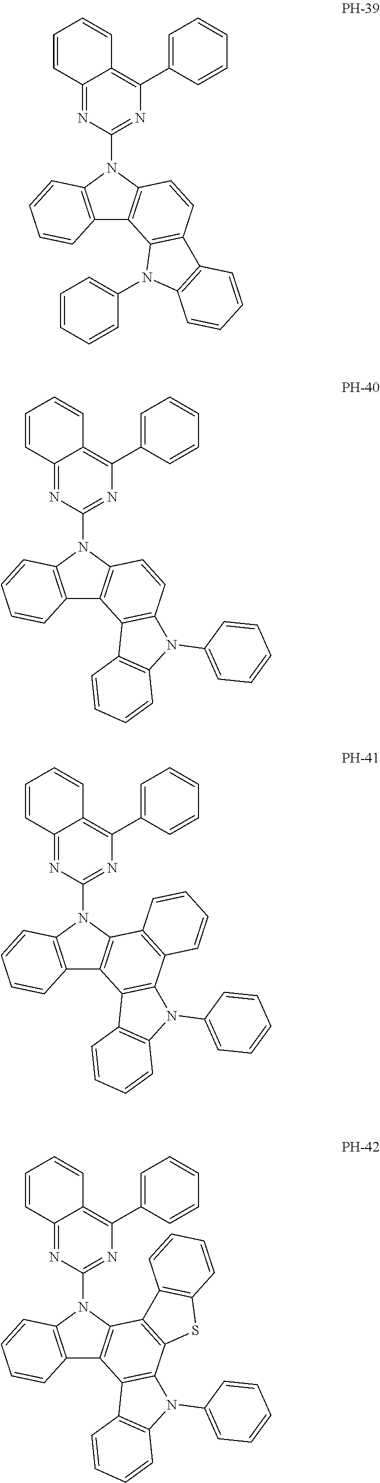 [SMILES: c1ccc(-c2nc(-n3c4ccccc4c4c3ccc3c5ccccc5n(-c5ccccc5)c34)nc3ccccc23)cc1 ; c1ccc(-c2nc(-n3c4ccccc4c4c5c6ccccc6n(-c6ccccc6)c5ccc43)nc3ccccc23)cc1 ; c1ccc(-c2nc(-n3c4ccccc4c4c5c6ccccc6n(-c6ccccc6)c5c5ccccc5c43)nc3ccccc23)cc1 ; c1ccc(-c2nc(-n3c4ccccc4c4c5c6ccccc6n(-c6ccccc6)c5c5sc6ccccc6c5c43)nc3ccccc23)cc1]

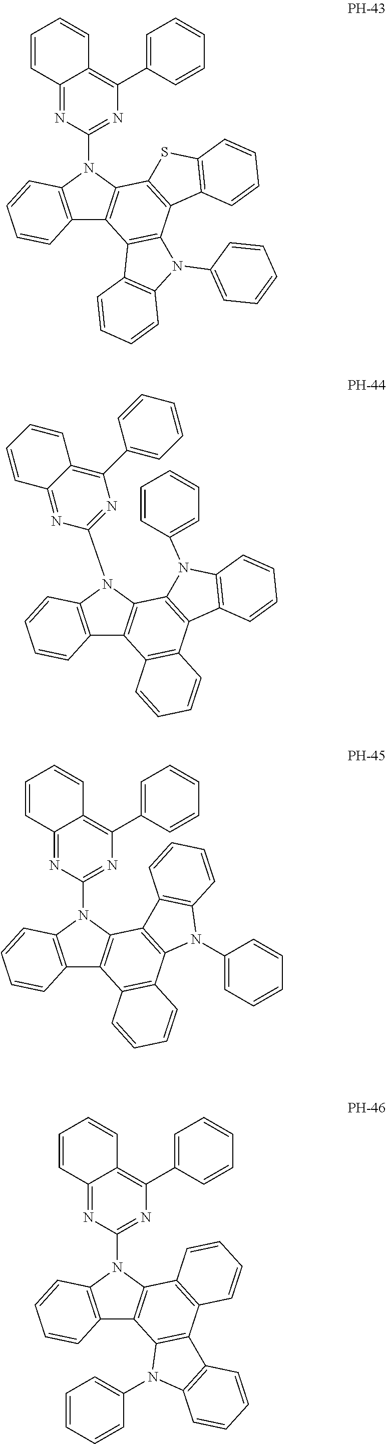 [SMILES: c1ccc(-c2nc(-n3c4ccccc4c4c5c6ccccc6n(-c6ccccc6)c5c5c6ccccc6sc5c43)nc3ccccc23)cc1 ; c1ccc(-c2nc(-n3c4ccccc4c4c5ccccc5c5c6ccccc6n(-c6ccccc6)c5c43)nc3ccccc23)cc1 ; c1ccc(-c2nc(-n3c4ccccc4c4c5ccccc5c5c(c6ccccc6n5-c5ccccc5)c43)nc3ccccc23)cc1 ; c1ccc(-c2nc(-n3c4ccccc4c4c3c3ccccc3c3c5ccccc5n(-c5ccccc5)c34)nc3ccccc23)cc1]

In addition, the material of the electron injection layer may include, but is not limited to, one or more of LiQ, LIF, NaCl, CsF, Li₂O, Cs₂CO₃, BaO, Na, Li, Ca, Mg, or Yb.

An example of the present application further provides a display apparatus, comprising the organic light-emitting diode described above. The display apparatus may specifically be a display device such as an OLED display, and any product or component comprising the display device and having a display function, such as a television, a digital camera, a mobile phone and a tablet computer. The display apparatus has the same advantages as the organic light-emitting diode described above compared to the prior art, and no more detailed description is to be given here.

The organic light-emitting diode of the present application will be further introduced with specific examples below.

In the examples below, the full width at half maximum of the narrow-spectrum fluorescent material used is between 15-45 nm.

In the following examples and comparative examples, the current efficiency (CE) of the devices in the examples and comparative examples are measured, and the ratios of the current efficiency of the devices in the examples and comparative examples to the current efficiency of the device in comparative example 3 are calculated, respectively, as the efficiency ratios. The results are shown in Table 1.

Herein, the current efficiency of the organic light-emitting diodes provided in examples and comparative examples of devices is measured using a digital source meter and PR 650 under the same luminance. Specifically, the voltage is increased at a rate of 0.1 V/sec, and when the luminance of the device reaches 15,000 cd/m², the current efficiency (CE) of the device at this time can be directly determined on PR 650.

### Example 1

The device in this example was a top green light-emitting stacked-layer device, which had a structure as shown in FIG. 2 and was prepared by the method including the following steps:
(1) a top-emitting substrate coated with an ITO conductive layer (anode) was sonicated in a commercial cleaning agent, rinsed in deionized water, sonicated in a mixed solvent of acetone: ethanol to remove oil, baked in a clean environment until moisture was completely removed, and cleaned with ultraviolet light and ozone, and then the surface was bombarded with a low-energy cation beam;
(2) the top-emitting substrate with an ITO conductive layer described above was placed in a vacuum cavity evacuated to less than 1×10⁻⁵ Pa; and an HT-28 material and an HI-2 material were co-evaporated onto the anode layer film as a first hole injection layer; where the proportion of the HI-2 material was 3%, the evaporation rate of the HT-28 material was 1 Å/s, and the total thickness of the evaporated film (i.e., the thickness of the first hole injection layer) was 100 Å; 3% was based on the sum of the mass of the HT-24 material and the HI-2 material of 100%, i.e., the total mass of the second hole injection layer of 100%; the percentages below were all based on the total mass of the corresponding functional layer of 100%; in addition, the total thickness of the evaporated film was the thickness of the corresponding functional layer formed via evaporation, which will not be explained in detail;
(3) a first hole transport layer was evaporated onto the first hole injection layer under vacuum using an HT-28 material at an evaporation rate of 1 Å/s, with the total thickness of the evaporated film being 250 Å;
(4) a first electron blocking layer was evaporated onto the first hole transport layer under vacuum using an HT-29 material at an evaporation rate of 1 Å/s, with the total thickness of the evaporated film being 250 Å;
(5) a first light-emitting layer comprising 94% of a host material A 85, 5% of a phosphorescent sensitizer GPD-22, and 1% of a narrow-spectrum fluorescent dye M1 was co-evaporated onto the first electron blocking layer, where a multi-source co-evaporation method was used, the host material was evaporated at a rate of 1 Å/s, and the total thickness of the evaporated film was 400 Å;
(6) a second hole blocking layer was evaporated onto the first light-emitting layer under vacuum using a PH-31 material at an evaporation rate of 1 Å/s, with the total thickness of the evaporated film being 50 Å;
(7) an ET-52 material and an ET-57 material, in a mass ratio of 1:1, were co-evaporated onto the second hole blocking layer under vacuum as a second electron transport layer, with the evaporation rate of the two materials being 1 Δ/s, and the total thickness of the evaporated film being 200 Å;
(8) a CGL-3 material and metal Yb were co-evaporated onto the second electron transport layer as an n-type charge generation layer, with CGL-3 evaporated at a rate of 1 Å/s, the proportion of metal Yb being 3%, and a total thickness being 100 Å;
(9) an HI-2 material and an HT-28 material were evaporated onto the n-type charge generation layer as a p-type charge generation layer, with HT-28 evaporated at a rate of 1 Å/s, the proportion of HI-2 being 5%, and a total thickness being 100 Å;
(10) a second hole transport layer was evaporated onto the p-type charge generation layer under vacuum using an HT-28 material, with an evaporation rate being 1 Å/s, and the total thickness of the evaporated film being 250 Å;
(11) a second electron blocking layer was evaporated onto the second hole transport layer under vacuum using an HT-29 material, with an evaporation rate being 1 Å/s, and the total thickness of the evaporated film being 450 Å;
(12) a second light-emitting layer comprising 94% of a host material A 85, 5% of a phosphorescent material GPD-22, and 1% of a narrow-spectrum fluorescent dye M1 was co-evaporated onto the second electron blocking layer, where a multi-source co-evaporation method was used, the host material was evaporated at a rate of 1 Å/s, and the total thickness of the evaporated film was 400 Å;
(13) a first hole blocking layer was evaporated onto the second light-emitting layer under vacuum using a PH-31 material, with an evaporation rate being 1 Å/s, and the total thickness of the evaporated film being 50 Å;
(14) an ET-52 material and an ET-57 material, in a mass ratio of 1:1, were co-evaporated onto the first hole blocking layer under vacuum as a first electron transport layer, with the evaporation rate of the two materials being 1 Å/s, and the total thickness of the evaporated film being 280 Å;
(15) a Yb material was evaporated onto the first electron transport layer under vacuum as a first electron injection layer with a thickness of 10 Å;
(16) M g and A g materials, in a mass ratio of 1:9 (i.e., M g: A g=1:9), were evaporated onto the first electron injection layer as a cathode, with the total thickness of the evaporated film being 130 Å; and
(17) a CPL-3 material was evaporated onto the cathode as a capping layer, with CPL-3 evaporated at a rate of 1 Å/s, and the total thickness of the evaporated film being 650 Å.

Examples 2-21: The conditions of Examples 2-21 were the same as those of Example 1, with the only exception that different narrow-spectrum fluorescent materials were used in the phosphorescence sensitized light-emitting layer, as specifically shown in Table 1.

Examples 22-29: The conditions of Examples 22-29 were the same as those of Example 1, with the only exception that different host materials were used in the phosphorescence sensitized light-emitting layer, as specifically shown in Table 1.

Examples 30-32: The conditions of Examples 30-32 were the same as those of Example 1, with the only exception that in the phosphorescence sensitized light-emitting layer, the type of the phosphorescent sensitizers was different, as specifically shown in Table 1.

Examples 33-42: The conditions of Examples 33-42 were the same as those of Example 1, with the only exception that the mass contents of the host material, the phosphorescent sensitizer, and the fluorescent material in the phosphorescence sensitized light-emitting layer were different, as specifically shown in Table 1.

Examples 43-44: The conditions of Examples 43-44 were the same as those of Example 1, with the only exception that the composition of the first light-emitting layer and the second light-emitting layer was different, as specifically shown in Table 1.

Example 45: The conditions of Example 45 were the same as those of Example 1, with the only exception that the first light-emitting layer was a phosphorescence sensitized light-emitting layer, and the second light-emitting layer was a phosphorescence layer, as specifically shown in Table 1.

Example 46: The conditions of Example 46 were the same as those of Example 1, with the only exception that the first light-emitting layer was phosphorescence layer, and the second light-emitting layer was a phosphorescence sensitized light-emitting layer, as specifically shown in Table 1.

Examples 47-49: The conditions of Examples 47-49 were the same as those of Example 1, except that the device was one with a single light-emitting layer, the device having a structure as shown in FIG. 1, including an anode, a first hole injection layer, a first hole transport layer, a first electron blocking layer, a first light-emitting layer (a phosphorescence sensitized light-emitting layer), a first hole blocking layer, a first electron transport layer, a first electron injection layer, and a cathode, which were stacked sequentially. The device with a single light-emitting layer was prepared according to steps (1)-(5) and (13)-(17) in Example 1, which will not be repeated.

The composition of the light-emitting layers and the performance test results of the devices in Examples 1-49 and Comparative examples 1-6 were summarized in Table 1, with the current efficiency (CE) of the device in Comparative example 3 measured to be approximately 320 cd/A.

TABLE 1

| | Composition of first light- | | | Composition of second light- | | | |
|---|---|---|---|---|---|---|---|
| | emitting layer | | | emitting layer | | | |
| | (Percentage refers to the mass | | | (Percentage refers to the mass | | | Performance |
| | content of a material in the first | | | content of a material in the | | | of |
| | light-emitting layer) | | | second light-emitting layer) | | | device |
| | Host | Phosphorescent | Fluorescent | Host | Phosphorescent | Fluorescent | Efficiency |
| Example | material | sensitizer | material | material | sensitizer | material | ratio |
| Comparative | A85, | GPD-22, | / | A85, | GPD-22, | / | 87% |
| example 1 | 95% | 5% | | 95% | 5% | | |
| Comparative | D-85, | GPD-22, | / | D85, | GPD-22, | / | 92% |
| example 2 | 95% | 5% | | 95% | 5% | | |
| Comparative | A85:D- | GPD-22, | / | A85:D- | GPD-22, | / | 100% |
| example 3 | 85 = 1:1, | 5% | | 85 = 1:1, | 5% | | |
| | 95%* | | | 95%* | | | |
| Comparative | D-85, | GPD-22, | / | / | / | / | 49% |
| example 4 | 95% | 5% | | | | | |
| Comparative | A85, | GPD-22, | / | / | / | / | 45% |
| example 5 | 95% | 5% | | | | | |
| Comparative | A85:D- | GPD-22, | / | / | / | / | 55% |
| example 6 | 85 = 1:1, | 5% | | | | | |
| | 95%* | | | | | | |
| Example 1 | A85:D- | GPD-22, | M 1, 1% | A85:D- | GPD-22, | M 1, 1% | 118% |
| | 85 = 1:1, | 5% | | 85 = 1:1, | 5% | | |
| | 94%* | | | 94%* | | | |
| Example 2 | A85:D- | GPD-22, | M 5, 1% | A85:D- | GPD-22, | M 5, 1% | 127% |
| | 85 = 1:1, | 5% | | 85 = 1:1, | 5% | | |
| | 94%* | | | 94%* | | | |
| Example 3 | A85:D- | GPD-22, | M 8, 1% | A85:D- | GPD-22, | M 8, 1% | 126% |
| | 85 = 1:1, | 5% | | 85 = 1:1, | 5% | | |
| | 94%* | | | 94%* | | | |
| Example 4 | A85:D- | GPD-22, | M 13, 1% | A85:D- | GPD-22, | M 13, | 125% |
| | 85 = 1:1, | 5% | | 85 = 1:1, | 5% | 1% | |
| | 94%* | | | 94%* | | | |
| Example 5 | A85:D- | GPD-22, | M 37, 1% | A85:D- | GPD-22, | M 37, | 125% |
| | 85 = 1:1, | 5% | | 85 = 1:1, | 5% | 1% | |
| | 94%* | | | 94%* | | | |
| Example 6 | A85:D- | GPD-22, | M 117, | A85:D- | GPD-22, | M 117, | 121% |
| | 85 = 1:1, | 5% | 1% | 85 = 1:1, | 5% | 1% | |
| | 94%* | | | 94%* | | | |
| Example 7 | A85:D- | GPD-22, | M 145, | A85:D- | GPD-22, | M 145, | 120% |
| | 85 = 1:1, | 5% | 1% | 85 = 1:1, | 5% | 1% | |
| | 94%* | | | 94%* | | | |
| Example 8 | A85:D- | GPD-22, | M 225, | A85:D- | GPD-22, | M 225, | 124% |
| | 85 = 1:1, | 5% | 1% | 85 = 1:1, | 5% | 1% | |
| | 94%* | | | 94%* | | | |
| Example 9 | A85:D- | GPD-22, | M 227, | A85:D- | GPD-22, | M 227, | 123% |
| | 85 = 1:1, | 5% | 1% | 85 = 1:1, | 5% | 1% | |
| | 94%* | | | 94%* | | | |
| Example 10 | A85:D- | GPD-22, | M 273, | A85:D- | GPD-22, | M 273, | 122% |
| | 85 = 1:1, | 5% | 1% | 85 = 1:1, | 5% | 1% | |
| | 94%* | | | 94%* | | | |
| Example 11 | A85:D- | GPD-22, | M 301, | A85:D- | GPD-22, | M 301, | 128% |
| | 85 = 1:1, | 5% | 1% | 85 = 1:1, | 5% | 1% | |
| | 94%* | | | 94%* | | | |
| Example 12 | A85:D- | GPD-22, | M 326, | A85:D- | GPD-22, | M 326, | 114% |
| | 85 = 1:1, | 5% | 1% | 85 = 1:1, | 5% | 1% | |
| | 94%* | | | 94%* | | | |
| Example 13 | A85:D- | GPD-22, | M 332, | A85:D- | GPD-22, | M 332, | 117% |
| | 85 = 1:1, | 5% | 1% | 85 = 1:1, | 5% | 1% | |
| | 94%* | | | 94%* | | | |
| Example 14 | A85:D- | GPD-22, | M 367, | A85:D- | GPD-22, | M 367, | 115% |
| | 85 = 1:1, | 5% | 1% | 85 = 1:1, | 5% | 1% | |
| | 94%* | | | 94%* | | | |
| Example 15 | A85:D- | GPD-22, | M 395, | A85:D- | GPD-22, | M 395, | 116% |
| | 85 = 1:1, | 5% | 1% | 85 = 1:1, | 5% | 1% | |
| | 94%* | | | 94%* | | | |
| Example 16 | A85:D- | GPD-22, | M 457, | A85:D- | GPD-22, | M 457, | 111% |
| | 85 = 1:1, | 5% | 1% | 85 = 1:1, | 5% | 1% | |
| | 94%* | | | 94%* | | | |
| Example 17 | A85:D- | GPD-22, | M 469, | A85:D- | GPD-22, | M 469, | 112% |
| | 85 = 1:1, | 5% | 1% | 85 = 1:1, | 5% | 1% | |
| | 94%* | | | 94%* | | | |
| Example 18 | A85:D- | GPD-22, | M 411, | A85:D- | GPD-22, | M 411, | 116% |
| | 85 = 1:1, | 5% | 1% | 85 = 1:1, | 5% | 1% | |
| | 94%* | | | 94%* | | | |
| Example 19 | A85:D- | GPD-22, | M 437, | A85:D- | GPD-22, | M 437, | 117% |
| | 85 = 1:1, | 5% | 1% | 85 = 1:1, | 5% | 1% | |
| | 94%* | | | 94%* | | | |
| Example 20 | A85:D- | GPD-22, | M 446, | A85:D- | GPD-22, | M 446, | 114% |
| | 85 = 1:1, | 5% | 1% | 85 = 1:1, | 5% | 1% | |
| | 94%* | | | 94%* | | | |
| Example 21 | A85:D- | GPD-22, | M 234, | A85:D- | GPD-22, | M 234, | 115% |
| | 85 = 1:1, | 5% | 1% | 85 = 1:1, | 5% | 1% | |
| | 94%* | | | 94%* | | | |
| Example 22 | A81, | GPD-22, | M 1, 1% | A81, | GPD-22, | M 1, 1% | 112% |
| | 94% | 5% | | 94% | 5% | | |
| Example 23 | A85, | GPD-22, | M 1, 1% | A85, | GPD-22, | M 1, 1% | 113% |
| | 94% | 5% | | 94% | 5% | | |
| Example 24 | A86, | GPD-22, | M 1, 1% | A86, | GPD-22, | M 1, 1% | 111% |
| | 94% | 5% | | 94% | 5% | | |
| Example 25 | D-85, | GPD-22, | M 1, 1% | D-85, | GPD-22, | M 1, 1% | 113% |
| | 94% | 5% | | 94% | 5% | | |
| Example 26 | D-5, | GPD-22, | M 1, 1% | D-5, | GPD-22, | M 1, 1% | 111% |
| | 94% | 5% | | 94% | 5% | | |
| Example 27 | D-7, | GPD-22, | M 1, 1% | D-7, | GPD-22, | M 1, 1% | 110% |
| | 94% | 5% | | 94% | 5% | | |
| Example 28 | A81:D- | GPD-22, | M 1, 1% | A81:D- | GPD-22, | M 1, 1% | 116% |
| | 5 = 1:1, | 5% | | 5 = 1:1, | 5% | | |
| | 94%* | | | 94%* | | | |
| Example 29 | A86:D- | GPD-22, | M 1, 1% | A86:D- | GPD-22, | M 1, 1% | 115% |
| | 7 = 1:1, | 5% | | 7 = 1:1, | 5% | | |
| | 94%* | | | 94%* | | | |
| Example 30 | A85:D- | GPD-23, | M 1, 1% | A85:D- | GPD-23, | M 1, 1% | 117% |
| | 85 = 1:1, | 5% | | 85 = 1:1, | 5% | | |
| | 94%* | | | 94%* | | | |
| Example 31 | A85:D- | GPD-42, | M 1, 1% | A85:D- | GPD-42, | M 1, 1% | 114% |
| | 85 = 1:1, | 5% | | 85 = 1:1, | 5% | | |
| | 94%* | | | 94%* | | | |
| Example 32 | A85:D- | GPD-1, | M 1, 1% | A85:D- | GPD-1, | M 1, 1% | 113% |
| | 85 = 1:1, | 5% | | 85 = 1:1, | 5% | | |
| | 94%* | | | 94%* | | | |
| Example 33 | A85:D- | GPD-22, | M 1, 0.3% | A85:D - | GPD-22, | M 1, | 109% |
| | 85 = 1:1, | 5% | | 85 = 1:1, | 5% | 0.3% | |
| | 94.7%* | | | 94.7%* | | | |
| Example 34 | A85:D- | GPD-22, | M 1, 0.5% | A85:D- | GPD-22, | M 1, | 113% |
| | 85 = 1:1, | 5% | | 85 = 1:1, | 5% | 0.5% | |
| | 94.5%* | | | 94.5%* | | | |
| Example 35 | A85:D- | GPD-22, | M 1, 1.5% | A85:D- | GPD-22, | M 1, | 117% |
| | 85 = 1:1, | 5% | | 85 = 1:1, | 5% | 1.5% | |
| | 93.5%* | | | 93.5%* | | | |
| Example 36 | A85:D- | GPD-22, | M 1, 5% | A85:D- | GPD-22, | M 1, 5% | 107% |
| | 85 = 1:1, | 5% | | 85 = 1:1, | 5% | | |
| | 90%* | | | 90%* | | | |
| Example 37 | A85:D- | GPD-22, | M 1, 20% | A85:D- | GPD-22, | M 1, | 103% |
| | 85 = 1:1, | 5% | | 85 = 1:1, | 5% | 20% | |
| | 75%* | | | 75%* | | | |
| Example 38 | A85:D- | GPD-22, | M 1, 1% | A85:D- | GPD-22, | M 1, 1% | 111% |
| | 85 = 1:1, | 1% | | 85 = 1:1, | 1% | | |
| | 98%* | | | 98%* | | | |
| Example 39 | A85:D- | GPD-22, | M 1, 1% | A85:D- | GPD-22, | M 1, 1% | 115% |
| | 85 = 1:1, | 3% | | 85 = 1:1, | 3% | | |
| | 96%* | | | 96%* | | | |
| Example 40 | A85:D- | GPD-22, | M 1, 1% | A85:D- | GPD-22, | M 1, 1% | 117% |
| | 85 = 1:1, | 8% | | 85 = 1:1, | 8% | | |
| | 91%* | | | 91%* | | | |
| Example 41 | A85:D- | GPD-22, | M 1, 1% | A85:D- | GPD-22, | M 1, 1% | 107% |
| | 85 = 1:1, | 10% | | 85 = 1:1, | 10% | | |
| | 89%* | | | 89%* | | | |
| Example 42 | A85:D- | GPD-22, | M 1, 1% | A85:D- | GPD-22, | M 1, 1% | 102% |
| | 85 = 1:1, | 40% | | 85 = 1:1, | 40% | | |
| | 59%* | | | 59%* | | | |
| Example 43 | A85:D- | GPD-22, | M 1, 1% | A81:D- | GPD-42, | M 1, 1% | 117% |
| | 85 = 1:1, | 5% | | 5 = 1:1, | 5% | | |
| | 94%* | | | 94%* | | | |
| Example 44 | A85, | GPD-22, | M 1, 1% | A86, | GPD-22, | M 5, 1% | 113% |
| | 94% | 5% | | 94% | 5% | | |
| Example 45 | A85:D- | GPD-22, | M 1, 1% | A85:D- | GPD-22, | / | 109% |
| | 85 = 1:1, | 5% | | 85 = 1:1, | 5% | | |
| | 94%* | | | 94%* | | | |
| Example 46 | A85:D- | GPD-22, | / | A85:D- | GPD-22, | M 1, 1% | 108% |
| | 85 = 1:1, | 5% | | 85 = 1:1, | 5% | | |
| | 94%* | | | 94%* | | | |
| Example 47 | A85, | GPD-22, | M 1, 1% | / | / | / | 52% |
| | 94% | 5% | | | | | |
| Example 48 | D-85, | GPD-22, | M 1, 1% | / | / | / | 55% |
| | 94% | 5% | | | | | |
| Example 49 | A85:D- | GPD-22, | M 1, 1% | / | / | / | 62% |
| | 85 = 1:1, | 5% | | | | | |
| | 94%* | | | | | | |

*denotes that the mass ratio of the two host materials is 1:1, and the sum of the mass contents of the two host materials in the light-emitting layer is 94%. For example, “A85:D85 = 1:1, 94%” denotes that: in the first light-emitting layer (or the second light-emitting layer), the mass ratio of A85 to D85 is 1:1, and the ratio of the sum of the mass of A85 and D85 to the total mass of the first light-emitting layer is 94%.

The singlet energy level (S₁^{P} and S₁^{N}) and triplet energy level (TIP and TIN) of the host materials in the examples described above, the singlet energy level SEX and the triplet energy level T₁^{EX} of the exciplexes formed by two host materials (A 85:D-85=1:1, A 81:D-5=1:1, and A 86:D-7=1:1), the triplet energy level T₁^{Phos} of the phosphorescent sensitizer, and the singlet energy level S₁^{F} and the triplet energy level T₁^{F} of the narrow-spectrum fluorescent material are shown in Table 2. The highest occupied molecular orbital E_{HOMO} (E_{HOMO}^{P} and E_{HOMO}^{N}) and the lowest unoccupied molecular orbital E_{LUMO} (E_{LUMO}^{P} and E_{LUMO}^{N}) of the host materials are shown in Table 3.

Herein, S₁^{P}, T₁^{P}, S₁^{N}, T₁^{N}, S₁^{EX} and T₁^{EX} can be respectively calculated from the Onset values of the fluorescence and phosphorescence emission spectra at a low temperature (77 K). Additionally, T₁^{Phos} was calculated from the Onset value of the phosphorescence emission spectrum at 77 K.

TABLE 2

| | | Singlet | |
|---|---|---|---|
| | | energy | Triplet energy |
| Material | | level/eV | level/eV |
| Hole transport | D-85 | S₁^{P} = 3.51 | T₁^{P} = 2.77 |
| host | D-5 | S₁^{P} = 3.4 | T₁^{P} = 2.84 |
| | D-7 | S₁^{P} = 3.42 | T₁^{P} = 2.84 |
| Electron | A 81 | S₁^{N} = 2.83 | T₁^{N} = 2.80 |
| transport host | A 85 | S₁^{N} = 3.44 | T₁^{N} = 2.92 |
| | A 86 | S₁^{N} = 3.33 | T₁^{N} = 2.8 |
| Exciplex | Exciplex | S₁^{EX} = 2.93 | T₁^{EX} = 2.76 |
| | formed with | | |
| | A 85:D-85 = | | |
| | 1:1 | | |
| | Exciplex | S₁^{EX} = 2.81 | T₁^{EX} = 2.78 |
| | formed with | | |
| | A 81:D-5 = | | |
| | 1:1 | | |
| | Exciplex | S₁^{EX} = 2.85 | T₁^{EX} = 2.81 |
| | formed with | | |
| | A 86:D-7 = | | |
| | 1:1 | | |
| Phosphorescent | GPD-1 | / | T₁^{Phos} = 2.65 |
| sensitizer | GPD-22 | / | T₁^{Phos} = 2.59 |
| | GPD-23 | / | T₁^{Phos} = 2.62 |
| | GPD-42 | / | T₁^{Phos} = 2.64 |
| Narrow- | M 1 | S₁^{F} = 2.5 | T₁^{F} = 2.29 |
| spectrum | M 5 | S₁^{F} = 2.46 | T₁^{F} = 2.26 |
| fluorescent | M 8 | S₁^{F} = 2.52 | T₁^{F} = 2.3 |
| material | M 13 | S₁^{F} = 2.45 | T₁^{F} = 2.23 |
| | M 37 | S₁^{F} = 2.46 | T₁^{F} = 2.27 |
| | M 117 | S₁^{F} = 2.49 | T₁^{F} = 2.29 |
| | M 145 | S₁^{F} = 2.4 | T₁^{F} = 2.26 |
| | M 225 | S₁^{F} = 2.45 | T₁^{F} = 2.24 |
| | M 227 | S₁^{F} = 2.44 | T₁^{F} = 2.22 |
| | M 273 | S₁^{F} = 2.39 | T₁^{F} = 2.11 |
| | M 301 | S₁^{F} = 2.45 | T₁^{F} = 2.24 |
| | M 326 | S₁^{F} = 2.51 | T₁^{F} = 2.23 |
| | M 332 | S₁^{F} = 2.46 | T₁^{F} = 2.19 |
| | M 367 | S₁^{F} = 2.5 | T₁^{F} = 2.24 |
| | M 395 | S₁^{F} = 2.48 | T₁^{F} = 2.32 |
| | M 457 | S₁^{F} = 2.51 | T₁^{F} = 2.25 |
| | M 469 | S₁^{F} = 2.53 | T₁^{F} = 2.26 |
| | M 411 | S₁^{F} = 2.46 | S₁^{F} = 2.22 |
| | M 446 | S₁^{F} = 2.40 | S₁^{F} = 2.15 |
| | M 437 | S₁^{F} = 2.45 | S₁^{F} = 2.17 |
| | M 234 | S₁^{F} = 2.47 | S₁^{F} = 2.26 |

TABLE 3

| Material | | E_{HOMO}/eV | E_{LUMO}/eV |
|---|---|---|---|
| Hole | D-85 | E_{HOMO}^{P} = −5.38 | E_{LUMO}^{P} = −1.66 |
| transport host | D-5 | E_{HOMO}^{P} = −5.41 | E_{LUMO}^{P} = −1.74 |
| material | D-7 | E_{HOMO}^{P} = −5.41 | E_{LUMO}^{P} = −1.74 |
| Electron | A 81 | E_{HOMO}^{N} = −5.55 | E_{LUMO}^{N} = −2.6 |
| transport host | A 85 | E_{HOMO}^{N} = −5.9 | E_{LUMO}^{N} = −2.66 |
| material | A 86 | E_{HOMO}^{N} = −5.56 | E_{LUMO}^{N} = −2.66 |

As can be seen from Table 1, compared to Comparative examples 1-3, the stacked-layer devices of Examples 1-46, which have at least one light-emitting layer as a phosphorescence sensitized light-emitting layer, exhibit significantly improved efficiency; moreover, compared to Comparative examples 4-6, the single-layer devices of Examples 47-49, which have a light-emitting layer as a phosphorescence sensitized light-emitting layer, exhibit significantly improved efficiency. In addition, by comprehensively analyzing Examples 1-21 and Examples 22-29, as well as Examples 47-48 and Example 49, it can be seen that a phosphorescence sensitized light-emitting layer using two host materials can further improve the performance such as efficiency of the device.

1. An organic light-emitting diode, comprising at least one light-emitting layer, which comprises at least one phosphorescence sensitized light-emitting layer, wherein the phosphorescence sensitized light-emitting layer comprises a host material, a phosphorescent sensitizer, and a narrow-spectrum fluorescent material, and the full width at half maximum of the narrow-spectrum fluorescent material is less than 50 nm.

2. The organic light-emitting diode according to claim 1, wherein the host material is a host material; or
the host material comprises a plurality of host materials, and
the mass percentage of each of the plurality of host materials is not less than 10%, based on the total mass of the plurality of host materials.

3. The organic light-emitting diode according to claim 1, wherein both the singlet energy level and the triplet energy level of the host material are higher than the triplet energy level of the phosphorescent sensitizer;
the triplet energy level of the phosphorescent sensitizer is higher than the singlet energy level and the triplet energy level of the narrow-spectrum fluorescent material.

4. The organic light-emitting diode according to claim 1, wherein the host material comprises a first host material and a second host material, and the first host material and the second host material form an exciplex.

5. The organic light-emitting diode according to claim 4, wherein both the singlet energy level and the triplet energy level of the exciplex are higher than the triplet energy level of the phosphorescent sensitizer;
both the singlet energy level and the triplet energy level of the exciplex are higher than the triplet energy level of the narrow-spectrum fluorescent material.

6. The organic light-emitting diode according to claim 4, wherein the first host material is a hole transport host material, the second host material is an electron transport host material, and the singlet energy level S₁^{P} of the first host material, the singlet energy level S₁^{N} of the second host material, and the singlet energy level S₁^{EX} of the exciplex satisfy the following relationship:
S₁^{P}>S₁^{N}≥S₁^{EX};
the singlet energy level S₁^{EX} and the triplet energy level T₁^{EX} of the exciplex satisfy the following relationship:
0<S₁^{EX}−T₁^{EX}≤0.3 eV.

7. The organic light-emitting diode according to claim 6, wherein the highest occupied molecular orbital energy level E_{HOMO}^{P} and the lowest unoccupied molecular orbital energy level E_{LUMO}^{P} of the hole transport host material, and the highest occupied molecular orbital energy level E_{HOMO}^{N} and the lowest unoccupied molecular orbital energy level E_{LUMO}^{N} of the electron transport host material satisfy:
E_{HOMO}^{P}>E_{HOMO}^{N}; and
E_{LUMO}^{P}>E_{LUMO}^{N}.

8. The organic light-emitting diode according to claim 4, wherein the first host material comprises a compound represented by Formula 1: 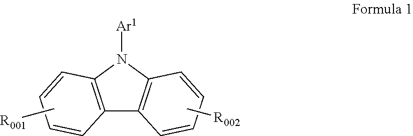
wherein Ar¹ is selected from one of substituted or unsubstituted C6-C60 aryl, and substituted or unsubstituted C3-C60 heteroaryl; and
R₀₀₁ and R₀₀₂ represent zero to the maximum permissible substituents on the benzene rings, and R₀₀₁ and R₀₀₂ are each independently selected from one of deuterium, cyano, substituted or unsubstituted C1-C20 alkyl, substituted or unsubstituted C3-C20 cycloalkyl, substituted or unsubstituted C1-C20 silanyl, substituted or unsubstituted C6-C30 arylamino, substituted or unsubstituted C7-C30 aralkyl, substituted or unsubstituted C3-C30 heteroarylamino, substituted or unsubstituted C6-C60 aryl, and substituted or unsubstituted C3-C60 heteroaryl.

9. The organic light-emitting diode according to claim 8, wherein the first host material has a structure represented by Formula 1-1 or Formula 1-2: 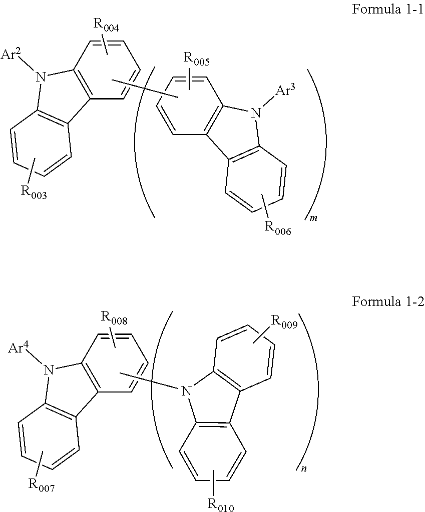
wherein m and n are each independently an integer from 1 to 4;
Ar², Ar³ and Ar⁴ are each independently selected from one of substituted or unsubstituted C6-C60 aryl, and substituted or unsubstituted C3-C60 heteroaryl; and
R₀₀₃ to R₀₁₀ represent zero to the maximum permissible substituents on the benzene rings and are each independently selected from one of hydrogen, deuterium, cyano, substituted or unsubstituted C1-C20 alkyl, substituted or unsubstituted C3-C20 cycloalkyl, substituted or unsubstituted C1-C20 silanyl, substituted or unsubstituted C6-C30 arylamino, substituted or unsubstituted C7-C30 aralkyl, substituted or unsubstituted C3-C30 heteroarylamino, substituted or unsubstituted C6-C60 aryl, and substituted or unsubstituted C3-C60 heteroaryl.

10. The organic light-emitting diode according to claim 9, wherein Ar², Ar³ and Ar⁴ are each independently selected from one or a combination of more of substituted or unsubstituted benzene, substituted or unsubstituted biphenyl, substituted or unsubstituted terphenyl, substituted or unsubstituted triphenylene, substituted or unsubstituted dibenzofuran, substituted or unsubstituted dibenzothiophene, substituted or unsubstituted indole, substituted or unsubstituted indolocarbazole, substituted or unsubstituted carbazole, and substituted or unsubstituted fluorene.

11. The organic light-emitting diode according to claim 9, wherein the first host material comprises one or more of the following compounds D-1 to D-85:

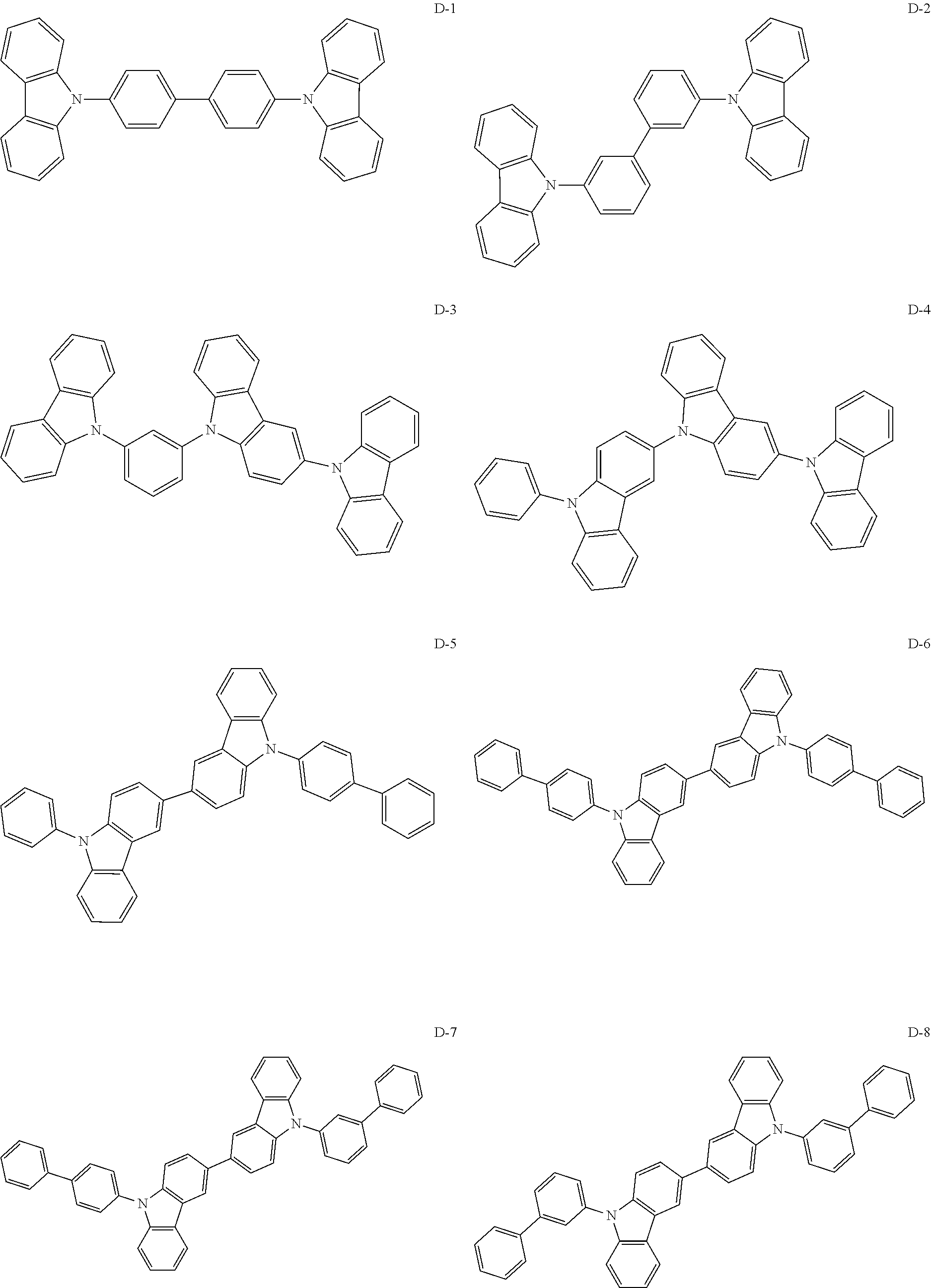

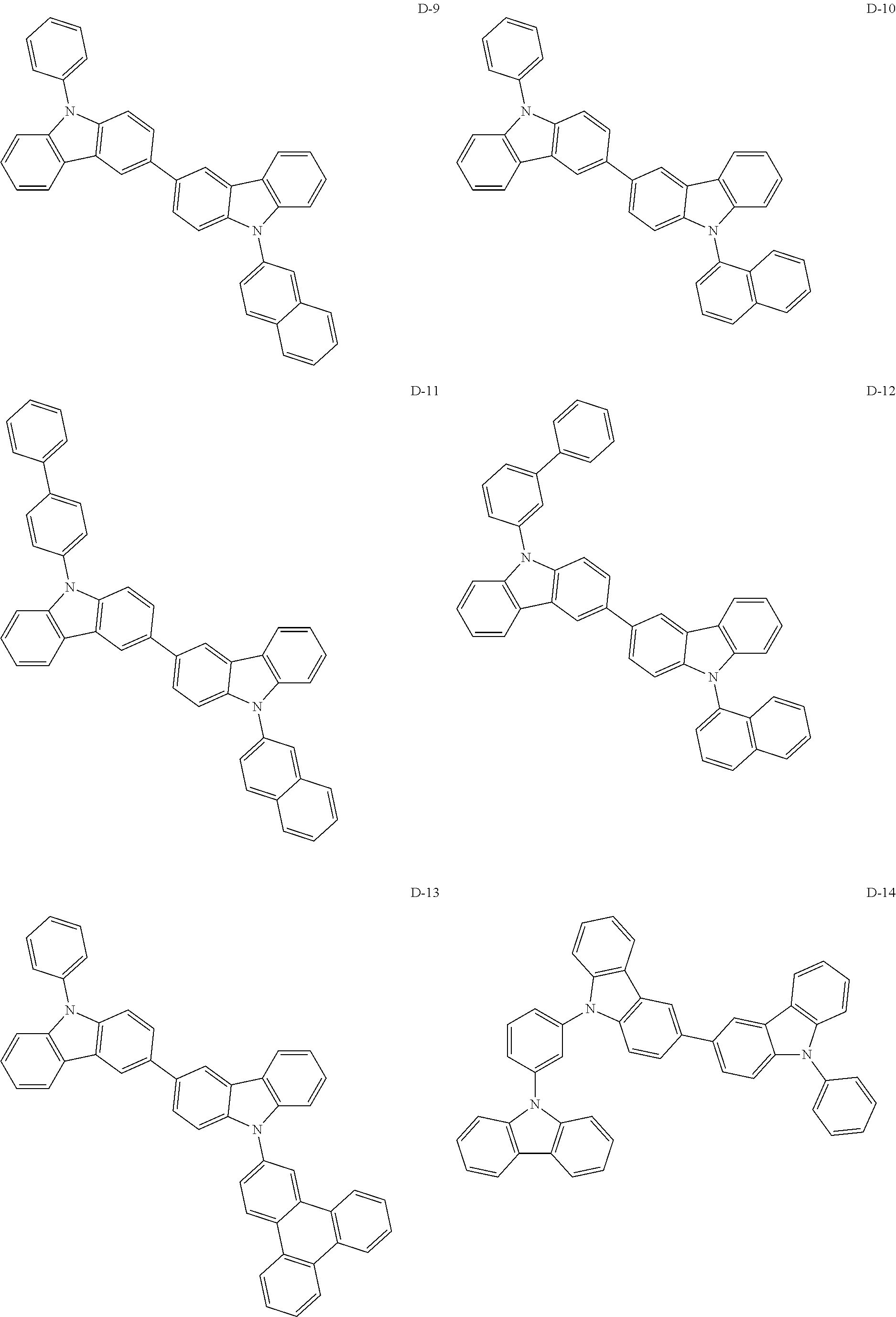 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc6ccccc56)ccc43)c2)cc1 ; c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4ccccc4n5-c4cccc(-n5c6ccccc6c6ccccc65)c4)ccc32)cc1]

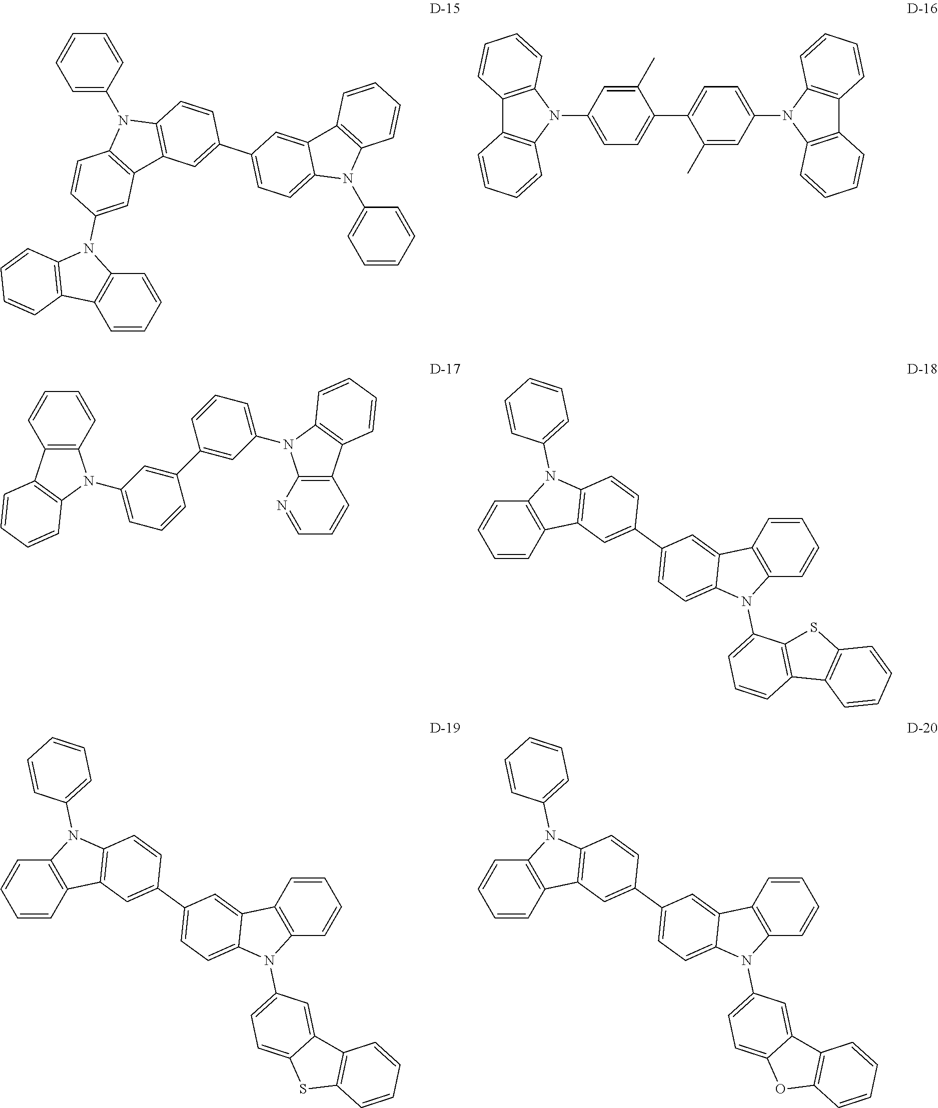 [SMILES: c1ccc(-n2c3ccccc3c3cc(-c4ccc5c(c4)c4cc(-n6c7ccccc7c7ccccc76)ccc4n5-c4ccccc4)ccc32)cc1 ; Cc1cc(-n2c3ccccc3c3ccccc32)ccc1-c1ccc(-n2c3ccccc3c3ccccc32)cc1C ; c1cc(-c2cccc(-n3c4ccccc4c4cccnc43)c2)cc(-n2c3ccccc3c3ccccc32)c1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1 ; c1ccc(-n2c3ccccc3c3cc(-c4ccc5c(c4)c4ccccc4n5-c4ccc5oc6ccccc6c5c4)ccc32)cc1]

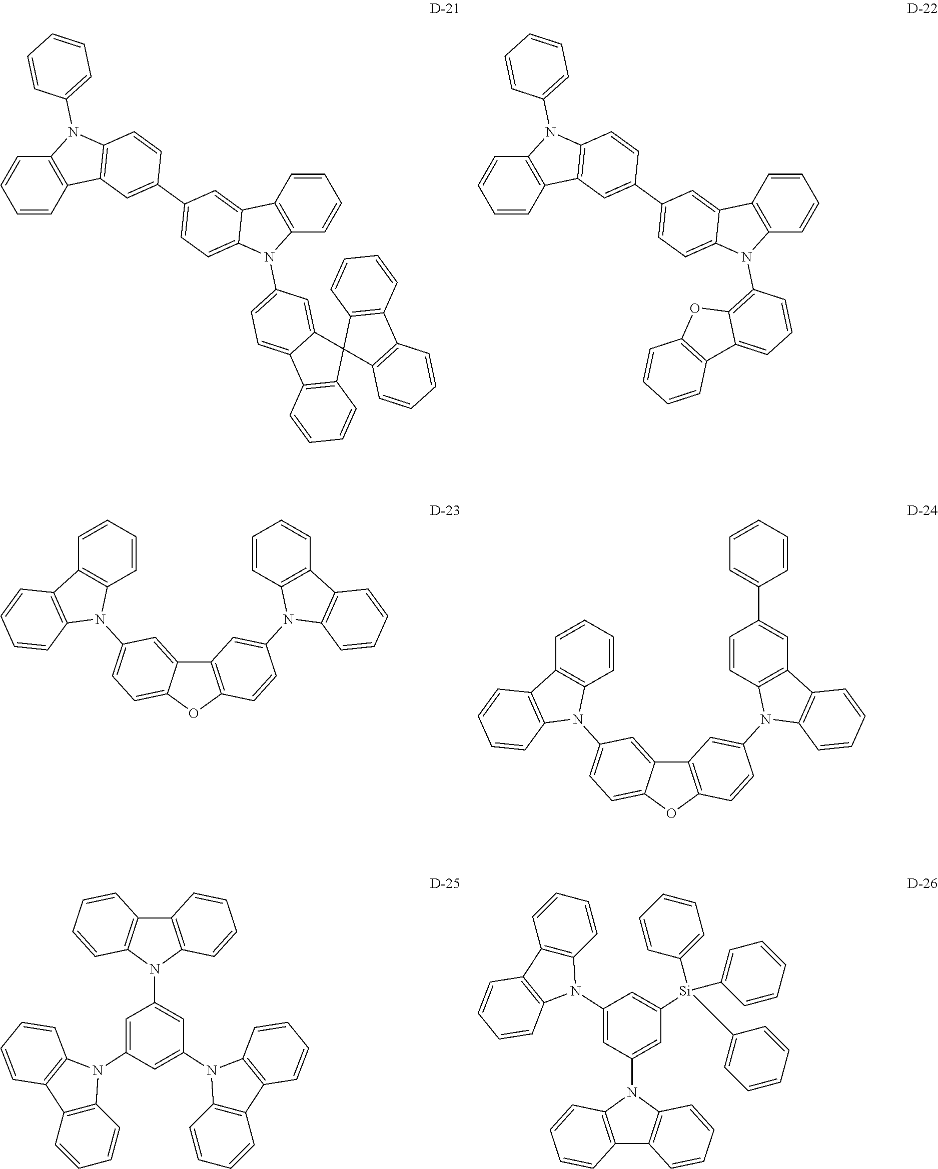 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; c1ccc(-n2c3ccccc3c3cc(-c4ccc5c(c4)c4ccccc4n5-c4cccc5c4oc4ccccc45)ccc32)cc1 ; c1ccc2c(c1)c1ccccc1n2-c1ccc2oc3ccc(-n4c5ccccc5c5ccccc54)cc3c2c1 ; c1ccc(-c2ccc3c(c2)c2ccccc2n3-c2ccc3oc4ccc(-n5c6ccccc6c6ccccc65)cc4c3c2)cc1 ; c1ccc2c(c1)c1ccccc1n2-c1cc(-n2c3ccccc3c3ccccc32)cc(-n2c3ccccc3c3ccccc32)c1 ; c1ccc([Si](c2ccccc2)(c2ccccc2)c2cc(-n3c4ccccc4c4ccccc43)cc(-n3c4ccccc4c4ccccc43)c2)cc1]

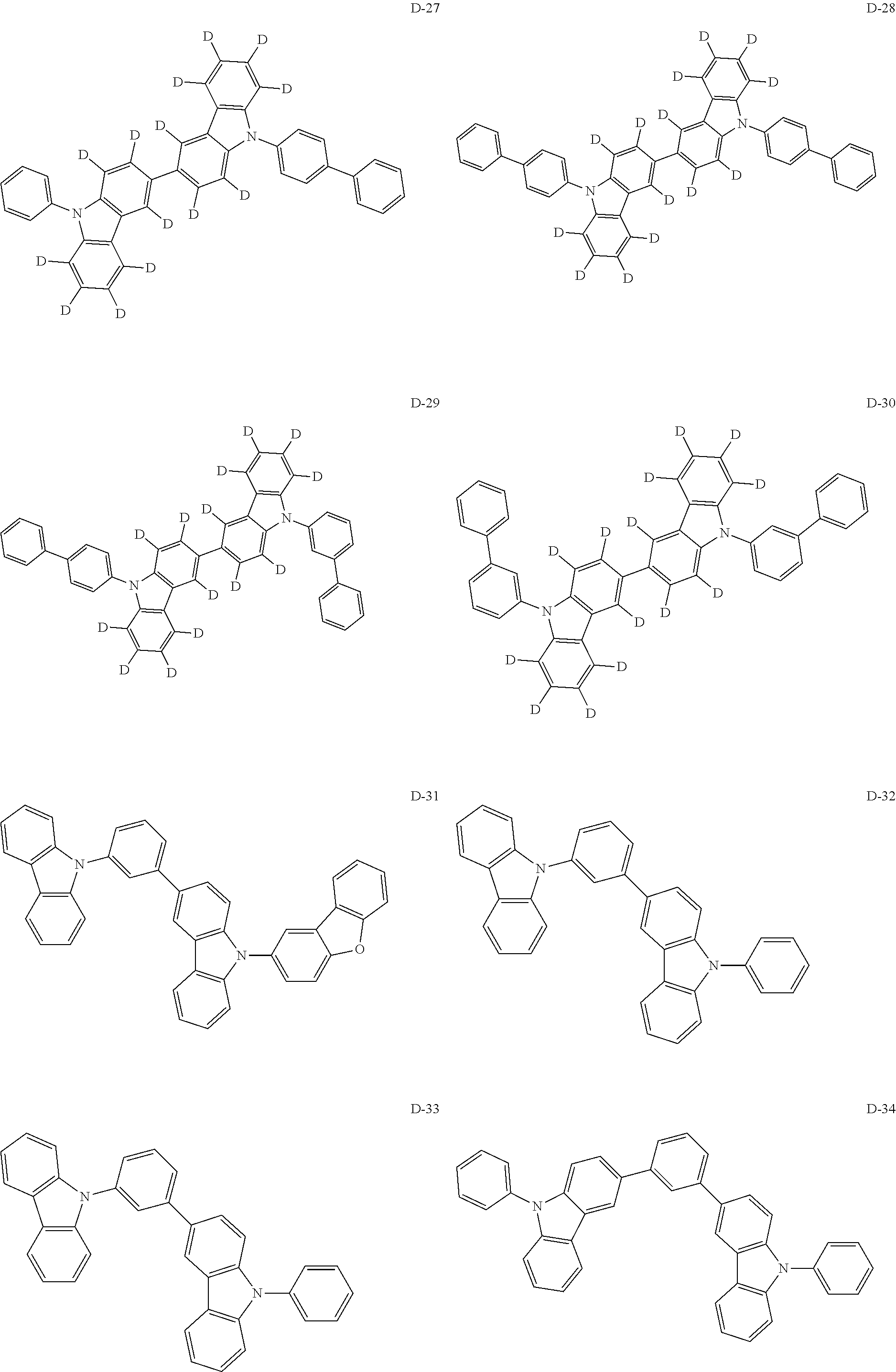

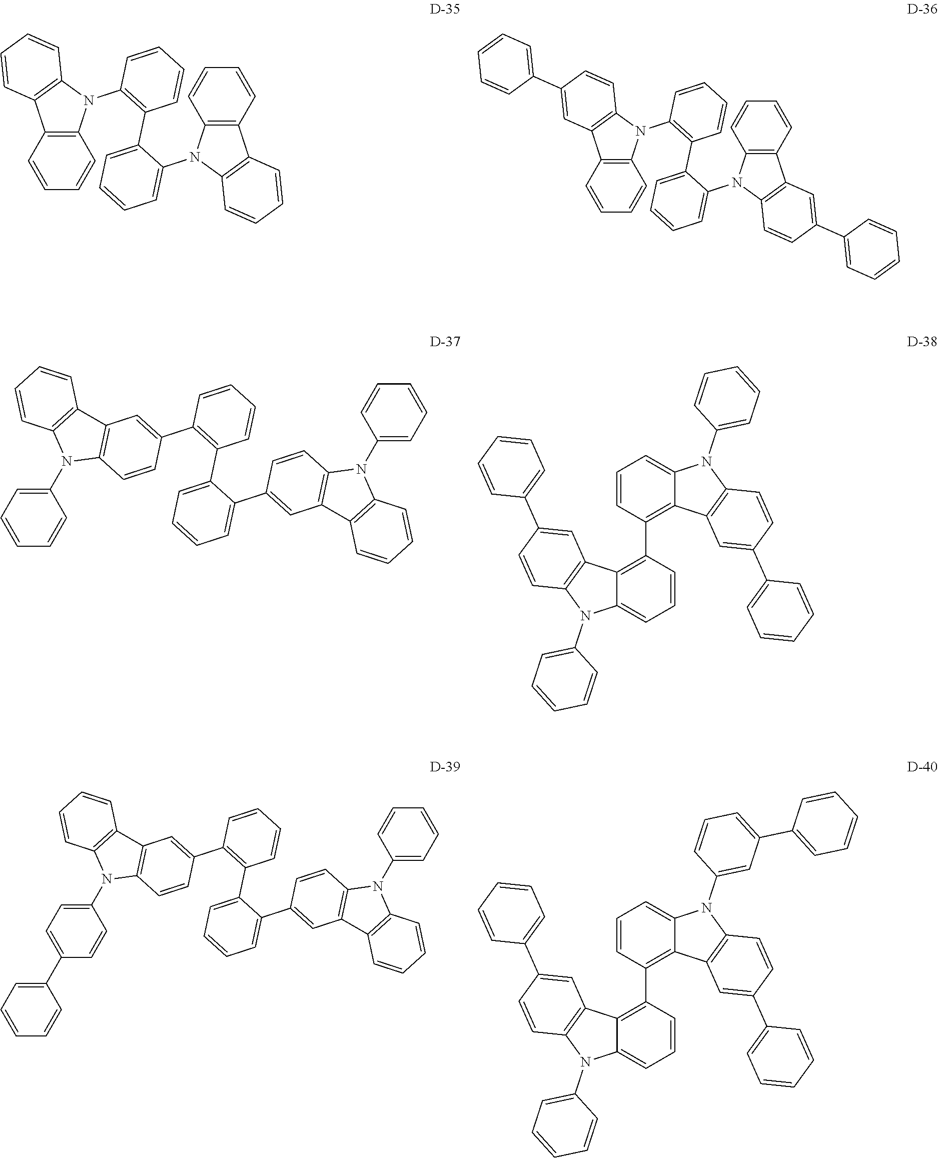

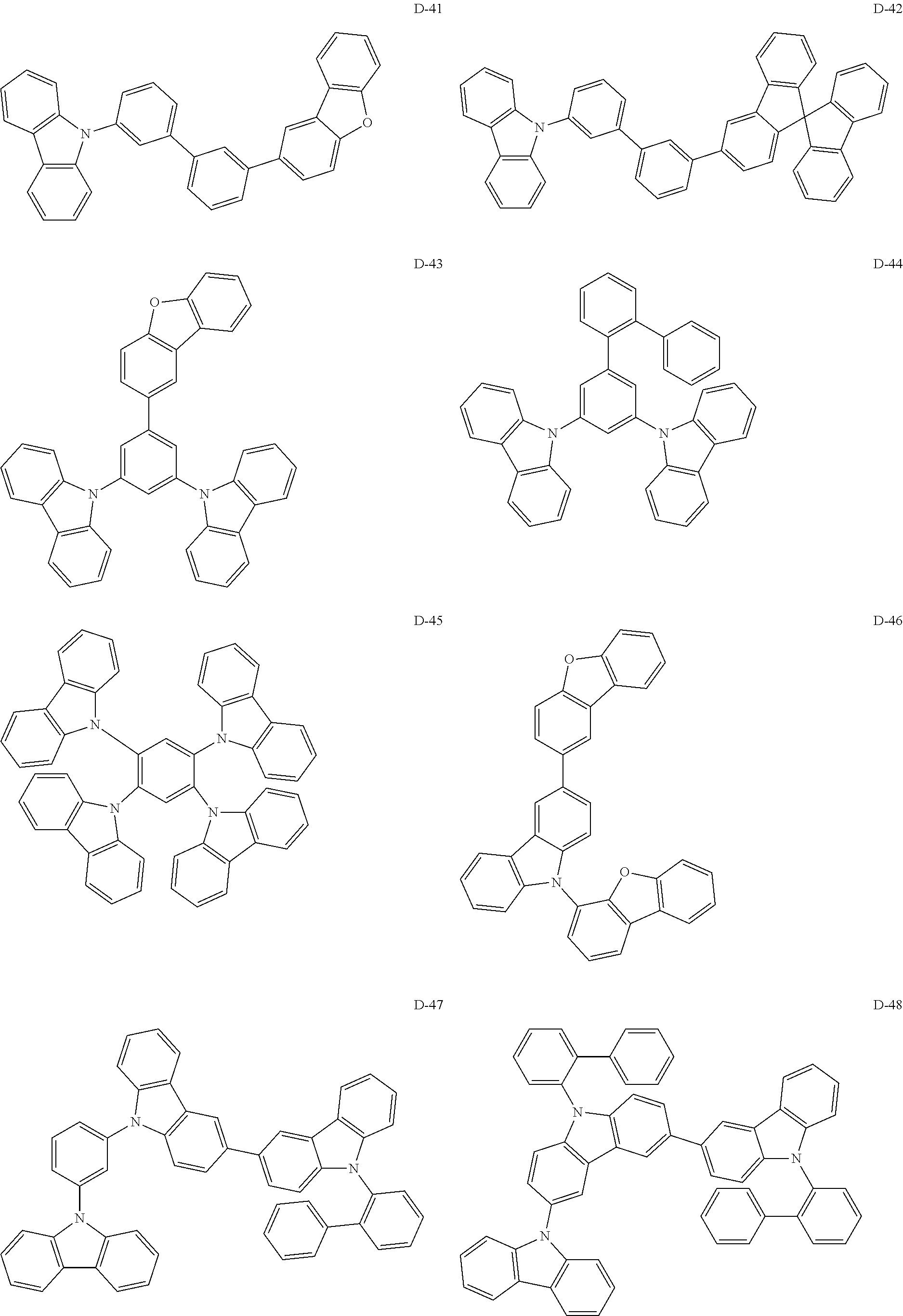

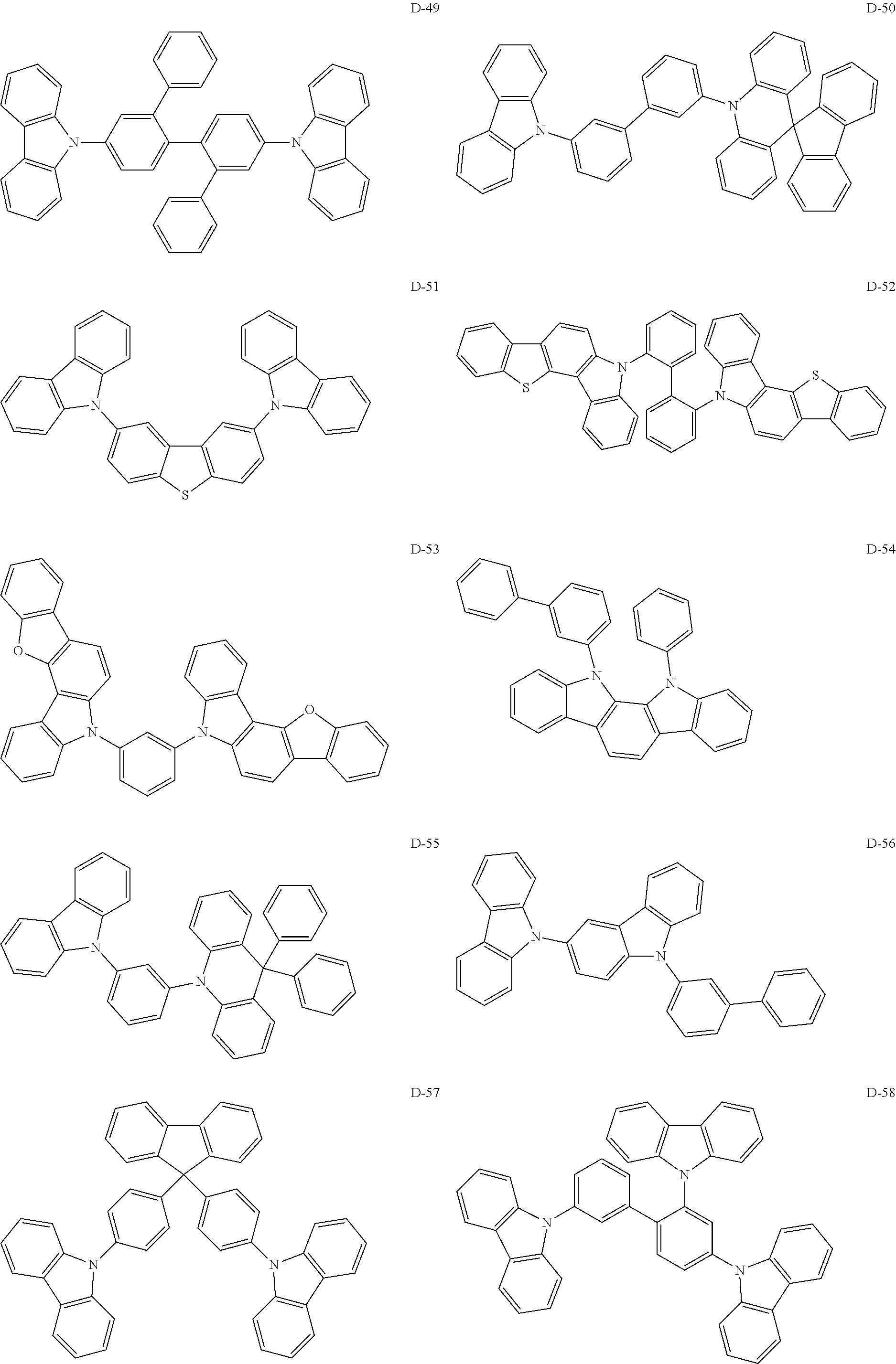

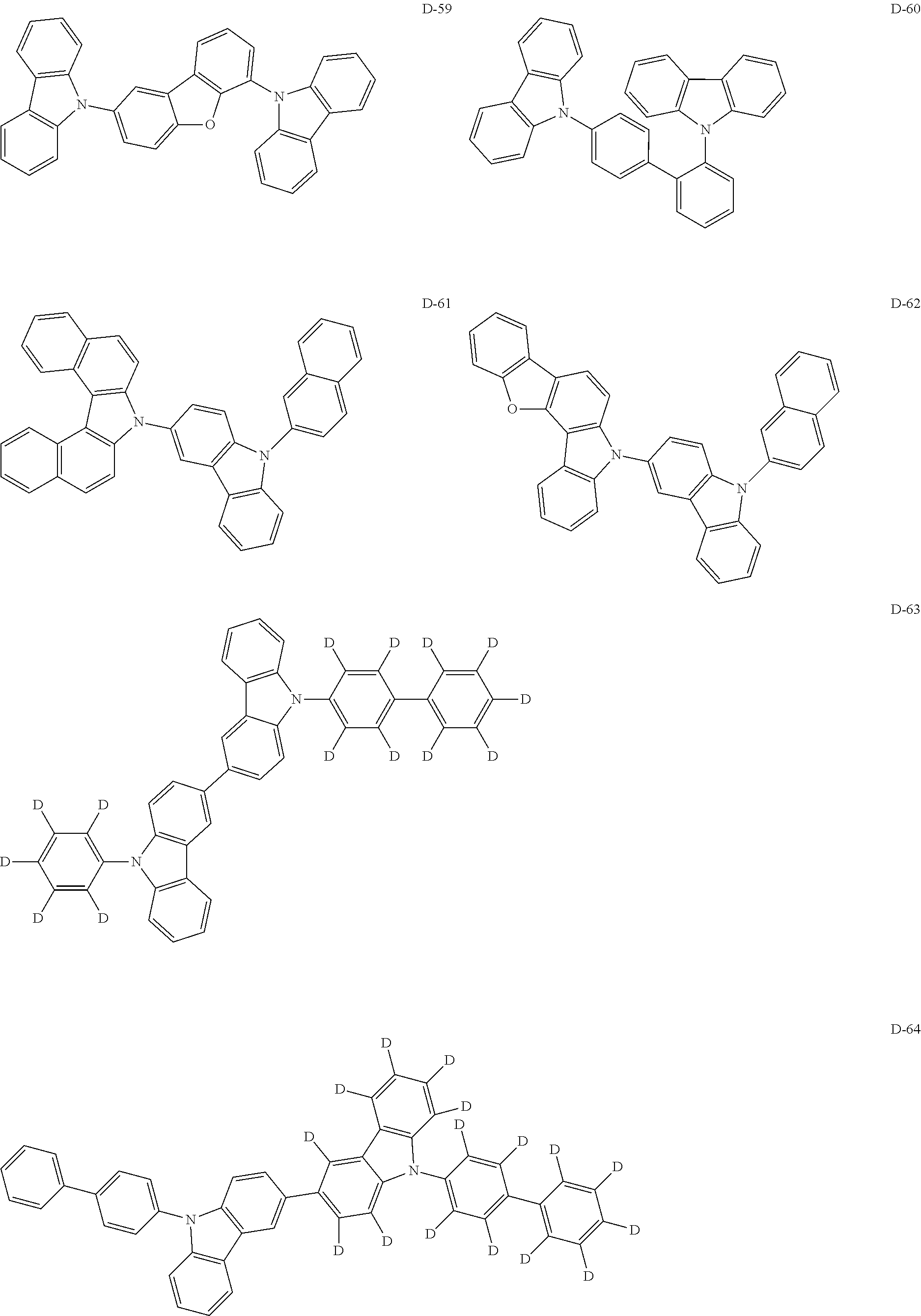

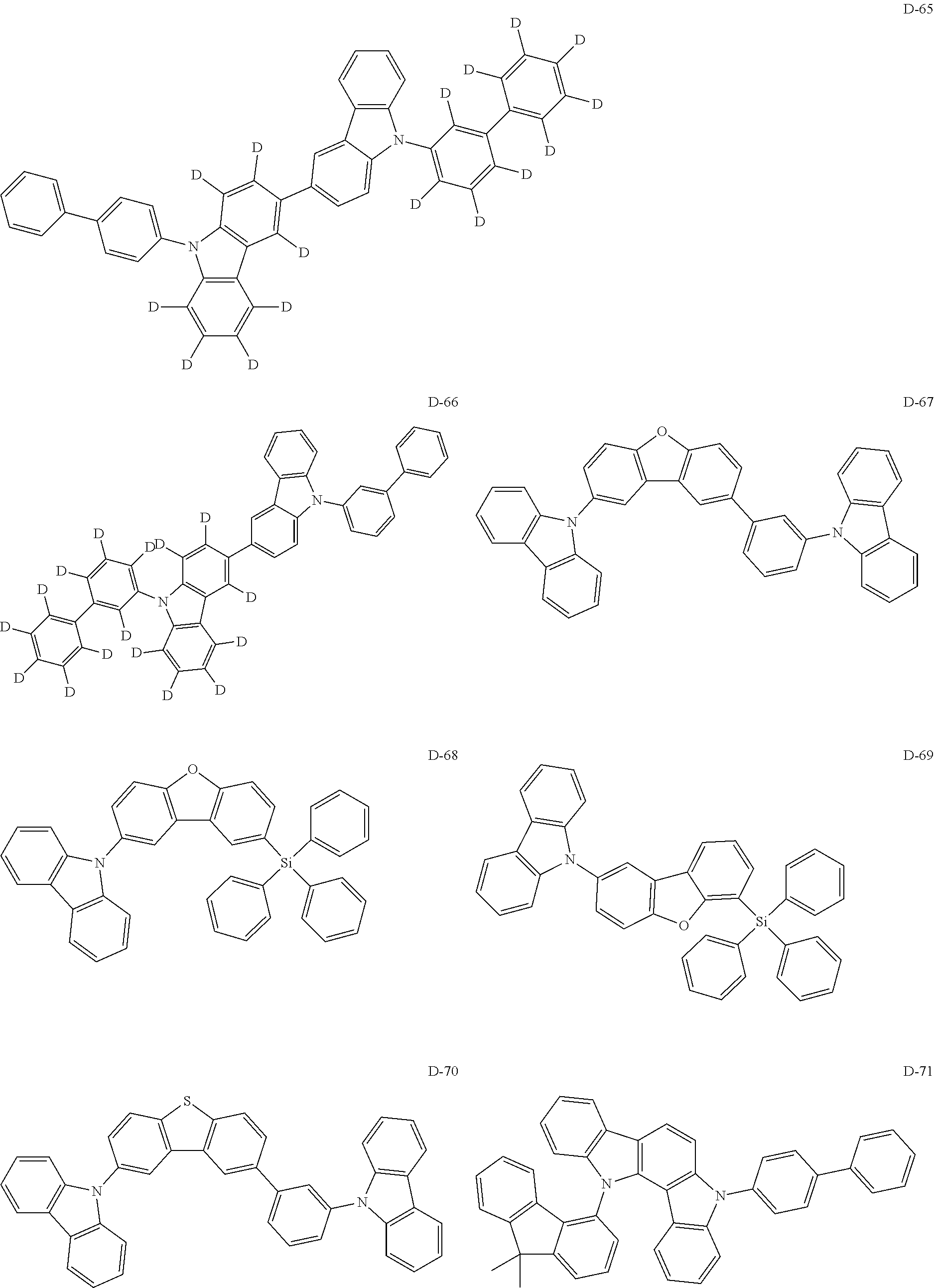

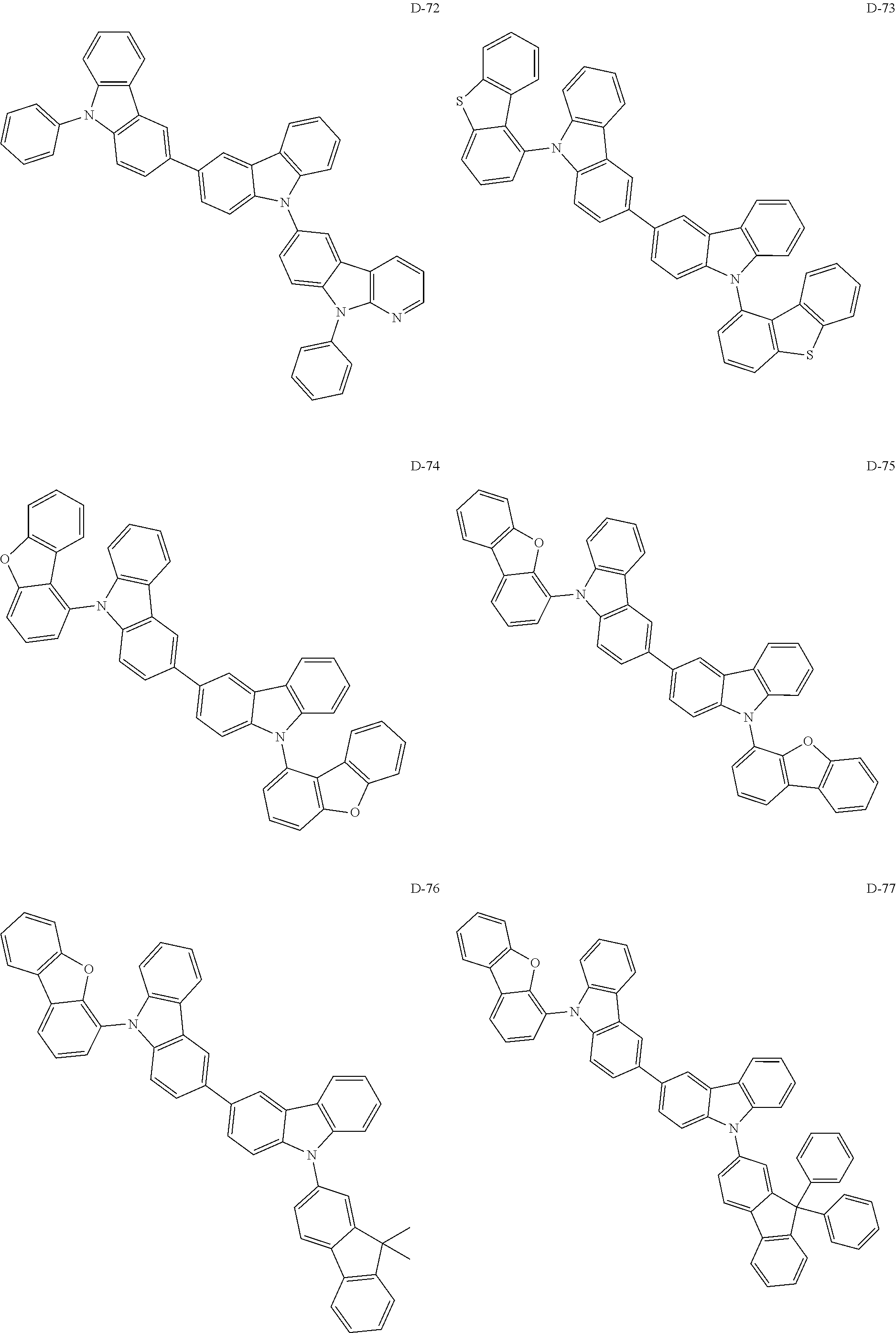

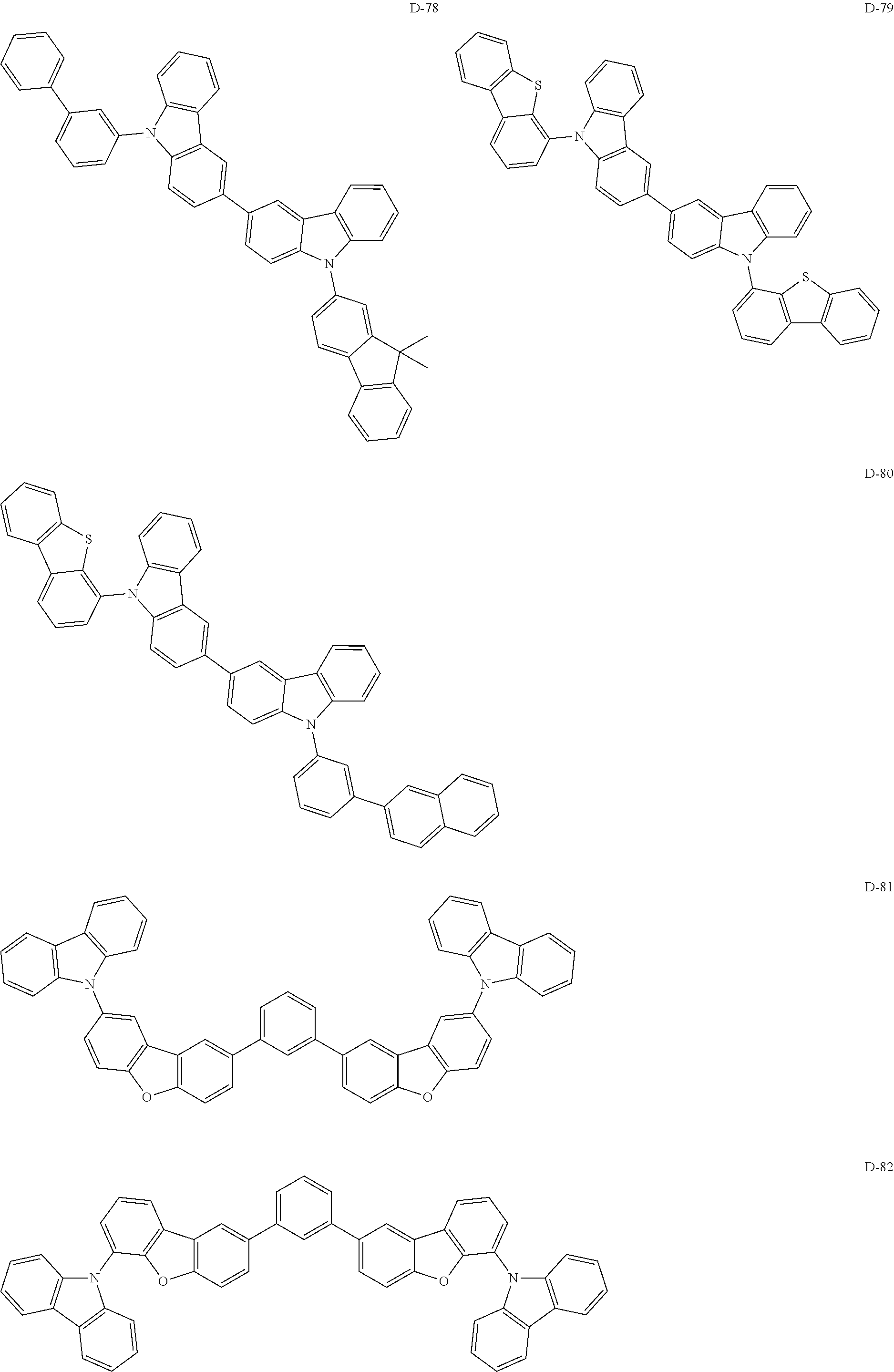 [SMILES: CC1(C)c2ccccc2-c2ccc(-n3c4ccccc4c4cc(-c5ccc6c(c5)c5ccccc5n6-c5cccc(-c6ccccc6)c5)ccc43)cc21 ; c1ccc2c(c1)sc1c(-n3c4ccccc4c4cc(-c5ccc6c(c5)c5ccccc5n6-c5cccc6c5sc5ccccc56)ccc43)cccc12 ; c1cc(-c2ccc3ccccc3c2)cc(-n2c3ccccc3c3cc(-c4ccc5c(c4)c4ccccc4n5-c4cccc5c4sc4ccccc45)ccc32)c1 ; c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1 ; c1cc(-c2ccc3oc4c(-n5c6ccccc6c6ccccc65)cccc4c3c2)cc(-c2ccc3oc4c(-n5c6ccccc6c6ccccc65)cccc4c3c2)c1]

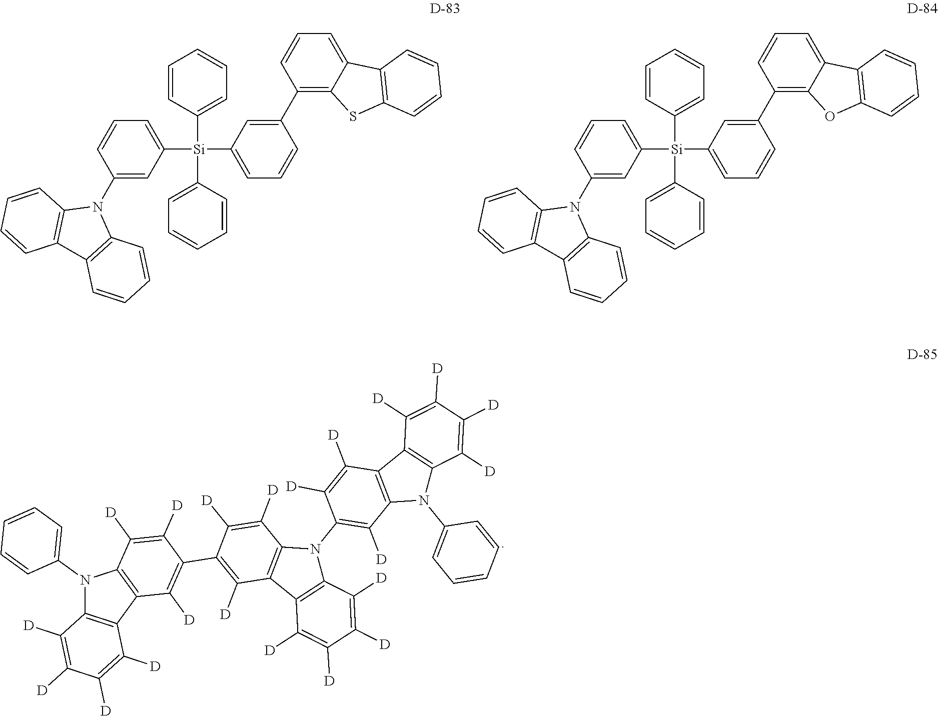 [SMILES: c1ccc([Si](c2ccccc2)(c2cccc(-c3cccc4c3sc3ccccc34)c2)c2cccc(-n3c4ccccc4c4ccccc43)c2)cc1 ; c1ccc([Si](c2ccccc2)(c2cccc(-c3cccc4c3oc3ccccc34)c2)c2cccc(-n3c4ccccc4c4ccccc43)c2)cc1 ; [2H]c1c([2H])c([2H])c2c(c1[2H])c1c([2H])c(-c3c([2H])c([2H])c4c(c3[2H])c3c([2H])c([2H])c([2H])c([2H])c3n4-c3c([2H])c([2H])c4c5c([2H])c([2H])c([2H])c([2H])c5n(-c5ccccc5)c4c3[2H])c([2H])c([2H])c1n2-c1ccccc1]

12. The organic light-emitting diode according to claim 4, wherein the second host material comprises a structural unit represented by Formula 2: 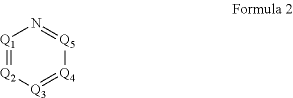
wherein Q1 to Q5 are each independently selected from nitrogen or C—R₀₁₁, and R₀₁₁ is independently selected from one of deuterium, substituted or unsubstituted C1-C20 alkyl, substituted or unsubstituted C3-C20 cycloalkyl, substituted or unsubstituted C2-C20 alkenyl, substituted or unsubstituted C1-C20 silanyl, substituted or unsubstituted C6-C60 arylsilyl, substituted or unsubstituted C6-C30 arylamino, substituted or unsubstituted C7-C30 aralkyl, substituted or unsubstituted C3-C30 heteroarylamino, substituted or unsubstituted C6-C60 aryl, and substituted or unsubstituted C3-C60 heteroaryl; and adjacent R₀₁₁ are linked or not linked.

13. The organic light-emitting diode according to claim 12, wherein the second host material comprises one or more of the following compounds A1 to A86:

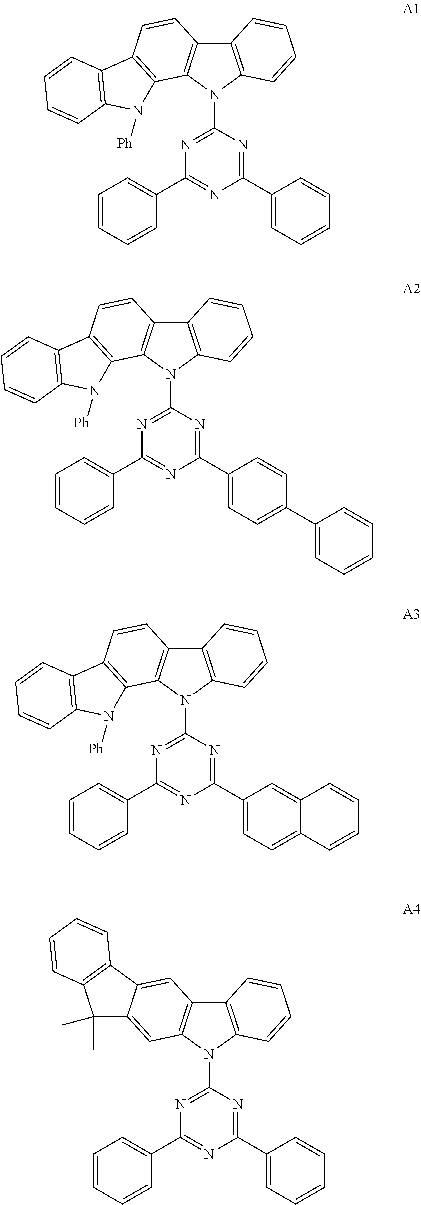 [SMILES: c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-c2nc(-c3ccc4ccccc4c3)nc(-n3c4ccccc4c4ccc5c6ccccc6n(-c6ccccc6)c5c43)n2)cc1 ; CC1(C)c2ccccc2-c2cc3c4ccccc4n(-c4nc(-c5ccccc5)nc(-c5ccccc5)n4)c3cc21]

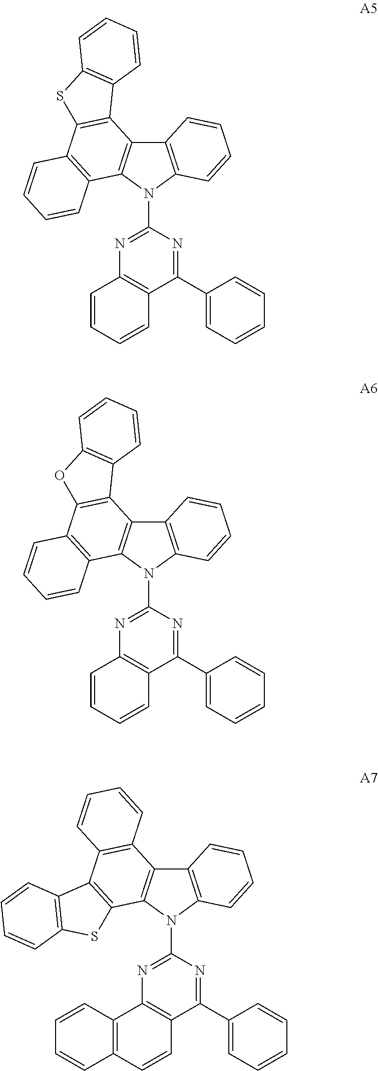 [SMILES: c1ccc(-c2nc(-n3c4ccccc4c4c5c6ccccc6sc5c5ccccc5c43)nc3ccccc23)cc1 ; c1ccc(-c2nc(-n3c4ccccc4c4c5c6ccccc6oc5c5ccccc5c43)nc3ccccc23)cc1 ; c1ccc(-c2nc(-n3c4ccccc4c4c5ccccc5c5c6ccccc6sc5c43)nc3c2ccc2ccccc23)cc1]

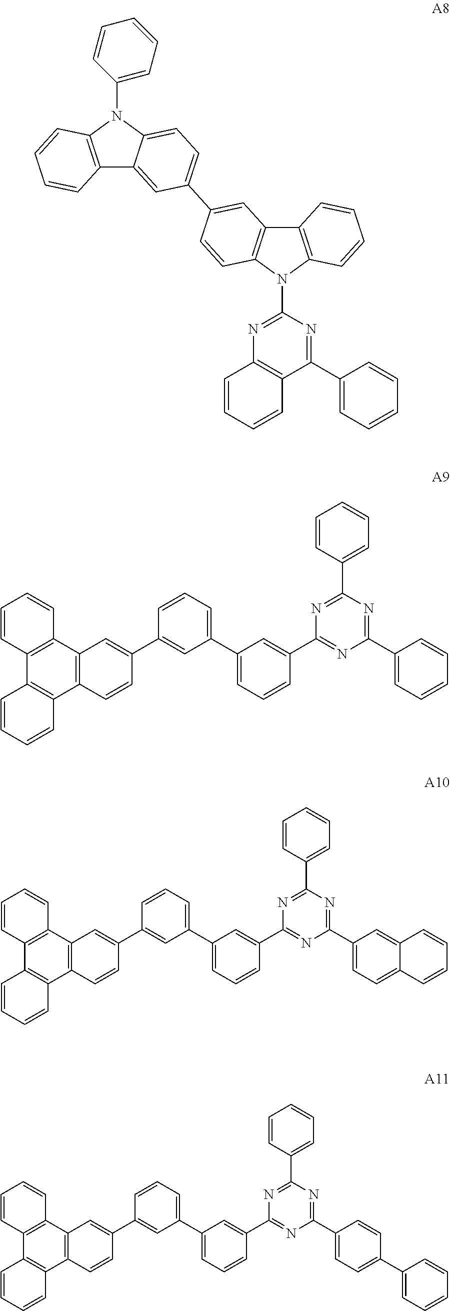 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3cccc(-c4cccc(-c5ccc6c7ccccc7c7ccccc7c6c5)c4)c3)nc(-c3ccc4ccccc4c3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1]

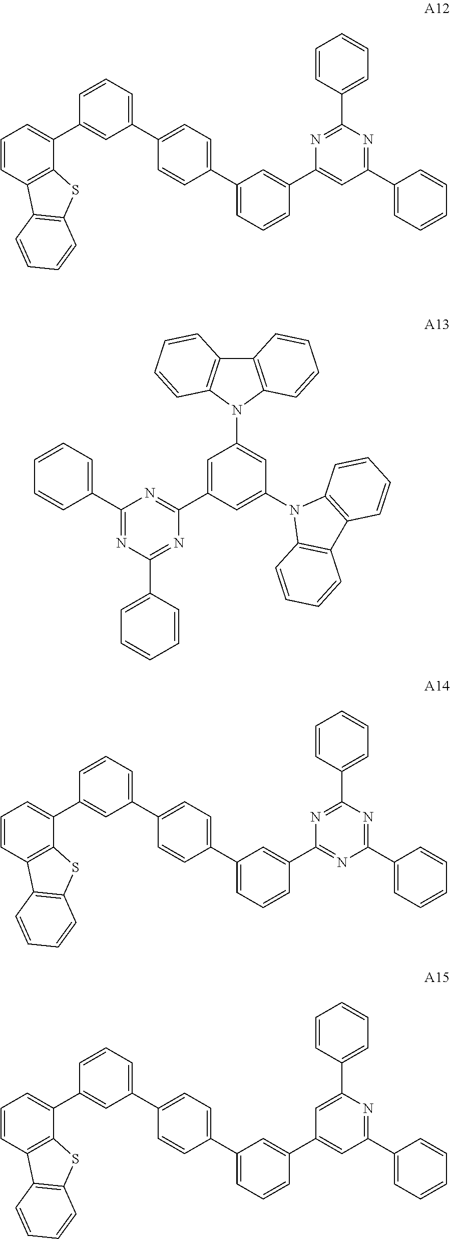 [SMILES: c1ccc(-c2cc(-c3cccc(-c4ccc(-c5cccc(-c6cccc7c6sc6ccccc67)c5)cc4)c3)nc(-c3ccccc3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1ccc(-c2nc(-c3ccccc3)nc(-c3cccc(-c4ccc(-c5cccc(-c6cccc7c6sc6ccccc67)c5)cc4)c3)n2)cc1 ; c1ccc(-c2cc(-c3cccc(-c4ccc(-c5cccc(-c6cccc7c6sc6ccccc67)c5)cc4)c3)cc(-c3ccccc3)n2)cc1]

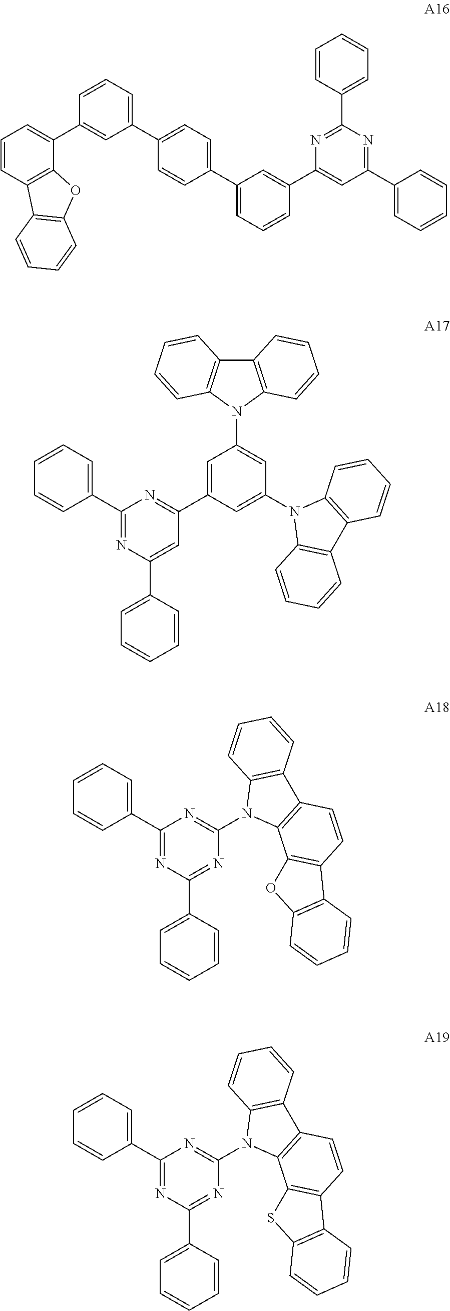 [SMILES: c1ccc(-c2cc(-c3cccc(-c4ccc(-c5cccc(-c6cccc7c6oc6ccccc67)c5)cc4)c3)nc(-c3ccccc3)n2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2nc(-c3ccccc3)nc(-n3c4ccccc4c4ccc5c6ccccc6oc5c43)n2)cc1 ; c1ccc(-c2nc(-c3ccccc3)nc(-n3c4ccccc4c4ccc5c6ccccc6sc5c43)n2)cc1]

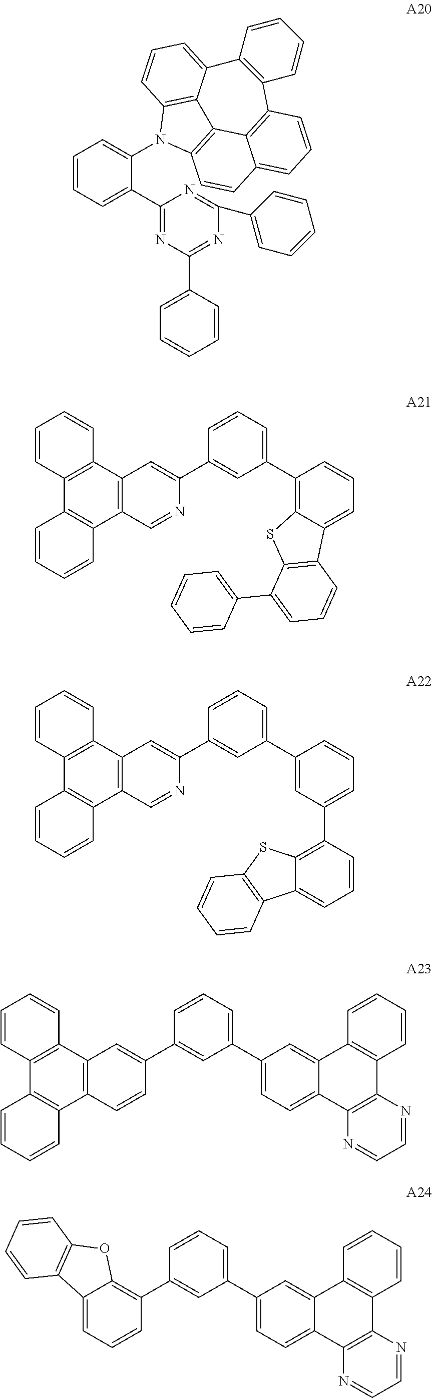 [SMILES: c1ccc(-c2nc(-c3ccccc3)nc(-c3ccccc3-n3c4cccc5c4c4c6c(cccc6ccc43)-c3ccccc3-5)n2)cc1 ; c1ccc(-c2cccc3c2sc2c(-c4cccc(-c5cc6c7ccccc7c7ccccc7c6cn5)c4)cccc23)cc1 ; c1cc(-c2cccc(-c3cccc4c3sc3ccccc34)c2)cc(-c2cc3c4ccccc4c4ccccc4c3cn2)c1 ; c1cc(-c2ccc3c4ccccc4c4ccccc4c3c2)cc(-c2ccc3c(c2)c2ccccc2c2nccnc32)c1 ; c1cc(-c2ccc3c(c2)c2ccccc2c2nccnc32)cc(-c2cccc3c2oc2ccccc23)c1]

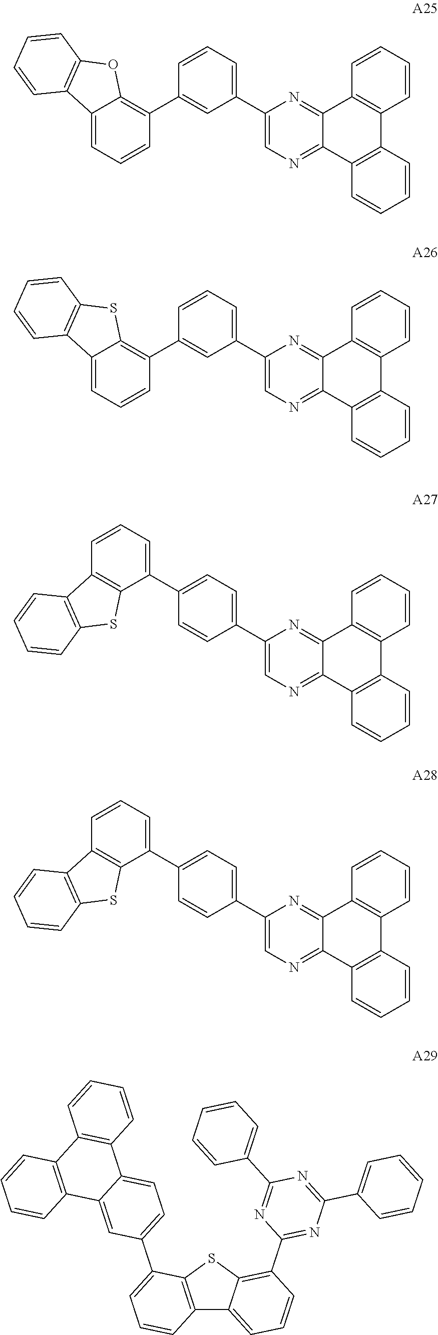 [SMILES: c1cc(-c2cnc3c4ccccc4c4ccccc4c3n2)cc(-c2cccc3c2oc2ccccc23)c1 ; c1cc(-c2cnc3c4ccccc4c4ccccc4c3n2)cc(-c2cccc3c2sc2ccccc23)c1 ; c1ccc2c(c1)sc1c(-c3ccc(-c4cnc5c6ccccc6c6ccccc6c5n4)cc3)cccc12 ; c1ccc2c(c1)sc1c(-c3ccc(-c4cnc5c6ccccc6c6ccccc6c5n4)cc3)cccc12 ; c1ccc(-c2nc(-c3ccccc3)nc(-c3cccc4c3sc3c(-c5ccc6c7ccccc7c7ccccc7c6c5)cccc34)n2)cc1]

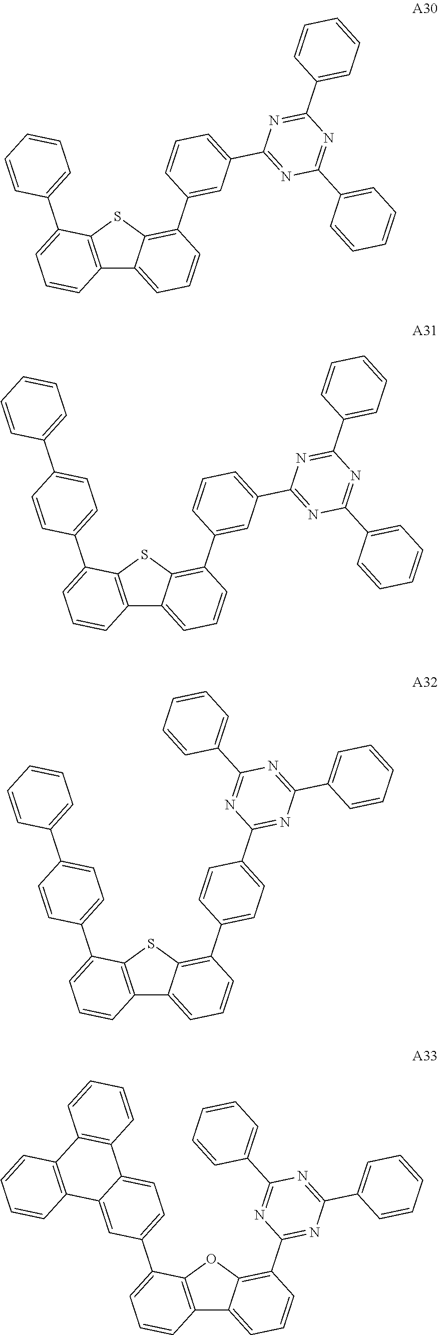 [SMILES: c1ccc(-c2nc(-c3ccccc3)nc(-c3cccc(-c4cccc5c4sc4c(-c6ccccc6)cccc45)c3)n2)cc1 ; c1ccc(-c2ccc(-c3cccc4c3sc3c(-c5cccc(-c6nc(-c7ccccc7)nc(-c7ccccc7)n6)c5)cccc34)cc2)cc1 ; c1ccc(-c2ccc(-c3cccc4c3sc3c(-c5ccc(-c6nc(-c7ccccc7)nc(-c7ccccc7)n6)cc5)cccc34)cc2)cc1 ; c1ccc(-c2nc(-c3ccccc3)nc(-c3cccc4c3oc3c(-c5ccc6c7ccccc7c7ccccc7c6c5)cccc34)n2)cc1]

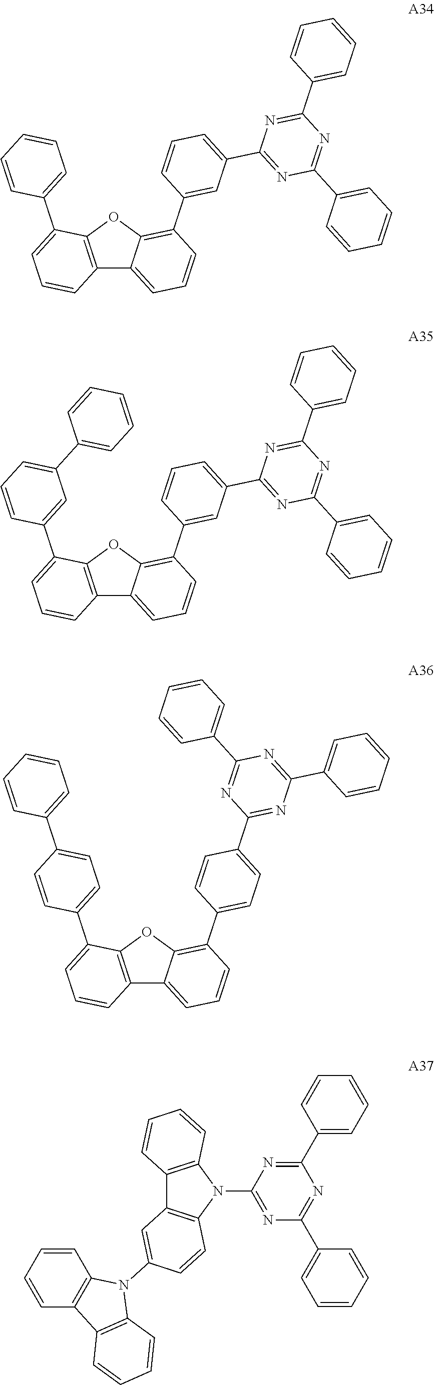 [SMILES: c1ccc(-c2nc(-c3ccccc3)nc(-c3cccc(-c4cccc5c4oc4c(-c6ccccc6)cccc45)c3)n2)cc1 ; c1ccc(-c2cccc(-c3cccc4c3oc3c(-c5cccc(-c6nc(-c7ccccc7)nc(-c7ccccc7)n6)c5)cccc34)c2)cc1 ; c1ccc(-c2ccc(-c3cccc4c3oc3c(-c5ccc(-c6nc(-c7ccccc7)nc(-c7ccccc7)n6)cc5)cccc34)cc2)cc1 ; c1ccc(-c2nc(-c3ccccc3)nc(-n3c4ccccc4c4cc(-n5c6ccccc6c6ccccc65)ccc43)n2)cc1]

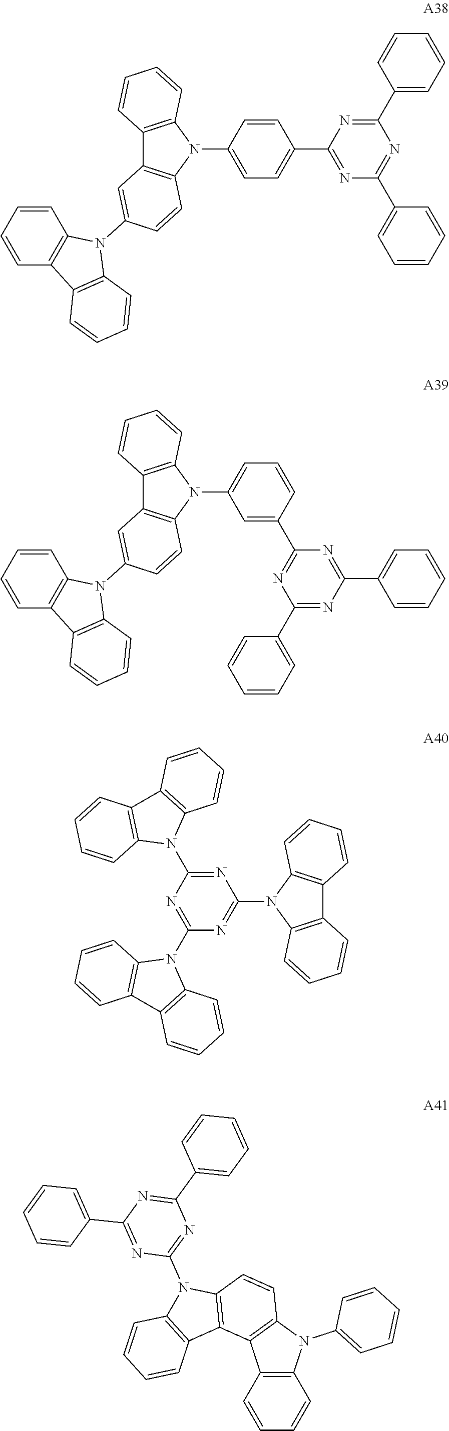 [SMILES: c1ccc(-c2nc(-c3ccccc3)nc(-c3ccc(-n4c5ccccc5c5cc(-n6c7ccccc7c7ccccc76)ccc54)cc3)n2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc2c(c1)c1ccccc1n2-c1nc(-n2c3ccccc3c3ccccc32)nc(-n2c3ccccc3c3ccccc32)n1 ; c1ccc(-c2nc(-c3ccccc3)nc(-n3c4ccccc4c4c5c6ccccc6n(-c6ccccc6)c5ccc43)n2)cc1]

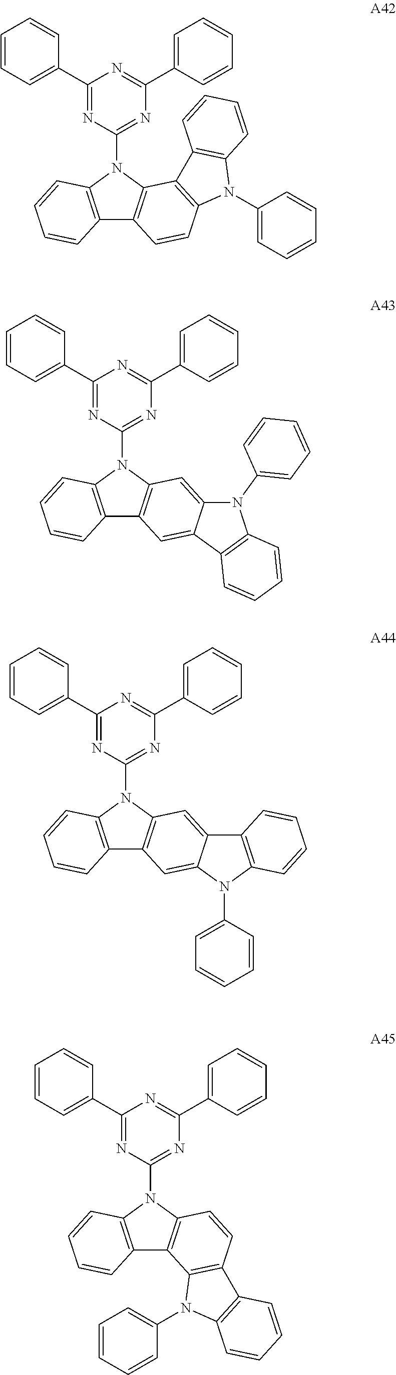 [SMILES: c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-n3c4ccccc4c4cc5c(cc43)c3ccccc3n5-c3ccccc3)n2)cc1 ; c1ccc(-c2nc(-c3ccccc3)nc(-n3c4ccccc4c4c3ccc3c5ccccc5n(-c5ccccc5)c34)n2)cc1]

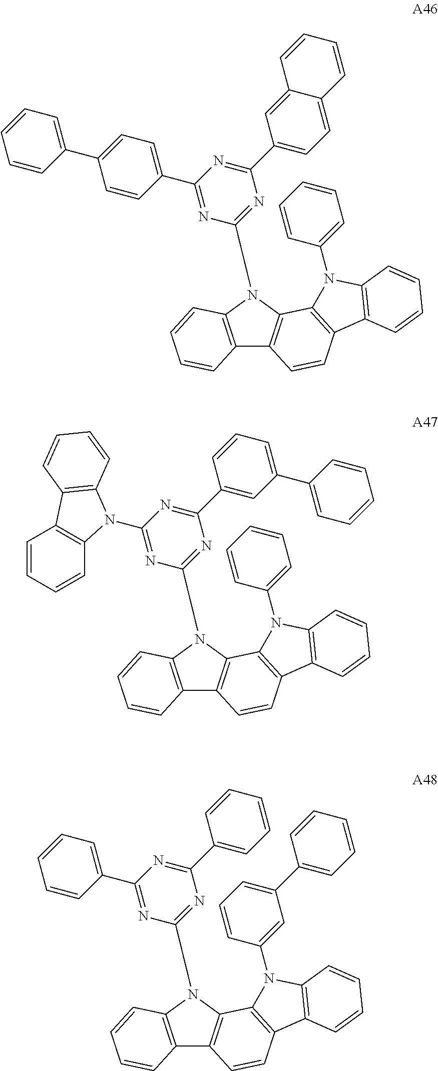 [SMILES: c1ccc(-c2ccc(-c3nc(-c4ccc5ccccc5c4)nc(-n4c5ccccc5c5ccc6c7ccccc7n(-c7ccccc7)c6c54)n3)cc2)cc1 ; c1ccc(-c2cccc(-c3nc(-n4c5ccccc5c5ccccc54)nc(-n4c5ccccc5c5ccc6c7ccccc7n(-c7ccccc7)c6c54)n3)c2)cc1 ; c1ccc(-c2cccc(-n3c4ccccc4c4ccc5c6ccccc6n(-c6nc(-c7ccccc7)nc(-c7ccccc7)n6)c5c43)c2)cc1]

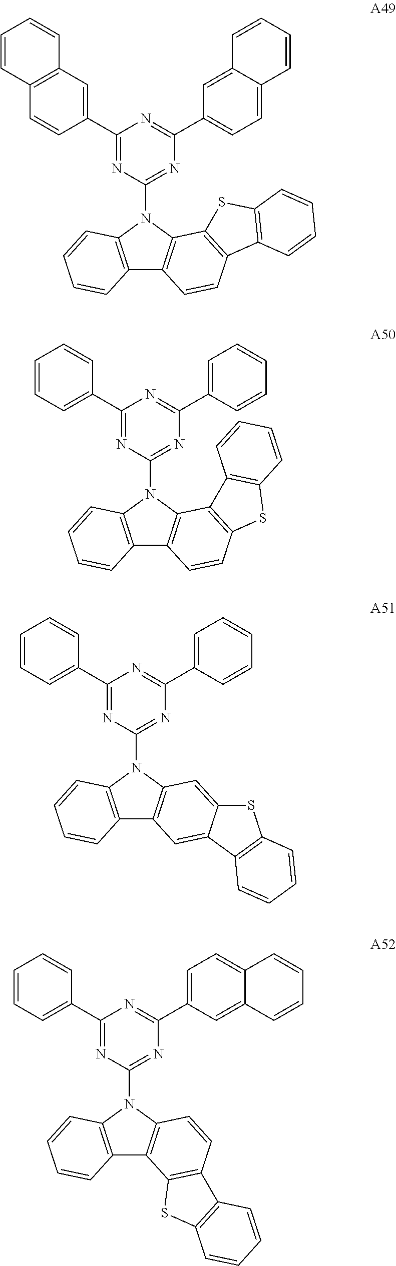 [SMILES: c1ccc2cc(-c3nc(-c4ccc5ccccc5c4)nc(-n4c5ccccc5c5ccc6c7ccccc7sc6c54)n3)ccc2c1 ; c1ccc(-c2nc(-c3ccccc3)nc(-n3c4ccccc4c4ccc5sc6ccccc6c5c43)n2)cc1 ; c1ccc(-c2nc(-c3ccccc3)nc(-n3c4ccccc4c4cc5c(cc43)sc3ccccc35)n2)cc1 ; c1ccc(-c2nc(-c3ccc4ccccc4c3)nc(-n3c4ccccc4c4c5sc6ccccc6c5ccc43)n2)cc1]

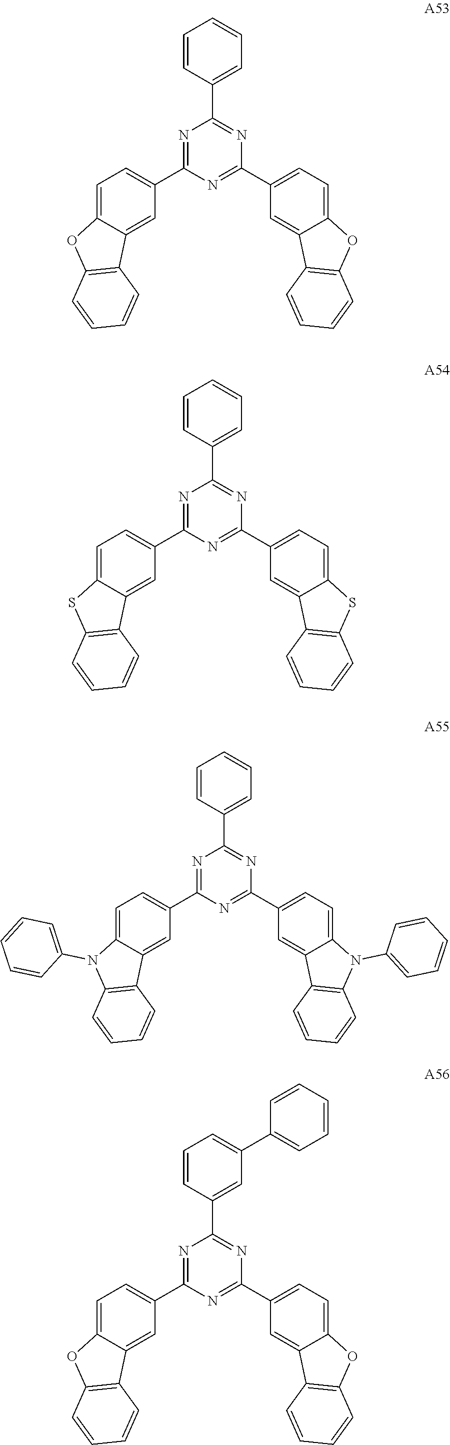

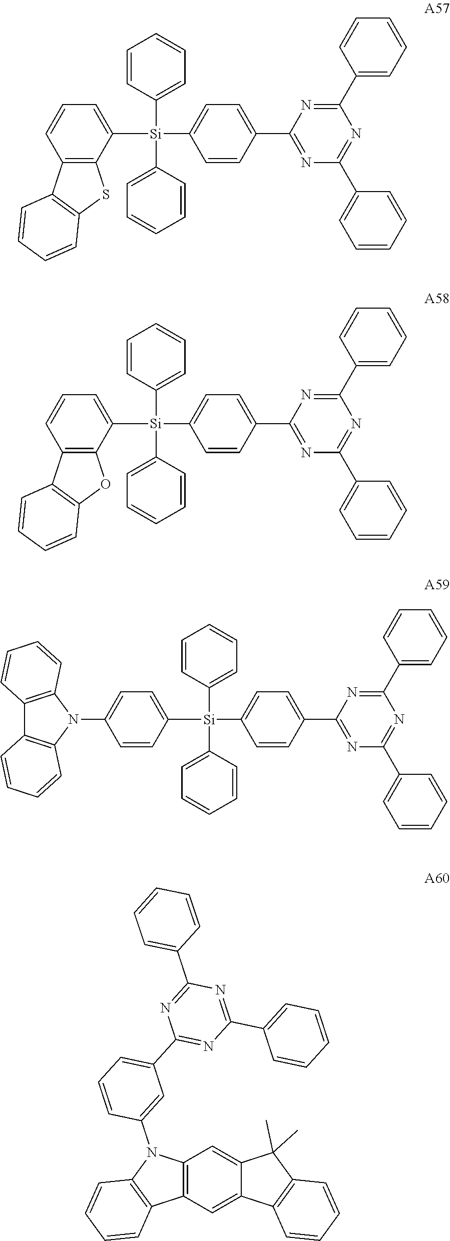 [SMILES: c1ccc(-c2nc(-c3ccccc3)nc(-c3ccc([Si](c4ccccc4)(c4ccccc4)c4cccc5c4sc4ccccc45)cc3)n2)cc1 ; c1ccc(-c2nc(-c3ccccc3)nc(-c3ccc([Si](c4ccccc4)(c4ccccc4)c4cccc5c4oc4ccccc45)cc3)n2)cc1 ; c1ccc(-c2nc(-c3ccccc3)nc(-c3ccc([Si](c4ccccc4)(c4ccccc4)c4ccc(-n5c6ccccc6c6ccccc65)cc4)cc3)n2)cc1 ; CC1(C)c2ccccc2-c2cc3c4ccccc4n(-c4cccc(-c5nc(-c6ccccc6)nc(-c6ccccc6)n5)c4)c3cc21]

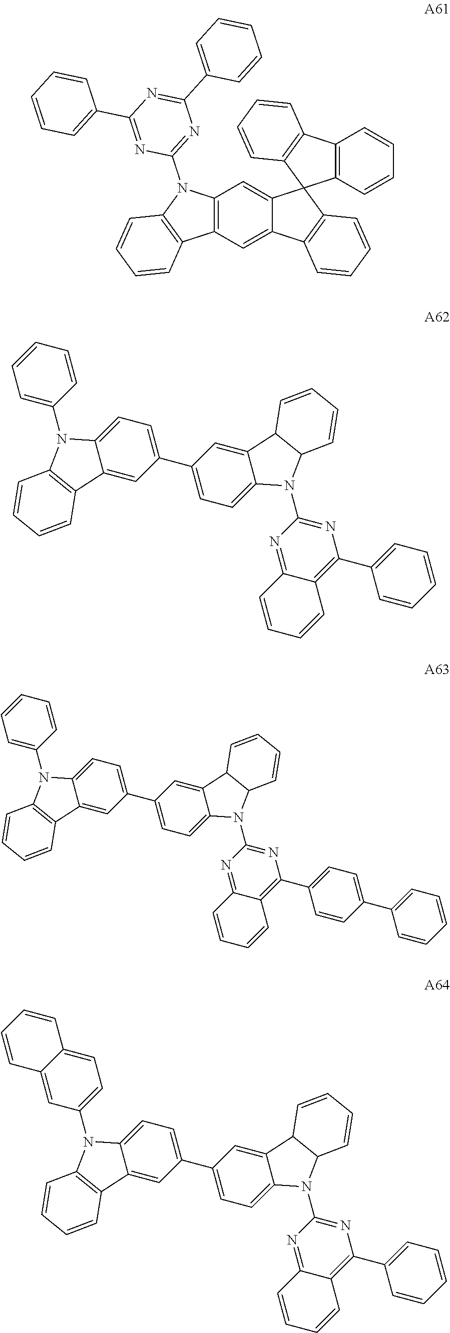 [SMILES: c1ccc(-c2nc(-c3ccccc3)nc(-n3c4ccccc4c4cc5c(cc43)C3(c4ccccc4-c4ccccc43)c3ccccc3-5)n2)cc1 ; C1=CC2c3cc(-c4ccc5c(c4)c4ccccc4n5-c4ccccc4)ccc3N(c3nc(-c4ccccc4)c4ccccc4n3)C2C=C1 ; C1=CC2c3cc(-c4ccc5c(c4)c4ccccc4n5-c4ccccc4)ccc3N(c3nc(-c4ccc(-c5ccccc5)cc4)c4ccccc4n3)C2C=C1 ; C1=CC2c3cc(-c4ccc5c(c4)c4ccccc4n5-c4ccc5ccccc5c4)ccc3N(c3nc(-c4ccccc4)c4ccccc4n3)C2C=C1]

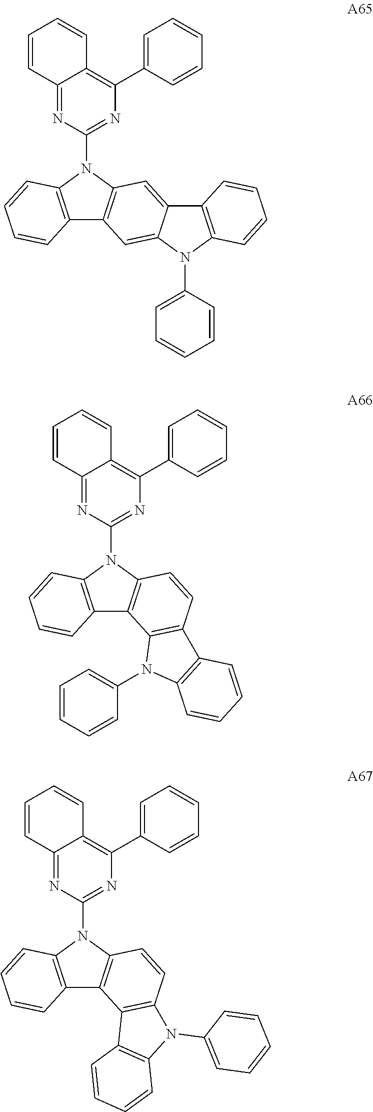 [SMILES: c1ccc(-c2nc(-n3c4ccccc4c4cc5c(cc43)c3ccccc3n5-c3ccccc3)nc3ccccc23)cc1 ; c1ccc(-c2nc(-n3c4ccccc4c4c3ccc3c5ccccc5n(-c5ccccc5)c34)nc3ccccc23)cc1 ; c1ccc(-c2nc(-n3c4ccccc4c4c5c6ccccc6n(-c6ccccc6)c5ccc43)nc3ccccc23)cc1]

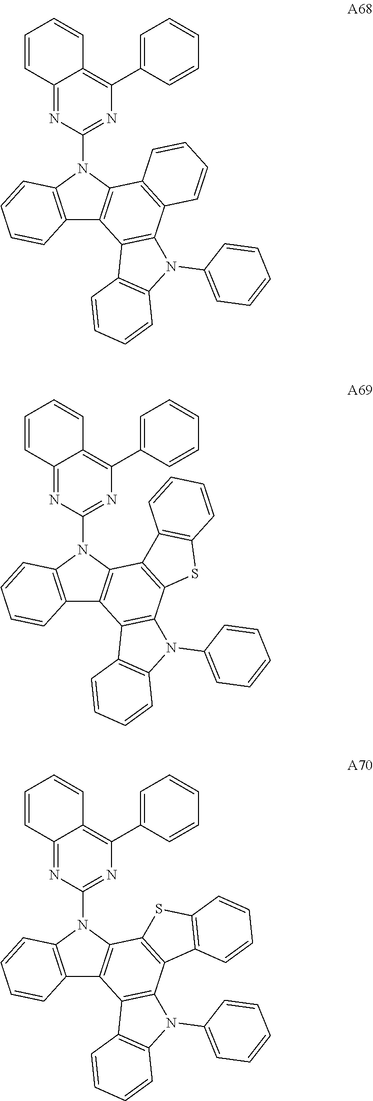 [SMILES: c1ccc(-c2nc(-n3c4ccccc4c4c5c6ccccc6n(-c6ccccc6)c5c5ccccc5c43)nc3ccccc23)cc1 ; c1ccc(-c2nc(-n3c4ccccc4c4c5c6ccccc6n(-c6ccccc6)c5c5sc6ccccc6c5c43)nc3ccccc23)cc1 ; c1ccc(-c2nc(-n3c4ccccc4c4c5c6ccccc6n(-c6ccccc6)c5c5c6ccccc6sc5c43)nc3ccccc23)cc1]

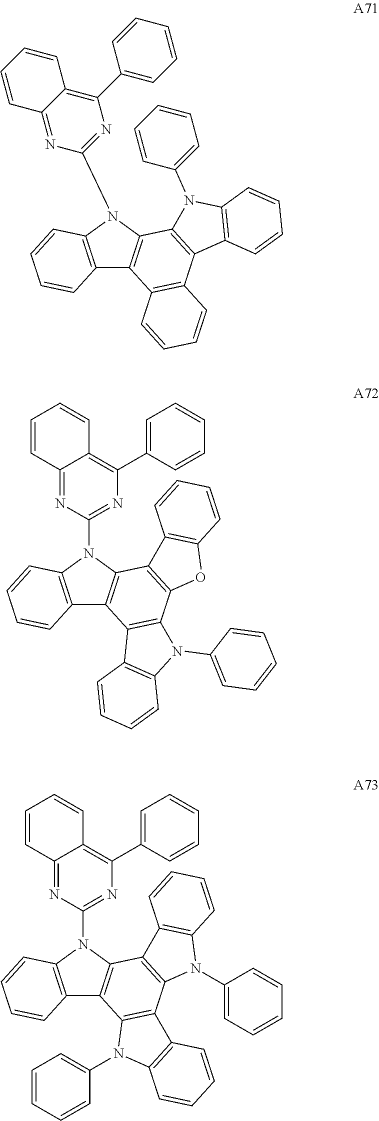 [SMILES: c1ccc(-c2nc(-n3c4ccccc4c4c5ccccc5c5c6ccccc6n(-c6ccccc6)c5c43)nc3ccccc23)cc1 ; c1ccc(-c2nc(-n3c4ccccc4c4c5c6ccccc6n(-c6ccccc6)c5c5oc6ccccc6c5c43)nc3ccccc23)cc1 ; c1ccc(-c2nc(-n3c4ccccc4c4c5c(c6ccccc6n5-c5ccccc5)c5c(c6ccccc6n5-c5ccccc5)c43)nc3ccccc23)cc1]

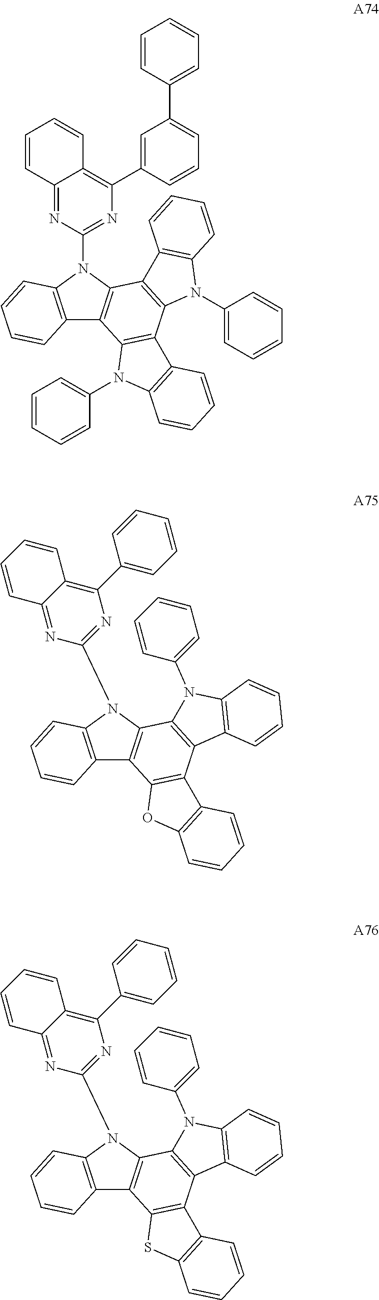 [SMILES: c1ccc(-c2cccc(-c3nc(-n4c5ccccc5c5c6c(c7ccccc7n6-c6ccccc6)c6c(c7ccccc7n6-c6ccccc6)c54)nc4ccccc34)c2)cc1 ; c1ccc(-c2nc(-n3c4ccccc4c4c5oc6ccccc6c5c5c6ccccc6n(-c6ccccc6)c5c43)nc3ccccc23)cc1 ; c1ccc(-c2nc(-n3c4ccccc4c4c5sc6ccccc6c5c5c6ccccc6n(-c6ccccc6)c5c43)nc3ccccc23)cc1]

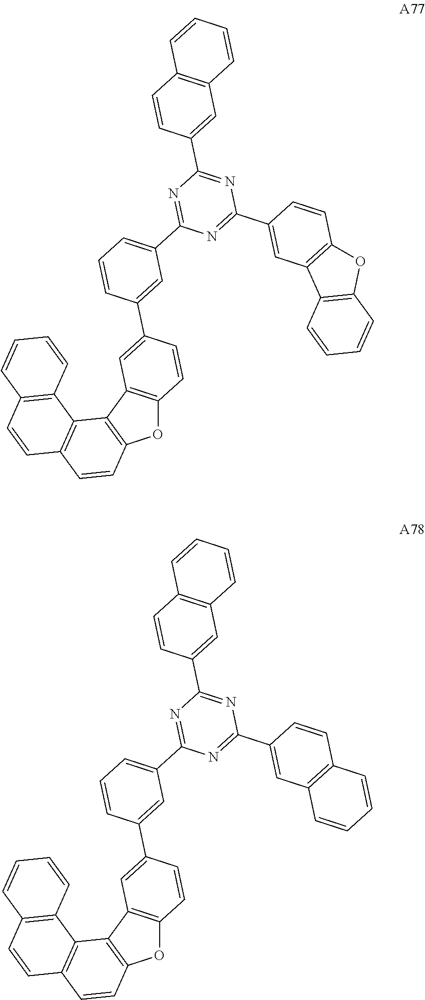 [SMILES: c1cc(-c2ccc3oc4ccc5ccc6ccccc6c5c4c3c2)cc(-c2nc(-c3ccc4ccccc4c3)nc(-c3ccc4oc5ccccc5c4c3)n2)c1 ; c1cc(-c2ccc3oc4ccc5ccc6ccccc6c5c4c3c2)cc(-c2nc(-c3ccc4ccccc4c3)nc(-c3ccc4ccccc4c3)n2)c1]

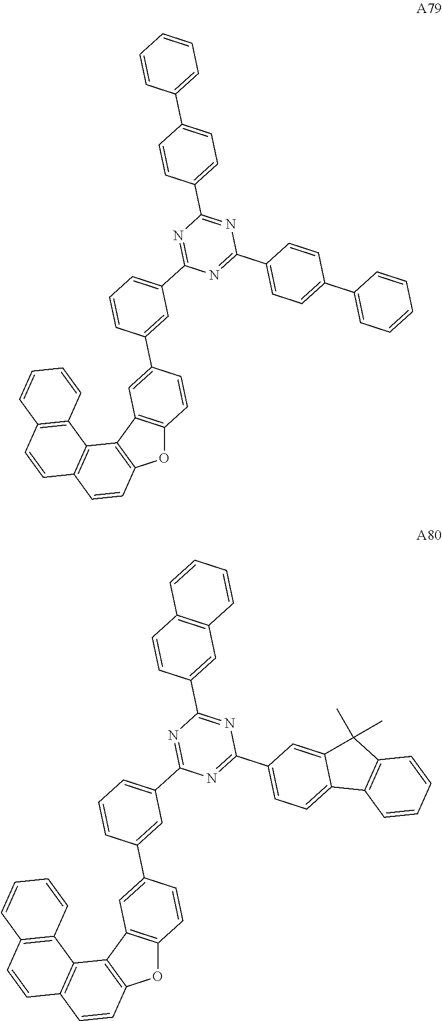 [SMILES: c1ccc(-c2ccc(-c3nc(-c4ccc(-c5ccccc5)cc4)nc(-c4cccc(-c5ccc6oc7ccc8ccc9ccccc9c8c7c6c5)c4)n3)cc2)cc1 ; CC1(C)c2ccccc2-c2ccc(-c3nc(-c4cccc(-c5ccc6oc7ccc8ccc9ccccc9c8c7c6c5)c4)nc(-c4ccc5ccccc5c4)n3)cc21]

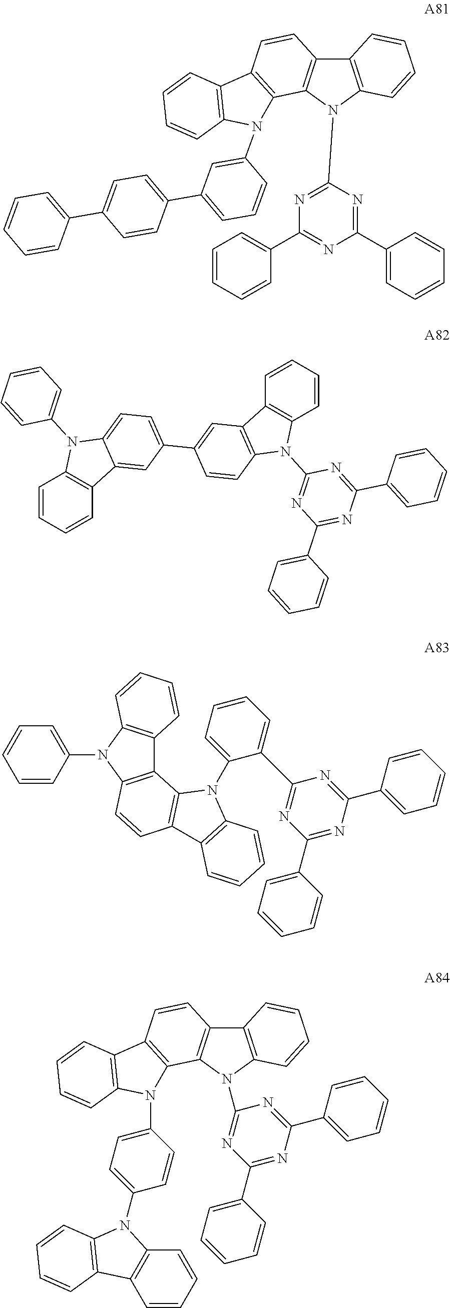 [SMILES: c1ccc(-c2ccc(-c3cccc(-n4c5ccccc5c5ccc6c7ccccc7n(-c7nc(-c8ccccc8)nc(-c8ccccc8)n7)c6c54)c3)cc2)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccccc3-n3c4ccccc4c4ccc5c(c6ccccc6n5-c5ccccc5)c43)n2)cc1 ; c1ccc(-c2nc(-c3ccccc3)nc(-n3c4ccccc4c4ccc5c6ccccc6n(-c6ccc(-n7c8ccccc8c8ccccc87)cc6)c5c43)n2)cc1]

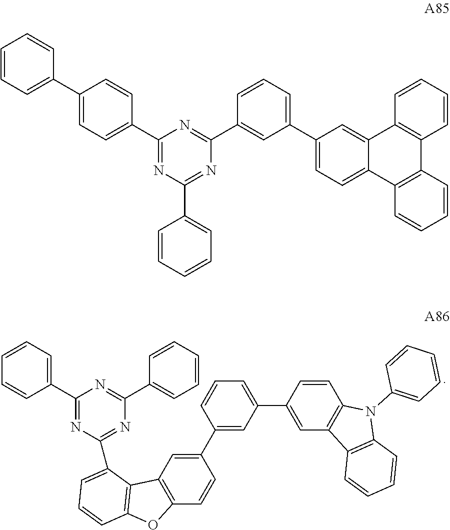 [SMILES: c1ccc(-c2ccc(-c3nc(-c4ccccc4)nc(-c4cccc(-c5ccc6c7ccccc7c7ccccc7c6c5)c4)n3)cc2)cc1 ; c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1]

14. The organic light-emitting diode according to claim 1, wherein the narrow-spectrum fluorescent material comprises one or more of compounds having structures represented by Formula 3-1, Formula 3-2, Formula 3-3, Formula 3-4, Formula 3-5, Formula 3-6, and Formula 3-7 as follows: 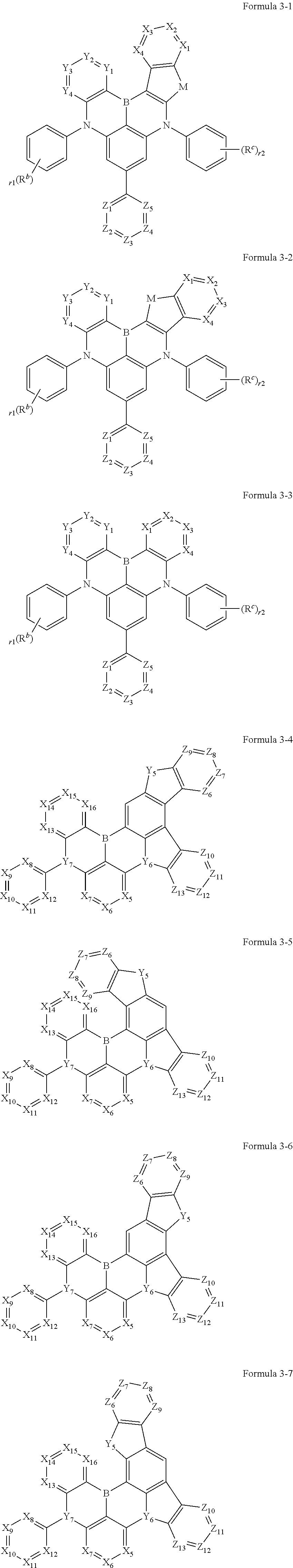
wherein M is NR², O, S or Se;
r1 and r2 are each independently an integer from 0 to 5;
X₁ to X₁₆, Y₁ to Y₄, and Z₁ to Z₅ are each independently CR₁ or N, and at least one of Z¹ to Z⁵ is N;
Y₅, Y₆ and Y₇ are each independently O, S, CR₂ or N;
R^{b}, R^{c}, R₁ and R₂ are each independently selected from at least one of hydrogen, halogen, cyano, nitro, hydroxyl, amino, substituted or unsubstituted C1-C20 linear or branched alkyl, substituted or unsubstituted C3-C20 cycloalkyl, substituted or unsubstituted C2-C20 linear, branched or cyclic alkenyl, substituted or unsubstituted C2-C20 linear or branched or cyclic alkynyl, substituted or unsubstituted C1-C20 alkoxy, substituted or unsubstituted C1-C20 silanyl, substituted or unsubstituted C6-C30 aryloxy, substituted or unsubstituted C6-C60 aryl, substituted or unsubstituted C3-C60 heteroaryl, a substituted or unsubstituted C6-C60 aryl ether group, a substituted or unsubstituted C3-C60 heteroaryl ether group, substituted or unsubstituted C6-C60 arylthio, substituted or unsubstituted C3-C60 heteroarylthio, substituted or unsubstituted C6-C60 arylamino, and substituted or unsubstituted C3-C60 heteroarylamino; and R¹ is linked or not linked to an adjacent group.

15. The organic light-emitting diode according to claim 14, wherein the “substituted” in the expression “substituted or unsubstituted” refers to being substituted with at least one selected from halogen, C1-C30 linear or branched alkyl, C3-C30 cycloalkyl, C3-C20 heterocycloalkyl, C1-C10 alkoxy, carboxyl, nitro, cyano, amino, hydroxyl, mercapto, C1-C20 alkylsilyl, C1-C20 alkylamino, C6-C30 arylamino, C3-C30 heteroarylamino, C6-C60 aryloxy, C3-C30 heteroaryloxy, C6-C60 aryl, or C3-C60 heteroaryl;
or X₁ to X₄ are all CR¹, and R₁ is selected from at least one of hydrogen, C1-C20 linear or branched alkyl, C3-C20 cycloalkyl, C6-C60 aryl, and C3-C60 heteroaryl;
preferably hydrogen, C1-C6 linear or branched alkyl and phenyl; more preferably hydrogen, isopropyl, tert-butyl and phenyl; and further preferably, at least one of the plurality of R¹ is not hydrogen;
or Y¹ to Y⁴ are all CR¹, and R₁ is selected from at least one of hydrogen, C1-C20 linear or branched alkyl, C3-C20 cycloalkyl, C6-C60 aryl, and C3-C60 heteroaryl, preferably hydrogen, C1-C6 linear or branched alkyl and phenyl, more preferably hydrogen, isopropyl, tert-butyl and phenyl, and at least one of the plurality of R₁ is not hydrogen;
or R^{b} is hydrogen, C1-C6 linear or branched alkyl, and phenyl, preferably hydrogen, isopropyl, tert-butyl and phenyl, and at least one of the plurality of R^{b} is not hydrogen; R^{c} is hydrogen, C1-C6 linear or branched alkyl, and phenyl, preferably hydrogen, isopropyl, tert-butyl and phenyl, and at least one of the plurality of R^{c} is not hydrogen;
or, Z₁ to Z₅ are not all N, and at least one R₁ is substituted or unsubstituted C6-C60 aryl, or substituted or unsubstituted C3-C60 heteroaryl; and preferably, Z₁ to Z₅ are not all N, and at least one R₁ is substituted or unsubstituted C6-C12 aryl, or substituted or unsubstituted C3-C12 heteroaryl.

16. The organic light-emitting diode according to claim 14, wherein the narrow-spectrum fluorescent material comprises one or more of the following compounds M1 to M474:

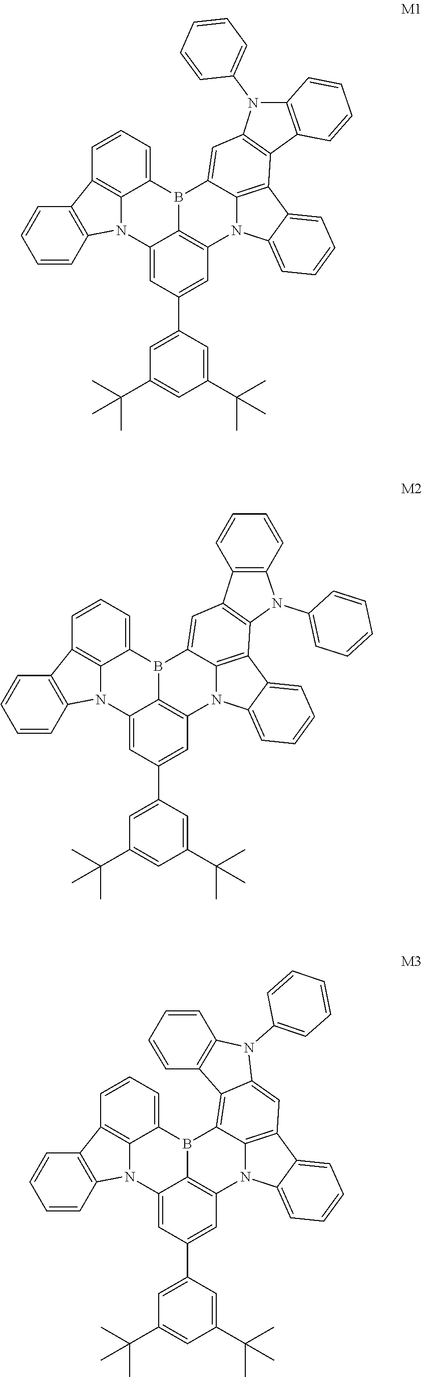 [SMILES: CC(C)(C)c1cc(-c2cc3c4c(c2)-n2c5ccccc5c5c6c7ccccc7n(-c7ccccc7)c6cc(c52)B4c2cccc4c5ccccc5n-3c24)cc(C(C)(C)C)c1 ; CC(C)(C)c1cc(-c2cc3c4c(c2)-n2c5ccccc5c5c2c(cc2c6ccccc6n(-c6ccccc6)c25)B4c2cccc4c5ccccc5n-3c24)cc(C(C)(C)C)c1 ; CC(C)(C)c1cc(-c2cc3c4c(c2)-n2c5ccccc5c5cc6c(c(c52)B4c2cccc4c5ccccc5n-3c24)c2ccccc2n6-c2ccccc2)cc(C(C)(C)C)c1]

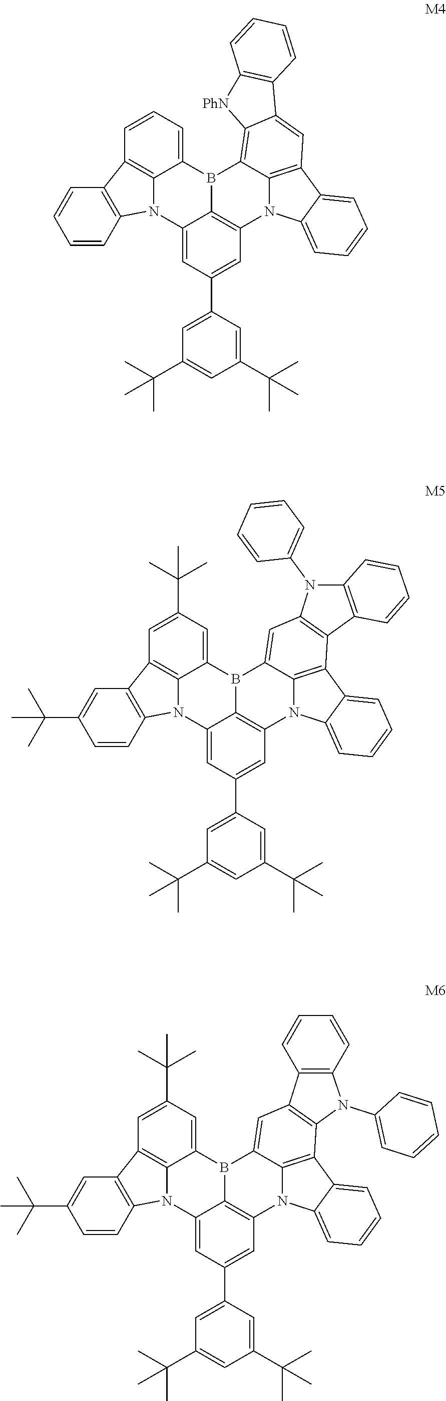

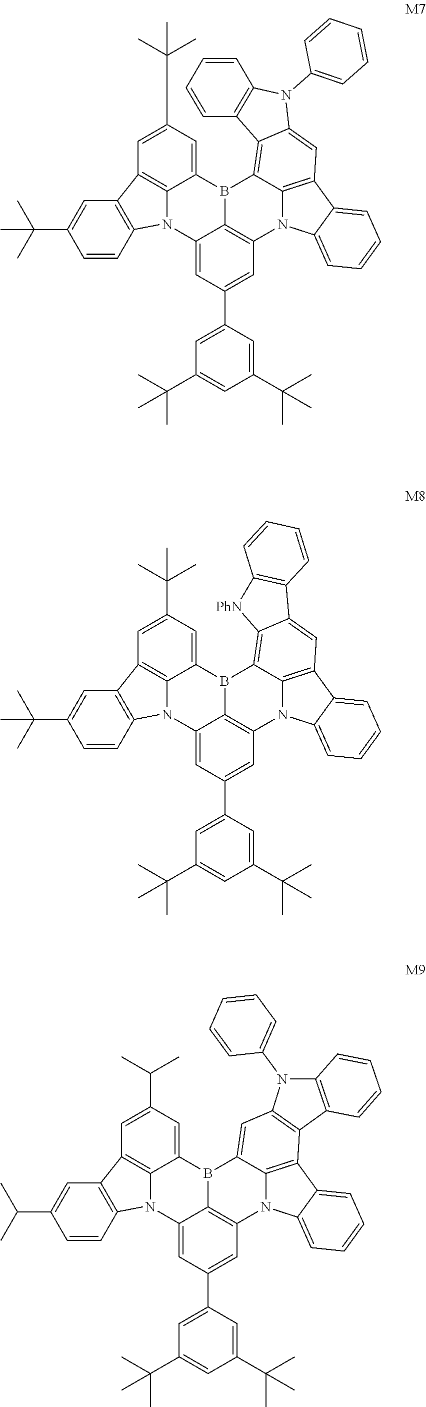

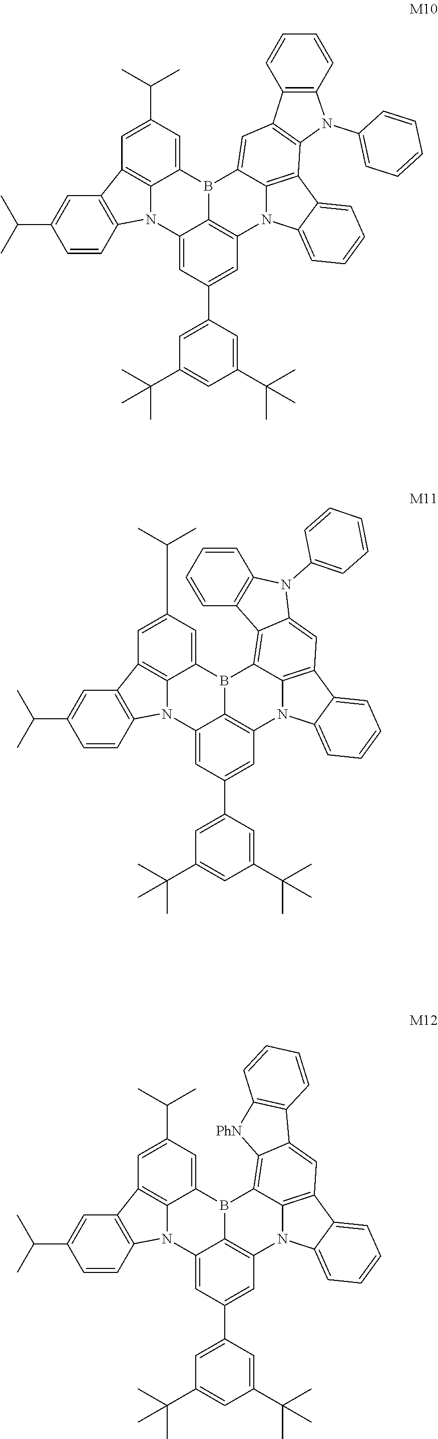

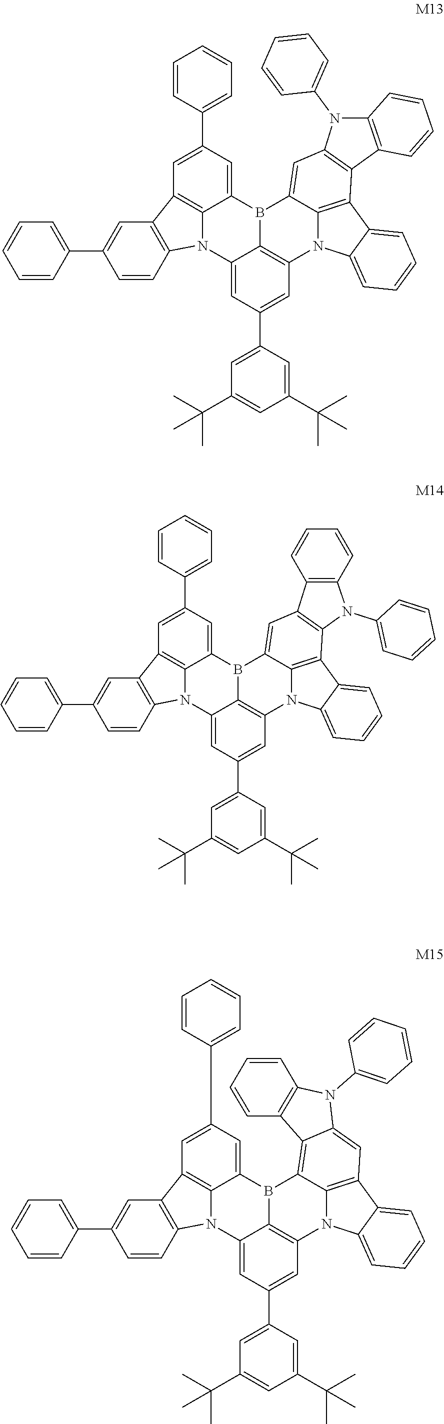 [SMILES: CC(C)(C)c1cc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc(C(C)(C)C)c1 ; CC(C)(C)c1cc(-c2cc3c4c(c2)-n2c5ccccc5c5c2c(cc2c6ccccc6n(-c6ccccc6)c25)B4c2cc(-c4ccccc4)cc4c5cc(-c6ccccc6)ccc5n-3c24)cc(C(C)(C)C)c1 ; CC(C)(C)c1cc(-c2cc3c4c(c2)-n2c5ccccc5c5cc6c(c(c52)B4c2cc(-c4ccccc4)cc4c5cc(-c7ccccc7)ccc5n-3c24)c2ccccc2n6-c2ccccc2)cc(C(C)(C)C)c1]

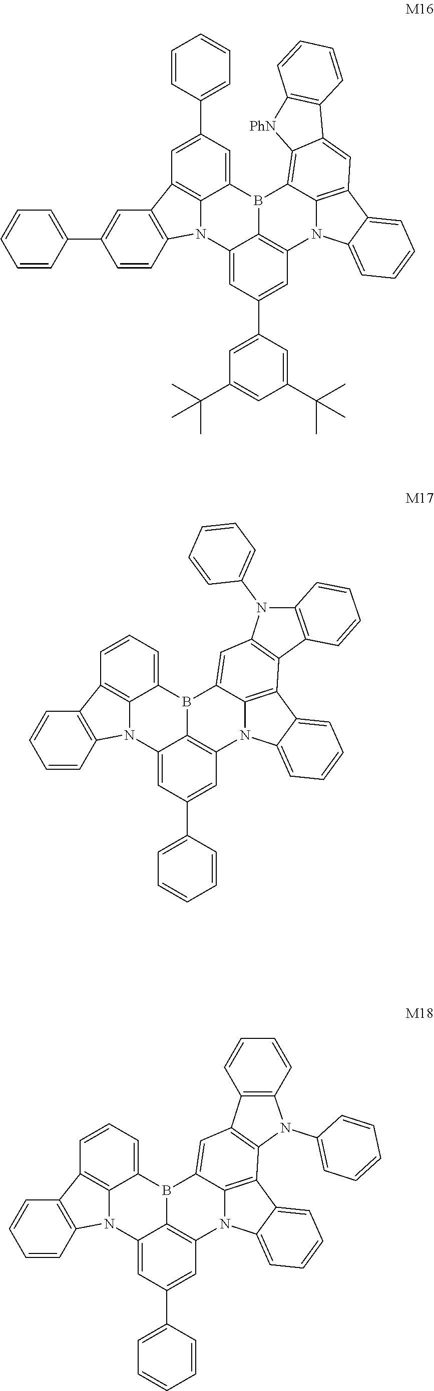

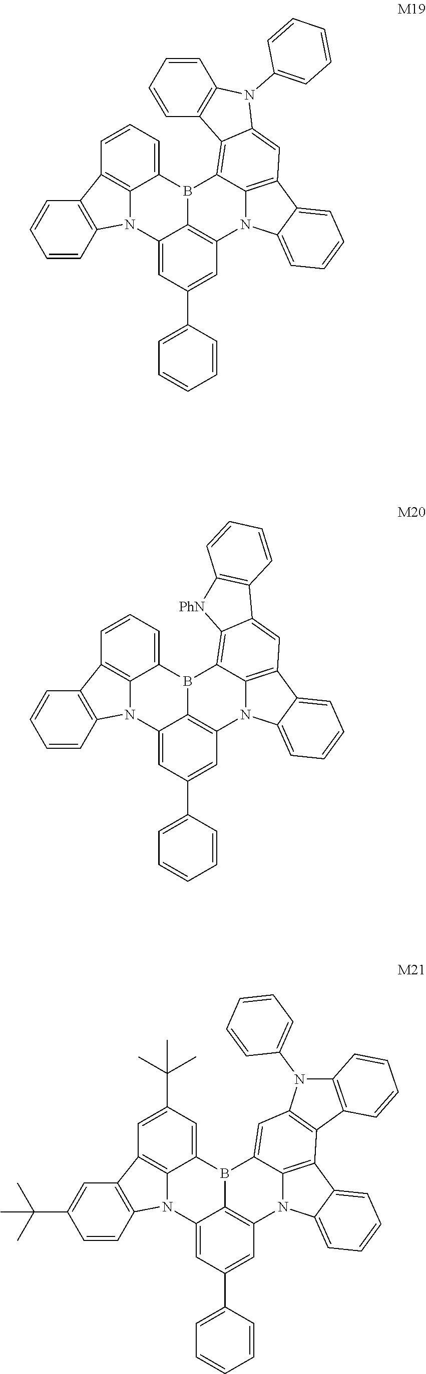

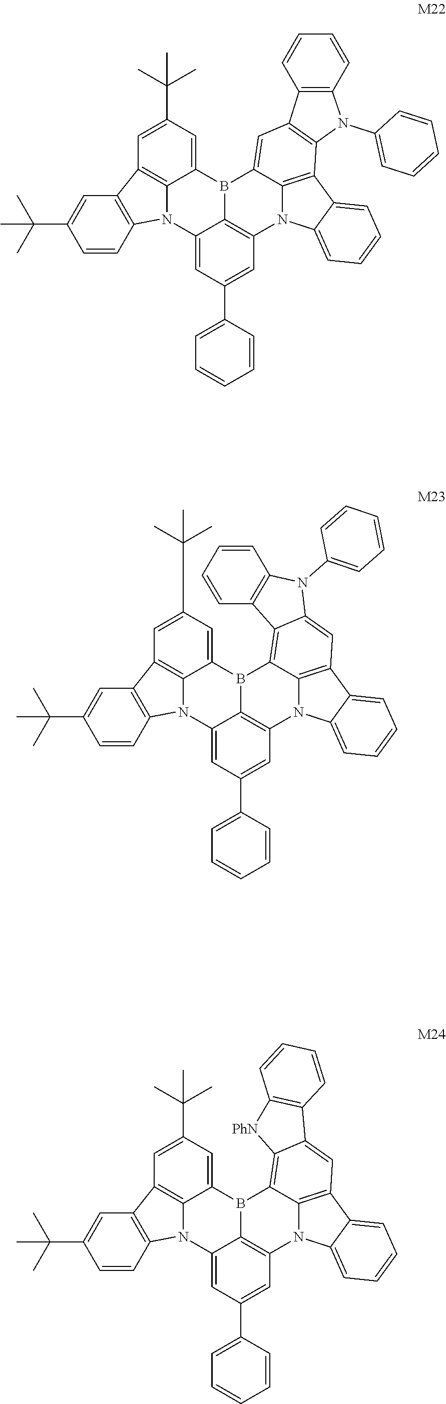

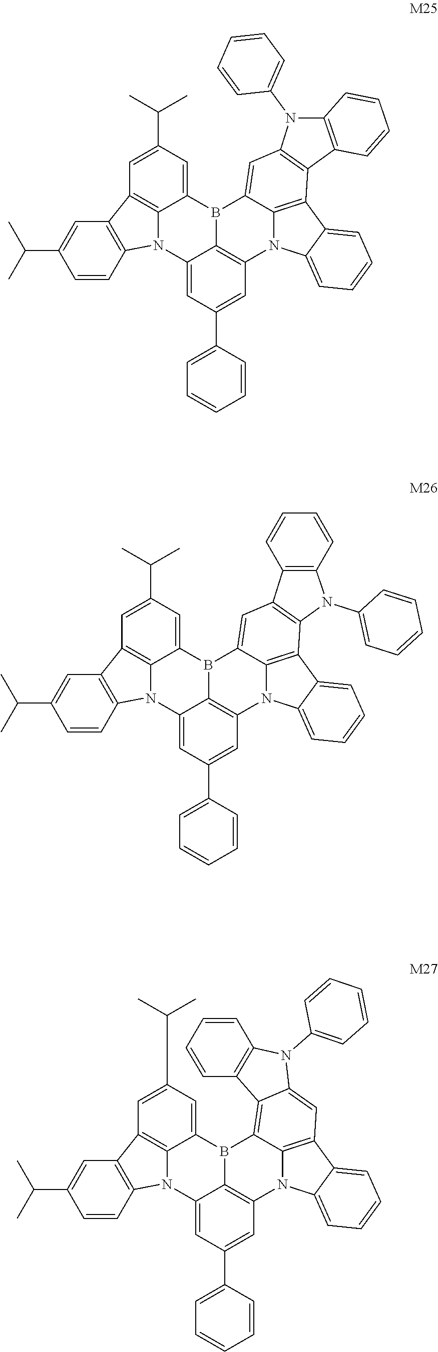 [SMILES: CC(C)c1ccc2c(c1)c1cc(C(C)C)cc3c1n2-c1cc(-c2ccccc2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2ccccc2)cc2c1B3c1cc3c4ccccc4n(-c4ccccc4)c3c3c4ccccc4n-2c13 ; CC(C)c1ccc2c(c1)c1cc(C(C)C)cc3c1n2-c1cc(-c2ccccc2)cc2c1B3c1c3c4ccccc4n(-c4ccccc4)c3cc3c4ccccc4n-2c13]

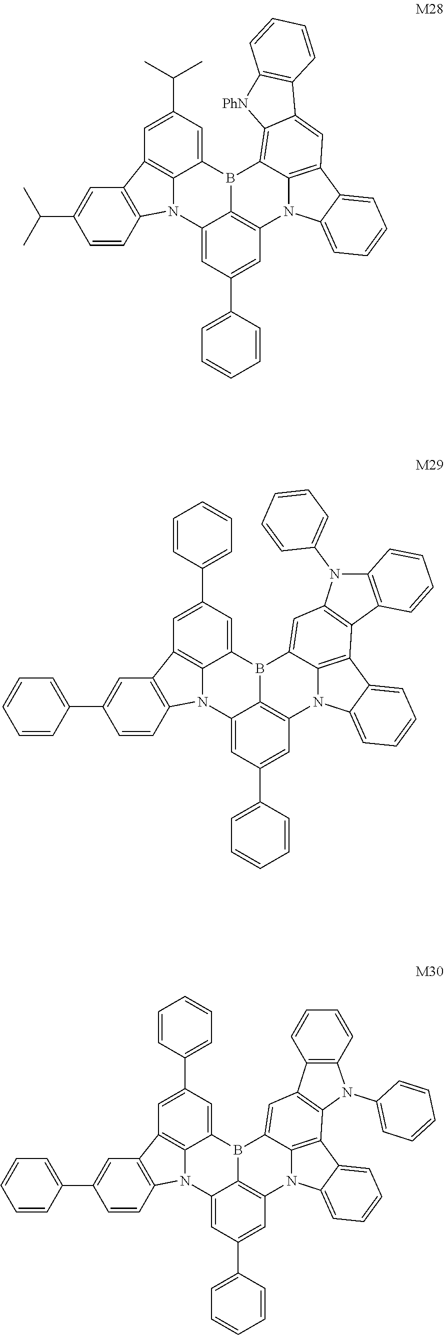

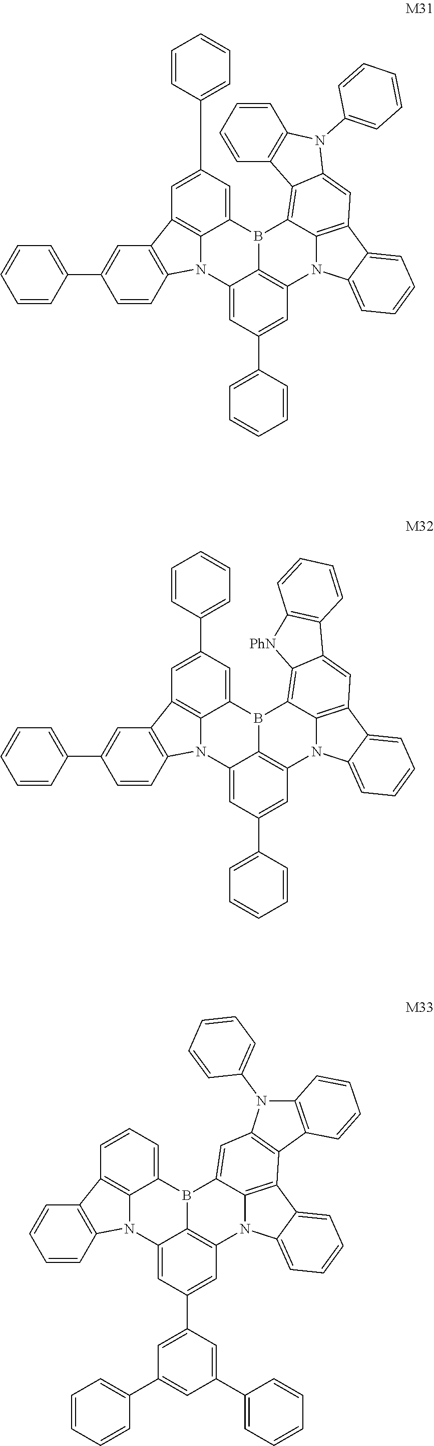

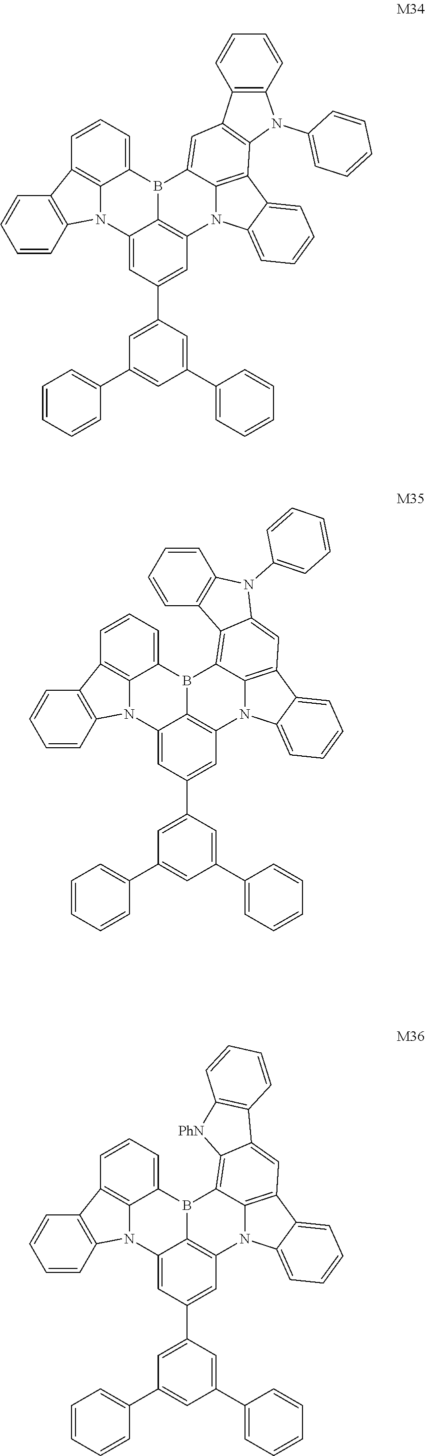

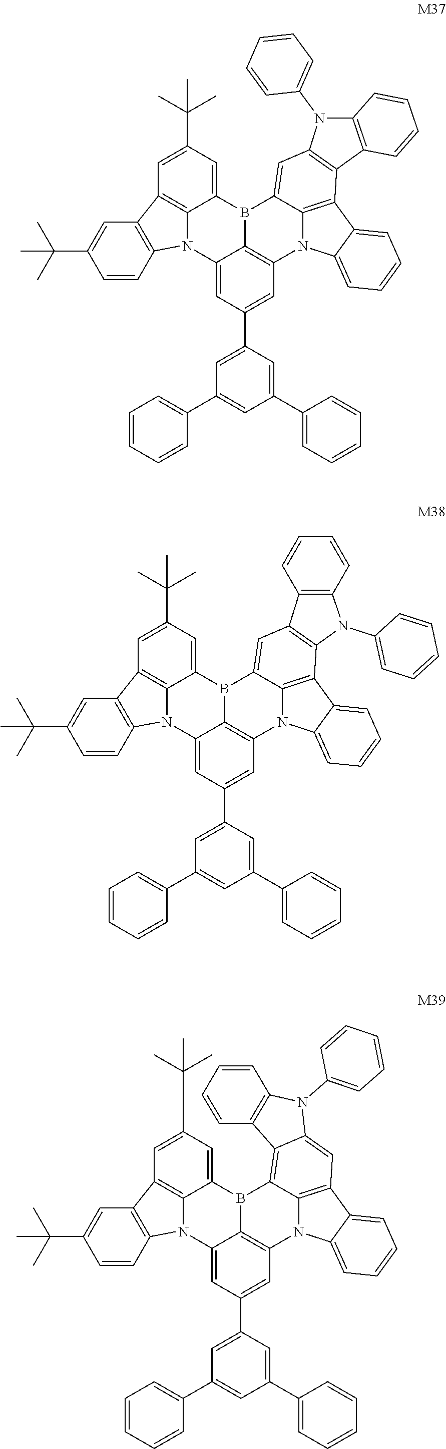 [SMILES: CC(C)(C)c1ccc2c(c1)c1cc(C(C)(C)C)cc3c1n2-c1cc(-c2cc(-c4ccccc4)cc(-c4ccccc4)c2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2cc(-c4ccccc4)cc(-c4ccccc4)c2)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2cc(-c4ccccc4)cc(-c4ccccc4)c2)cc2c1B3c1c3c4ccccc4n(-c4ccccc4)c3cc3c4ccccc4n-2c13]

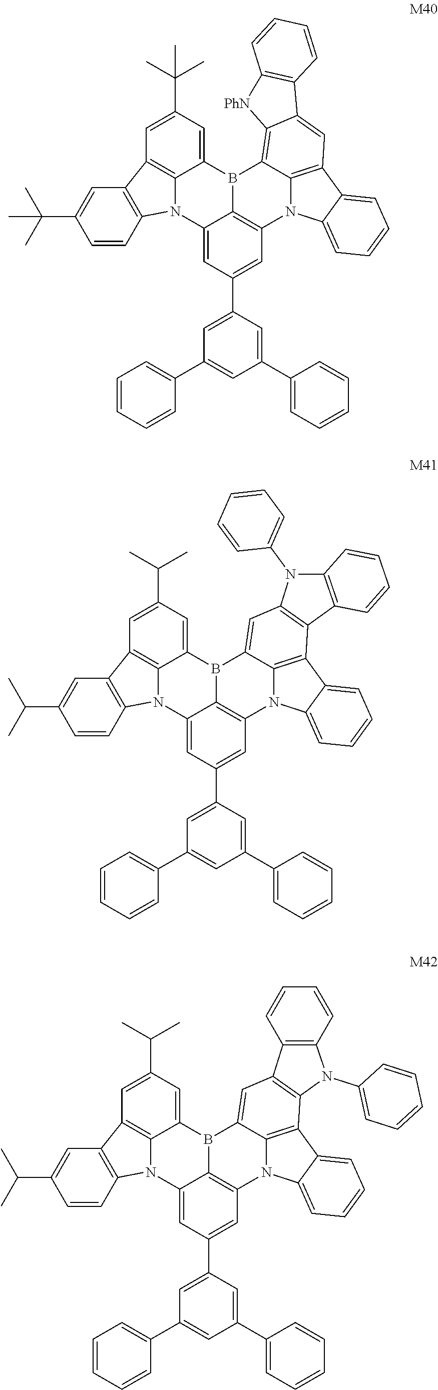

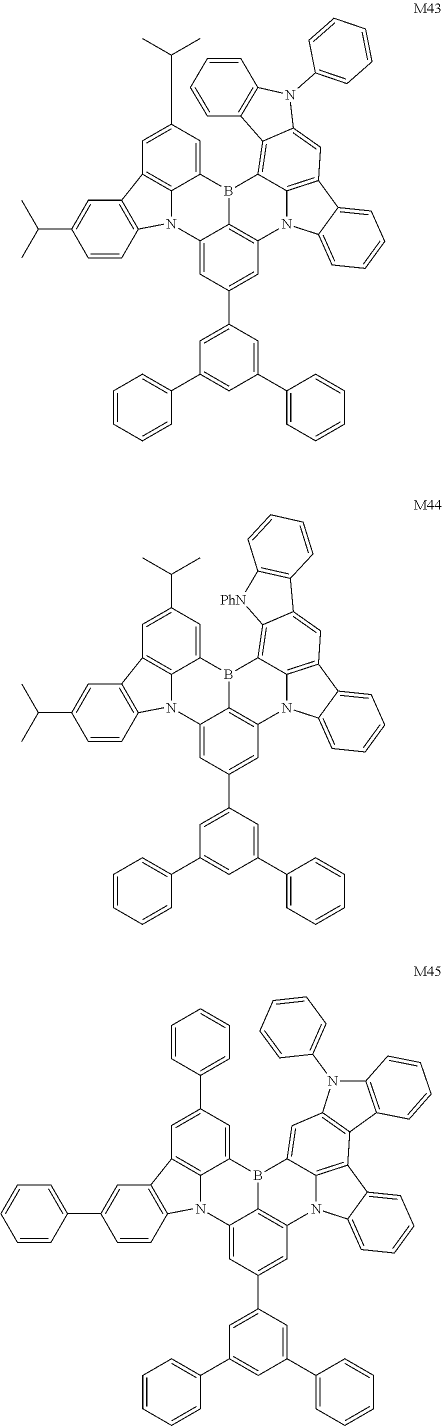

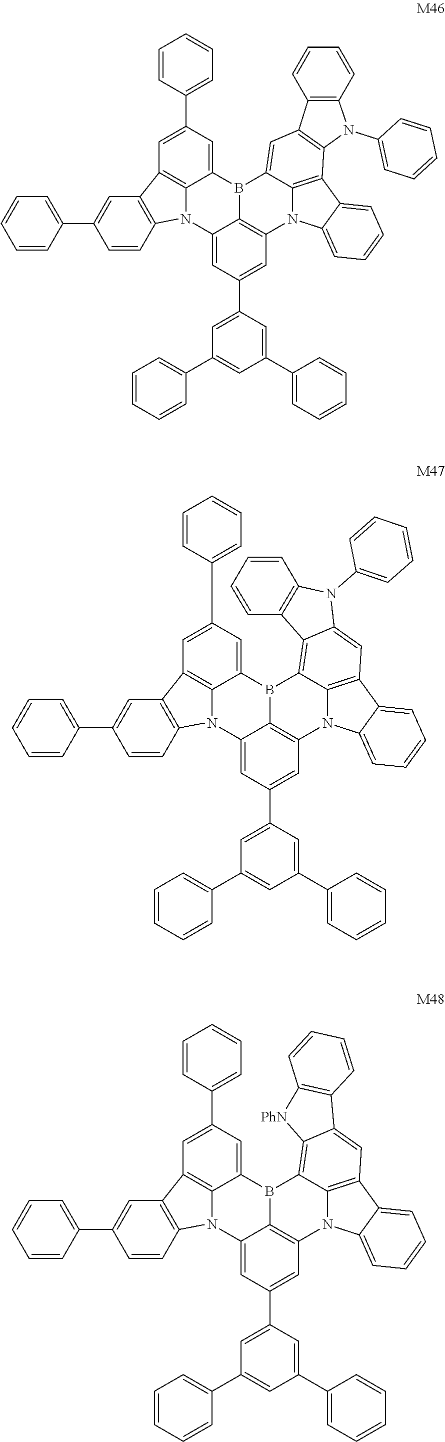

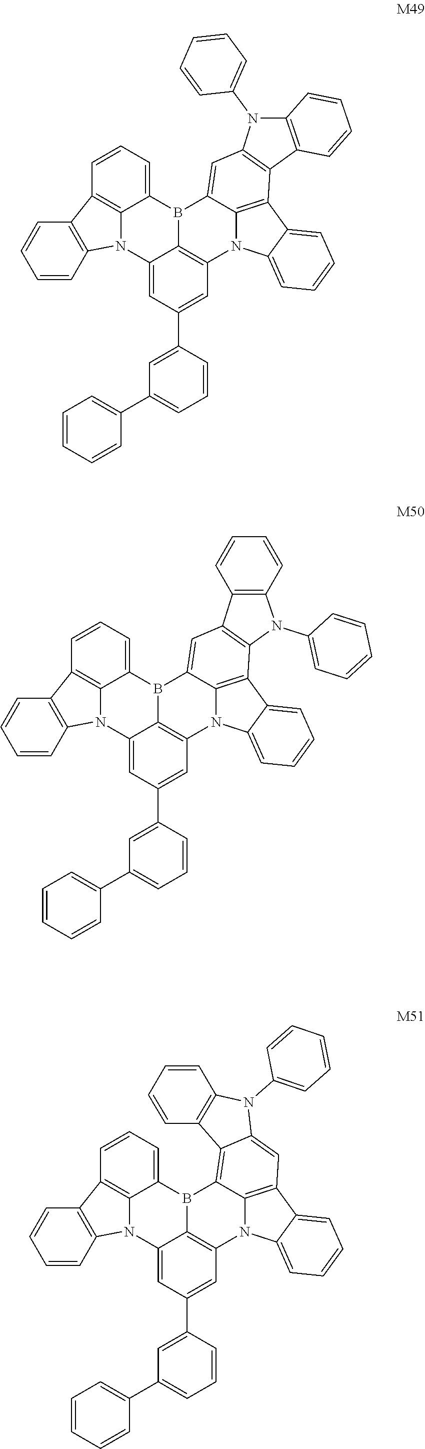 [SMILES: c1ccc(-c2cccc(-c3cc4c5c(c3)-n3c6ccccc6c6c7c8ccccc8n(-c8ccccc8)c7cc(c63)B5c3cccc5c6ccccc6n-4c35)c2)cc1 ; c1ccc(-c2cccc(-c3cc4c5c(c3)-n3c6ccccc6c6c3c(cc3c7ccccc7n(-c7ccccc7)c36)B5c3cccc5c6ccccc6n-4c35)c2)cc1 ; c1ccc(-c2cccc(-c3cc4c5c(c3)-n3c6ccccc6c6cc7c(c(c63)B5c3cccc5c6ccccc6n-4c35)c3ccccc3n7-c3ccccc3)c2)cc1]

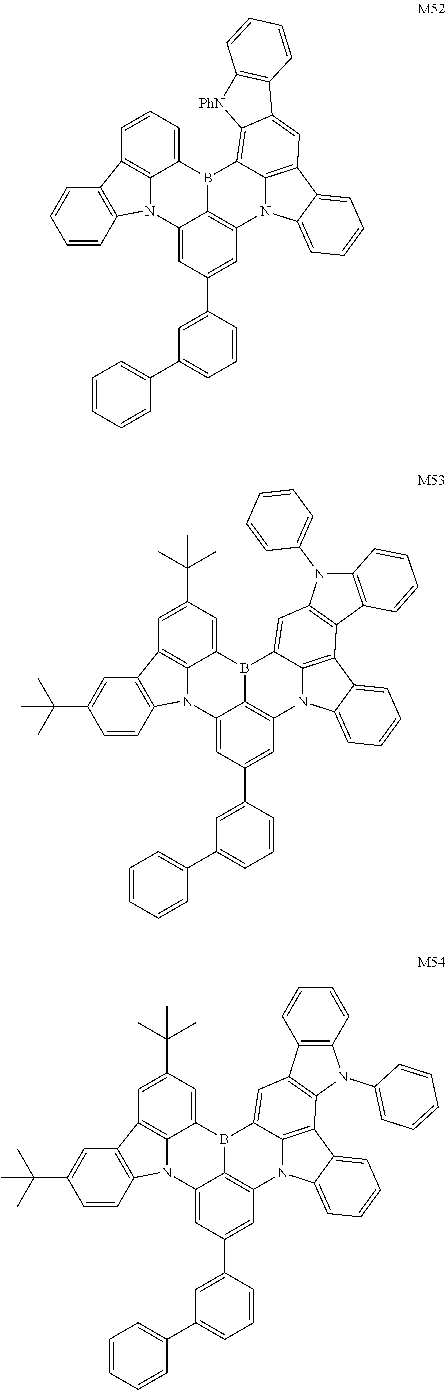

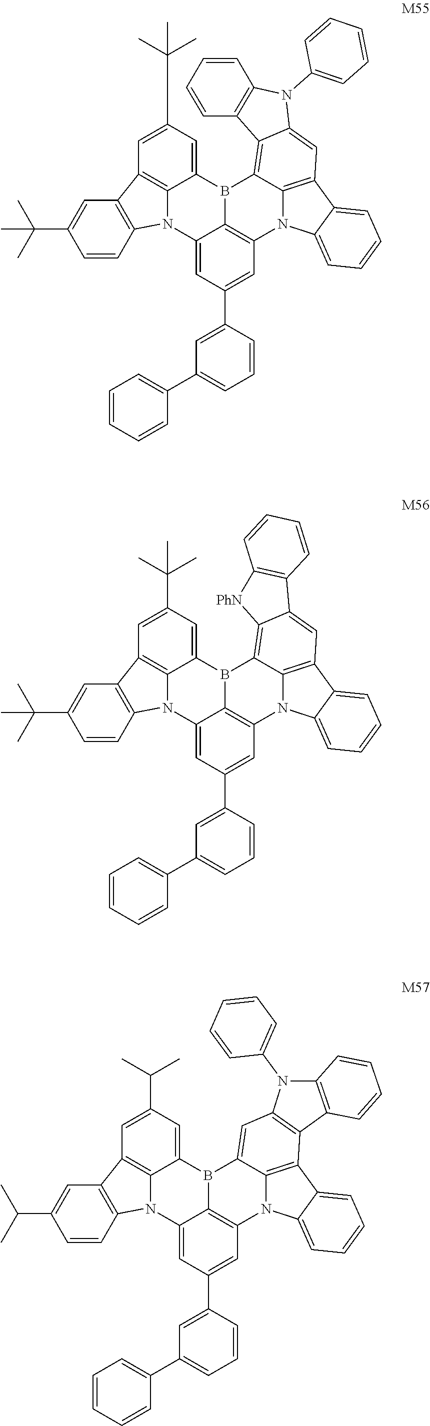

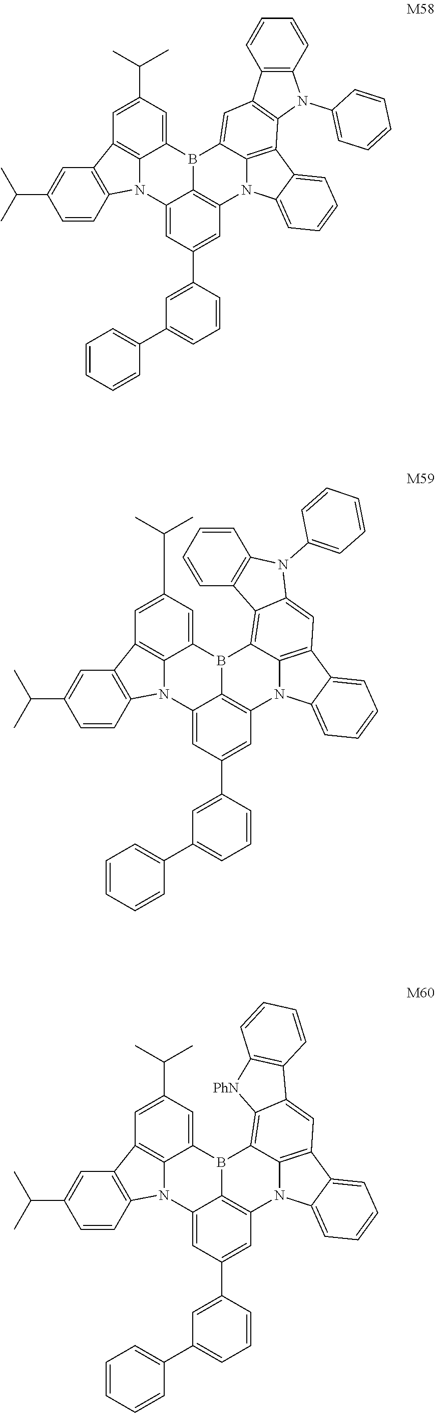

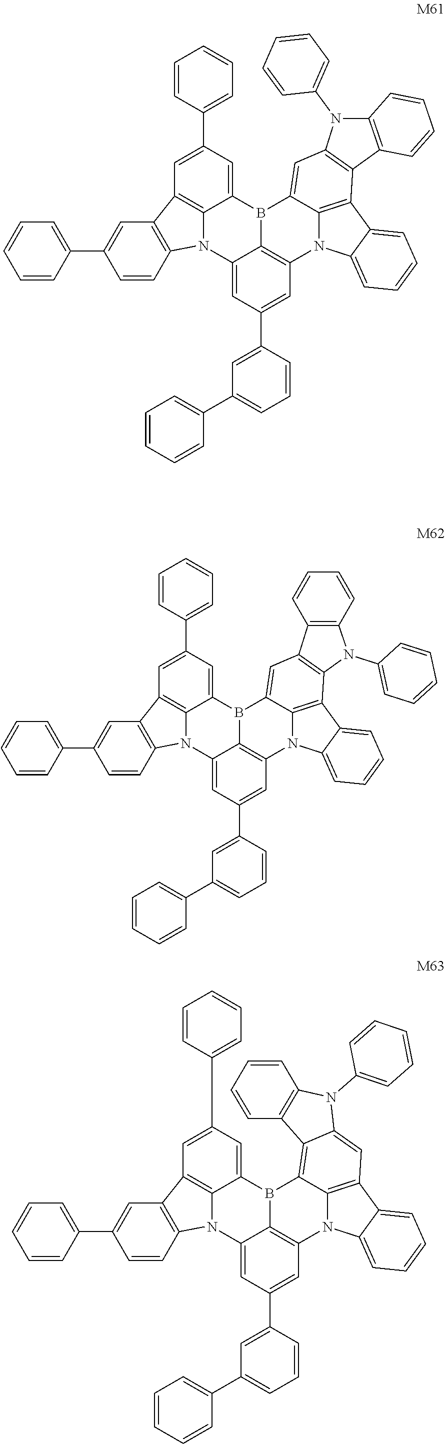 [SMILES: c1ccc(-c2cccc(-c3cc4c5c(c3)-n3c6ccccc6c6c7c8ccccc8n(-c8ccccc8)c7cc(c63)B5c3cc(-c5ccccc5)cc5c6cc(-c7ccccc7)ccc6n-4c35)c2)cc1 ; c1ccc(-c2cccc(-c3cc4c5c(c3)-n3c6ccccc6c6c3c(cc3c7ccccc7n(-c7ccccc7)c36)B5c3cc(-c5ccccc5)cc5c6cc(-c7ccccc7)ccc6n-4c35)c2)cc1 ; c1ccc(-c2cccc(-c3cc4c5c(c3)-n3c6ccccc6c6cc7c(c(c63)B5c3cc(-c5ccccc5)cc5c6cc(-c8ccccc8)ccc6n-4c35)c3ccccc3n7-c3ccccc3)c2)cc1]

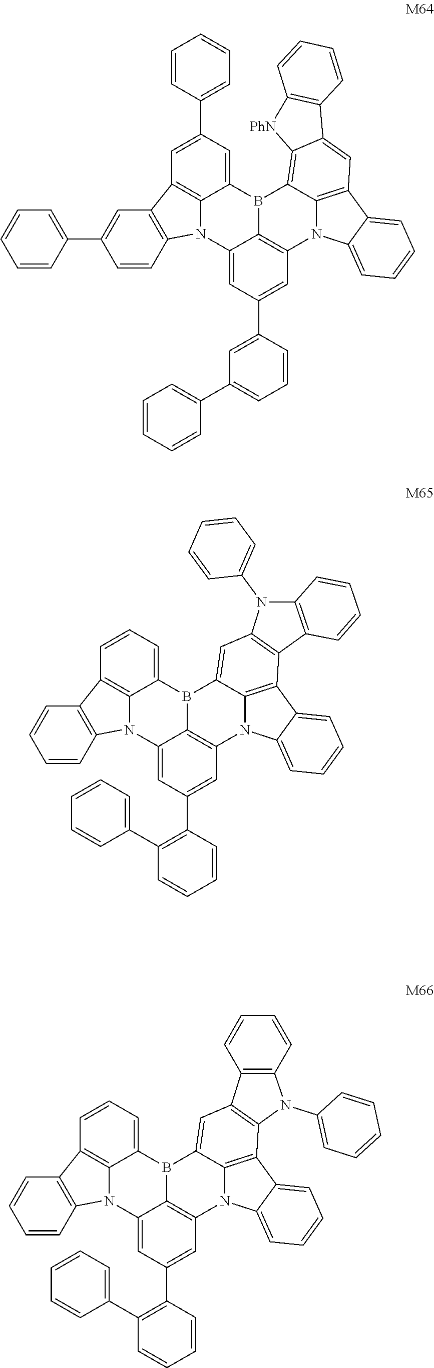

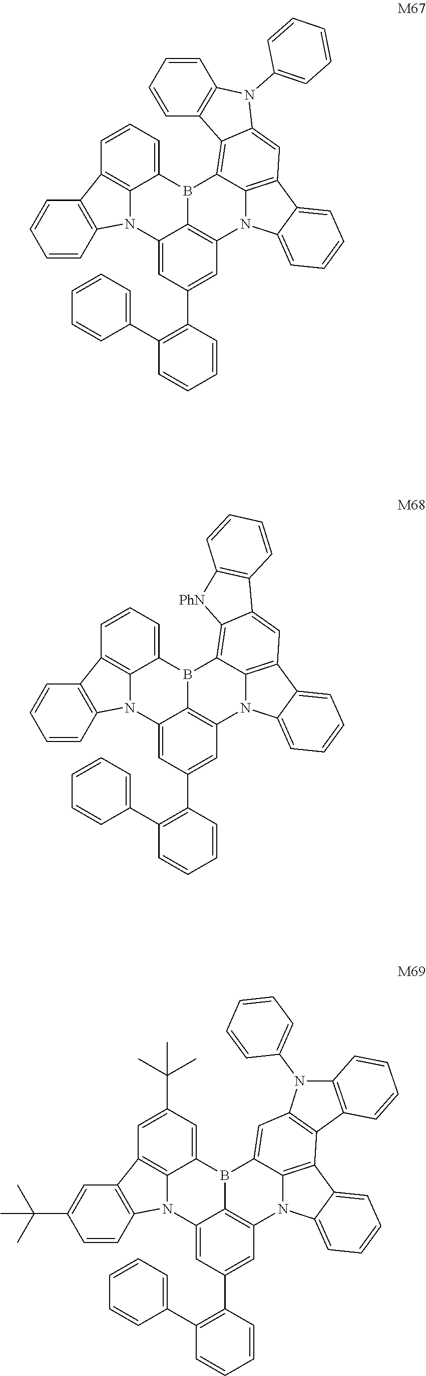

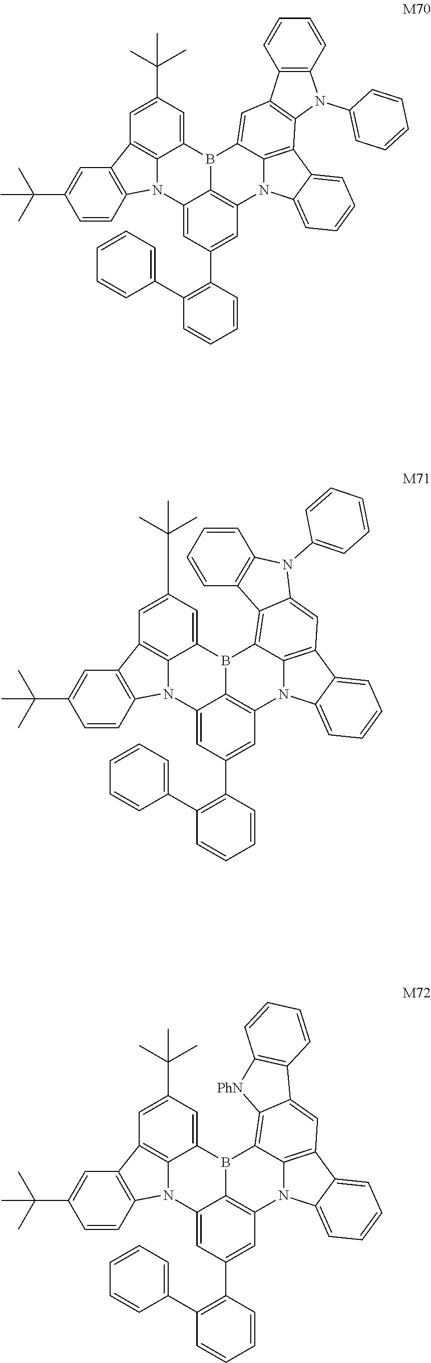

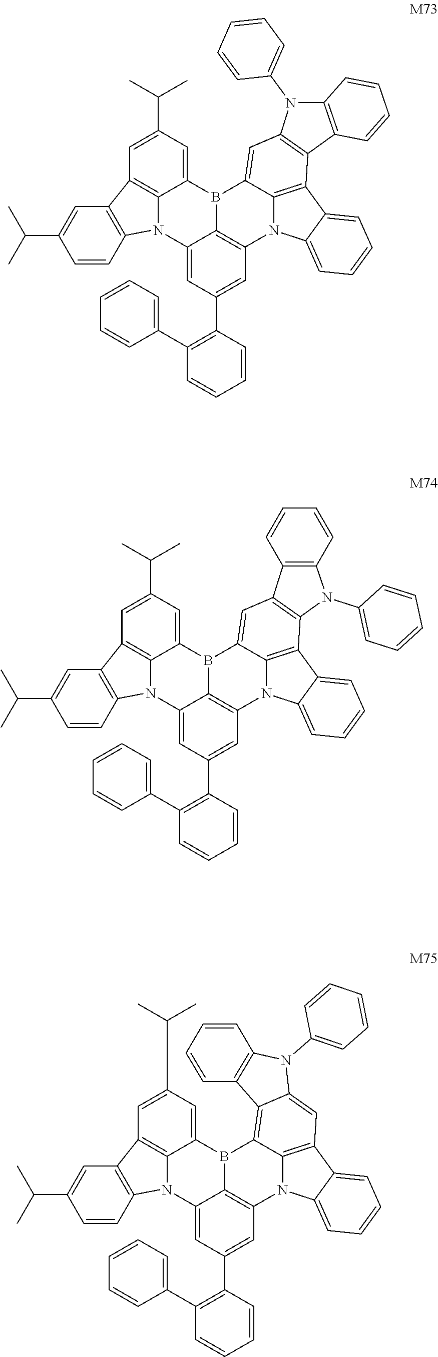 [SMILES: CC(C)c1ccc2c(c1)c1cc(C(C)C)cc3c1n2-c1cc(-c2ccccc2-c2ccccc2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2ccccc2-c2ccccc2)cc2c1B3c1cc3c4ccccc4n(-c4ccccc4)c3c3c4ccccc4n-2c13 ; CC(C)c1ccc2c(c1)c1cc(C(C)C)cc3c1n2-c1cc(-c2ccccc2-c2ccccc2)cc2c1B3c1c3c4ccccc4n(-c4ccccc4)c3cc3c4ccccc4n-2c13]

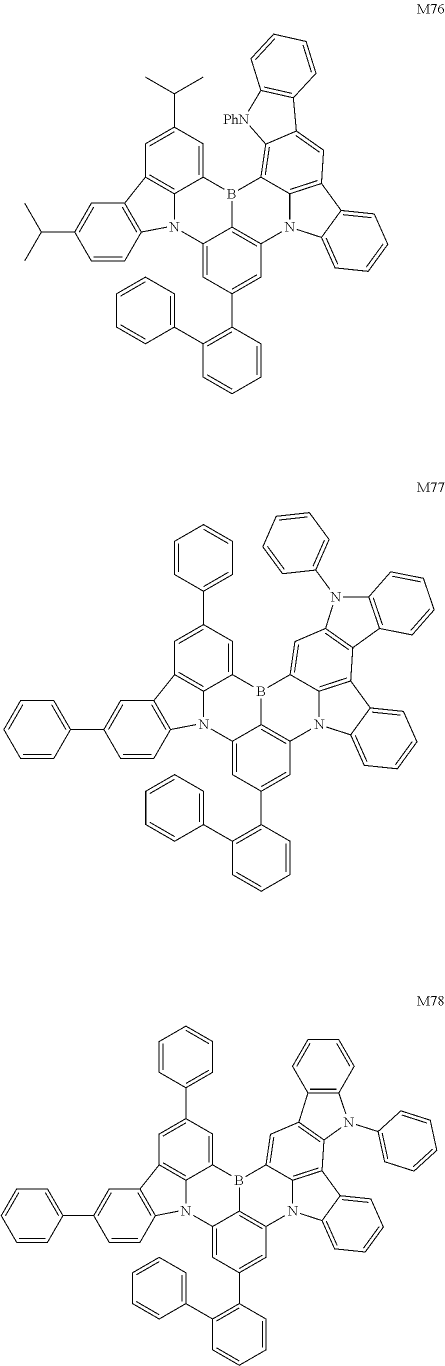

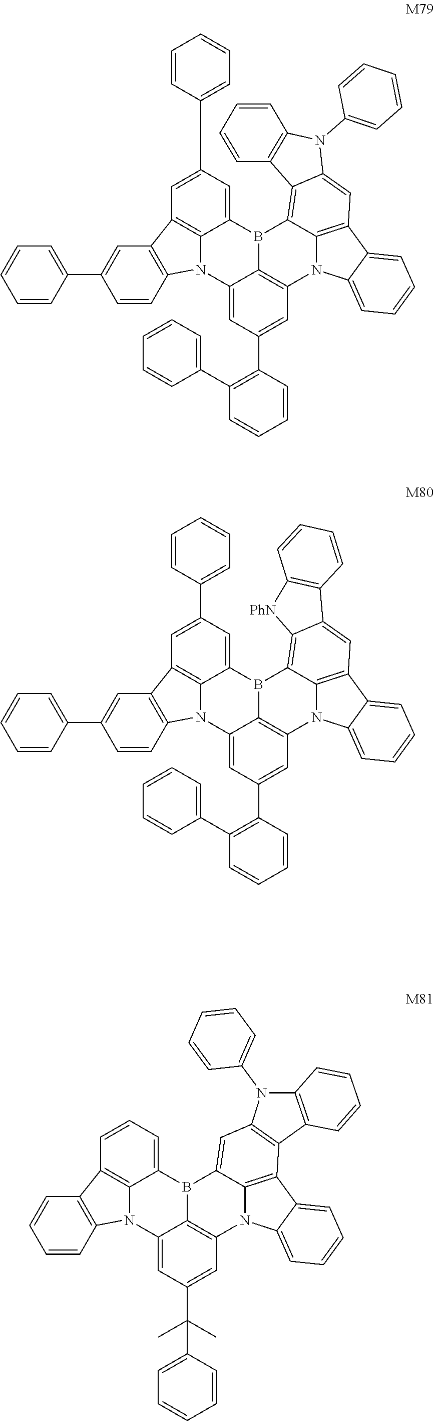

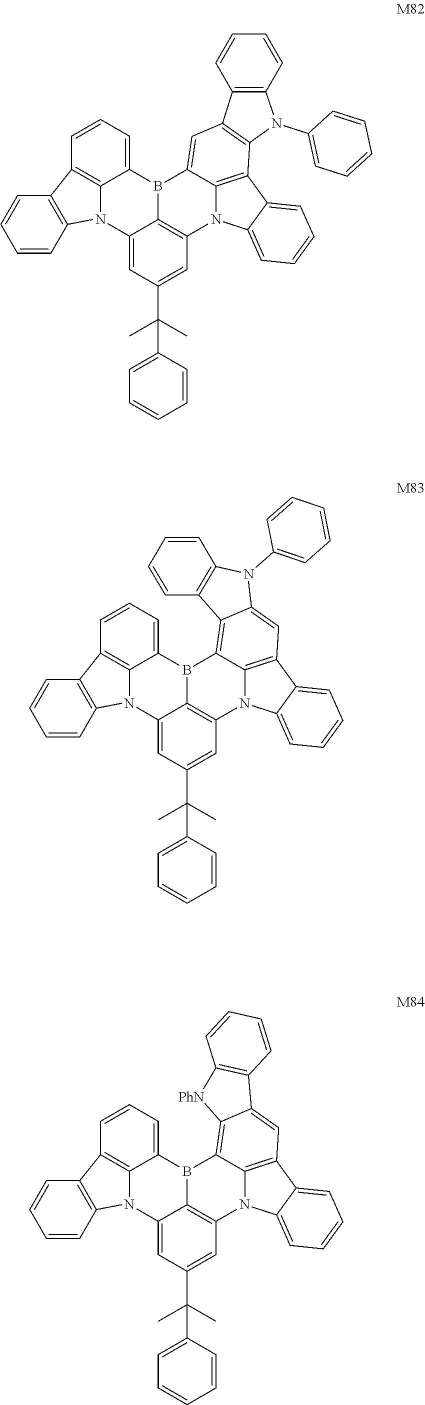

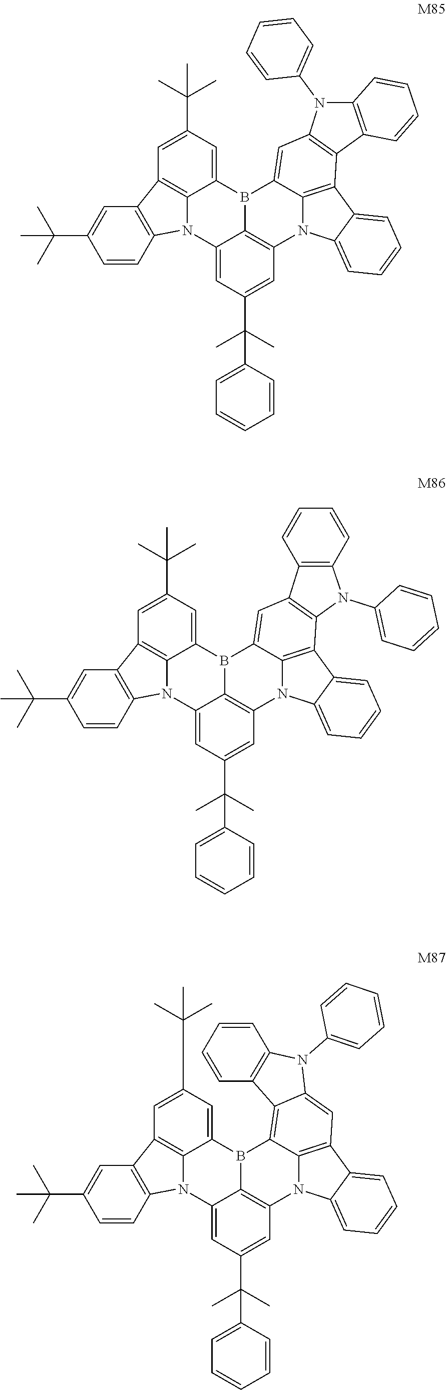 [SMILES: CC(C)(C)c1ccc2c(c1)c1cc(C(C)(C)C)cc3c1n2-c1cc(C(C)(C)c2ccccc2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(C(C)(C)c2ccccc2)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(C(C)(C)c2ccccc2)cc2c1B3c1c3c4ccccc4n(-c4ccccc4)c3cc3c4ccccc4n-2c13]

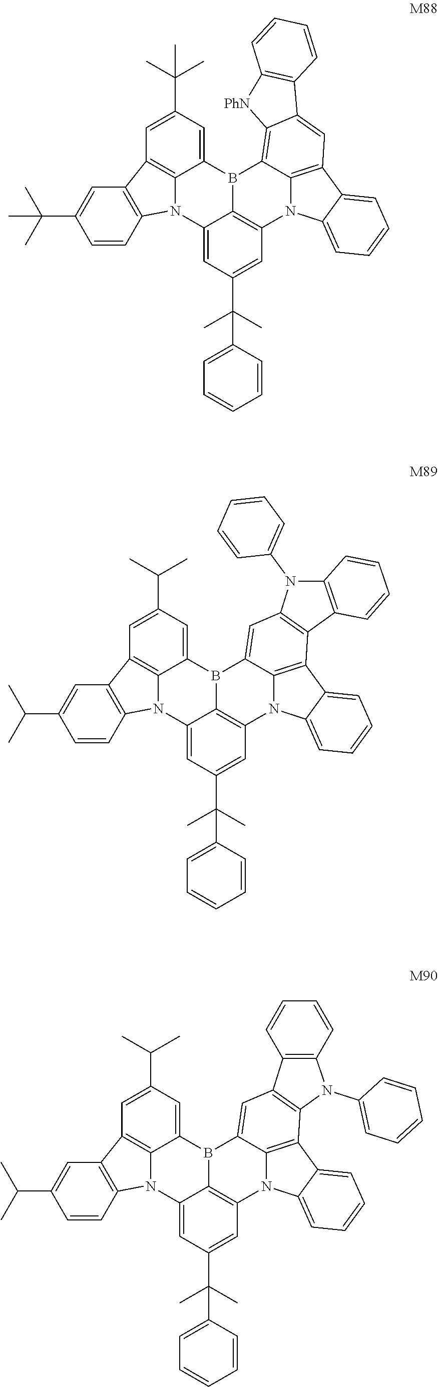

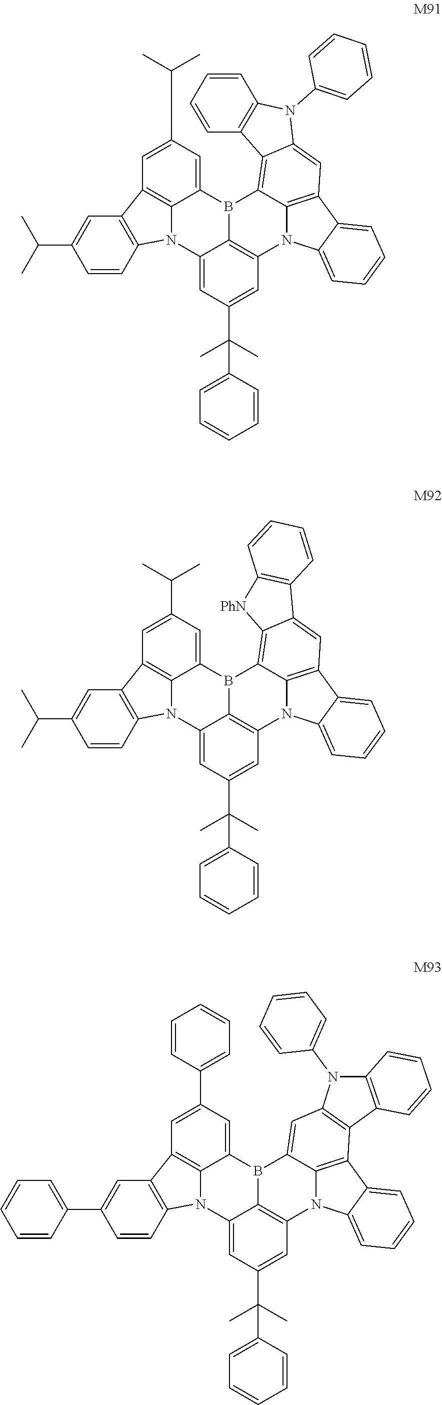

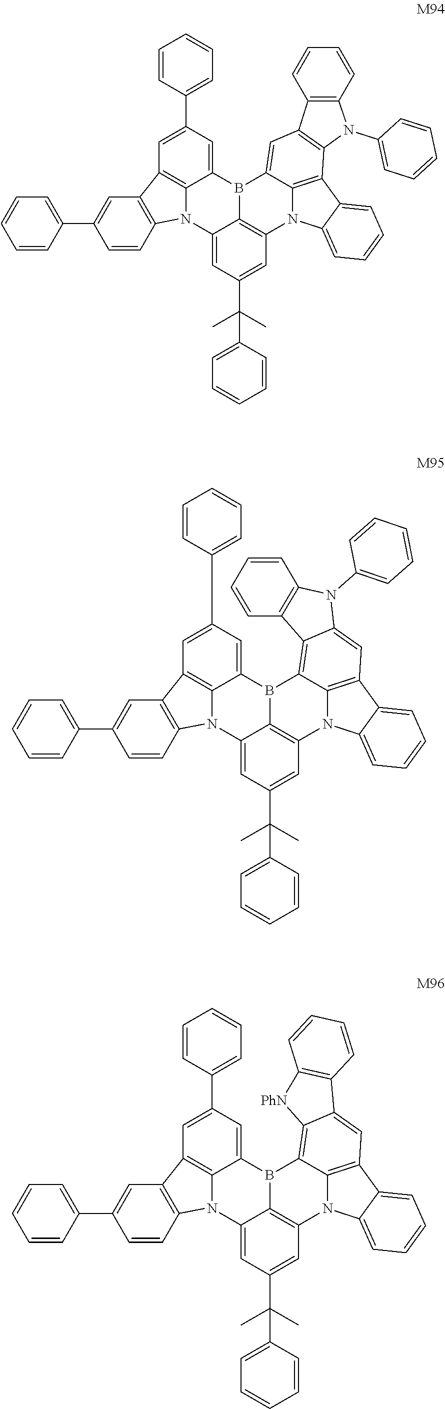

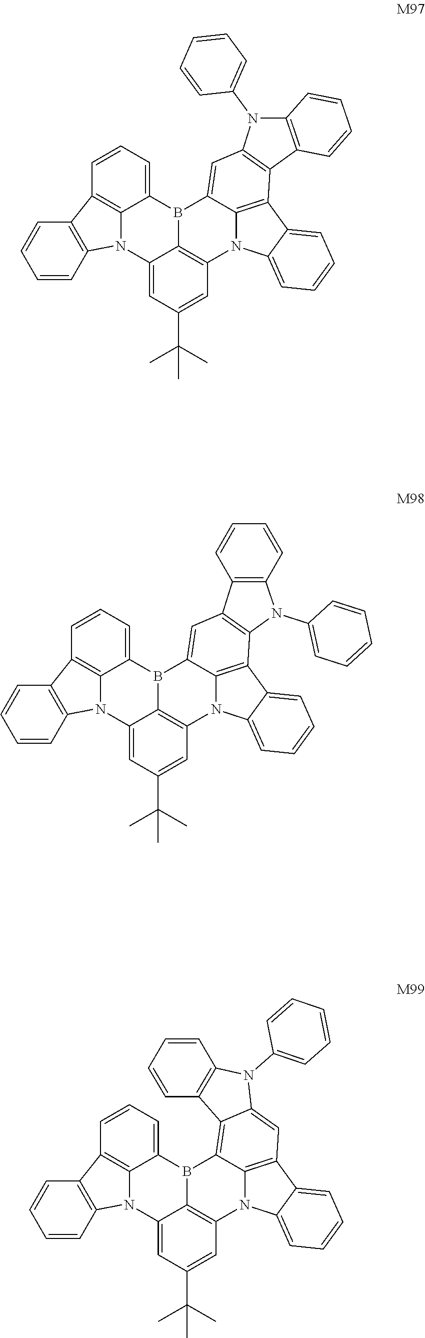 [SMILES: CC(C)(C)c1cc2c3c(c1)-n1c4ccccc4c4c5c6ccccc6n(-c6ccccc6)c5cc(c41)B3c1cccc3c4ccccc4n-2c13 ; CC(C)(C)c1cc2c3c(c1)-n1c4ccccc4c4c1c(cc1c5ccccc5n(-c5ccccc5)c14)B3c1cccc3c4ccccc4n-2c13 ; CC(C)(C)c1cc2c3c(c1)-n1c4ccccc4c4cc5c(c(c41)B3c1cccc3c4ccccc4n-2c13)c1ccccc1n5-c1ccccc1]

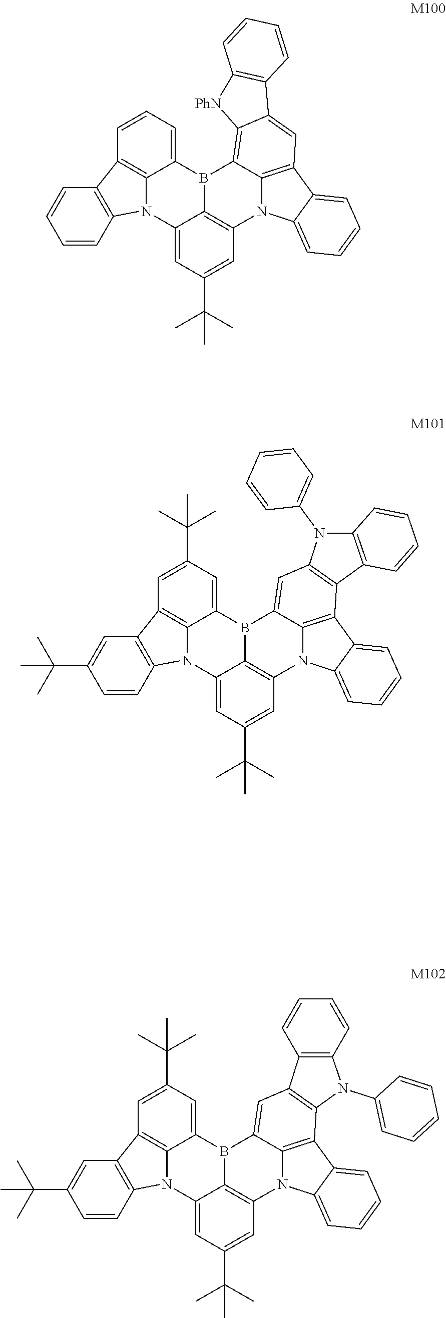

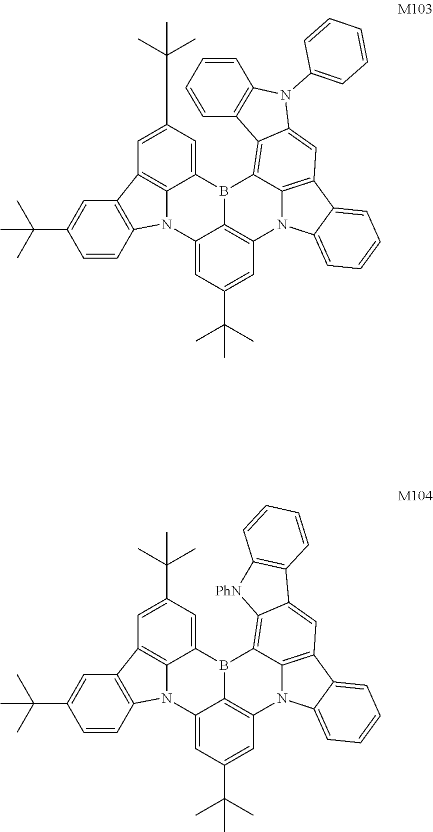

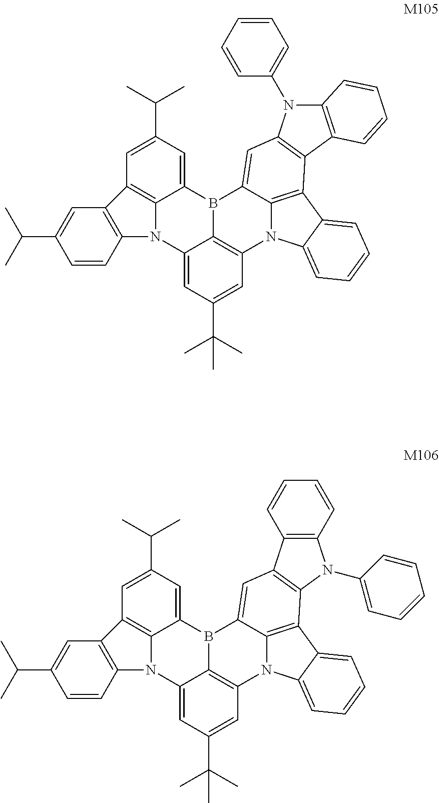 [SMILES: CC(C)c1ccc2c(c1)c1cc(C(C)C)cc3c1n2-c1cc(C(C)(C)C)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(C(C)(C)C)cc2c1B3c1cc3c4ccccc4n(-c4ccccc4)c3c3c4ccccc4n-2c13]

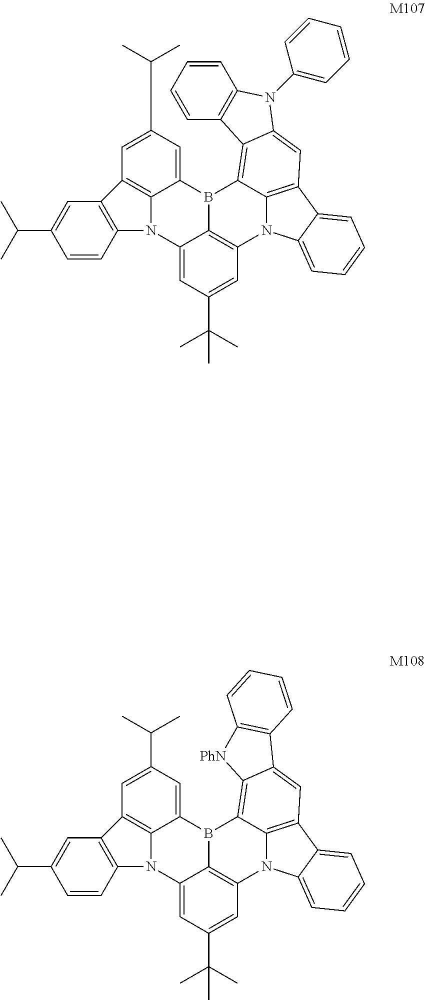

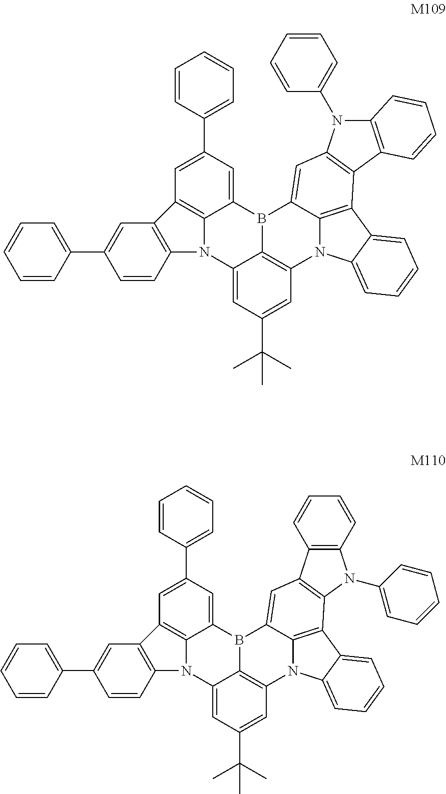 [SMILES: CC(C)(C)c1cc2c3c(c1)-n1c4ccccc4c4c5c6ccccc6n(-c6ccccc6)c5cc(c41)B3c1cc(-c3ccccc3)cc3c4cc(-c5ccccc5)ccc4n-2c13 ; CC(C)(C)c1cc2c3c(c1)-n1c4ccccc4c4c1c(cc1c5ccccc5n(-c5ccccc5)c14)B3c1cc(-c3ccccc3)cc3c4cc(-c5ccccc5)ccc4n-2c13]

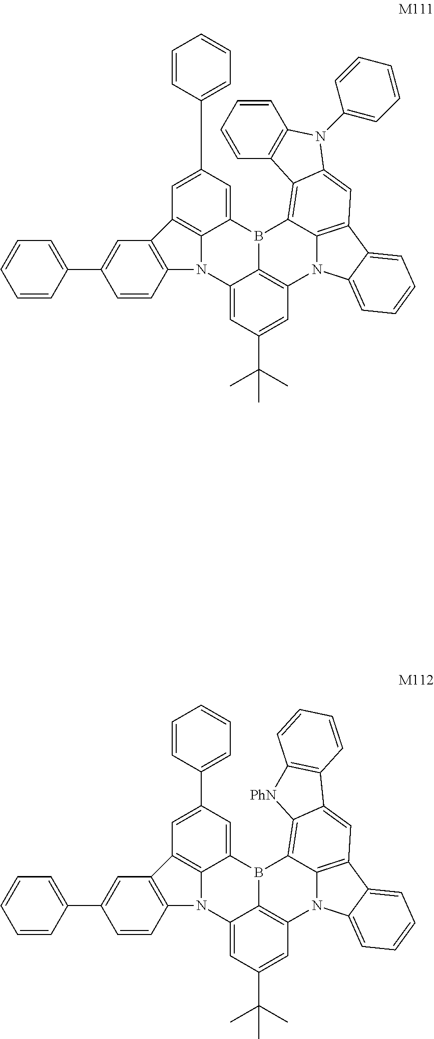

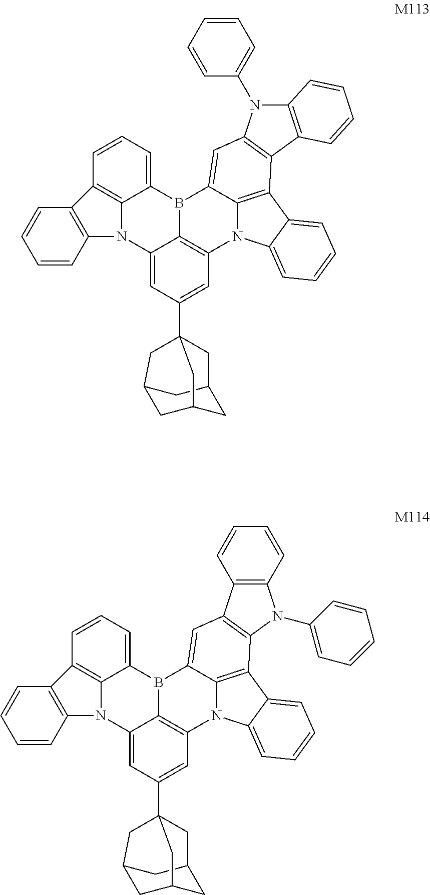 [SMILES: c1ccc(-n2c3ccccc3c3c4c5ccccc5n5c4c(cc32)B2c3c(cc(C46CC7CC(CC(C7)C4)C6)cc3-5)-n3c4ccccc4c4cccc2c43)cc1 ; c1ccc(-n2c3ccccc3c3cc4c5c(c6ccccc6n5-c5cc(C67CC8CC(CC(C8)C6)C7)cc6c5B4c4cccc5c7ccccc7n-6c45)c32)cc1]

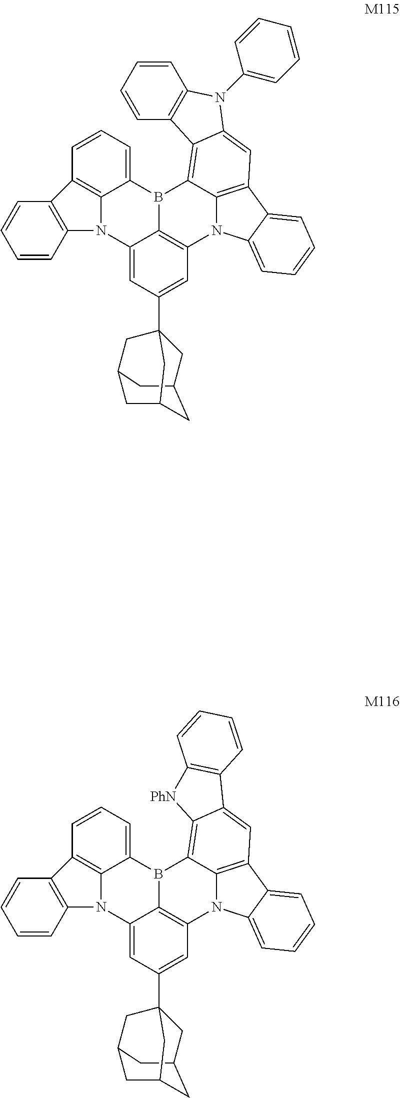

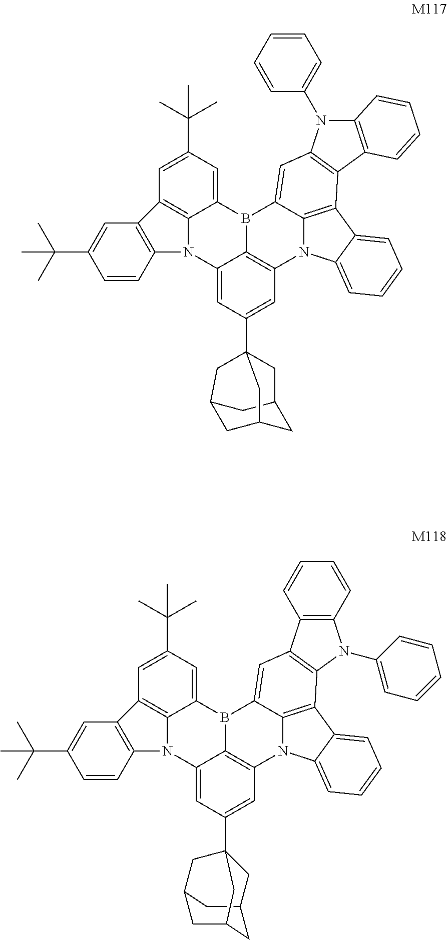 [SMILES: CC(C)(C)c1ccc2c(c1)c1cc(C(C)(C)C)cc3c1n2-c1cc(C24CC5CC(CC(C5)C2)C4)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(C24CC5CC(CC(C5)C2)C4)cc2c1B3c1cc3c4ccccc4n(-c4ccccc4)c3c3c4ccccc4n-2c13]

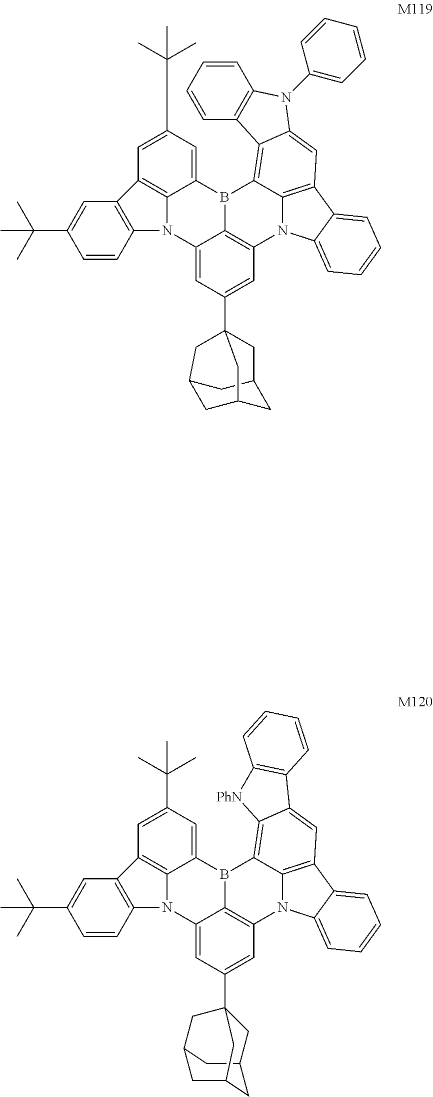

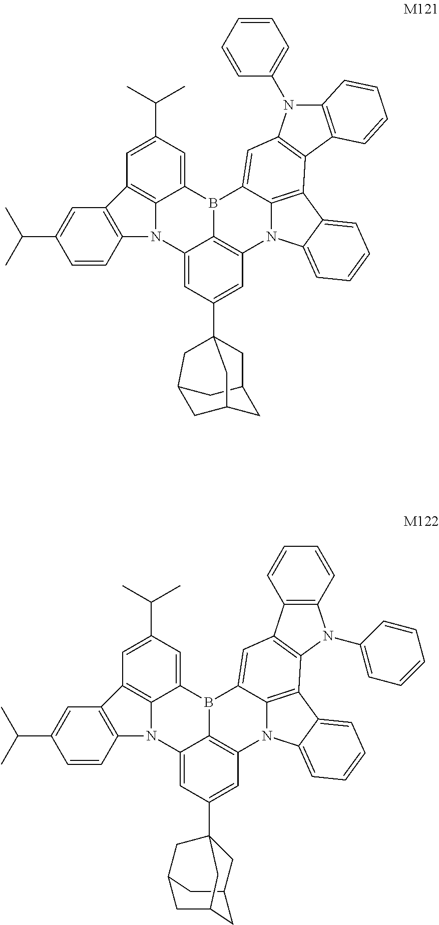 [SMILES: CC(C)c1ccc2c(c1)c1cc(C(C)C)cc3c1n2-c1cc(C24CC5CC(CC(C5)C2)C4)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(C24CC5CC(CC(C5)C2)C4)cc2c1B3c1cc3c4ccccc4n(-c4ccccc4)c3c3c4ccccc4n-2c13]

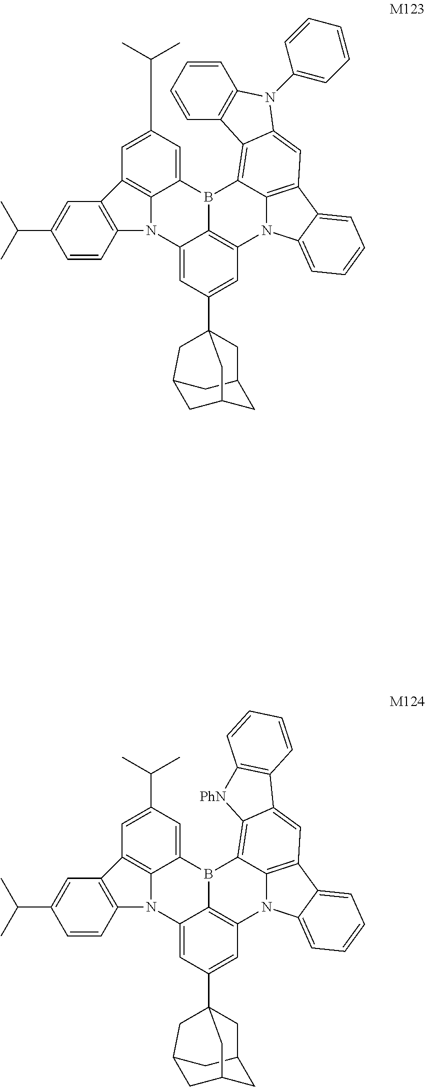

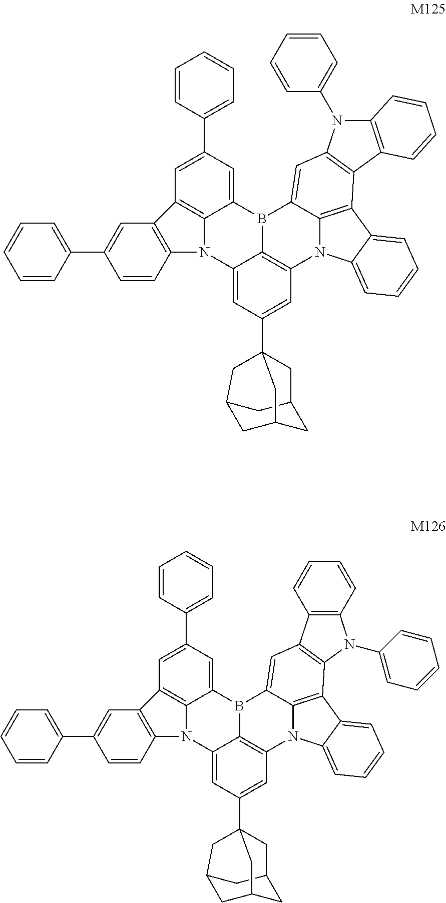 [SMILES: c1ccc(-c2ccc3c(c2)c2cc(-c4ccccc4)cc4c2n3-c2cc(C35CC6CC(CC(C6)C3)C5)cc3c2B4c2cc4c(c5ccccc5n4-c4ccccc4)c4c5ccccc5n-3c24)cc1 ; c1ccc(-c2ccc3c(c2)c2cc(-c4ccccc4)cc4c2n3-c2cc(C35CC6CC(CC(C6)C3)C5)cc3c2B4c2cc4c5ccccc5n(-c5ccccc5)c4c4c5ccccc5n-3c24)cc1]

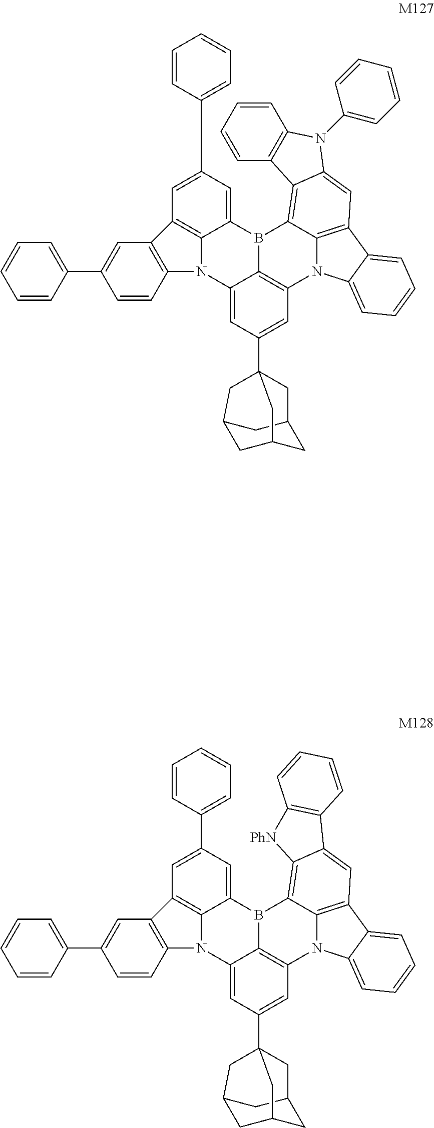

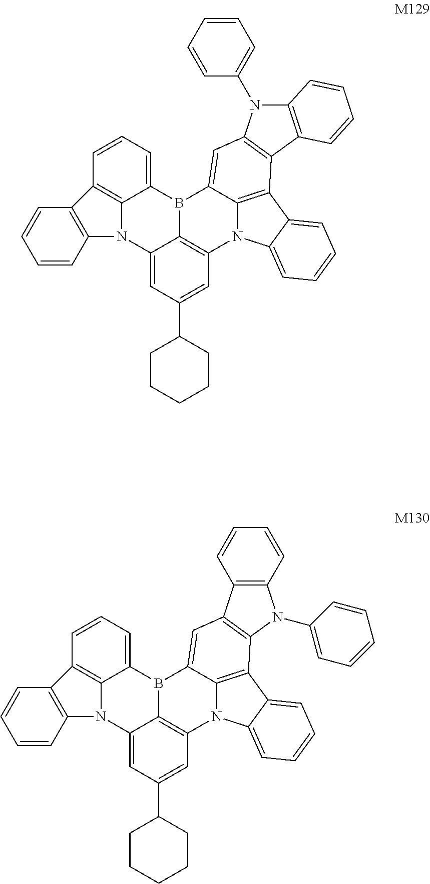 [SMILES: c1ccc(-n2c3ccccc3c3c4c5ccccc5n5c4c(cc32)B2c3c(cc(C4CCCCC4)cc3-5)-n3c4ccccc4c4cccc2c43)cc1 ; c1ccc(-n2c3ccccc3c3cc4c5c(c6ccccc6n5-c5cc(C6CCCCC6)cc6c5B4c4cccc5c7ccccc7n-6c45)c32)cc1]

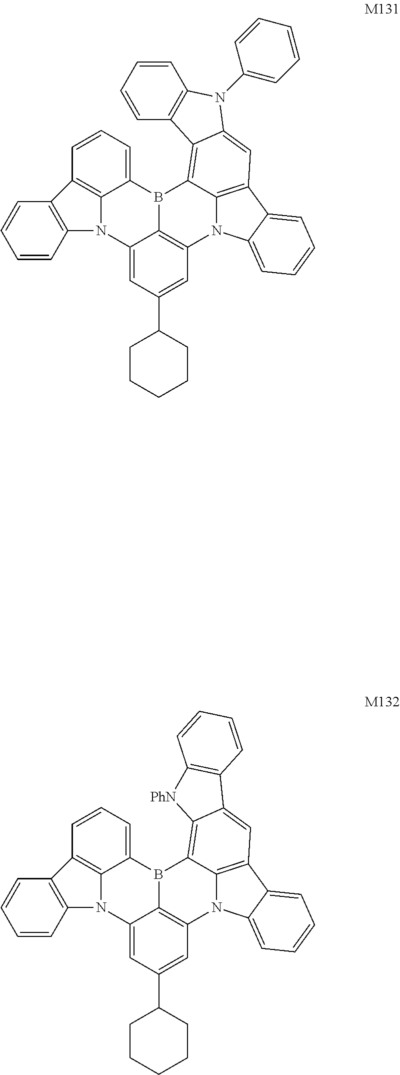

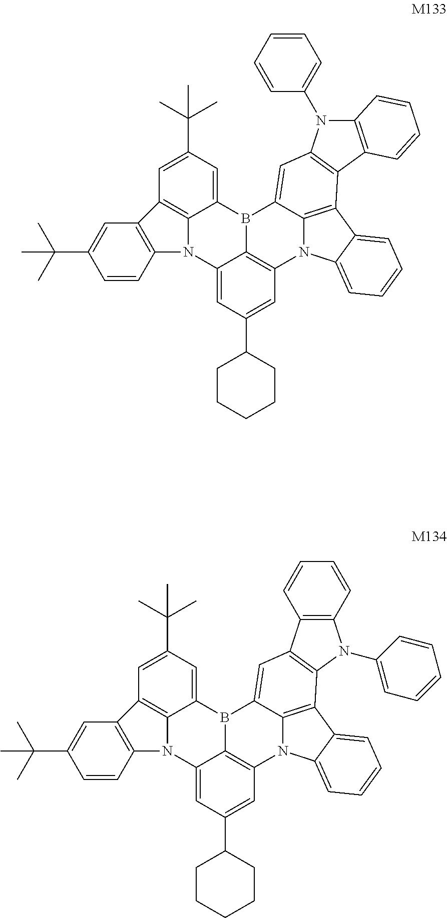 [SMILES: CC(C)(C)c1ccc2c(c1)c1cc(C(C)(C)C)cc3c1n2-c1cc(C2CCCCC2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(C2CCCCC2)cc2c1B3c1cc3c4ccccc4n(-c4ccccc4)c3c3c4ccccc4n-2c13]

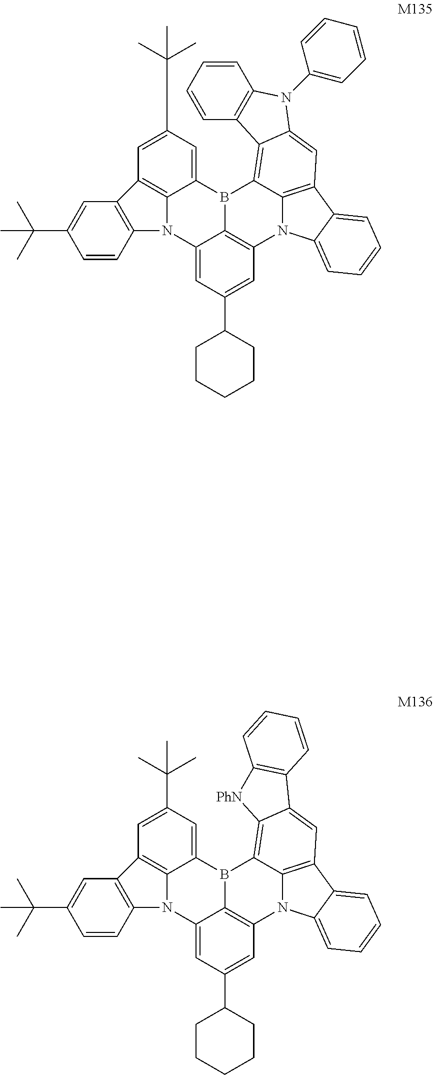

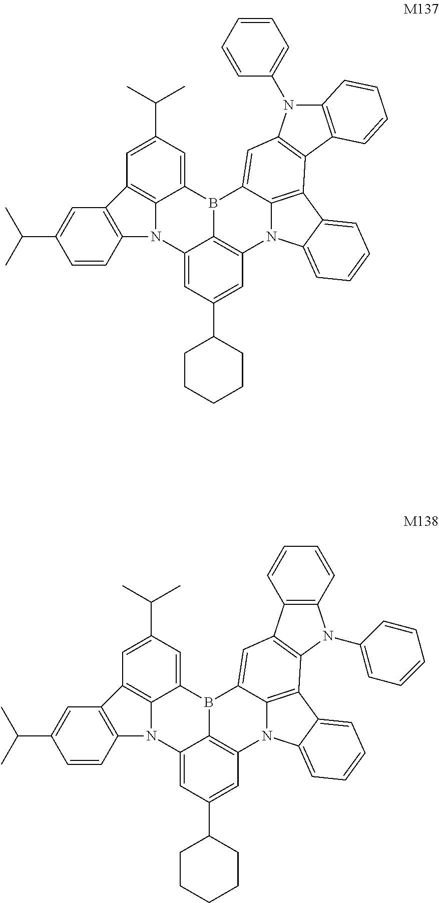 [SMILES: CC(C)c1ccc2c(c1)c1cc(C(C)C)cc3c1n2-c1cc(C2CCCCC2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(C2CCCCC2)cc2c1B3c1cc3c4ccccc4n(-c4ccccc4)c3c3c4ccccc4n-2c13]

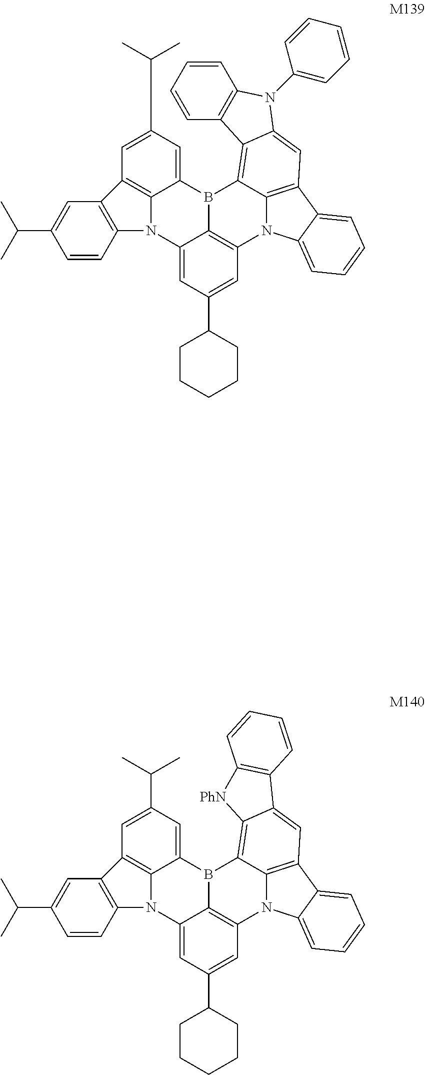

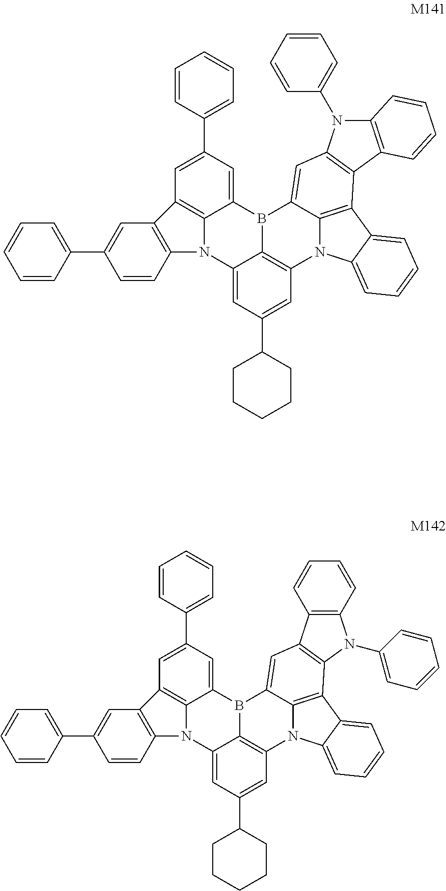 [SMILES: c1ccc(-c2ccc3c(c2)c2cc(-c4ccccc4)cc4c2n3-c2cc(C3CCCCC3)cc3c2B4c2cc4c(c5ccccc5n4-c4ccccc4)c4c5ccccc5n-3c24)cc1 ; c1ccc(-c2ccc3c(c2)c2cc(-c4ccccc4)cc4c2n3-c2cc(C3CCCCC3)cc3c2B4c2cc4c5ccccc5n(-c5ccccc5)c4c4c5ccccc5n-3c24)cc1]

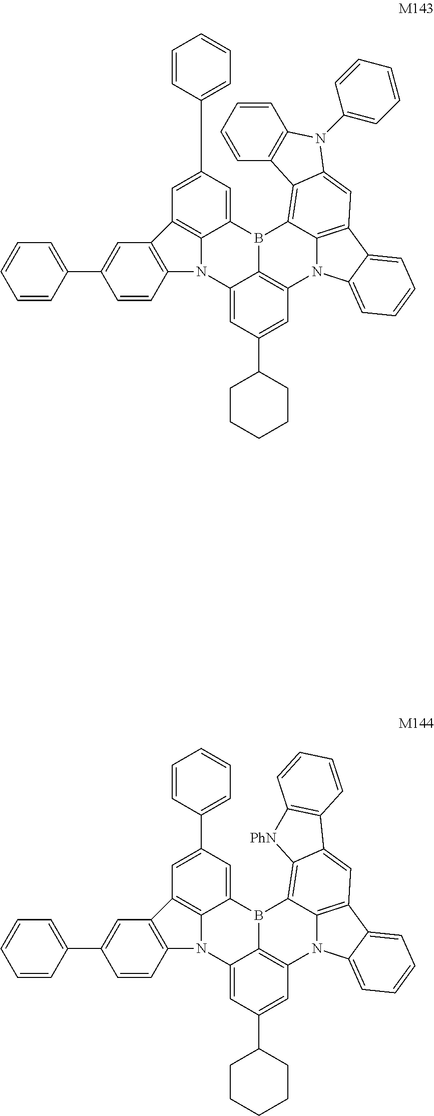

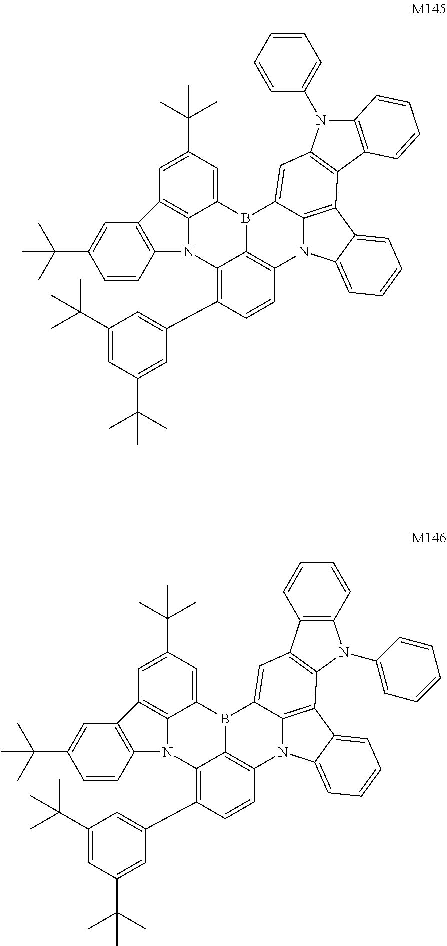 [SMILES: CC(C)(C)c1cc(-c2ccc3c4c2-n2c5ccc(C(C)(C)C)cc5c5cc(C(C)(C)C)cc(c52)B4c2cc4c(c5ccccc5n4-c4ccccc4)c4c5ccccc5n-3c24)cc(C(C)(C)C)c1 ; CC(C)(C)c1cc(-c2ccc3c4c2-n2c5ccc(C(C)(C)C)cc5c5cc(C(C)(C)C)cc(c52)B4c2cc4c5ccccc5n(-c5ccccc5)c4c4c5ccccc5n-3c24)cc(C(C)(C)C)c1]

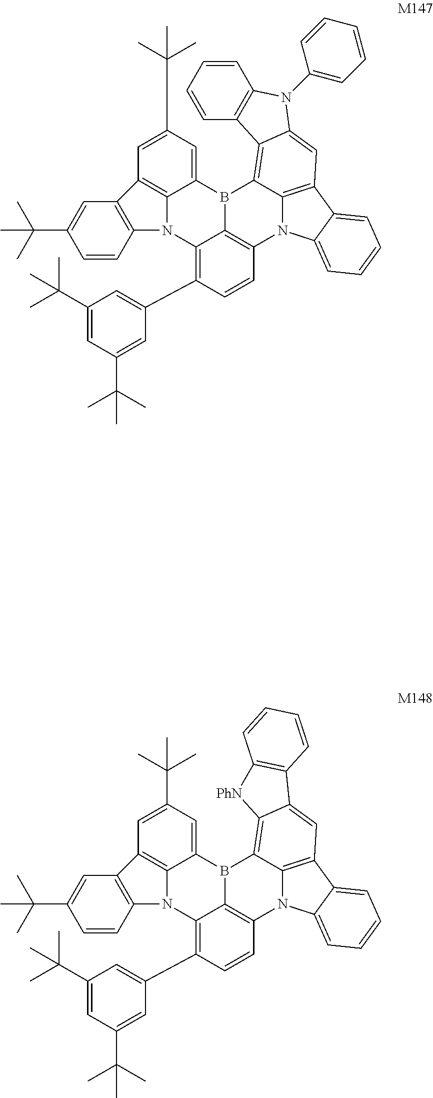

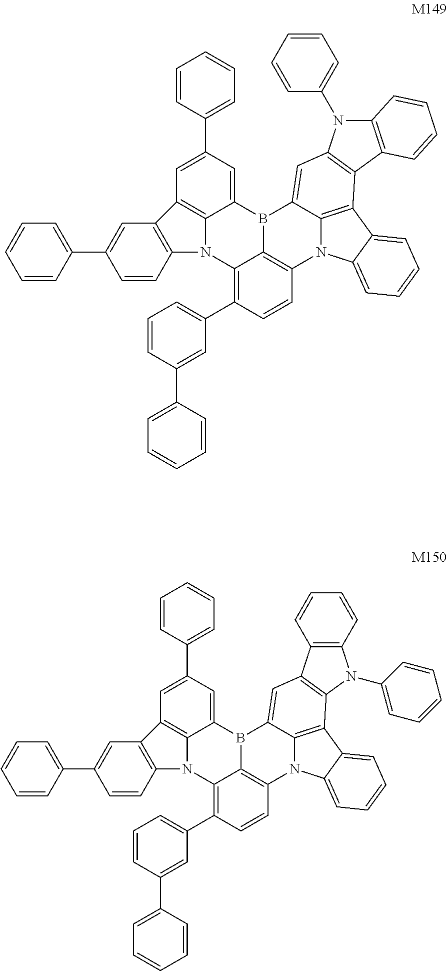 [SMILES: c1ccc(-c2cccc(-c3ccc4c5c3-n3c6ccc(-c7ccccc7)cc6c6cc(-c7ccccc7)cc(c63)B5c3cc5c(c6ccccc6n5-c5ccccc5)c5c6ccccc6n-4c35)c2)cc1 ; c1ccc(-c2cccc(-c3ccc4c5c3-n3c6ccc(-c7ccccc7)cc6c6cc(-c7ccccc7)cc(c63)B5c3cc5c6ccccc6n(-c6ccccc6)c5c5c6ccccc6n-4c35)c2)cc1]

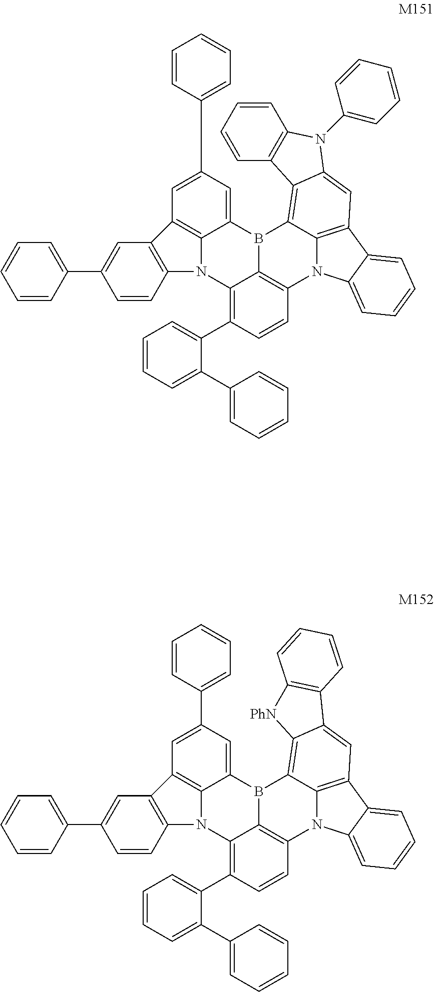

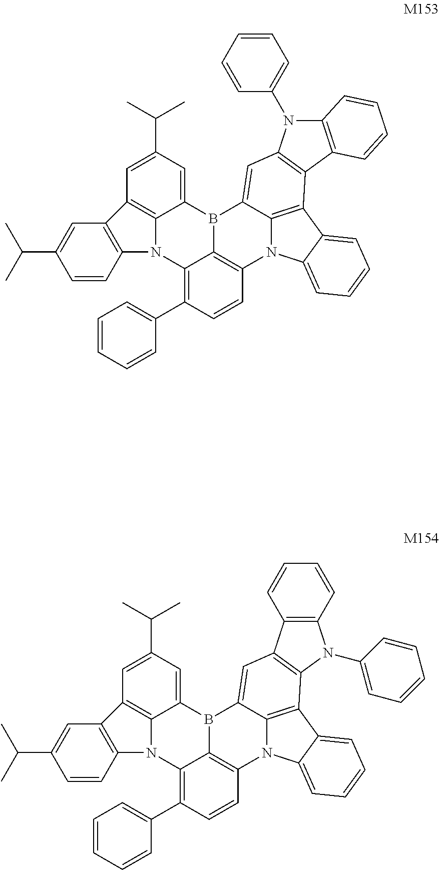 [SMILES: CC(C)c1ccc2c(c1)c1cc(C(C)C)cc3c1n2-c1c(-c2ccccc2)ccc2c1B3c1cc3c(c4ccccc4n3-c3ccccc3)c3c4ccccc4n-2c13 ; CC(C)c1ccc2c(c1)c1cc(C(C)C)cc3c1n2-c1c(-c2ccccc2)ccc2c1B3c1cc3c4ccccc4n(-c4ccccc4)c3c3c4ccccc4n-2c13]

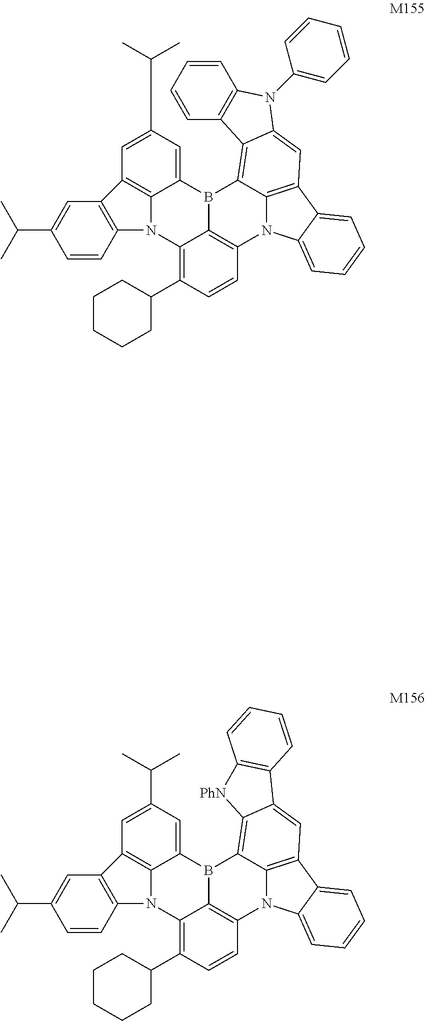

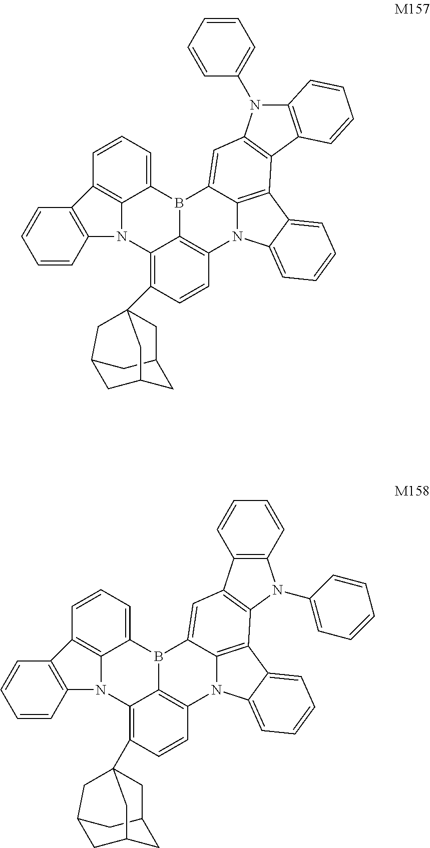 [SMILES: c1ccc(-n2c3ccccc3c3c4c5ccccc5n5c4c(cc32)B2c3c-5ccc(C45CC6CC(CC(C6)C4)C5)c3-n3c4ccccc4c4cccc2c43)cc1 ; c1ccc(-n2c3ccccc3c3cc4c5c(c6ccccc6n5-c5ccc(C67CC8CC(CC(C8)C6)C7)c6c5B4c4cccc5c7ccccc7n-6c45)c32)cc1]

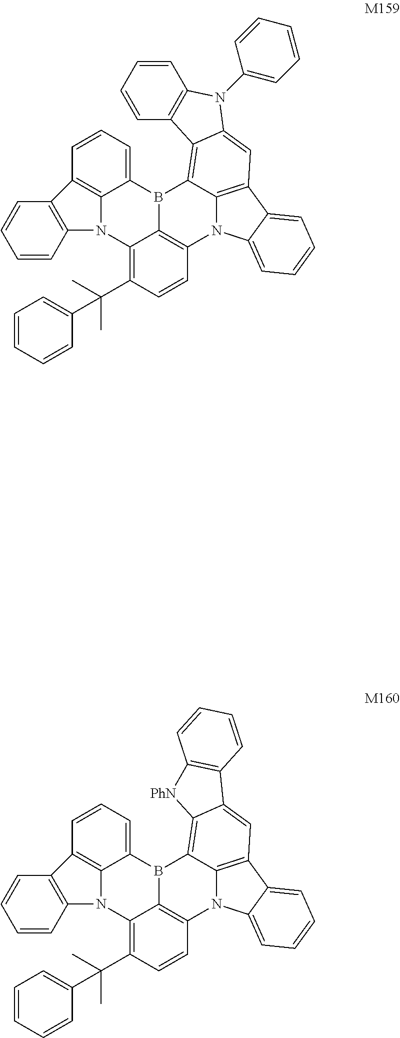

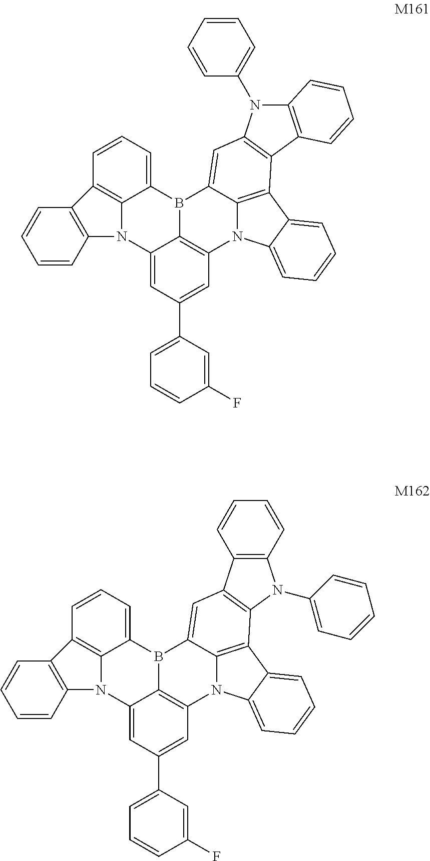 [SMILES: Fc1cccc(-c2cc3c4c(c2)-n2c5ccccc5c5c6c7ccccc7n(-c7ccccc7)c6cc(c52)B4c2cccc4c5ccccc5n-3c24)c1 ; Fc1cccc(-c2cc3c4c(c2)-n2c5ccccc5c5c2c(cc2c6ccccc6n(-c6ccccc6)c25)B4c2cccc4c5ccccc5n-3c24)c1]

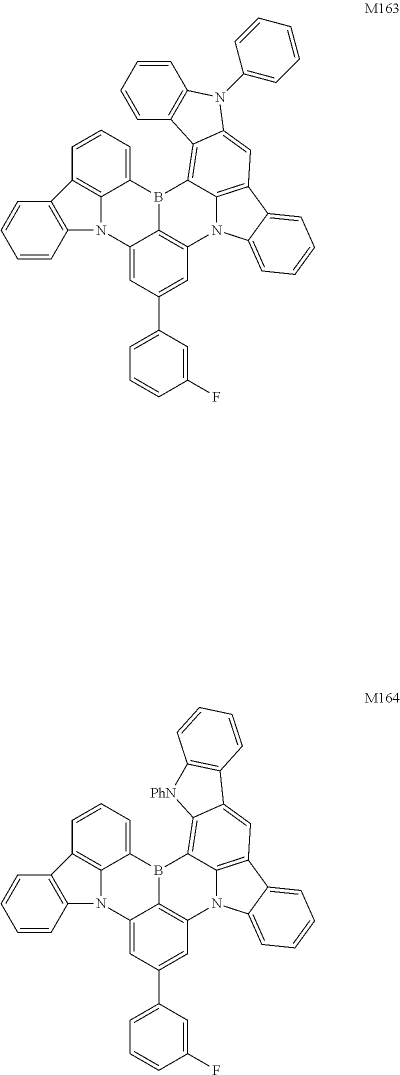

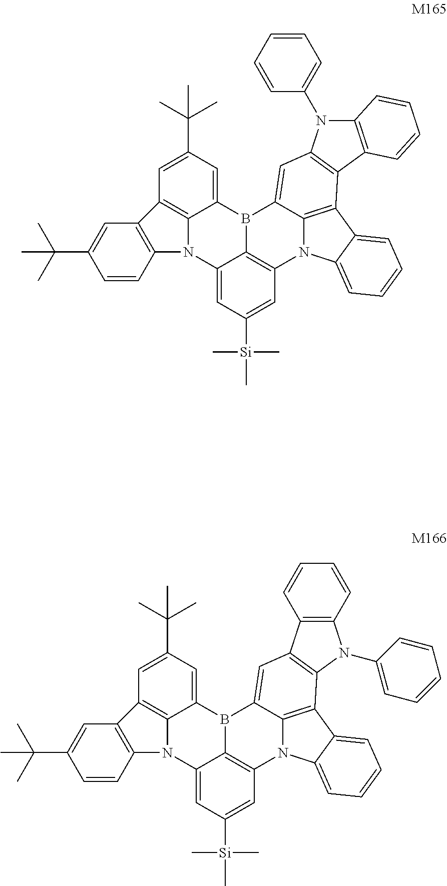 [SMILES: CC(C)(C)c1ccc2c(c1)c1cc(C(C)(C)C)cc3c1n2-c1cc([Si](C)(C)C)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc([Si](C)(C)C)cc2c1B3c1cc3c4ccccc4n(-c4ccccc4)c3c3c4ccccc4n-2c13]

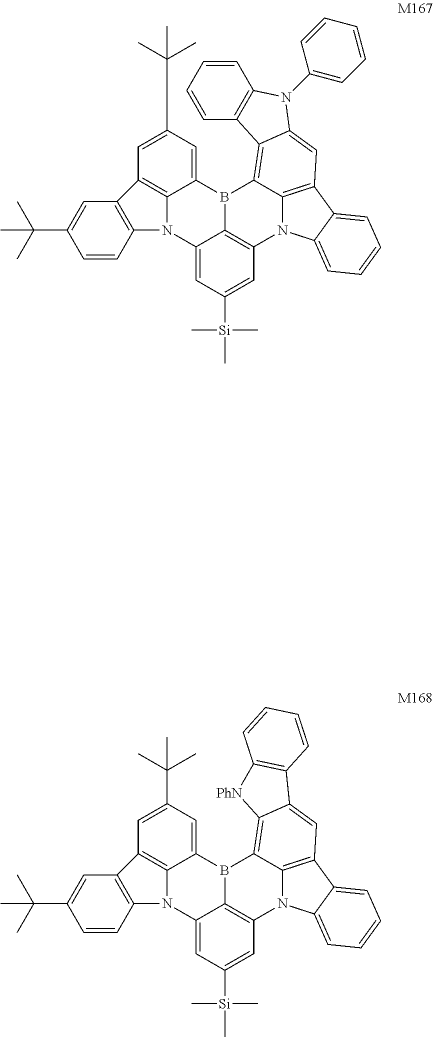

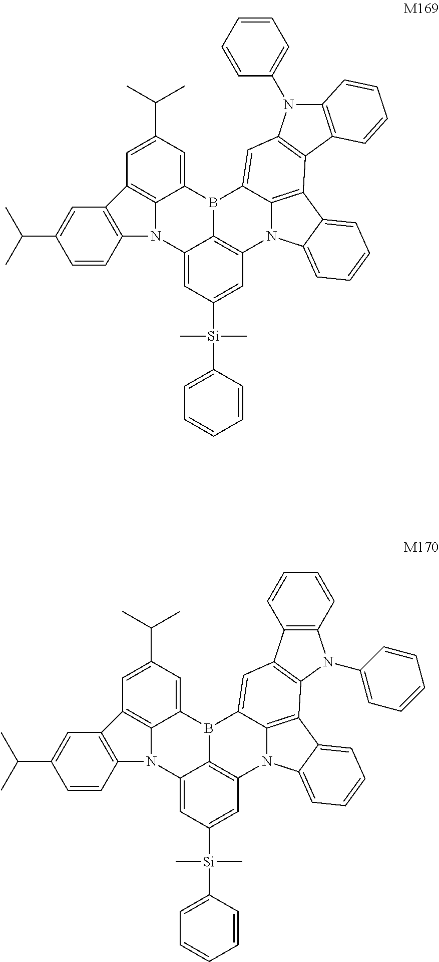 [SMILES: CC(C)c1ccc2c(c1)c1cc(C(C)C)cc3c1n2-c1cc([Si](C)(C)c2ccccc2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc([Si](C)(C)c2ccccc2)cc2c1B3c1cc3c4ccccc4n(-c4ccccc4)c3c3c4ccccc4n-2c13]

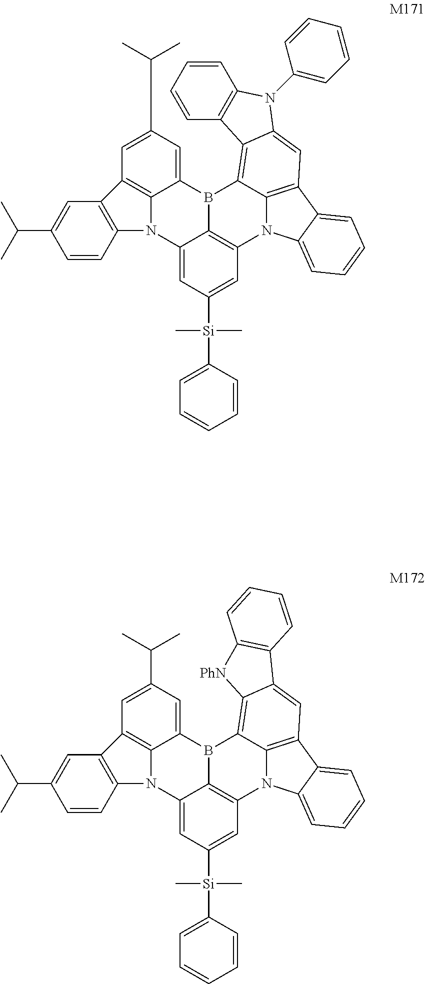

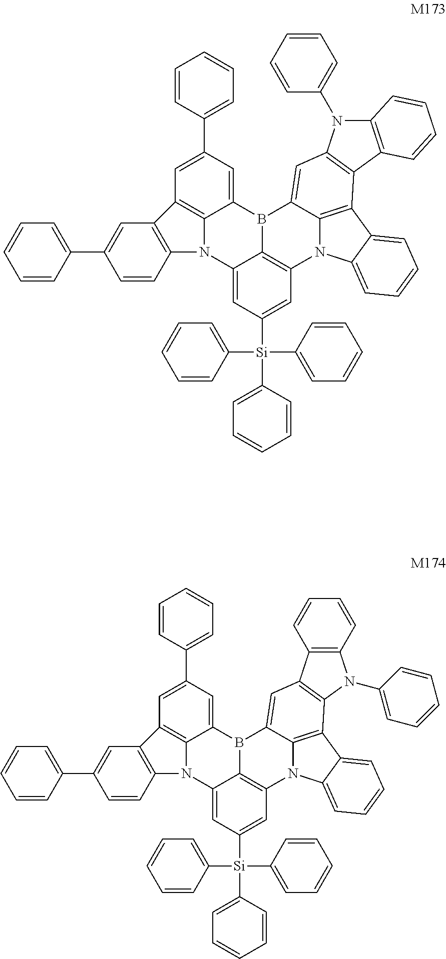 [SMILES: c1ccc(-c2ccc3c(c2)c2cc(-c4ccccc4)cc4c2n3-c2cc([Si](c3ccccc3)(c3ccccc3)c3ccccc3)cc3c2B4c2cc4c(c5ccccc5n4-c4ccccc4)c4c5ccccc5n-3c24)cc1 ; c1ccc(-c2ccc3c(c2)c2cc(-c4ccccc4)cc4c2n3-c2cc([Si](c3ccccc3)(c3ccccc3)c3ccccc3)cc3c2B4c2cc4c5ccccc5n(-c5ccccc5)c4c4c5ccccc5n-3c24)cc1]

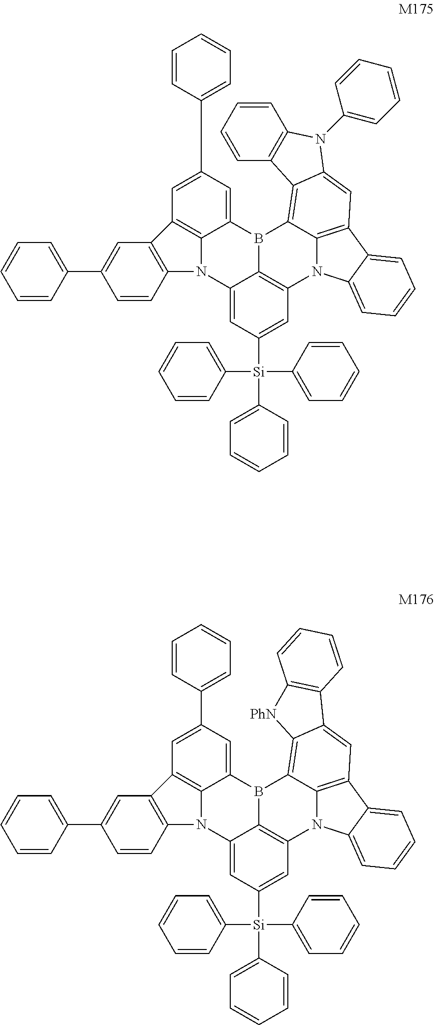

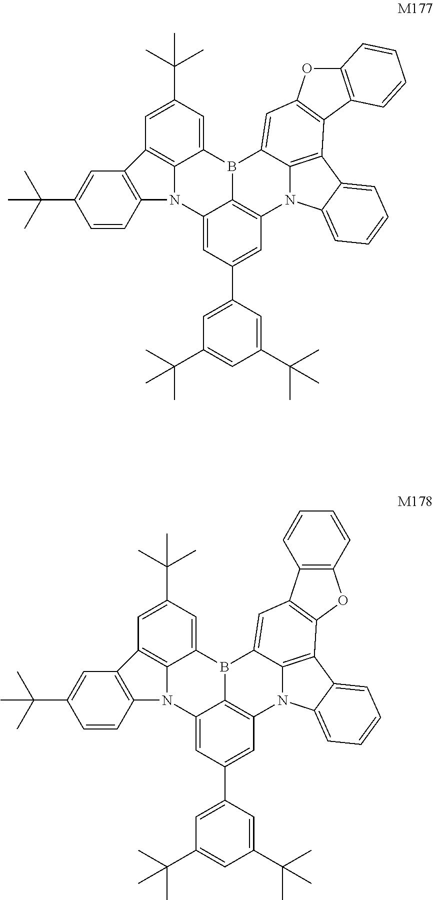 [SMILES: CC(C)(C)c1cc(-c2cc3c4c(c2)-n2c5ccccc5c5c6c(cc(c52)B4c2cc(C(C)(C)C)cc4c5cc(C(C)(C)C)ccc5n-3c24)oc2ccccc26)cc(C(C)(C)C)c1 ; CC(C)(C)c1cc(-c2cc3c4c(c2)-n2c5ccccc5c5c6oc7ccccc7c6cc(c52)B4c2cc(C(C)(C)C)cc4c5cc(C(C)(C)C)ccc5n-3c24)cc(C(C)(C)C)c1]

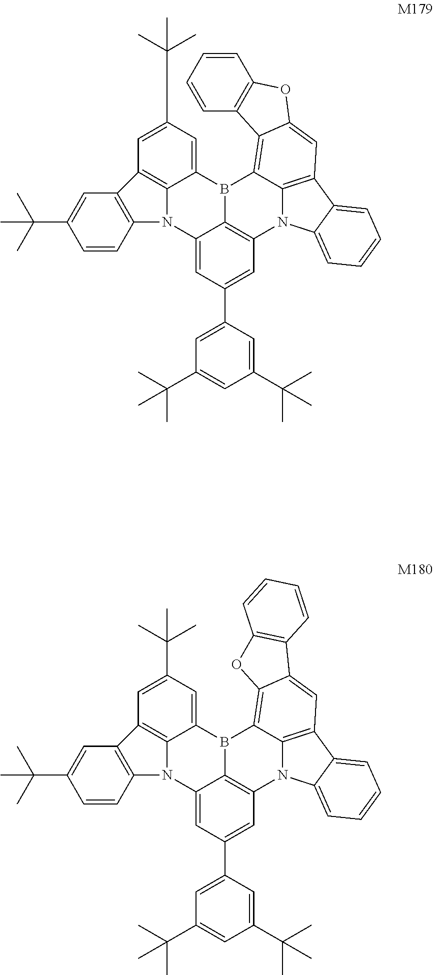 [SMILES: CC(C)(C)c1cc(-c2cc3c4c(c2)-n2c5ccccc5c5cc6oc7ccccc7c6c(c52)B4c2cc(C(C)(C)C)cc4c5cc(C(C)(C)C)ccc5n-3c24)cc(C(C)(C)C)c1 ; CC(C)(C)c1cc(-c2cc3c4c(c2)-n2c5ccccc5c5cc6c(oc7ccccc76)c(c52)B4c2cc(C(C)(C)C)cc4c5cc(C(C)(C)C)ccc5n-3c24)cc(C(C)(C)C)c1]

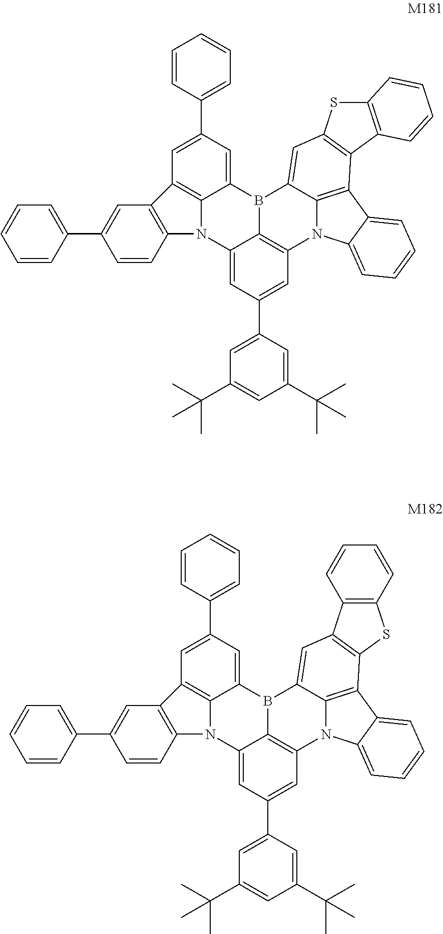 [SMILES: CC(C)(C)c1cc(-c2cc3c4c(c2)-n2c5ccccc5c5c6c(cc(c52)B4c2cc(-c4ccccc4)cc4c5cc(-c7ccccc7)ccc5n-3c24)sc2ccccc26)cc(C(C)(C)C)c1 ; CC(C)(C)c1cc(-c2cc3c4c(c2)-n2c5ccccc5c5c6sc7ccccc7c6cc(c52)B4c2cc(-c4ccccc4)cc4c5cc(-c6ccccc6)ccc5n-3c24)cc(C(C)(C)C)c1]

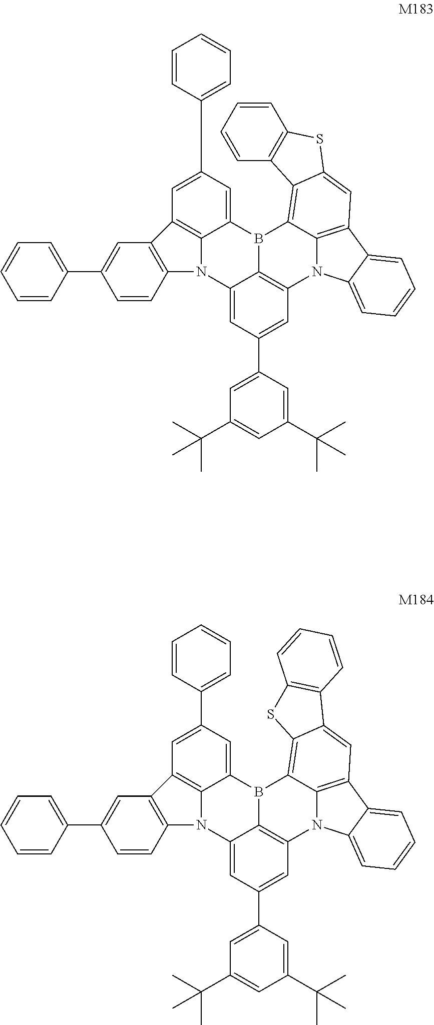 [SMILES: CC(C)(C)c1cc(-c2cc3c4c(c2)-n2c5ccccc5c5cc6sc7ccccc7c6c(c52)B4c2cc(-c4ccccc4)cc4c5cc(-c6ccccc6)ccc5n-3c24)cc(C(C)(C)C)c1 ; CC(C)(C)c1cc(-c2cc3c4c(c2)-n2c5ccccc5c5cc6c(sc7ccccc76)c(c52)B4c2cc(-c4ccccc4)cc4c5cc(-c6ccccc6)ccc5n-3c24)cc(C(C)(C)C)c1]

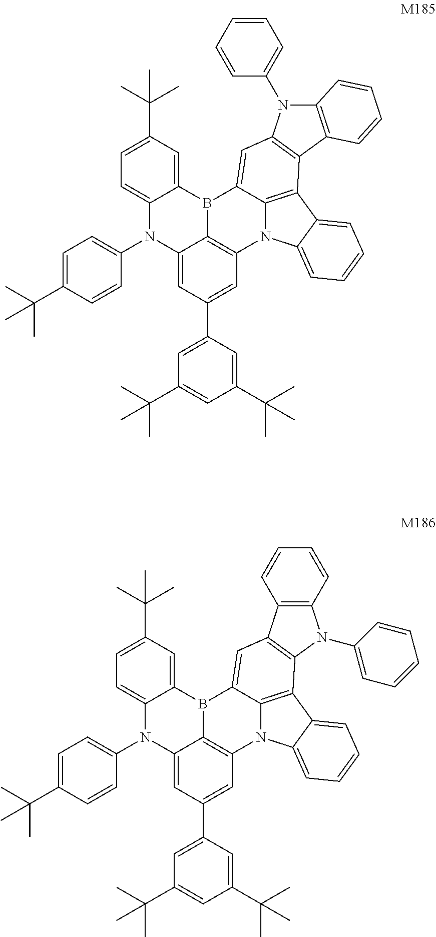 [SMILES: CC(C)(C)c1ccc(N2c3ccc(C(C)(C)C)cc3B3c4c2cc(-c2cc(C(C)(C)C)cc(C(C)(C)C)c2)cc4-n2c4ccccc4c4c5c6ccccc6n(-c6ccccc6)c5cc3c42)cc1 ; CC(C)(C)c1ccc(N2c3ccc(C(C)(C)C)cc3B3c4c2cc(-c2cc(C(C)(C)C)cc(C(C)(C)C)c2)cc4-n2c4ccccc4c4c2c3cc2c3ccccc3n(-c3ccccc3)c24)cc1]

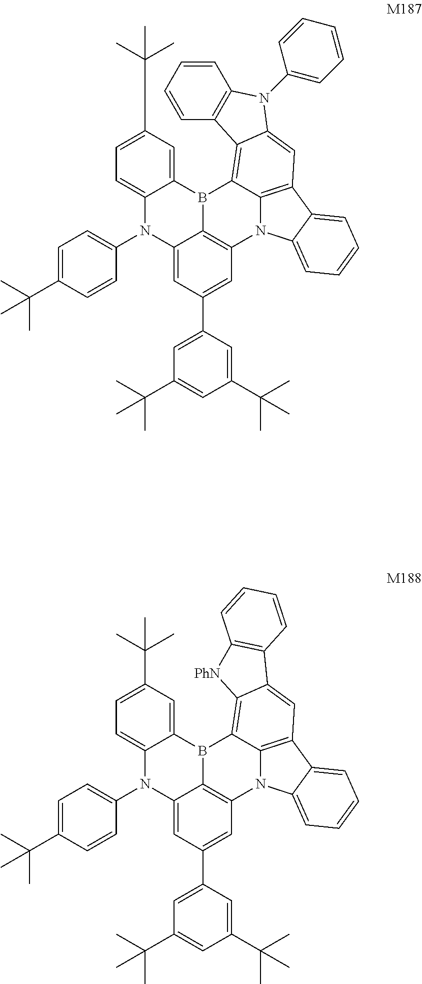

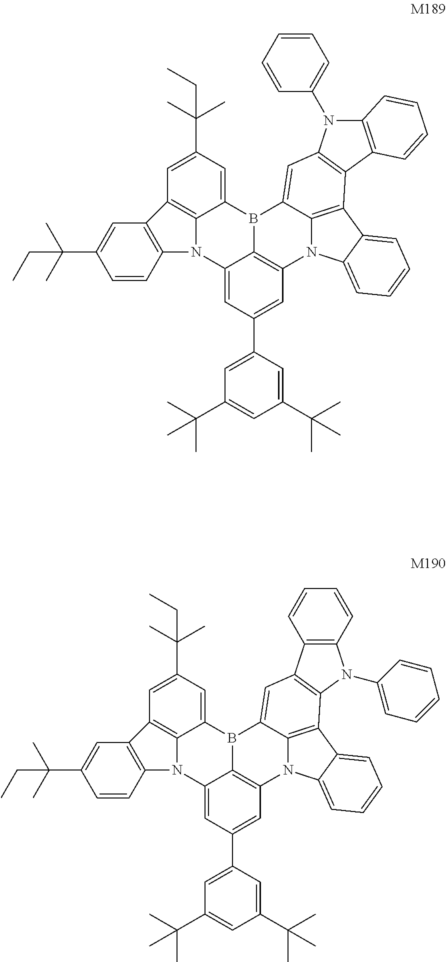 [SMILES: CCC(C)(C)c1ccc2c(c1)c1cc(C(C)(C)CC)cc3c1n2-c1cc(-c2cc(C(C)(C)C)cc(C(C)(C)C)c2)cc2c1B3c1cc3c(c4ccccc4n3-c3ccccc3)c3c4ccccc4n-2c13 ; CCC(C)(C)c1ccc2c(c1)c1cc(C(C)(C)CC)cc3c1n2-c1cc(-c2cc(C(C)(C)C)cc(C(C)(C)C)c2)cc2c1B3c1cc3c4ccccc4n(-c4ccccc4)c3c3c4ccccc4n-2c13]

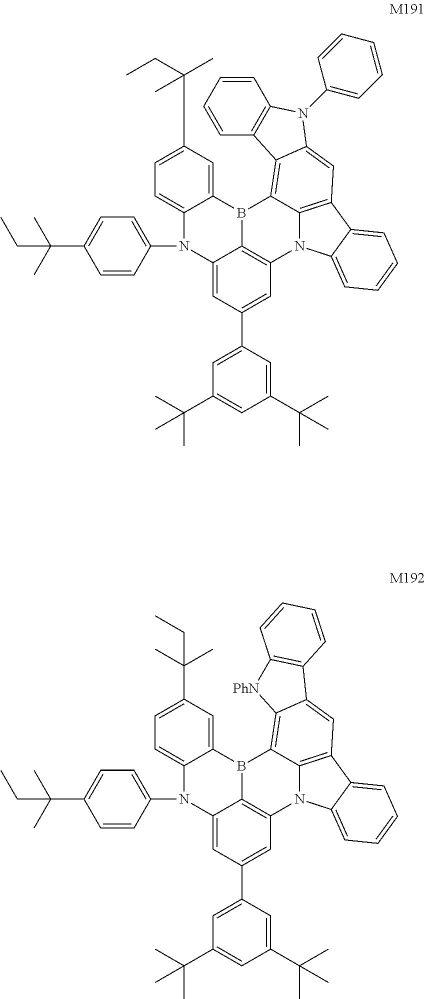

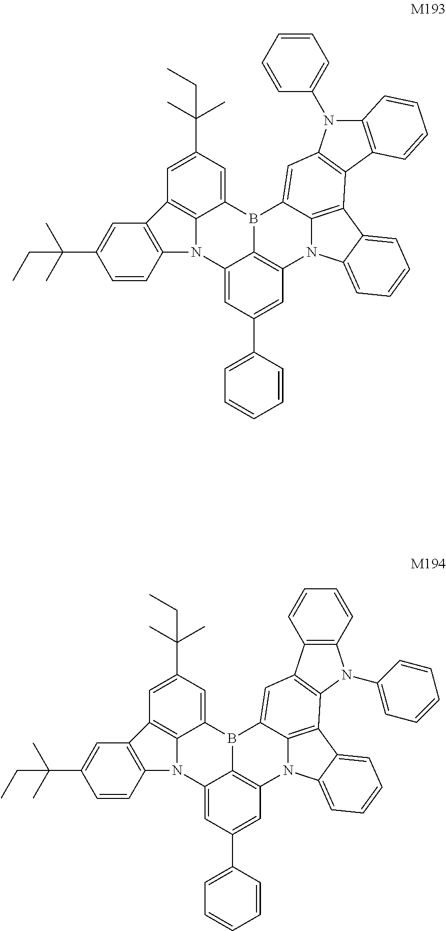 [SMILES: CCC(C)(C)c1ccc2c(c1)c1cc(C(C)(C)CC)cc3c1n2-c1cc(-c2ccccc2)cc2c1B3c1cc3c(c4ccccc4n3-c3ccccc3)c3c4ccccc4n-2c13 ; CCC(C)(C)c1ccc2c(c1)c1cc(C(C)(C)CC)cc3c1n2-c1cc(-c2ccccc2)cc2c1B3c1cc3c4ccccc4n(-c4ccccc4)c3c3c4ccccc4n-2c13]

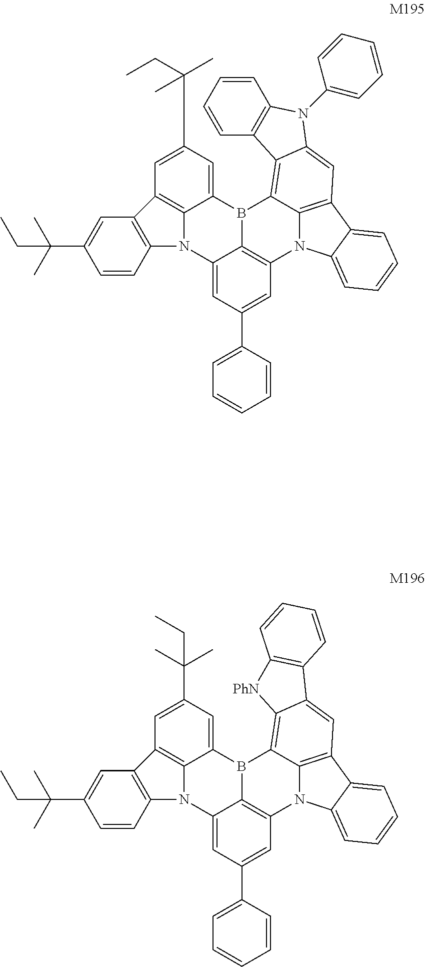

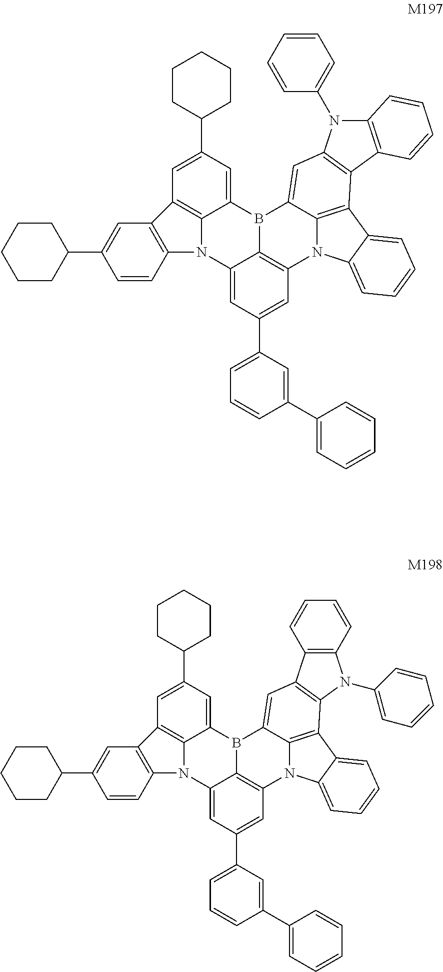 [SMILES: c1ccc(-c2cccc(-c3cc4c5c(c3)-n3c6ccccc6c6c7c8ccccc8n(-c8ccccc8)c7cc(c63)B5c3cc(C5CCCCC5)cc5c6cc(C7CCCCC7)ccc6n-4c35)c2)cc1 ; c1ccc(-c2cccc(-c3cc4c5c(c3)-n3c6ccccc6c6c3c(cc3c7ccccc7n(-c7ccccc7)c36)B5c3cc(C5CCCCC5)cc5c6cc(C7CCCCC7)ccc6n-4c35)c2)cc1]

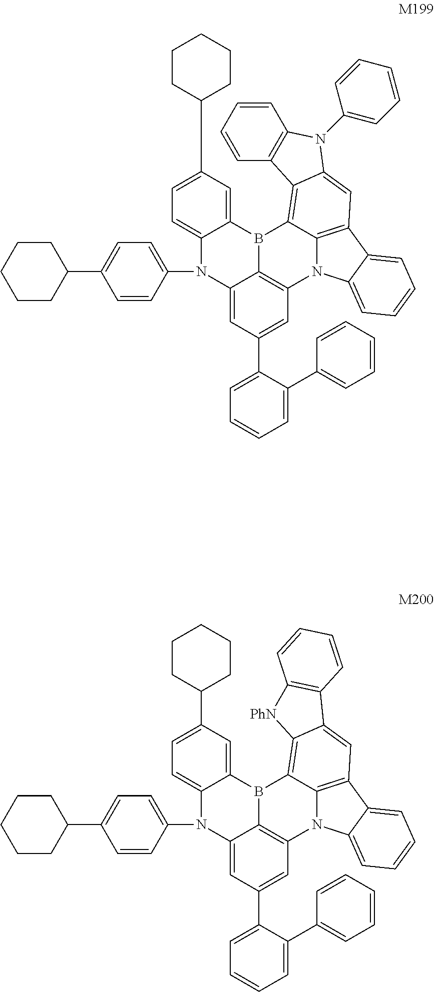

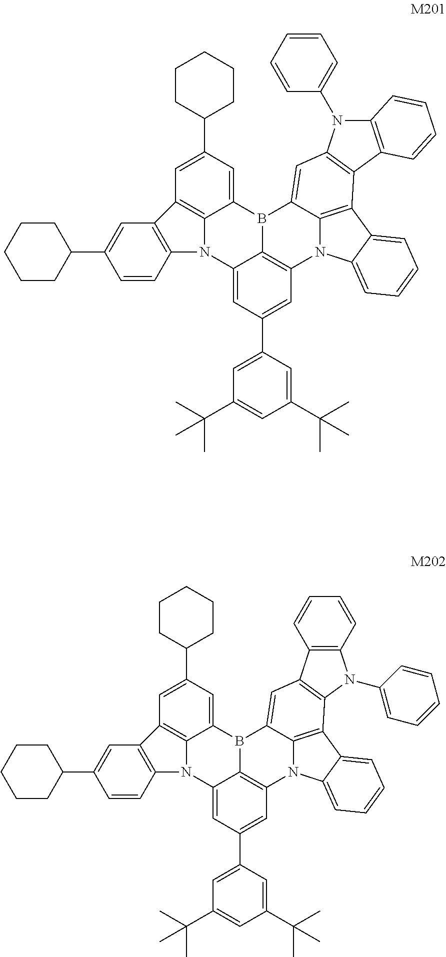 [SMILES: CC(C)(C)c1cc(-c2cc3c4c(c2)-n2c5ccccc5c5c6c7ccccc7n(-c7ccccc7)c6cc(c52)B4c2cc(C4CCCCC4)cc4c5cc(C6CCCCC6)ccc5n-3c24)cc(C(C)(C)C)c1 ; CC(C)(C)c1cc(-c2cc3c4c(c2)-n2c5ccccc5c5c2c(cc2c6ccccc6n(-c6ccccc6)c25)B4c2cc(C4CCCCC4)cc4c5cc(C6CCCCC6)ccc5n-3c24)cc(C(C)(C)C)c1]

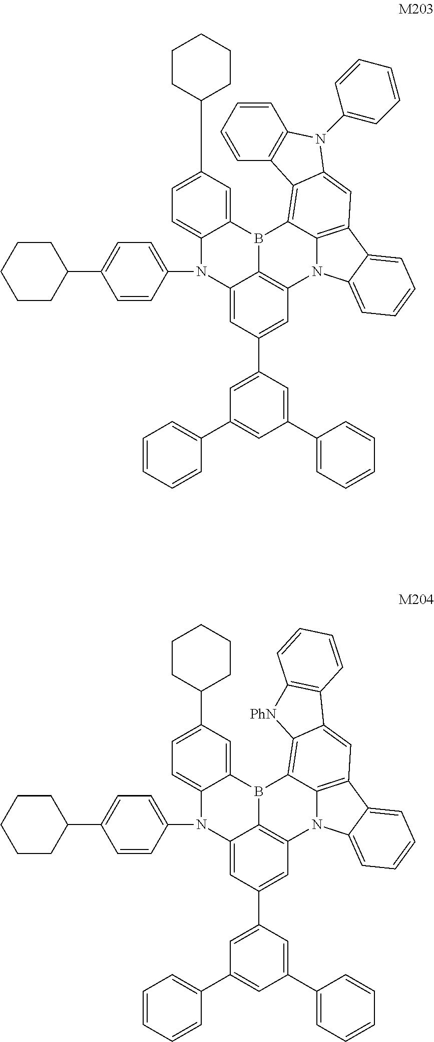

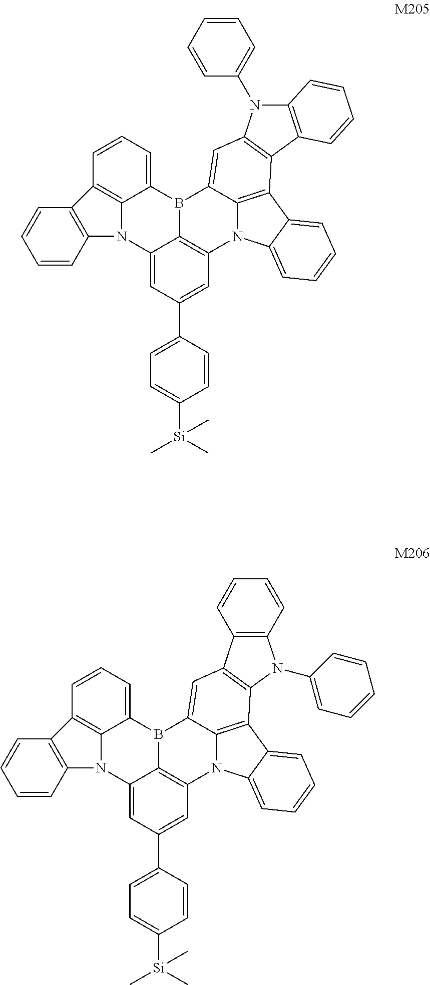 [SMILES: C[Si](C)(C)c1ccc(-c2cc3c4c(c2)-n2c5ccccc5c5c6c7ccccc7n(-c7ccccc7)c6cc(c52)B4c2cccc4c5ccccc5n-3c24)cc1 ; C[Si](C)(C)c1ccc(-c2cc3c4c(c2)-n2c5ccccc5c5c2c(cc2c6ccccc6n(-c6ccccc6)c25)B4c2cccc4c5ccccc5n-3c24)cc1]

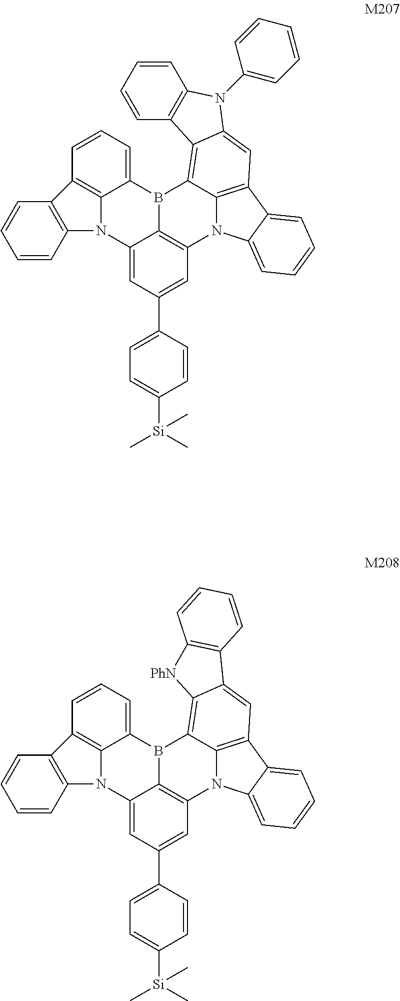

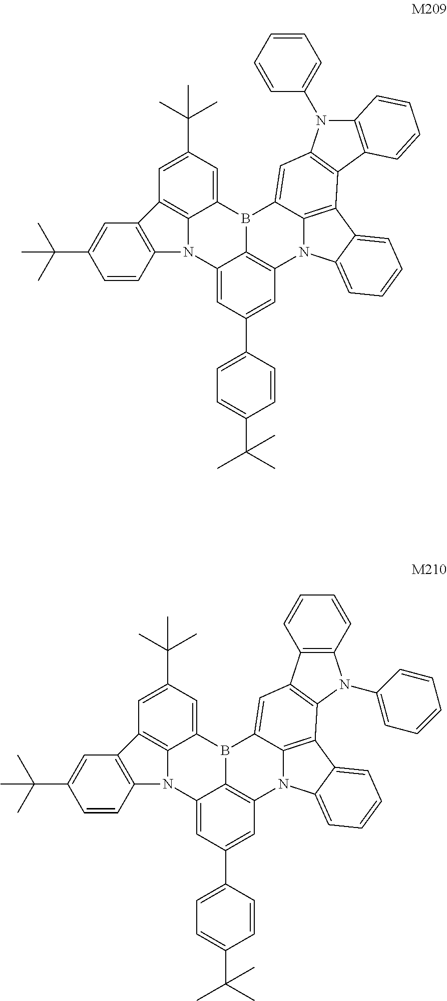 [SMILES: CC(C)(C)c1ccc(-c2cc3c4c(c2)-n2c5ccccc5c5c6c7ccccc7n(-c7ccccc7)c6cc(c52)B4c2cc(C(C)(C)C)cc4c5cc(C(C)(C)C)ccc5n-3c24)cc1 ; CC(C)(C)c1ccc(-c2cc3c4c(c2)-n2c5ccccc5c5c2c(cc2c6ccccc6n(-c6ccccc6)c25)B4c2cc(C(C)(C)C)cc4c5cc(C(C)(C)C)ccc5n-3c24)cc1]

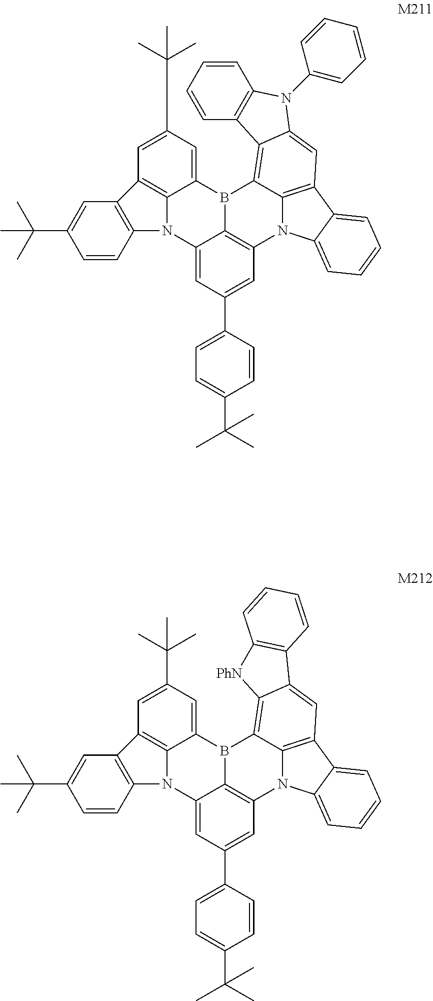

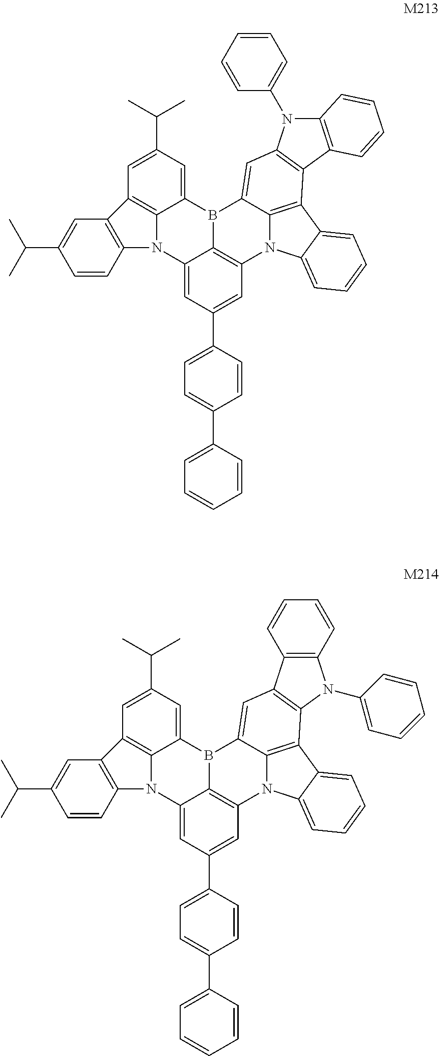 [SMILES: CC(C)c1ccc2c(c1)c1cc(C(C)C)cc3c1n2-c1cc(-c2ccc(-c4ccccc4)cc2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2ccc(-c4ccccc4)cc2)cc2c1B3c1cc3c4ccccc4n(-c4ccccc4)c3c3c4ccccc4n-2c13]

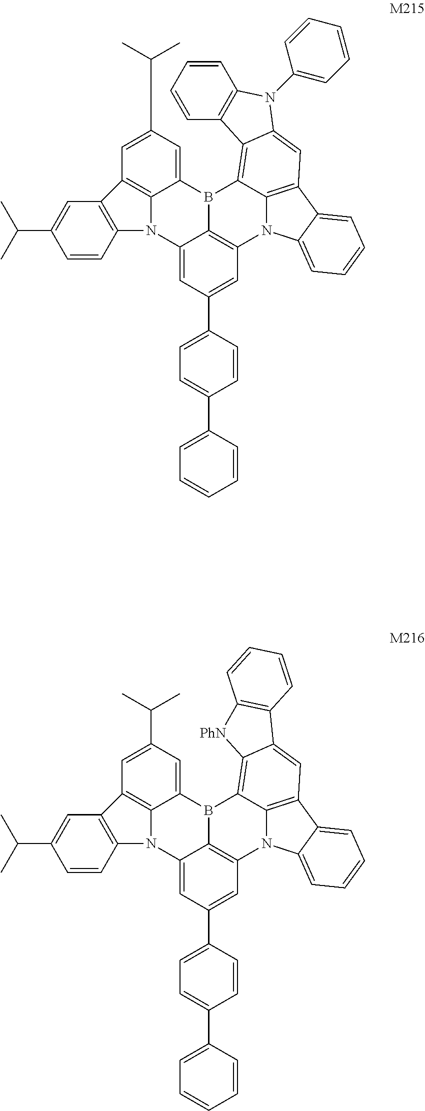

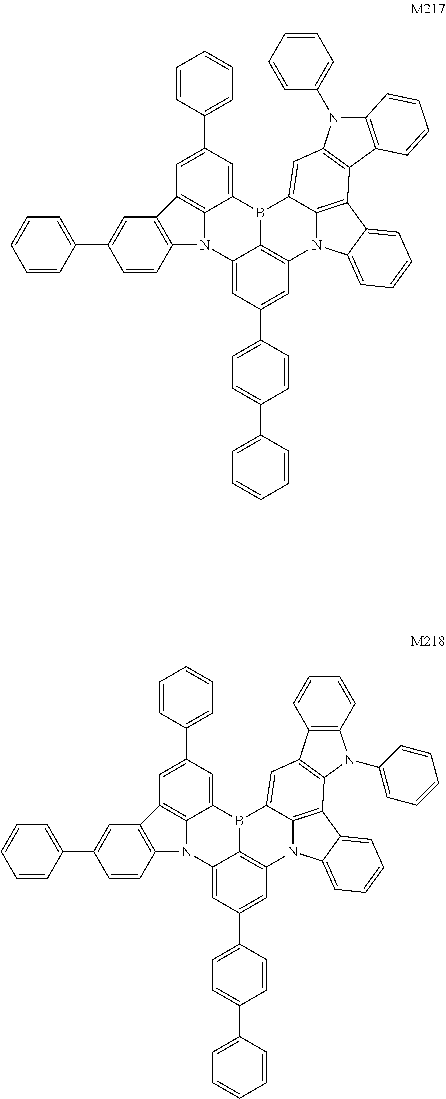 [SMILES: c1ccc(-c2ccc(-c3cc4c5c(c3)-n3c6ccccc6c6c7c8ccccc8n(-c8ccccc8)c7cc(c63)B5c3cc(-c5ccccc5)cc5c6cc(-c7ccccc7)ccc6n-4c35)cc2)cc1 ; c1ccc(-c2ccc(-c3cc4c5c(c3)-n3c6ccccc6c6c3c(cc3c7ccccc7n(-c7ccccc7)c36)B5c3cc(-c5ccccc5)cc5c6cc(-c7ccccc7)ccc6n-4c35)cc2)cc1]

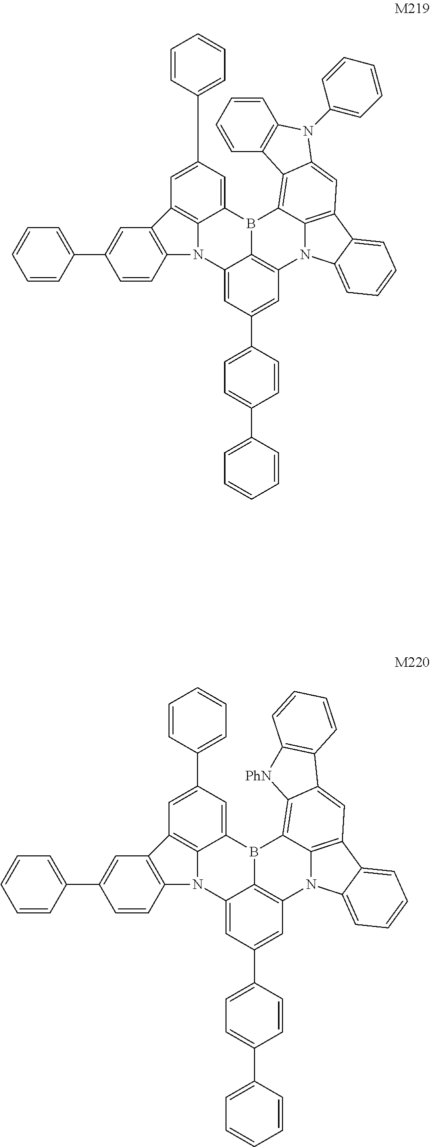

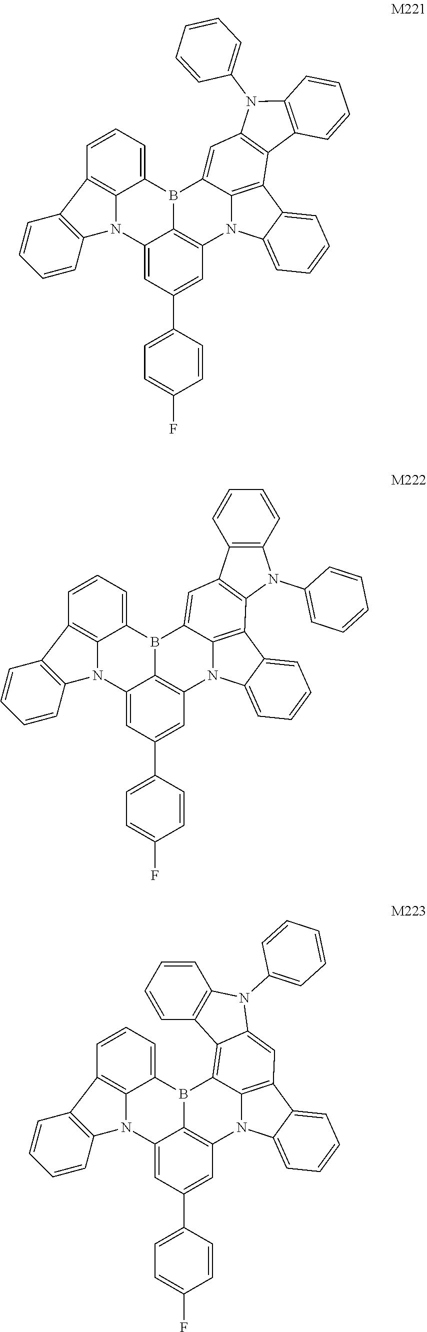 [SMILES: Fc1ccc(-c2cc3c4c(c2)-n2c5ccccc5c5c6c7ccccc7n(-c7ccccc7)c6cc(c52)B4c2cccc4c5ccccc5n-3c24)cc1 ; Fc1ccc(-c2cc3c4c(c2)-n2c5ccccc5c5c2c(cc2c6ccccc6n(-c6ccccc6)c25)B4c2cccc4c5ccccc5n-3c24)cc1 ; Fc1ccc(-c2cc3c4c(c2)-n2c5ccccc5c5cc6c(c(c52)B4c2cccc4c5ccccc5n-3c24)c2ccccc2n6-c2ccccc2)cc1]

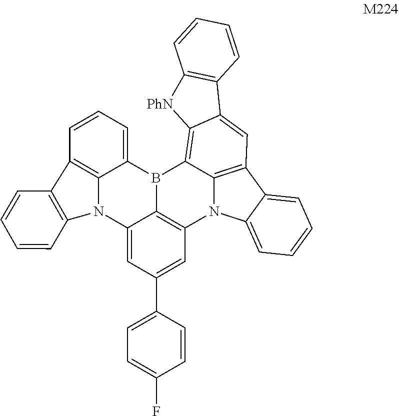

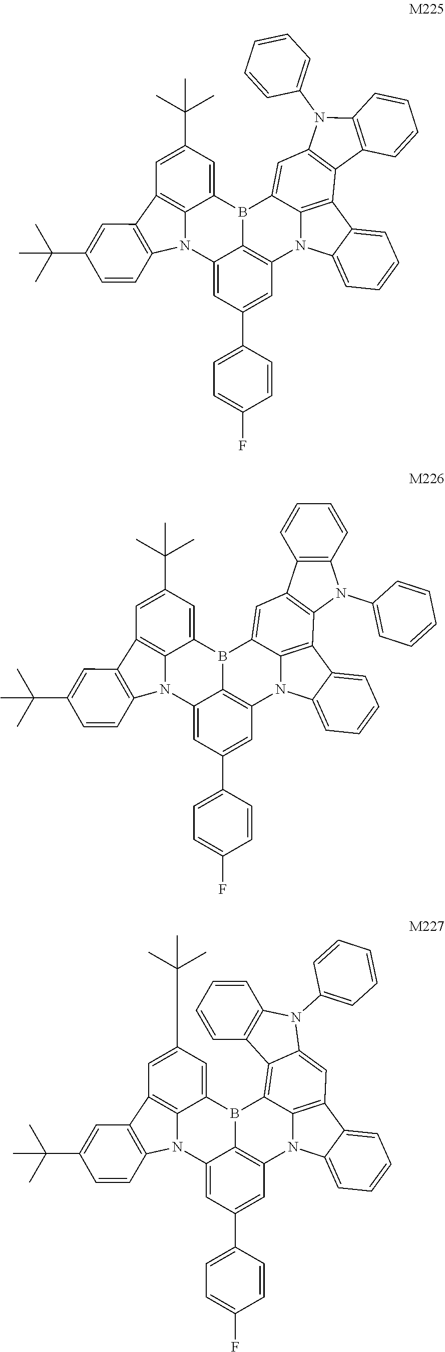 [SMILES: CC(C)(C)c1ccc2c(c1)c1cc(C(C)(C)C)cc3c1n2-c1cc(-c2ccc(F)cc2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2ccc(F)cc2)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2ccc(F)cc2)cc2c1B3c1c3c4ccccc4n(-c4ccccc4)c3cc3c4ccccc4n-2c13]

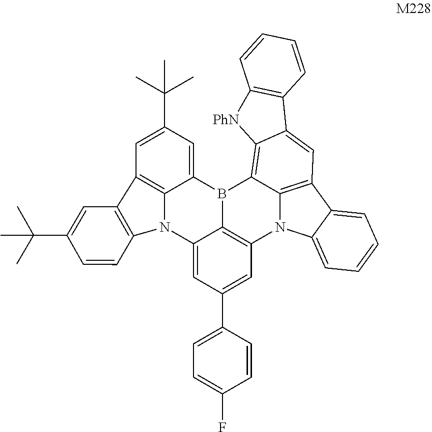

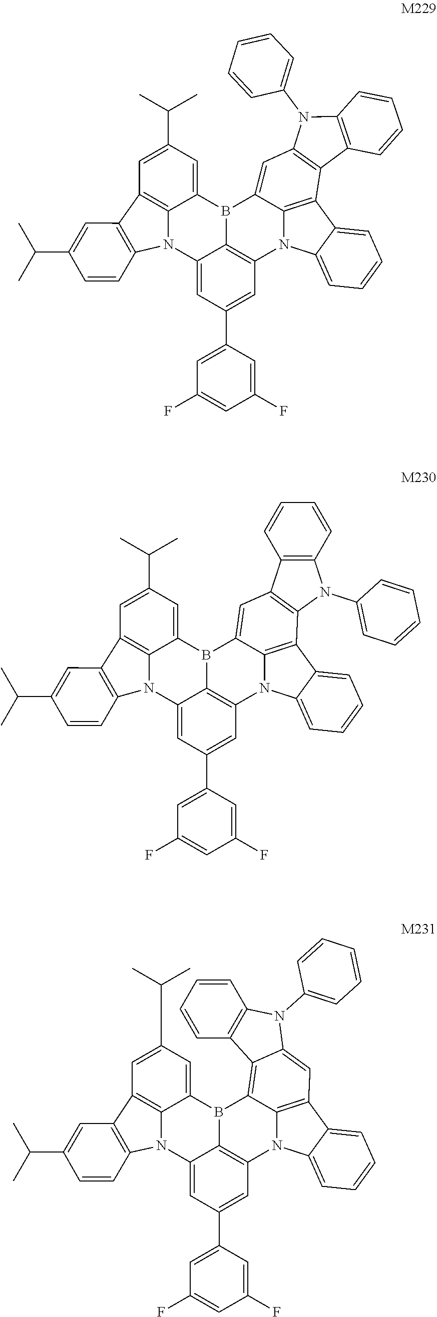 [SMILES: CC(C)c1ccc2c(c1)c1cc(C(C)C)cc3c1n2-c1cc(-c2cc(F)cc(F)c2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2cc(F)cc(F)c2)cc2c1B3c1cc3c4ccccc4n(-c4ccccc4)c3c3c4ccccc4n-2c13 ; CC(C)c1ccc2c(c1)c1cc(C(C)C)cc3c1n2-c1cc(-c2cc(F)cc(F)c2)cc2c1B3c1c3c4ccccc4n(-c4ccccc4)c3cc3c4ccccc4n-2c13]

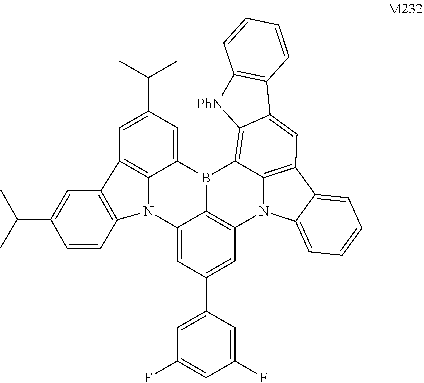

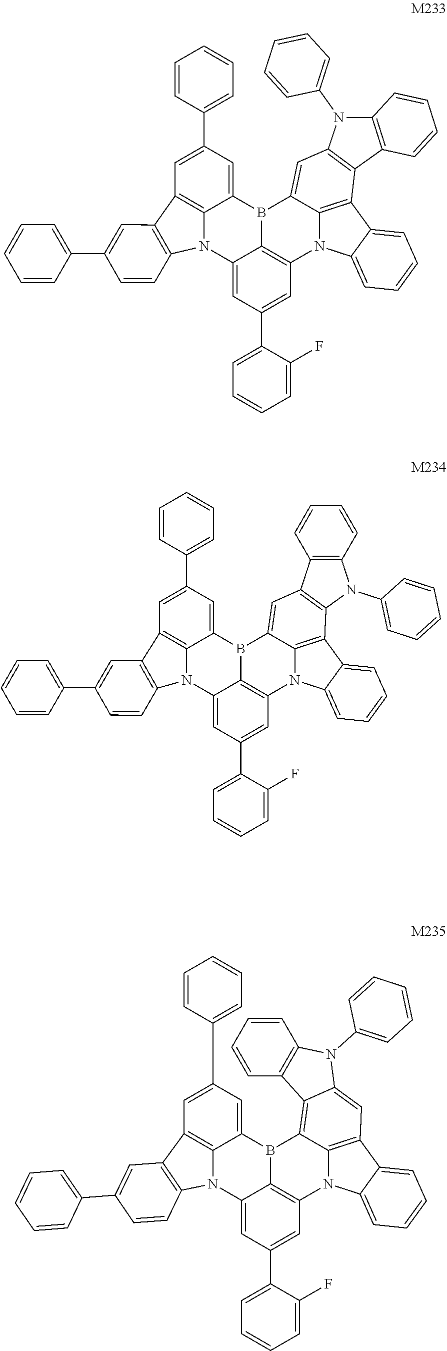 [SMILES: Fc1ccccc1-c1cc2c3c(c1)-n1c4ccccc4c4c5c6ccccc6n(-c6ccccc6)c5cc(c41)B3c1cc(-c3ccccc3)cc3c4cc(-c5ccccc5)ccc4n-2c13 ; Fc1ccccc1-c1cc2c3c(c1)-n1c4ccccc4c4c1c(cc1c5ccccc5n(-c5ccccc5)c14)B3c1cc(-c3ccccc3)cc3c4cc(-c5ccccc5)ccc4n-2c13 ; Fc1ccccc1-c1cc2c3c(c1)-n1c4ccccc4c4cc5c(c(c41)B3c1cc(-c3ccccc3)cc3c4cc(-c6ccccc6)ccc4n-2c13)c1ccccc1n5-c1ccccc1]

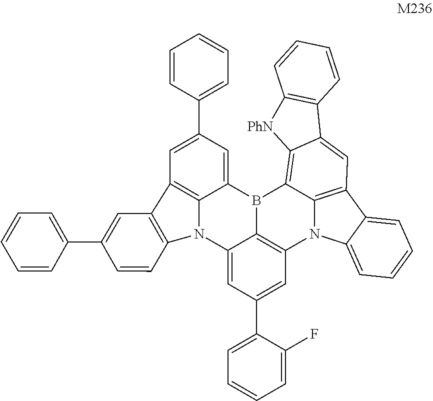

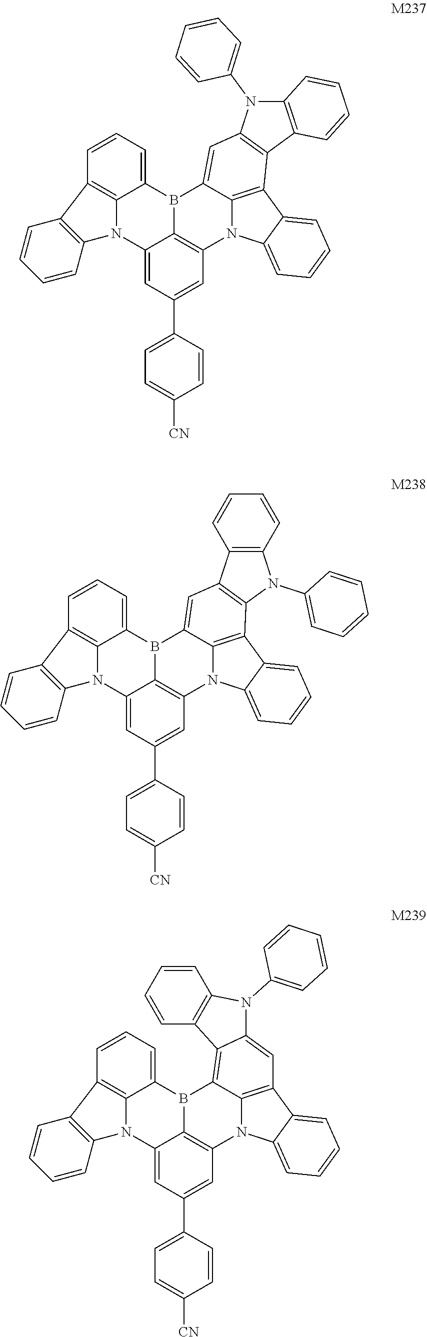 [SMILES: N#Cc1ccc(-c2cc3c4c(c2)-n2c5ccccc5c5c6c7ccccc7n(-c7ccccc7)c6cc(c52)B4c2cccc4c5ccccc5n-3c24)cc1 ; N#Cc1ccc(-c2cc3c4c(c2)-n2c5ccccc5c5c2c(cc2c6ccccc6n(-c6ccccc6)c25)B4c2cccc4c5ccccc5n-3c24)cc1 ; N#Cc1ccc(-c2cc3c4c(c2)-n2c5ccccc5c5cc6c(c(c52)B4c2cccc4c5ccccc5n-3c24)c2ccccc2n6-c2ccccc2)cc1]

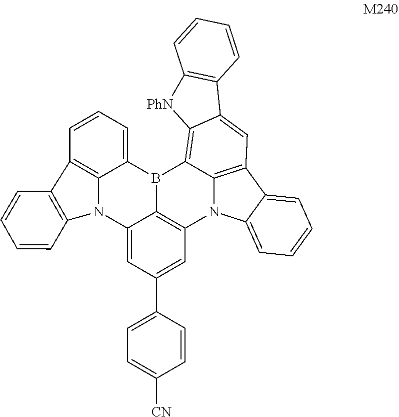

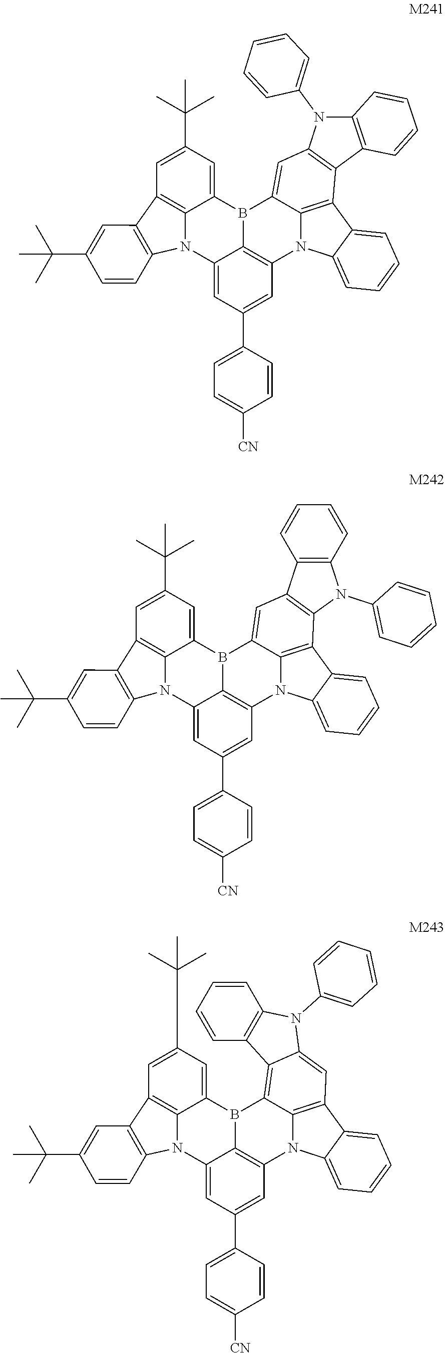 [SMILES: CC(C)(C)c1ccc2c(c1)c1cc(C(C)(C)C)cc3c1n2-c1cc(-c2ccc(C#N)cc2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2ccc(C#N)cc2)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2ccc(C#N)cc2)cc2c1B3c1c3c4ccccc4n(-c4ccccc4)c3cc3c4ccccc4n-2c13]

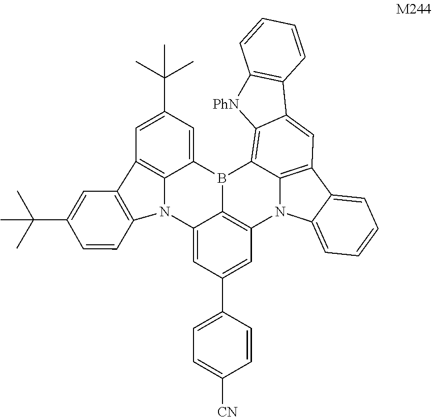

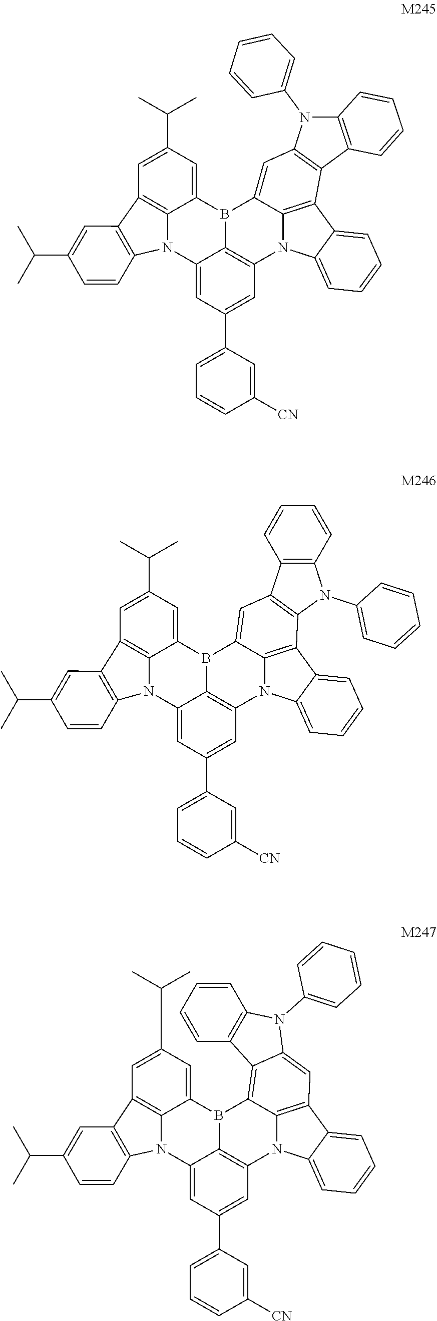 [SMILES: CC(C)c1ccc2c(c1)c1cc(C(C)C)cc3c1n2-c1cc(-c2cccc(C#N)c2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2cccc(C#N)c2)cc2c1B3c1cc3c4ccccc4n(-c4ccccc4)c3c3c4ccccc4n-2c13 ; CC(C)c1ccc2c(c1)c1cc(C(C)C)cc3c1n2-c1cc(-c2cccc(C#N)c2)cc2c1B3c1c3c4ccccc4n(-c4ccccc4)c3cc3c4ccccc4n-2c13]

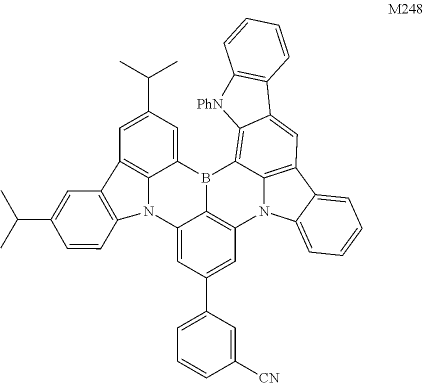

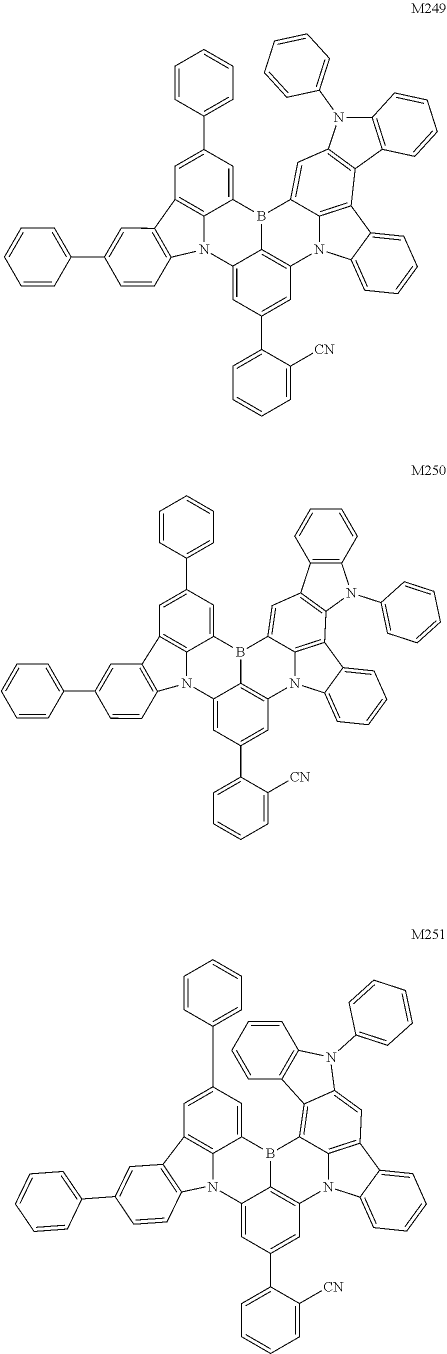 [SMILES: N#Cc1ccccc1-c1cc2c3c(c1)-n1c4ccccc4c4c5c6ccccc6n(-c6ccccc6)c5cc(c41)B3c1cc(-c3ccccc3)cc3c4cc(-c5ccccc5)ccc4n-2c13 ; N#Cc1ccccc1-c1cc2c3c(c1)-n1c4ccccc4c4c1c(cc1c5ccccc5n(-c5ccccc5)c14)B3c1cc(-c3ccccc3)cc3c4cc(-c5ccccc5)ccc4n-2c13 ; N#Cc1ccccc1-c1cc2c3c(c1)-n1c4ccccc4c4cc5c(c(c41)B3c1cc(-c3ccccc3)cc3c4cc(-c6ccccc6)ccc4n-2c13)c1ccccc1n5-c1ccccc1]

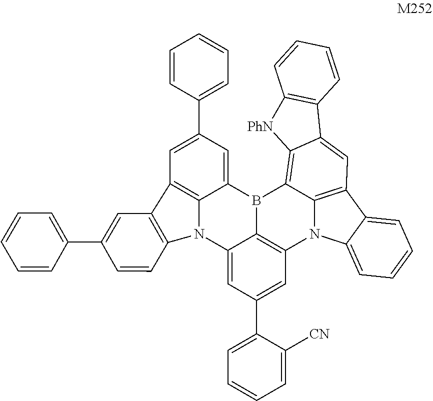

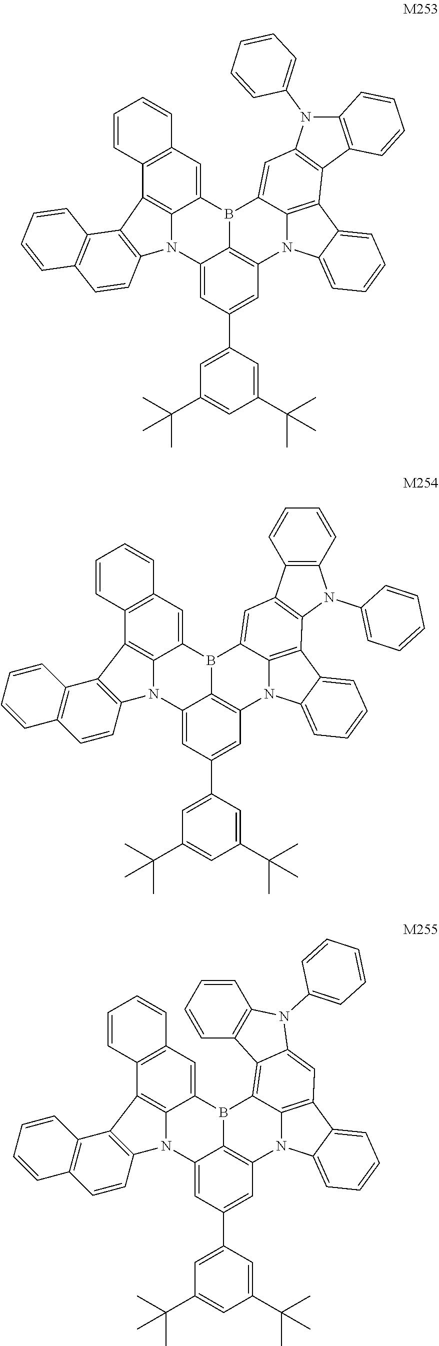 [SMILES: CC(C)(C)c1cc(-c2cc3c4c(c2)-n2c5ccc6ccccc6c5c5c6ccccc6cc(c52)B4c2cc4c(c5ccccc5n4-c4ccccc4)c4c5ccccc5n-3c24)cc(C(C)(C)C)c1 ; CC(C)(C)c1cc(-c2cc3c4c(c2)-n2c5ccc6ccccc6c5c5c6ccccc6cc(c52)B4c2cc4c5ccccc5n(-c5ccccc5)c4c4c5ccccc5n-3c24)cc(C(C)(C)C)c1 ; CC(C)(C)c1cc(-c2cc3c4c(c2)-n2c5ccc6ccccc6c5c5c6ccccc6cc(c52)B4c2c4c5ccccc5n(-c5ccccc5)c4cc4c5ccccc5n-3c24)cc(C(C)(C)C)c1]

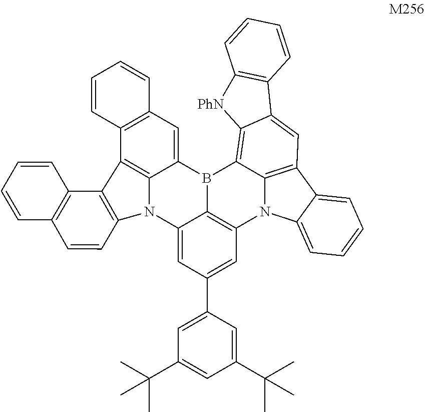

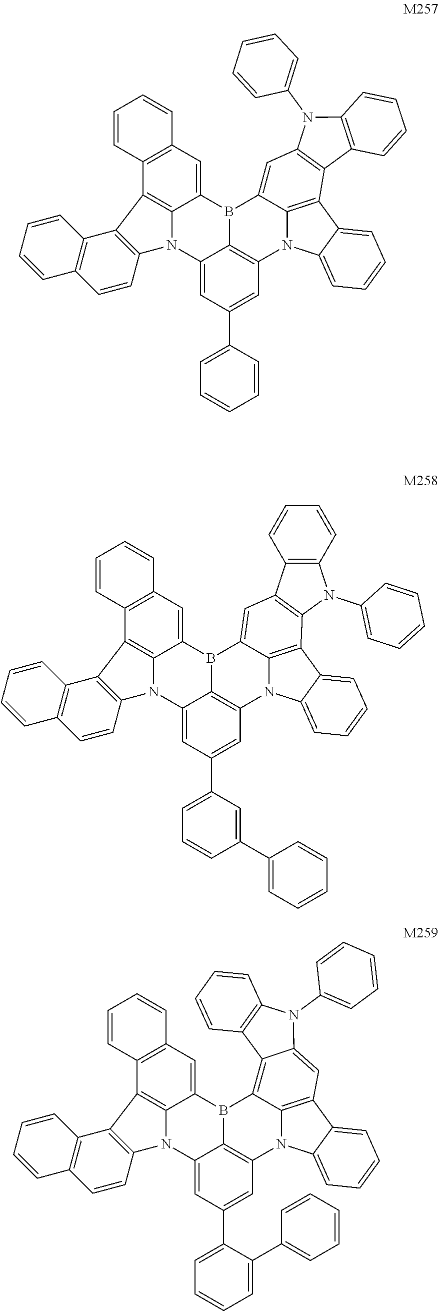 [SMILES: c1ccc(-c2cc3c4c(c2)-n2c5ccc6ccccc6c5c5c6ccccc6cc(c52)B4c2cc4c(c5ccccc5n4-c4ccccc4)c4c5ccccc5n-3c24)cc1 ; c1ccc(-c2cccc(-c3cc4c5c(c3)-n3c6ccc7ccccc7c6c6c7ccccc7cc(c63)B5c3cc5c6ccccc6n(-c6ccccc6)c5c5c6ccccc6n-4c35)c2)cc1 ; c1ccc(-c2ccccc2-c2cc3c4c(c2)-n2c5ccc6ccccc6c5c5c6ccccc6cc(c52)B4c2c4c5ccccc5n(-c5ccccc5)c4cc4c5ccccc5n-3c24)cc1]

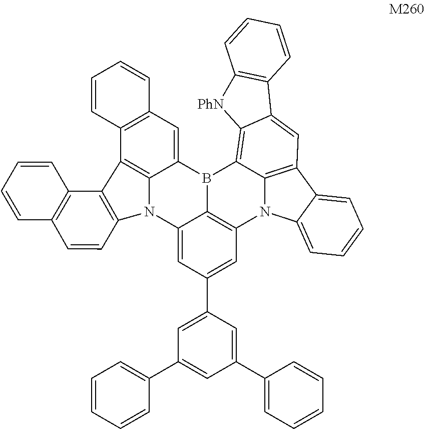

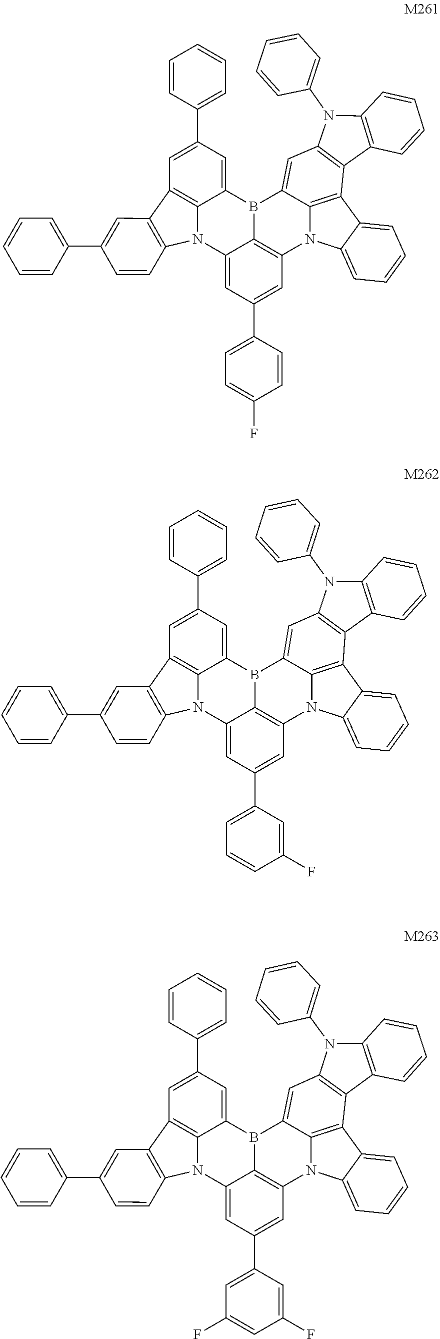 [SMILES: Fc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc1 ; Fc1cccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1 ; Fc1cc(F)cc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1]

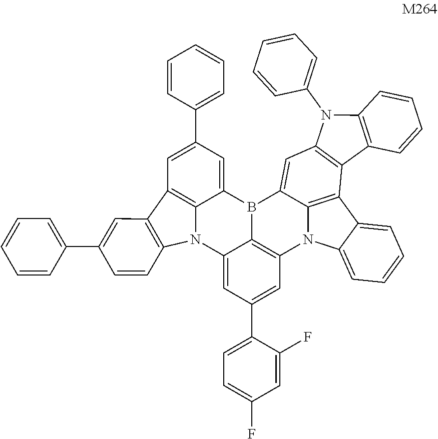 [SMILES: Fc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c(F)c1]

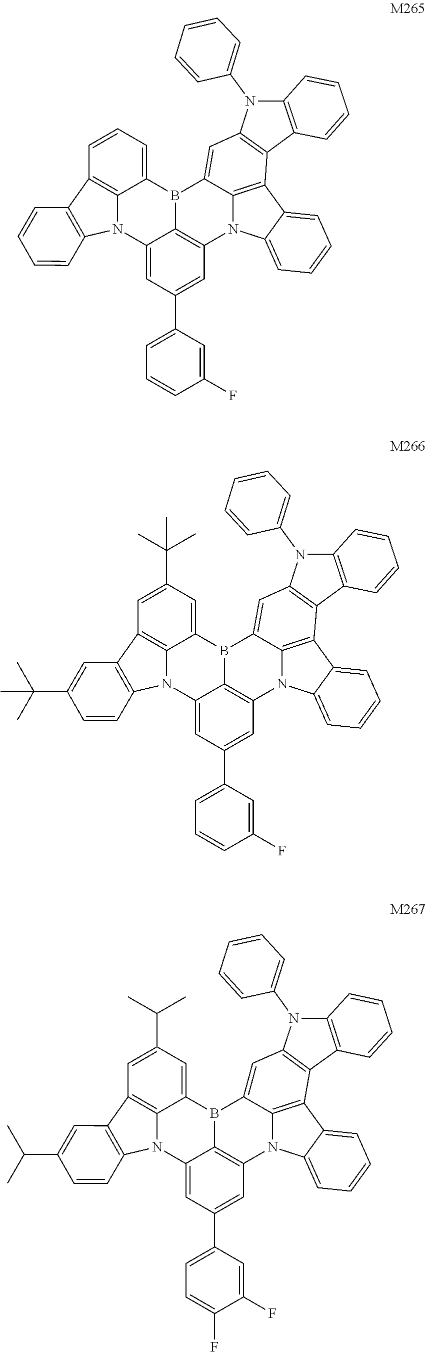 [SMILES: Fc1cccc(-c2cc3c4c(c2)-n2c5ccccc5c5c6c7ccccc7n(-c7ccccc7)c6cc(c52)B4c2cccc4c5ccccc5n-3c24)c1 ; CC(C)(C)c1ccc2c(c1)c1cc(C(C)(C)C)cc3c1n2-c1cc(-c2cccc(F)c2)cc2c1B3c1cc3c(c4ccccc4n3-c3ccccc3)c3c4ccccc4n-2c13 ; CC(C)c1ccc2c(c1)c1cc(C(C)C)cc3c1n2-c1cc(-c2ccc(F)c(F)c2)cc2c1B3c1cc3c(c4ccccc4n3-c3ccccc3)c3c4ccccc4n-2c13]

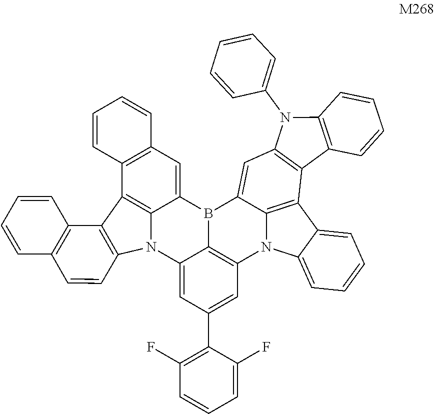 [SMILES: Fc1cccc(F)c1-c1cc2c3c(c1)-n1c4ccc5ccccc5c4c4c5ccccc5cc(c41)B3c1cc3c(c4ccccc4n3-c3ccccc3)c3c4ccccc4n-2c13]

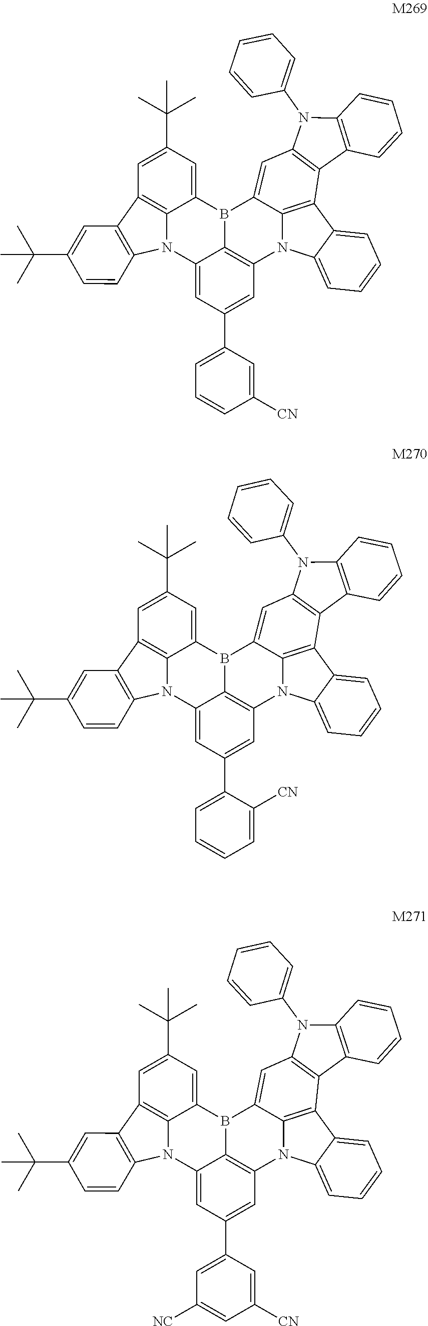 [SMILES: CC(C)(C)c1ccc2c(c1)c1cc(C(C)(C)C)cc3c1n2-c1cc(-c2cccc(C#N)c2)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2ccccc2C#N)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2cc(C#N)cc(C#N)c2)cc2c1B3c1cc3c(c4ccccc4n3-c3ccccc3)c3c4ccccc4n-2c13]

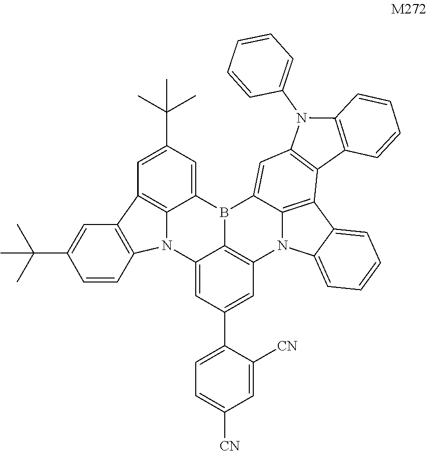 [SMILES: CC(C)(C)c1ccc2c(c1)c1cc(C(C)(C)C)cc3c1n2-c1cc(-c2ccc(C#N)cc2C#N)cc2c1B3c1cc3c(c4ccccc4n3-c3ccccc3)c3c4ccccc4n-2c13]

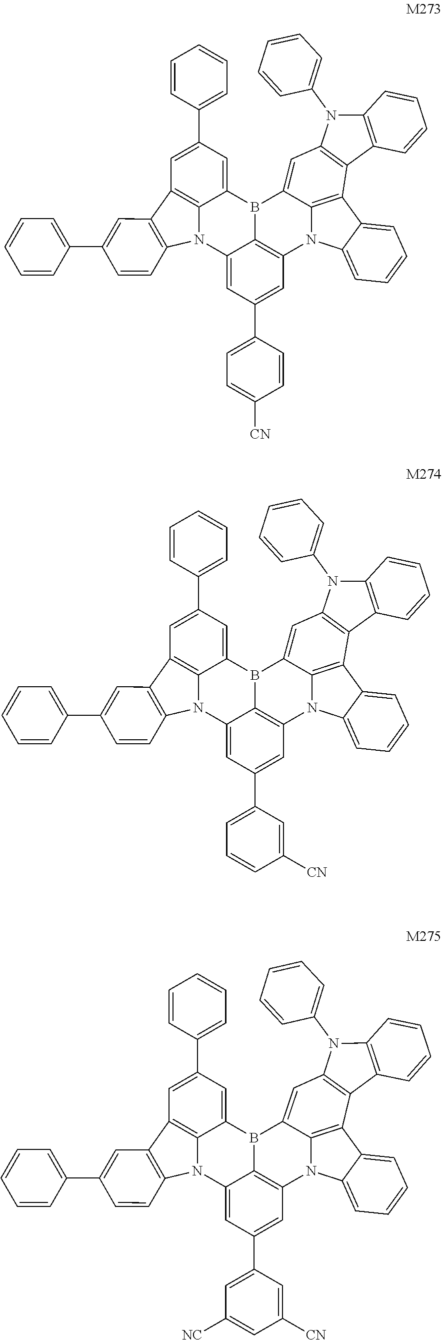 [SMILES: N#Cc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc1 ; N#Cc1cccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1 ; N#Cc1cc(C#N)cc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1]

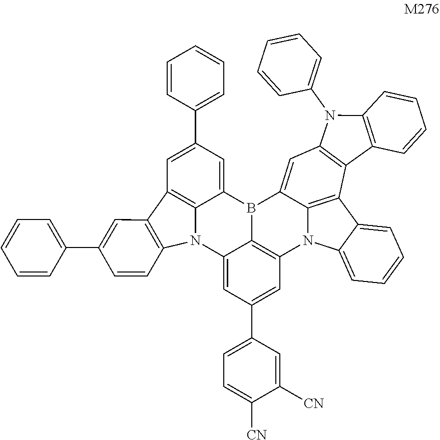 [SMILES: N#Cc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)cc1C#N]

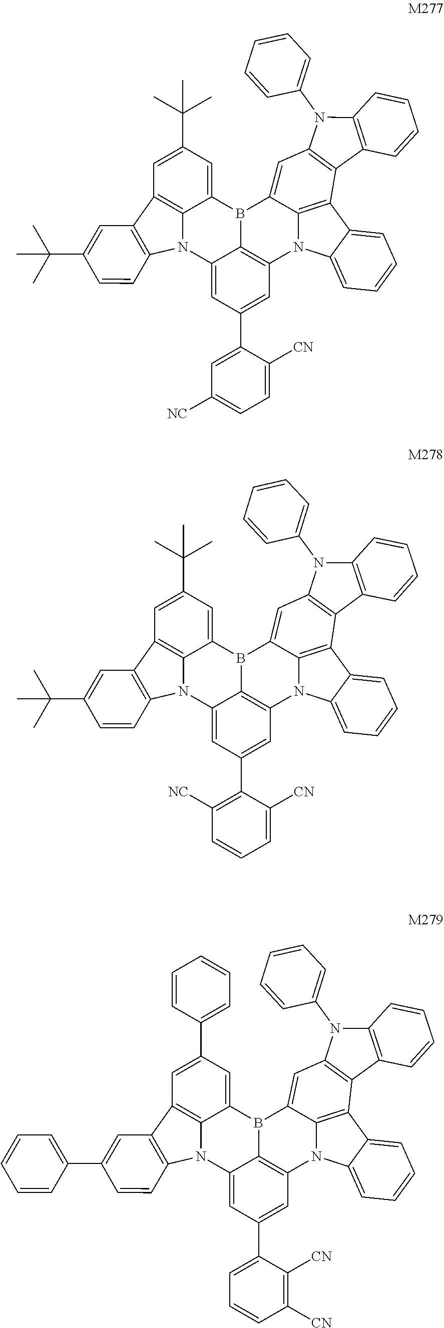 [SMILES: CC(C)(C)c1ccc2c(c1)c1cc(C(C)(C)C)cc3c1n2-c1cc(-c2cc(C#N)ccc2C#N)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2c(C#N)cccc2C#N)cc2c1B3c1cc3c(c4ccccc4n3-c3ccccc3)c3c4ccccc4n-2c13 ; N#Cc1cccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c1C#N]

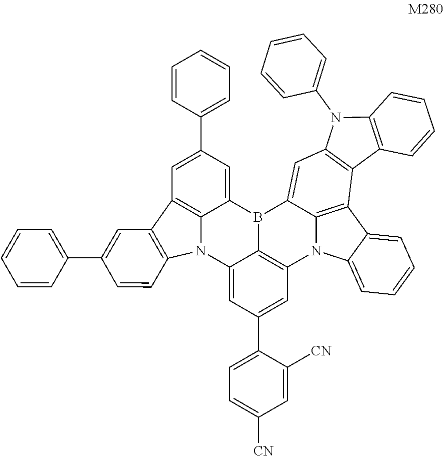 [SMILES: N#Cc1ccc(-c2cc3c4c(c2)-n2c5ccccc5c5c6c7ccccc7n(-c7ccccc7)c6cc(c52)B4c2cc(-c4ccccc4)cc4c5cc(-c6ccccc6)ccc5n-3c24)c(C#N)c1]

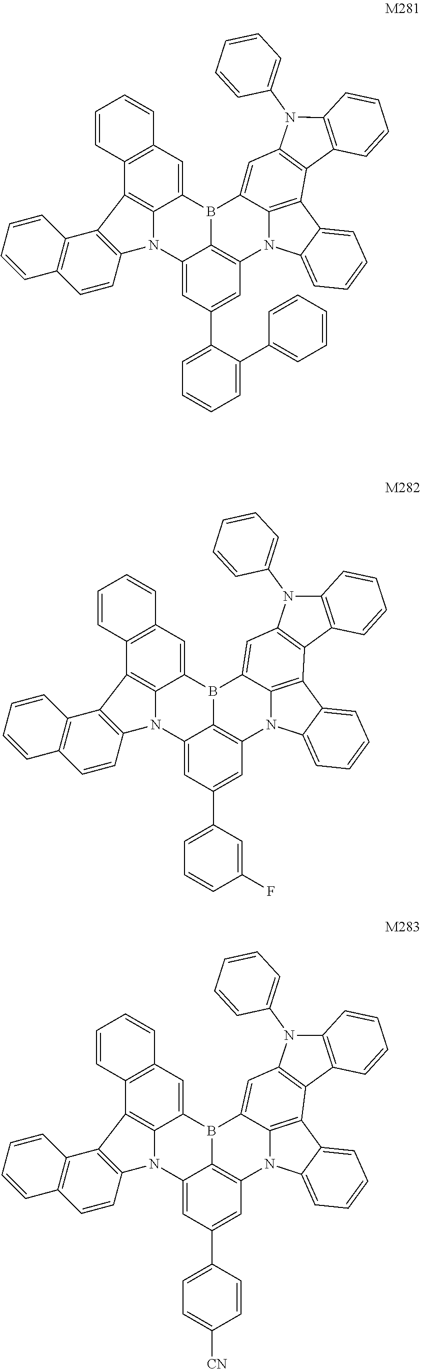 [SMILES: c1ccc(-c2ccccc2-c2cc3c4c(c2)-n2c5ccc6ccccc6c5c5c6ccccc6cc(c52)B4c2cc4c(c5ccccc5n4-c4ccccc4)c4c5ccccc5n-3c24)cc1 ; Fc1cccc(-c2cc3c4c(c2)-n2c5ccc6ccccc6c5c5c6ccccc6cc(c52)B4c2cc4c(c5ccccc5n4-c4ccccc4)c4c5ccccc5n-3c24)c1 ; N#Cc1ccc(-c2cc3c4c(c2)-n2c5ccc6ccccc6c5c5c6ccccc6cc(c52)B4c2cc4c(c5ccccc5n4-c4ccccc4)c4c5ccccc5n-3c24)cc1]

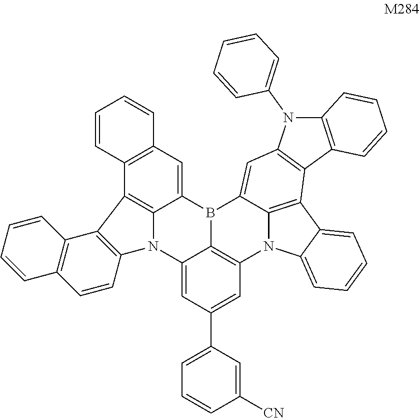 [SMILES: N#Cc1cccc(-c2cc3c4c(c2)-n2c5ccc6ccccc6c5c5c6ccccc6cc(c52)B4c2cc4c(c5ccccc5n4-c4ccccc4)c4c5ccccc5n-3c24)c1]

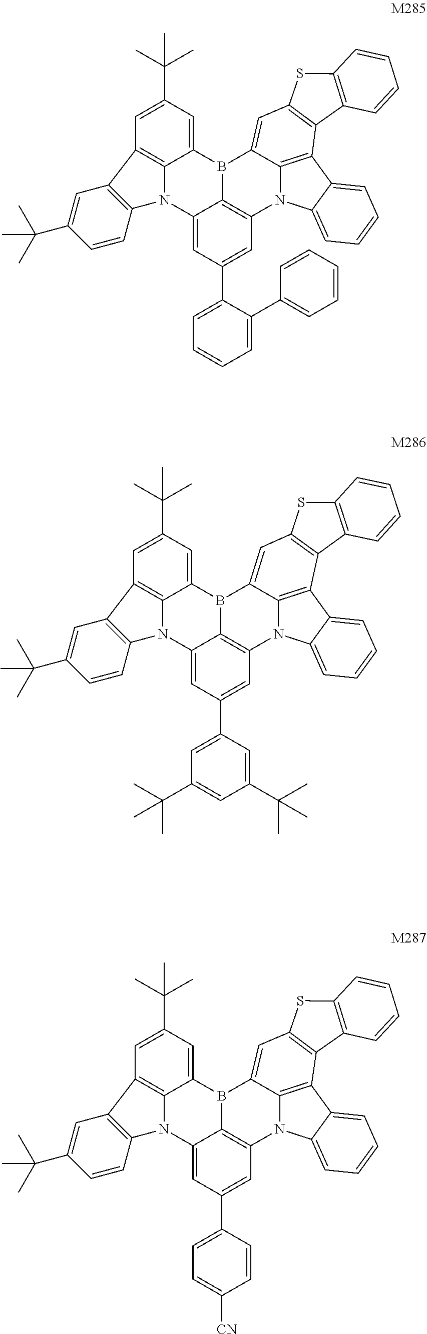 [SMILES: CC(C)(C)c1ccc2c(c1)c1cc(C(C)(C)C)cc3c1n2-c1cc(-c2ccccc2-c2ccccc2)cc2c1B3c1cc3sc4ccccc4c3c3c4ccccc4n-2c13 ; CC(C)(C)c1cc(-c2cc3c4c(c2)-n2c5ccccc5c5c6c(cc(c52)B4c2cc(C(C)(C)C)cc4c5cc(C(C)(C)C)ccc5n-3c24)sc2ccccc26)cc(C(C)(C)C)c1 ; CC(C)(C)c1ccc2c(c1)c1cc(C(C)(C)C)cc3c1n2-c1cc(-c2ccc(C#N)cc2)cc2c1B3c1cc3sc4ccccc4c3c3c4ccccc4n-2c13]

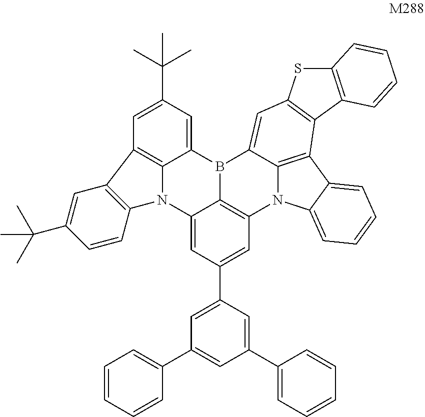 [SMILES: CC(C)(C)c1ccc2c(c1)c1cc(C(C)(C)C)cc3c1n2-c1cc(-c2cc(-c4ccccc4)cc(-c4ccccc4)c2)cc2c1B3c1cc3sc4ccccc4c3c3c4ccccc4n-2c13]

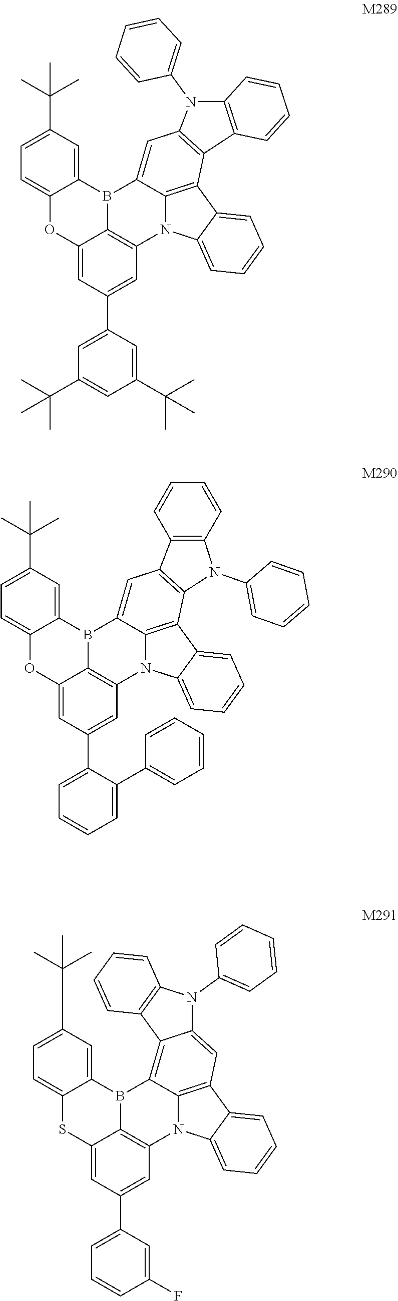 [SMILES: CC(C)(C)c1cc(-c2cc3c4c(c2)-n2c5ccccc5c5c6c7ccccc7n(-c7ccccc7)c6cc(c52)B4c2cc(C(C)(C)C)ccc2O3)cc(C(C)(C)C)c1 ; CC(C)(C)c1ccc2c(c1)B1c3c(cc(-c4ccccc4-c4ccccc4)cc3-n3c4ccccc4c4c3c1cc1c3ccccc3n(-c3ccccc3)c14)O2 ; CC(C)(C)c1ccc2c(c1)B1c3c(cc(-c4cccc(F)c4)cc3-n3c4ccccc4c4cc5c(c1c43)c1ccccc1n5-c1ccccc1)S2]

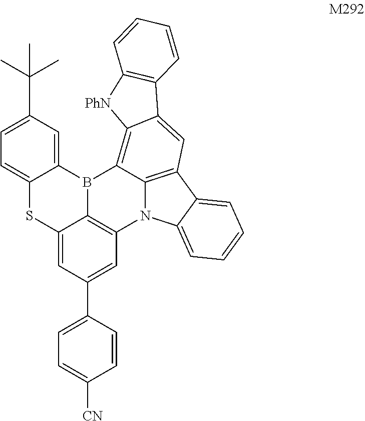

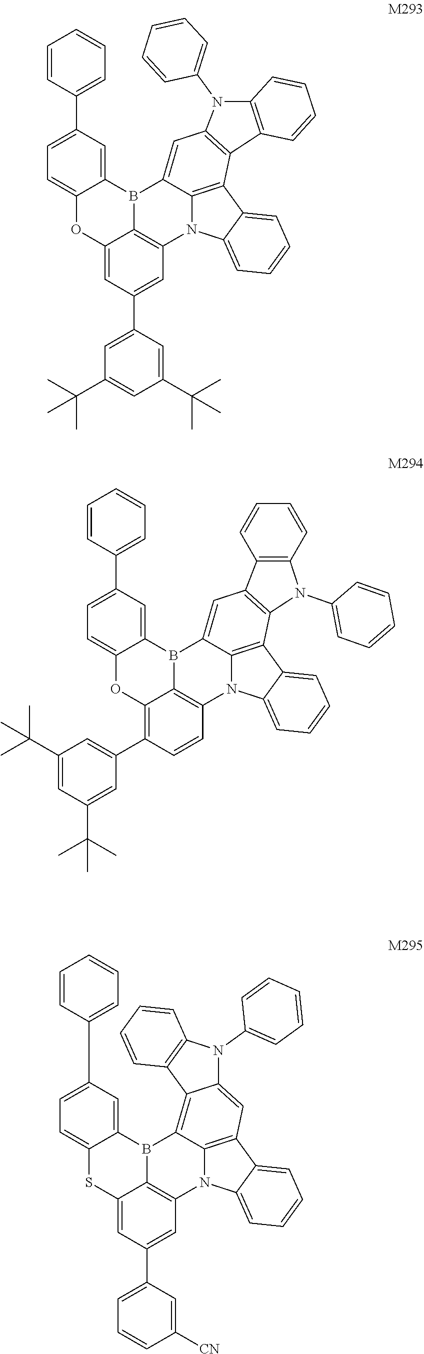 [SMILES: CC(C)(C)c1cc(-c2cc3c4c(c2)-n2c5ccccc5c5c6c7ccccc7n(-c7ccccc7)c6cc(c52)B4c2cc(-c4ccccc4)ccc2O3)cc(C(C)(C)C)c1 ; CC(C)(C)c1cc(-c2ccc3c4c2Oc2ccc(-c5ccccc5)cc2B4c2cc4c5ccccc5n(-c5ccccc5)c4c4c5ccccc5n-3c24)cc(C(C)(C)C)c1 ; N#Cc1cccc(-c2cc3c4c(c2)-n2c5ccccc5c5cc6c(c(c52)B4c2cc(-c4ccccc4)ccc2S3)c2ccccc2n6-c2ccccc2)c1]

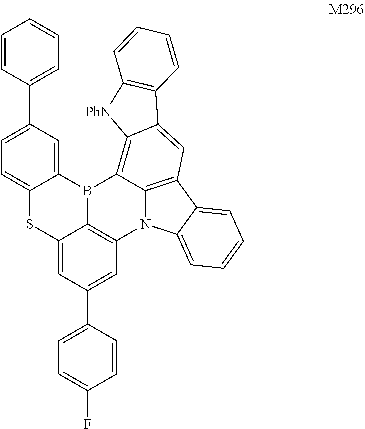

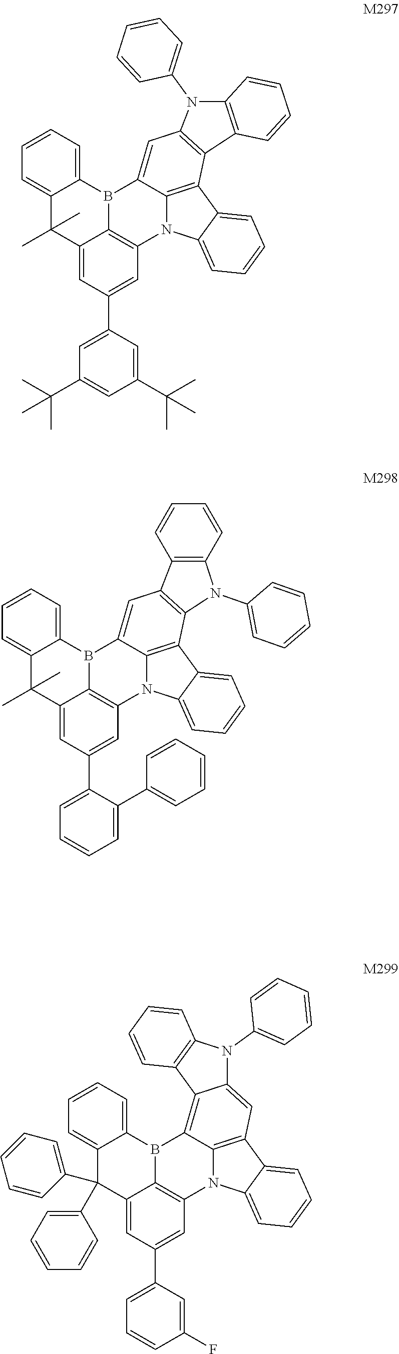

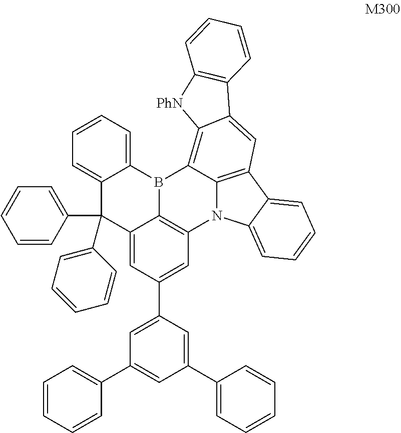

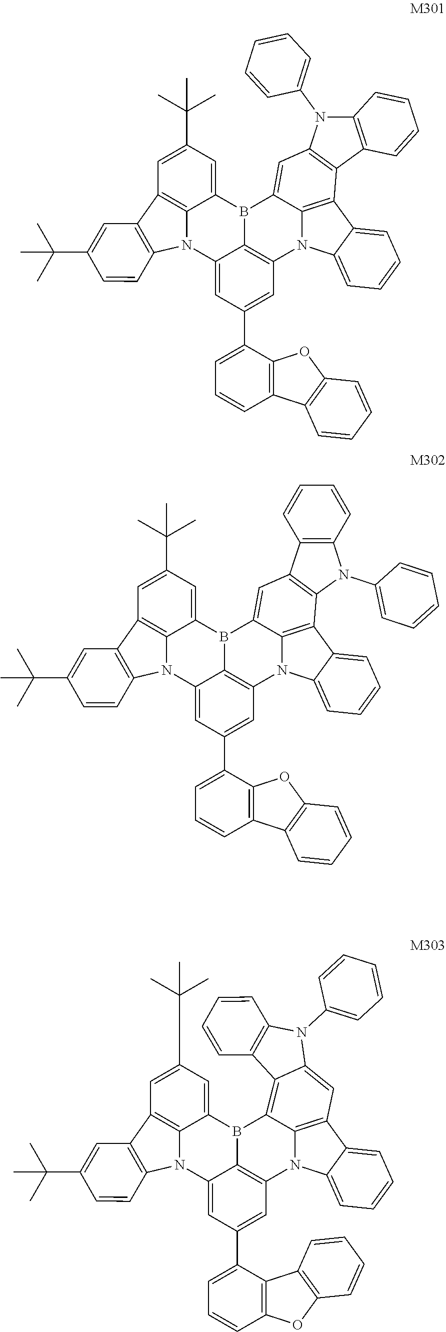 [SMILES: CC(C)(C)c1ccc2c(c1)c1cc(C(C)(C)C)cc3c1n2-c1cc(-c2cccc4c2oc2ccccc24)cc2c1B3c1cc3c(c4ccccc4n3-c3ccccc3)c3c4ccccc4n-2c13 ; CC(C)(C)c1ccc2c(c1)c1cc(C(C)(C)C)cc3c1n2-c1cc(-c2cccc4c2oc2ccccc24)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2cccc4oc5ccccc5c24)cc2c1B3c1c3c4ccccc4n(-c4ccccc4)c3cc3c4ccccc4n-2c13]

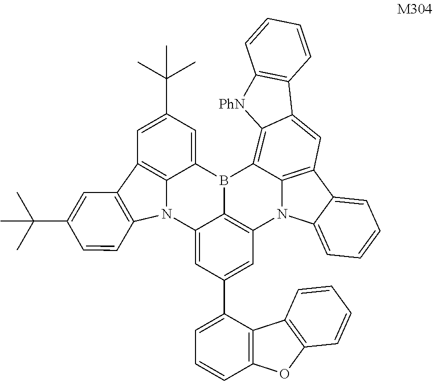

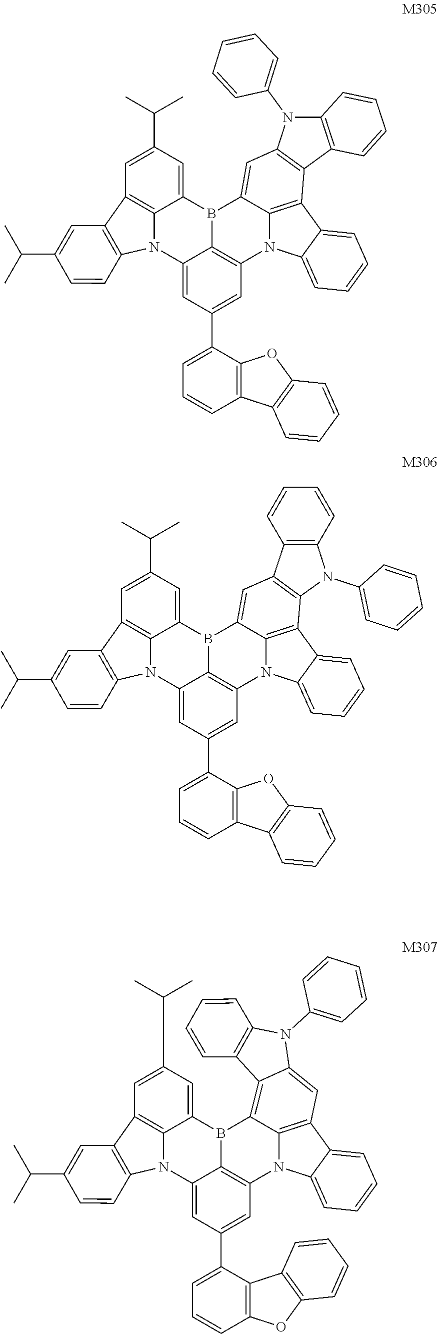

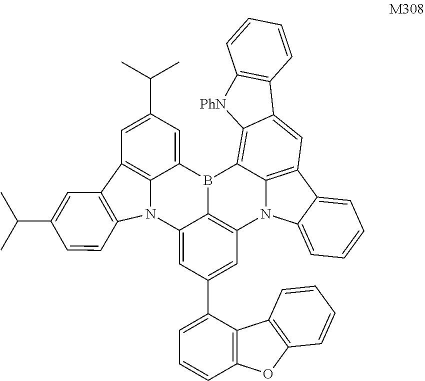

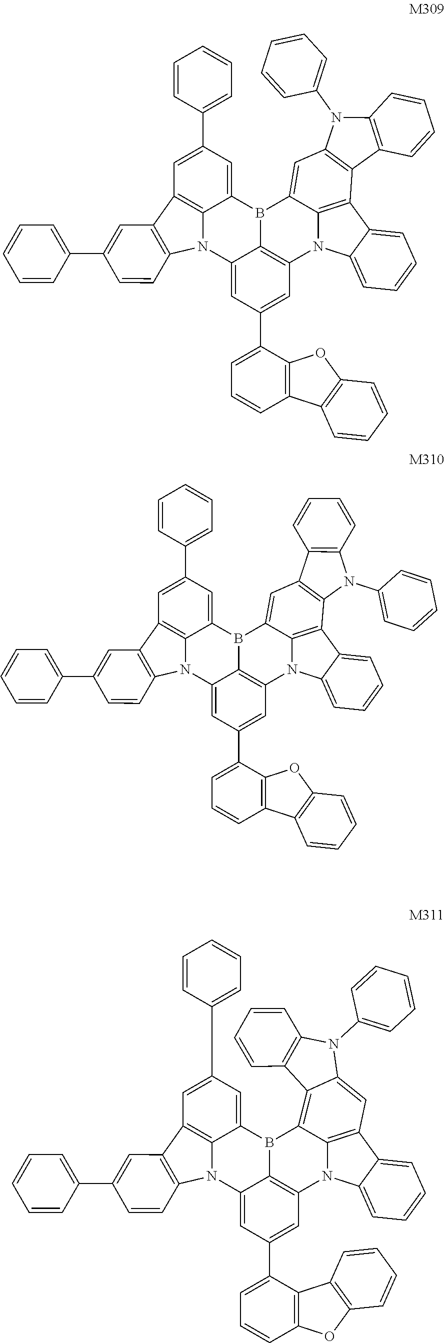 [SMILES: c1ccc(-c2ccc3c(c2)c2cc(-c4ccccc4)cc4c2n3-c2cc(-c3cccc5c3oc3ccccc35)cc3c2B4c2cc4c(c5ccccc5n4-c4ccccc4)c4c5ccccc5n-3c24)cc1 ; c1ccc(-c2ccc3c(c2)c2cc(-c4ccccc4)cc4c2n3-c2cc(-c3cccc5c3oc3ccccc35)cc3c2B4c2cc4c5ccccc5n(-c5ccccc5)c4c4c5ccccc5n-3c24)cc1 ; c1ccc(-c2ccc3c(c2)c2cc(-c4ccccc4)cc4c2n3-c2cc(-c3cccc5oc6ccccc6c35)cc3c2B4c2c4c5ccccc5n(-c5ccccc5)c4cc4c5ccccc5n-3c24)cc1]

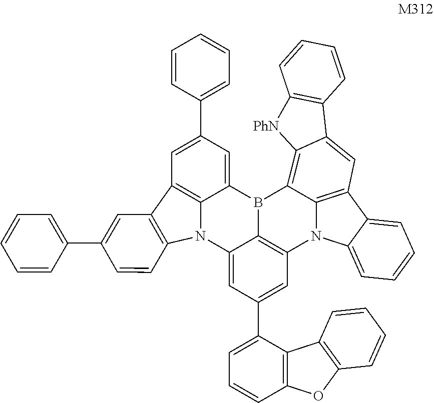

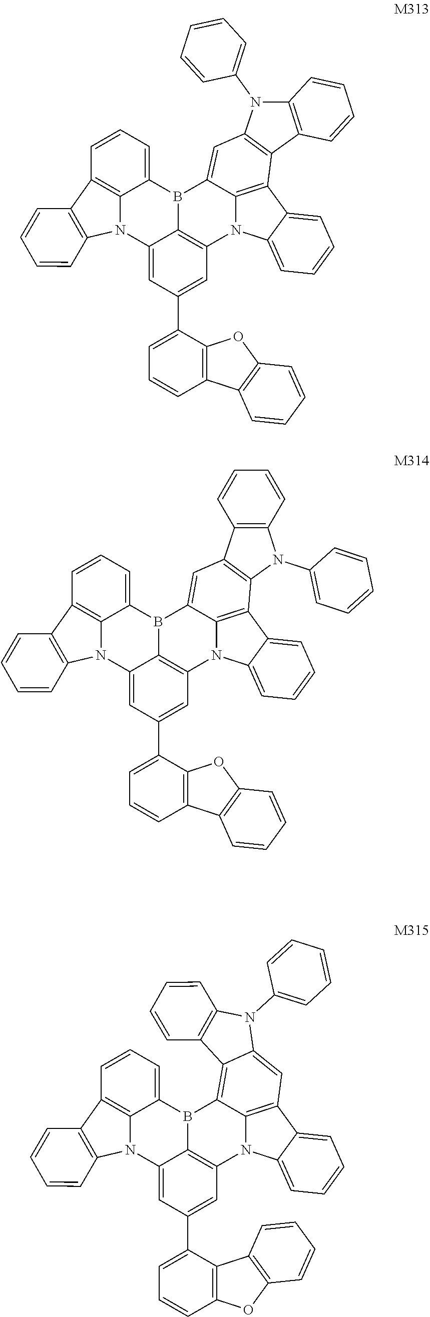 [SMILES: c1ccc(-n2c3ccccc3c3c4c5ccccc5n5c4c(cc32)B2c3c(cc(-c4cccc6c4oc4ccccc46)cc3-5)-n3c4ccccc4c4cccc2c43)cc1 ; c1ccc(-n2c3ccccc3c3cc4c5c(c6ccccc6n5-c5cc(-c6cccc7c6oc6ccccc67)cc6c5B4c4cccc5c7ccccc7n-6c45)c32)cc1 ; c1ccc(-n2c3ccccc3c3c4c5c(cc32)c2ccccc2n5-c2cc(-c3cccc5oc6ccccc6c35)cc3c2B4c2cccc4c5ccccc5n-3c24)cc1]

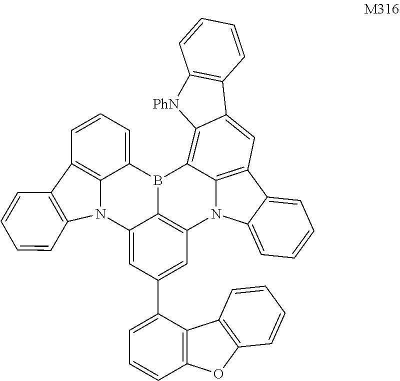

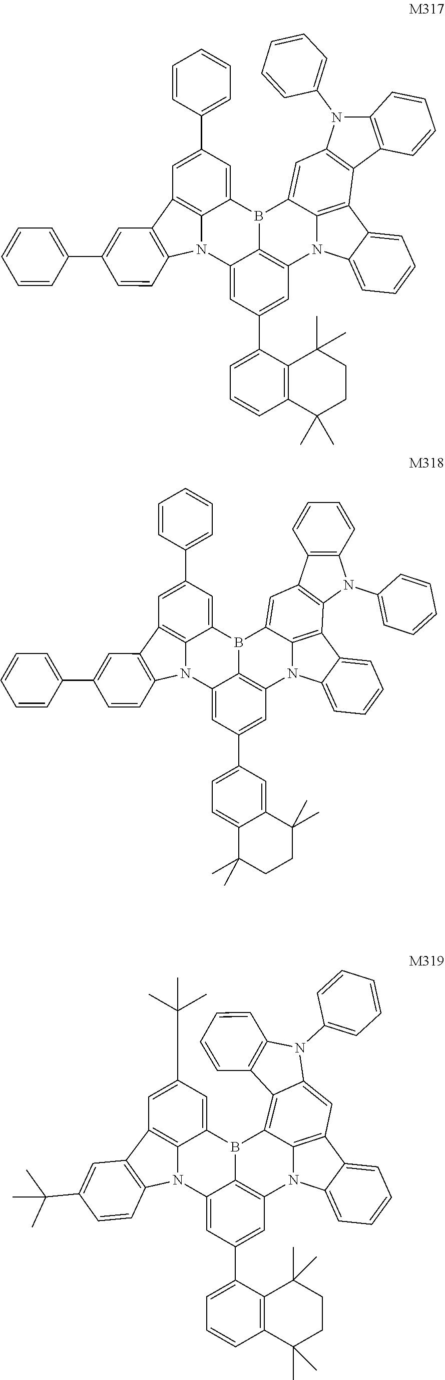 [SMILES: CC1(C)CCC(C)(C)c2c(-c3cc4c5c(c3)-n3c6ccccc6c6c7c8ccccc8n(-c8ccccc8)c7cc(c63)B5c3cc(-c5ccccc5)cc5c6cc(-c7ccccc7)ccc6n-4c35)cccc21 ; CC1(C)CCC(C)(C)c2cc(-c3cc4c5c(c3)-n3c6ccccc6c6c3c(cc3c7ccccc7n(-c7ccccc7)c36)B5c3cc(-c5ccccc5)cc5c6cc(-c7ccccc7)ccc6n-4c35)ccc21 ; CC(C)(C)c1ccc2c(c1)c1cc(C(C)(C)C)cc3c1n2-c1cc(-c2cccc4c2C(C)(C)CCC4(C)C)cc2c1B3c1c3c4ccccc4n(-c4ccccc4)c3cc3c4ccccc4n-2c13]

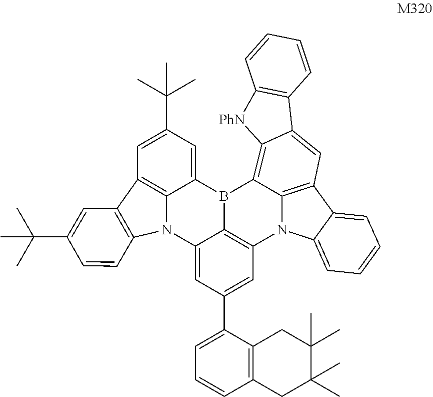

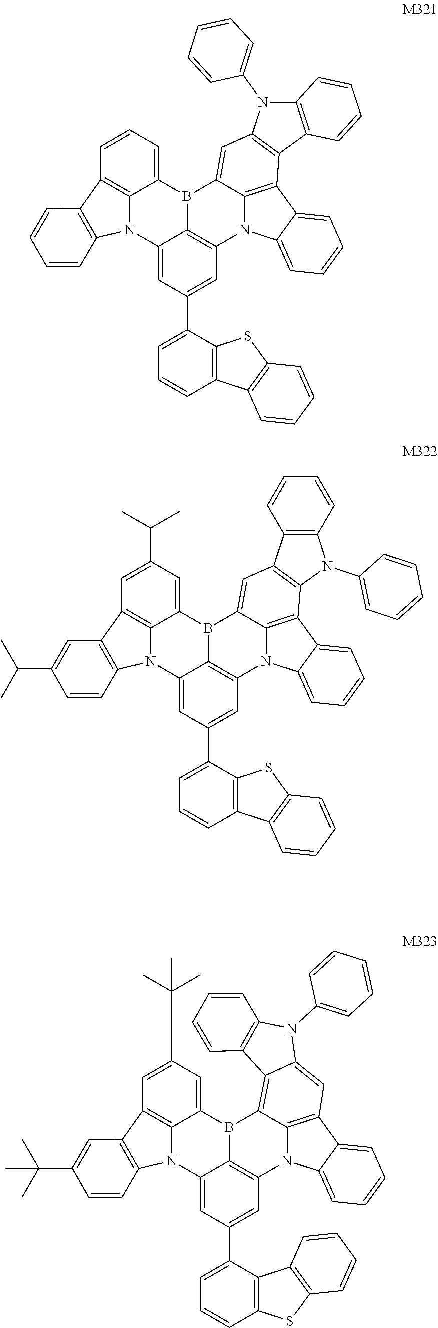 [SMILES: c1ccc(-n2c3ccccc3c3c4c5ccccc5n5c4c(cc32)B2c3c(cc(-c4cccc6c4sc4ccccc46)cc3-5)-n3c4ccccc4c4cccc2c43)cc1 ; CC(C)c1ccc2c(c1)c1cc(C(C)C)cc3c1n2-c1cc(-c2cccc4c2sc2ccccc24)cc2c1B3c1cc3c4ccccc4n(-c4ccccc4)c3c3c4ccccc4n-2c13 ; CC(C)(C)c1ccc2c(c1)c1cc(C(C)(C)C)cc3c1n2-c1cc(-c2cccc4sc5ccccc5c24)cc2c1B3c1c3c4ccccc4n(-c4ccccc4)c3cc3c4ccccc4n-2c13]

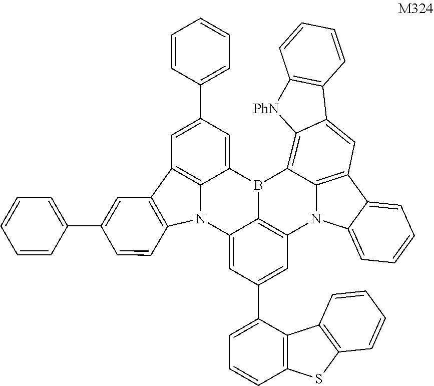

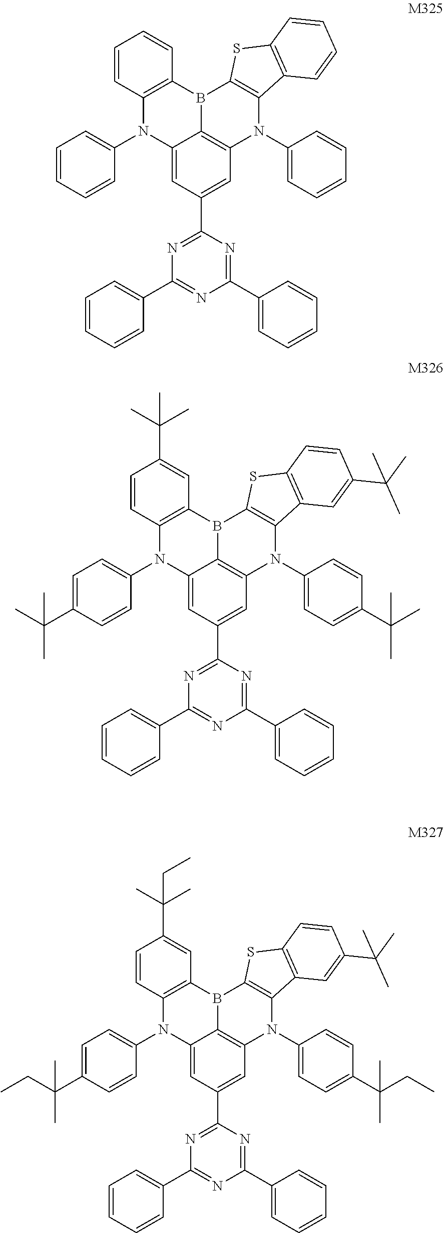

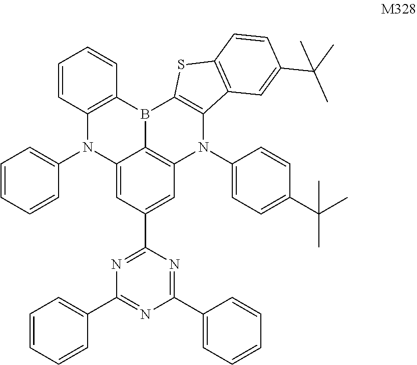 [SMILES: CC(C)(C)c1ccc(N2c3cc(-c4nc(-c5ccccc5)nc(-c5ccccc5)n4)cc4c3B(c3ccccc3N4c3ccccc3)c3sc4ccc(C(C)(C)C)cc4c32)cc1]

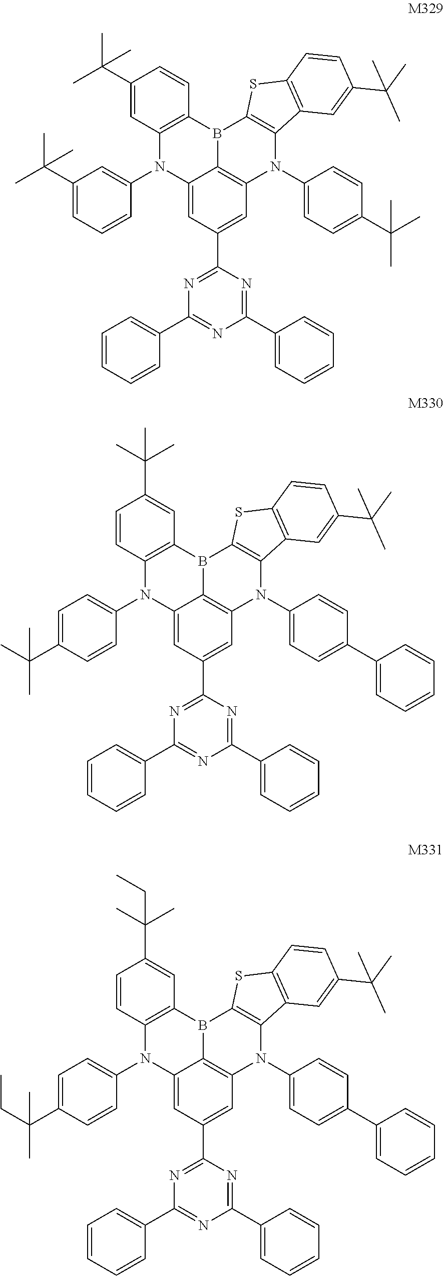

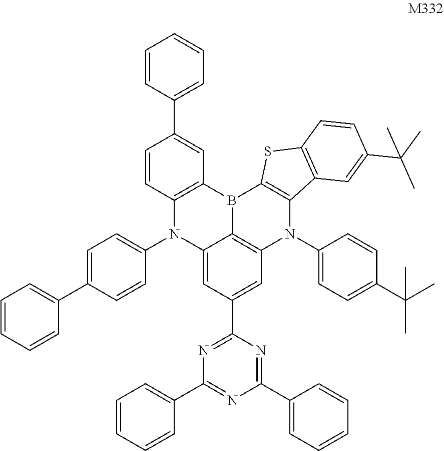 [SMILES: CC(C)(C)c1ccc(N2c3cc(-c4nc(-c5ccccc5)nc(-c5ccccc5)n4)cc4c3B(c3cc(-c5ccccc5)ccc3N4c3ccc(-c4ccccc4)cc3)c3sc4ccc(C(C)(C)C)cc4c32)cc1]

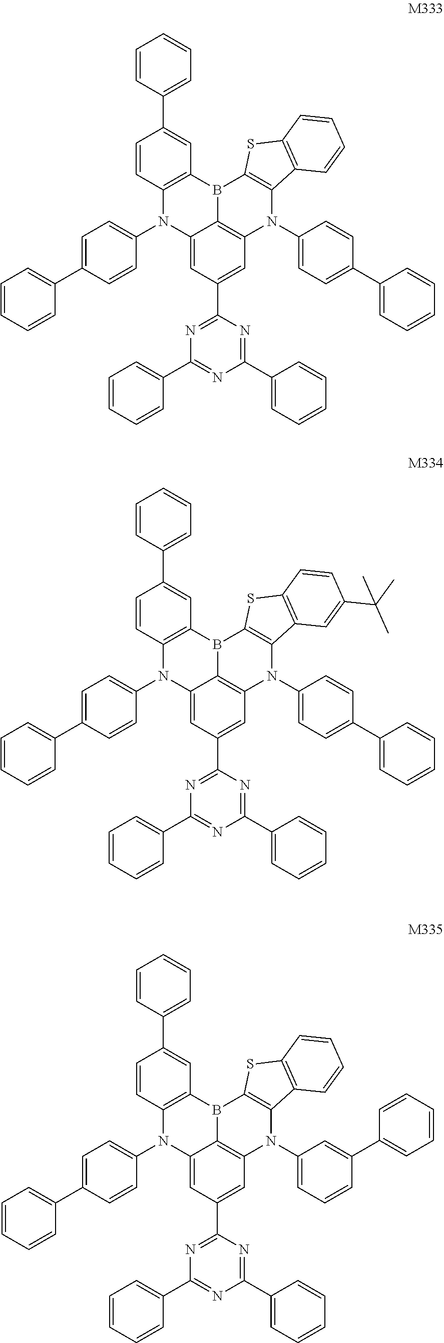 [SMILES: c1ccc(-c2ccc(N3c4ccc(-c5ccccc5)cc4B4c5sc6ccccc6c5N(c5ccc(-c6ccccc6)cc5)c5cc(-c6nc(-c7ccccc7)nc(-c7ccccc7)n6)cc3c54)cc2)cc1 ; CC(C)(C)c1ccc2sc3c(c2c1)N(c1ccc(-c2ccccc2)cc1)c1cc(-c2nc(-c4ccccc4)nc(-c4ccccc4)n2)cc2c1B3c1cc(-c3ccccc3)ccc1N2c1ccc(-c2ccccc2)cc1 ; c1ccc(-c2ccc(N3c4ccc(-c5ccccc5)cc4B4c5sc6ccccc6c5N(c5cccc(-c6ccccc6)c5)c5cc(-c6nc(-c7ccccc7)nc(-c7ccccc7)n6)cc3c54)cc2)cc1]

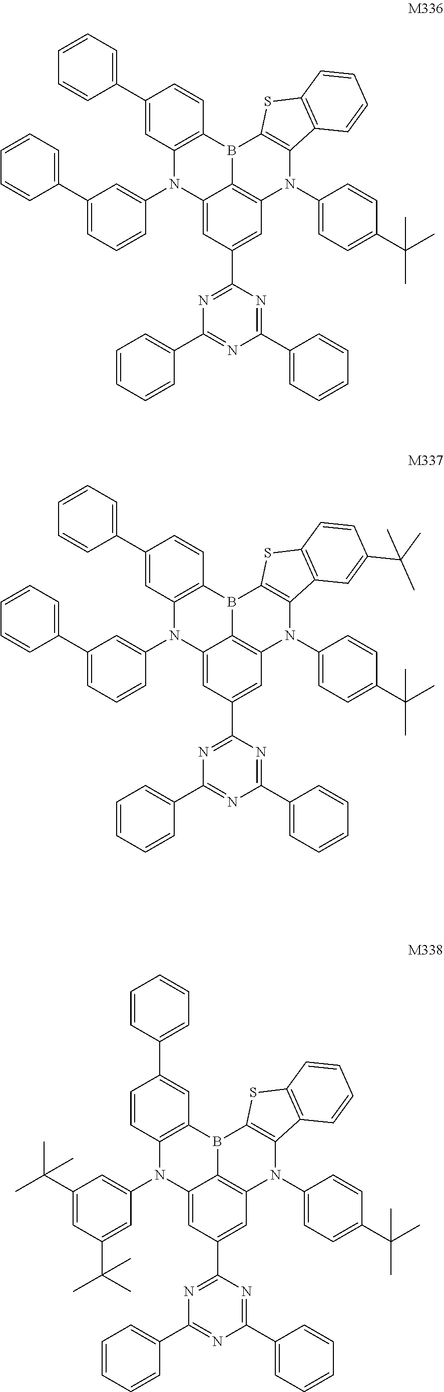

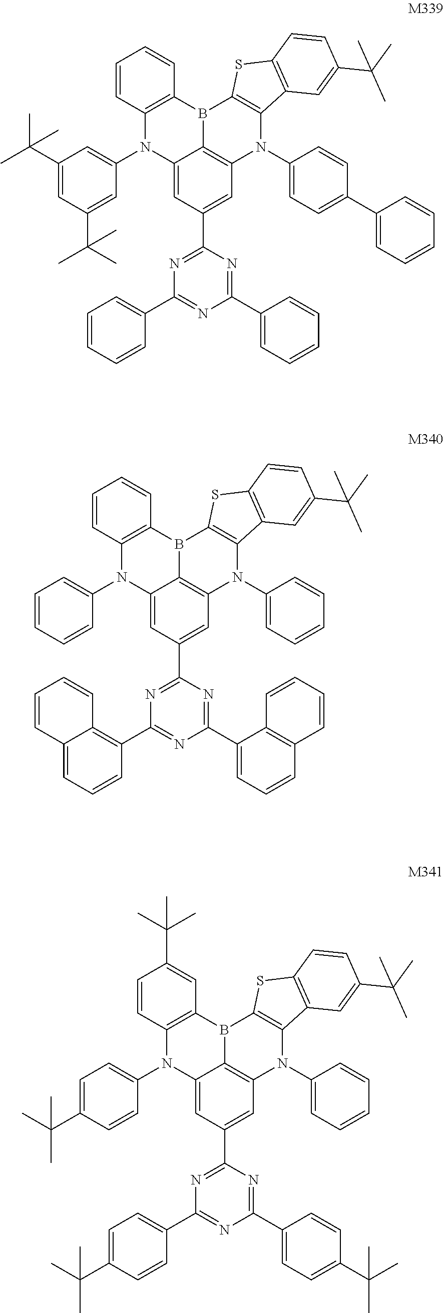

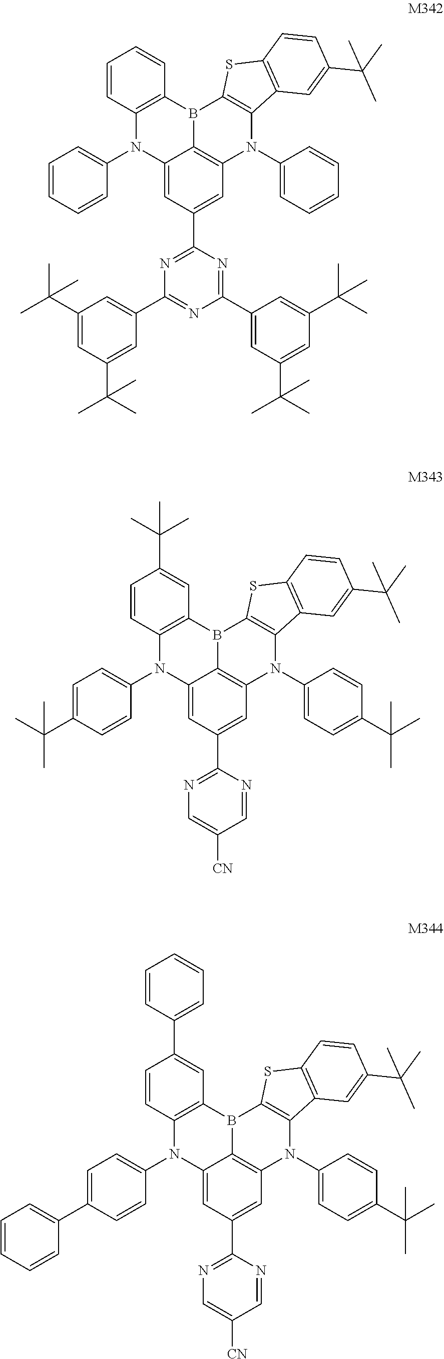

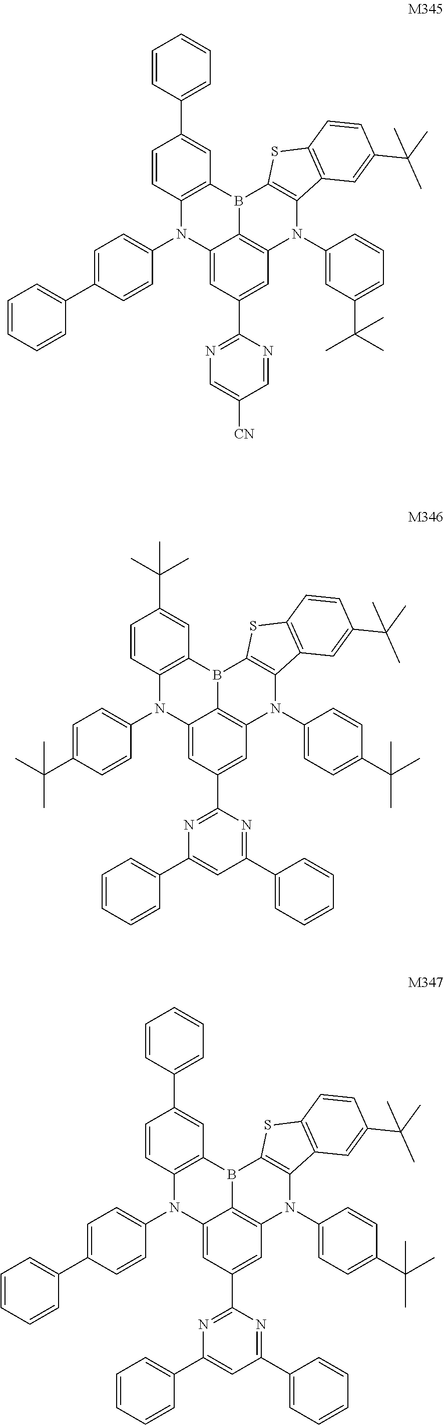

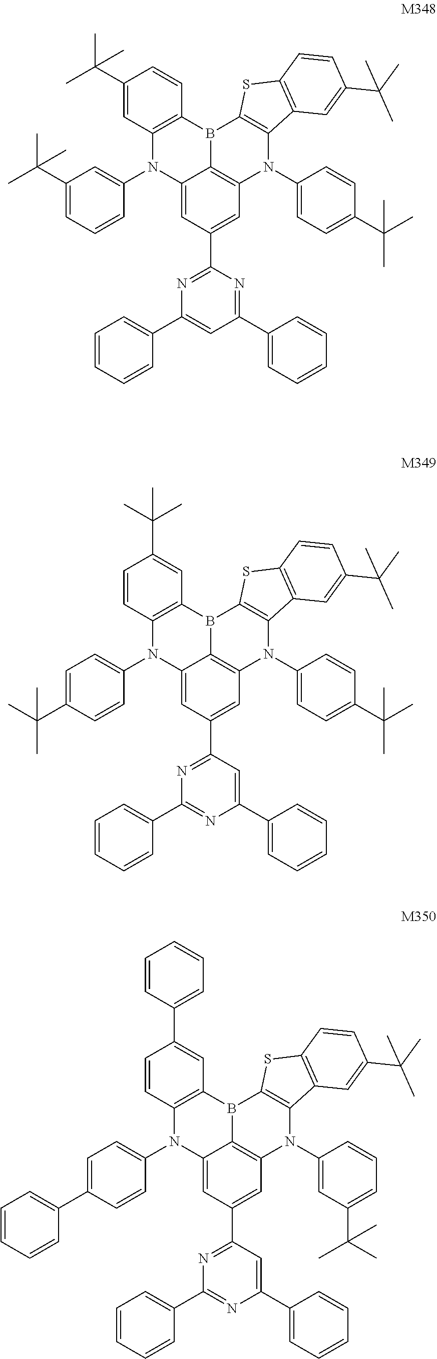

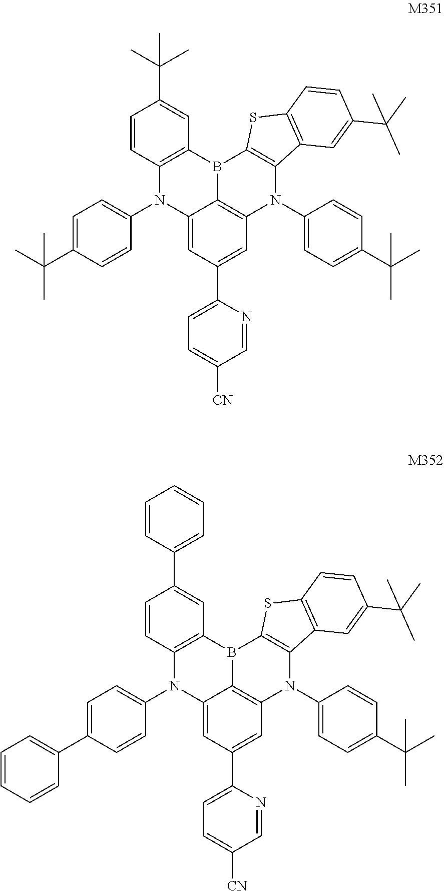 [SMILES: CC(C)(C)c1ccc(N2c3ccc(C(C)(C)C)cc3B3c4sc5ccc(C(C)(C)C)cc5c4N(c4ccc(C(C)(C)C)cc4)c4cc(-c5ccc(C#N)cn5)cc2c43)cc1 ; CC(C)(C)c1ccc(N2c3cc(-c4ccc(C#N)cn4)cc4c3B(c3cc(-c5ccccc5)ccc3N4c3ccc(-c4ccccc4)cc3)c3sc4ccc(C(C)(C)C)cc4c32)cc1]

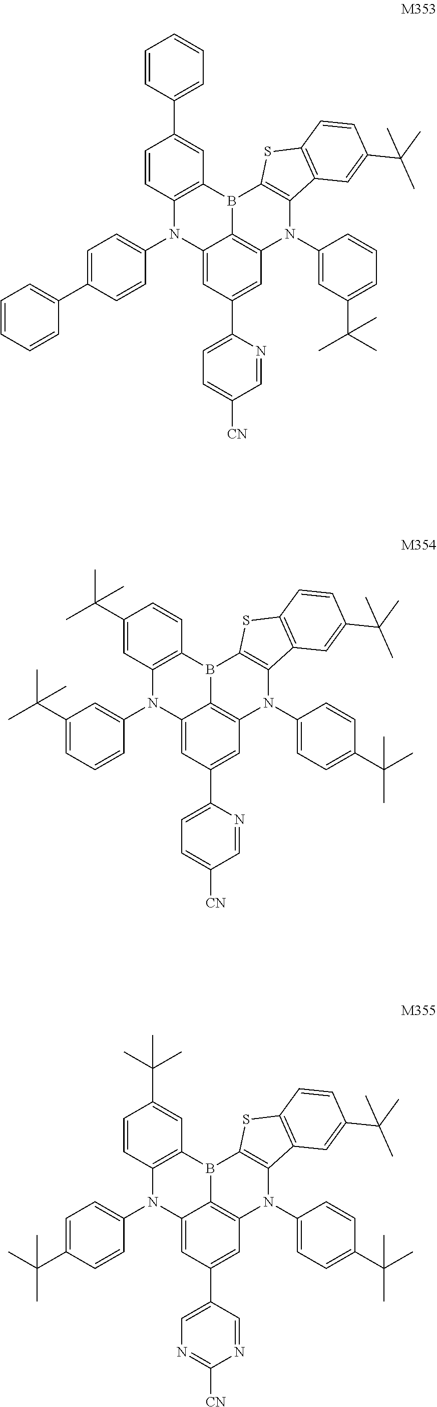

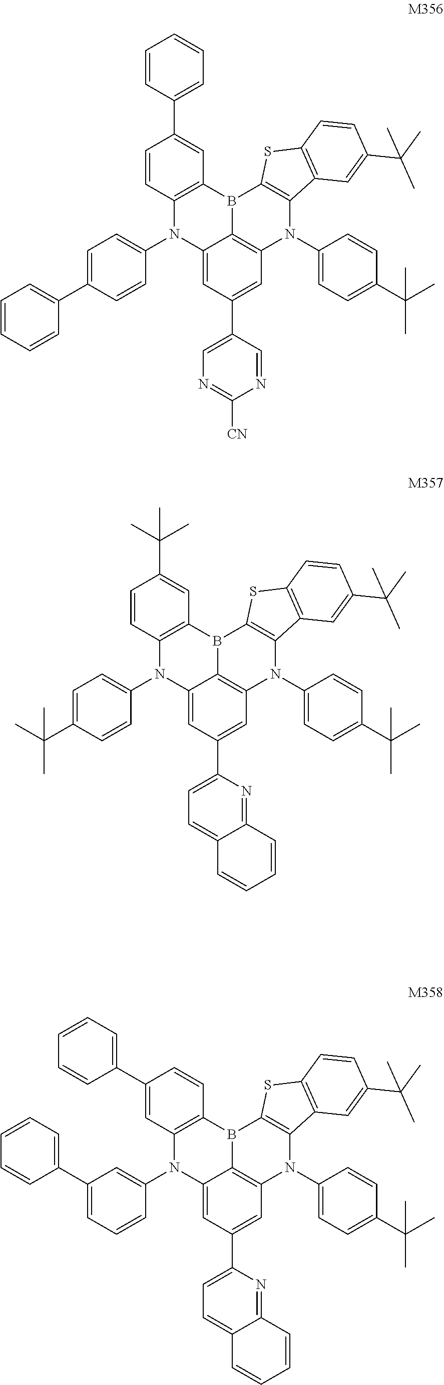

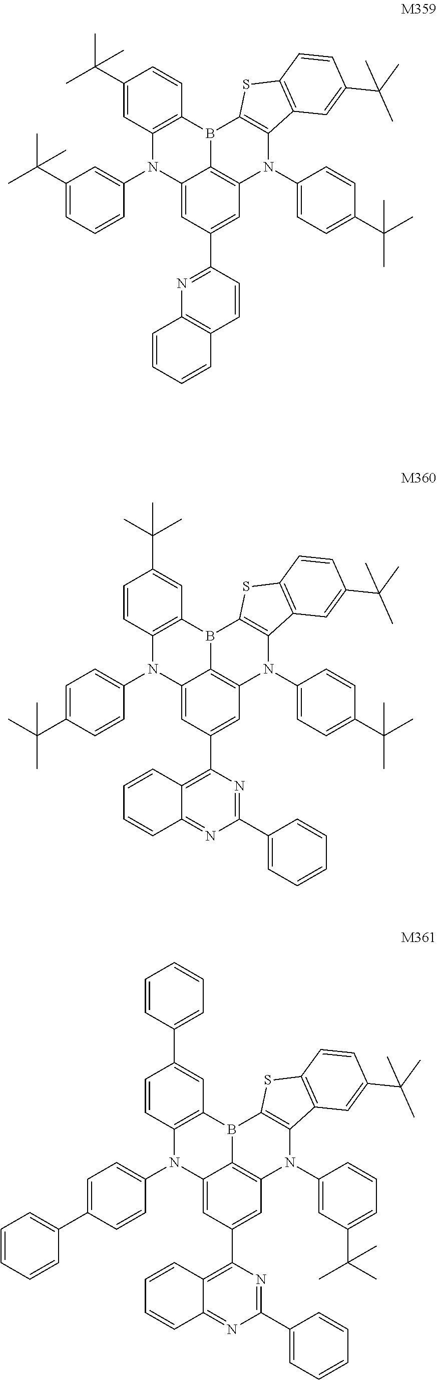

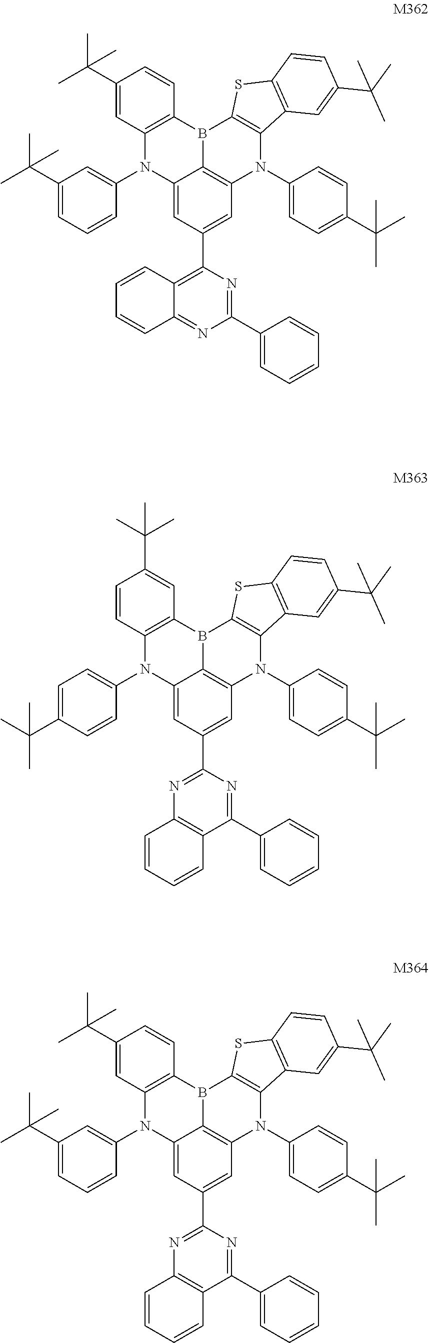

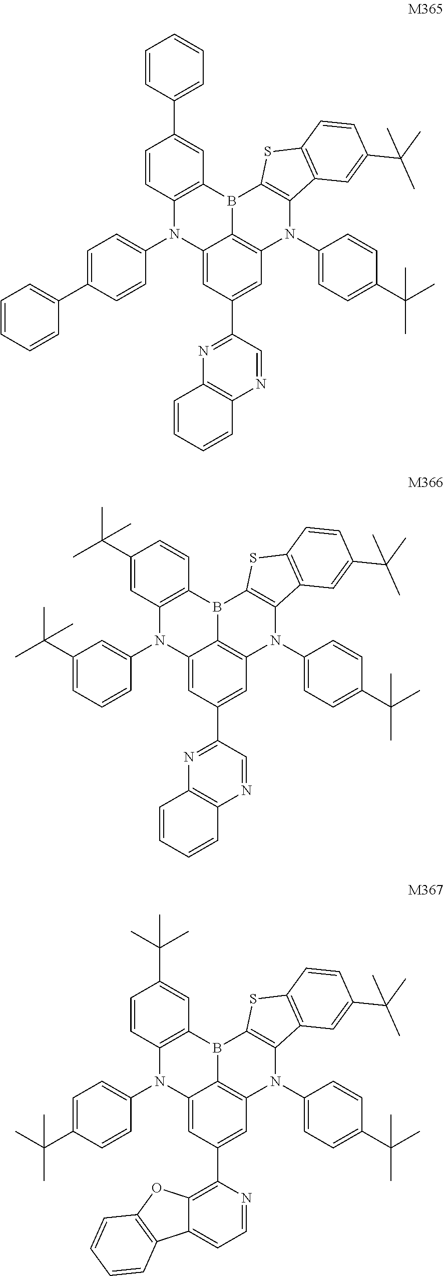

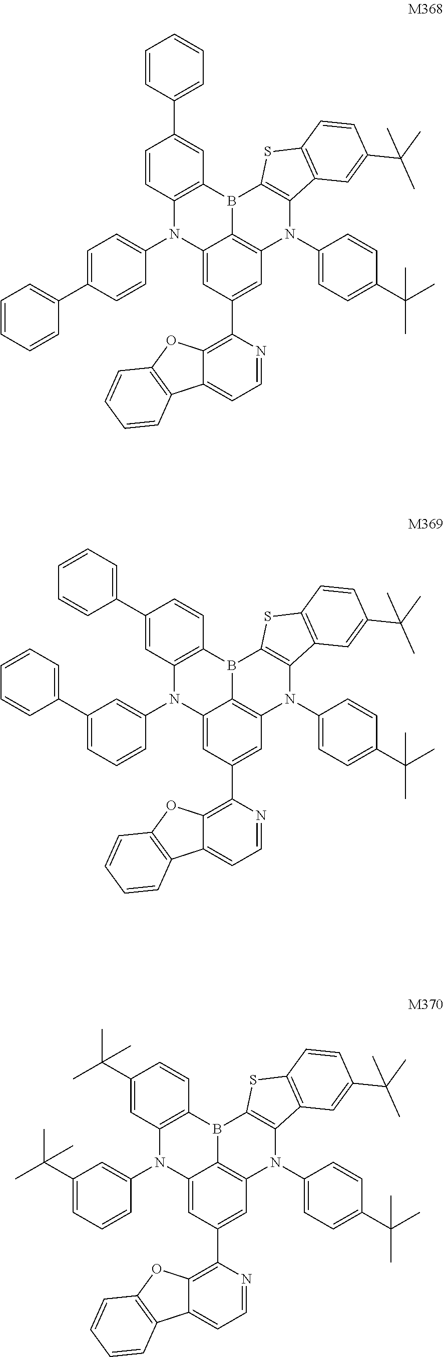

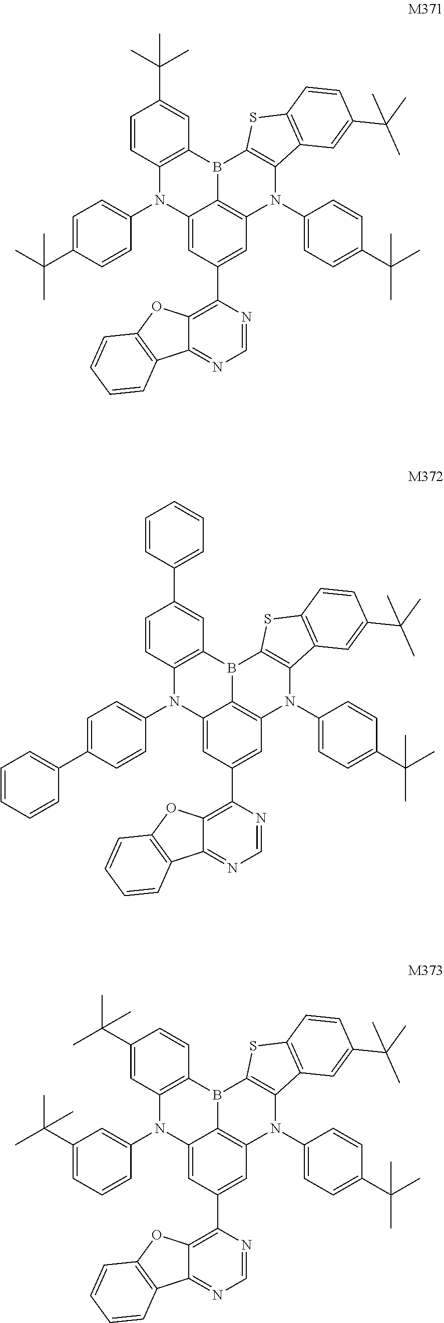

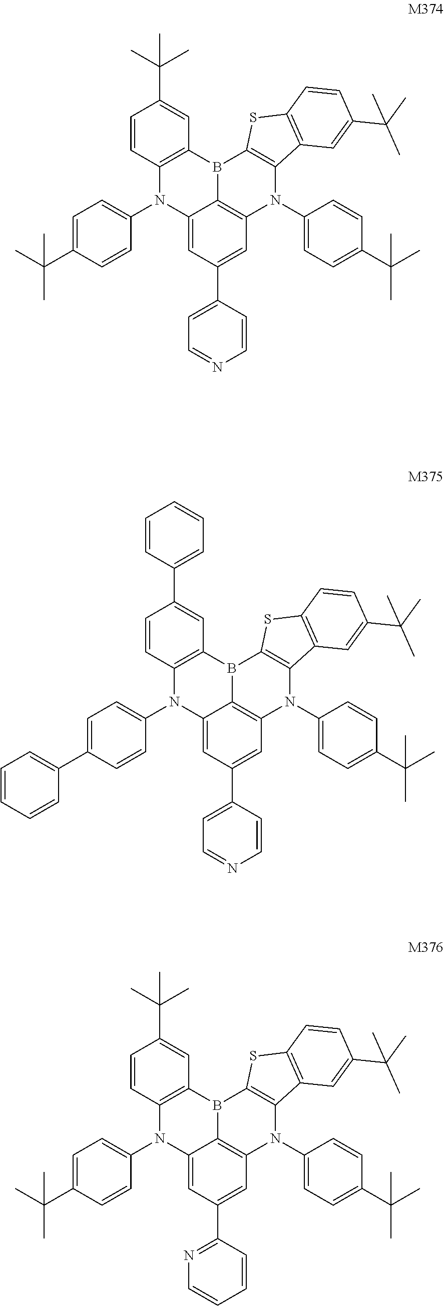

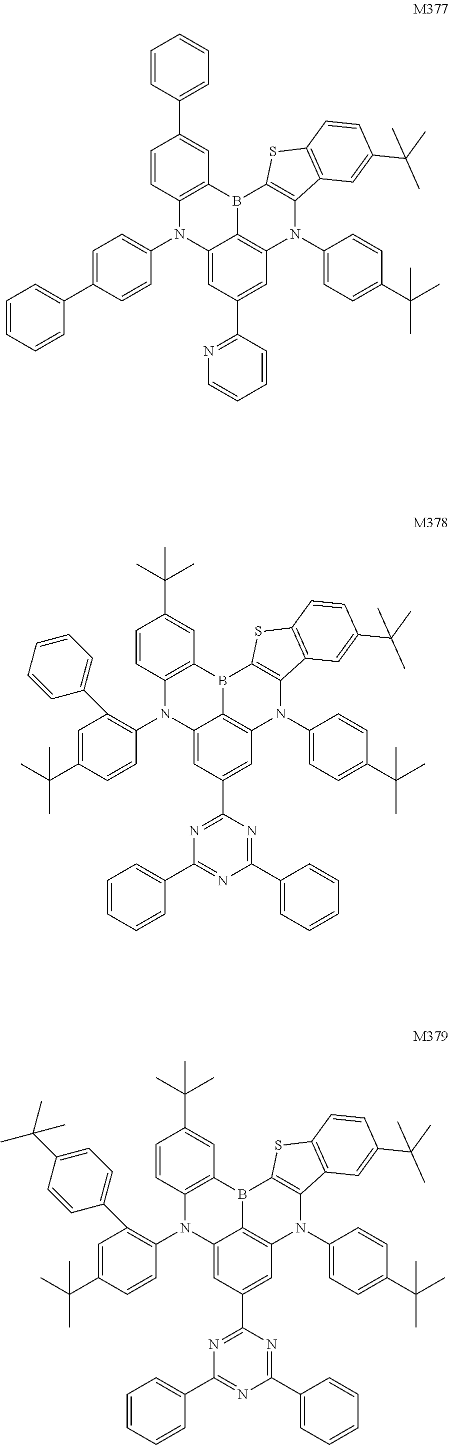

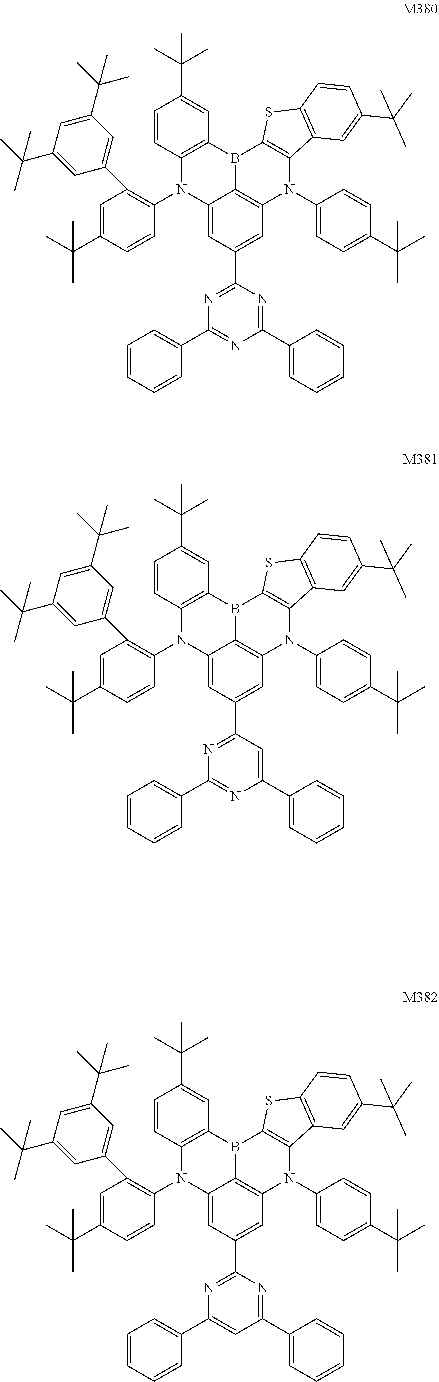

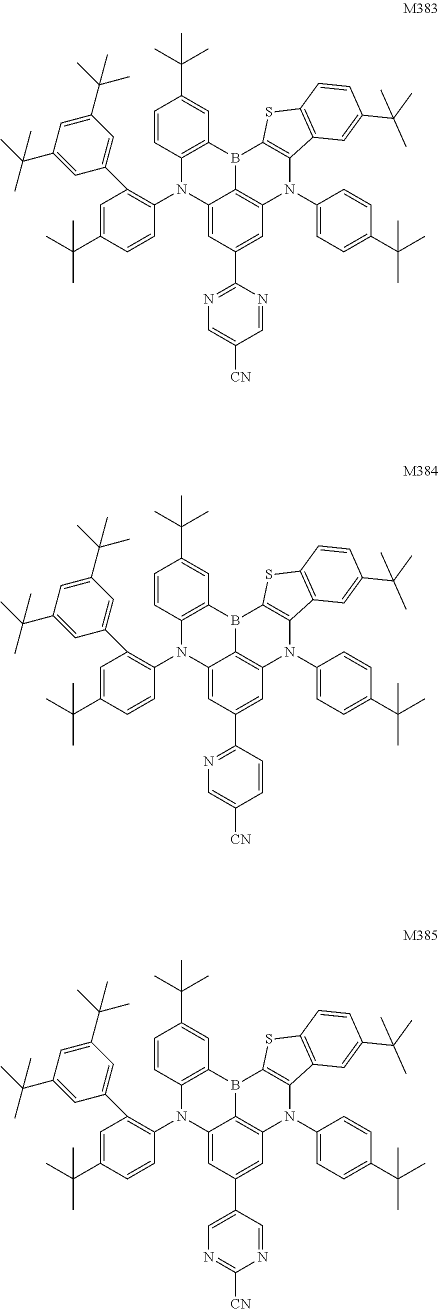

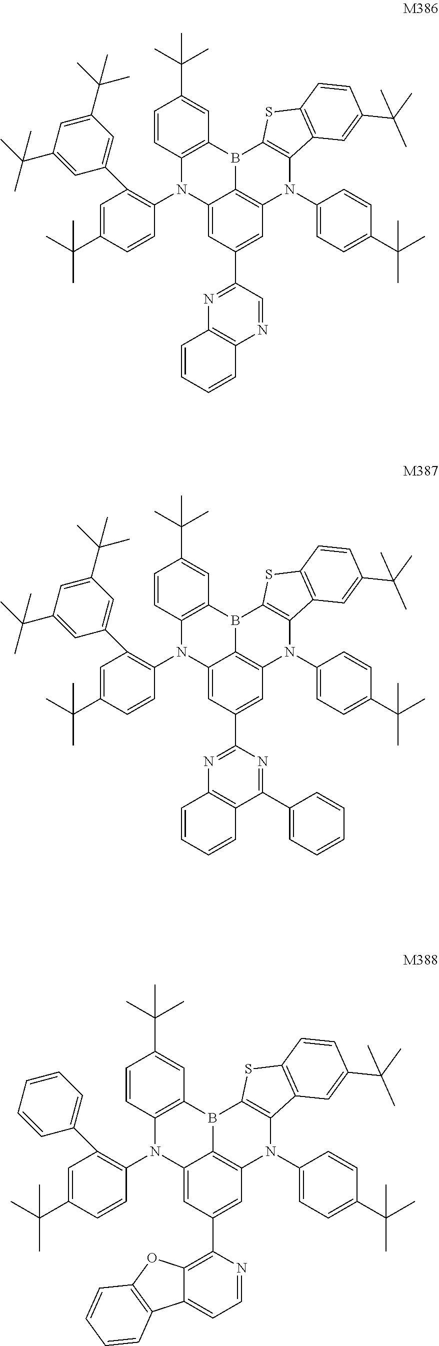

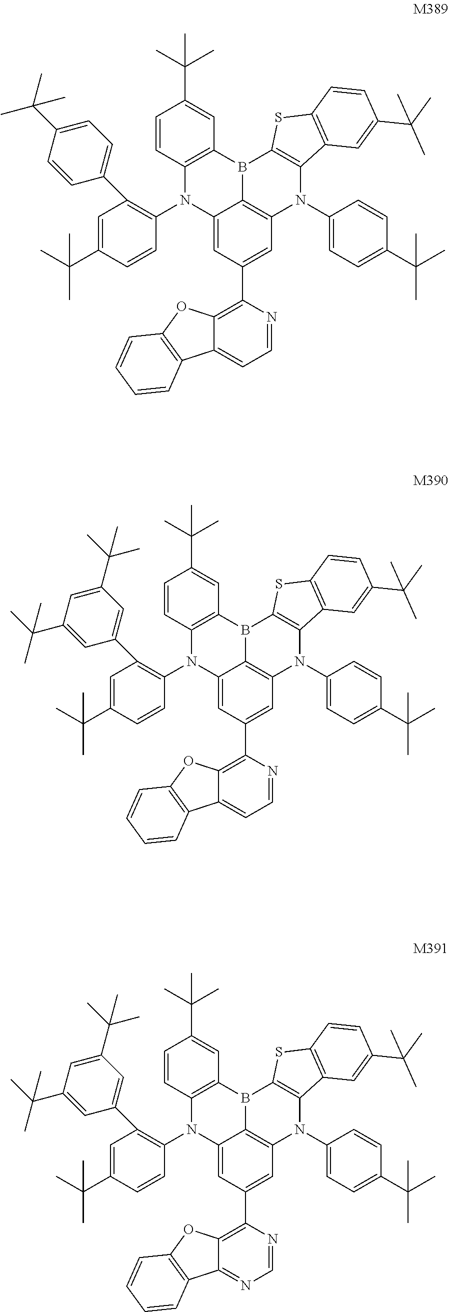

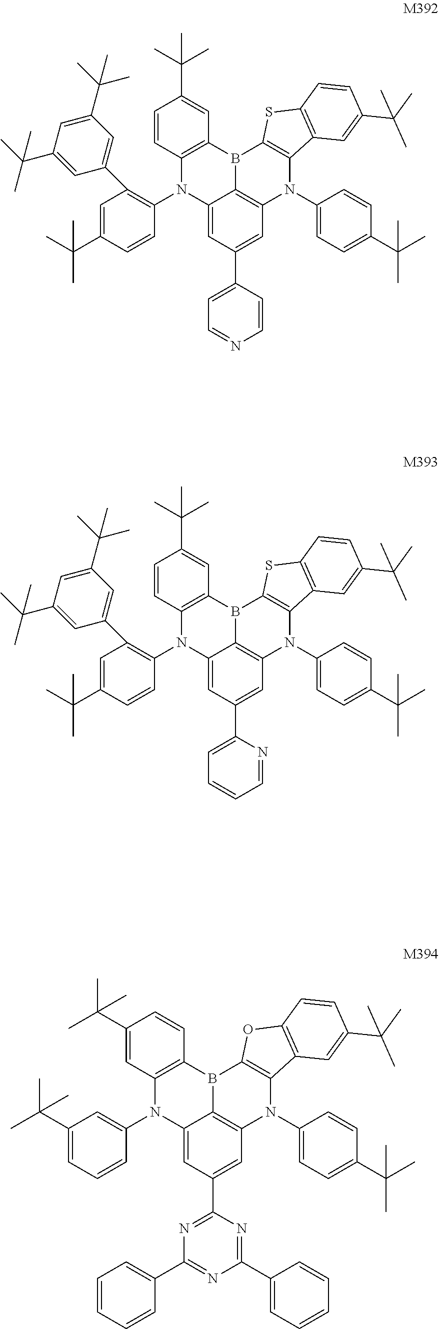

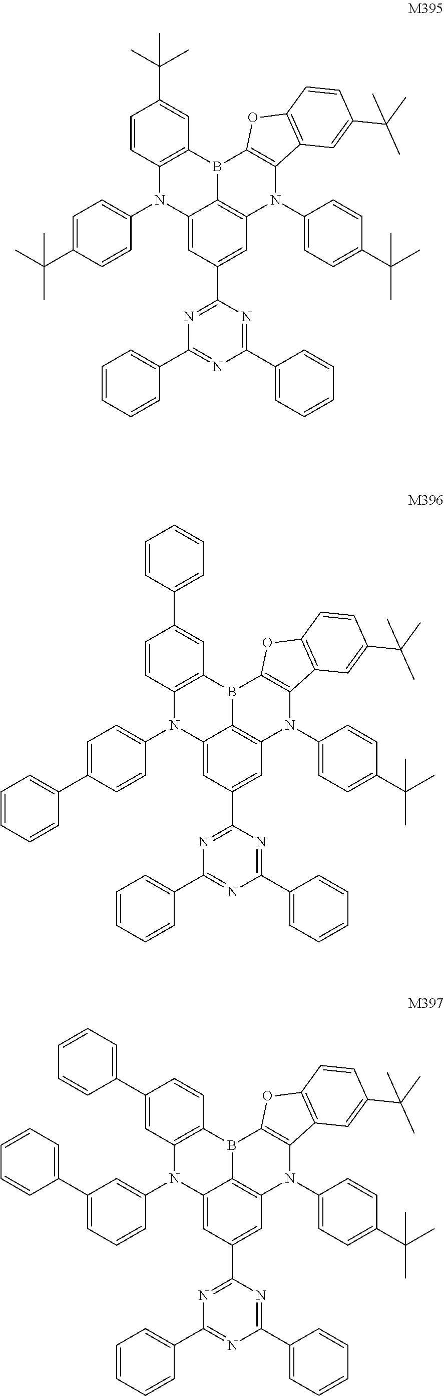 [SMILES: CC(C)(C)c1ccc(N2c3ccc(C(C)(C)C)cc3B3c4oc5ccc(C(C)(C)C)cc5c4N(c4ccc(C(C)(C)C)cc4)c4cc(-c5nc(-c6ccccc6)nc(-c6ccccc6)n5)cc2c43)cc1 ; CC(C)(C)c1ccc(N2c3cc(-c4nc(-c5ccccc5)nc(-c5ccccc5)n4)cc4c3B(c3cc(-c5ccccc5)ccc3N4c3ccc(-c4ccccc4)cc3)c3oc4ccc(C(C)(C)C)cc4c32)cc1 ; CC(C)(C)c1ccc(N2c3cc(-c4nc(-c5ccccc5)nc(-c5ccccc5)n4)cc4c3B(c3ccc(-c5ccccc5)cc3N4c3cccc(-c4ccccc4)c3)c3oc4ccc(C(C)(C)C)cc4c32)cc1]

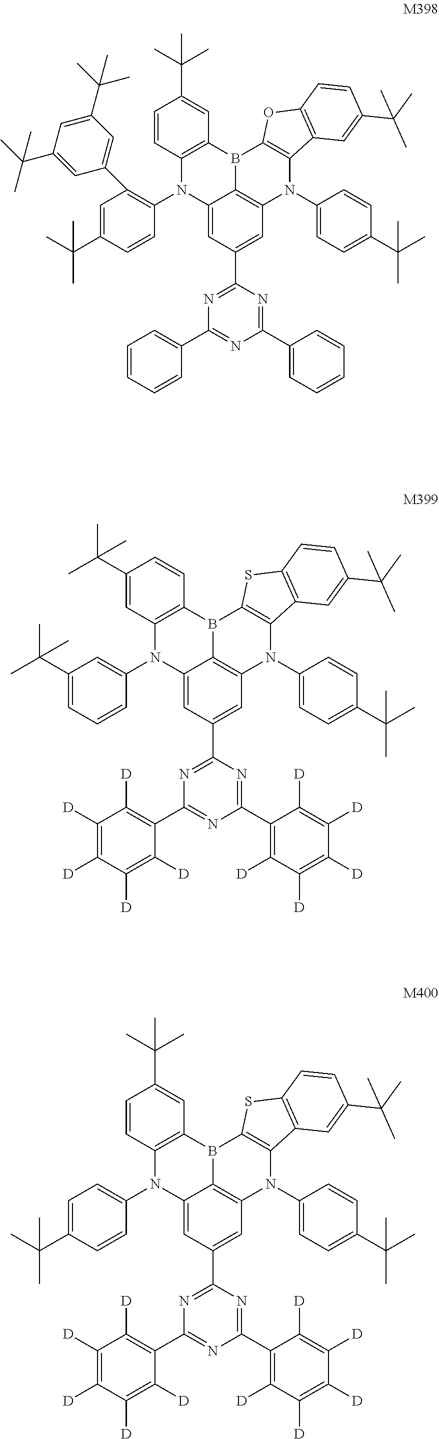

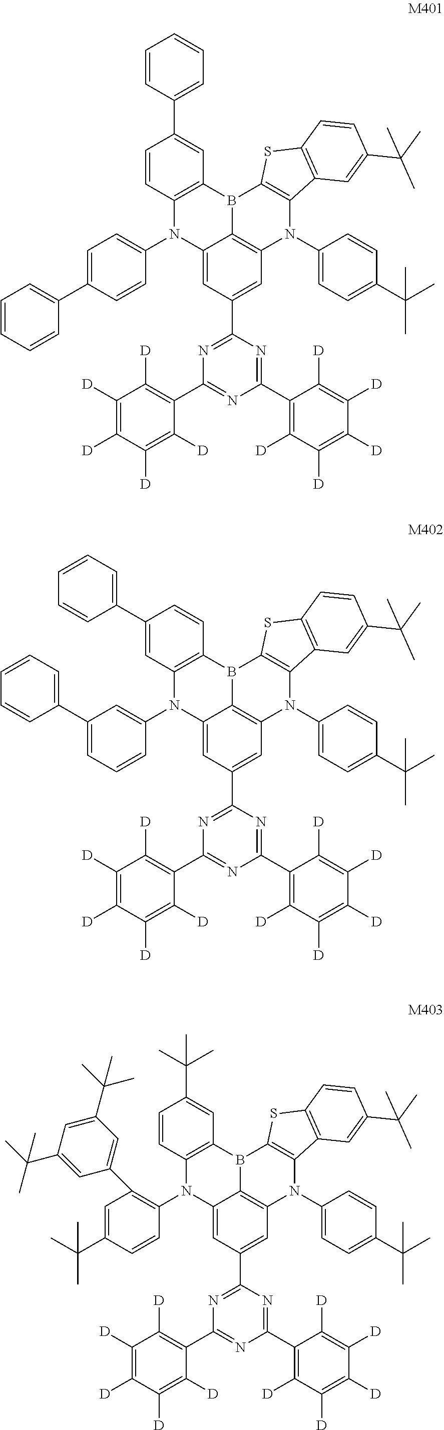

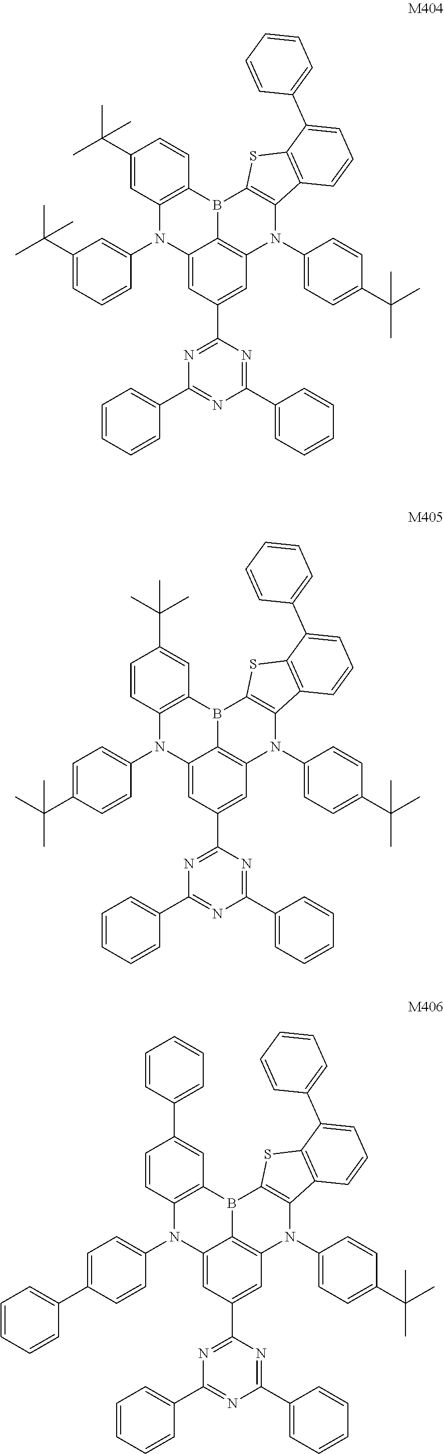

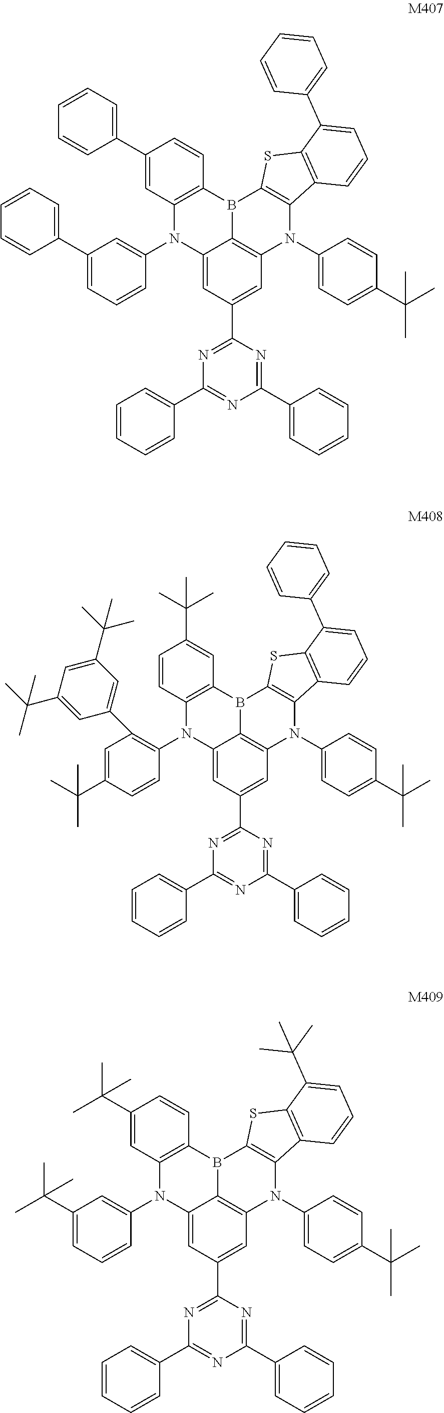

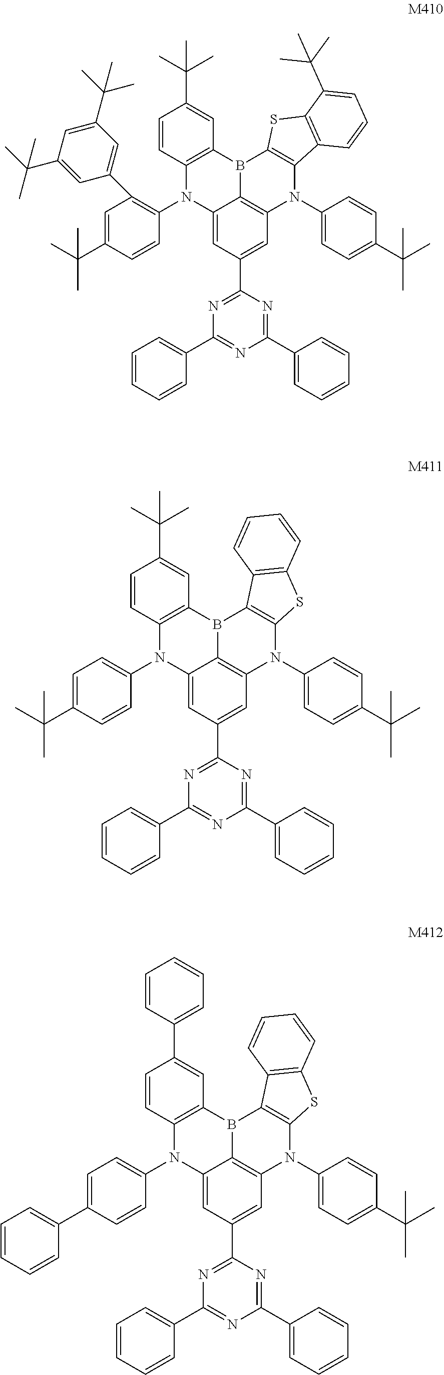

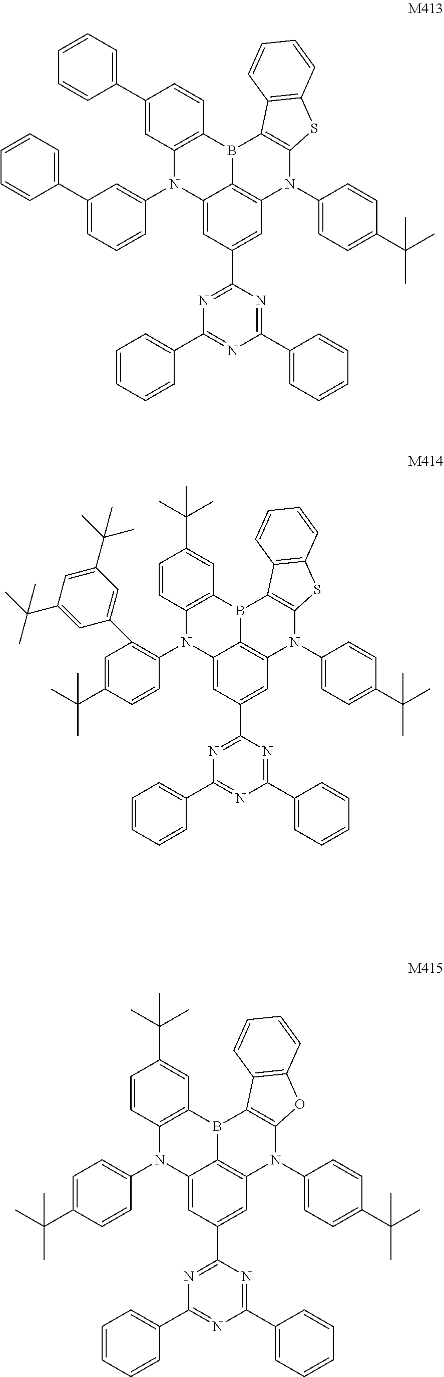

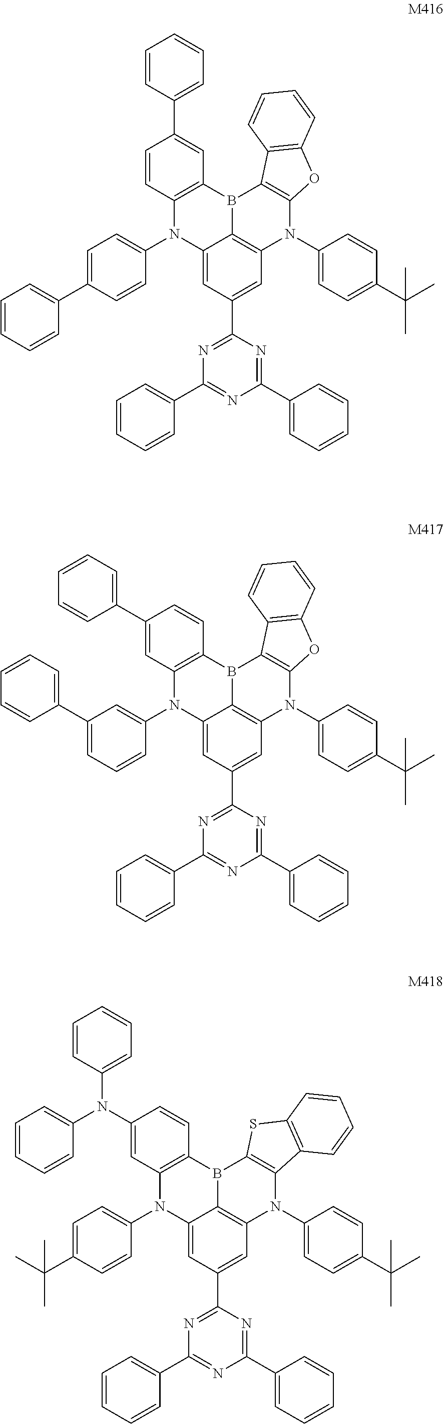

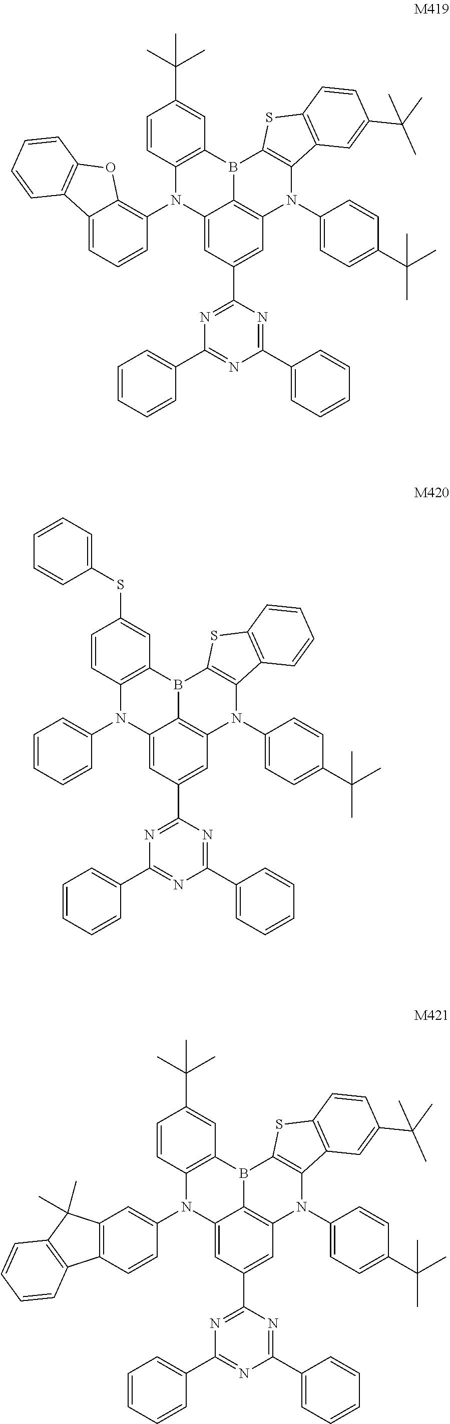 [SMILES: CC(C)(C)c1ccc(N2c3cc(-c4nc(-c5ccccc5)nc(-c5ccccc5)n4)cc4c3B(c3cc(C(C)(C)C)ccc3N4c3cccc4c3oc3ccccc34)c3sc4ccc(C(C)(C)C)cc4c32)cc1 ; CC(C)(C)c1ccc(N2c3cc(-c4nc(-c5ccccc5)nc(-c5ccccc5)n4)cc4c3B(c3cc(Sc5ccccc5)ccc3N4c3ccccc3)c3sc4ccccc4c32)cc1 ; CC(C)(C)c1ccc(N2c3cc(-c4nc(-c5ccccc5)nc(-c5ccccc5)n4)cc4c3B(c3cc(C(C)(C)C)ccc3N4c3ccc4c(c3)C(C)(C)c3ccccc3-4)c3sc4ccc(C(C)(C)C)cc4c32)cc1]

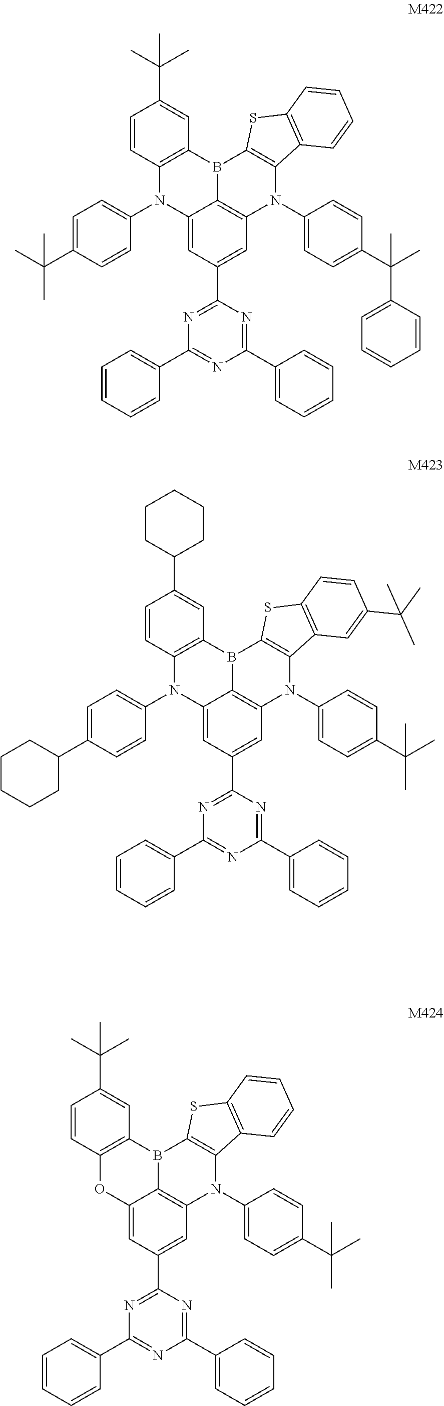 [SMILES: CC(C)(C)c1ccc(N2c3ccc(C(C)(C)C)cc3B3c4sc5ccccc5c4N(c4ccc(C(C)(C)c5ccccc5)cc4)c4cc(-c5nc(-c6ccccc6)nc(-c6ccccc6)n5)cc2c43)cc1 ; CC(C)(C)c1ccc(N2c3cc(-c4nc(-c5ccccc5)nc(-c5ccccc5)n4)cc4c3B(c3cc(C5CCCCC5)ccc3N4c3ccc(C4CCCCC4)cc3)c3sc4ccc(C(C)(C)C)cc4c32)cc1 ; CC(C)(C)c1ccc(N2c3cc(-c4nc(-c5ccccc5)nc(-c5ccccc5)n4)cc4c3B(c3cc(C(C)(C)C)ccc3O4)c3sc4ccccc4c32)cc1]

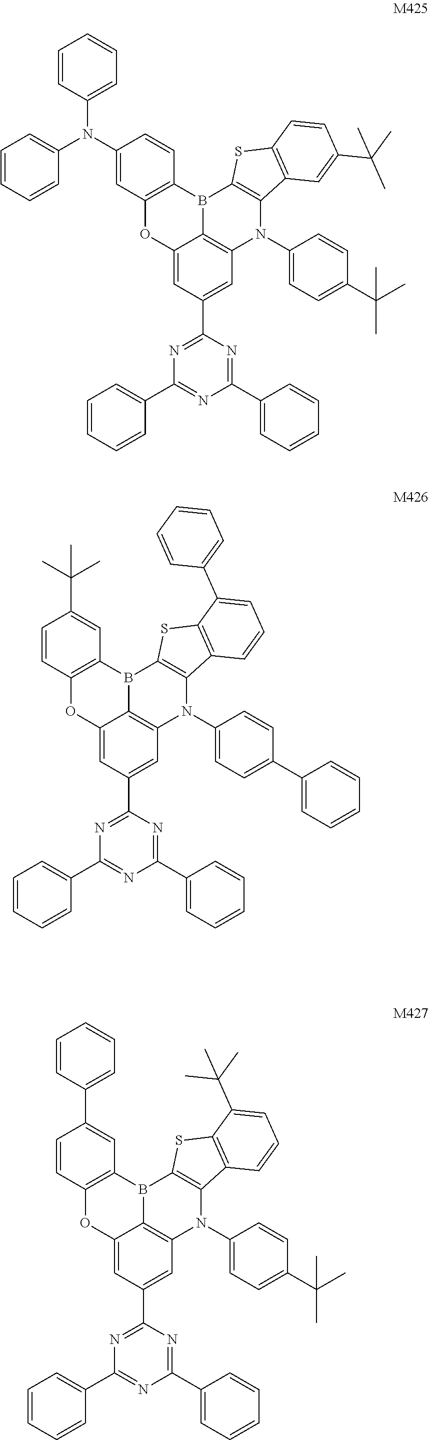 [SMILES: CC(C)(C)c1ccc(N2c3cc(-c4nc(-c5ccccc5)nc(-c5ccccc5)n4)cc4c3B(c3ccc(N(c5ccccc5)c5ccccc5)cc3O4)c3sc4ccc(C(C)(C)C)cc4c32)cc1 ; CC(C)(C)c1ccc2c(c1)B1c3sc4c(-c5ccccc5)cccc4c3N(c3ccc(-c4ccccc4)cc3)c3cc(-c4nc(-c5ccccc5)nc(-c5ccccc5)n4)cc(c31)O2 ; CC(C)(C)c1ccc(N2c3cc(-c4nc(-c5ccccc5)nc(-c5ccccc5)n4)cc4c3B(c3cc(-c5ccccc5)ccc3O4)c3sc4c(C(C)(C)C)cccc4c32)cc1]

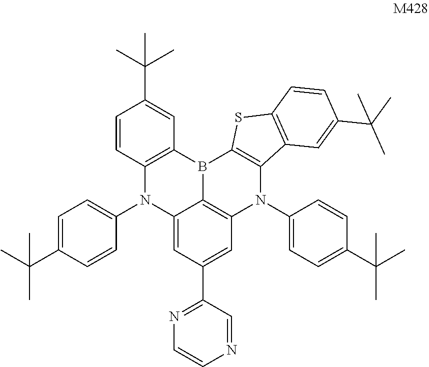 [SMILES: CC(C)(C)c1ccc(N2c3ccc(C(C)(C)C)cc3B3c4sc5ccc(C(C)(C)C)cc5c4N(c4ccc(C(C)(C)C)cc4)c4cc(-c5cnccn5)cc2c43)cc1]

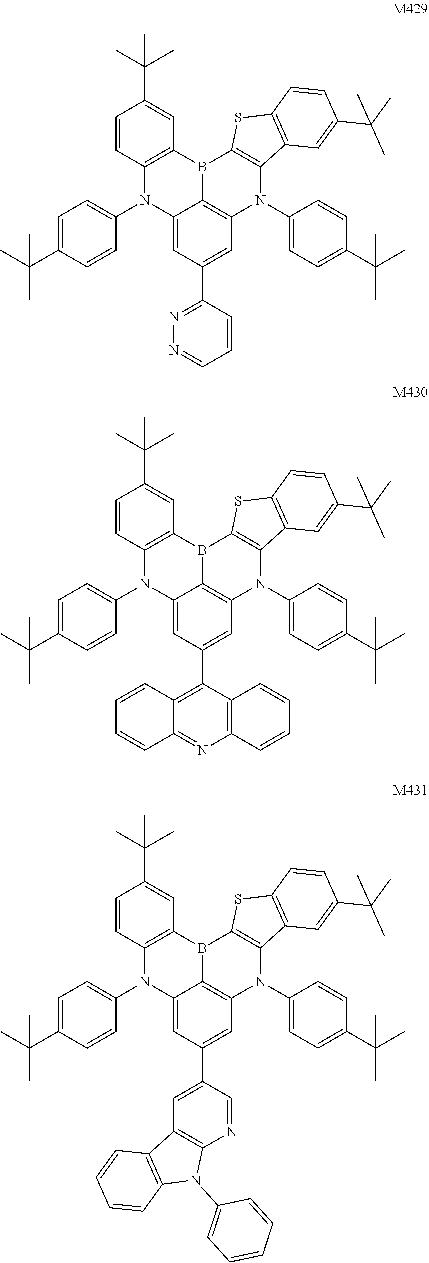

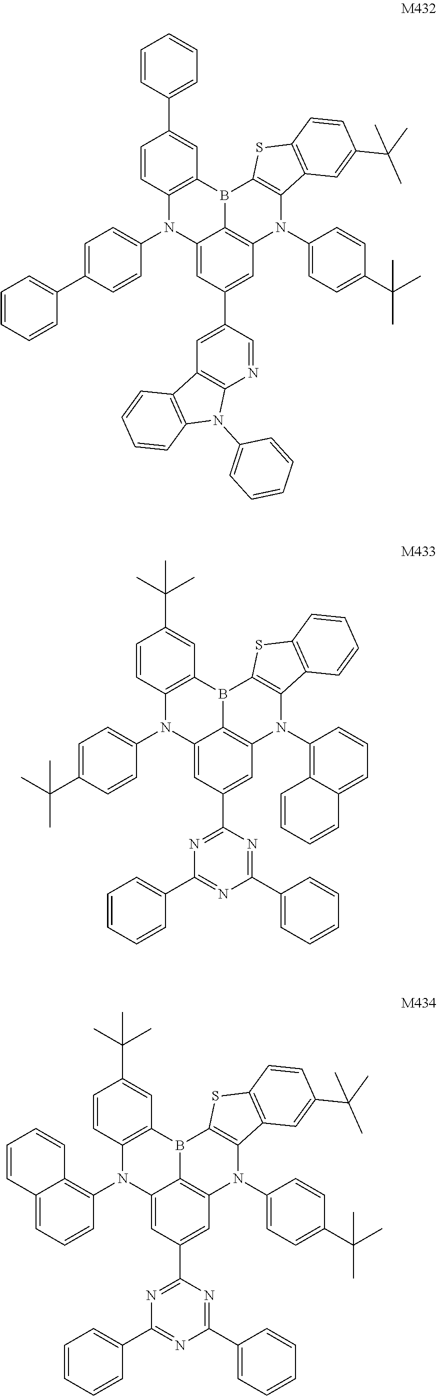

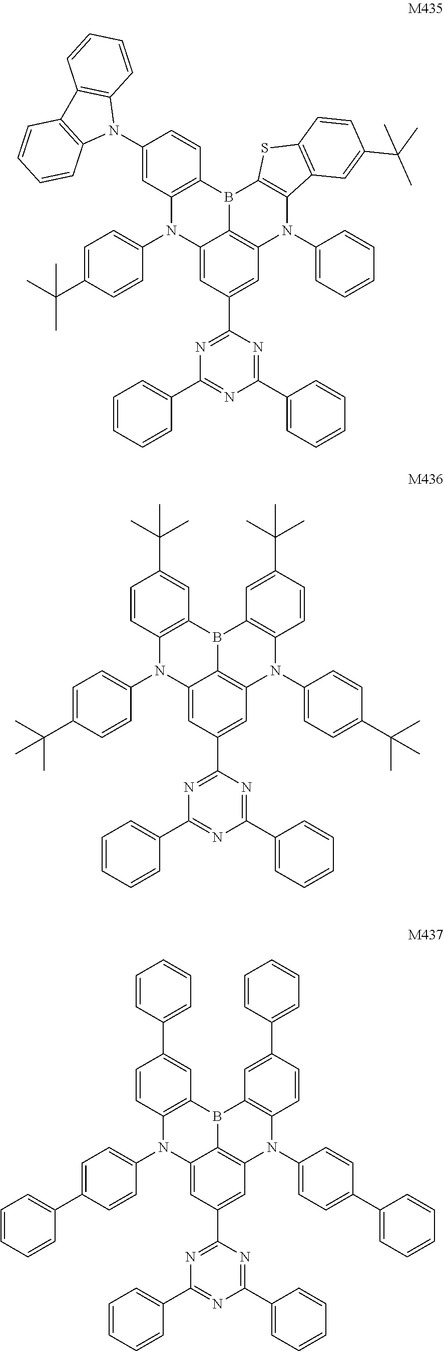

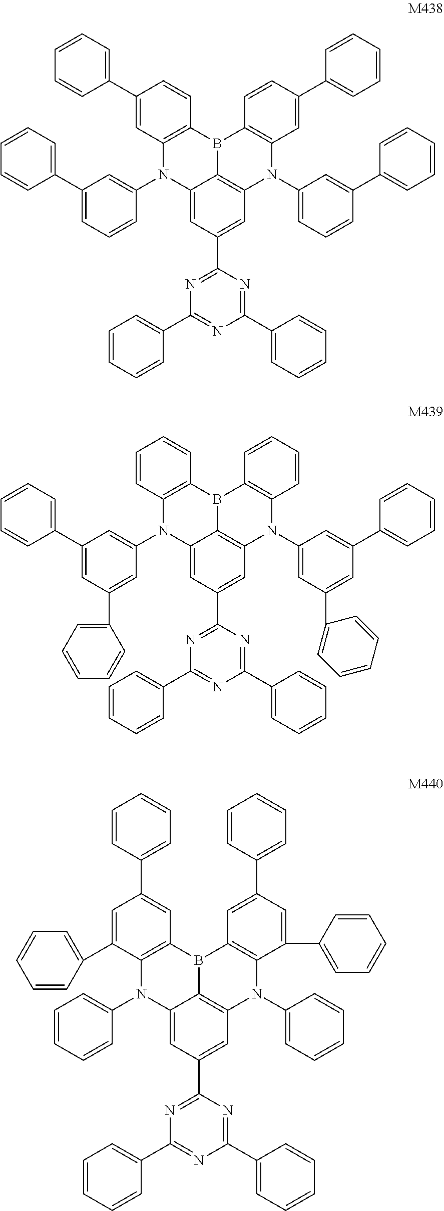 [SMILES: c1ccc(-c2cccc(N3c4cc(-c5ccccc5)ccc4B4c5ccc(-c6ccccc6)cc5N(c5cccc(-c6ccccc6)c5)c5cc(-c6nc(-c7ccccc7)nc(-c7ccccc7)n6)cc3c54)c2)cc1 ; c1ccc(-c2cc(-c3ccccc3)cc(N3c4ccccc4B4c5ccccc5N(c5cc(-c6ccccc6)cc(-c6ccccc6)c5)c5cc(-c6nc(-c7ccccc7)nc(-c7ccccc7)n6)cc3c54)c2)cc1 ; c1ccc(-c2cc3c(c(-c4ccccc4)c2)N(c2ccccc2)c2cc(-c4nc(-c5ccccc5)nc(-c5ccccc5)n4)cc4c2B3c2cc(-c3ccccc3)cc(-c3ccccc3)c2N4c2ccccc2)cc1]

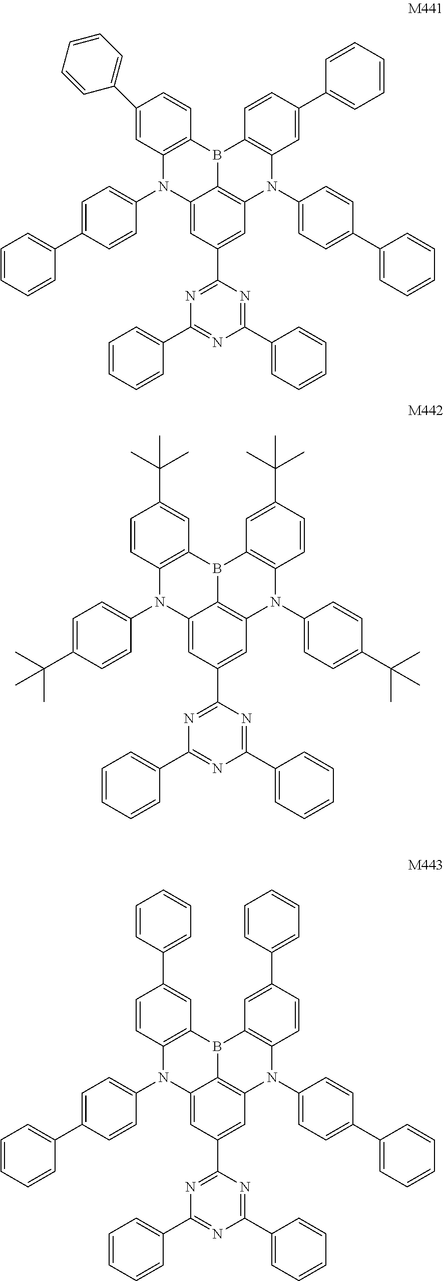 [SMILES: c1ccc(-c2ccc(N3c4cc(-c5ccccc5)ccc4B4c5ccc(-c6ccccc6)cc5N(c5ccc(-c6ccccc6)cc5)c5cc(-c6nc(-c7ccccc7)nc(-c7ccccc7)n6)cc3c54)cc2)cc1 ; CC(C)(C)c1ccc(N2c3ccc(C(C)(C)C)cc3B3c4cc(C(C)(C)C)ccc4N(c4ccc(C(C)(C)C)cc4)c4cc(-c5nc(-c6ccccc6)nc(-c6ccccc6)n5)cc2c43)cc1 ; c1ccc(-c2ccc(N3c4ccc(-c5ccccc5)cc4B4c5cc(-c6ccccc6)ccc5N(c5ccc(-c6ccccc6)cc5)c5cc(-c6nc(-c7ccccc7)nc(-c7ccccc7)n6)cc3c54)cc2)cc1]

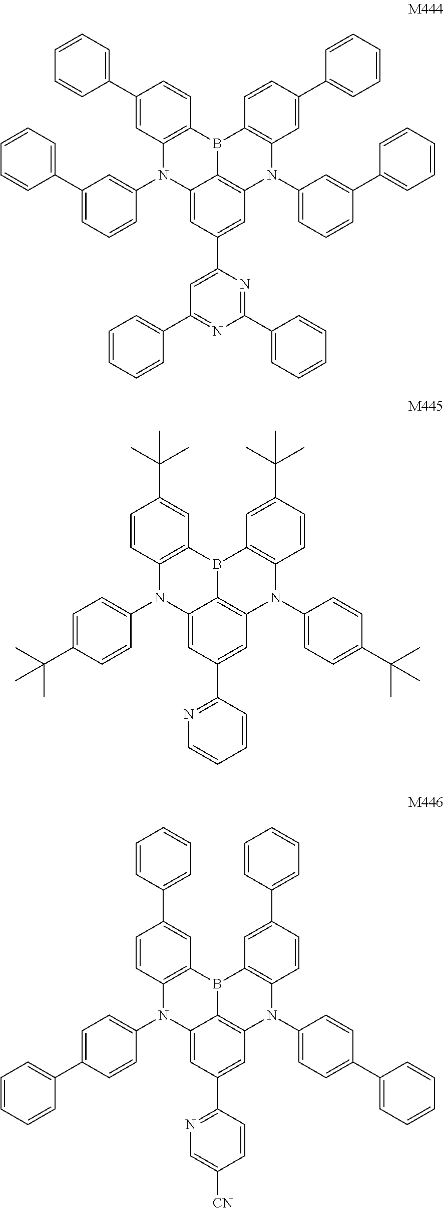 [SMILES: c1ccc(-c2cccc(N3c4cc(-c5ccccc5)ccc4B4c5ccc(-c6ccccc6)cc5N(c5cccc(-c6ccccc6)c5)c5cc(-c6cc(-c7ccccc7)nc(-c7ccccc7)n6)cc3c54)c2)cc1 ; CC(C)(C)c1ccc(N2c3ccc(C(C)(C)C)cc3B3c4cc(C(C)(C)C)ccc4N(c4ccc(C(C)(C)C)cc4)c4cc(-c5ccccn5)cc2c43)cc1 ; N#Cc1ccc(-c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)nc1]

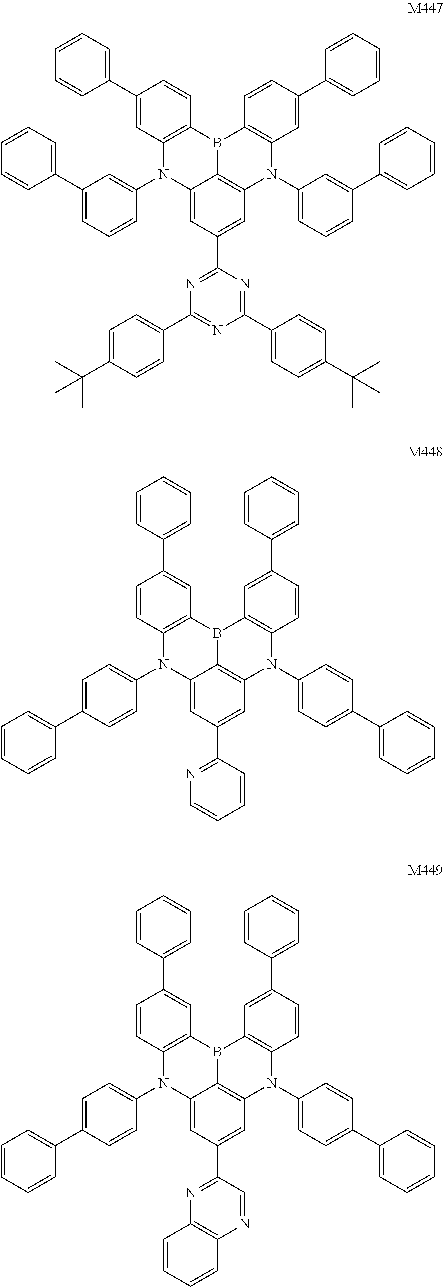 [SMILES: CC(C)(C)c1ccc(-c2nc(-c3ccc(C(C)(C)C)cc3)nc(-c3cc4c5c(c3)N(c3cccc(-c6ccccc6)c3)c3cc(-c6ccccc6)ccc3B5c3ccc(-c5ccccc5)cc3N4c3cccc(-c4ccccc4)c3)n2)cc1 ; c1ccc(-c2ccc(N3c4ccc(-c5ccccc5)cc4B4c5cc(-c6ccccc6)ccc5N(c5ccc(-c6ccccc6)cc5)c5cc(-c6ccccn6)cc3c54)cc2)cc1 ; c1ccc(-c2ccc(N3c4ccc(-c5ccccc5)cc4B4c5cc(-c6ccccc6)ccc5N(c5ccc(-c6ccccc6)cc5)c5cc(-c6cnc7ccccc7n6)cc3c54)cc2)cc1]

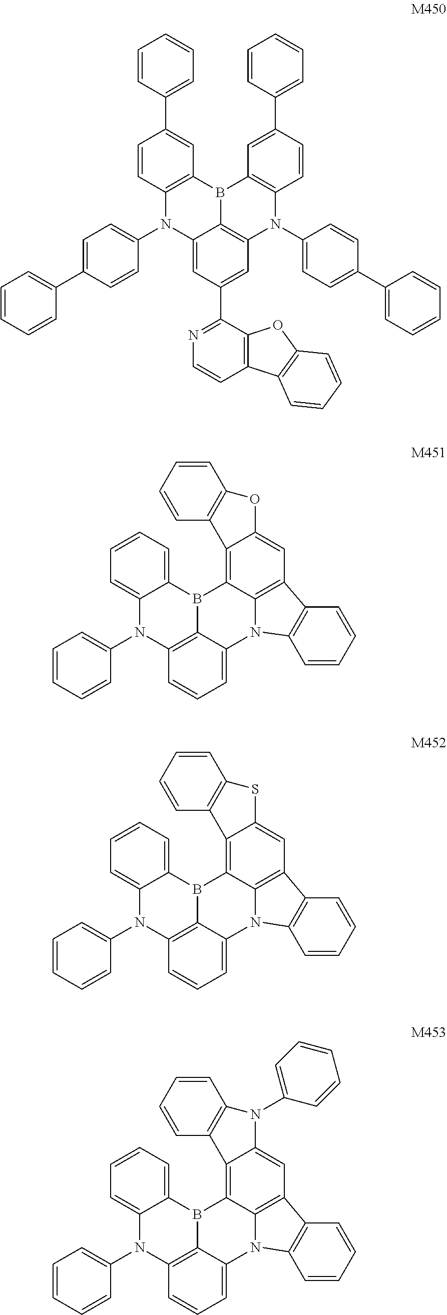 [SMILES: c1ccc(-c2ccc(N3c4ccc(-c5ccccc5)cc4B4c5cc(-c6ccccc6)ccc5N(c5ccc(-c6ccccc6)cc5)c5cc(-c6nccc7c6oc6ccccc67)cc3c54)cc2)cc1 ; c1ccc(N2c3ccccc3B3c4c2cccc4-n2c4ccccc4c4cc5oc6ccccc6c5c3c42)cc1 ; c1ccc(N2c3ccccc3B3c4c2cccc4-n2c4ccccc4c4cc5sc6ccccc6c5c3c42)cc1 ; c1ccc(N2c3ccccc3B3c4c2cccc4-n2c4ccccc4c4cc5c(c3c42)c2ccccc2n5-c2ccccc2)cc1]

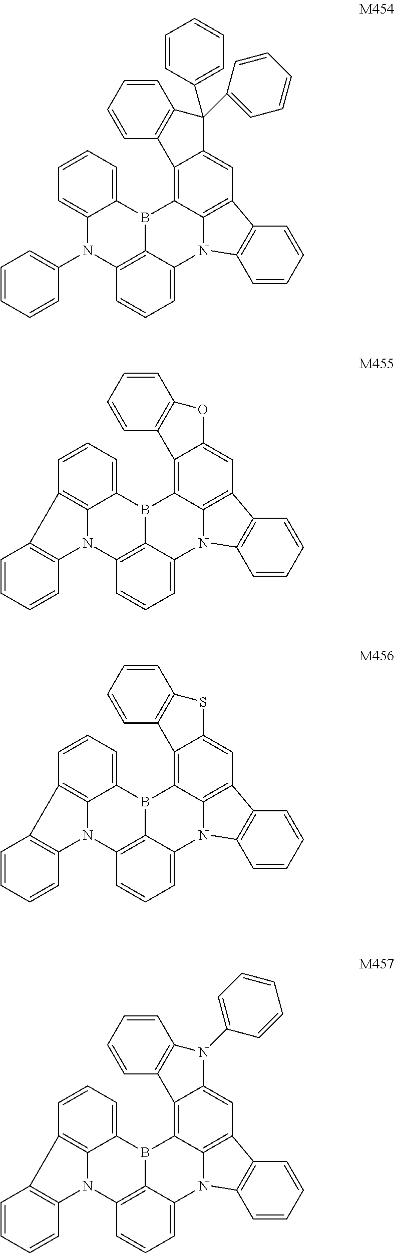 [SMILES: c1ccc(N2c3ccccc3B3c4c2cccc4-n2c4ccccc4c4cc5c(c3c42)-c2ccccc2C5(c2ccccc2)c2ccccc2)cc1 ; c1cc2c3c(c1)-n1c4ccccc4c4cc5oc6ccccc6c5c(c41)B3c1cccc3c4ccccc4n-2c13 ; c1cc2c3c(c1)-n1c4ccccc4c4cc5sc6ccccc6c5c(c41)B3c1cccc3c4ccccc4n-2c13 ; c1ccc(-n2c3ccccc3c3c4c5c(cc32)c2ccccc2n5-c2cccc3c2B4c2cccc4c5ccccc5n-3c24)cc1]

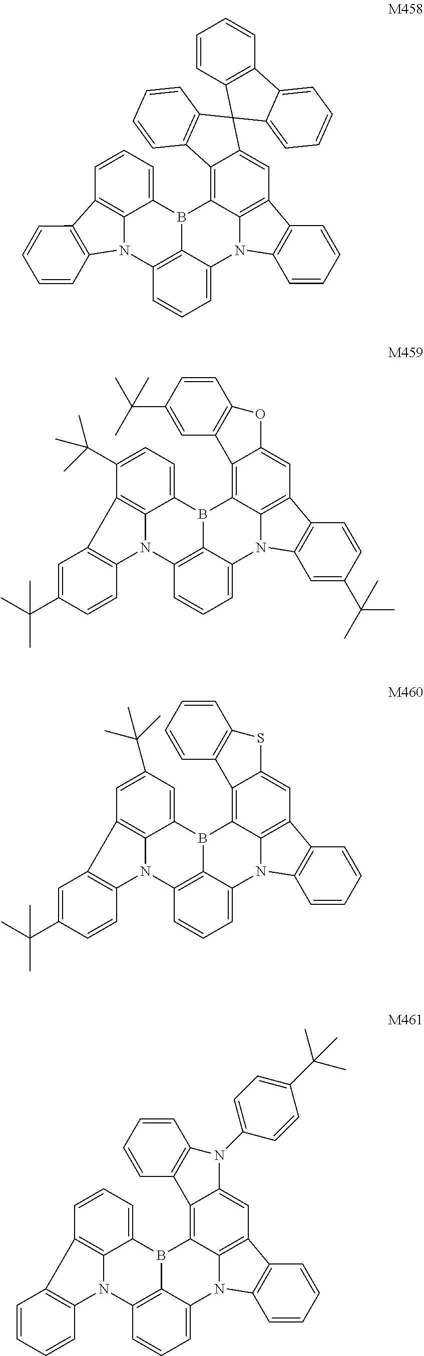

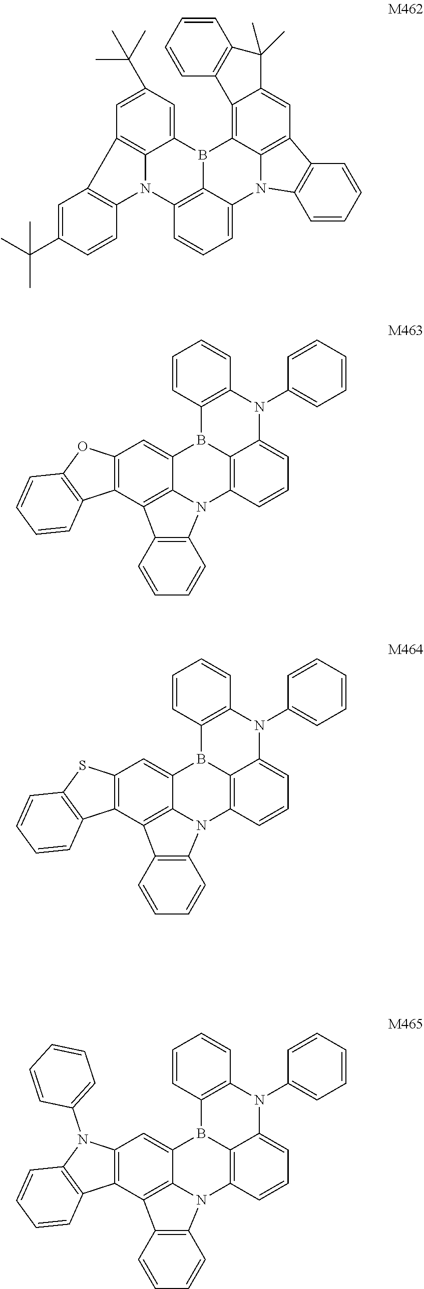 [SMILES: CC(C)(C)c1ccc2c(c1)c1cc(C(C)(C)C)cc3c1n2-c1cccc2c1B3c1c3c(cc4c5ccccc5n-2c14)C(C)(C)c1ccccc1-3 ; c1ccc(N2c3ccccc3B3c4c2cccc4-n2c4ccccc4c4c5c(cc3c42)oc2ccccc25)cc1 ; c1ccc(N2c3ccccc3B3c4c2cccc4-n2c4ccccc4c4c5c(cc3c42)sc2ccccc25)cc1 ; c1ccc(N2c3ccccc3B3c4c2cccc4-n2c4ccccc4c4c5c6ccccc6n(-c6ccccc6)c5cc3c42)cc1]

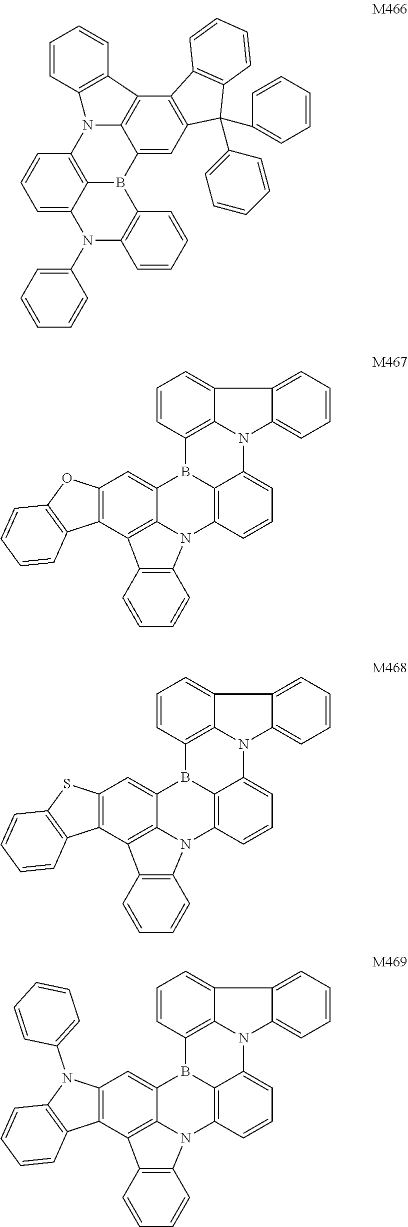

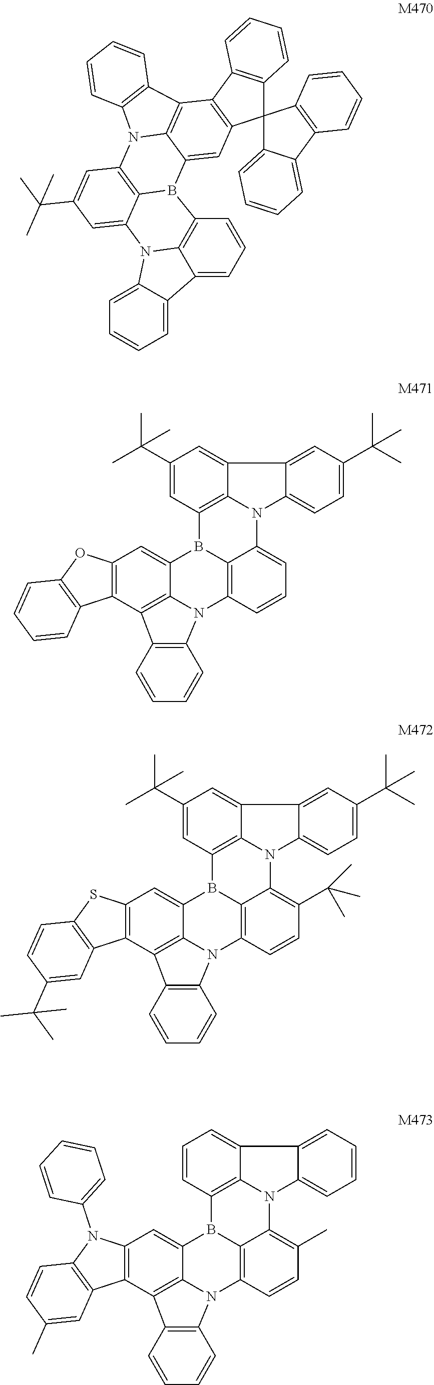

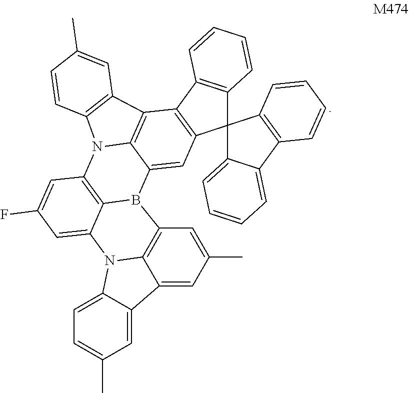 [SMILES: Cc1ccc2c(c1)c1cc(C)cc3c1n2-c1cc(F)cc2c1B3c1cc3c(c4c5cc(C)ccc5n-2c14)-c1ccccc1C31c2ccccc2-c2ccccc21]

17. The organic light-emitting diode according to claim 1, wherein the phosphorescent sensitizer comprises one or more of the following compounds GPD-1 to GPD-47:

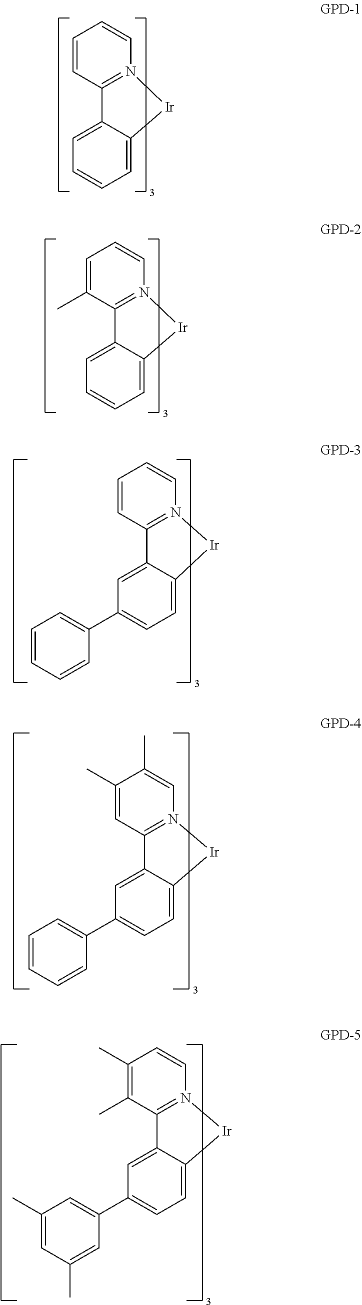

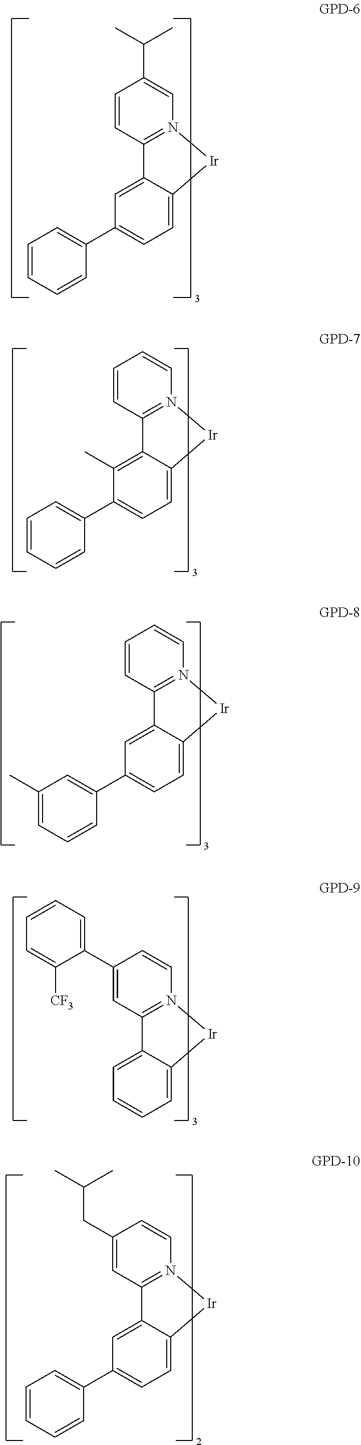

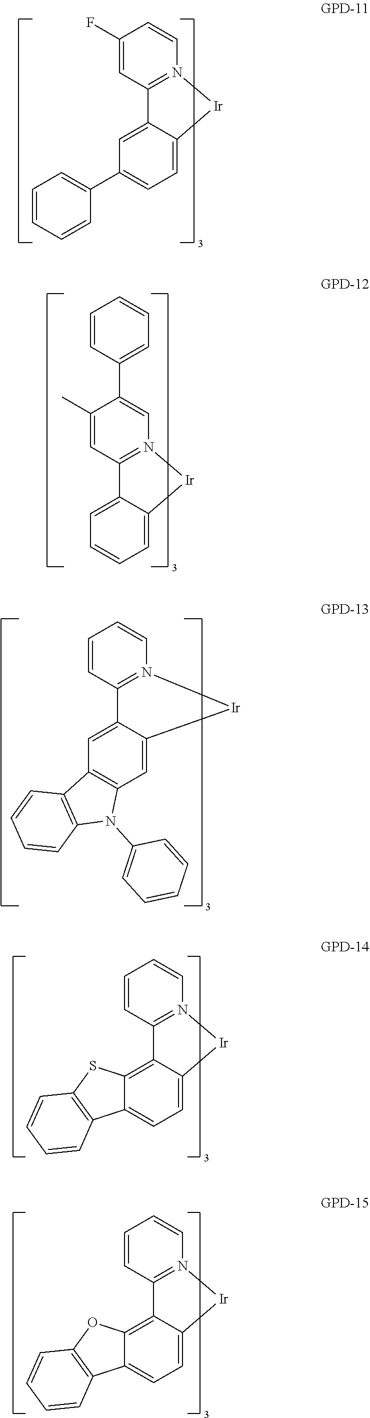

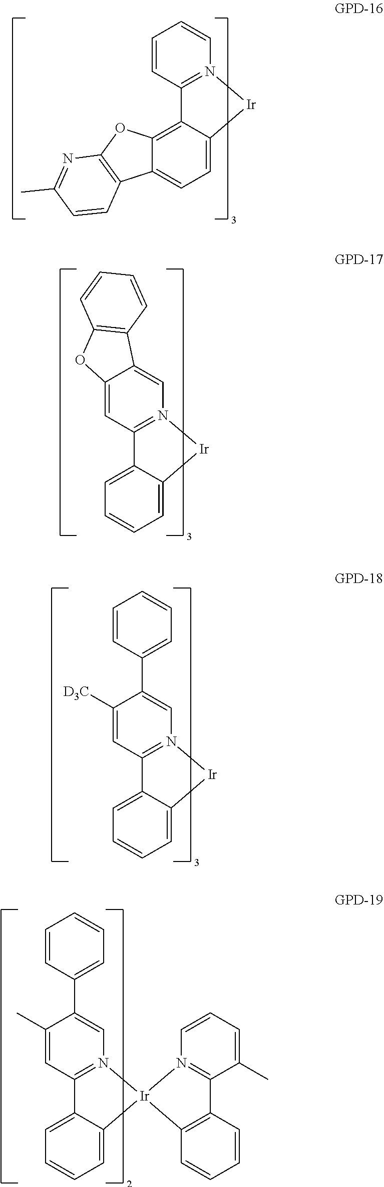

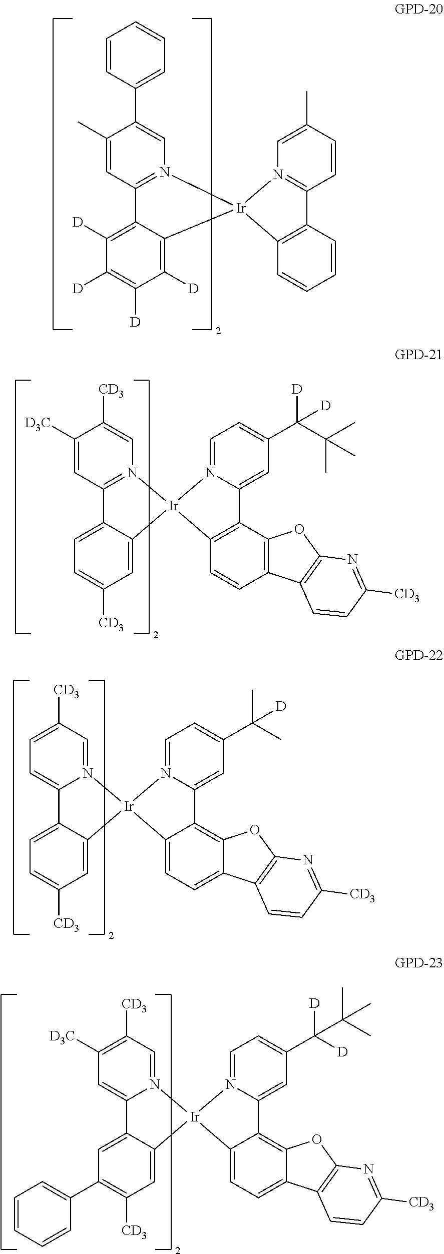

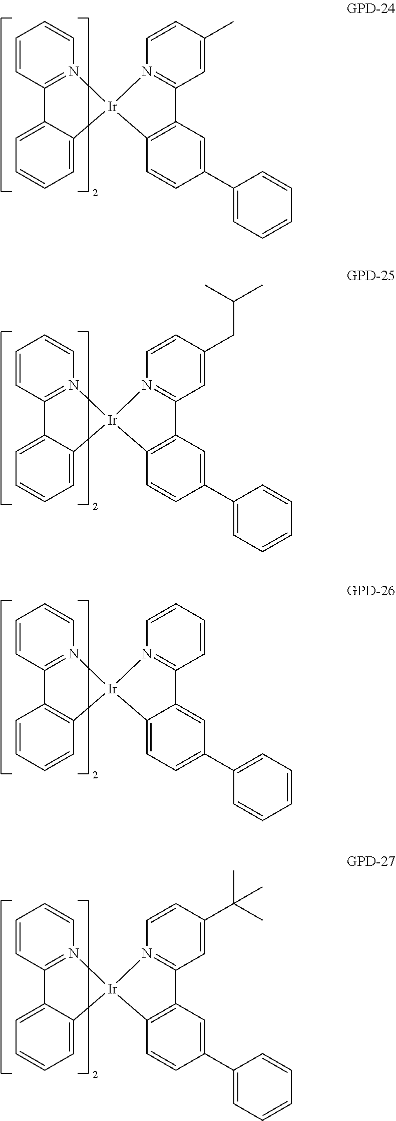

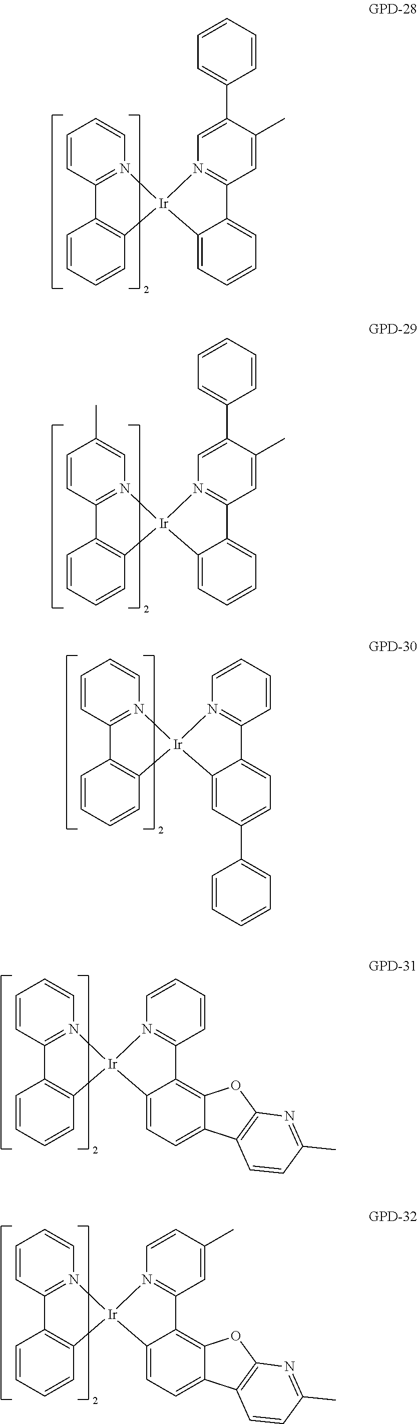

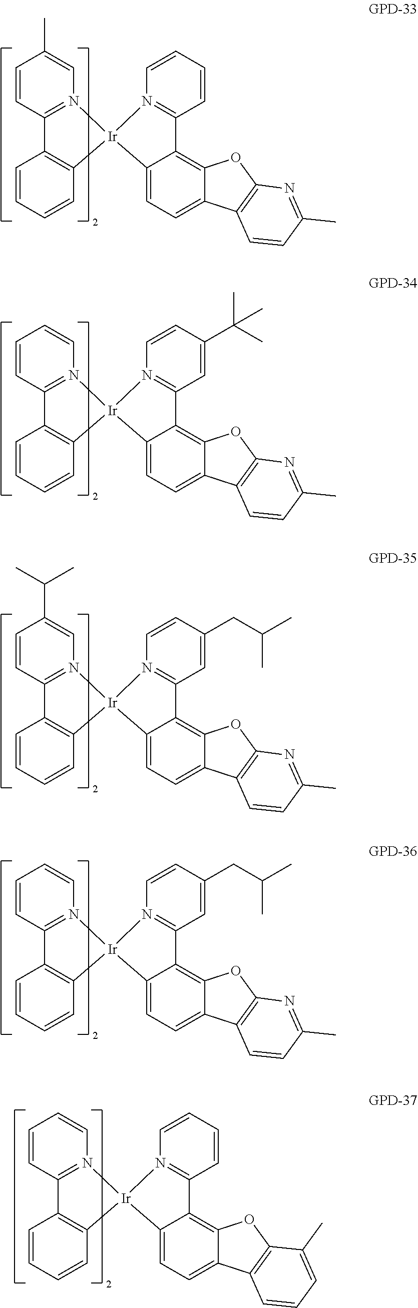

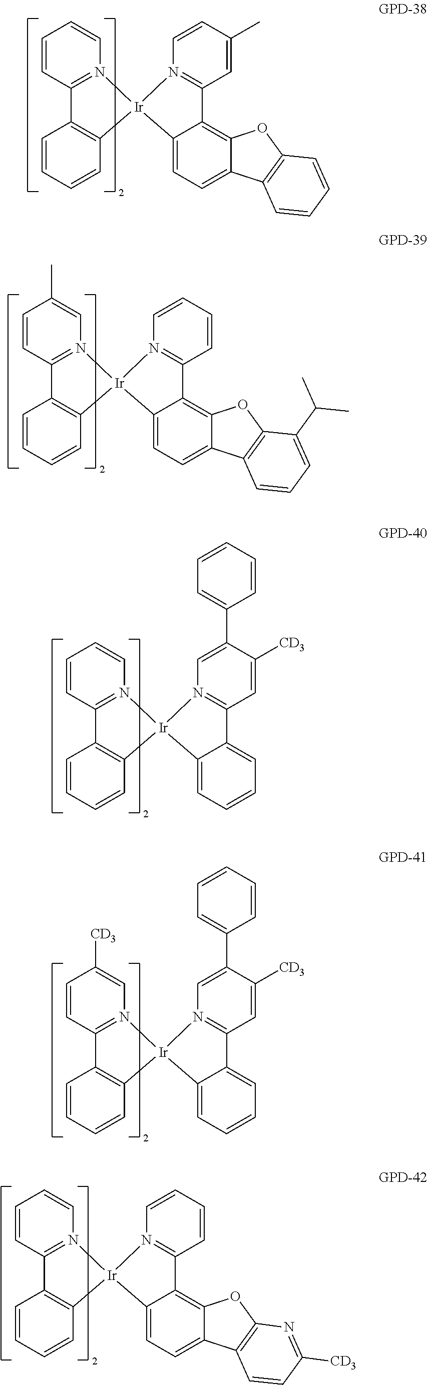

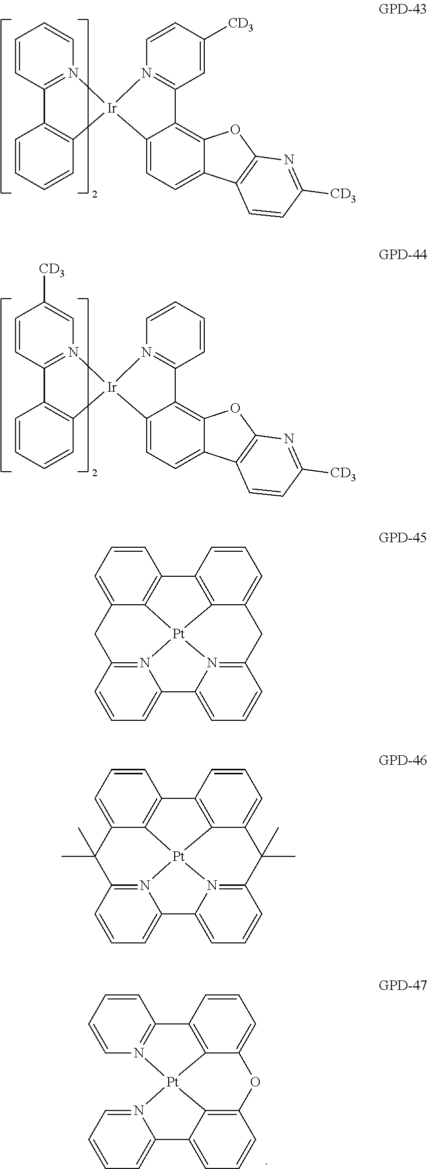

18. The organic light-emitting diode according to claim 1, wherein
the luminescence peak of the narrow-spectrum fluorescent material is 500 nm-550 nm;
or in the phosphorescence sensitized light-emitting layer, the mass content of the phosphorescent sensitizer is 0.1-50%;
or in the phosphorescence sensitized light-emitting layer, the mass content of the narrow-spectrum fluorescent material is 0.1-30%.

19. The organic light-emitting diode according to claim 1, wherein
the at least one light-emitting layer comprises at least two light-emitting layers that are stacked;
the organic light-emitting diode further comprises an anode and a cathode, the at least one light-emitting layer comprises a first light-emitting layer and a second light-emitting layer, and the cathode, the first light-emitting layer, the second light-emitting layer and the anode are stacked sequentially,
wherein the first light-emitting layer is the phosphorescence sensitized light-emitting layer, or the second light-emitting layer is the phosphorescence sensitized light-emitting layer, or
both the first light-emitting layer and the second light-emitting layer are the phosphorescence sensitized light-emitting layer.

20. A display apparatus, comprising the organic light-emitting diode according to claim 1.
